(19) United States
(12) Patent Application Publication
(10) Pub. No.: US 2022/0259239 A1
(43) Pub. Date: Aug. 18, 2022

(54) ORGANIC ELECTROLUMINESCENT MATERIAL AND DEVICE THEREOF

(71) Applicant: BEIJING SUMMER SPROUT TECHNOLOGY CO., LTD., Beijing (CN)

(72) Inventors: Wei Cai, Beijing (CN); Ming Sang, Beijing (CN); Hongbo Li, Beijing (CN); Zhen Wang, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 17/649,239

(22) Filed: Jan. 28, 2022

(30) Foreign Application Priority Data
Feb. 6, 2021 (CN) 202110165116.0

(51) Int. Cl. C07F 15/00; H01L 51/00

(52) U.S. Cl. CPC C07F 15/0033; H01L 51/0067; H01L 51/0072; H01L 51/0054; H01L 51/5028; H01L 51/0073; H01L 51/0074; H01L 51/0085; H01L 51/0058

(57) ABSTRACT

Provided are an organic electroluminescent material and device thereof. The organic electroluminescent material is a metal complex including a ligand Lₐ having a structure of Formula 1, and the metal complex can be used as a luminescent material in an electroluminescent device. These new compounds, when used in electroluminescent devices, can show better performance, provide more saturated luminescence, higher luminous efficiency and narrower full width at half maximum, and significantly improve the comprehensive performance of devices. Further provided are an electroluminescent device including the metal complex and a compound combination including the metal complex.

### CROSS-REFERENCE TO RELATED APPLICATION(S)

This application claims priority to Chinese Patent Application No. CN 202110165116.0 filed on Feb. 6, 2021, the disclosure of which is incorporated herein by reference in its entirety.

### TECHNICAL FIELD

The present disclosure relates to compounds for organic electronic devices, for example, an organic light-emitting device. More particularly, the present disclosure relates to a metal complex including a ligand Lₐ having a structure represented by Formula 1, an organic electroluminescent device including the metal complex, and a compound combination.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which includes an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may include multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may include one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

In the previous patent US20200251666A1, the applicant discloses a metal complex comprising a ligand having a structure represented by

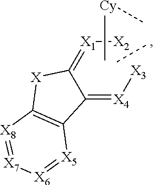

wherein at least one of X₁ to X₈ is selected from C—CN, and further discloses an iridium complex having a structure represented by

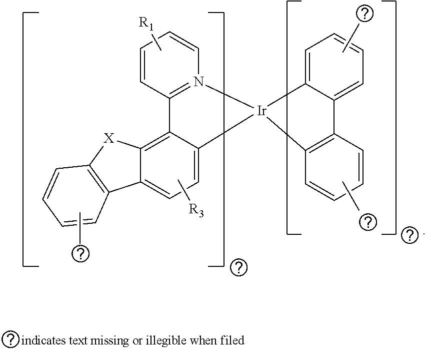

The complex, when used in organic electroluminescent devices, can improve device performance and color saturation and has achieved a high level in the industry, but there is still room for improvement. However, in this application, only a metal complex in which R₄ is an aryl substituent of a phenyl group and the use thereof in devices are disclosed, and the impact of the introduction of an aryl group or a heteroaryl group as specified in the present application on the performance of devices is not disclosed and concerned.

In the previous patent US20200091442A1, the applicant discloses a metal complex comprising a ligand having a structure represented by

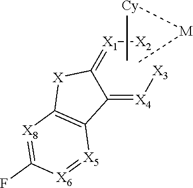

and further discloses an iridium complex having a structure represented by

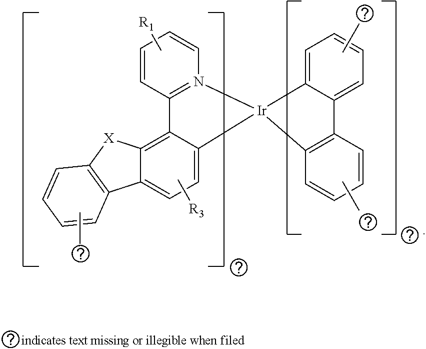

In this application, fluorine at the specific position of the ligand can improve the performance of materials, including prolonging device lifetime and improving thermal stability, but there is still room for improvement. However, in this application, only a metal complex in which R₄ is an aryl substituent of a phenyl group and the use thereof in devices are disclosed, and the impact of the introduction of an aryl group or a heteroaryl group as specified in the present application on the performance of devices is not disclosed and concerned.

### SUMMARY

The present disclosure aims to provide a series of metal complexes including a ligand Lₐ having a structure represented by Formula 1 to solve at least part of the above-mentioned problems.

According to an embodiment of the present disclosure, a metal complex is disclosed, which includes a metal M and a ligand Lₐ coordinated to the metal M, wherein Lₐ has a structure represented by Formula 1:

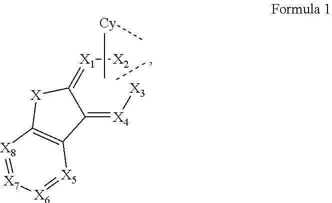

in Formula 1,

the metal M is selected from a metal having a relative atomic mass greater than 40;

Cy is, at each occurrence identically or differently, selected from a substituted or unsubstituted aromatic ring having 6 to 24 ring atoms, a substituted or unsubstituted heteroaromatic ring having 5 to 24 ring atoms or combinations thereof,

X is selected from the group consisting of O, S, Se, NR′, CR′R′, SiR′R′, and GeR′R′; when two R′ are present, the two R′ are the same or different;

X₁ to X₈ are, at each occurrence identically or differently, selected from C, CRₓ or N; at least one of X₁ to X₄ is C and is attached to the Cy;

X₁, X₂, X₃ or X₄ is attached to the metal M through a metal-carbon bond or a metal-nitrogen bond;

at least one of X₁ to X₈ is CRₓ, and the Rₓ is a cyano group or fluorine;

at least another one of X₁ to X₈ is CRₓ, and Rₓ is Ar, and the Ar has a structure represented by Formula 2:

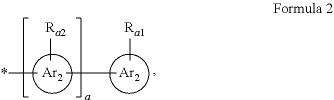

a is selected from 0, 1, 2, 3, 4 or 5;

Rₐ₁ and Rₐ₂ represent, at each occurrence identically or differently, mono-substitution, multiple substitutions or non-substitution;

ring Ar₁ and ring Ar₂ are, at each occurrence identically or differently, selected from an aromatic ring having 6 to 30 ring atoms, a heteroaromatic ring having 5 to 30 ring atoms or combinations thereof; and a total number of ring atoms of ring Ar₁ and ring Ar₂ is greater than or equal to 8;

R′, Rₓ, Rₐ₁, and Rₐ₂ are, at each occurrence identically or differently, selected from the group consisting of: hydrogen, deuterium, halogen, a substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a substituted or unsubstituted alkylgermanyl having 3 to 20 carbon atoms, a substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,

“*” represents a position where Formula 2 is attached;

adjacent substituents R′, Rₓ, Rₐ₁, Rₐ₂ can be optionally joined to form a ring.

According to another embodiment of the present disclosure, an electroluminescent device is further disclosed, which includes:

an anode,

a cathode, and

an organic layer disposed between the anode and the cathode, wherein the organic layer includes the metal complex described in the above-mentioned embodiments.

According to another embodiment of the present disclosure, a compound combination is further disclosed, which comprises the metal complex described in the above-mentioned embodiments.

The present disclosure discloses a series of metal complexes including a ligand Lₐ having a structure of Formula 1, and the metal complexes can be used as a luminescent material in an electroluminescent device. These new metal complexes, when used in electroluminescent devices, can provide more saturated luminescence, higher luminous efficiency and narrower full width at half maximum and significantly improve the comprehensive performance of devices.

### BRIEF DESCRIPTION OF DRAWINGS

FIG. 1 is a schematic diagram of an organic electroluminescent device including a metal complex and a compound combination disclosed in the present disclosure.

FIG. 2 is a schematic diagram of another organic electroluminescent device including a metal complex and a compound combination disclosed in the present disclosure.

### DETAILED DESCRIPTION

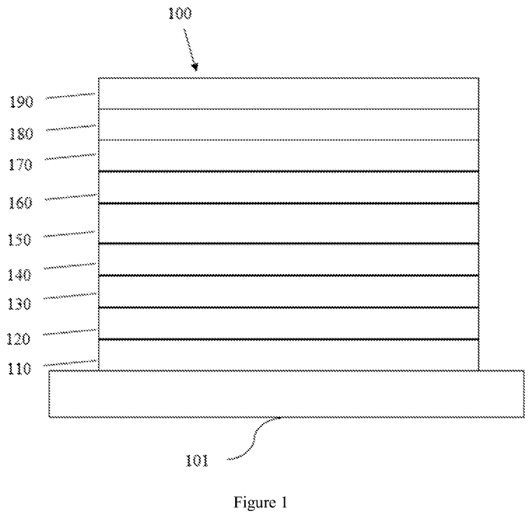

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

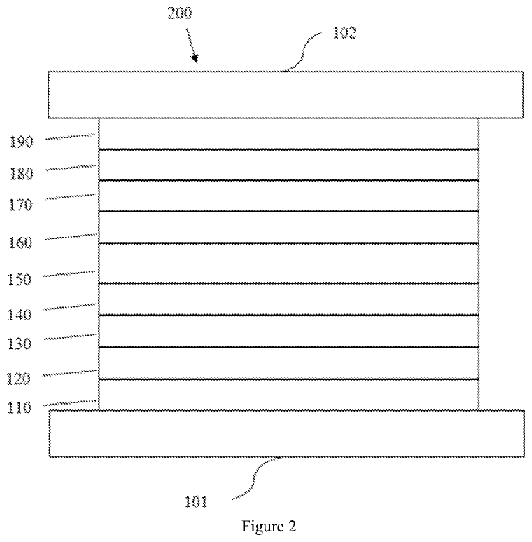

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (Δ_{ES-T}). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small Δ_{ES-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, a n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butylmethylgermanylmethyl, triethylgermanylmethyl, triethylgermanylethyl, triisopropylgermanylmethyl, triisopropylgermanylethyl, trimethylsilylmethyl, trimethylsilylethyl, and trimethylsilylisopropyl, triisopropylsilylmethyl, triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups includes saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates a germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, amino, acyl, carbonyl, a carboxylic acid group, an ester group, sulfinyl, sulfonyl, and phosphino may be substituted with one or more moieties selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl having 3 to 20 carbon atoms, unsubstituted arylgermanyl having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to its enhancements of device efficiency and stability.

In the compounds mentioned in the present disclosure, multiple substitution refers to a range that includes a di-substitution, up to the maximum available substitution. When substitution in the compounds mentioned in the present disclosure represents multiple substitution (including di-, tri-, and tetra-substitutions etc.), that means the substituent may exist at a plurality of available substitution positions on its linking structure, the substituents present at a plurality of available substitution positions may have the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

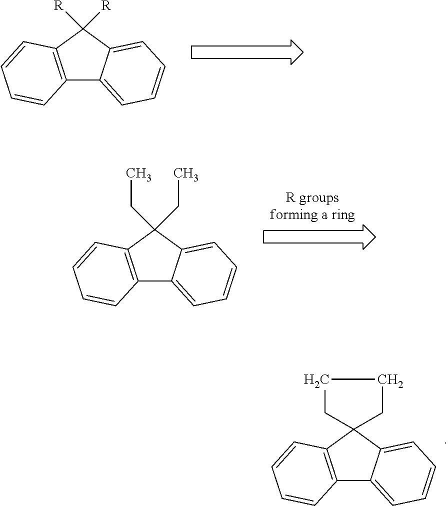

The expression that adjacent substituents can be optionally joined to form a ring is also intended to mean that two substituents bonded to carbon atoms which are directly bonded to each other are joined to each other via a chemical bond to form a ring, which can be exemplified by the following formula:

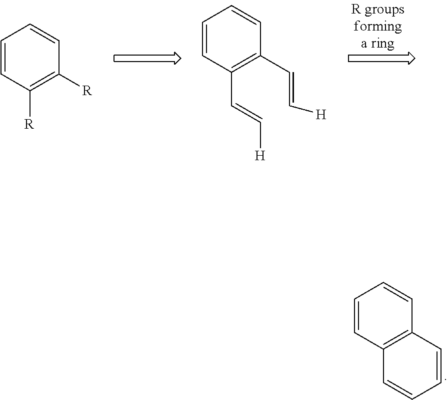

The expression that adjacent substituents can be optionally joined to form a ring is also intended to mean that two substituents bonded to a further distant carbon atom are joined to each other via a chemical bond to form a ring, which can be exemplified by the following formula:

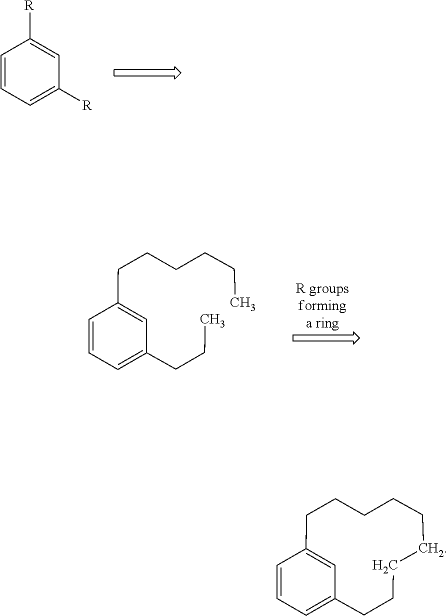

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

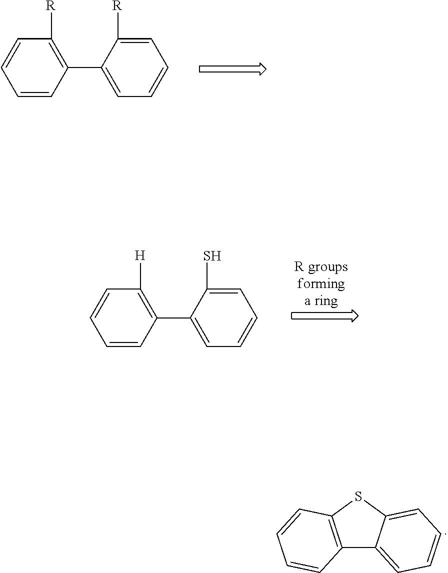

According to an embodiment of the present disclosure, a metal complex is disclosed, which includes a metal M and a ligand Lₐ coordinated to the metal M, wherein Lₐ has a structure represented by Formula 1:

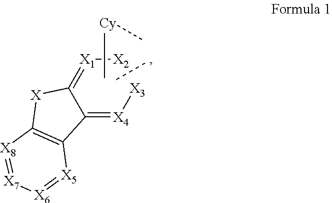

in Formula 1,

the metal M is selected from a metal having a relative atomic mass greater than 40;

Cy is, at each occurrence identically or differently, selected from a substituted or unsubstituted aromatic ring having 6 to 24 ring atoms, a substituted or unsubstituted heteroaromatic ring having 5 to 24 ring atoms or combinations thereof;

X is selected from the group consisting of O, S, Se, NR′, CR′R′, SiR′R′, and GeR′R′; when two R′ are present, the two R′ are the same or different;

X₁ to X₈ are, at each occurrence identically or differently, selected from C, CRₓ or N; at least one of X₁ to X₄ is C and is attached to the Cy;

X₁, X₂, X₃ or X₄ is attached to the metal M through a metal-carbon bond or a metal-nitrogen bond;

at least one of X₁ to X₈ is CRₓ, and the Rₓ is a cyano group or fluorine;

at least another one of X₁ to X₈ is CRₓ, and Rₓ is Ar, and the Ar has a structure represented by Formula 2:

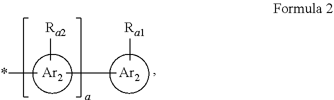

a is selected from 0, 1, 2, 3, 4 or 5;

Rₐ₁ and Rₐ₂ represent, at each occurrence identically or differently, mono-substitution, multiple substitutions or non-substitution;

ring Ar₁ and ring Ar₂ are, at each occurrence identically or differently, selected from an aromatic ring having 6 to 30 ring atoms, a heteroaromatic ring having 5 to 30 ring atoms or combinations thereof, and a total number of ring atoms of ring Ar₁ and ring Ar₂ is greater than or equal to 8;

R′, Rₓ (referred to the remaining Rₓ present in X₁ to X₈, excluding the above-mentioned specific Rₓ), Rₐ₁, and Rₐ₂ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a substituted or unsubstituted alkylgermanyl having 3 to 20 carbon atoms, a substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,

“*” represents a position where Formula 2 is attached;

adjacent substituents R′, Rₓ, Rₐ₁, Rₐ₂ can be optionally joined to form a ring.

Herein, the expression that “adjacent substituents R′, Rₓ, Rₐ₁, Rₐ₂ can be optionally joined to form a ring” is intended to mean that any one or more of groups of adjacent substituents, such as two substituents R′, two substituents Rₓ, two substituents Rₐ₁, two substituents Rₐ₂, substituents R′ and Rₓ, and substituents Rₐ₁ and Rₐ₂, can be joined to form a ring. Apparently, these substituents may not be joined to form a ring.

Herein, “ring atoms” in aromatic and heteroaromatic rings refer to atoms that are bonded to form a ring structure having aromaticity (e.g. monocyclic aromatic(heteroaromatic) rings and fused aromatic(heteroaromatic) rings). The carbon atoms and heteroatoms in the ring (including, but not limited to, O, S, N, Se, Si, etc.) are all counted in the number of ring atoms. When the ring is substituted by a substituent, the atoms included in the substituent are excluded from the number of ring atoms. For example, the number of ring atoms of phenyl, pyridyl and triazinyl is 6, the number of ring atoms of fused dithiophene and fused difuran is 8, the number of ring atoms of benzothiophenyl and benzofuryl is 9, the number of ring atoms of naphthyl, quinolinyl, isoquinolinyl, quinazolinyl and quinoxalinyl is all 10, the number of ring atoms of dibenzothiophene, dibenzofuran, fluorene, azadibenzothiophene, azadibenzofuran and azafluorene is all 13; the various examples described here are illustrative only, to which the other cases are similar. When “a” in Formula 2 is 0, Ar has a structure represented by

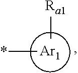

and at this point, the expression that a total number of ring atoms of ring Ar₁ and ring Ar₂ is greater than or equal to 8 means that ring Ar₁ is an aromatic or heteroaromatic ring having a total number of ring atoms greater than or equal to 8; when “a” in Formula 2 is 1, Ar has a structure represented by

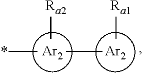

and at this point, for example, when ring Ar₁ and ring Ar₂ are both phenyl and Rₐ₁ and Rₐ₂ are both hydrogen, the total number of ring atoms of ring Ar₁ and ring Ar₂ equals to 12, and in another example, when ring Ar₁ and ring Ar₂ are both phenyl, Rₐ₁ is hydrogen, and Rₐ₂ is mono-substituted and the substitution is phenyl, the total number of ring atoms of ring Ar₁ and ring Ar₂ equals to 12, to which the other cases are similar.

According to an embodiment of the present disclosure, wherein Cy is selected from the group consisting of the following structures:

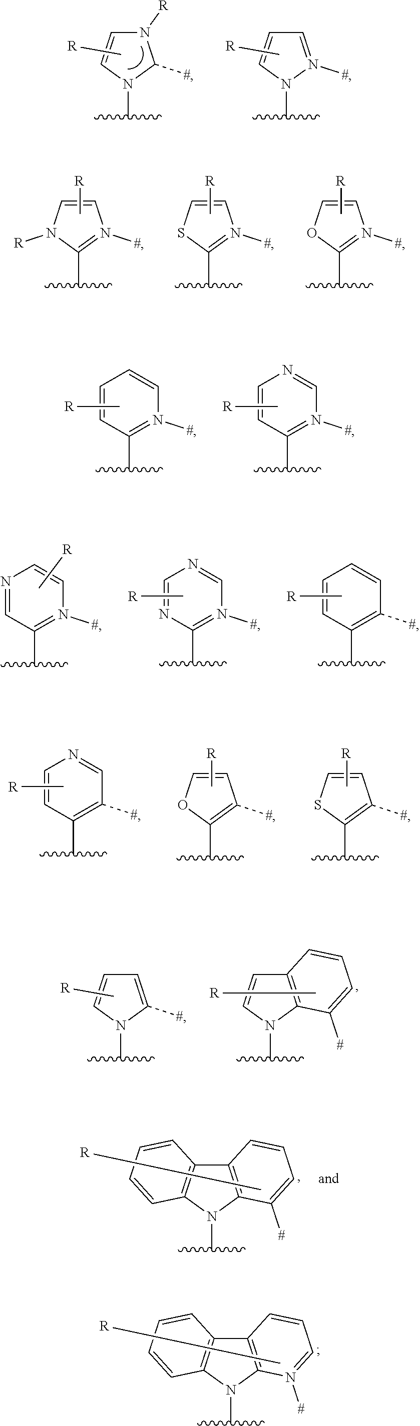

wherein,

R represents, at each occurrence identically or differently, mono-substitution, multiple substitutions or non-substitution; when a plurality of R is present, the plurality of R are the same or different;

R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a substituted or unsubstituted alkylgermanyl having 3 to 20 carbon atoms, a substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,

two adjacent substituents R can be optionally joined to form a ring;

“#” represents a position where the metal M is attached, and

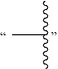

represents a position where X₁, X₂, X₃ or X₄ is attached.

Herein, the expression that “two adjacent substituents R can be optionally joined to form a ring” is intended to mean that any one or more of substituent groups consisting of any two adjacent substituents R can be joined to form a ring. Apparently, these substituents may not be joined to form a ring.

According to an embodiment of the present disclosure, wherein Lₐ is, at each occurrence identically or differently, selected from the group consisting of:

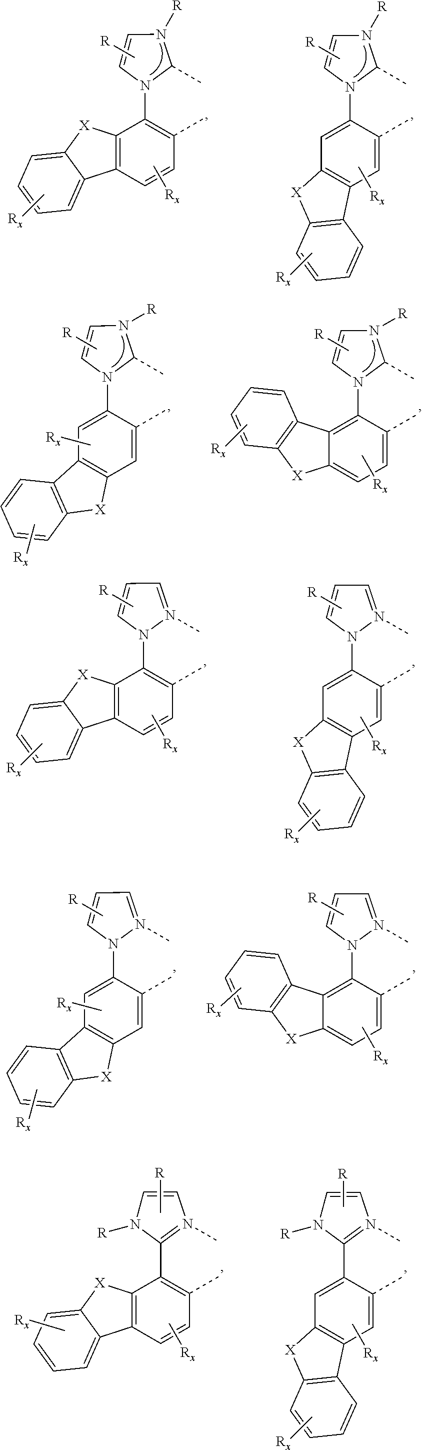

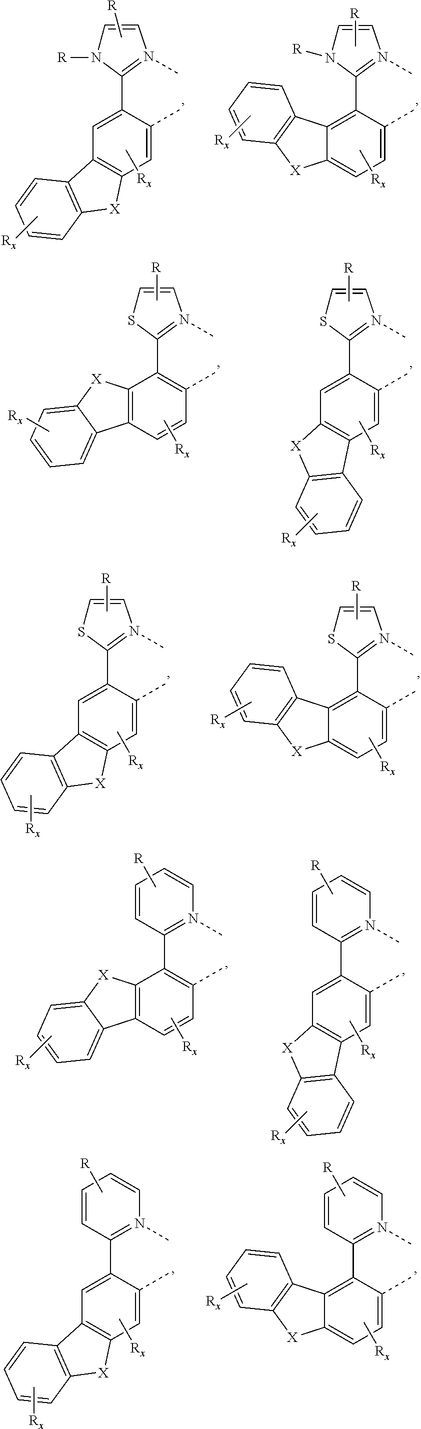

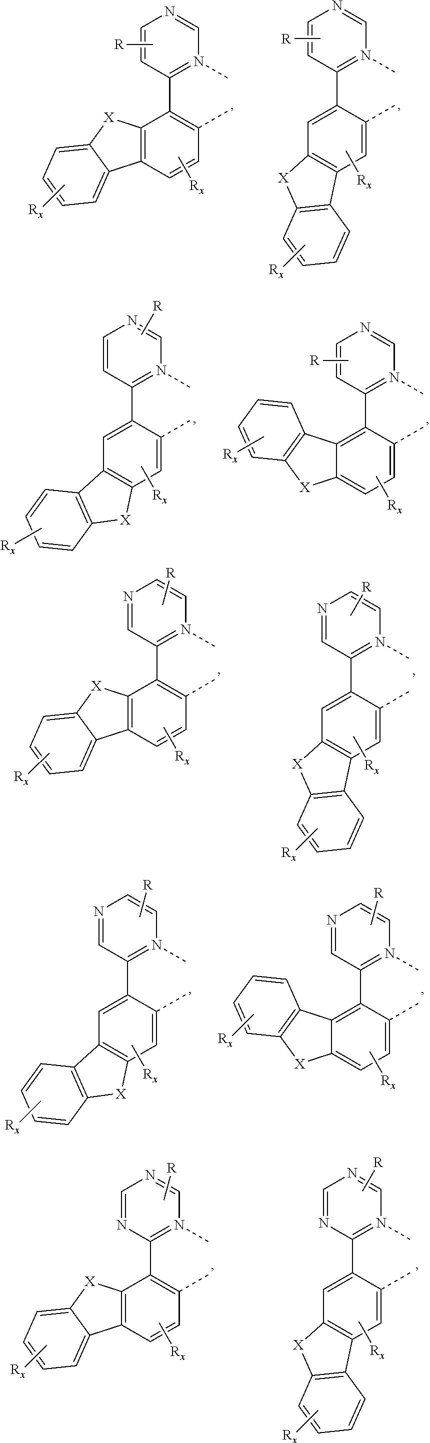

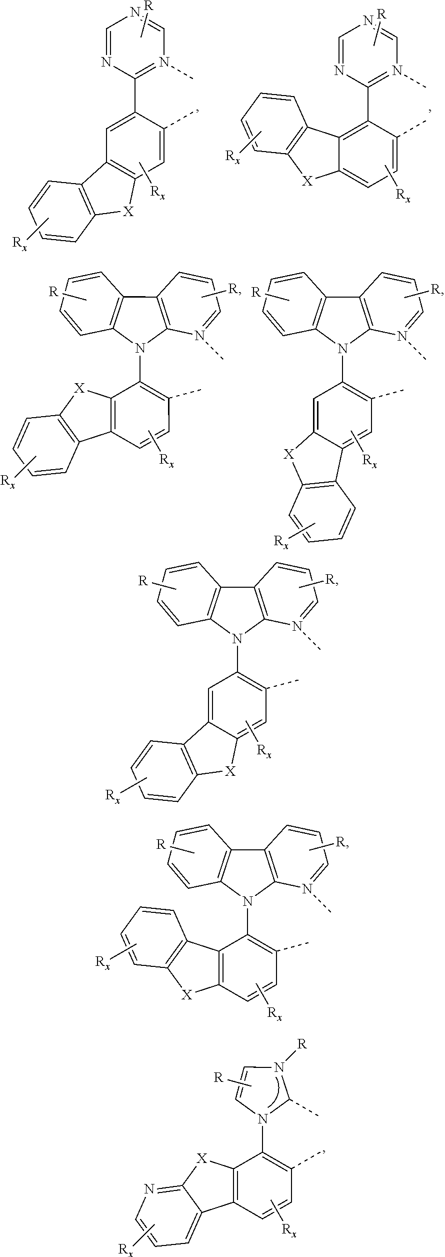

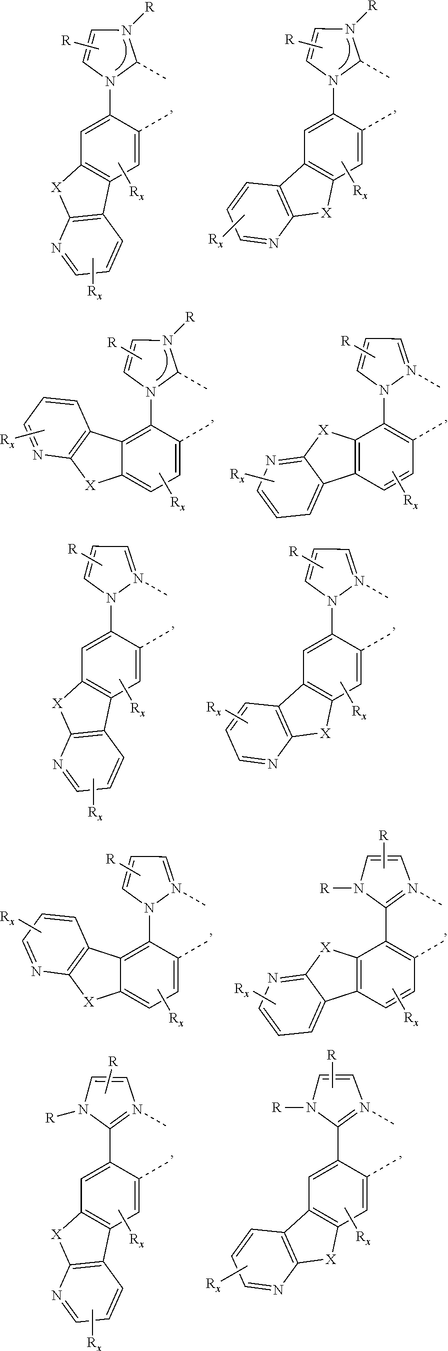

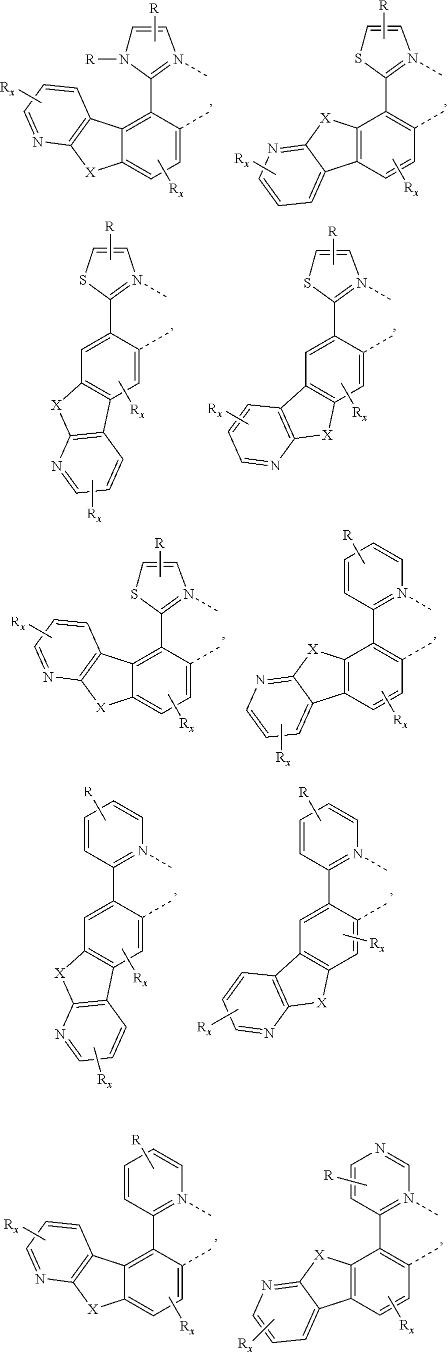

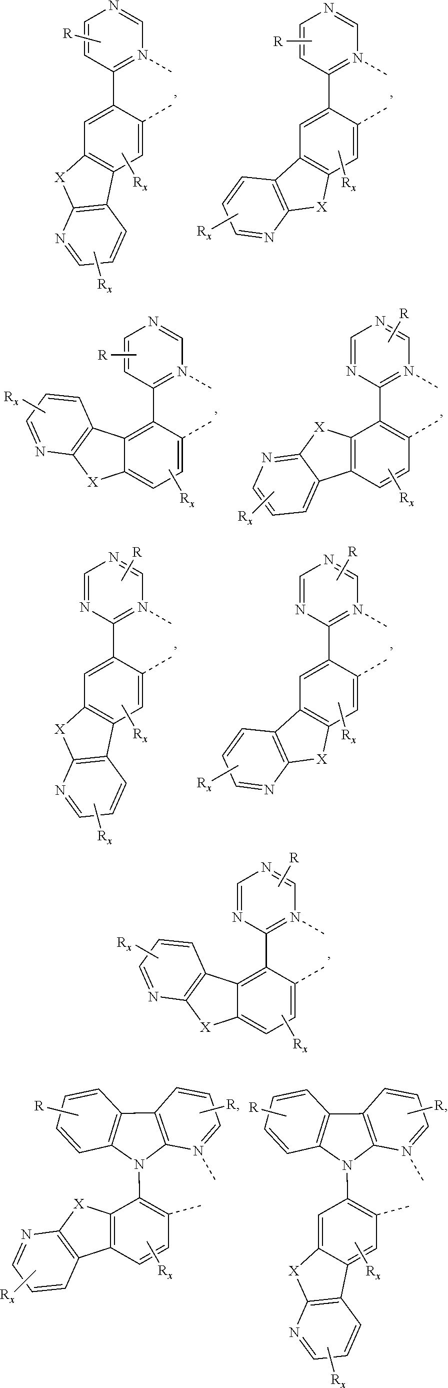

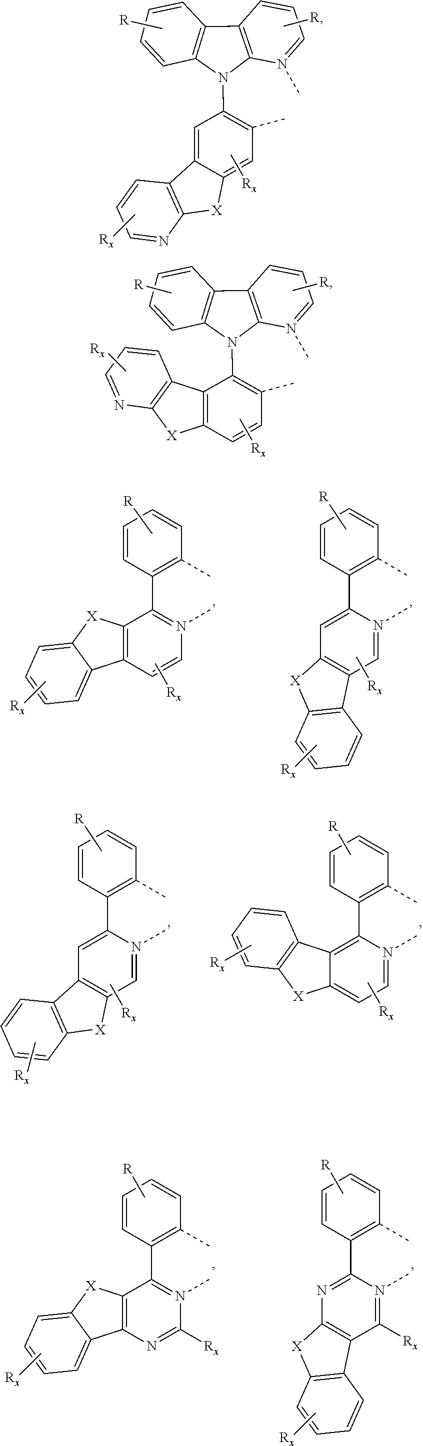

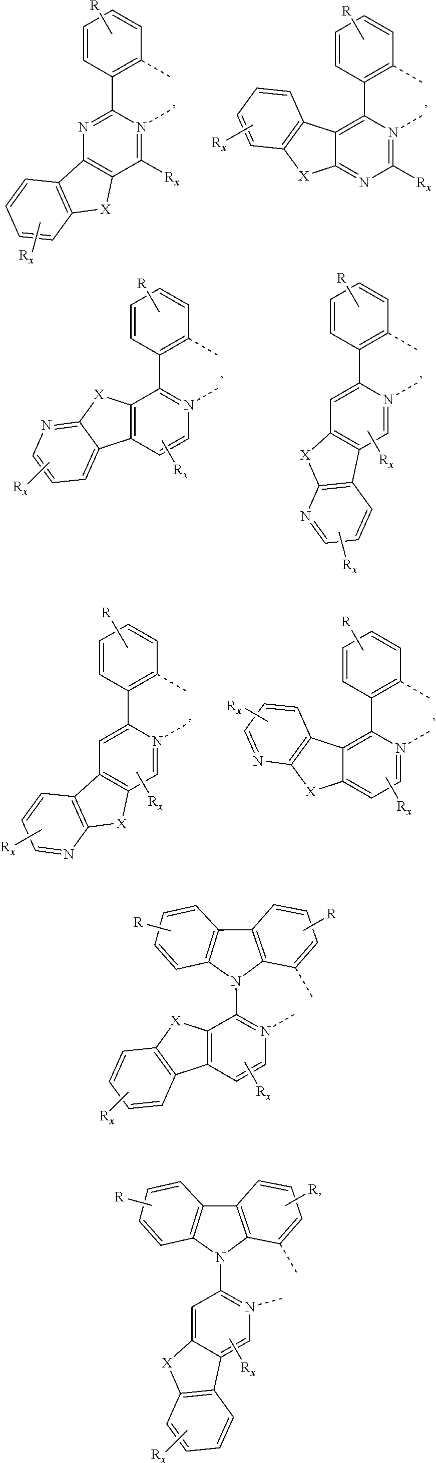

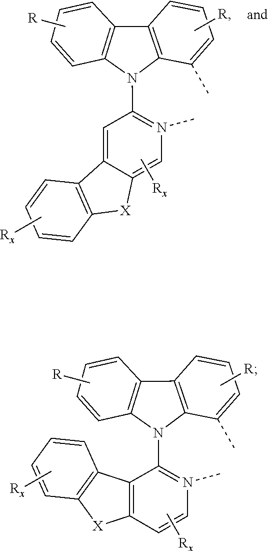

wherein,

X is selected from the group consisting of O, S, Se, NR′, CR′R′, SiR′R′, and GeR′R′; when two R′ are present, the two R′ are the same or different;

R and Rₓ represent, at each occurrence identically or differently, mono-substitution, multiple substitutions or non-substitution;

at least one of Rₓ is a cyano group or fluorine;

at least another one of Rₓ is Ar, and the Ar has a structure represented by Formula 2:

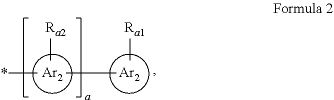

a is selected from 0, 1, 2, 3, 4 or 5;

ring Ar₁ and ring Ar₂ are, at each occurrence identically or differently, selected from an aromatic ring having 6 to 30 ring atoms, a heteroaromatic ring having 5 to 30 ring atoms or combinations thereof; and a total number of ring atoms of ring Ar₁ and ring Ar₂ is greater than or equal to 8;

Rₐ₁ and Rₐ₂ represent, at each occurrence identically or differently, mono-substitution, multiple substitutions or non-substitution;

R, R′, Rₓ, Rₐ₁, and Rₐ₂ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a substituted or unsubstituted alkylgermanyl having 3 to 20 carbon atoms, a substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

adjacent substituents R, R′, Rₓ, Rₐ₁, and Rₐ₂ can be optionally joined to form a ring;

“*” represents a position where Formula 2 is attached.

Herein, the expression that “adjacent substituents R, R′, Rₓ, Rₐ₁, and Rₐ₂ can be optionally joined to form a ring” is intended to mean that any one or more of groups of adjacent substituents, such as two substituents R, two substituents R′, two substituents Rₓ, two substituents Rₐ₁, two substituents Rₐ₂, substituents R′ and Rₓ, and substituents Rₐ₁ and Rₐ₂, can be joined to form a ring. Apparently, these substituents may not be joined to form a ring.

According to an embodiment of the present disclosure, wherein the metal complex has a general formula of M(Lₐ)ₘ(L_{b})ₙ(L_{c})_{q};

wherein,

M is, at each occurrence identically or differently, selected from the group consisting of Cu, Ag, Au, Ru, Rh, Pd, Os, Ir, and Pt; preferably, M is, at each occurrence identically or differently, selected from Pt or Ir;

Lₐ, L_{b}, and L_{c} are a first ligand, a second ligand and a third ligand coordinated to the metal M, respectively, and L_{c} is the same as or different from Lₐ or L_{b}; wherein Lₐ, L_{b}, and L_{c} can be optionally joined to form a multidentate ligand; for example, any two of Lₐ, L_{b}, and L_{c} can be joined to form a tetradentate ligand; in another example, Lₐ, L_{b}, and L_{c} can be joined to each other to form a hexadentate ligand; in another example, Lₐ, L_{b}, and L_{c} are not joined so that no multidentate ligand is formed;

m is selected from 1, 2 or 3, n is selected from 0, 1 or 2, q is selected from 0, 1 or 2, and m+n+q equals an oxidation state of the metal M; when m is greater than or equal to 2, a plurality of Lₐ are the same or different; when n is equal to 2, two L_{b} are the same or different; when q is equal to 2, two L_{c} are the same or different;

L_{b} and L_{c} are, at each occurrence identically or differently, selected from the group consisting of the following structures:

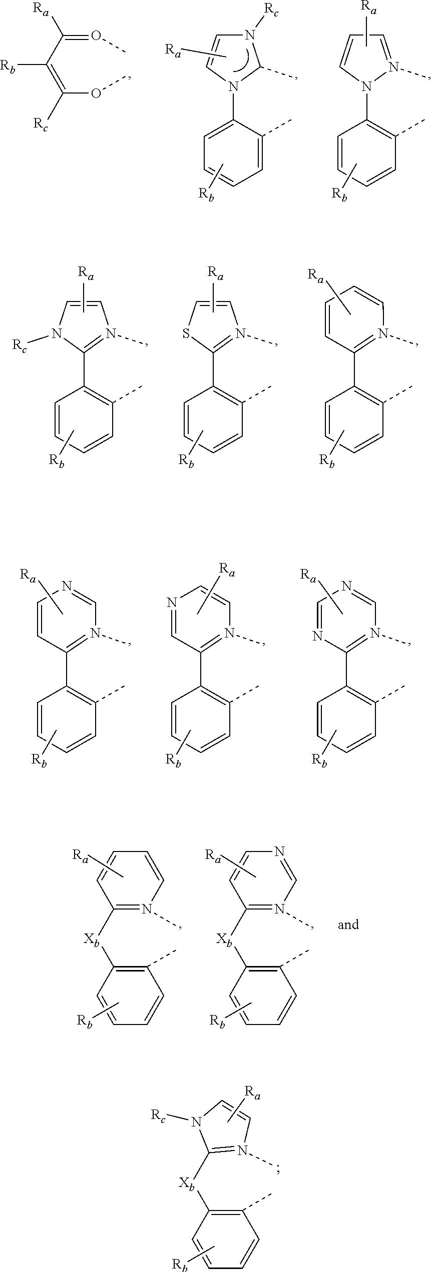

wherein,

Rₐ and R_{b} represent, at each occurrence identically or differently, mono-substitution, multiple substitutions or non-substitution;

X_{b} is, at each occurrence identically or differently, selected from the group consisting of: O, S, Se, NR_{N1}, and CR_{C1}R_{C2};

Rₐ, R_{b}, R_{c}, R_{N1}, R_{C1}, and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a substituted or unsubstituted alkylgermanyl having 3 to 20 carbon atoms, a substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,

adjacent substituents Rₐ, R_{b}, R_{c}, R_{N1}, R_{C1}, and R_{C2} can be optionally joined to form a ring.

Herein, the expression that “adjacent substituents Rₐ, R_{b}, R_{c}, R_{N1}, R_{C1}, and R_{C2} can be optionally joined to form a ring” is intended to mean that any one or more of groups of adjacent substituents, such as two substituents Rₐ, two substituents R_{b}, two substituents R_{c}, substituents Rₐ and R_{b}, substituents Rₐ and R_{c}, substituents R_{b} and R_{c}, substituents Rₐ and R_{N1}, substituents R_{b} and R_{N1}, substituents Rₐ and R_{C1}, substituents Rₐ and R_{C2}, substituents R_{b} and R_{C1}, substituents R_{b} and R_{C2}, and substituents R_{C1} and R_{C2}, can be joined to form a ring. Apparently, these substituents may not be joined to form a ring.

According to an embodiment of the present disclosure, wherein the metal M is, at each occurrence identically or differently, selected from the group consisting of Cu, Ag, Au, Ru, Rh, Pd, Os, Ir, and Pt.

According to an embodiment of the present disclosure, wherein the metal M is, at each occurrence identically or differently, selected from Pt or Ir.

According to an embodiment of the present disclosure, wherein the metal complex Ir(Lₐ)ₘ(L_{b})₃₋ₘ has a structure represented by Formula 3:

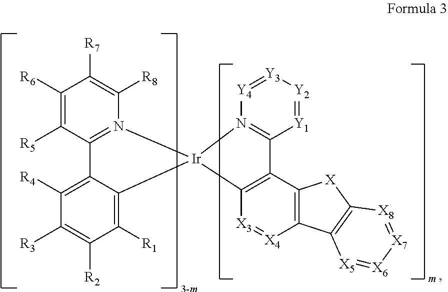

wherein,

m is selected from 1, 2 or 3; when m is selected from 1, two L_{b} are the same or different;

when m is selected from 2 or 3, a plurality of Lₐ are the same or different;

X is selected from the group consisting of O, S, Se, NR′, CR′R′, SiR′R′, and GeR′R′; when two R′ are present, the two R′ are the same or different;

Y₁ to Y₄ are, at each occurrence identically or differently, selected from CR_{y} or N;

X₃ to X₈ are, at each occurrence identically or differently, selected from CRₓ or N;

at least one of X₃ to X₈ is CRₓ, and the Rₓ is a cyano group or fluorine;

at least another one of X₃ to X₈ is CRₓ, and the Rₓ is Ar, and the Ar has a structure represented by Formula 2:

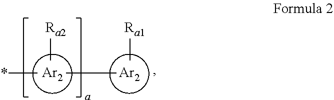

a is selected from 0, 1, 2, 3, 4 or 5;

Rₐ₁ and Rₐ₂ represent, at each occurrence identically or differently, mono-substitution, multiple substitutions or non-substitution;

ring Ar₁ and ring Ar₂ are, at each occurrence identically or differently, selected from an aromatic ring having 6 to 30 ring atoms, a heteroaromatic ring having 5 to 30 ring atoms or combinations thereof; and a total number of ring atoms of ring Ar₁ and ring Ar₂ is greater than or equal to 8;

R′, Rₓ, R_{y}, R₁ to R₈, Rₐ₁, and Rₐ₂ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a substituted or unsubstituted alkylgermanyl having 3 to 20 carbon atoms, a substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,

“*” represents a position where Formula 2 is attached;

adjacent substituents R′, Rₓ, R_{y}, Rₐ₁, Rₐ₂ can be optionally joined to form a ring;

adjacent substituents R₁ to R₈ can be optionally joined to form a ring.

Herein, the expression that “adjacent substituents R′, Rₓ, R_{y}, Rₐ₁, Rₐ₂ can be optionally joined to form a ring” is intended to mean that any one or more of groups of adjacent substituents, such as two substituents R′, two substituents Rₓ, two substituents R_{y}, two substituents Rₐ₁, two substituents Rₐ₂, substituents Rₐ₁ and Rₐ₂, and substituents R′ and Rₓ, can be joined to form a ring. The expression that “adjacent substituents R₁ to R₈ can be optionally joined to form a ring” is intended to mean that any one or more of groups of adjacent substituents, such as adjacent substituents R₁ and R₂, adjacent substituents R₃ and R₂, adjacent substituents R₃ and R₄, adjacent substituents R₅ and R₄, adjacent substituents R₅ and R₆, adjacent substituents R₇ and R₆, and adjacent substituents R₇ and R₈, can be joined to form a ring. Apparently, these substituents may not be joined to form a ring.

According to an embodiment of the present disclosure, wherein the metal complex Ir(Lₐ)ₘ(L_{b})₃₋ₘ has a structure represented by Formula 3A:

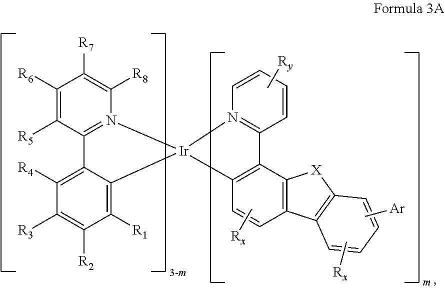

wherein,

m is selected from 1, 2 or 3; when m is selected from 1, two L_{b} are the same or different; when m is selected from 2 or 3, a plurality of Lₐ are the same or different;

X is selected from the group consisting of O, S, Se, NR′, CR′R′, SiR′R′, and GeR′R′; when two R′ are present, the two R′ are the same or different;

Rₓ and R_{y} represent, at each occurrence identically or differently, mono-substitution, multiple substitutions or non-substitution;

at least one of Rₓ is a cyano group or fluorine, and Ar has a structure represented by Formula 2:

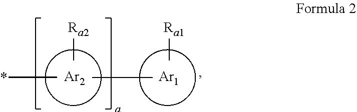

a is selected from 0, 1, 2, 3, 4 or 5;

ring Ar₁ and ring Ar₂ are, at each occurrence identically or differently, selected from an aromatic ring having 6 to 30 ring atoms, a heteroaromatic ring having 5 to 30 ring atoms or combinations thereof; and a total number of ring atoms of ring Ar₁ and ring Ar₂ is greater than or equal to 8;

Rₐ₁ and Rₐ₂ represent, at each occurrence identically or differently, mono-substitution, multiple substitutions or non-substitution;

R′, Rₓ, R_{y}, R₁ to R₈, Rₐ₁, and Rₐ₂ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a substituted or unsubstituted alkylgermanyl having 3 to 20 carbon atoms, a substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,

“*” represents a position where Formula 2 is attached;

adjacent substituents R′, Rₓ, R_{y}, Rₐ₁, Rₐ₂ can be optionally joined to form a ring;

adjacent substituents R₁ to R₈ can be optionally joined to form a ring.

According to an embodiment of the present disclosure, wherein X is selected from O or S.

According to an embodiment of the present disclosure, wherein X is O.

According to an embodiment of the present disclosure, wherein X₁ to X₈ are, at each occurrence identically or differently, selected from C or CRₓ.

According to an embodiment of the present disclosure, wherein at least one of X₁ to X₈ is N, for example, one of X₁ to X₈ is N or two of X₁ to X₈ are N.

According to an embodiment of the present disclosure, in Formula 3, X₃ to X₈ are, at each occurrence identically or differently, selected from CRₓ.

According to an embodiment of the present disclosure, in Formula 3, at least one of X₃ to X₈ is N, for example, one of X₃ to X₈ is N or two of X₃ to X₈ are N.

According to an embodiment of the present disclosure, wherein Y₁ to Y₄ are, at each occurrence identically or differently, selected from CR_{y}.

According to an embodiment of the present disclosure, wherein at least one of Y₁ to Y₄ is N, for example, one of Y₁ to Y₄ is N or two of Y₁ to Y₄ are N.

According to an embodiment of the present disclosure, wherein a is selected from 0, 1, 2 or 3.

According to an embodiment of the present disclosure, wherein a is selected from 1.

According to an embodiment of the present disclosure, wherein at least one of X₅ to X₈ is selected from CRₓ, and the Rₓ is a cyano group or fluorine.

According to an embodiment of the present disclosure, wherein at least one of X₇ to X₈ is selected from CRₓ, and the Rₓ is a cyano group or fluorine.

According to an embodiment of the present disclosure, wherein X₇ is CRₓ, and the Rₓ is a cyano group or fluorine.

According to an embodiment of the present disclosure, wherein X₈ is CRₓ, and the Rₓ is a cyano group or fluorine.

According to an embodiment of the present disclosure, wherein at least one of X₅ to X₈ is selected from CRₓ, and the Rₓ is Ar.

According to an embodiment of the present disclosure, wherein at least one of X₇ to X₈ is selected from CRₓ, and the Rₓ is Ar.

According to an embodiment of the present disclosure, wherein X₈ is selected from CRₓ, and the Rₓ is Ar.

According to an embodiment of the present disclosure, wherein X₇ is selected from CRₓ, and the Rₓ is Ar.

According to an embodiment of the present disclosure, wherein Rₐ₁ and Rₐ₂ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group, an isocyano group, a hydroxyl group, a sulfanyl group, and combinations thereof.

According to an embodiment of the present disclosure, wherein Rₐ₁ and Rₐ₂ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, and combinations thereof.

According to an embodiment of the present disclosure, wherein Rₐ₁ and Rₐ₂ are, at each occurrence identically or differently, selected from the group consisting of: hydrogen, deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 18 carbon atoms, substituted or unsubstituted heteroaryl having 3 to 18 carbon atoms, substituted or unsubstituted alkylsilyl having 3 to 15 carbon atoms, and combinations thereof.

According to an embodiment of the present disclosure, wherein Rₐ₁ and Rₐ₂ are, at each occurrence identically or differently, selected from the group consisting of: hydrogen, deuterium, fluorine, methyl, ethyl, propyl, isopropyl, n-butyl, isobutyl, t-butyl, cyclopentyl, cyclohexyl, deuterated methyl, deuterated ethyl, deuterated propyl, deuterated isopropyl, deuterated n-butyl, deuterated isobutyl, deuterated t-butyl, deuterated cyclopentyl, deuterated cyclohexyl, phenyl, pyridyl, trimethylsilyl, and combinations thereof.

According to an embodiment of the present disclosure, wherein in Ar, ring Ar₁ and ring Ar₂ are, at each occurrence identically or differently, selected from an aromatic ring having 6 to 18 ring atoms, a heteroaromatic ring having 5 to 18 ring atoms or combinations thereof; and a total number of ring atoms of ring Ar₁ and ring Ar₂ is greater than or equal to 8 and less than or equal to 30.

According to an embodiment of the present disclosure, in Ar, a total number of ring atoms of ring Ar₁ and ring Ar₂ is greater than or equal to 8 and less than or equal to 24.

According to an embodiment of the present disclosure, in Ar, a total number of ring atoms of ring Ar₁ and ring Ar₂ is greater than or equal to 8 and less than or equal to 18.

According to an embodiment of the present disclosure, in Ar, ring Ar₁ and ring Ar₂ are, at each occurrence identically or differently, selected from an aromatic ring having 6 ring atoms, a heteroaromatic ring having 5 or 6 ring atoms or combinations thereof.

According to an embodiment of the present disclosure, in Ar, ring Ar₁ and ring Ar₂ are, at each occurrence identically or differently, selected from an aromatic ring having 6 ring atoms or a heteroaromatic ring having 6 ring atoms.

According to an embodiment of the present disclosure, in Ar, ring Ar₁ and ring Ar₂ are, at each occurrence identically or differently, selected from an aromatic ring having 6 ring atoms.

According to an embodiment of the present disclosure, in Ar, ring Ar₁ and ring Ar₂ are, at each occurrence identically or differently, selected from the group consisting of: a benzene ring, a pyridine ring, a pyrimidine ring, a triazine ring, a naphthalene ring, a phenanthrene ring, an anthracene ring, a fluorene ring, a silafluorene ring, a quinoline ring, an isoquinoline ring, a fused dithiophene ring, a fused difuran ring, a benzofuran ring, a benzothiophene ring, a dibenzofuran ring, a dibenzothiophene ring, a triphenylene ring, a carbazole ring, an azacarbazole ring, an azafluorene ring, an azasilafluorene ring, an azadibenzofuran ring, an azadibenzothiophene ring, and combinations thereof, and a total number of ring atoms of ring Ar₁ and ring Ar₂ is greater than or equal to 8 and less than or equal to 30.

According to an embodiment of the present disclosure, wherein, in Ar is, at each occurrence identically or differently, selected from substituted or unsubstituted biphenyl, substituted or unsubstituted fused dithiophenyl, substituted or unsubstituted fused difuryl, substituted or unsubstituted indolyl, substituted or unsubstituted phenanthryl, substituted or unsubstituted anthracyl, substituted or unsubstituted fluorenyl, substituted or unsubstituted silafluorenyl, substituted or unsubstituted germafluorenyl, substituted or unsubstituted carbazolyl, substituted or unsubstituted azadibenzothiophenyl, substituted or unsubstituted azadibenzofuryl, substituted or unsubstituted azacarbazolyl, substituted or unsubstituted azabiphenyl, substituted or unsubstituted triphenylenyl or combinations thereof.

According to an embodiment of the present disclosure, wherein Ar is, at each occurrence identically or differently, selected from the group consisting of:

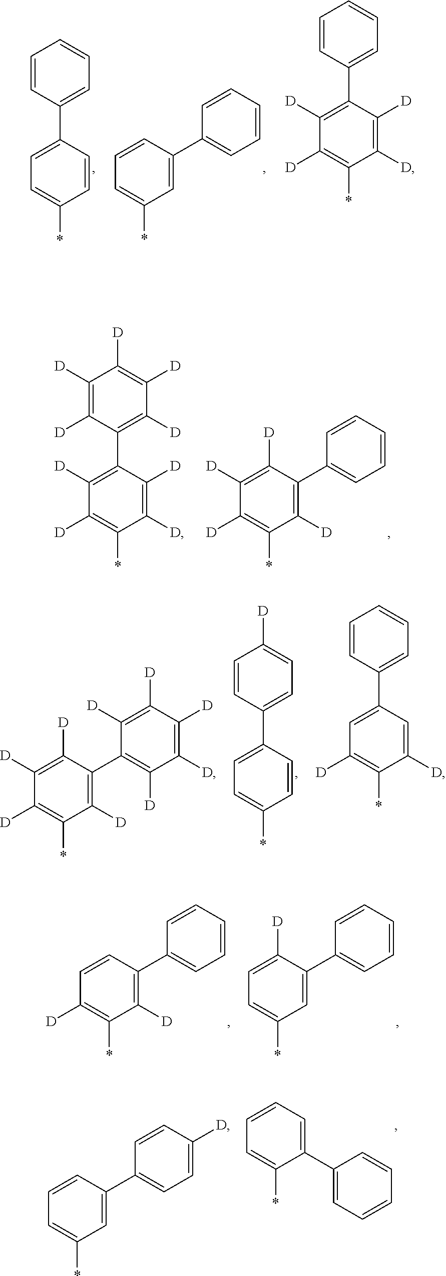

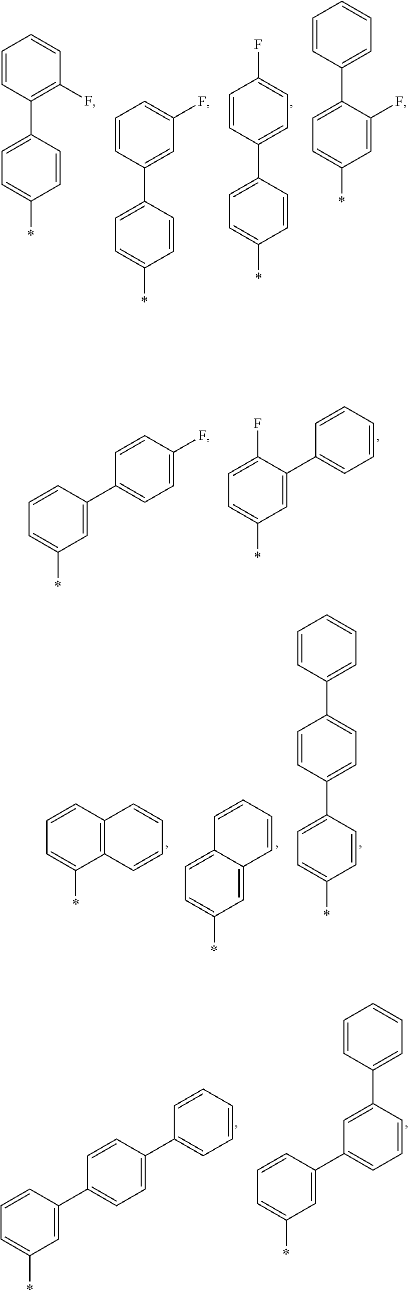

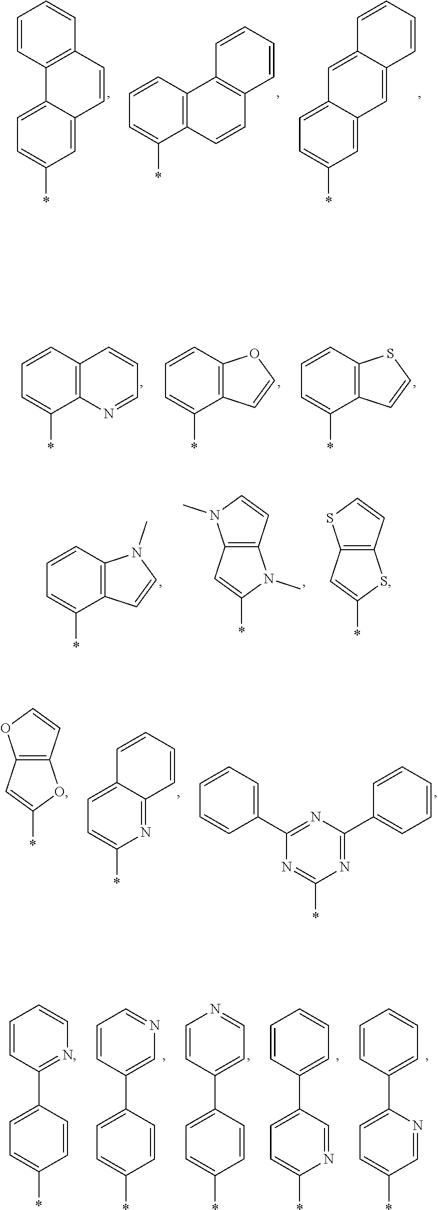

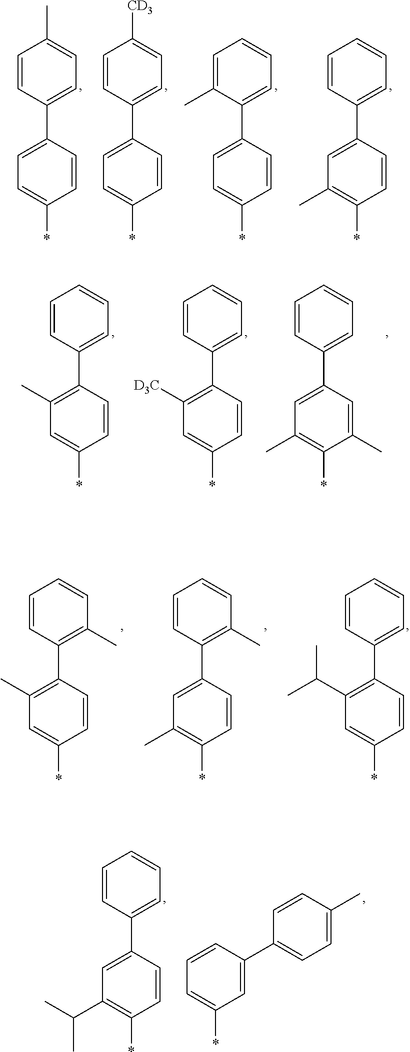

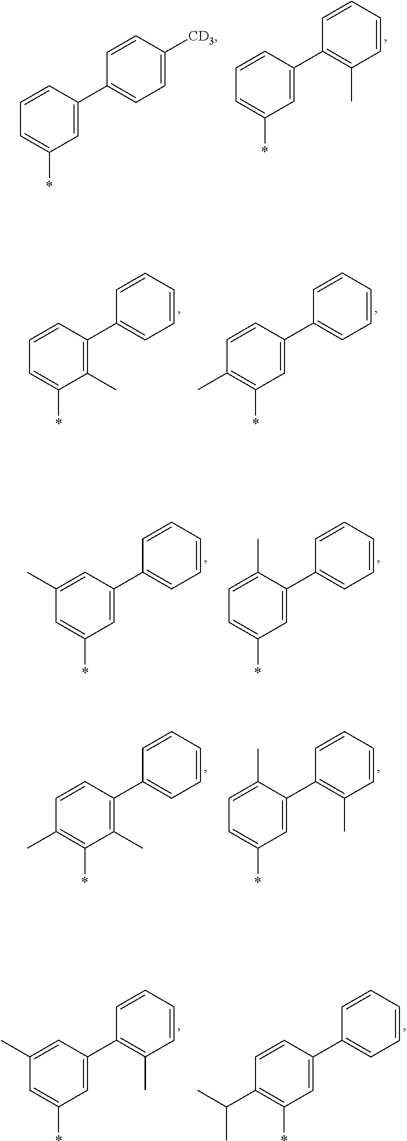

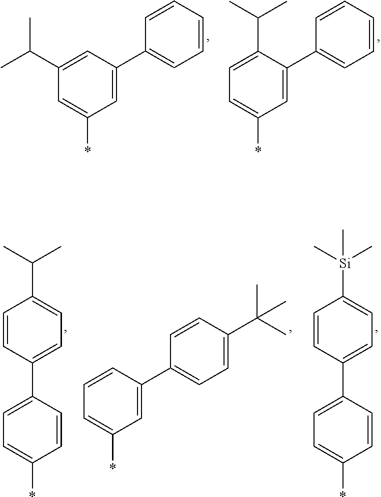

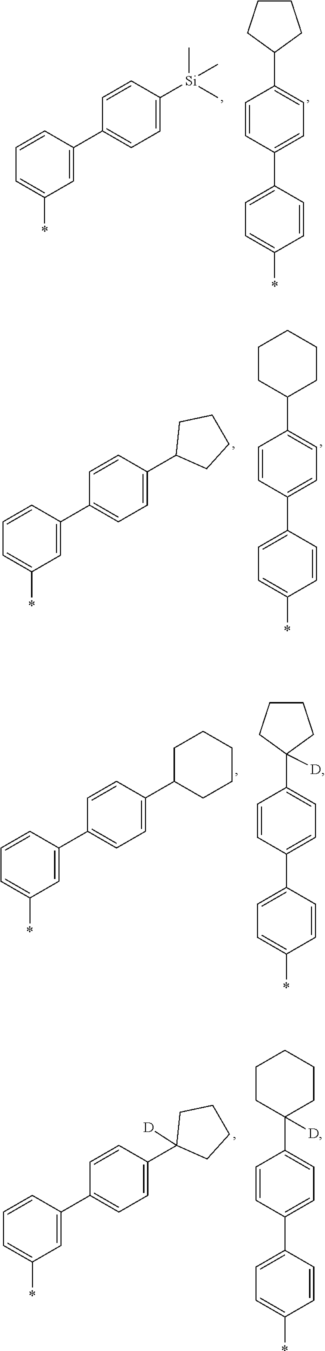

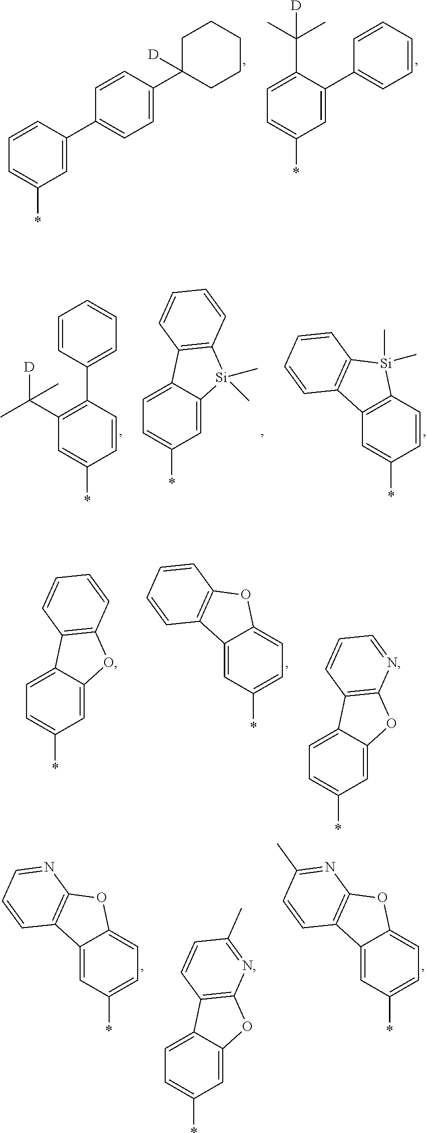

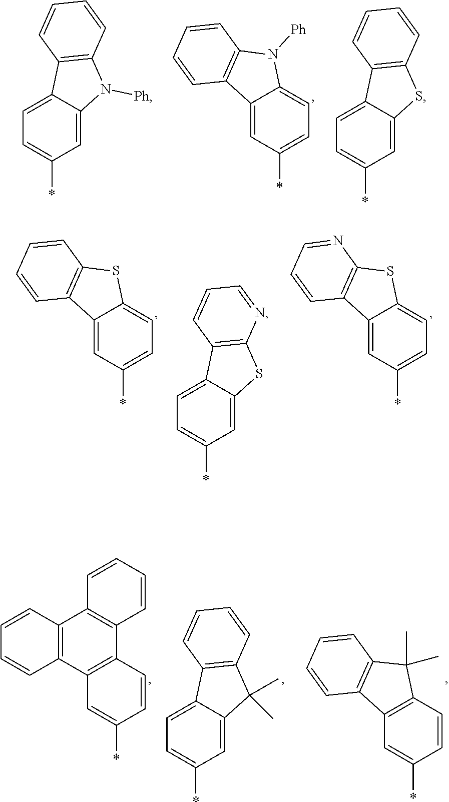

and combinations thereof;

optionally, hydrogen in the above groups can be partially or fully substituted with deuterium; wherein “*” represents a position where Ar is attached.

According to an embodiment of the present disclosure, wherein at least one of Rₓ is selected from a cyano group or fluorine, at least another one of Rₓ is selected from Ar, and remaining Rₓ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, a cyano group, and combinations thereof.

According to an embodiment of the present disclosure, wherein at least one of Rₓ is selected from a cyano group or fluorine, at least another one of Rₓ is selected from Ar, and remaining Rₓ are, at each occurrence identically or differently, selected from the group consisting of: hydrogen, deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 6 carbon atoms, a cyano group, and combinations thereof.

According to an embodiment of the present disclosure, wherein at least one of Rₓ is selected from a cyano group or fluorine, at least another one of Rₓ is selected from Ar, and remaining Rₓ are, at each occurrence identically or differently, selected from the group consisting of: hydrogen, deuterium, substituted or unsubstituted alkyl having 1 to 6 carbon atoms, substituted or unsubstituted cycloalkyl having 3 to 6 ring carbon atoms, and combinations thereof.

According to an embodiment of the present disclosure, wherein R_{y} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, and combinations thereof.

According to an embodiment of the present disclosure, wherein R_{y} is selected from the group consisting of: hydrogen, deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 6 carbon atoms, a cyano group, and combinations thereof.

According to an embodiment of the present disclosure, wherein R_{y} is, at each occurrence identically or differently, selected from the group consisting of: hydrogen, deuterium, methyl, ethyl, propyl, isopropyl, n-butyl, isobutyl, t-butyl, cyclopentyl, cyclohexyl, deuterated methyl, deuterated ethyl, deuterated propyl, deuterated isopropyl, deuterated n-butyl, deuterated isobutyl, deuterated t-butyl, deuterated cyclopentyl, deuterated cyclohexyl, phenyl, pyridyl, trimethylsilyl, and combinations thereof.

According to an embodiment of the present disclosure, wherein R_{y} is selected from hydrogen or deuterium.

According to an embodiment of the present disclosure, wherein in Formula 3, at least one R_{y} is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, wherein in Formula 3, at least one or at least two or at least three or all of R₂, R₃, R₆, and R₇ is(are) selected from the group consisting of: deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, wherein in Formula 3, at least one or at least two or at least three or all of R₂, R₃, R₆, and R₇ is(are) selected from the group consisting of: deuterium, substituted or unsubstituted alkyl having 1 to 20 carbon atoms, substituted or unsubstituted cycloalkyl having 3 to 20 ring carbon atoms, and combinations thereof.

According to an embodiment of the present disclosure, wherein in Formula 3, at least one or at least two or at least three or all of R₂, R₃, R₆, and R₇ is(are) selected from the group consisting of: deuterium, methyl, ethyl, propyl, isopropyl, n-butyl, isobutyl, t-butyl, cyclopentyl, cyclohexyl, and combinations thereof, optionally, hydrogen in the above groups can be partially or fully substituted with deuterium.

According to an embodiment of the present disclosure, wherein R′ is selected from substituted or unsubstituted alkyl having 1 to 20 carbon atoms or substituted or unsubstituted cycloalkyl having 3 to 20 ring carbon atoms.

According to an embodiment of the present disclosure, wherein R′ is methyl or deuterated methyl.

According to an embodiment of the present disclosure, wherein Lₐ is, at each occurrence identically or differently, selected from the group consisting of Lₐ₁ to Lₐ₉₅₅, wherein for the specific structures of Lₐ₁ to Lₐ₉₅₅, reference is made to claim 16.

According to an embodiment of the present disclosure, wherein L_{b} is, at each occurrence identically or differently, selected from any one of the group consisting of L_{b1} to L_{b128}, and for the specific structures of L_{b1} to L_{b128}, reference is made to claim 17.

According to an embodiment of the present disclosure, wherein L_{c} is, at each occurrence identically or differently, selected from any one of the group consisting of L_{c1} to L_{c360}, and for the specific structures of L_{c1} to L_{c360}, reference is made to claim 18.

According to an embodiment of the present disclosure, wherein the metal complex has a structure of Ir(Lₐ)₂(L_{b}), Lₐ is, at each occurrence identically or differently, selected from any one or any two of the group consisting of Lₐ₁ to Lₐ₉₅₅, and L_{b} is selected from any one of the group consisting of L_{b1} to L_{b128}, wherein for the specific structures of Lₐ₁ to Lₐ₉₅₅, reference is made to claim 16, and for the specific structures of L_{b1} to L_{b128}, reference is made to claim 17.

According to an embodiment of the present disclosure, wherein the metal complex has a structure of Ir(Lₐ)(L_{b})₂, Lₐ is, at each occurrence identically or differently, selected from any one of the group consisting of Lₐ₁ to Lₐ₉₅₅, and L_{b} is selected from any one or any two of the group consisting of L_{b1} to L_{b128}, wherein for the specific structures of Lₐ₁ to Lₐ₉₅₅, reference is made to claim 16, and for the specific structures of L_{b1} to L_{b128}, reference is made to claim 17.

According to one embodiment of the present disclosure, wherein the metal complex has a structure of Ir(Lₐ)₃, and Lₐ is, at each occurrence identically or differently, selected from any one or any two or any three of the group consisting of Lₐ₁ to Lₐ₉₅₅, wherein for the specific structures of Lₐ₁ to Lₐ₉₅₅, reference is made to claim 16.

According to an embodiment of the present disclosure, wherein the metal complex has a structure of Ir(Lₐ)₂(L_{c}), Lₐ is, at each occurrence identically or differently, selected from any one or any two of the group consisting of Lₐ₁ to Lₐ₉₅₅, and L_{c} is selected from any one of the group consisting of L_{c1} to L_{c360}, wherein for the specific structures of Lₐ₁ to Lₐ₉₅₅, reference is made to claim 16, and for the specific structures of L_{c1} to L_{c360}, reference is made to claim 18.

According to an embodiment of the present disclosure, wherein the metal complex has a structure of Ir(Lₐ)(L_{c})₂, Lₐ is, at each occurrence identically or differently, selected from any one of the group consisting of Lₐ₁ to Lₐ₉₅₅, and L_{c} is selected from any one or any two of the group consisting of L_{c1} to L_{c360}, wherein for the specific structures of Lₐ₁ to Lₐ₉₅₅, reference is made to claim 16, and for the specific structures of L_{c1} to L_{c360}, reference is made to claim 18.

According to an embodiment of the present disclosure, wherein the metal complex has a structure of Ir(Lₐ)(L_{b})(L_{c}), Lₐ is, at each occurrence identically or differently, selected from any one of the group consisting of Lₐ₁ to Lₐ₉₅₅, L_{b} is selected from any one of the group consisting of L_{b1} to L_{b128}, and L_{c} is selected from any one of the group consisting of L_{c1} to L_{c360}, wherein for the specific structures of Lₐ₁ to Lₐ₉₅₅, reference is made to claim 16, for the specific structures of L_{b1} to L_{b128}, reference is made to claim 17, and for the specific structures of L_{c1} to L_{c360}, reference is made to claim 18.

According to an embodiment of the present disclosure, wherein the metal complex is selected from the group consisting of Compound 1 to Compound 1216, wherein for the specific structures of Compound 1 to Compound 1216, reference is made to claim 19.

According to an embodiment of the present disclosure, an electroluminescent device is disclosed, which comprises:

an anode,

a cathode, and

an organic layer disposed between the anode and the cathode, wherein the organic layer includes the metal complex described in any one of the above-mentioned embodiments.

According to an embodiment of the present disclosure, wherein the organic layer including the metal complex is an emissive layer.

According to an embodiment of the present disclosure, wherein the electroluminescent device emits green light.

According to an embodiment of the present disclosure, wherein the electroluminescent device emits white light.

According to an embodiment of the present disclosure, wherein the emissive layer of the electroluminescent device includes a first host compound.

According to an embodiment of the present disclosure, wherein the emissive layer of the electroluminescent device includes a first host compound and a second host compound.

According to an embodiment of the present disclosure, wherein the first host compound and/or the second host compound included in the electroluminescent device include at least one chemical group selected from the group consisting of: benzene, pyridine, pyrimidine, triazine, carbazole, azacarbazole, indolocarbazole, dibenzothiophene, azadibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

According to an embodiment of the present disclosure, wherein the first host compound has a structure represented by Formula 4:

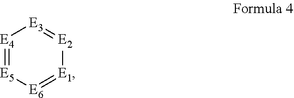

wherein

E₁ to E₆ are, at each occurrence identically or differently, selected from C, CR_{c} or N, at least two of E₁ to E₆ are N, and at least one of E₁ to E₆ is C and is attached to Formula A:

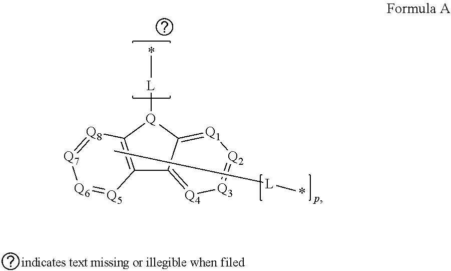

wherein,

Q is, at each occurrence identically or differently, selected from the group consisting of O, S, Se, N, NR″, CR″R″, SiR″R″, GeR″R″, and R″C═CR″; when two R″ are present, the two R″ can be the same or different;

p is 0 or 1; r is 0 or 1;

when Q is selected from N, p is 0, and r is 1;

when Q is selected from the group consisting of O, S, Se, NR″, CR″R″, SiR″R″, GeR″R″, and R″C═CR″, p is 1, and r is 0; L is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or combinations thereof;

Q₁ to Q₈ are, at each occurrence identically or differently, selected from C, CR_{q} or N;

R_{c}, R″, and R_{q} are, at each occurrence identically or differently, selected from the group consisting of hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a substituted or unsubstituted alkylgermanyl having 3 to 20 carbon atoms, a substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

“*” represents a position where Formula A is attached to Formula 4;

adjacent substituents Rₑ, R″, R_{q} can be optionally joined to form a ring.

Herein, the expression that “adjacent substituents Rₑ, R”, R_{q} can be optionally joined to form a ring″ is intended to mean that any one or more of groups of adjacent substituents, such as two substituents Rₑ, two substituents R″, two substituents R_{q}, and substituents R″ and R_{q}, can be joined to form a ring. Apparently, these substituents may not be joined to form a ring.

According to an embodiment of the present disclosure, wherein Q is, at each occurrence identically or differently, selected from O, S, N or NR″.

According to an embodiment of the present disclosure, wherein E₁ to E₆ are, at each occurrence identically or differently, selected from C, CRₑ or N, and three of E₁ to E₆ are N, at least one of E₁ to E₆ is CRₑ, and the Rₑ is, at each occurrence identically or differently, selected from the group consisting of: substituted or unsubstituted aryl having 6 to 30 carbon atoms, substituted or unsubstituted heteroaryl having 3 to 30 carbon atoms, and combinations thereof.

According to an embodiment of the present disclosure, wherein E₁ to E₆ are, at each occurrence identically or differently, selected from C, CRₑ or N, and three of E₁ to E₆ are N, at least one of E₁ to E₆ is CRₑ, and the Rₑ is, at each occurrence identically or differently, selected from the group consisting of: substituted or unsubstituted phenyl, substituted or unsubstituted biphenyl, substituted or unsubstituted terphenyl, substituted or unsubstituted naphthyl, substituted or unsubstituted phenanthryl, substituted or unsubstituted triphenylenyl, substituted or unsubstituted fluorenyl, substituted or unsubstituted dibenzofuryl, substituted or unsubstituted dibenzothiophenyl, substituted or unsubstituted carbazolyl, and combinations thereof.

According to an embodiment of the present disclosure, wherein Rₑ is, at each occurrence identically or differently, selected from the group consisting of: substituted or unsubstituted aryl having 6 to 30 carbon atoms, substituted or unsubstituted heteroaryl having 3 to 30 carbon atoms, and combinations thereof.

According to an embodiment of the present disclosure, wherein Rₑ is, at each occurrence identically or differently, selected from the group consisting of: substituted or unsubstituted phenyl, substituted or unsubstituted biphenyl, substituted or unsubstituted terphenyl, substituted or unsubstituted naphthyl, substituted or unsubstituted phenanthryl, substituted or unsubstituted triphenylenyl, substituted or unsubstituted fluorenyl, substituted or unsubstituted dibenzofuryl, substituted or unsubstituted dibenzothiophenyl, substituted or unsubstituted carbazolyl, and combinations thereof.

According to an embodiment of the present disclosure, wherein at least one or at least two of Q₁ to Q₈ is(are) selected from CR_{q}, and the R_{q} is selected from substituted or unsubstituted aryl having 6 to 30 carbon atoms, substituted or unsubstituted heteroaryl having 5 to 30 carbon atoms or combinations thereof.

According to an embodiment of the present disclosure, wherein at least one or at least two of Q₁ to Q₈ is(are) selected from CR_{q}, and the R_{q} is selected from substituted or unsubstituted phenyl, substituted or unsubstituted naphthyl, substituted or unsubstituted biphenyl, substituted or unsubstituted terphenyl, substituted or unsubstituted pyridyl or combinations thereof.

According to an embodiment of the present disclosure, wherein L is, at each occurrence identically or differently, selected from a single bond, substituted or unsubstituted arylene having 6 to 20 carbon atoms, substituted or unsubstituted heteroarylene having 3 to 20 carbon atoms or combinations thereof.

According to an embodiment of the present disclosure, wherein L is, at each occurrence identically or differently, selected from a single bond, substituted or unsubstituted phenylene, substituted or unsubstituted biphenylene, substituted or unsubstituted carbazolylene, substituted or unsubstituted dibenzofuranylene, substituted or unsubstituted dibenzothiophenylene or substituted or unsubstituted fluorenylene.

According to an embodiment of the present disclosure, wherein L is, at each occurrence identically or differently, selected from a single bond, substituted or unsubstituted phenylene or substituted or unsubstituted biphenylene.

According to an embodiment of the present disclosure, wherein the first host compound is selected from the group consisting of H-1 to H-243, wherein for the specific structures of H-1 to H-243, reference is made to claim 26.

According to an embodiment of the present disclosure, wherein the second host compound in the electroluminescent device has a structure represented by Formula 5:

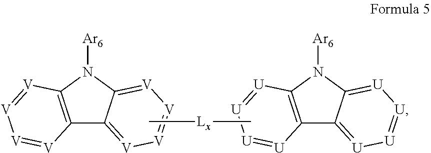

wherein,

Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or combinations thereof;

V is, at each occurrence identically or differently, selected from C, CRᵥ or N, and at least one of V is C and is attached to Lₓ;

U is, at each occurrence identically or differently, selected from C, CRᵤ or N, and at least one of U is C and is attached to Lₓ;

Rᵥ and Rᵤ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a substituted or unsubstituted alkylgermanyl having 3 to 20 carbon atoms, a substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,

Ar₆ is, at each occurrence identically or differently, selected from substituted or unsubstituted aryl having 6 to 30 carbon atoms, substituted or unsubstituted heteroaryl having 3 to 30 carbon atoms or combinations thereof,

adjacent substituents Rᵥ and Rᵤ can be optionally joined to form a ring.

In this embodiment, the expression that “adjacent substituents Rᵥ and Rᵤ can be optionally joined to form” a ring is intended to mean that any one or more of groups of adjacent substituents, such as two substituents Rᵥ, two substituents Rᵤ, and substituents Rᵥ and Rᵤ, can be joined to form a ring. Apparently, these substituents may not be joined to form a ring.

According to an embodiment of the present disclosure, wherein the second host compound in the electroluminescent device has a structure represented by one of Formula 5-a to Formula 5-j:

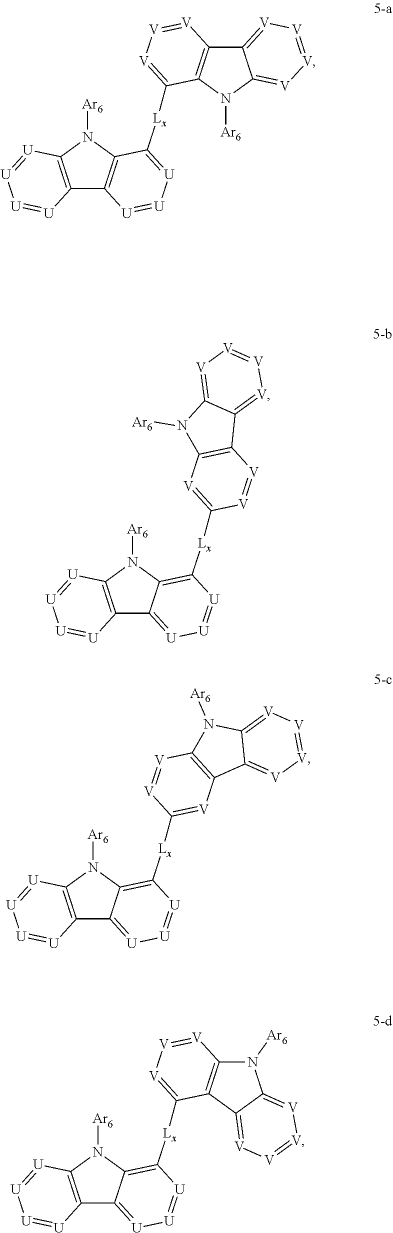

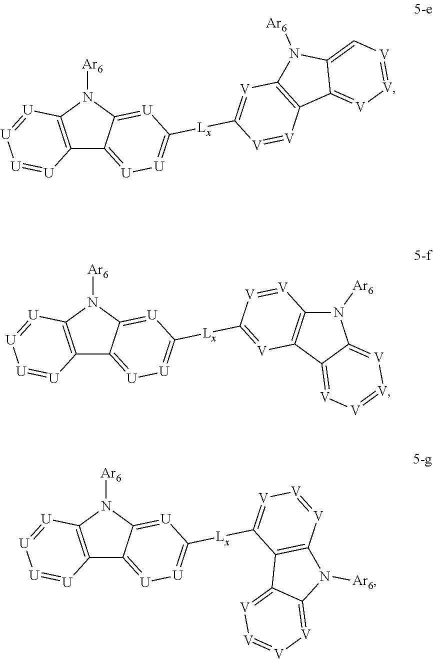

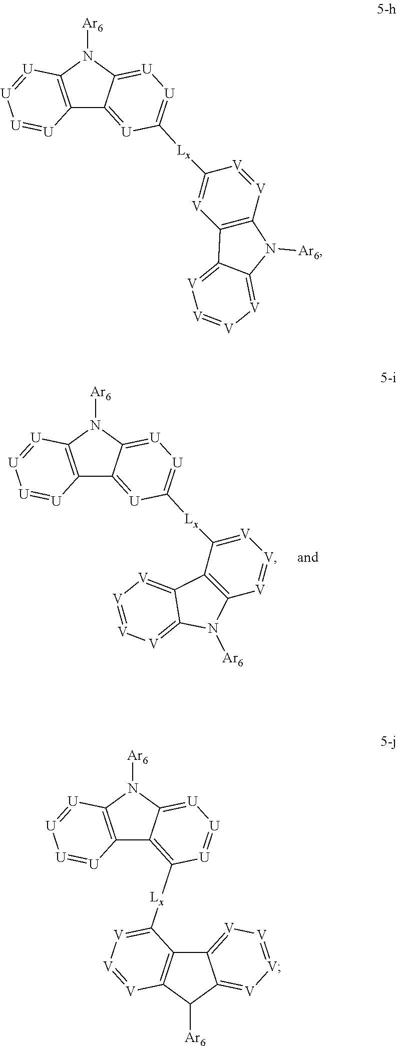

wherein,

Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or combinations thereof,

V is, at each occurrence identically or differently, selected from CRᵥ or N;

U is, at each occurrence identically or differently, selected from CRᵤ or N;

Rᵥ and Rᵤ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a substituted or unsubstituted alkylgermanyl having 3 to 20 carbon atoms, a substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,

Ar₆ is, at each occurrence identically or differently, selected from substituted or unsubstituted aryl having 6 to 30 carbon atoms, substituted or unsubstituted heteroaryl having 3 to 30 carbon atoms or combinations thereof, adjacent substituents R, and Rᵤ can be optionally joined to form a ring.

According to an embodiment of the present disclosure, wherein the second host compound is selected from the group consisting of X-1 to X-128, wherein for the specific structures of X-1 to X-128, reference is made to claim 28.

According to an embodiment of the present disclosure, wherein in the electroluminescent device, the metal complex is doped in the first host compound and the second host compound, and the weight of the metal complex accounts for 1% to 30% of the total weight of the emissive layer.

According to an embodiment of the present disclosure, wherein in the electroluminescent device, the metal complex is doped in the first host compound and the second host compound, and the weight of the metal complex accounts for 3% to 13% of the total weight of the emissive layer.

According to another embodiment of the present disclosure, a compound combination is further disclosed. The compound combination includes the metal complex described in any one of the above-mentioned embodiments.

Combination with Other Materials

The materials described in the present disclosure for a particular layer in an organic light-emitting device can be used in combination with various other materials present in the device. The combinations of these materials are described in more detail in U.S. Pat. App. No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light-emitting device may be used in combination with a variety of other materials present in the device. For example, dopants disclosed herein may be used in combination with a wide variety of hosts, transport layers, blocking layers, injection layers, electrodes and other layers that may be present. The combination of these materials is described in detail in paragraphs 0080-0101 of U.S. Pat. App. No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. In the embodiments of the device, the characteristics of the device were also tested using conventional equipment in the art (including, but not limited to, evaporator produced by ANGSTROM ENGINEERING optical testing system produced by SUZHOU FATAR, life testing system produced by SUZHOU FATAR, and ellipsometer produced by BEIJING ELLITOP, etc.) by methods well known to the persons skilled in the art. As the persons skilled in the art are aware of the above-mentioned equipment use, test methods and other related contents, the inherent data of the sample can be obtained with certainty and without influence, so the above related contents are not further described in this patent.

### Material Synthesis Example

The method for preparing a compound of the present disclosure is not limited herein. Typically, the following compounds are taken as examples without limitations, and synthesis routes and preparation methods thereof are described below.

### Synthesis Example 1: Synthesis of Metal Complex 151

Step 1:

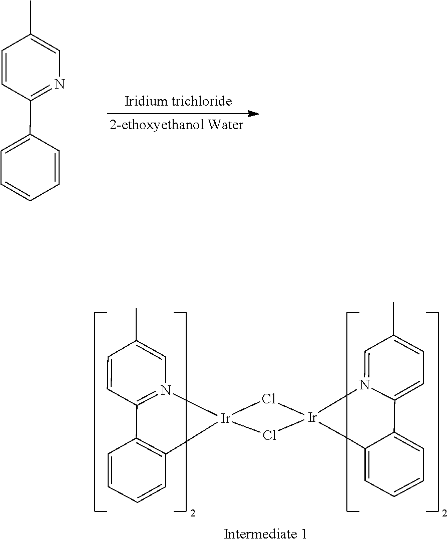

5-methyl-2-phenylpyridine (10.0 g, 59.2 mmol), iridium(III) chloride trihydrate (5.0 g, 14.2 mmol), 300 mL of 2-ethoxyethanol and 100 mL of water were sequentially added into a dry 500 mL round-bottom flask, purged with nitrogen three times, and the reaction was heated and stirred at 130° C. for 24 hours under nitrogen protection. The reaction product was cooled, filtered, washed three times with methanol and n-hexane separately, and suction-dried to give 7.5 g of Intermediate 1 as a yellow solid (with a yield of 97%).

Step 2:

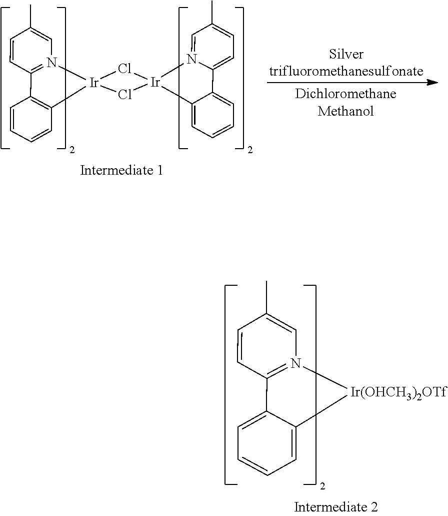

Intermediate 1 (7.5 g, 6.8 mmol), 250 mL of anhydrous dichloromethane, 10 mL of methanol and silver trifluoromethanesulfonate (3.8 g, 14.8 mmol) were sequentially added into a dry 500 mL round-bottom flask, purged with nitrogen three times, and the reaction was stirred overnight at room temperature under nitrogen protection. The reaction product was filtered through Celite and washed twice with dichloromethane. The lower organic phases were collected and concentrated under reduced pressure to give 9.2 g of Intermediate 2 (with a yield of 93%).

Step 3:

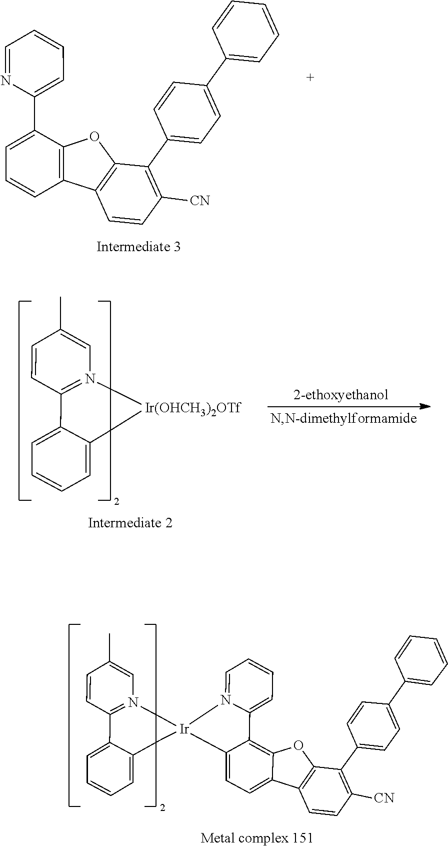

Intermediate 2 (2.2 g, 3.0 mmol), Intermediate 3 (1.7 g, 3.9 mmol), 50 mL of 2-ethoxyethanol and 50 mL of N,N-dimethylformamide were sequentially added into a dry 250 mL round-bottom flask, purged with nitrogen three times, and the reaction was heated at 100° C. for 96 hours under nitrogen protection. After the reaction was cooled, the reaction product was filtered through Celite and washed twice with methanol and n-hexane separately. Yellow solids above the Celite were dissolved with dichloromethane. The organic phases were collected, concentrated under reduced pressure, and purified by column chromatography to give Metal complex 151 as a yellow solid (1.3 g with a yield of 45.6%). The product was confirmed as the target product with a molecular weight of 950.3.

### Synthesis Example 2: Synthesis of Metal Complex 186

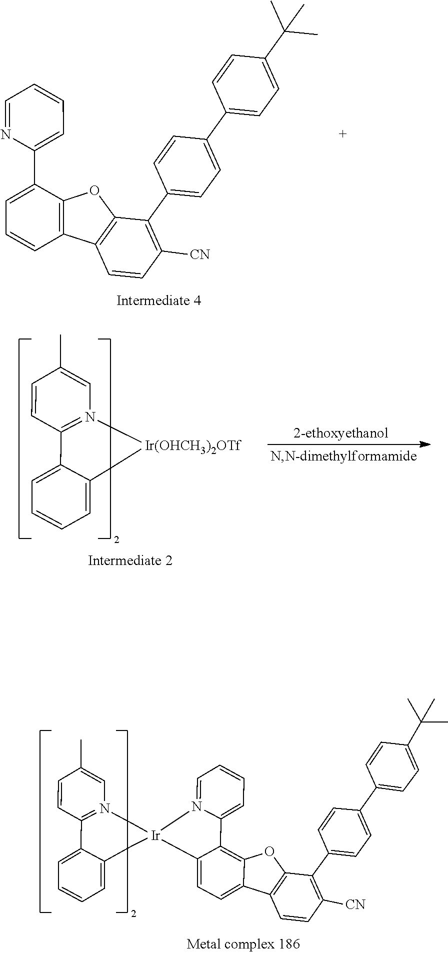

Intermediate 2 (2.0 g, 2.8 mmol), Intermediate 4 (1.8 g, 3.9 mmol), 50 mL of 2-ethoxyethanol and 50 mL of N,N-dimethylformamide were sequentially added into a dry 250 mL round-bottom flask, purged with nitrogen three times, and the reaction was heated at 100° C. for 72 hours under nitrogen protection. After the reaction was cooled, the reaction product was filtered through Celite and washed twice with methanol and n-hexane separately. Yellow solids above the Celite were dissolved with dichloromethane. The organic phases were collected, concentrated under reduced pressure, and purified by column chromatography to give Metal complex 186 as a yellow solid (1.2 g with a yield of 43.4%). The product was confirmed as the target product with a molecular weight of 1006.3.

### Synthesis Example 3: Synthesis of Metal Complex 243

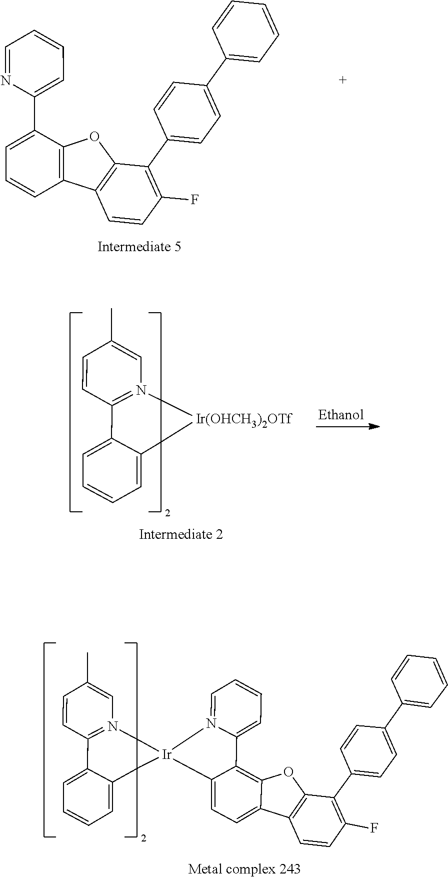

Intermediate 2 (2.6 g, 3.5 mmol), Intermediate 5 (2.2 g, 5.3 mmol) and 250 mL of ethanol were sequentially added into a dry 500 mL round-bottom flask, purged with nitrogen three times, and the reaction was heated at 100° C. for 18 hours under nitrogen protection. After the reaction was cooled, the reaction product was filtered through Celite washed twice with methanol and n-hexane separately. Yellow solids above the Celite were dissolved with dichloromethane. The organic phases were collected, concentrated under reduced pressure, and purified by column chromatography to give Metal complex 243 as a yellow solid (1.1 g with a yield of 33.3%). The product was confirmed as the target product with a molecular weight of 943.2.

### Synthesis Example 4: Synthesis of Metal Complex 467

Step 1:

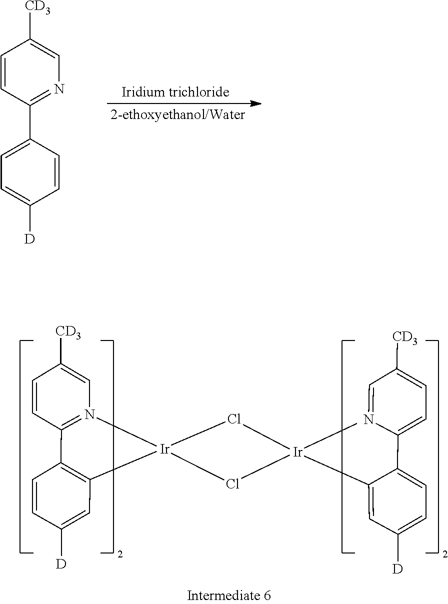

4-(methyl-d₃)-2-phenylpyridine-5-d (5.0 g, 28.9 mmol), iridium trichloride trihydrate (2.6 g, 7.4 mmol), 2-ethoxyethanol (60 mL) and water (20 mL) were sequentially added into a dry 250 mL round-bottom flask, and the reaction was heated to reflux and stirred for 24 hours under nitrogen protection. The reaction product was cooled, filtered by suction under reduced pressure, and washed three times with methanol and n-hexane separately to give 4.0 g of Intermediate 6 as a yellow solid (with a yield of 94.8%).

Step 2:

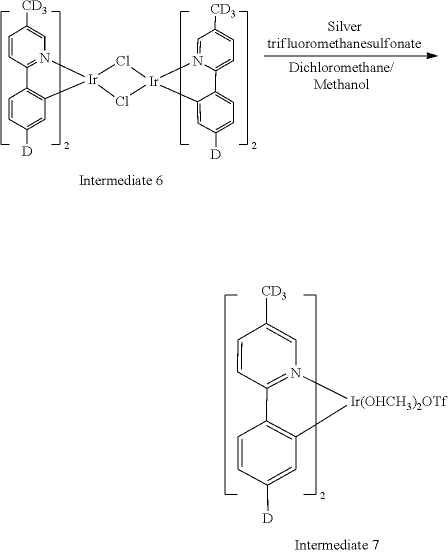

Intermediate 6 (4.0 g, 3.5 mmol), anhydrous dichloromethane (250 mL), methanol (10 mL), and silver trifluoromethanesulfonate (1.9 g, 7.6 mmol) were sequentially added into a dry 500 mL round-bottom flask, purged with nitrogen three times, and the reaction was stirred overnight at room temperature under nitrogen protection. The reaction product was filtered through Celite and washed twice with dichloromethane. The lower organic phases were collected and concentrated under reduced pressure to give 5.1 g of Intermediate 7 (with a yield of 97.4%).

Step 3:

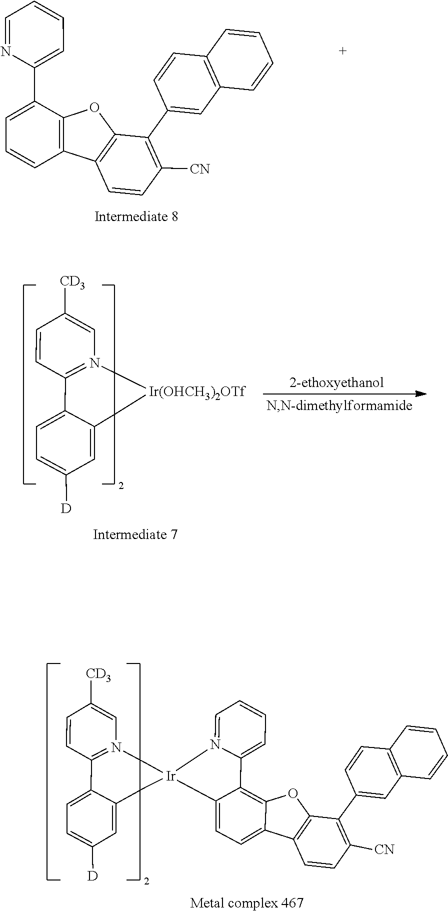

Intermediate 8 (1.5 g, 3.7 mmol), Intermediate 7 (2.1 g, 2.2 mmol), 50 mL of N,N-dimethylformamide and 50 mL of 2-ethoxyethanol were sequentially added into a dry 250 mL round-bottom flask and the reaction was heated to reflux to react for 96 hours under N₂ protection. After the reaction was cooled, the reaction product was filtered through Celite washed twice with methanol and n-hexane separately. Yellow solids above the Celite were dissolved with dichloromethane. The organic phases were collected, concentrated under reduced pressure, and purified by column chromatography to give Metal complex 467 as a yellow solid (0.82 g with a yield of 40.0%). The product was confirmed as the target product with a molecular weight of 932.3.

### Synthesis Example 5: Synthesis of Metal Complex 601

Step 1:

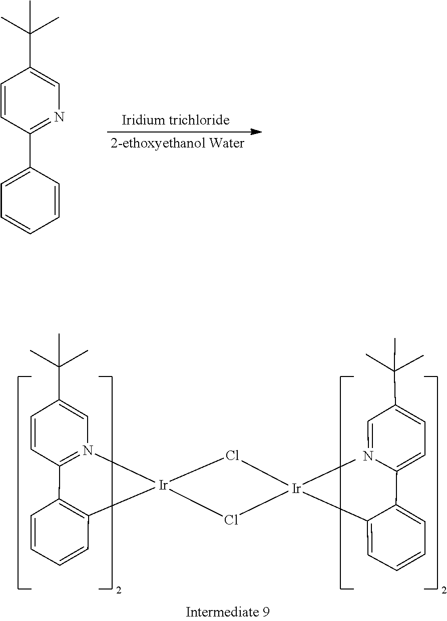

5-t-butyl-2-phenylpyridine (13.2 g, 62.9 mmol), iridium(III) chloride trihydrate (5.5 g, 15.7 mmol), 300 mL of 2-ethoxyethanol and 100 mL of water were sequentially added into a dry 500 mL round-bottom flask, purged with nitrogen three times, and the reaction was heated and stirred at 130° C. for 24 hours under nitrogen protection. The reaction product was cooled, filtered, washed three times with methanol and n-hexane separately, and suction-dried to give 9.7 g of Intermediate 9 (with a yield of 97%).

Step 2:

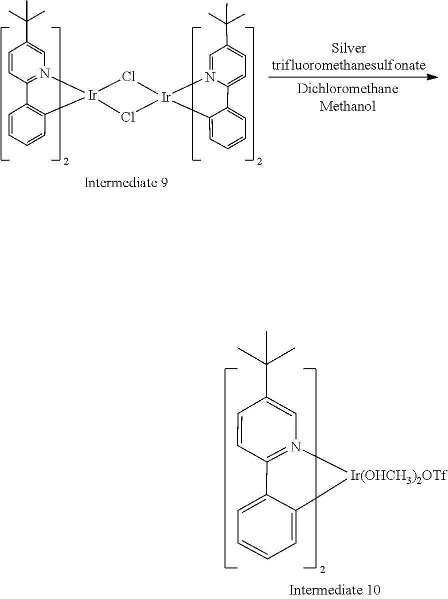

Intermediate 9 (9.7 g, 7.7 mmol), 250 mL of anhydrous dichloromethane, 10 mL of methanol and silver trifluoromethanesulfonate (4.3 g, 16.7 mmol) were sequentially added into a dry 500 mL round-bottom flask, purged with nitrogen three times, and the reaction was stirred overnight at room temperature under nitrogen protection. The reaction product was filtered through Celite and washed twice with dichloromethane. The lower organic phases were collected and concentrated under reduced pressure to give 13.2 g of Intermediate 10 (with a yield of 93%).

Step 3:

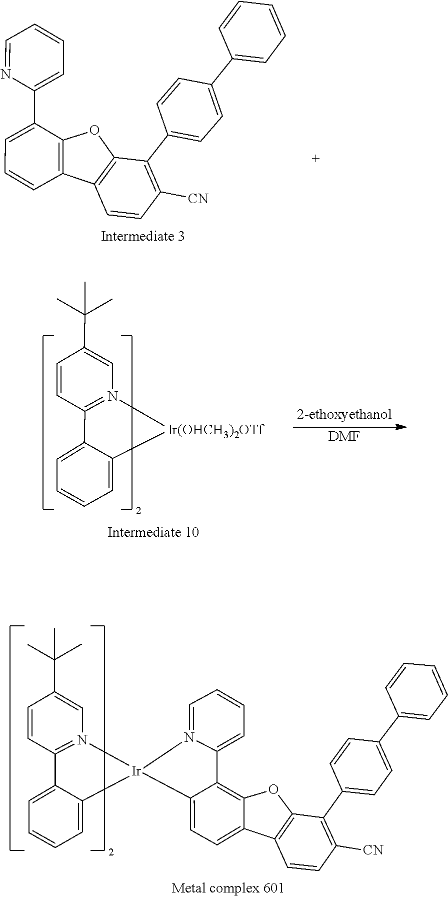

Intermediate 10 (1.4 g, 1.7 mmol), Intermediate 3 (1.0 g, 2.4 mmol), 50 mL of 2-ethoxyethanol and 50 mL of N,N-dimethylformamide were sequentially added into a dry 250 mL round-bottom flask, purged with nitrogen three times, and the reaction was heated at 100° C. for 72 hours under nitrogen protection. After the reaction was cooled, the reaction product was filtered through Celite washed twice with methanol and n-hexane separately. Yellow solids above the Celite were dissolved with dichloromethane. The organic phases were collected, concentrated under reduced pressure, and purified by column chromatography to give Metal complex 601 as a yellow solid (0.5 g with a yield of 28.4%). The product was confirmed as the target product with a molecular weight of 1034.3.

### Synthesis Example 6: Synthesis of Metal Complex 604

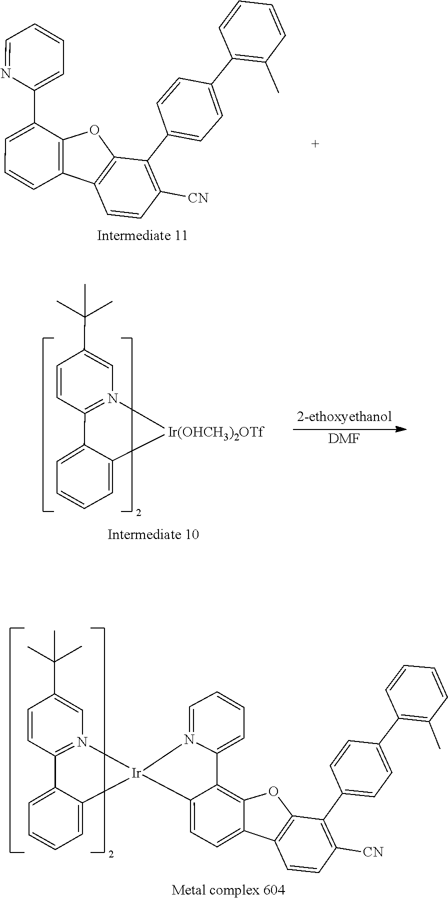

Intermediate 10 (2.4 g, 2.9 mmol), Intermediate 11 (1.5 g, 3.4 mmol), 50 mL of 2-ethoxyethanol and 50 mL of N,N-dimethylformamide were sequentially added into a dry 250 mL round-bottom flask, purged with nitrogen three times, and the reaction was heated at 100° C. for 72 hours under nitrogen protection. After the reaction was cooled, the reaction product was filtered through Celite washed twice with methanol and n-hexane separately. Yellow solids above the Celite were dissolved with dichloromethane. The organic phases were collected, concentrated under reduced pressure, and purified by column chromatography to give Metal complex 604 as a yellow solid (0.7 g with a yield of 23.0%). The product was confirmed as the target product with a molecular weight of 1048.4.

### Synthesis Example 7: Synthesis of Metal Complex 610

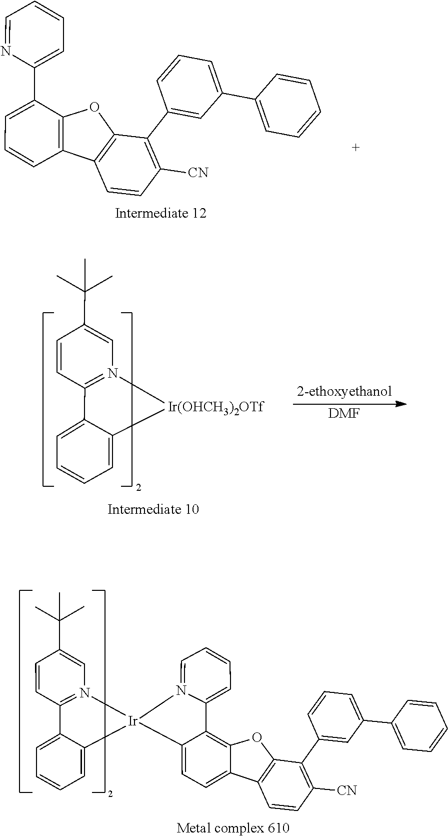

Intermediate 10 (2.2 g, 2.7 mmol), Intermediate 12 (1.5 g, 3.6 mmol), 50 mL of 2-ethoxyethanol and 50 mL of N,N-dimethylformamide were sequentially added into a dry 250 mL round-bottom flask, purged with nitrogen three times, and the reaction was heated at 100° C. for 72 hours under nitrogen protection. After the reaction was cooled, the reaction product was filtered through Celite washed twice with methanol and n-hexane separately. Yellow solids above the Celite were dissolved with dichloromethane. The organic phases were collected, concentrated under reduced pressure, and purified by column chromatography to give Metal complex 610 as a yellow solid (0.8 g with a yield of 30.7%). The product was confirmed as the target product with a molecular weight of 1034.3.

### Synthesis Example 8: Synthesis of Metal Complex 646

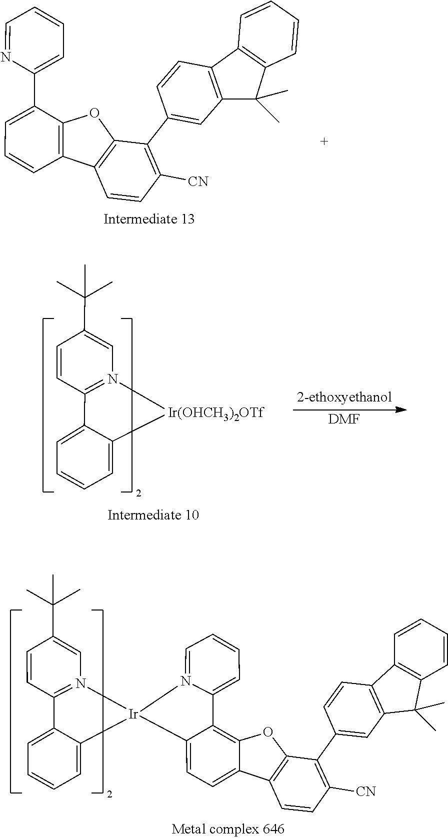

Intermediate 10 (2.5 g, 3.0 mmol), Intermediate 13 (1.8 g, 3.9 mmol), 50 mL of 2-ethoxyethanol and 50 mL of N,N-dimethylformamide were sequentially added into a dry 250 mL round-bottom flask, purged with nitrogen three times, and the reaction was heated at 100° C. for 72 hours under nitrogen protection. After the reaction was cooled, the reaction product was filtered through Celite washed twice with methanol and n-hexane separately. Yellow solids above the Celite were dissolved with dichloromethane. The organic phases were collected, concentrated under reduced pressure, and purified by column chromatography to give Metal complex 646 as a yellow solid (1.45 g with a yield of 44.4%). The product was confirmed as the target product with a molecular weight of 1074.4.

### Synthesis Example 9: Synthesis of Metal Complex 613

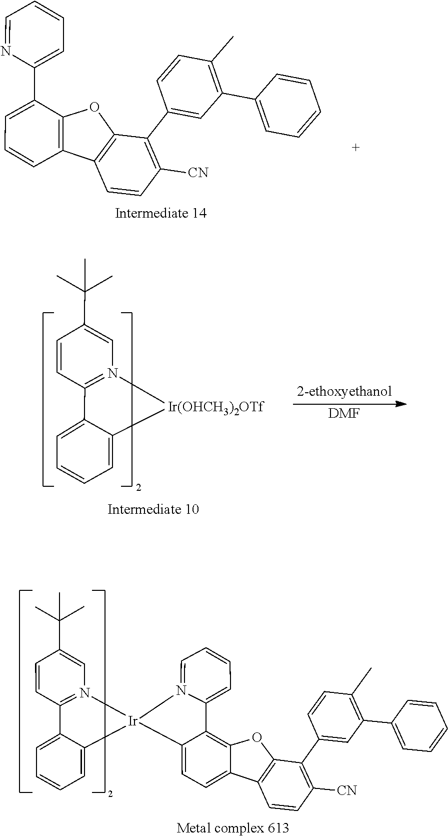

Intermediate 10 (1.9 g, 2.3 mmol), Intermediate 14 (1.1 g, 2.5 mmol), 50 mL of 2-ethoxyethanol and 50 mL of N,N-dimethylformamide were sequentially added into a dry 250 mL round-bottom flask, purged with nitrogen three times, and the reaction was heated at 100° C. for 72 hours under nitrogen protection. After the reaction was cooled, the reaction product was filtered through Celite washed twice with methanol and n-hexane separately. Yellow solids above the Celite were dissolved with dichloromethane. The organic phases were collected, concentrated under reduced pressure, and purified by column chromatography to give Metal complex 613 as a yellow solid (0.68 g with a yield of 28.2%). The product was confirmed as the target product with a molecular weight of 1048.4.

### Synthesis Example 10: Synthesis of Metal Complex 636

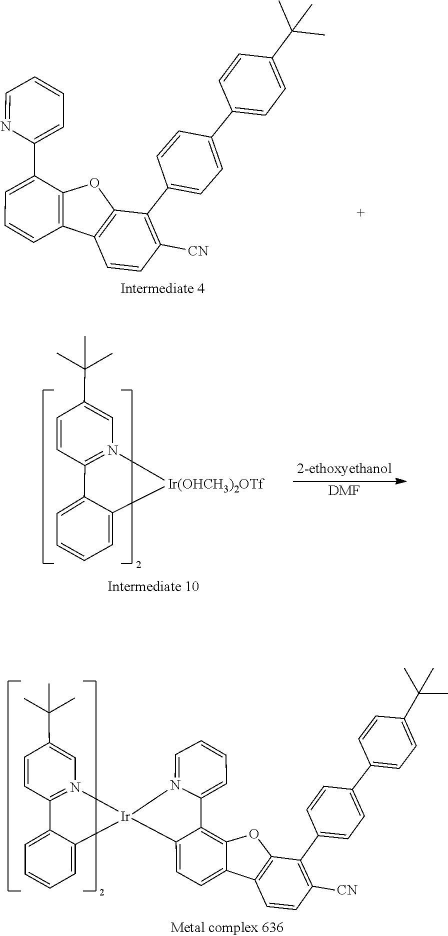

Intermediate 10 (3.1 g, 3.7 mmol), Intermediate 4 (2.1 g, 4.5 mmol), 50 mL of 2-ethoxyethanol and 50 mL of N,N-dimethylformamide were sequentially added into a dry 250 mL round-bottom flask, purged with nitrogen three times, and the reaction was heated at 100° C. for 72 hours under nitrogen protection. After the reaction was cooled, the reaction product was filtered through Celite washed twice with methanol and n-hexane separately. Yellow solids above the Celite were dissolved with dichloromethane. The organic phases were collected, concentrated under reduced pressure, and purified by column chromatography to give Metal complex 636 as a yellow solid (0.8 g with a yield of 19.8%). The product was confirmed as the target product with a molecular weight of 1090.4.

### Synthesis Example 11: Synthesis of Metal Complex 693

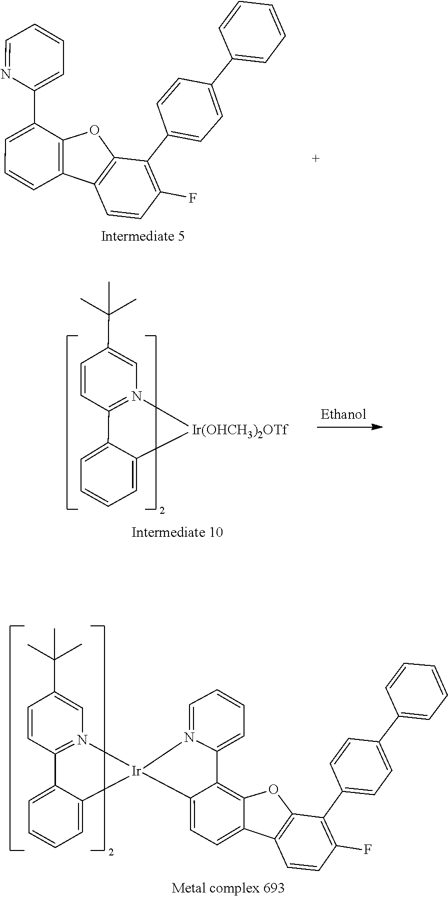

Intermediate 10 (2.1 g, 2.6 mmol), Intermediate 5 (1.5 g, 3.6 mmol) and 300 mL of ethanol were sequentially added into a dry 500 mL round-bottom flask, purged with nitrogen three times, and the reaction was heated at 100° C. for 24 hours under nitrogen protection. After the reaction was cooled, the reaction product was filtered through Celite washed twice with methanol and n-hexane separately. Yellow solids above the Celite were dissolved with dichloromethane. The organic phases were collected, concentrated under reduced pressure, and purified by column chromatography to give Metal complex 693 as a yellow solid (1.30 g with a yield of 48.7%). The product was confirmed as the target product with a molecular weight of 1027.3.

### Synthesis Example 12: Synthesis of Metal Complex 751

Step 1:

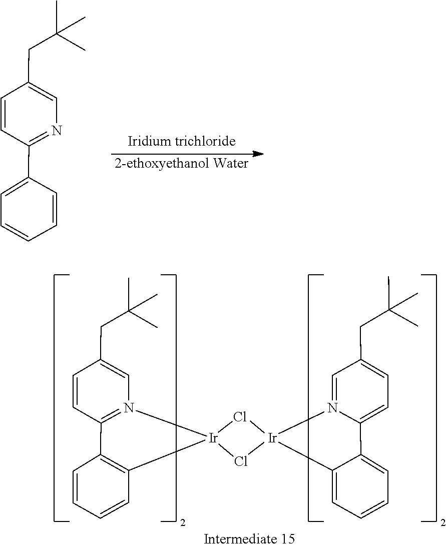

5-neopentyl-2-phenylpyridine (13.4 g, 59.1 mmol), iridium(III) chloride trihydrate (5.2 g, 14.8 mmol), 300 mL of 2-ethoxyethanol and 100 mL of water were sequentially added into a dry 500 mL round-bottom flask, purged with nitrogen three times, and the reaction was heated and stirred at 130° C. for 24 hours under nitrogen protection. The reaction product was cooled, filtered, washed three times with methanol and n-hexane separately, and suction-dried to give 8.5 g of Intermediate 15 (with a yield of 88%).

Step 2:

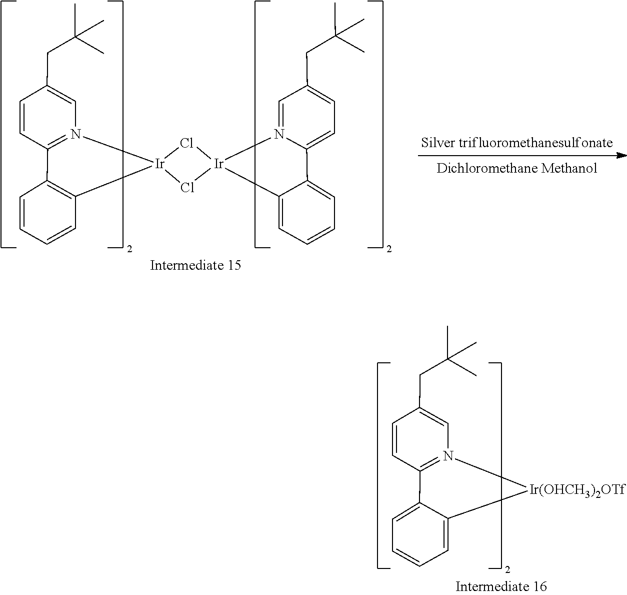

Intermediate 15 (9.7 g, 7.7 mmol), 250 mL of anhydrous dichloromethane, 10 mL of methanol and silver trifluoromethanesulfonate (4.3 g, 16.7 mmol) were sequentially added into a dry 500 mL round-bottom flask, purged with nitrogen three times, and the reaction was stirred overnight at room temperature under nitrogen protection. The reaction product was filtered through Celite and washed twice with dichloromethane. The lower organic phases were collected and concentrated under reduced pressure to give 11.8 g of Intermediate 16 (with a yield of 100%).

Step 3:

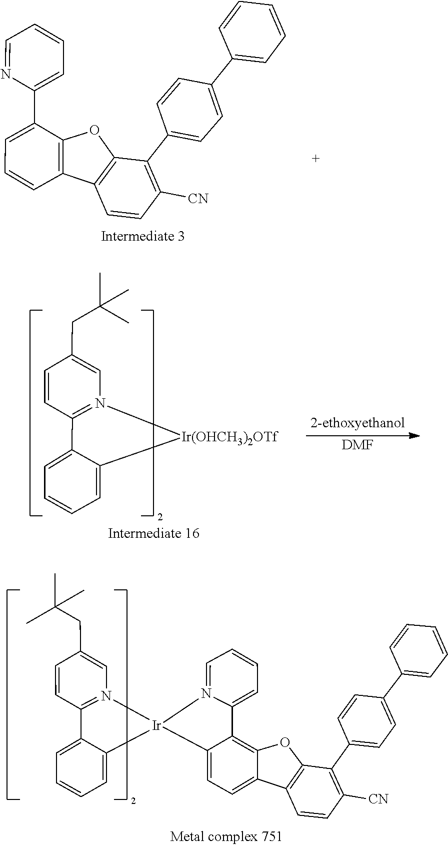

Intermediate 16 (2.0 g, 2.3 mmol), Intermediate 3 (1.4 g, 3.2 mmol), 50 mL of 2-ethoxyethanol and 50 mL of N,N-dimethylformamide were sequentially added into a dry 250 mL round-bottom flask, purged with nitrogen three times, and the reaction was heated at 100° C. for 72 hours under nitrogen protection. After the reaction was cooled, the reaction product was filtered through Celite washed twice with methanol and n-hexane separately. Yellow solids above the Celite were dissolved with dichloromethane. The organic phases were collected, concentrated under reduced pressure, and purified by column chromatography to give Metal complex 751 as a yellow solid (0.8 g with a yield of 32.7%). The product was confirmed as the target product with a molecular weight of 1062.4.

### Synthesis Example 13: Synthesis of Metal Complex 670

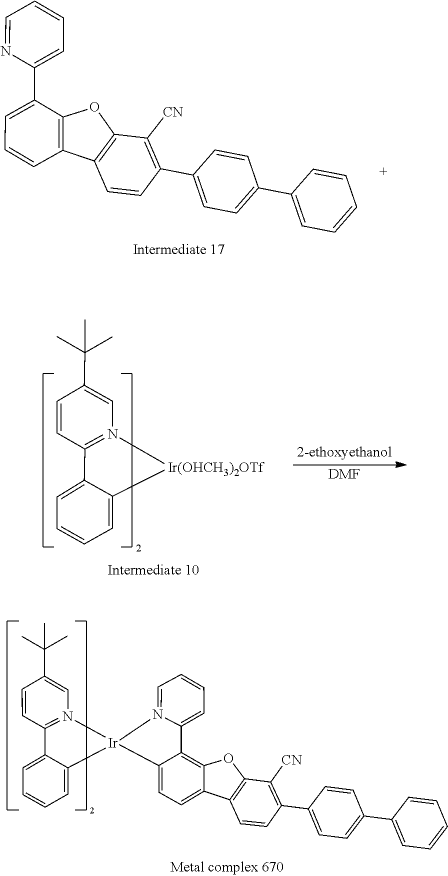

Intermediate 10 (3.0 g, 3.6 mmol), Intermediate 17 (2.7 g, 6.4 mmol), 50 mL of 2-ethoxyethanol and 50 mL of N,N-dimethylformamide were sequentially added into a dry 250 mL round-bottom flask, purged with nitrogen three times, and the reaction was heated at 100° C. for 72 hours under nitrogen protection. After the reaction was cooled, the reaction product was filtered through Celite washed twice with methanol and n-hexane separately. Yellow solids above the Celite were dissolved with dichloromethane. The organic phases were collected, concentrated under reduced pressure, and purified by column chromatography to give Metal complex 670 as a yellow solid (2.7 g with a yield of 72.5%). The product was confirmed as the target product with a molecular weight of 1034.3.

### Synthesis Example 14: Synthesis of Metal Complex 1217

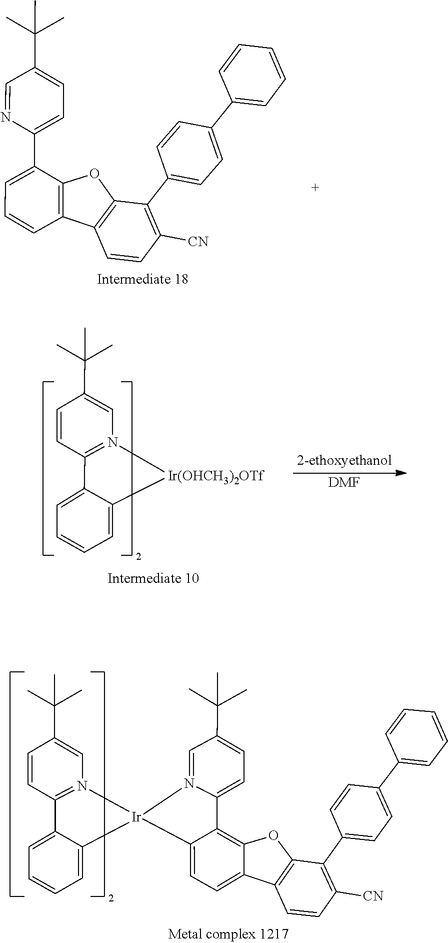

Intermediate 10 (0.8 g, 1.0 mmol), Intermediate 18 (0.6 g, 1.2 mmol), 40 mL of 2-ethoxyethanol and 40 mL of N,N-dimethylformamide were sequentially added into a dry 250 mL round-bottom flask, purged with nitrogen three times, and the reaction was heated at 100° C. for 72 hours under nitrogen protection. After the reaction was cooled, the reaction product was filtered through Celite washed twice with methanol and n-hexane separately. Yellow solids above the Celite were dissolved with dichloromethane. The organic phases were collected, concentrated under reduced pressure, and purified by column chromatography to give Metal complex 1217 as a yellow solid (0.2 g with a yield of 18.3%). The product was confirmed as the target product with a molecular weight of 1090.4.

### Synthesis Example 15: Synthesis of Metal Complex 697

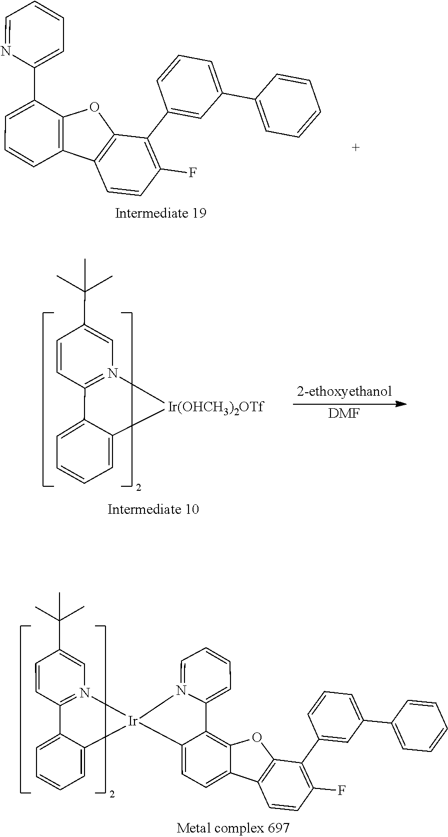

Intermediate 19 (1.6 g, 3.9 mmol), Intermediate 10 (2.5 g, 3.0 mmol), 40 mL of 2-ethoxyethanol and 40 mL of N,N-dimethylformamide were sequentially added into a dry 500 mL round-bottom flask, purged with nitrogen three times, and the reaction was heated at 100° C. for 72 hours under nitrogen protection. After the reaction was cooled, the reaction product was filtered through Celite washed twice with methanol and n-hexane separately. Yellow solids above the Celite were dissolved with dichloromethane. The organic phases were collected, concentrated under reduced pressure, and purified by column chromatography to give Metal complex 697 as a yellow solid (1.08 g with a yield of 35.0%). The product was confirmed as the target product with a molecular weight of 1027.3.

The persons skilled in the art will appreciate that the above preparation methods are merely examples. The persons skilled in the art can obtain other compound structures of the present disclosure through the modifications of the preparation methods.

### Device Example 1-1

First, a glass substrate having an indium tin oxide (ITO) anode with a thickness of 80 nm was cleaned and then treated with oxygen plasma and UV ozone. After the treatment, the substrate was dried in a glovebox to remove moisture. Next, the substrate was mounted on a substrate holder and placed in a vacuum chamber. Organic layers specified below were sequentially deposited through vacuum thermal evaporation on the ITO anode at a rate of 0.2 to 2 Angstroms per second at a vacuum degree of about 10⁻⁸ torr. Compound HI was deposited as a hole injection layer (TIL). Compound HT was deposited as a hole transport layer (HTL). Compound X-4 was deposited as an electron blocking layer (EBL). Metal complex 151 of the present disclosure was doped in Compound X-4 and Compound H-91 and they were co-deposited as an emissive layer (EML). On the EML, Compound H-1 was deposited as a hole blocking layer (HBL). On the HBL, Compound ET and 8-hydroxyquinolinolato-lithium (Liq) were co-deposited as an electron transport layer (ETL). Finally, 8-hydroxyquinolinolato-lithium (Liq) with a thickness of 1 nm was deposited as an electron injection layer, and Al with a thickness of 120 nm was deposited as a cathode. The device was transferred back to the glovebox and encapsulated with a glass lid and a moisture absorbent to complete the device.

### Device Example 1-2

The implementation mode in Device Example 1-2 was the same as that in Device Example 1-1, except that Metal complex 151 of the present disclosure in the EML was replaced with Metal complex 186 of the present disclosure.

### Device Example 2-1

The implementation mode in Device Example 2-1 was the same as that in Device Example 1-1, except that Metal complex 151 of the present disclosure in the EML was replaced with Metal complex 467 of the present disclosure.

### Device Example 3-1

The implementation mode in Device Example 3-1 was the same as that in Device Example 1-1, except that Metal complex 151 of the present disclosure in the EML was replaced with Metal complex 601 of the present disclosure.

### Device Example 3-2

The implementation mode in Device Example 3-2 was the same as that in Device Example 1-1, except that Metal complex 151 of the present disclosure in the EML was replaced with Metal complex 604 of the present disclosure.

### Device Example 3-3

The implementation mode in Device Example 3-3 was the same as that in Device Example 1-1, except that Metal complex 151 of the present disclosure in the EML was replaced with Metal complex 610 of the present disclosure.

### Device Example 3-4

The implementation mode in Device Example 3-4 was the same as that in Device Example 1-1, except that Metal complex 151 of the present disclosure in the EML was replaced with Metal complex 646 of the present disclosure.

### Device Example 3-5

The implementation mode in Device Example 3-5 was the same as that in Device Example 1-1, except that Metal complex 151 of the present disclosure in the EML was replaced with Metal complex 613 of the present disclosure.

### Device Example 3-6

The implementation mode in Device Example 3-6 was the same as that in Device Example 1-1, except that Metal complex 151 of the present disclosure in the EML was replaced with Metal complex 636 of the present disclosure.

### Device Example 3-7

The implementation mode in Device Example 3-7 was the same as that in Device Example 1-1, except that Metal complex 151 of the present disclosure in the EML was replaced with Metal complex 1217 of the present disclosure.

### Device Example 4-1

The implementation mode in Device Example 4-1 was the same as that in Device Example 1-1, except that Metal complex 151 of the present disclosure in the EML was replaced with Metal complex 751 of the present disclosure.

### Device Example 5-1

The implementation mode in Device Example 5-1 was the same as that in Device Example 1-1, except that Metal complex 151 of the present disclosure in the EML was replaced with Metal complex 243 of the present disclosure.

### Device Example 6-1

The implementation mode in Device Example 6-1 was the same as that in Device Example 1-1, except that Metal complex 151 of the present disclosure in the EML was replaced with Metal complex 693 of the present disclosure.

### Device Example 6-2

The implementation mode in Device Example 6-2 was the same as that in Device Example 1-1, except that Metal complex 151 of the present disclosure in the EML was replaced with Metal complex 697 of the present disclosure.

### Device Comparative Example 1-1

The implementation mode in Device Comparative Example 1-1 was the same as that in Device Example 1-1, except that Metal complex 151 of the present disclosure in the emissive layer (EML) was replaced with Compound GD1.

### Device Comparative Example 2-1

The implementation mode in Device Comparative Example 2-1 was the same as that in Device Example 1-1, except that Metal complex 151 of the present disclosure in the emissive layer (EML) was replaced with Compound GD2.

### Device Comparative Example 3-1

The implementation mode in Device Comparative Example 3-1 was the same as that in Device Example 1-1, except that Metal complex 151 of the present disclosure in the emissive layer (EML) was replaced with Compound GD3.

### Device Comparative Example 4-1

The implementation mode in Device Comparative Example 4-1 was the same as that in Device Example 1-1, except that Metal complex 151 of the present disclosure in the emissive layer (EML) was replaced with Compound GD4.

### Device Comparative Example 5-1

The implementation mode in Device Comparative Example 5-1 was the same as that in Device Example 1-1, except that Metal complex 151 of the present disclosure in the emissive layer (EML) was replaced with Compound GD5.

### Device Comparative Example 6-1

The implementation mode in Device Comparative Example 6-1 was the same as that in Device Example 1-1, except that Metal complex 151 of the present disclosure in the emissive layer (EML) was replaced with Compound GD6.

Detailed structures and thicknesses of layers of the devices are shown in the following table. The layers using more than one material were obtained by doping different compounds at a weight ratio as recorded in the following table.

TABLE 1
Device structures in Examples and Comparative Examples

| Device ID | HIL | HTL | EBL | EML | HBL | ETL |
|---|---|---|---|---|---|---|
| Example 1-1 | Compound | Compound | Compound | Compound X-4: | Compound | Compound |
| | HI | HT | X-4 | Compound H-91: | H-1 | ET: Liq |
| | (100 Å) | (350 Å) | (50 Å) | Metal complex 151 | (50 Å) | (40:60) (350 |
| | | | | (63:31:6) (400 Å) | | Å) |
| Example 1-2 | Compound | Compound | Compound | Compound X-4: | Compound | Compound |
| | HI | HT | X-4 | Compound H-91: | H-1 | ET: Liq |
| | (100 Å) | (350 Å) | (50 Å) | Metal complex 186 | (50 Å) | (40:60) (350 |
| | | | | (63:31:6) (400 Å) | | Å) |
| Comparative | Compound | Compound | Compound | Compound X-4: | Compound | Compound |
| Example 1-1 | HI | HT | X-4 | Compound H-91: | H-1 | ET: Liq |
| | (100 Å) | (350 Å) | (50 Å) | Compound GD1 | (50 Å) | (40:60) (350 |
| | | | | (63:31:6) (400 Å) | | Å) |
| Example 2-1 | Compound | Compound | Compound | Compound X-4: | Compound | Compound |
| | HI | HT | X-4 | Compound H-91: | H-1 | ET: Liq |
| | (100 Å) | (350 Å) | (50 Å) | Metal complex 467 | (50 Å) | (40:60) (350 |
| | | | | (63:31:6) (400 Å) | | Å) |
| Comparative | Compound | Compound | Compound | Compound X-4: | Compound | Compound |
| Example 2-1 | HI | HT | X-4 | Compound H-91: | H-1 | ET: Liq |
| | (100 Å) | (350 Å) | (50 Å) | Compound GD2 | (50 Å) | (40:60) (350 |
| | | | | (63:31:6) (400 Å) | | Å) |
| Example 3-1 | Compound | Compound | Compound | Compound X-4: | Compound | Compound |
| | HI | HT | X-4 | Compound H-91: | H-1 | ET: Liq |
| | (100 Å) | (350 Å) | (50 Å) | Metal complex 601 | (50 Å) | (40:60) (350 |
| | | | | (63:31:6) (400 Å) | | Å) |
| Example 3-2 | Compound | Compound | Compound | Compound X-4: | Compound | Compound |
| | HI | HT | X-4 | Compound H-91: | H-1 | ET: Liq |
| | (100 Å) | (350 Å) | (50 Å) | Metal complex 604 | (50 Å) | (40:60) (350 |
| | | | | (63:31:6) (400 Å) | | Å) |
| Example 3-3 | Compound | Compound | Compound | Compound X-4: | Compound | Compound |
| | HI | HT | X-4 | Compound H-91: | H-1 | ET: Liq |
| | (100 Å) | (350 Å) | (50 Å) | Metal complex 610 | (50 Å) | (40:60) (350 |
| | | | | (63:31:6) (400 Å) | | Å) |
| Example 3-4 | Compound | Compound | Compound | Compound X-4: | Compound | Compound |
| | HI | HT | X-4 | Compound H-91: | H-1 | ET: Liq |
| | (100 Å) | (350 Å) | (50 Å) | Metal complex 646 | (50 Å) | (40:60) (350 |
| | | | | (63:31:6) (400 Å) | | Å) |
| Example 3-5 | Compound | Compound | Compound | Compound X-4: | Compound | Compound |
| | HI | HT | X-4 (50 Å) | Compound H-91: | H-1 | ET: Liq |
| | (100 Å) | (350 Å) | | Metal complex 613 | (50 Å) | (40:60) (350 |
| | | | | (63:31:6) (400 Å) | | Å) |
| Example 3-6 | Compound | Compound | Compound | Compound X-4: | Compound | Compound |
| | HI | HT | X-4 (50 Å) | Compound H-91: | H-1 | ET: Liq |
| | (100 Å) | (350 Å) | | Metal complex 636 | (50 Å) | (40:60) (350 |
| | | | | (63:31:6) (400 Å) | | Å) |
| Example 3-7 | Compound | Compound | Compound | Compound X-4: | Compound | Compound |
| | HI | HT | X-4 (50 Å) | Compound H-91: | H-1 | ET: Liq |
| | (100 Å) | (350 Å) | | Metal complex 1217 | (50 Å) | (40:60) (350 |
| | | | | (63:31:6) (400 Å) | | Å) |
| Comparative | Compound | Compound | Compound | Compound X-4: | Compound | Compound |
| Example 3-1 | HI | HT | X-4 | Compound H-91: | H-1 | ET: Liq |
| | (100 Å) | (350 Å) | (50 Å) | Compound GD3 | (50 Å) | (40:60) (350 |
| | | | | (63:31:6) (400 Å) | | Å) |
| Example 4-1 | Compound | Compound | Compound | Compound X-4: | Compound | Compound |
| | HI | HT | X-4 (50 Å) | Compound H-91: | H-1 | ET: Liq |
| | (100 Å) | (350 Å) | | Metal complex 751 | (50 Å) | (40:60) (350 |
| | | | | (63:31:6) (400 Å) | | Å) |
| Comparative | Compound | Compound | Compound | Compound X-4: | Compound | Compound |
| Example 4-1 | HI | HT | X-4 | Compound H-91: | H-1 | ET: Liq |
| | (100 Å) | (350 Å) | (50 Å) | Compound GD4 | (50 Å) | (40:60) (350 |
| | | | | (63:31:6) (400 Å) | | Å) |
| Example 5-1 | Compound | Compound | Compound | Compound X-4: | Compound | Compound |
| | HI | HT | X-4 | Compound H-91: | H-1 | ET: Liq |
| | (100 Å) | (350 Å) | (50 Å) | Metal complex 243 | (50 Å) | (40:60) (350 |
| | | | | (63:31:6) (400 Å) | | Å) |
| Comparative | Compound | Compound | Compound | Compound X-4: | Compound | Compound |
| Example 5-1 | HI | HT | X-4 | Compound H-91: | H-1 | ET: Liq |
| | (100 Å) | (350 Å) | (50 Å) | Compound GD5 | (50 Å) | (40:60) (350 |
| | | | | (63:31:6) (400 Å) | | Å) |
| Example 6-1 | Compound | Compound | Compound | Compound X-4: | Compound | Compound |
| | HI | HT | X-4 | Compound H-91: | H-1 | ET: Liq |
| | (100 Å) | (350 Å) | (50 Å) | Metal complex 693 | (50 Å) | (40:60) (350 |
| | | | | (63:31:6) (400 Å) | | Å) |
| Example 6-2 | Compound | Compound | Compound | Compound X-4: | Compound | Compound |
| | HI | HT | X-4 | Compound H-91: | H-1 | ET: Liq |
| | (100 Å) | (350 Å) | (50 Å) | Metal complex 697 | (50 Å) | (40:60) (350 |
| | | | | (63:31:6) (400 Å) | | Å) |
| Comparative | Compound | Compound | Compound | Compound X-4: | Compound | Compound |
| Example 6-1 | HI | HT | X-4 | Compound H-91: | H-1 | ET: Liq |
| | (100 Å) | (350 Å) | (50 Å) | Compound GD6 | (50 Å) | (40:60) (350 |
| | | | | (63:31:6) (400 Å) | | Å) |

The structures of the materials used in the devices are shown as follows.

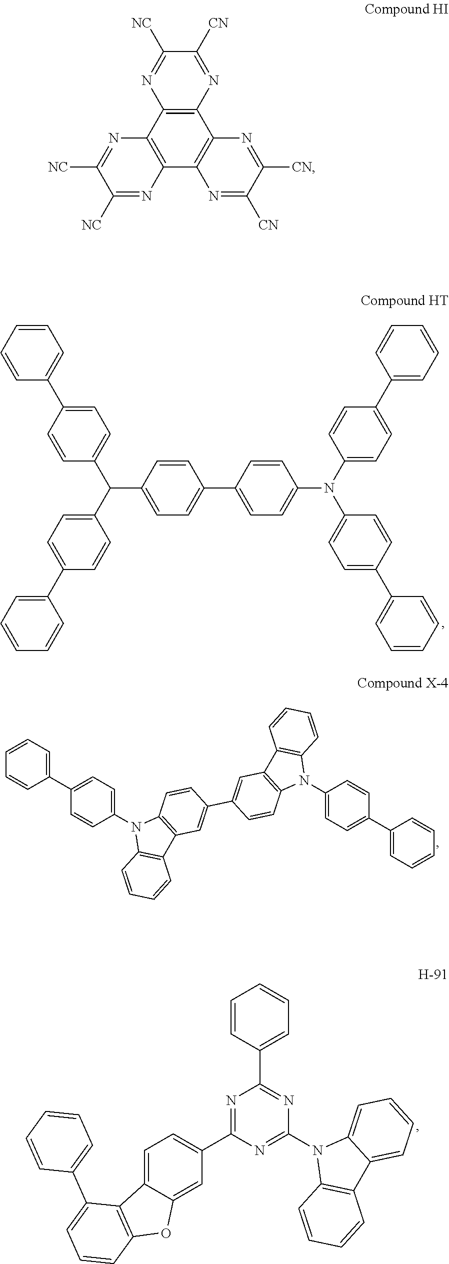 [SMILES: N#Cc1nc2c3nc(C#N)c(C#N)nc3c3nc(C#N)c(C#N)nc3c2nc1C#N ; c1ccc(-c2ccc(C(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2nc(-c3ccc4c(c3)oc3cccc(-c5ccccc5)c34)nc(-n3c4ccccc4c4ccccc43)n2)cc1]

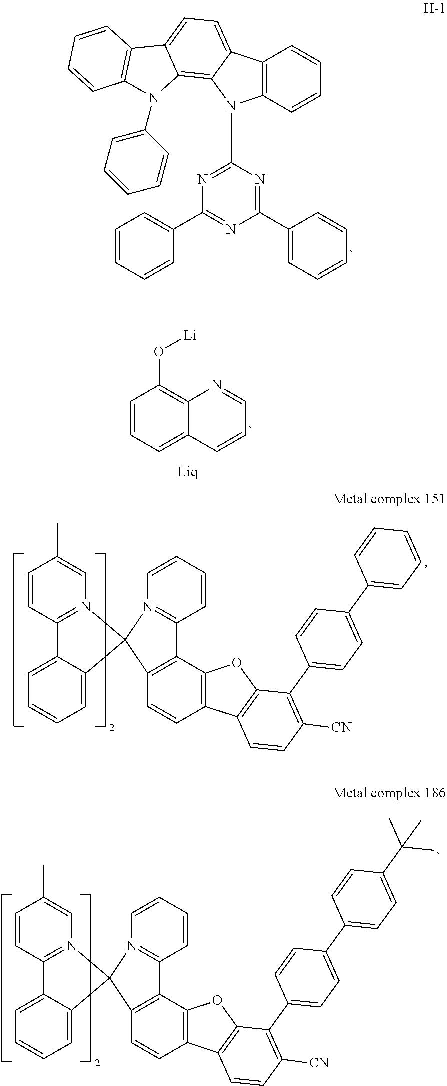

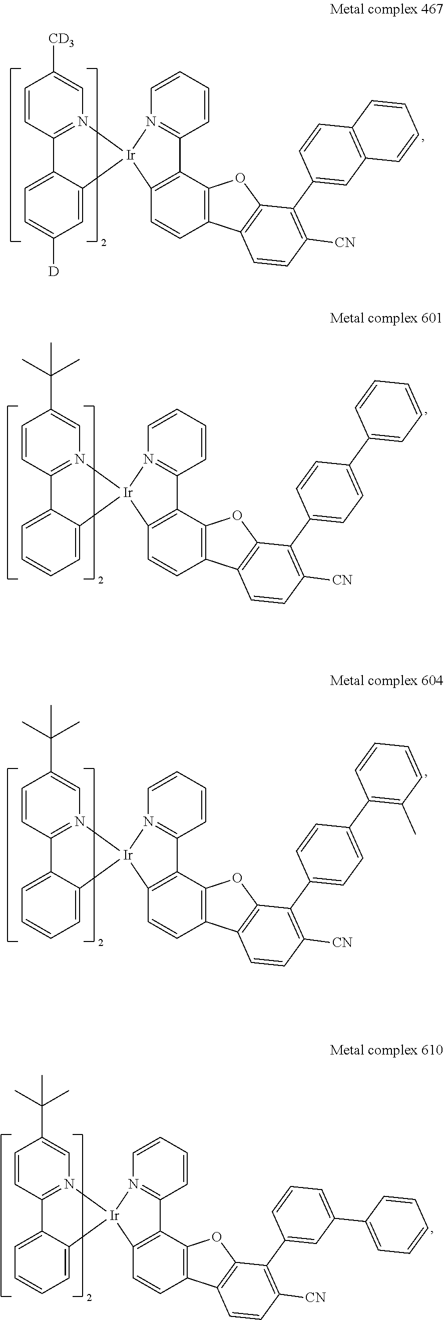

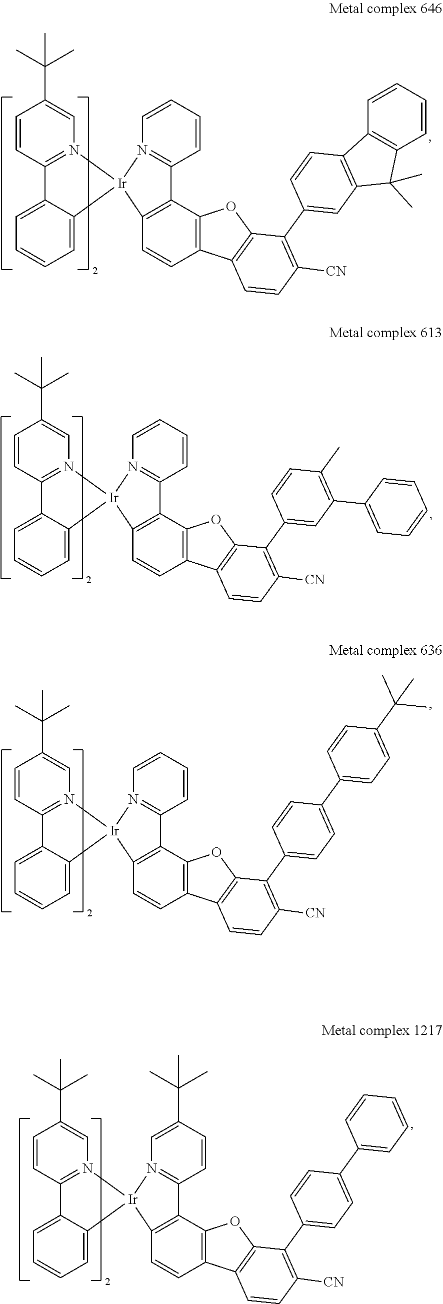

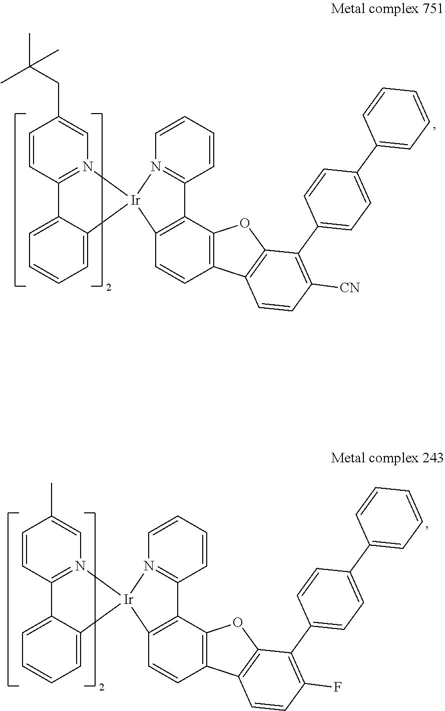

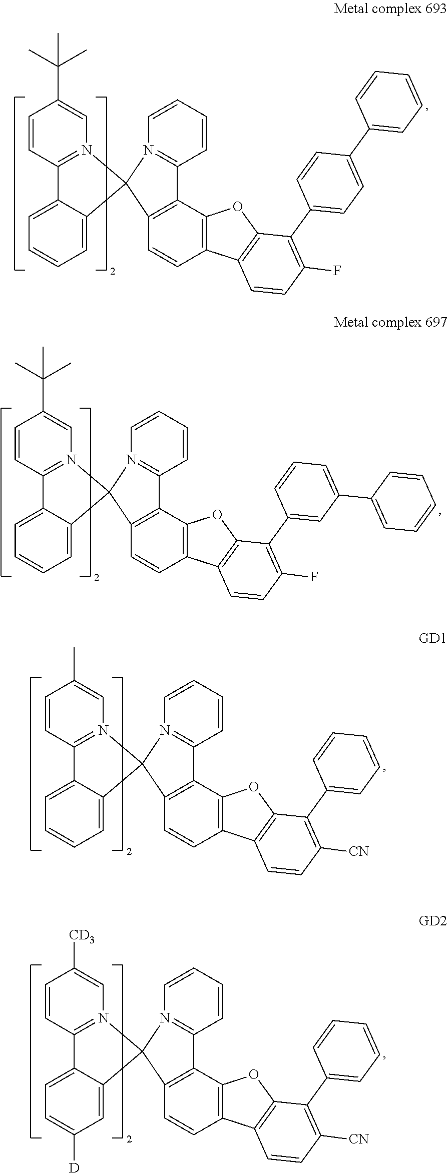

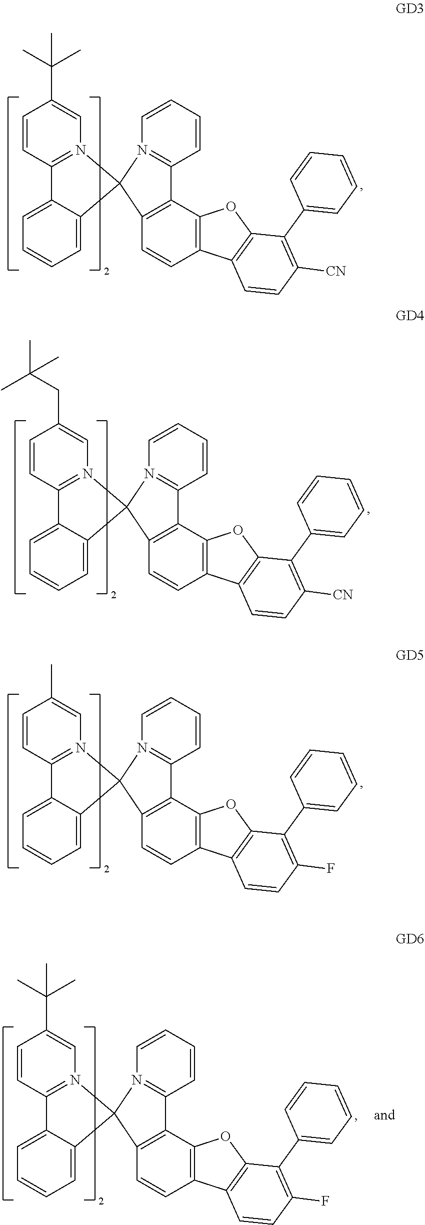

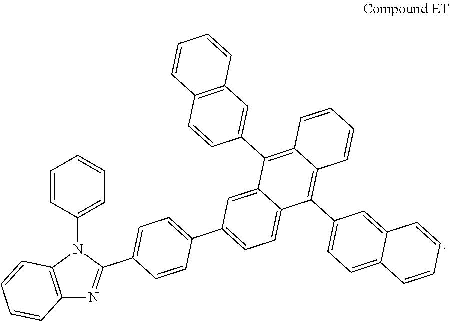 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1]

The current-voltage-luminance (IVL) characteristics of the devices were measured. The CIE data, maximum emission wavelength (λₘₐₓ), full width at half maximum (FWHM), voltage (V), current efficiency (CE), power efficiency (PE), and external quantum efficiency (EQE) of the devices were measured at 1000 cd/m². The data was recorded and shown in Table 2.

TABLE 2
Device data of Examples and Comparative Examples

| | | λₘₐₓ | FWHM | Voltage | | | |
|---|---|---|---|---|---|---|---|
| Device ID | CIE (x, y) | (nm) | (nm) | (V) | CE (cd/A) | PE (lm/W) | EQE (%) |
| Example | (0.340, 0.636) | 530 | 36.2 | 2.60 | 113 | 137 | 28.79 |
| 1-1 | | | | | | | |
| Example | (0.336, 0.639) | 530 | 35.2 | 2.62 | 115 | 138 | 29.43 |
| 1-2 | | | | | | | |
| Comparative | (0.342, 0.634) | 529 | 37.9 | 2.68 | 105 | 123 | 26.56 |
| Example | | | | | | | |
| 1-1 | | | | | | | |
| Example | (0.342, 0.635) | 531 | 34.9 | 2.62 | 109 | 130 | 27.57 |
| 2-1 | | | | | | | |
| Comparative | (0.343, 0.634) | 530 | 38.5 | 2.67 | 103 | 121 | 26.02 |
| Example | | | | | | | |
| 2-1 | | | | | | | |
| Example | (0.338, 0.638) | 531 | 34.0 | 2.67 | 112 | 132 | 28.50 |
| 3-1 | | | | | | | |
| Example | (0.340, 0.636) | 531 | 34.8 | 2.65 | 115 | 137 | 28.80 |
| 3-2 | | | | | | | |
| Example | (0.344, 0.634) | 531 | 36.1 | 2.75 | 110 | 126 | 27.73 |
| 3-3 | | | | | | | |
| Example | (0.341, 0.636) | 531 | 34.5 | 2.66 | 115 | 136 | 28.88 |
| 3-4 | | | | | | | |
| Example | (0.347, 0.631) | 532 | 37.3 | 2.72 | 112 | 129 | 28.13 |
| 3-5 | | | | | | | |
| Example | (0.344, 0.633) | 531 | 35.6 | 2.71 | 116 | 135 | 29.32 |
| 3-6 | | | | | | | |
| Example | (0.332, 0.643) | 530 | 30.8 | 2.80 | 115 | 136 | 28.94 |
| 3-7 | | | | | | | |
| Comparative | (0.342, 0.635) | 531 | 35.9 | 2.70 | 104 | 121 | 26.21 |
| Example | | | | | | | |
| 3-1 | | | | | | | |
| Example | (0.339, 0.637) | 531 | 34.9 | 2.67 | 109 | 128 | 27.78 |
| 4-1 | | | | | | | |
| Comparative | (0.340, 0.635) | 530 | 36.8 | 2.66 | 105 | 124 | 26.78 |
| Example | | | | | | | |
| 4-1 | | | | | | | |
| Example | (0.349, 0.625) | 528 | 59.9 | 2.84 | 104 | 115 | 27.25 |
| 5-1 | | | | | | | |
| Comparative | (0.349, 0.625) | 529 | 59.0 | 2.82 | 93 | 104 | 24.30 |
| Example | | | | | | | |
| 5-1 | | | | | | | |
| Example | (0.352, 0.624) | 531 | 58.4 | 2.92 | 105 | 114 | 27.36 |
| 6-1 | | | | | | | |
| Example | (0.351, 0.624) | 531 | 58.2 | 2.83 | 102 | 113 | 26.48 |
| 6-2 | | | | | | | |
| Comparative | (0.352, 0.624) | 530 | 58.4 | 3.06 | 96 | 98 | 24.75 |
| Example | | | | | | | |
| 6-1 | | | | | | | |

Discussion

Table 2 shows the performance of the devices in Examples and Comparative Examples. In comparison with Comparative Example 1-1, in Examples 1-1 and 1-2, there was cyano substitution at the same position of the ligand Lₐ of the metal complex with the only difference that on the ligand Lₐ of the metal complex, phenyl was replaced with the specific Ar substituent in the present disclosure, but the full width at half maximum was narrowed by 1.7 nm and 2.7 nm, respectively, the CE was increased by 7.6% and 9.5%, respectively, the PE was increased by about 11.4% and 12.2%, respectively, and the EQE was increased by about 8.4% and 10.8%, respectively, with no significant change in the maximum emission wavelength and drive voltage. In particular, the full width at half maximum of Example 1-2 reached 35.2 nm, and the EQE reached 29.43%. Meanwhile, in comparison with the device in Example 1-1 having an unsubstituted Ar substitution, the device in Example 1-2 having a substituted Ar substitution was further improved in terms of CE, PE and EQE. The above data show that the metal complex of the present disclosure including a ligand Lₐ having specific Ar substitution and cyano substitution is superior to the complex of Comparative Examples in multiple device performances such as the full width at half maximum, CE, PE and EQE and significantly improves the comprehensive performance of devices.

Similarly, in comparison with Comparative Example 2-1, Comparative Example 3-1 and Comparative Example 4-1, respectively, in Example 2-1, Examples 3-1 to 3-7 and Example 4-1, there was cyano substitution at the same position of the ligand Lₐ of the metal complex with the only difference that on the ligand Lₐ of the metal complex, phenyl was replaced with the specific Ar substituent in the present disclosure, and the devices were significantly improved in terms of CE, PE and EQE, especially the EQE which was all higher than 27.0%, reaching the leading level in the industry, with no significant blue-shifted or red-shifted luminescence. In comparison with Comparative Example 2-1, in Example 2-1, the full width at half maximum was narrowed by 3.6 nm, and the EQE was increased by about 6%. In comparison with Comparative Example 3-1, in Examples 3-1, 3-2, 3-4, 3-6 and 3-7, the full width at half maximum was narrowed by 1.9 nm, 1.1 nm, 1.4 nm, 0.3 nm and 5.1 nm, respectively, and the EQE was increased by about 8.7%, 9.9%, 10.2%, 11.9% and 9.4%, respectively; although the full width at half maximum in Example 3-3 was slightly wider than that in Comparative Example 3-1, in Example 3-3, the EQE was increased by about 5.8%, and the PE and CE were also increased by about 5%; in comparison with Comparative Example 3-1, in Example 3-5, the EQE was increased by 7.2%. In comparison with Comparative Example 4-1, in Example 4-1, the full width at half maximum was narrowed by 1.9 nm, the EQE was increased by about 4%, and the PE and CE were also increased by about 4%. In these Examples, especially in Example 3-1, the full width at half maximum was only 34 nm, which is very rare in green phosphorescent devices. In addition, the lifetime (LT97) of devices in Examples 3-3, 3-4, 3-6, 3-7 and 4-1 and Comparative Examples 3-1 and 4-1 were tested at a constant current of 80 mA/cm². In comparison with Comparative Example 3-1, in Examples 3-3, 3-4, 3-6 and 3-7, the device lifetime was 38.1 hours, 32.01 hours, 31.7 hours, 37.0 hours and 26.8 hours, respectively, which were increased by 41.8%, 19.4%, 18.3% and 38.1%, respectively. In comparison with Comparative Example 4-1 in which the device lifetime was 11.35 hours, in Example 4-1, the device lifetime was 14.85 hours, which was increased by 30.8%. As can be seen from the above data, the specific Ar substitution of various structural types in the present disclosure is of great help for improving important parameters such as efficiency, lifetime and color saturation of green-light devices and significantly improves the comprehensive performance of devices.

Similarly, in comparison with Comparative Example 5-1 and Comparative Example 6-1, respectively, in Example 5-1 and Examples 6-1 to 6-2, there was fluorine substitution at the same position of the ligand Lₐ of the metal complex with the only difference that on the ligand Lₐ of the metal complex, phenyl was replaced with the specific Ar substituent in the present disclosure, and the CE, PE EQE and lifetime of devices were significantly improved, with no significant change in the maximum emission wavelength. In terms of EQE, the EQE of Example 5-1 was increased by 12.1%, in comparison with Comparative Example 5-1; the EQE of Examples 6-1 and 6-2 were increased by 10.5% and 7.0%, respectively, in comparison with Comparative Example 6-1. The lifetime (LT97) of devices in Examples 5-1 and 6-1 and Comparative Examples 5-1 and 6-1 were tested at a constant current of 80 mA/cm². In comparison with Comparative Example 5-1 in which the device lifetime was 31 hours, in Example 5-1, the device lifetime was 42 hours, which was increased by 23.5%; in comparison with Comparative Example 6-1 in which the device lifetime was 40.7 hours, in Example 6-1, the device lifetime was 46.35 hours, which was increased by 13.8%. The above data show that for complexes including a fluorine-substituted ligand Lₐ, the metal complex of the present disclosure including a ligand Lₐ having specific Ar substitution is superior to the complex of Comparative Examples in multiple device performances such as the lifetime, CE, PE and EQE.

The above results show that the metal complex of the present disclosure including a ligand Lₐ having cyano or fluorine substitution and a specific Ar substitution can be used as a luminescent material in the emissive layer of an electroluminescent device, and in comparison with the metal complex including a ligand Lₐ having cyano or fluorine substitution and phenyl substitution, shows excellent performance. The metal complex of the present disclosure, when used, can provide more saturated luminescence, higher luminous efficiency and narrower full width at half maximum and can significantly improve the comprehensive performance of devices.

Meanwhile, Metal complex 601 of the present disclosure was used as a light-emitting dopant and together with first host compound having different structure, was used in the emissive layer of the organic electroluminescent device, devices in Device Examples 7-1 to 7-5 were prepared, and the performance of these devices were characterized.

### Device Example 7-1

The implementation mode in Device Example 7-1 was the same as that in Device Example 3-1, except that the ratio of Compound X-4, Compound H-91 and Metal complex 601 in the emissive layer was 66:28:6.

### Device Example 7-2

The implementation mode in Device Example 7-2 was the same as that in Device Example 7-1, except that Compound H-91 was replaced with Compound H-1 in the emissive layer.

### Device Example 7-3

The implementation mode in Device Example 7-3 was the same as that in Device Example 7-1, except that Compound H-91 was replaced with Compound H-141 in the emissive layer.

### Device Example 7-4

The implementation mode in Device Example 7-4 was the same as that in Device Example 7-1, except that Compound H-91 was replaced with Compound H-171 in the emissive layer.

### Device Example 7-5

The implementation mode in Device Example 7-5 was the same as that in Device Example 7-1, except that Compound H-91 was replaced with Compound H-172 in the emissive layer.

Detailed structures and thicknesses of layers of the devices are shown in the following table. The layers using more than one material were obtained by doping different compounds at a weight ratio as recorded in the following table.

TABLE 3
Device structures in Device Examples 7-1 to 7-5

| Device ID | HIL | HTL | EBL | EML | HBL | ETL |
|---|---|---|---|---|---|---|
| Example | Compound | Compound | Compound | Compound X-4: | Compound | Compound |
| 7-1 | HI | HT | X-4 | Compound H-91: | H-1 | ET: Liq |
| | (100 Å) | (350 Å) | (50 Å) | Metal complex 601 | (50 Å) | (40:60) (350 |
| | | | | (66:28:6) (400 Å) | | Å) |
| Example | Compound | Compound | Compound | Compound X-4: | Compound | Compound |
| 7-2 | HI | HT | X-4 | Compound H-1: | H-1 | ET: Liq |
| | (100 Å) | (350 Å) | (50 Å) | Metal complex 601 | (50 Å) | (40:60) (350 |
| | | | | (66:28:6) (400 Å) | | Å) |
| Example | Compound | Compound | Compound | Compound X-4: | Compound | Compound |
| 7-3 | HI | HT | X-4 | Compound H-141: | H-1 | ET: Liq |
| | (100 Å) | (350 Å) | (50 Å) | Metal complex 601 | (50 Å) | (40:60) (350 |
| | | | | (66:28:6) (400 Å) | | Å) |
| Example | Compound | Compound | Compound | Compound X-4: | Compound | Compound |
| 7-4 | HI | HT | X-4 | Compound H-171: | H-1 | ET: Liq |
| | (100 Å) | (350 Å) | (50 Å) | Metal complex 601 | (50 Å) | (40:60) (350 |
| | | | | (66:28:6) (400 Å) | | Å) |
| Example | Compound | Compound | Compound | Compound X-4: | Compound | Compound |
| 7-5 | HI | HT | X-4 | Compound H-172: | H-1 | ET: Liq |
| | (100 Å) | (350 Å) | (50 Å) | Metal complex 601 | (50 Å) | (40:60) (350 |
| | | | | (66:28:6) (400 Å) | | Å) |

Structures of the new materials used in the device are as follows:

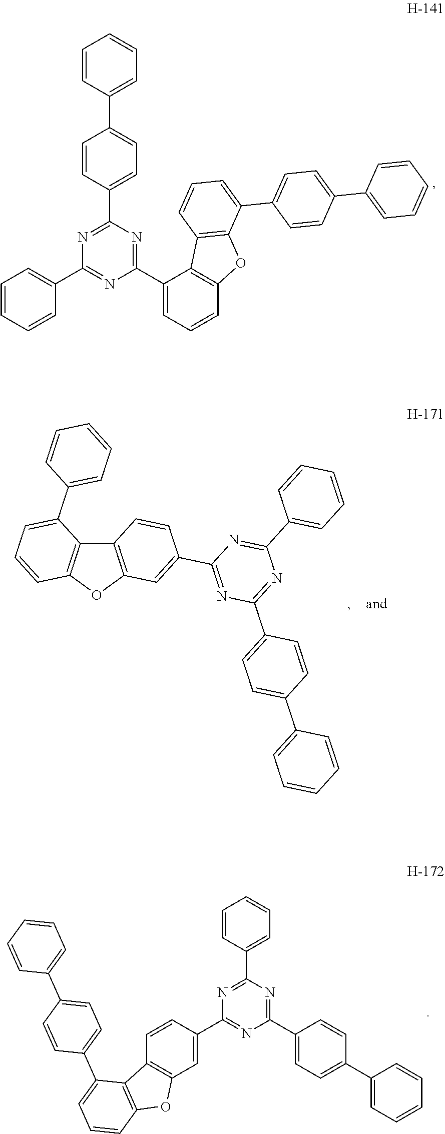 [SMILES: c1ccc(-c2ccc(-c3nc(-c4ccccc4)nc(-c4cccc5oc6c(-c7ccc(-c8ccccc8)cc7)cccc6c45)n3)cc2)cc1 ; c1ccc(-c2ccc(-c3nc(-c4ccccc4)nc(-c4ccc5c(c4)oc4cccc(-c6ccccc6)c45)n3)cc2)cc1 ; c1ccc(-c2ccc(-c3nc(-c4ccccc4)nc(-c4ccc5c(c4)oc4cccc(-c6ccc(-c7ccccc7)cc6)c45)n3)cc2)cc1]

The IVL characteristics of the devices were measured. The CIE data, maximum emission wavelength (λₘₐₓ), full width at half maximum (FWHM), voltage (V), current efficiency (CE), power efficiency (PE), and external quantum efficiency (EQE) of the devices were measured at 1000 cd/m². The data was recorded and shown in Table 4.

TABLE 4
Device data of Device Examples 7-1 to 7-5

| | | λₘₐₓ | FWHM | Voltage | | PE | |
|---|---|---|---|---|---|---|---|
| Device ID | CIE (x, y) | (nm) | (nm) | (V) | CE (cd/A) | (lm/W) | EQE (%) |
| Example 7-1 | (0.341, 0.636) | 532 | 34.5 | 2.80 | 107 | 121 | 26.90 |
| Example 7-2 | (0.341, 0.636) | 531 | 34.5 | 2.80 | 109 | 123 | 27.30 |
| Example 7-3 | (0.343, 0.634) | 532 | 35.0 | 2.80 | 109 | 124 | 27.40 |
| Example 7-4 | (0.340, 0.637) | 531 | 33.7 | 2.70 | 110 | 129 | 27.90 |
| Example 7-5 | (0.343, 0.634) | 531 | 34.7 | 2.70 | 114 | 133 | 28.90 |

As can be seen from the above data, in Examples 7-1 to 7-5, the EQE was about 27%, especially the EQE in Example 7-5 reached 28.9%, and the full width at half maximum was less than or equal to 35 nm, especially the full width at half maximum in Example 7-4 reached 33.7 nm, which is rare in green phosphorescent devices and is helpful for devices to providing more saturated luminescence. It is shown that the metal complex of the present disclosure including a ligand Lₐ having cyano or fluorine substitution and specific Ar substitution can be used as a luminescent material in the emissive layer of an electroluminescent device, and when used in combination with host materials whose structures are different from the structure of the metal complex, can provide excellent device performance.

### Device Example 8-1

The implementation mode in Device Example 8-1 was the same as that in Device Example 1-1, except that Metal complex 151 of the present disclosure in the emissive layer was replaced with Metal complex 670 of the present disclosure.

### Device Comparative Example 8-1

The implementation mode in Device Comparative Example 8-1 was the same as that in Device Example 8-1, except that Metal complex 670 of the present disclosure in the emissive layer was replaced with Compound GD7.

Detailed structures and thicknesses of layers of the devices are shown in the following table. The layers using more than one material were obtained by doping different compounds at a weight ratio as recorded in the following table.

TABLE 5
Device structures in Example and Comparative Example

| Device ID | HIL | HTL | EBL | EML | HBL | ETL |
|---|---|---|---|---|---|---|
| Example 8-1 | Compound | Compound | Compound | Compound X-4: | Compound | Compound |
| | HI | HT | X-4 | Compound H-91: | H-1 | ET: Liq |
| | (100 Å) | (350 Å) | (50 Å) | Metal complex 670 | (50 Å) | (40:60) (350 |
| | | | | (63:31:6) (400 Å) | | Å) |
| Comparative | Compound | Compound | Compound | Compound X-4: | Compound | Compound |
| Example 8-1 | HI | HT | X-4 | Compound H-91: | H-1 | ET: Liq |
| | (100 Å) | (350 Å) | (50 Å) | Compound GD7 | (50 Å) | (40:60) (350 |
| | | | | (63:31:6) (400 Å) | | Å) |

Structures of the new materials used in the device are as follows:

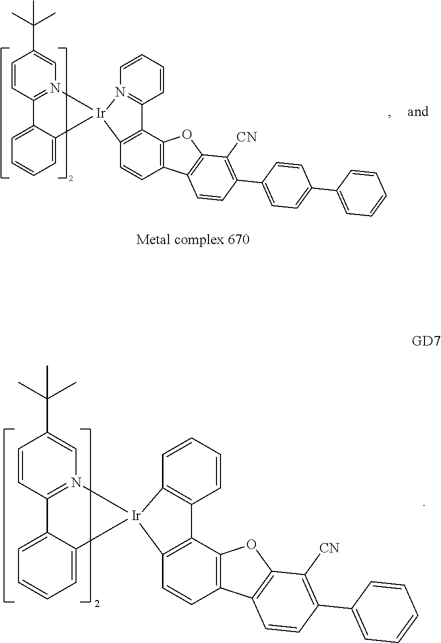

The external quantum efficiency (EQE) of devices in Example 8-1 and Comparative Example 8-1 were tested at 100 cd/m², and in comparison with Comparative Example 8-1 in which the EQE was 24.64%, in Example 8-1, the EQE was 25.7%, which was increased by 4.3%. The lifetime (LT97) of devices in Example 8-1 and Comparative Example 8-1 were tested at a constant current of 80 mA/cm², and in comparison with Comparative Example 8-1 in which the device lifetime was 44.17 hours, in Example 8-1, the device lifetime was 48.18 hours, which was increased by 9.1%. It is shown that the metal complex of the present disclosure including a ligand Lₐ having cyano substitution and specific Ar substitution can be used as a luminescent material in the emissive layer of an electroluminescent device, provide higher luminous efficiency and longer lifetime, and significantly improve the comprehensive performance of devices.

In summary, the metal complex of the present disclosure including a ligand Lₐ having cyano or fluorine substitution and specific Ar substitution can be used as a luminescent material in the emissive layer of an electroluminescent device, provide more saturated luminescence, higher luminous efficiency and narrower full width at half maximum, and significantly improve the comprehensive performance of devices. The metal complex, when used in combination with host material of different structures, can provide excellent device performance.

It should be understood that various embodiments described herein are merely examples and not intended to limit the scope of the present disclosure. Therefore, it is apparent to the persons skilled in the art that the present disclosure as claimed may include variations from specific embodiments and preferred embodiments described herein. Many of materials and structures described herein may be substituted with other materials and structures without departing from the spirit of the present disclosure. It should be understood that various theories as to why the present disclosure works are not intended to be limitative.

What is claimed is:

1. A metal complex, comprising a metal M and a ligand Lₐ coordinated to the metal M, wherein Lₐ has a structure represented by Formula 1: 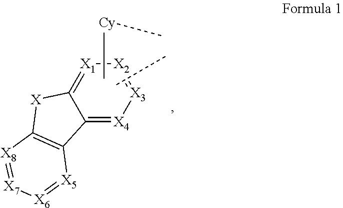
in Formula 1,
the metal M is selected from a metal having a relative atomic mass greater than 40;
Cy is, at each occurrence identically or differently, selected from a substituted or unsubstituted aromatic ring having 6 to 24 ring atoms, a substituted or unsubstituted heteroaromatic ring having 5 to 24 ring atoms or combinations thereof,
X is selected from the group consisting of O, S, Se, NR′, CR′R′, SiR′R′, and GeR′R′;
when two R′ are present, the two R′ are the same or different;
X₁ to X₈ are, at each occurrence identically or differently, selected from C, CRₓ or N; at least one of X₁ to X₄ is C and is attached to the Cy;
X₁, X₂, X₃ or X₄ is attached to the metal M through a metal-carbon bond or a metal-nitrogen bond;
at least one of X₁ to X₈ is CRₓ, and the Rₓ is a cyano group or fluorine;
at least another one of X₁ to X₈ is CRₓ, and Rₓ is Ar, and the Ar has a structure represented by Formula 2: 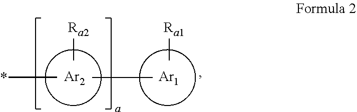
a is selected from 0, 1, 2, 3, 4 or 5;
Rₐ₁ and Rₐ₂ represent, at each occurrence identically or differently, mono-substitution, multiple substitutions or non-substitution;
ring Ar₁ and ring Ar₂ are, at each occurrence identically or differently, selected from an aromatic ring having 6 to 30 ring atoms, a heteroaromatic ring having 5 to 30 ring atoms or combinations thereof; and a total number of ring atoms of ring Ar₁ and ring Ar₂ is greater than or equal to 8;
R′, Rₓ, Rₐ₁, and Rₐ₂ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a substituted or unsubstituted alkylgermanyl having 3 to 20 carbon atoms, a substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,
“*” represents an attached position where Formula 2 is attached;
adjacent substituents R′, Rₓ, Rₐ₁, Rₐ₂ can be optionally joined to form a ring.

2. The metal complex according to claim 1, wherein Cy is selected from the group consisting of the following structures: 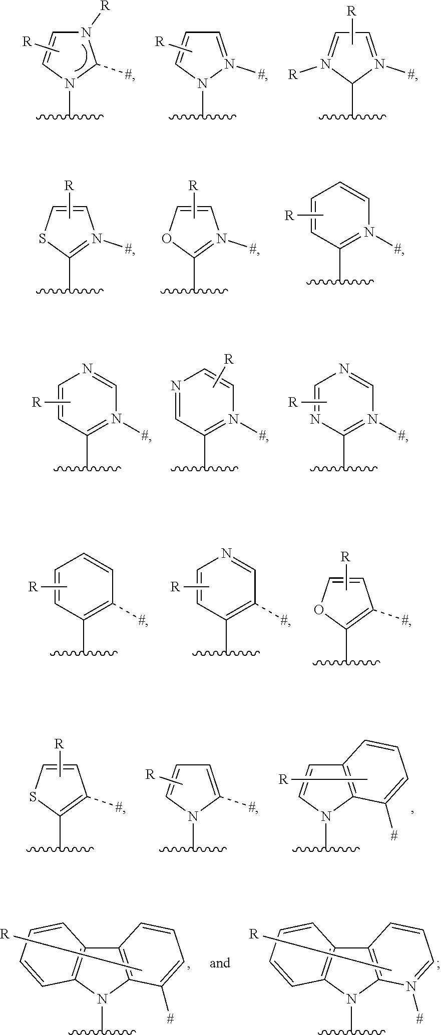
wherein,
R represents, at each occurrence identically or differently, mono-substitution, multiple substitutions or non-substitution; when a plurality of R is present, the plurality of R are the same or different;
R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a substituted or unsubstituted alkylgermanyl having 3 to 20 carbon atoms, a substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,
two adjacent substituents R can be optionally joined to form a ring;
“#” represents a position where the metal M is attached, and 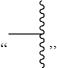
represents a position where X₁, X₂, X₃ or X₄ is attached.

3. The metal complex according to claim 1, having a general formula of M(Lₐ)ₘ(L_{b})ₙ(L_{c})_{q};
wherein,
M is, at each occurrence identically or differently, selected from the group consisting of Cu, Ag, Au, Ru, Rh, Pd, Os, Ir, and Pt; preferably, M is, at each occurrence identically or differently, selected from Pt or Ir;
Lₐ, L_{b}, and L_{c} are a first ligand, a second ligand and a third ligand coordinated to the metal M, respectively, and L_{c} is the same as or different from Lₐ or L_{b}; wherein Lₐ, L_{b}, and L_{c} can be optionally joined to form a multidentate ligand;
m is selected from 1, 2 or 3, n is selected from 0, 1 or 2, q is selected from 0, 1 or 2, and m+n+q equals an oxidation state of the metal M; when m is greater than or equal to 2, a plurality of Lₐ are the same or different; when n is equal to 2, two L_{b} are the same or different;
when q is equal to 2, two L_{c} are the same or different;
Lₐ is, at each occurrence identically or differently, selected from the group consisting of: 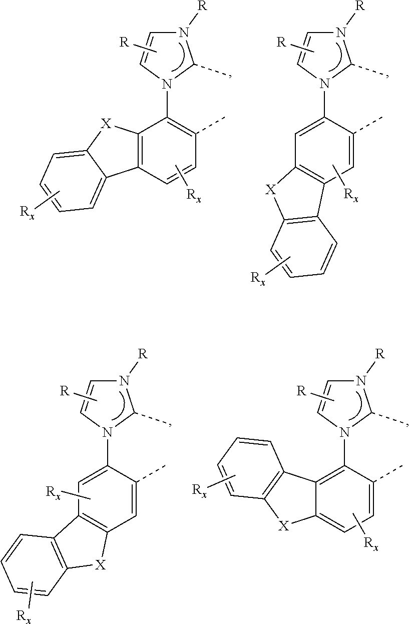 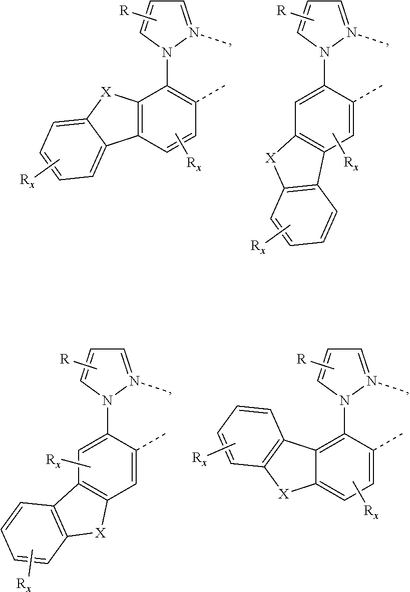 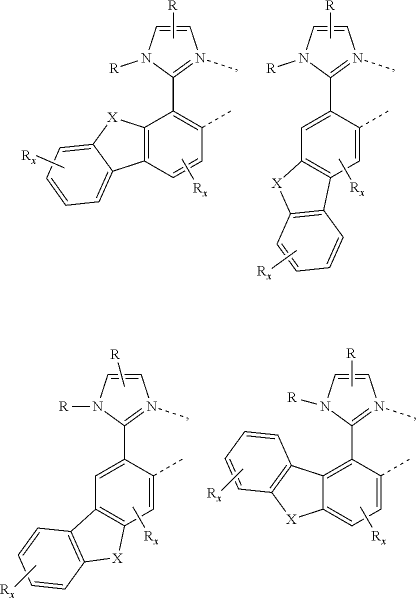 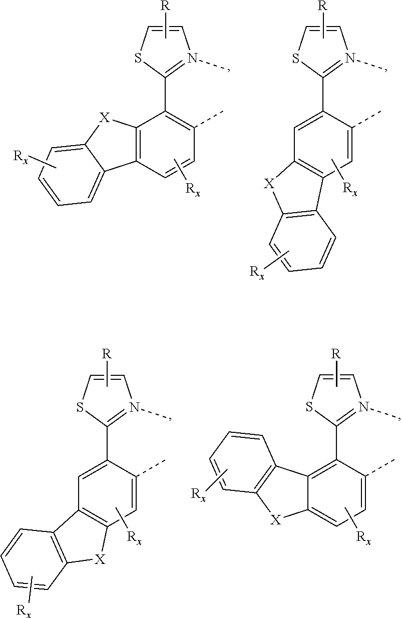 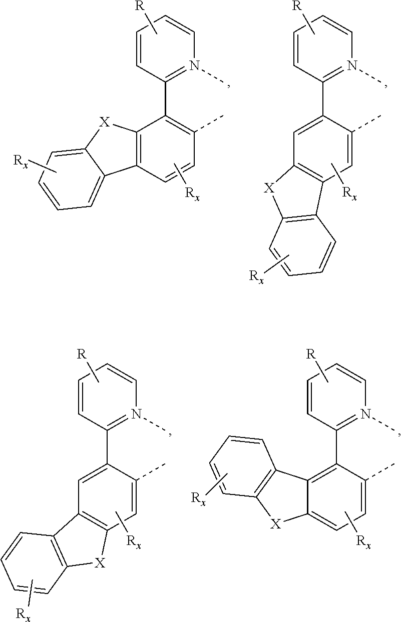 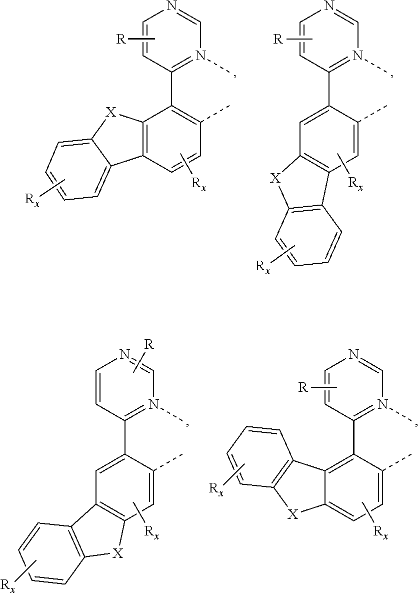 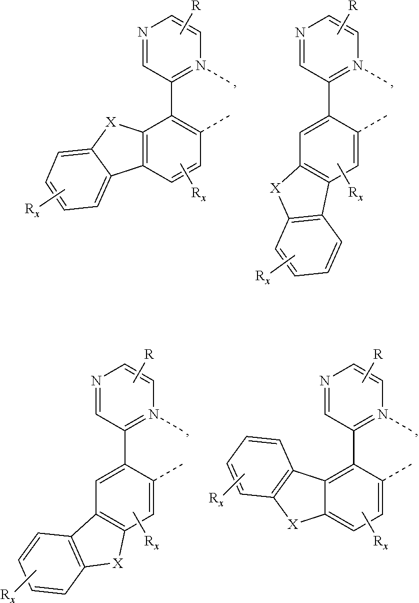 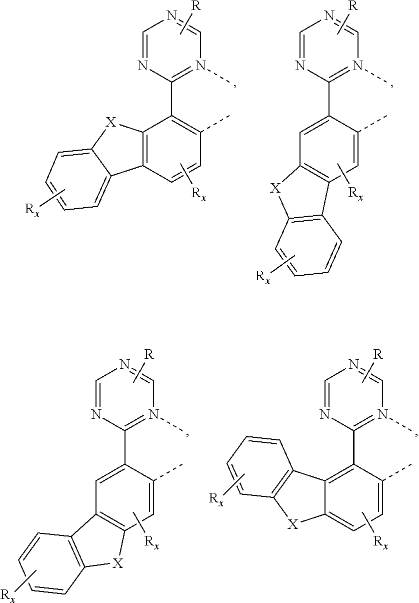 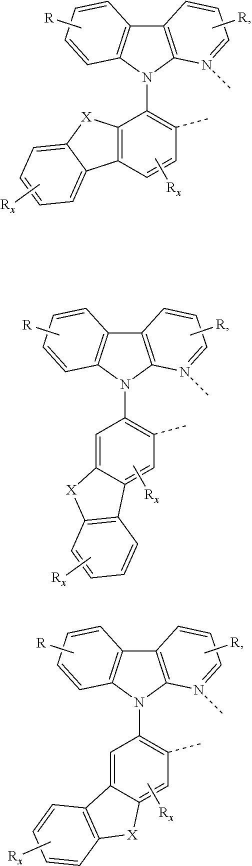 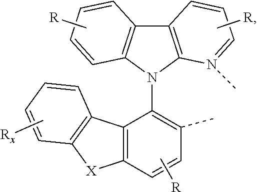 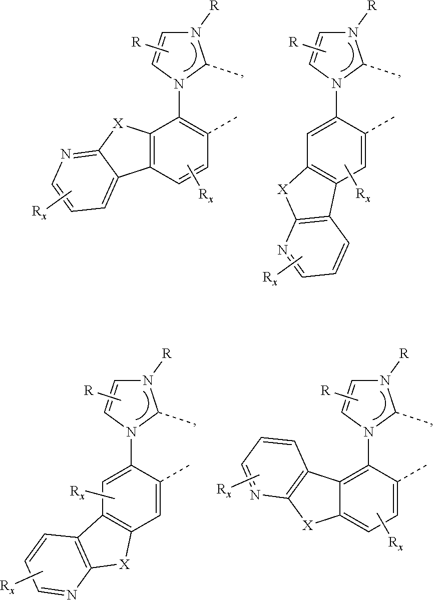 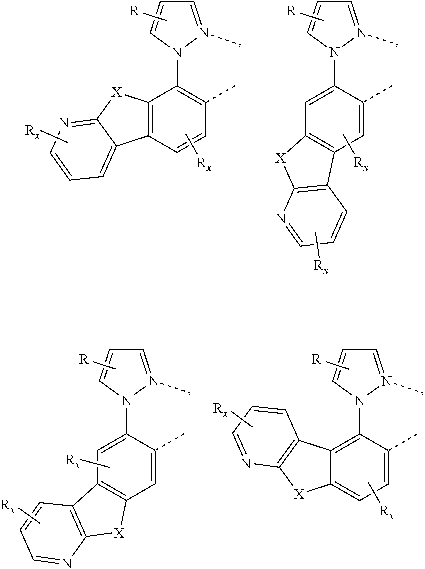 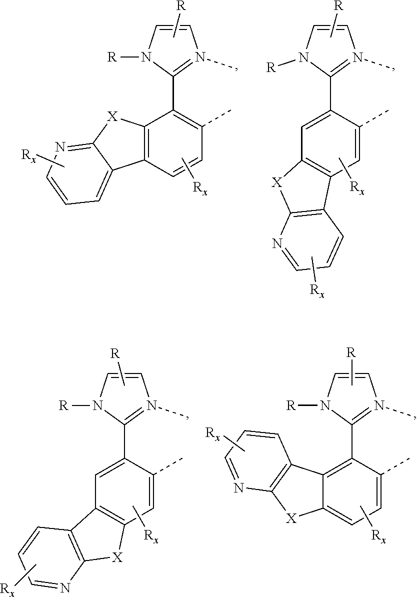 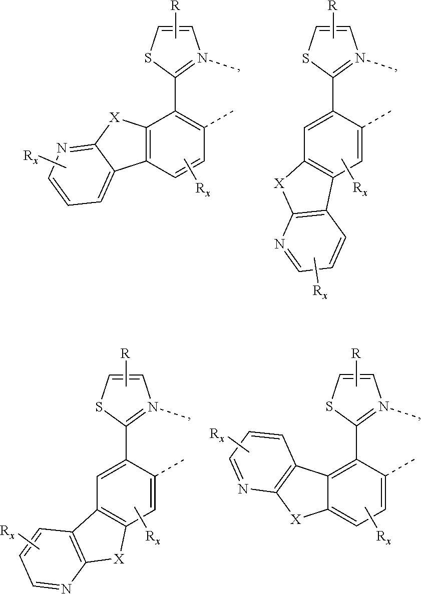 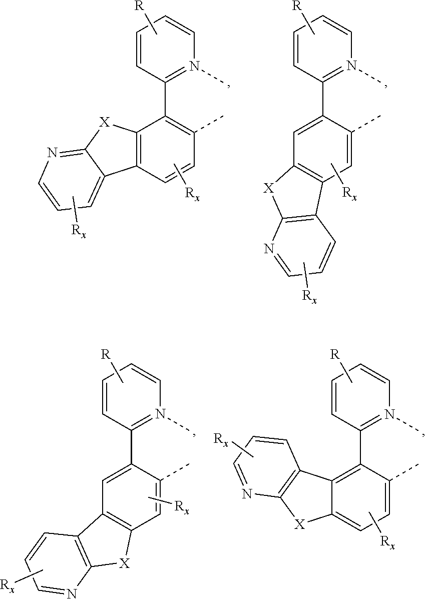 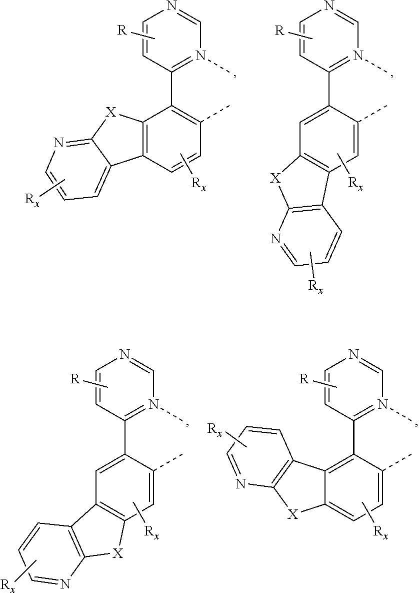 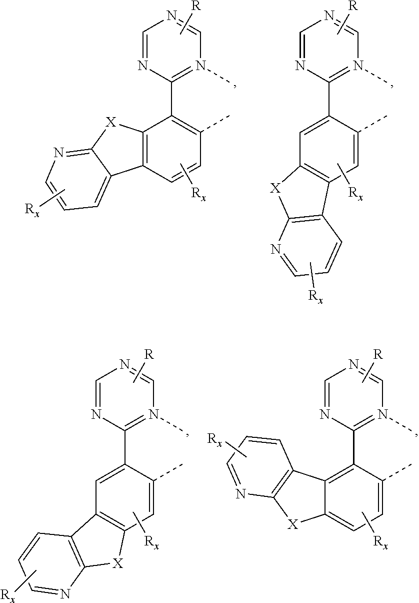 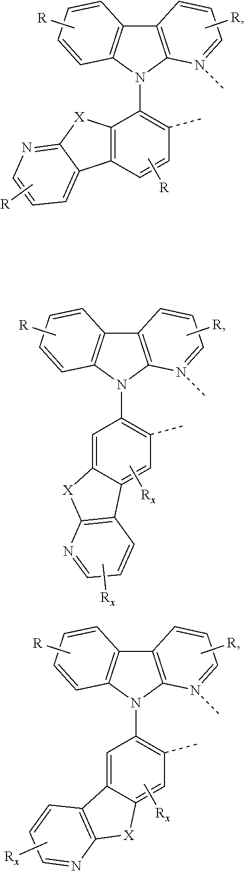 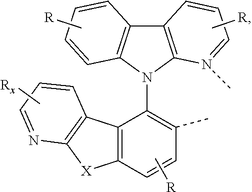 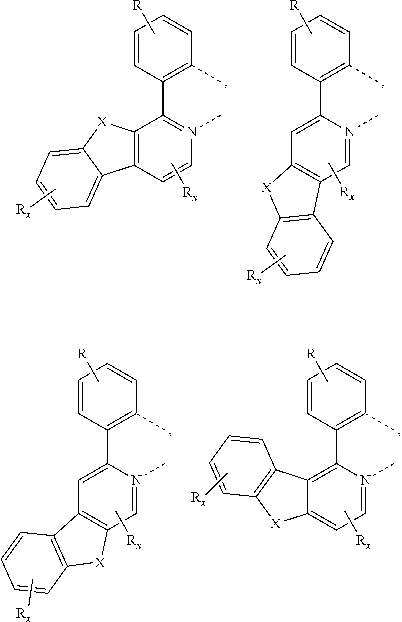 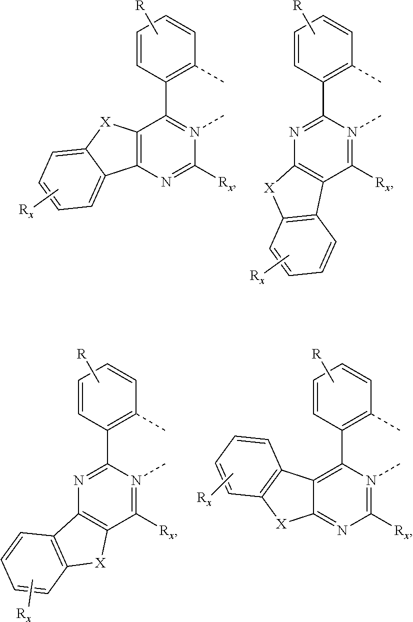 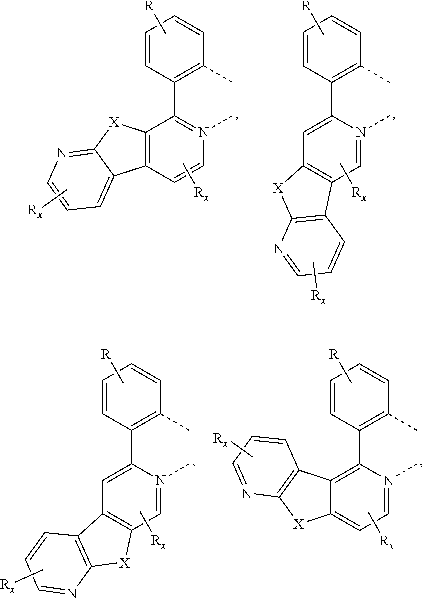 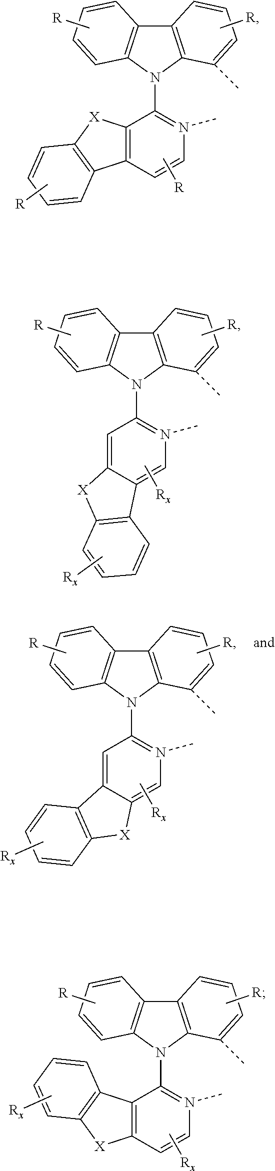
X is selected from the group consisting of O, S, Se, NR′, CR′R′, SiR′R′, and GeR′R′; when two R′ are present, the two R′ are the same or different;
R and Rₓ represent, at each occurrence identically or differently, mono-substitution, multiple substitutions or non-substitution;
at least one of Rₓ is selected from a cyano group or fluorine;
at least another one of Rₓ is Ar, and the Ar has a structure represented by Formula 2: 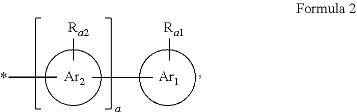
a is selected from 0, 1, 2, 3, 4 or 5;
ring Ar₁ and ring Ar₂ are, at each occurrence identically or differently, selected from an aromatic ring having 6 to 30 ring atoms, a heteroaromatic ring having 5 to 30 ring atoms or combinations thereof; and a total number of ring atoms of ring Ar₁ and ring Ar₂ is greater than or equal to 8;
Rₐ₁ and Rₐ₂ represent, at each occurrence identically or differently, mono-substitution, multiple substitutions or non-substitution;
adjacent substituents R, R′, Rₓ, Rₐ₁, and Rₐ₂ can be optionally joined to form a ring;
L_{b} and L_{c} are, at each occurrence identically or differently, selected from the group consisting of the following structures: 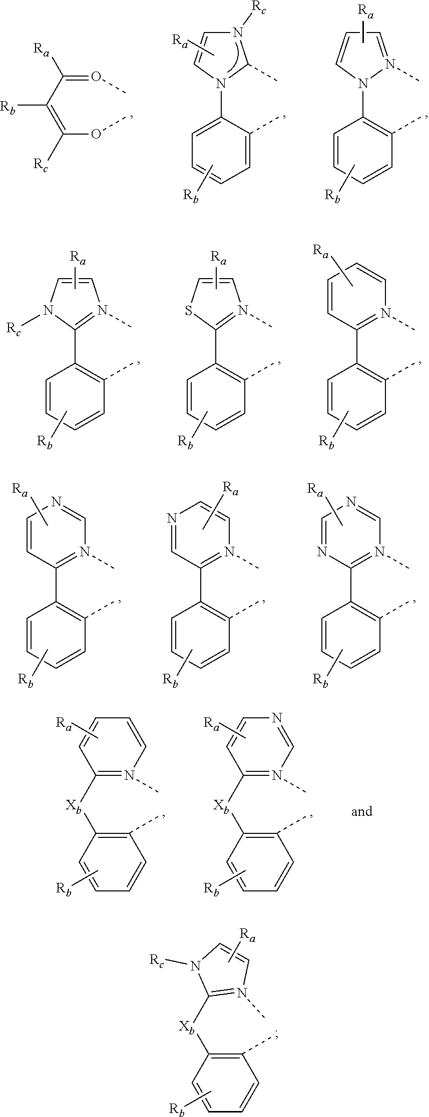
wherein,
X_{b} is, at each occurrence identically or differently, selected from the group consisting of: O, S, Se, NR_{N1}, and CR_{C1}R_{C2};
Rₐ and R_{b} represent, at each occurrence identically or differently, mono-substitution, multiple substitutions or non-substitution;
R, R′, Rₐ₁, Rₐ₂, Rₓ, Rₐ, R_{b}, R_{c}, R_{N1}, R_{C1}, and R_{C2} are, at each occurrence identically or differently, selected from the group consisting of hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a substituted or unsubstituted alkylgermanyl having 3 to 20 carbon atoms, a substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,
adjacent substituents Rₐ, R_{b}, R_{c}, R_{N1}, R_{C1}, and R_{C2} can be optionally joined to form a ring;
“*” represents an attached position where Formula 2 is attached.

4. The metal complex according to claim 1, wherein the metal complex Ir(Lₐ)ₘ(L_{b})₃₋ₘ has a structure represented by Formula 3: 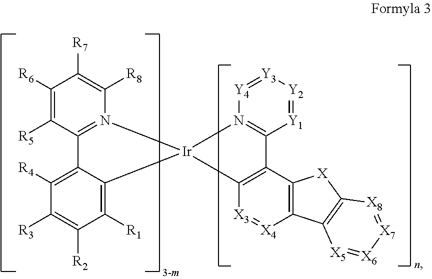
wherein,
m is selected from 1, 2 or 3; when m is selected from 1, two L_{b} are the same or different;
when m is selected from 2 or 3, a plurality of Lₐ are the same or different;
X is selected from the group consisting of O, S, Se, NR′, CR′R′, SiR′R′, and GeR′R′;
when two R′ are present, the two R′ are the same or different;
Y₁ to Y₄ are, at each occurrence identically or differently, selected from CR_{y} or N;
X₃ to X₈ are, at each occurrence identically or differently, selected from CRₓ or N;
at least one of X₃ to X₈ is CRₓ, and the Rₓ is a cyano group or fluorine;
at least another one of X₃ to X₈ is CRₓ, and Rₓ is Ar, and the Ar has a structure represented by Formula 2: 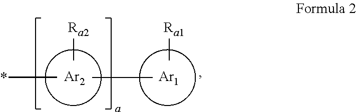
a is selected from 0, 1, 2, 3, 4 or 5;
Rₐ₁ and Rₐ₂ represent, at each occurrence identically or differently, mono-substitution, multiple substitutions or non-substitution;
ring Ar₁ and ring Ar₂ are, at each occurrence identically or differently, selected from an aromatic ring having 6 to 30 ring atoms, a heteroaromatic ring having 5 to 30 ring atoms or combinations thereof, and a total number of ring atoms of ring Ar₁ and ring Ar₂ is greater than or equal to 8;
R′, Rₓ, R_{y}, R₁ to R₈, Rₐ₁, and Rₐ₂ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a substituted or unsubstituted alkylgermanyl having 3 to 20 carbon atoms, a substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,
“*” represents an attached position where Formula 2 is attached;
adjacent substituents R′, Rₓ, R_{y}, Rₐ₁, Rₐ₂ can be optionally joined to form a ring;
adjacent substituents R₁ to R₈ can be optionally joined to form a ring.

5. The metal complex according to claim 1, wherein X is selected from O or S, and a is selected from 0, 1, 2 or 3; preferably, a is 1.

6. The metal complex according to claim 4, wherein X₃ to X₈ are, at each occurrence identically or differently, selected from CRₓ; and/or Y₁ to Y₄ are, at each occurrence identically or differently, selected from CR_{y}.

7. The metal complex according to claim 4, wherein at least one of X₃ to X₈ is N, and/or at least one of Y₁ to Y₄ is N.

8. The metal complex according to claim 1, wherein at least one of X₅ to X₈ is CRₓ, and Rₓ is a cyano group or fluorine; at least another one of X₅ to X₈ is CRₓ, and Rₓ is Ar;
preferably, X₇ and X₈ are selected from CRₓ, one Rₓ is selected from a cyano group or fluorine, and the other Rₓ is Ar;
more preferably, X₇ is CRₓ, and the Rₓ is a cyano group or fluorine; X₈ is selected from CRₓ, and the Rₓ is Ar.

9. The metal complex according to claim 1, wherein Rₐ₁ and Rₐ₂ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group, an isocyano group, a hydroxyl group, a sulfanyl group, and combinations thereof;
preferably, Rₐ₁ and Rₐ₂ are, at each occurrence identically or differently, selected from the group consisting of: hydrogen, deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 18 carbon atoms, substituted or unsubstituted heteroaryl having 3 to 18 carbon atoms, substituted or unsubstituted alkylsilyl having 3 to 15 carbon atoms, and combinations thereof,
more preferably, Rₐ₁ and Rₐ₂ are, at each occurrence identically or differently, selected from the group consisting of: hydrogen, deuterium, fluorine, methyl, ethyl, propyl, isopropyl, n-butyl, isobutyl, t-butyl, cyclopentyl, cyclohexyl, deuterated methyl, deuterated ethyl, deuterated propyl, deuterated isopropyl, deuterated n-butyl, deuterated isobutyl, deuterated t-butyl, deuterated cyclopentyl, deuterated cyclohexyl, phenyl, pyridyl, trimethylsilyl, and combinations thereof.

10. The metal complex according to claim 1, wherein in Ar, ring Ar₁ and ring Ar₂ are, at each occurrence identically or differently, selected from an aromatic ring having 6 ring atoms, a heteroaromatic ring having 5 or 6 ring atoms or combinations thereof;
preferably, ring Ar₁ and ring Ar₂ are, at each occurrence identically or differently, selected from an aromatic ring having 6 ring atoms or a heteroaromatic ring having 6 ring atoms;
preferably, ring Ar₁ and ring Ar₂ are, at each occurrence identically or differently, selected from an aromatic ring having 6 ring atoms.

11. The metal complex according to claim 1, wherein in Ar, ring Ar₁ and ring Ar₂ are, at each occurrence identically or differently, selected from an aromatic ring having 6 to 18 ring atoms, a heteroaromatic ring having 5 to 18 ring atoms or combinations thereof; and a total number of ring atoms of ring Ar₁ and ring Ar₂ is greater than or equal to 8 and less than or equal to 30;
preferably, in Ar, ring Ar₁ and ring Ar₂ are, at each occurrence identically or differently, selected from the group consisting of: a benzene ring, a pyridine ring, a pyrimidine ring, a triazine ring, a naphthalene ring, a phenanthrene ring, an anthracene ring, a fluorene ring, a silafluorene ring, a quinoline ring, an isoquinoline ring, a fused dithiophene ring, a fused difuran ring, a benzofuran ring, a benzothiophene ring, a dibenzofuran ring, a dibenzothiophene ring, a triphenylene ring, a carbazole ring, an azacarbazole ring, an azafluorene ring, an azasilafluorene ring, an azadibenzofuran ring, an azadibenzothiophene ring, and combinations thereof, and a total number of ring atoms of ring Ar₁ and ring Ar₂ is greater than or equal to 8 and less than or equal to 30.

12. The metal complex according to claim 1, wherein Ar is, at each occurrence identically or differently, selected from the group consisting of: 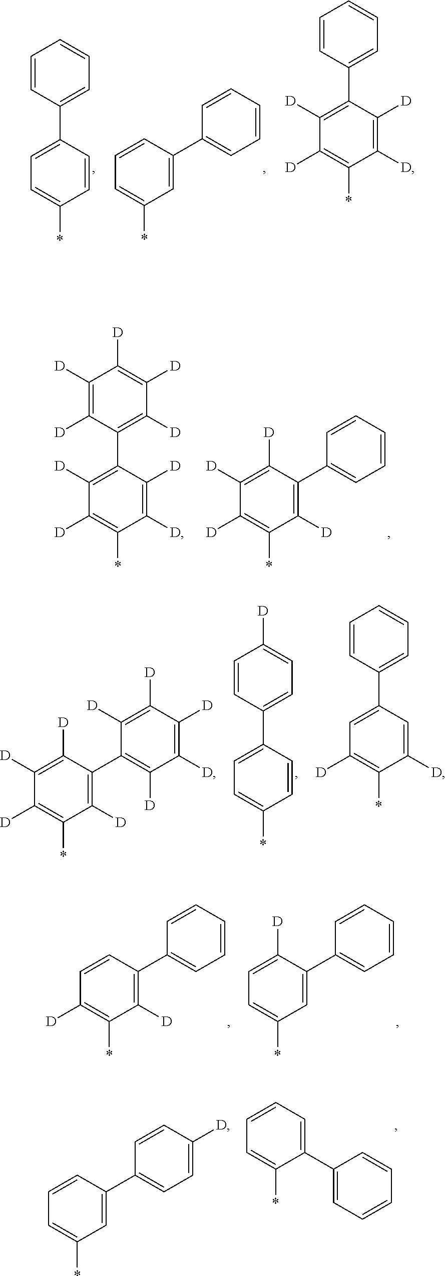 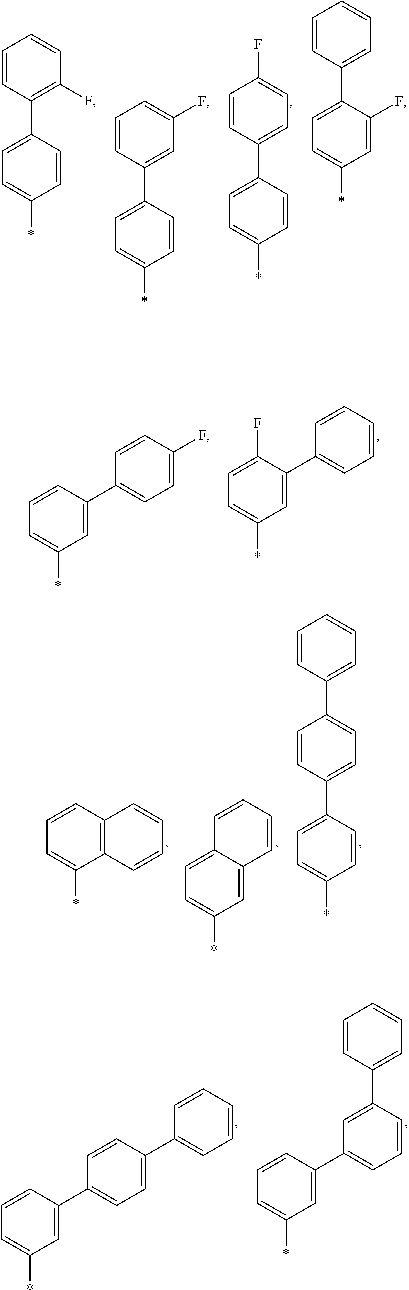 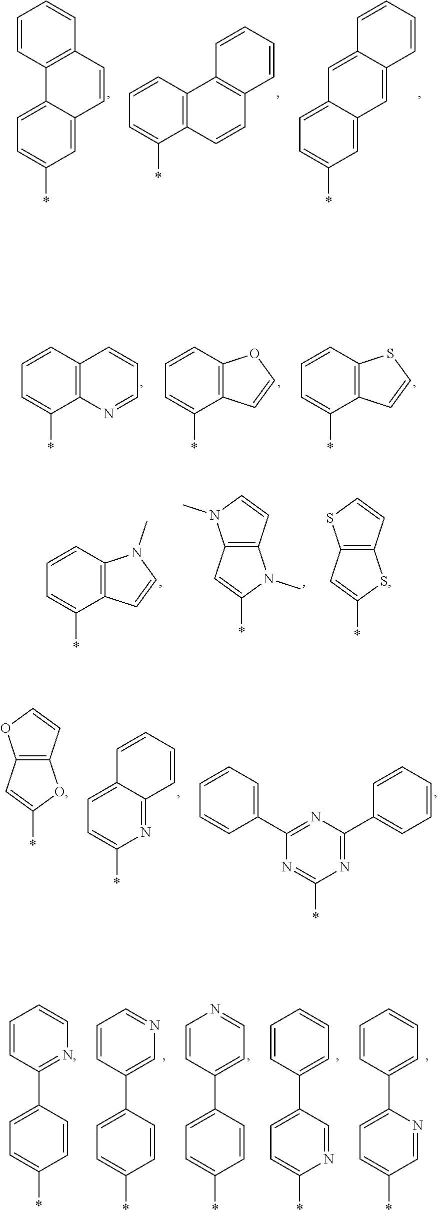 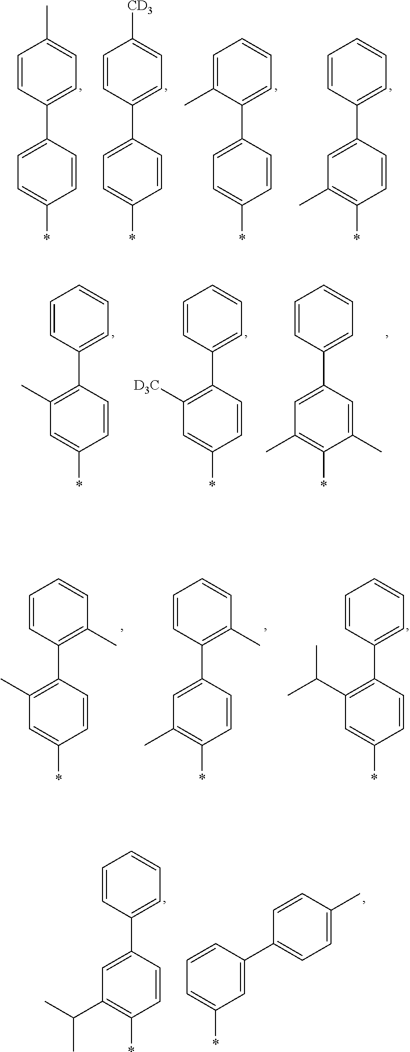 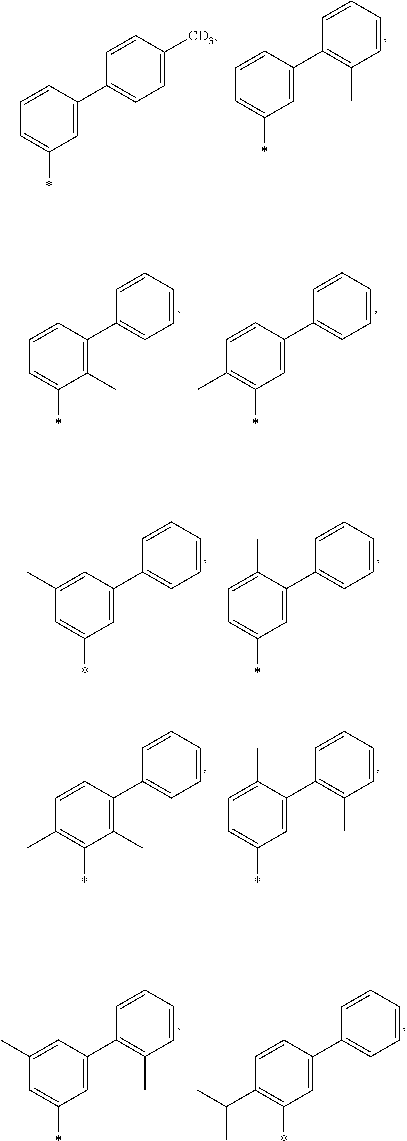 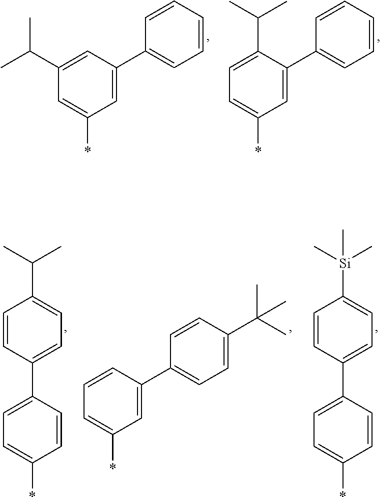 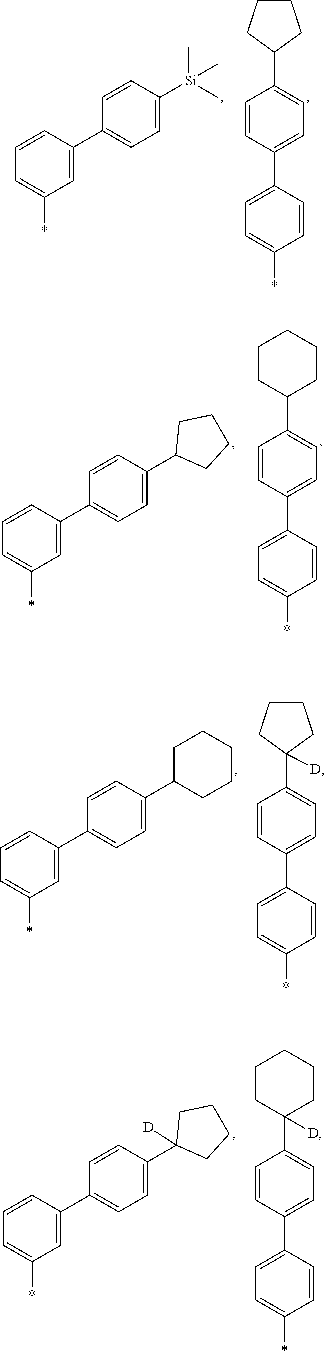 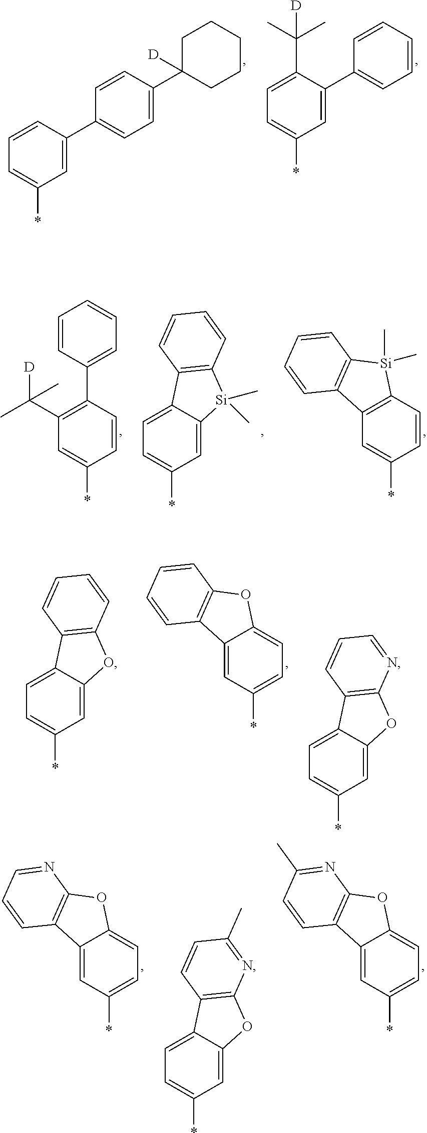 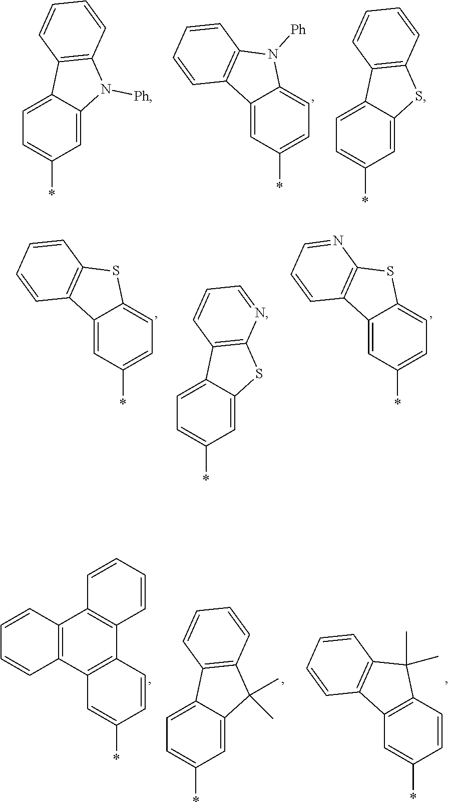
and combinations thereof;
optionally, hydrogen in the above groups can be partially or fully substituted with deuterium; wherein “*” represents a position where Ar is attached.

13. The metal complex according to claim 1, wherein at least one of Rₓ is selected from a cyano group or fluorine, at least another one of Rₓ is selected from Ar, and remaining Rₓ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, a cyano group, and combinations thereof;
preferably, at least one of Rₓ is selected from a cyano group or fluorine, at least another one of Rₓ is selected from Ar, and remaining Rₓ are, at each occurrence identically or differently, selected from the group consisting of: hydrogen, deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 6 carbon atoms, a cyano group, and combinations thereof;
more preferably, at least one of Rₓ is selected from a cyano group or fluorine, at least another one of Rₓ is selected from Ar, and remaining Rₓ are, at each occurrence identically or differently, selected from the group consisting of: hydrogen, deuterium, substituted or unsubstituted alkyl having 1 to 6 carbon atoms, substituted or unsubstituted cycloalkyl having 3 to 6 ring carbon atoms, and combinations thereof.

14. The metal complex according to claim 4, wherein R_{y} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, and combinations thereof;
preferably, at least one R_{y} is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

15. The metal complex according to claim 4, wherein at least one or at least two or at least three or all of R₂, R₃, R₆, and R₇ is(are) selected from the group consisting of: deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof;
preferably, at least one or at least two or at least three or all of R₂, R₃, R₆, and R₇ is(are) selected from the group consisting of: deuterium, substituted or unsubstituted alkyl having 1 to 20 carbon atoms, substituted or unsubstituted cycloalkyl having 3 to 20 ring carbon atoms, and combinations thereof;
more preferably, at least one or at least two or at least three or all of R₂, R₃, R₆, and R₇ is(are) selected from the group consisting of: deuterium, methyl, ethyl, propyl, isopropyl, n-butyl, isobutyl, t-butyl, cyclopentyl, cyclohexyl, neopentyl, t-pentyl, and combinations thereof, optionally, hydrogen in the above groups can be partially or fully substituted with deuterium.

16. The metal complex according to claim 1, wherein Lₐ is, at each occurrence identically or differently, selected from the group consisting of:

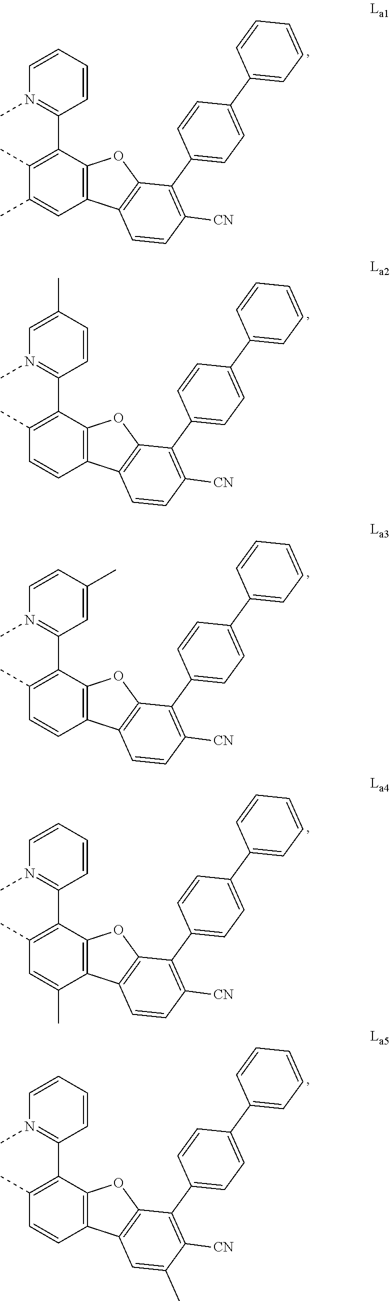

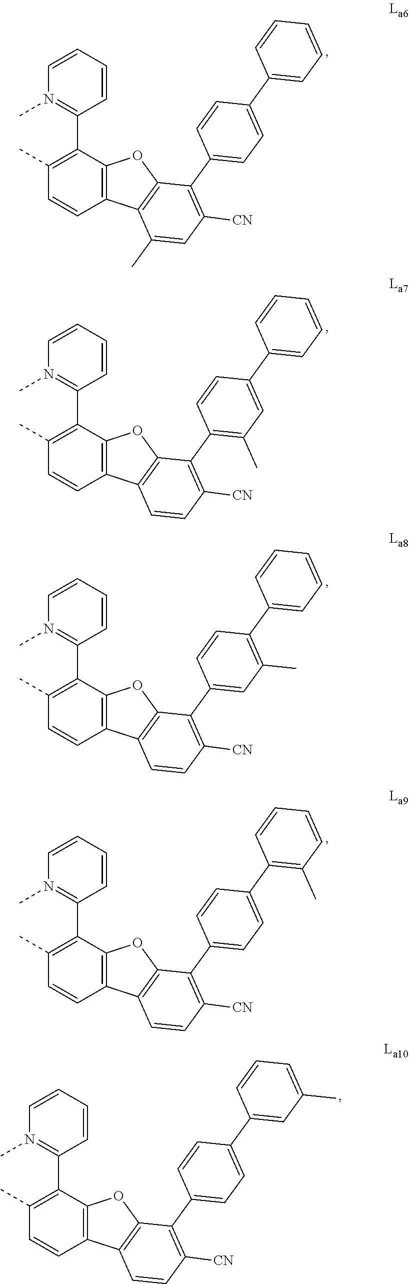

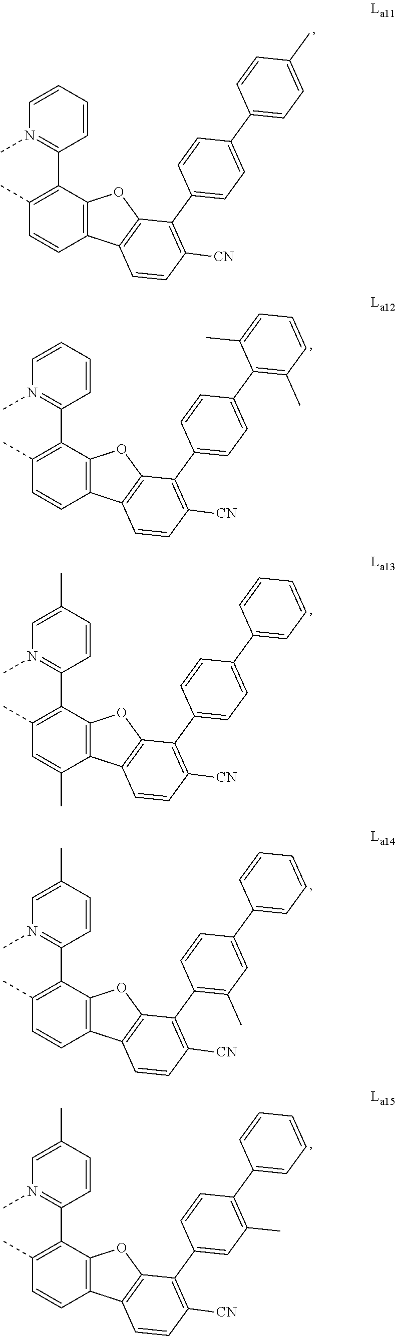

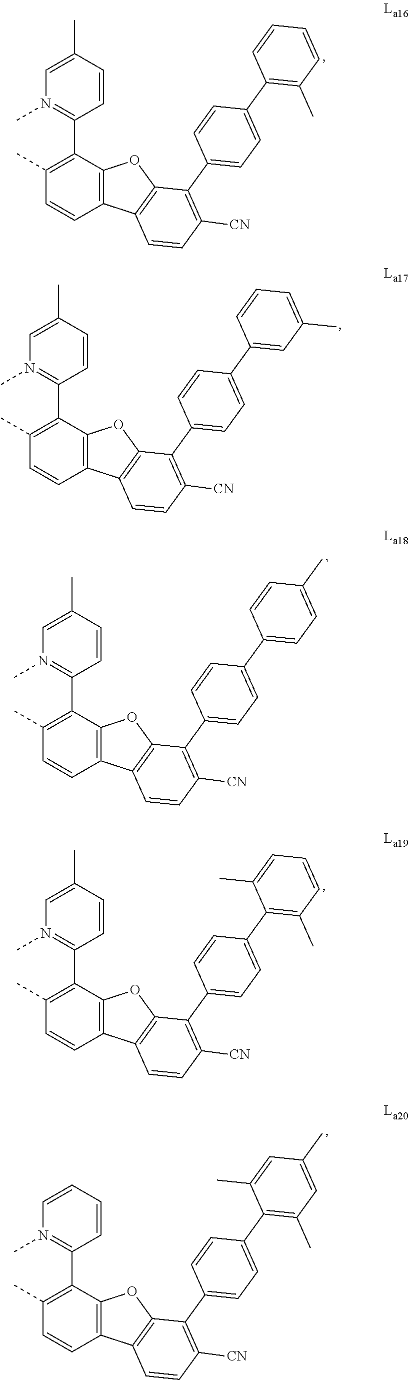

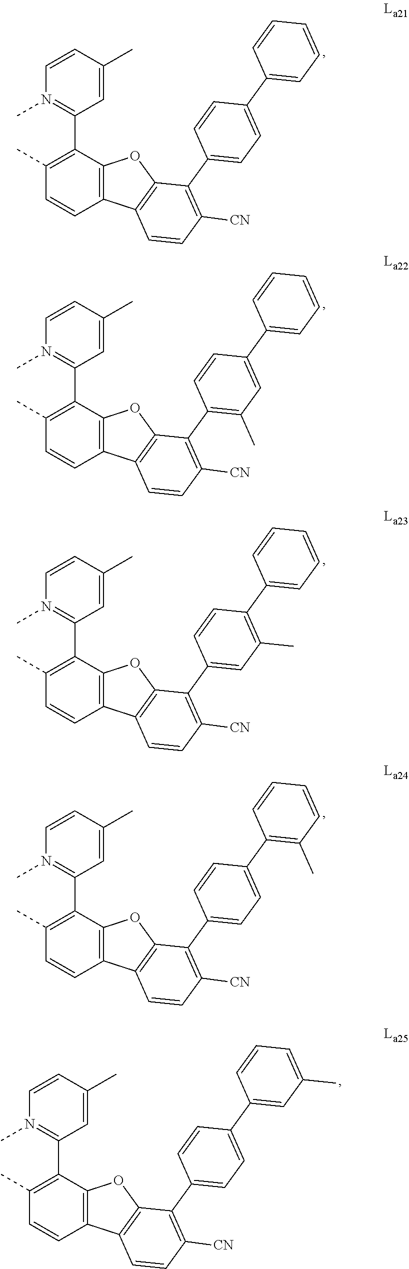

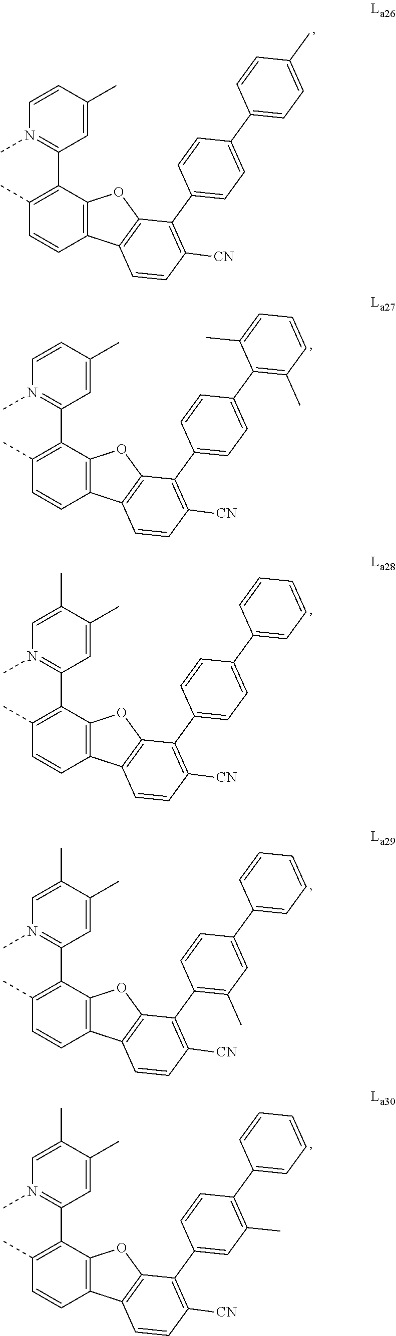

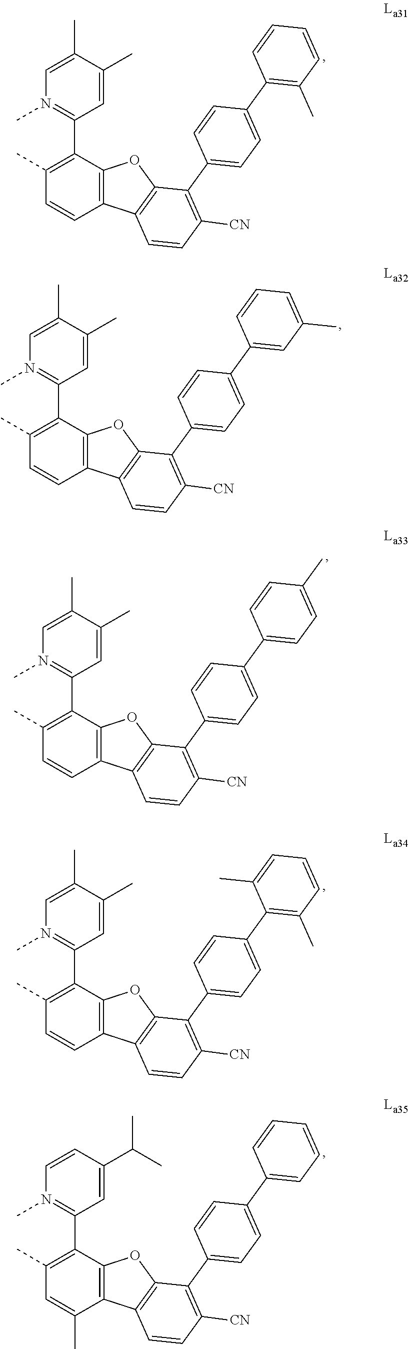

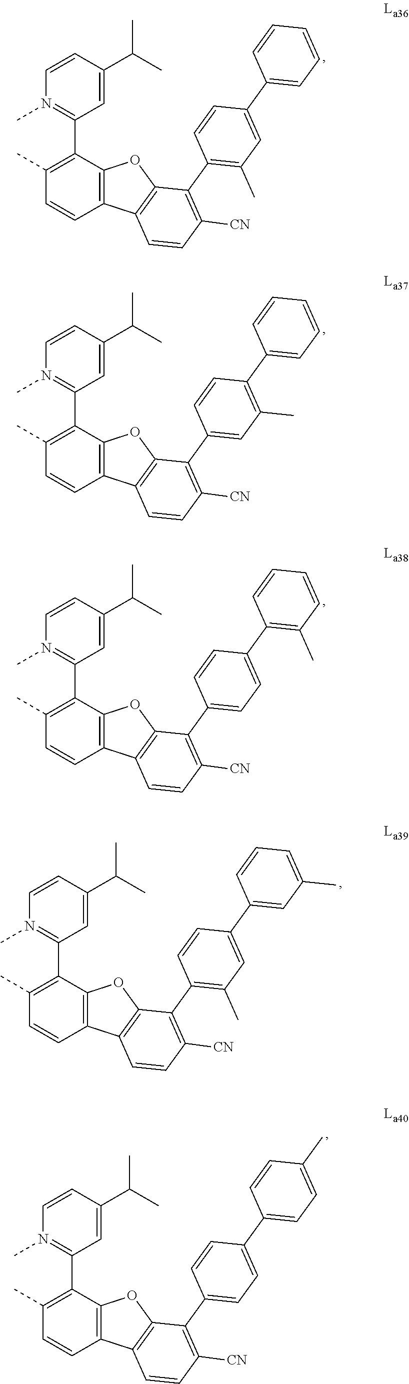

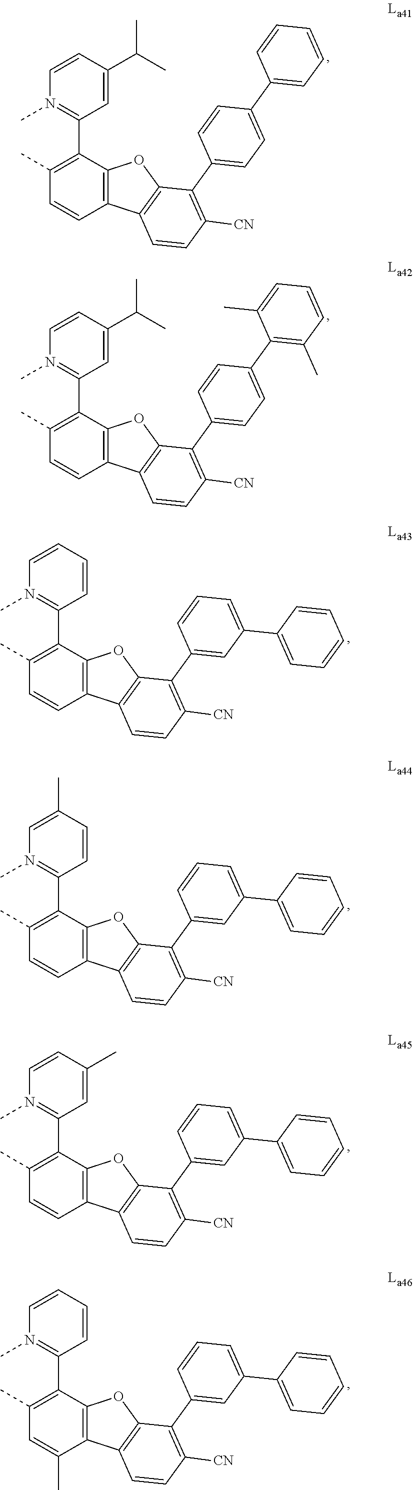

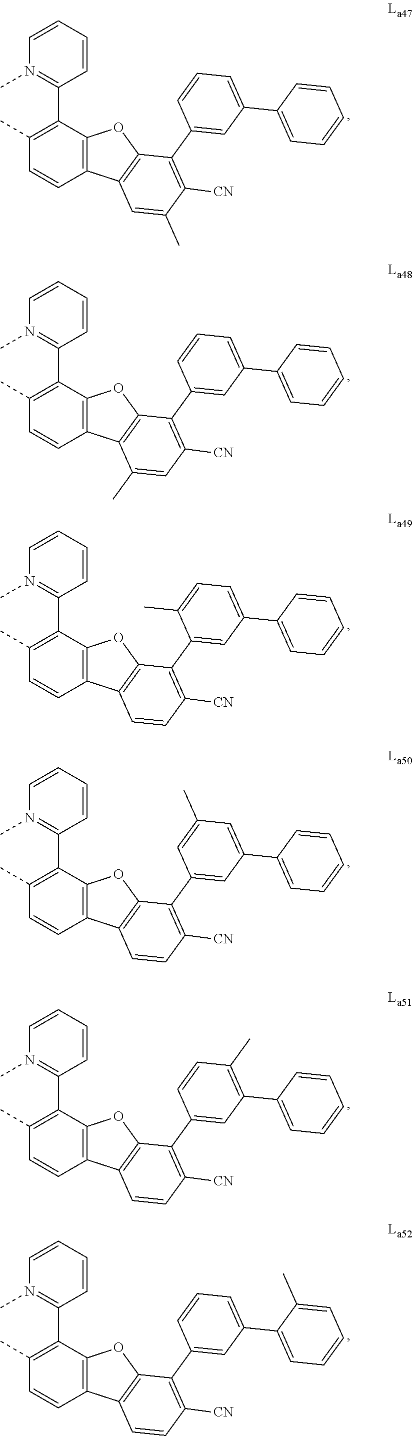

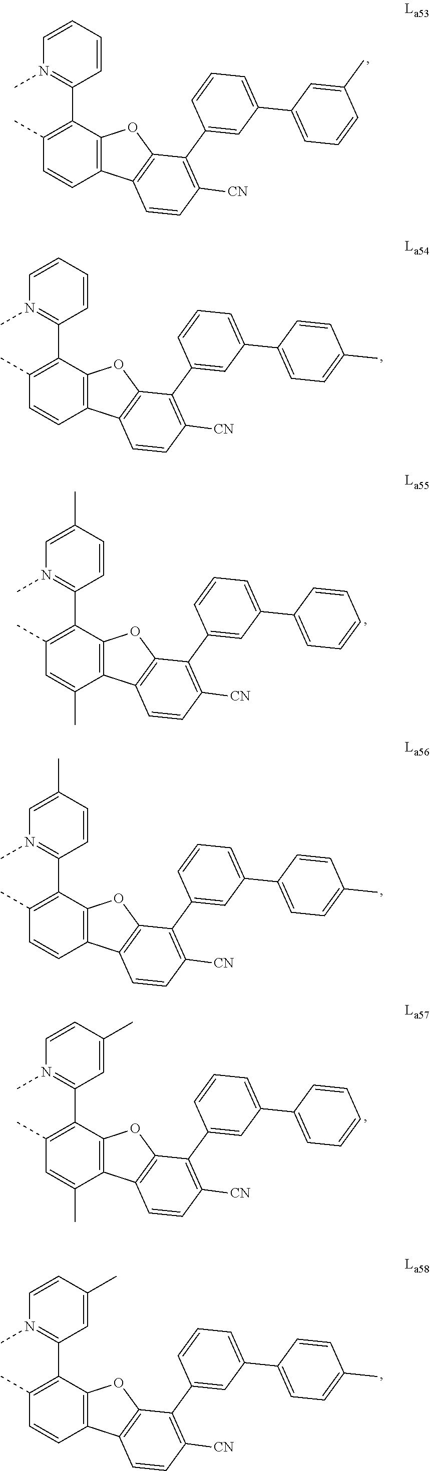

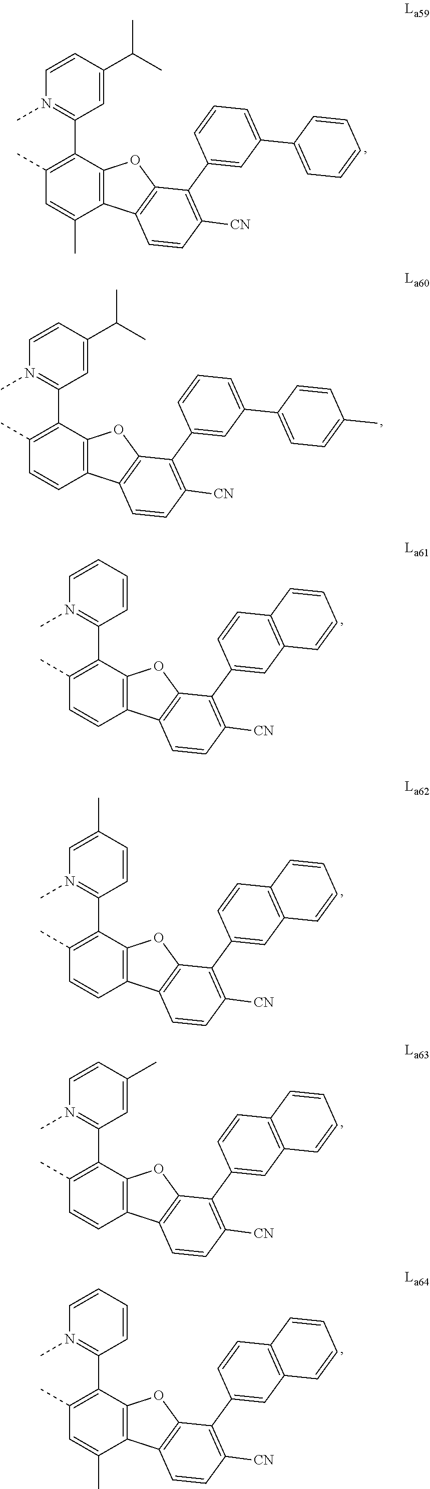

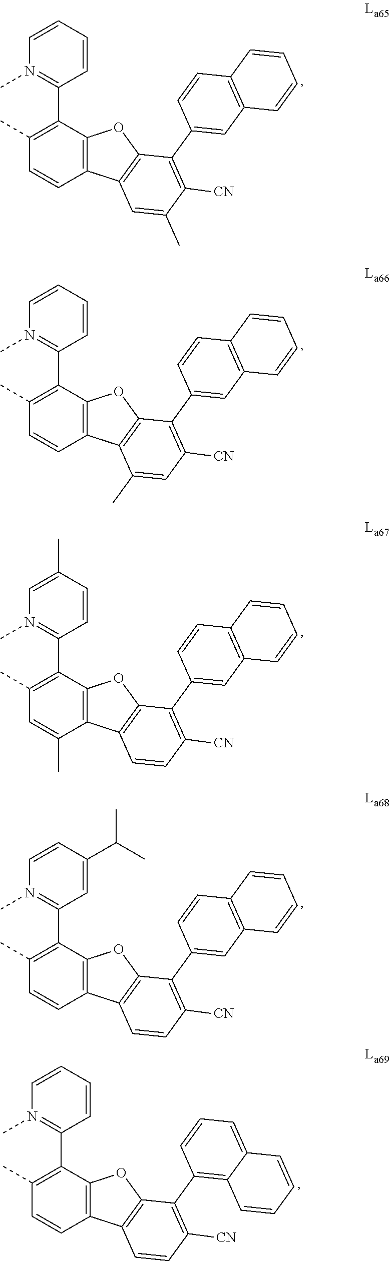

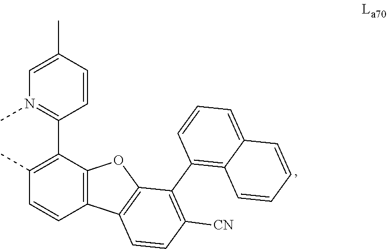

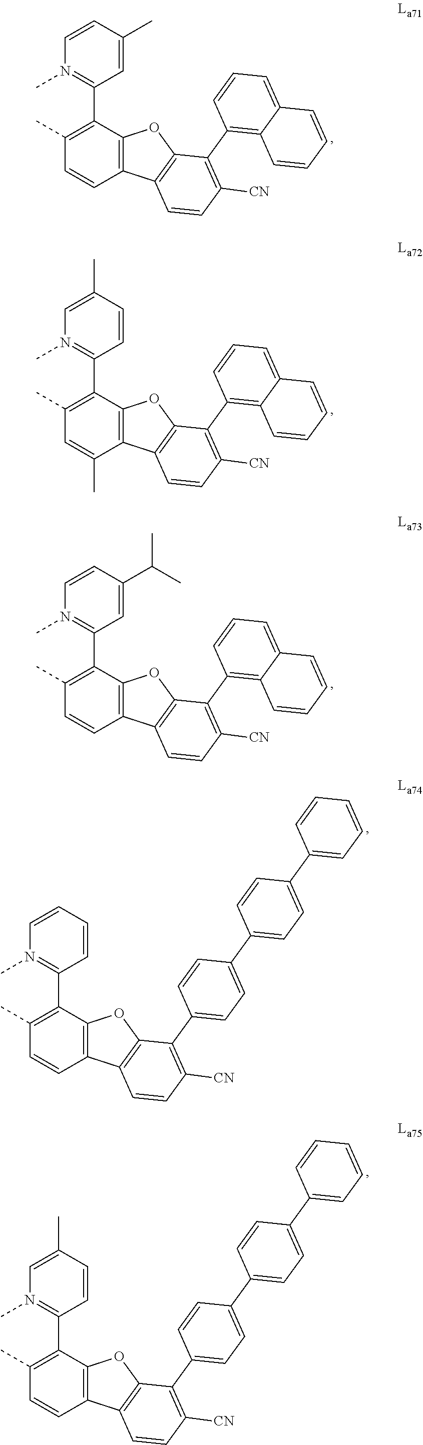

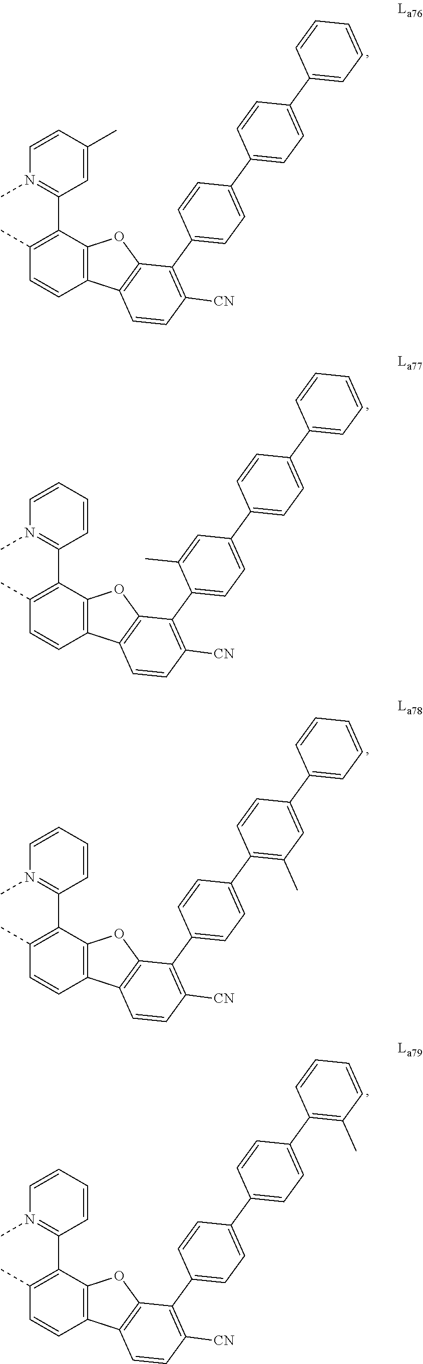

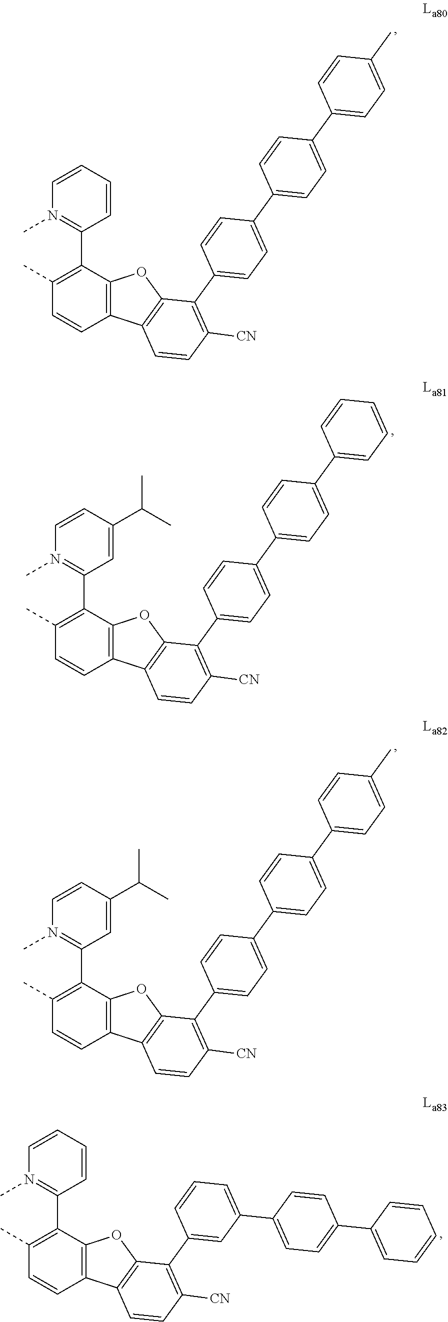

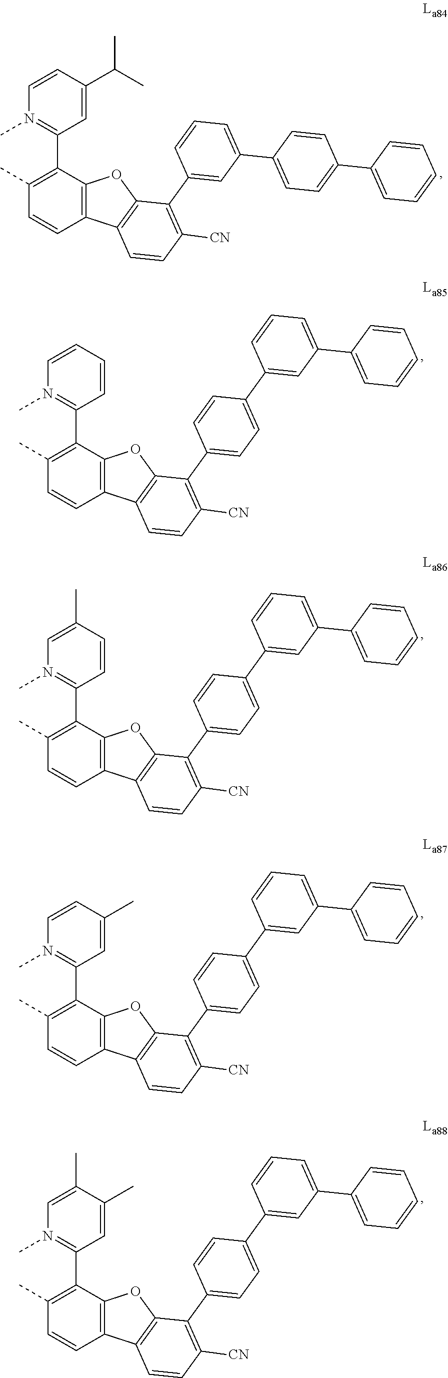

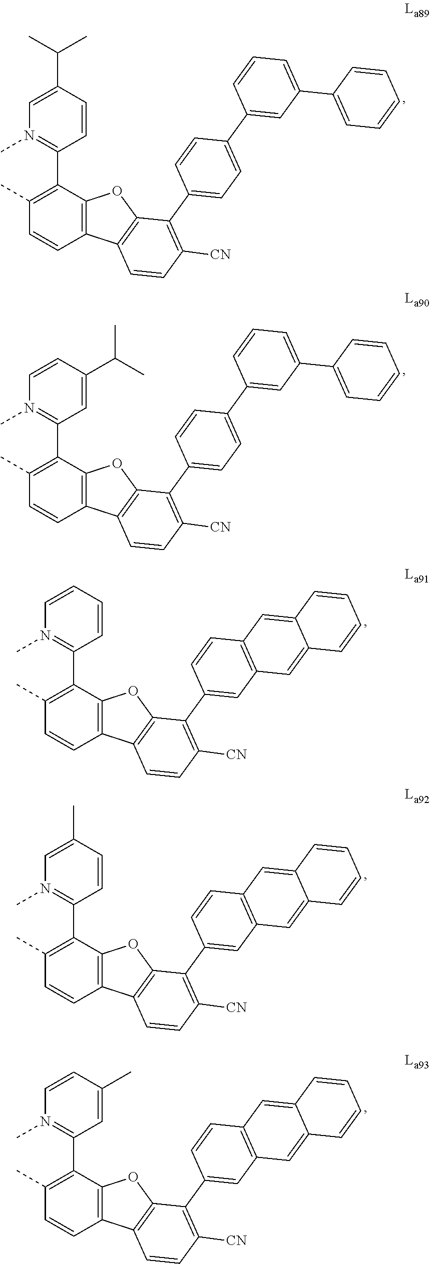

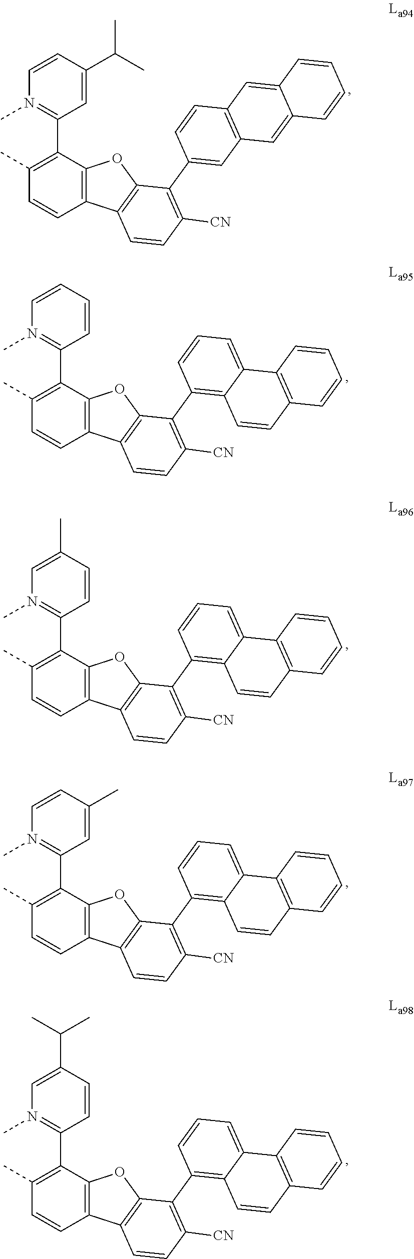

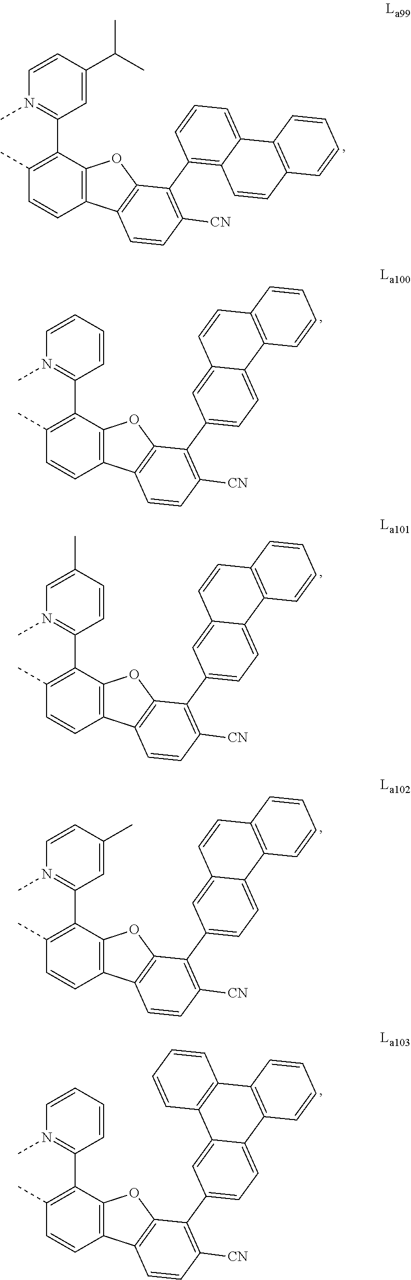

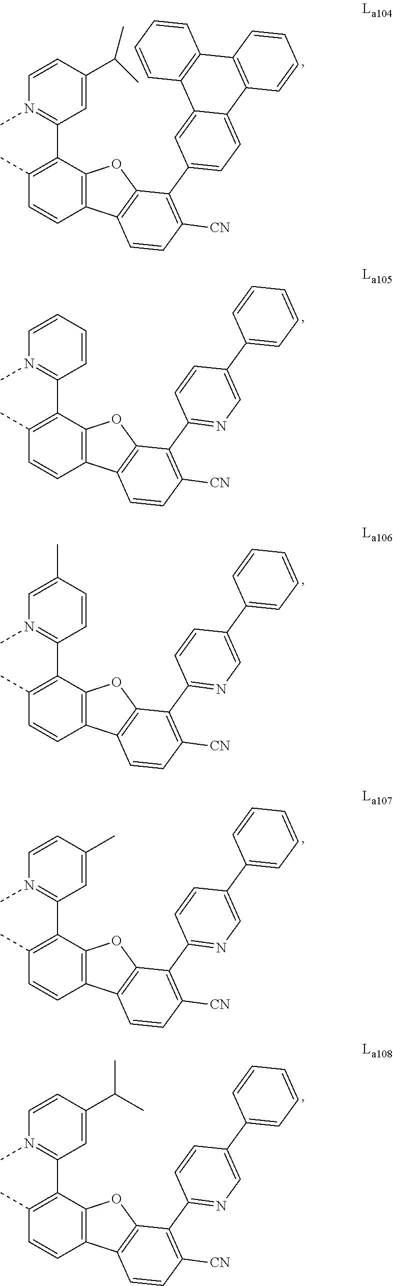

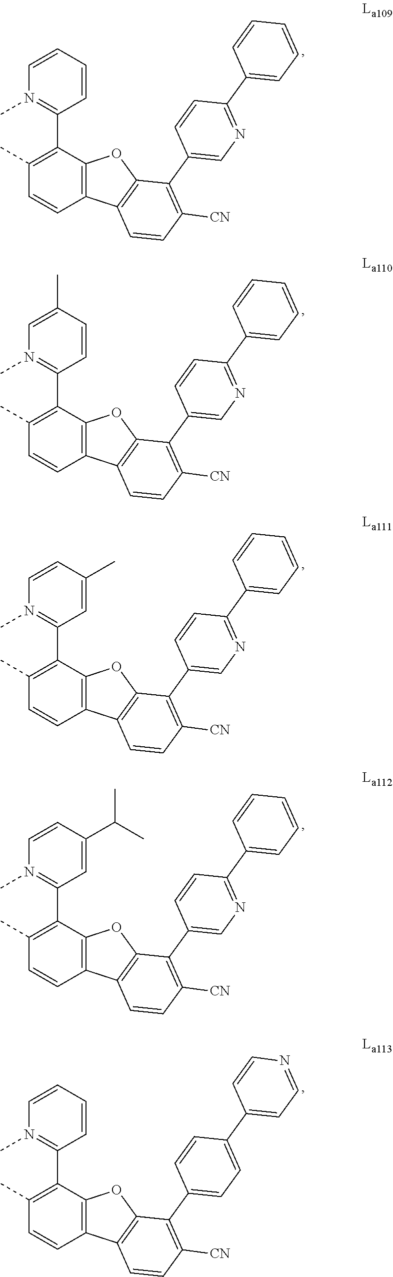

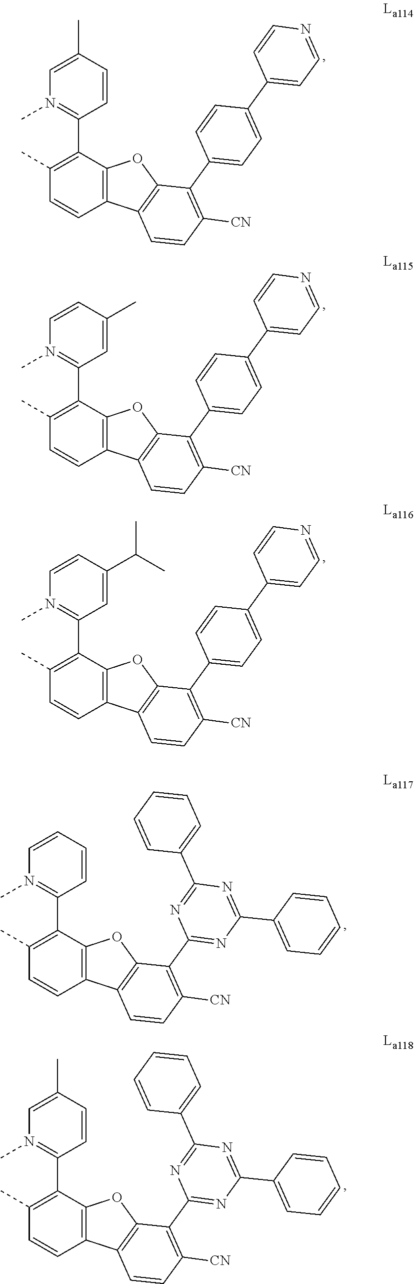

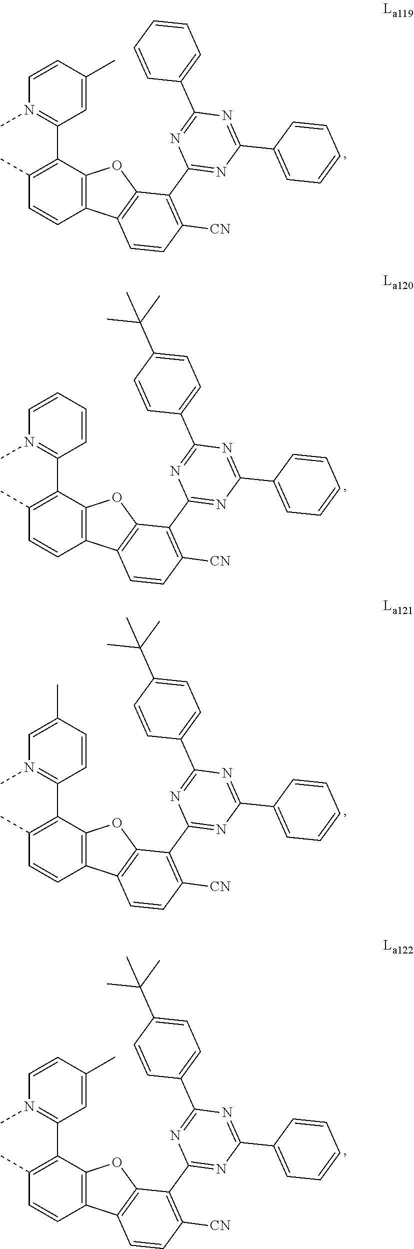

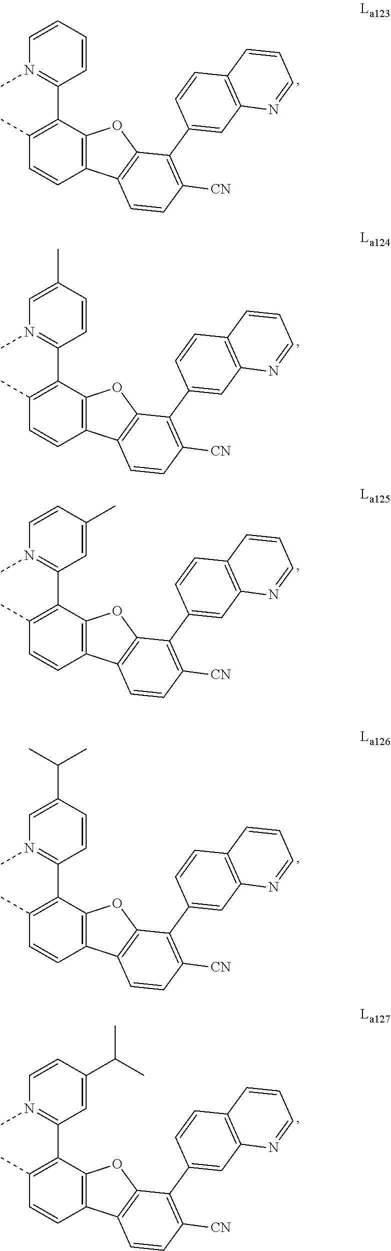

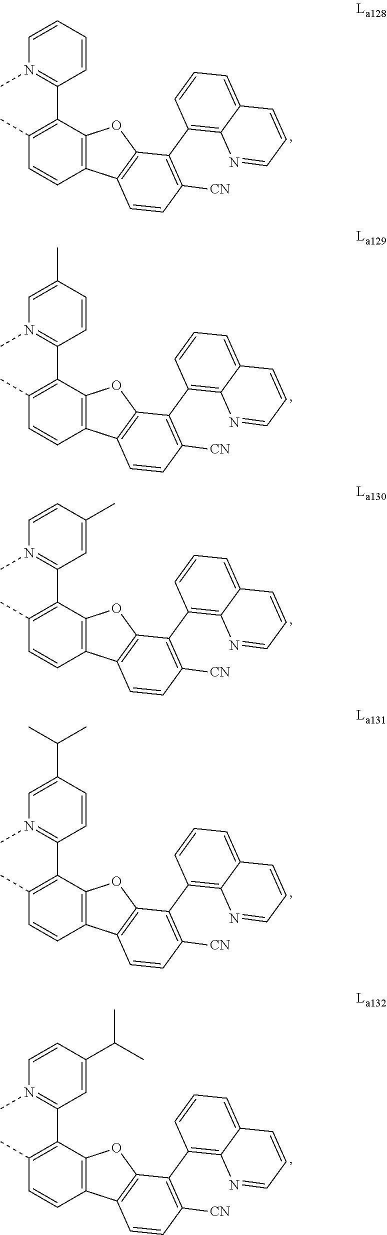

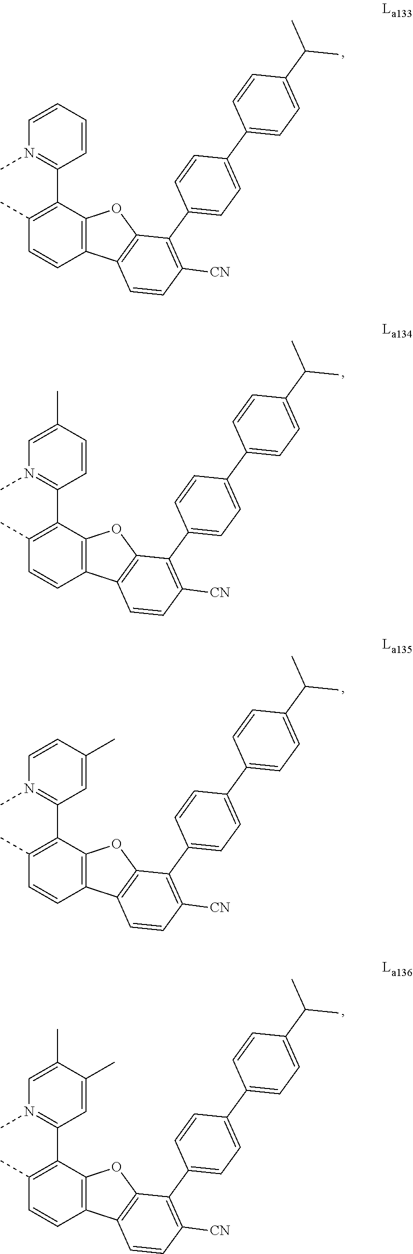

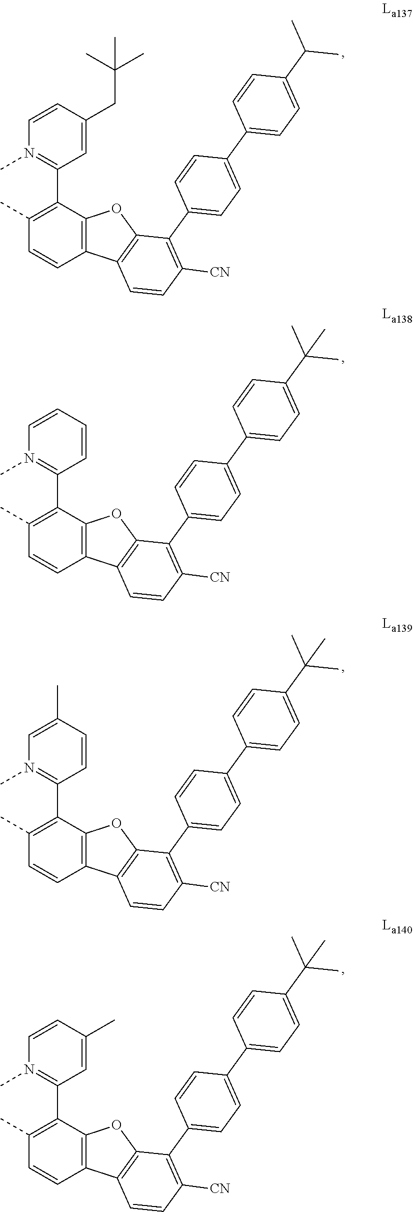

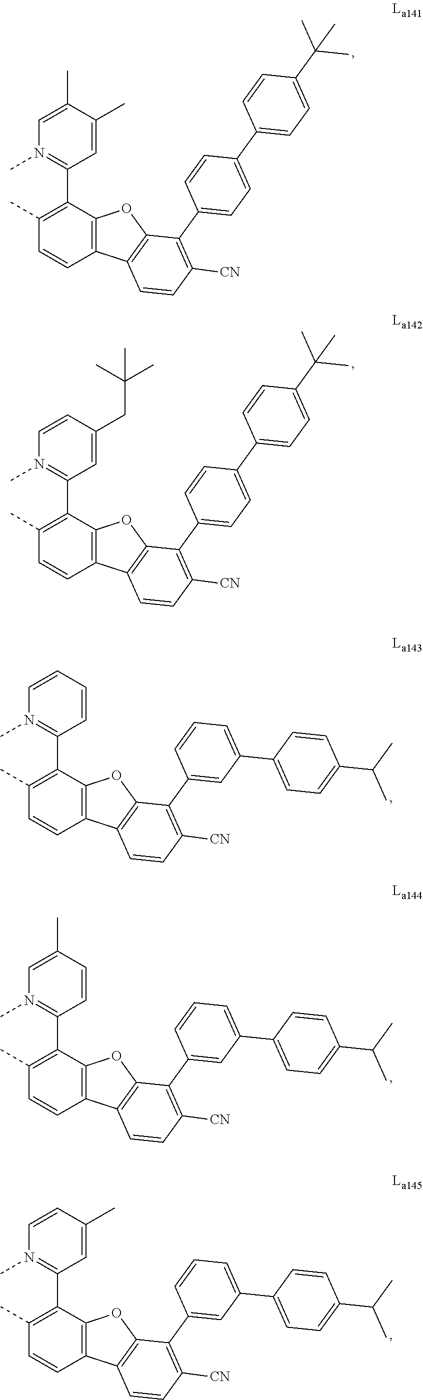

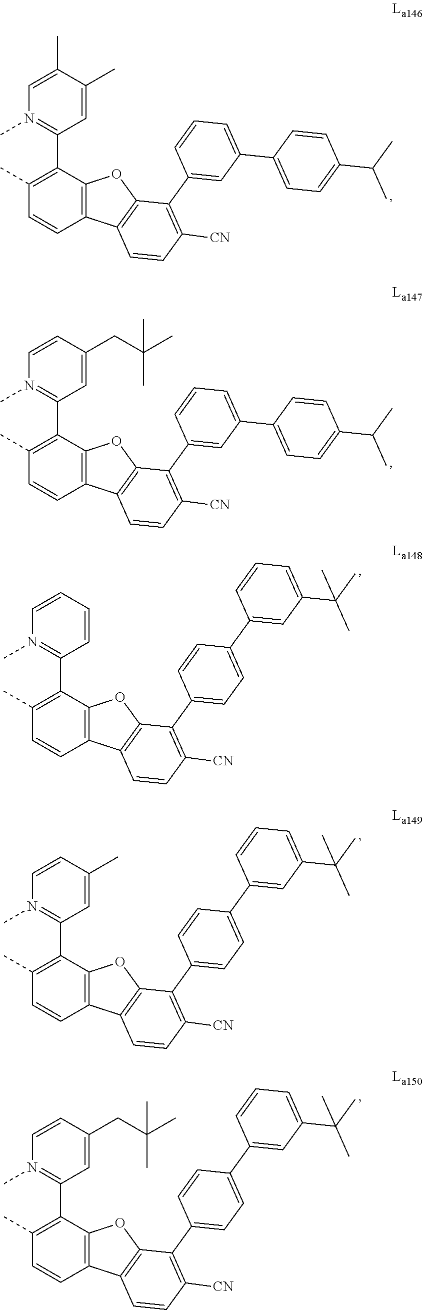

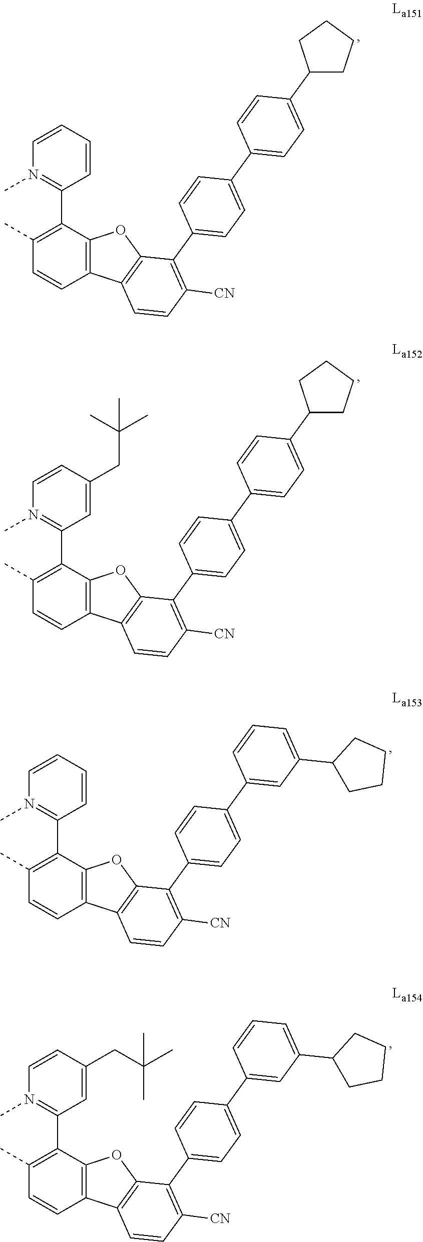

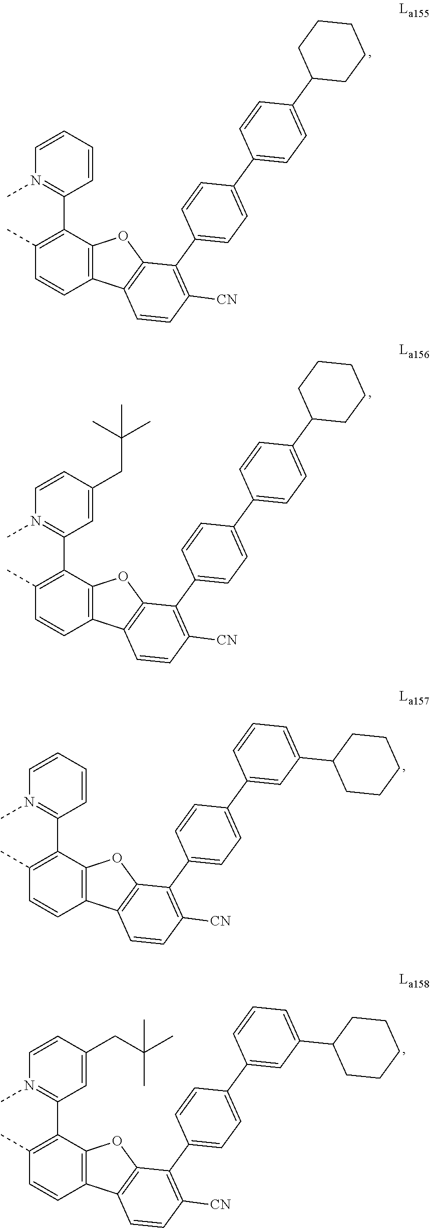

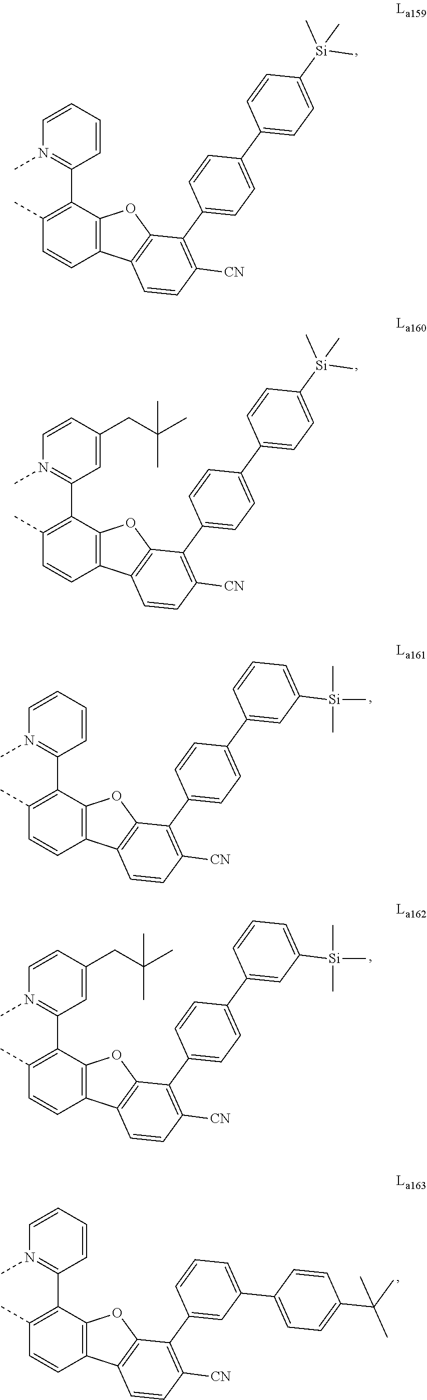

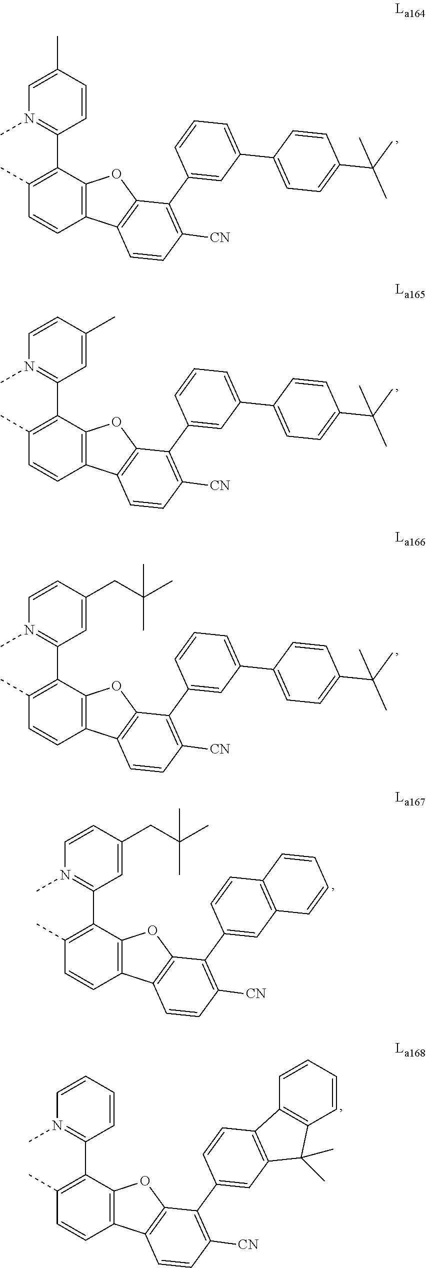

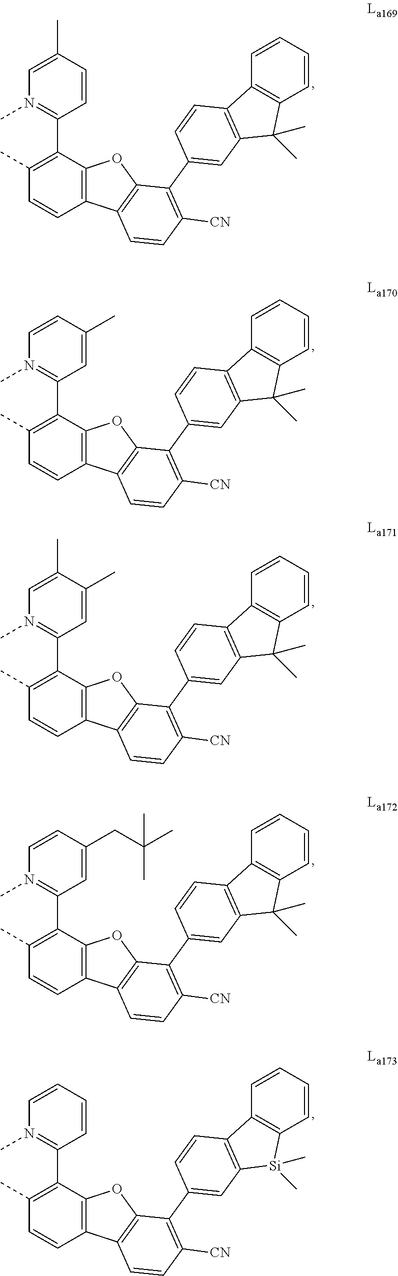

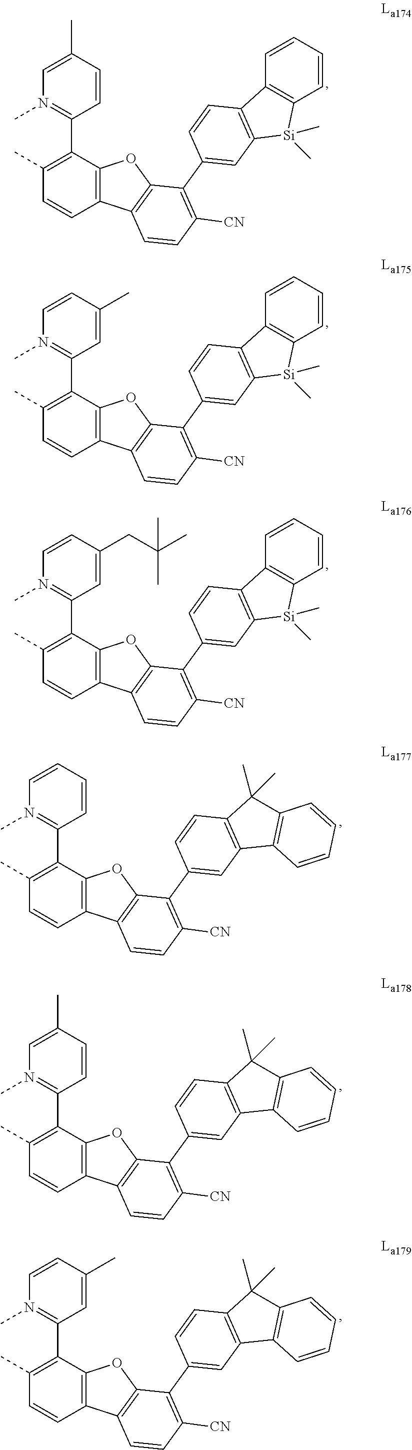

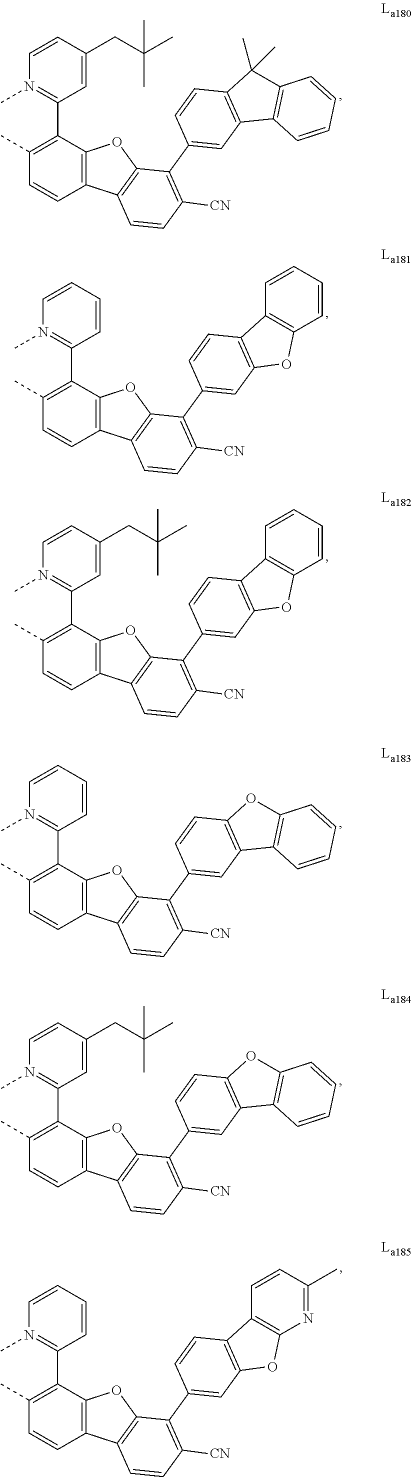

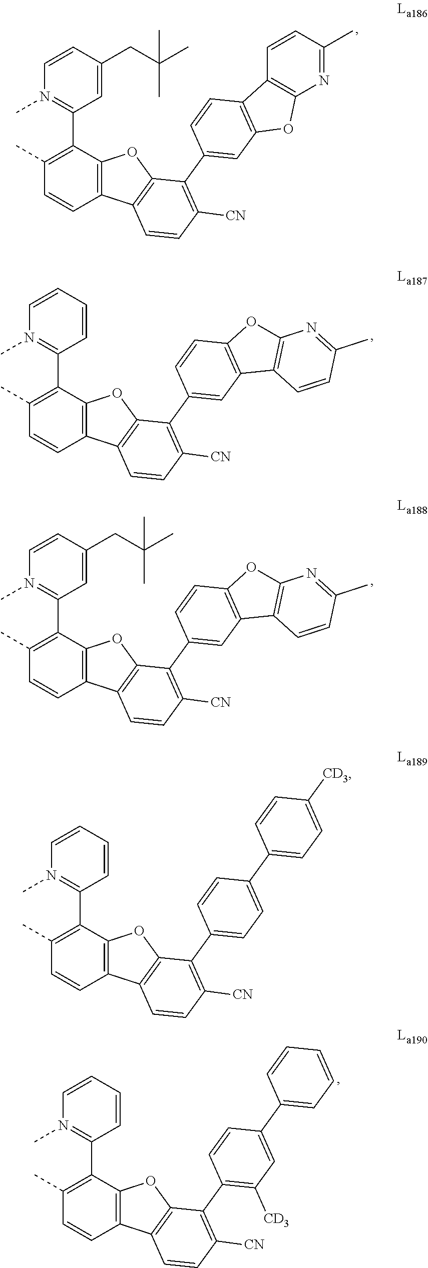

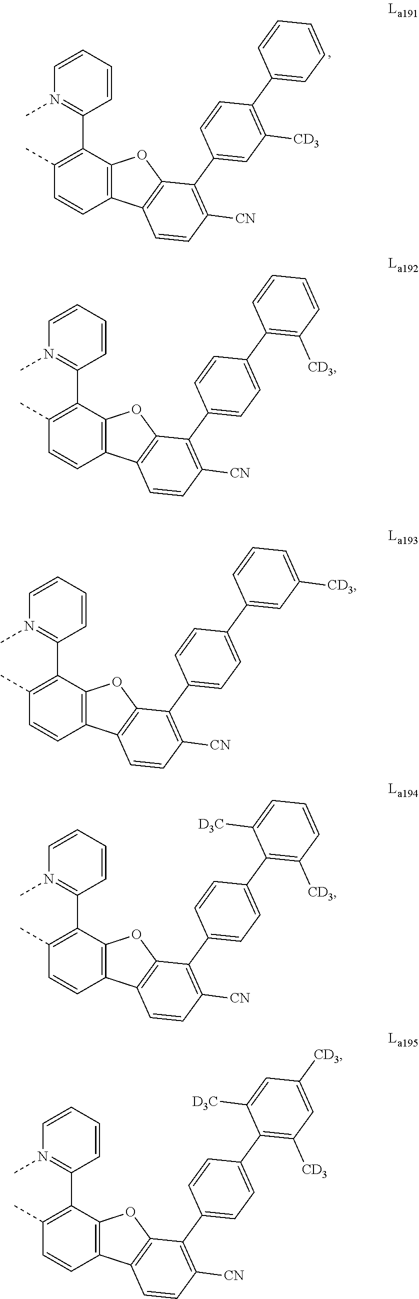

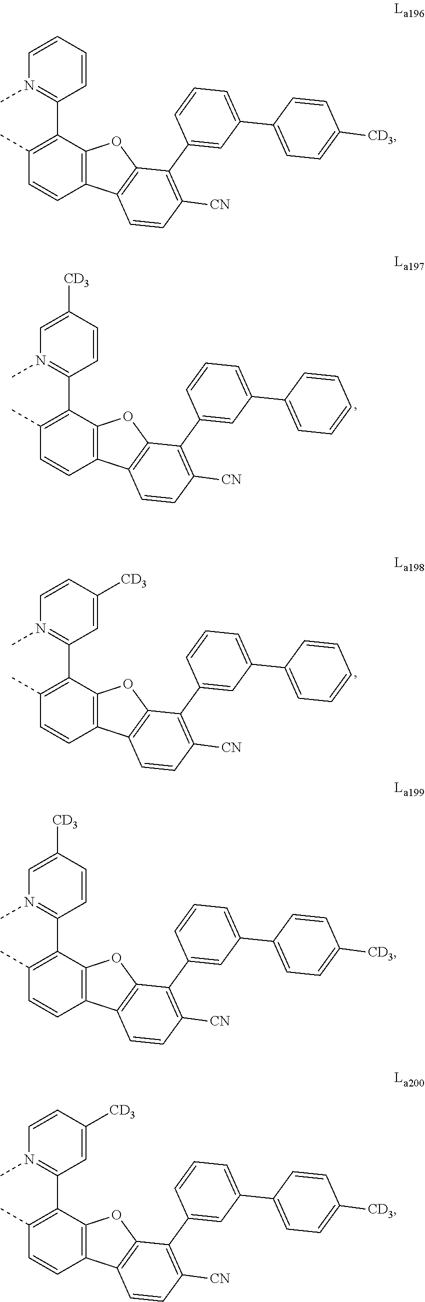

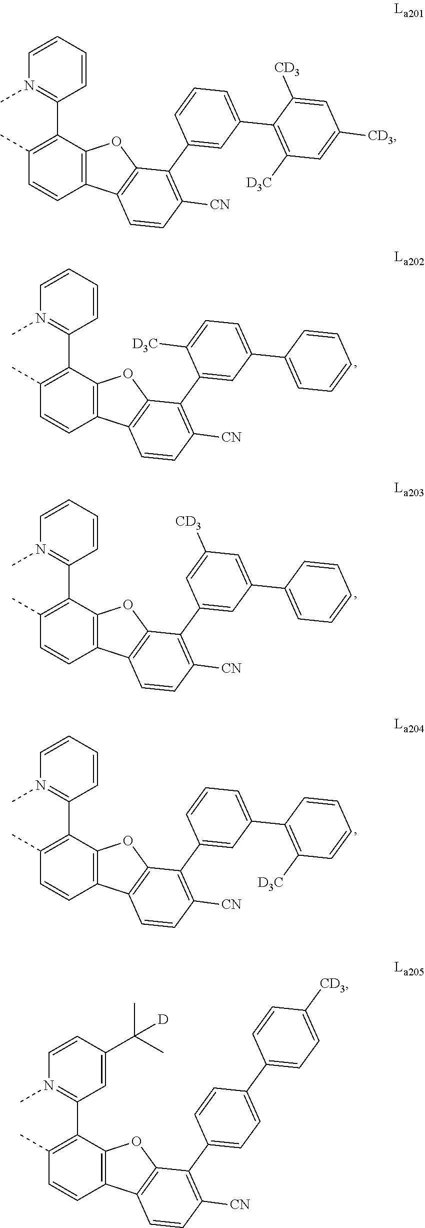

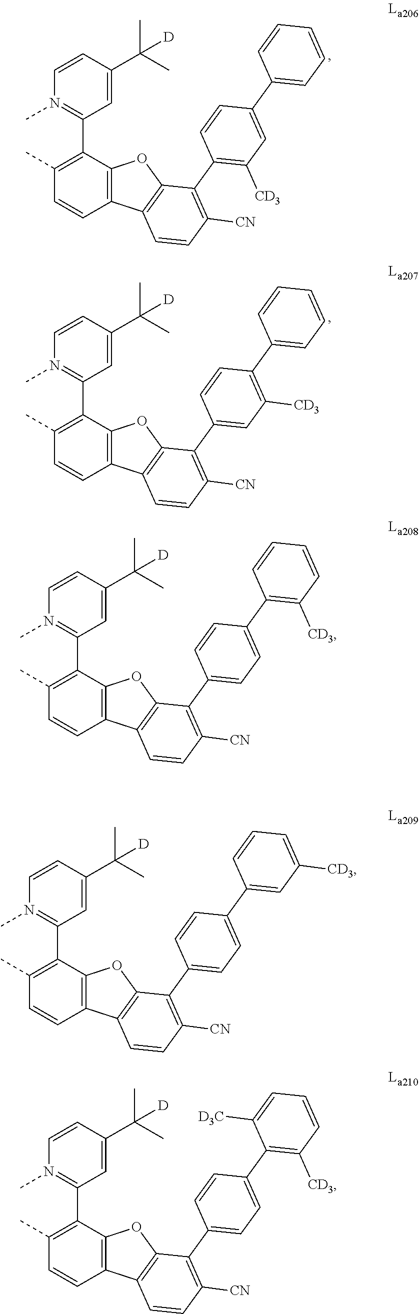

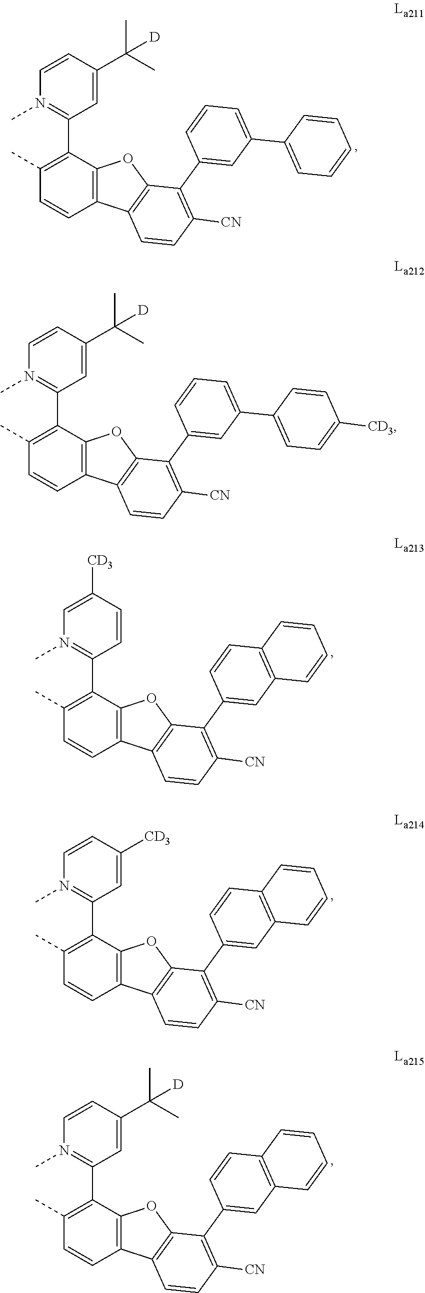

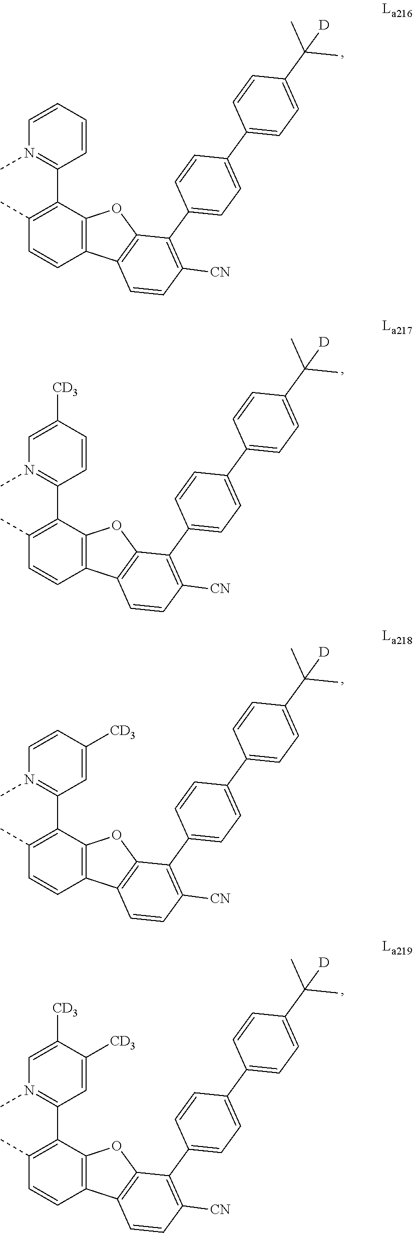

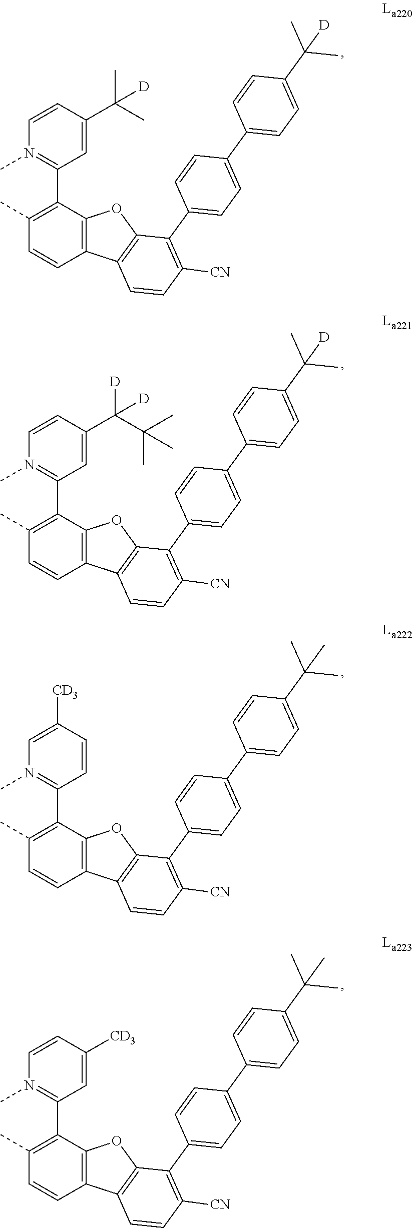

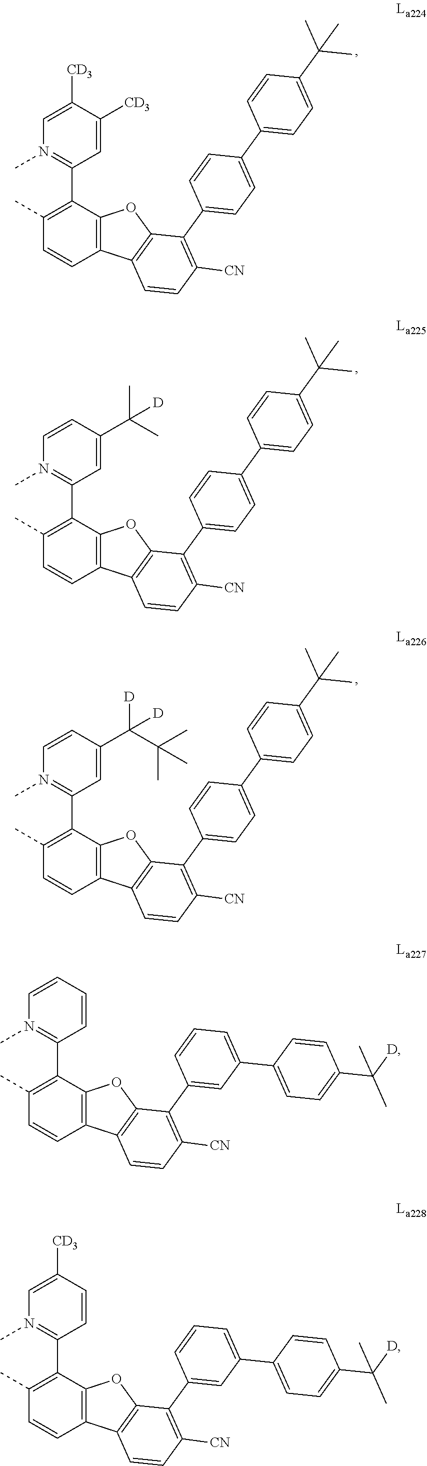

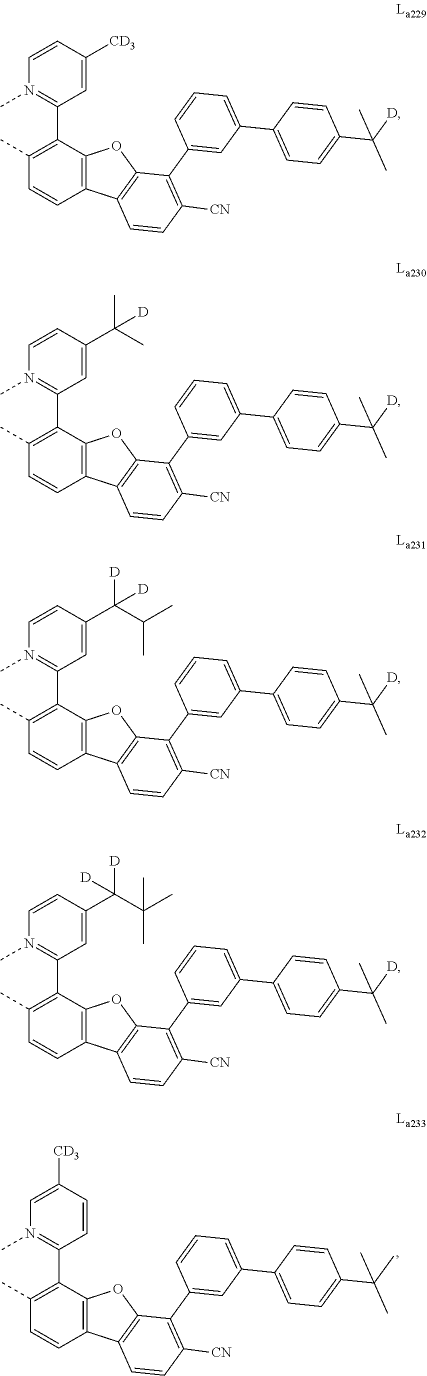

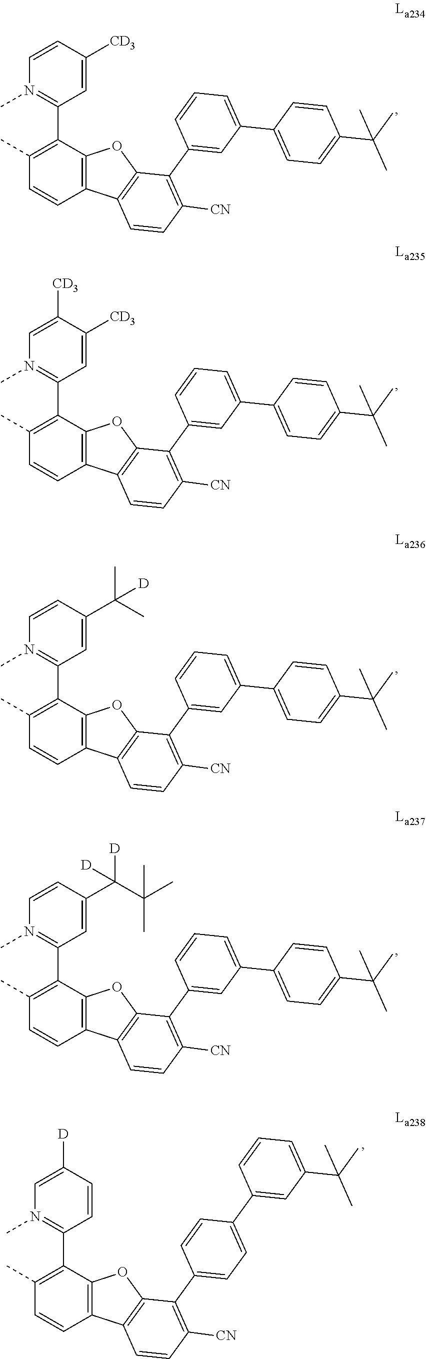

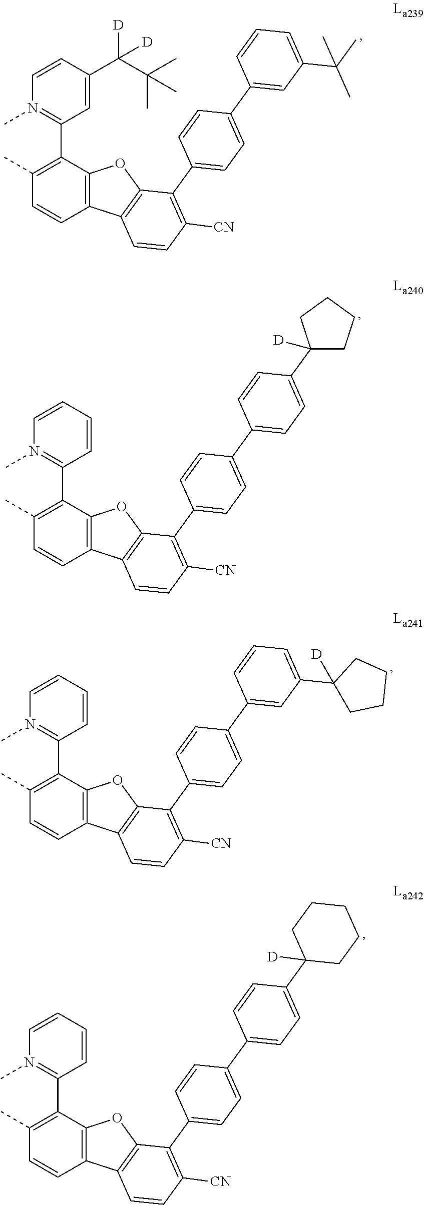

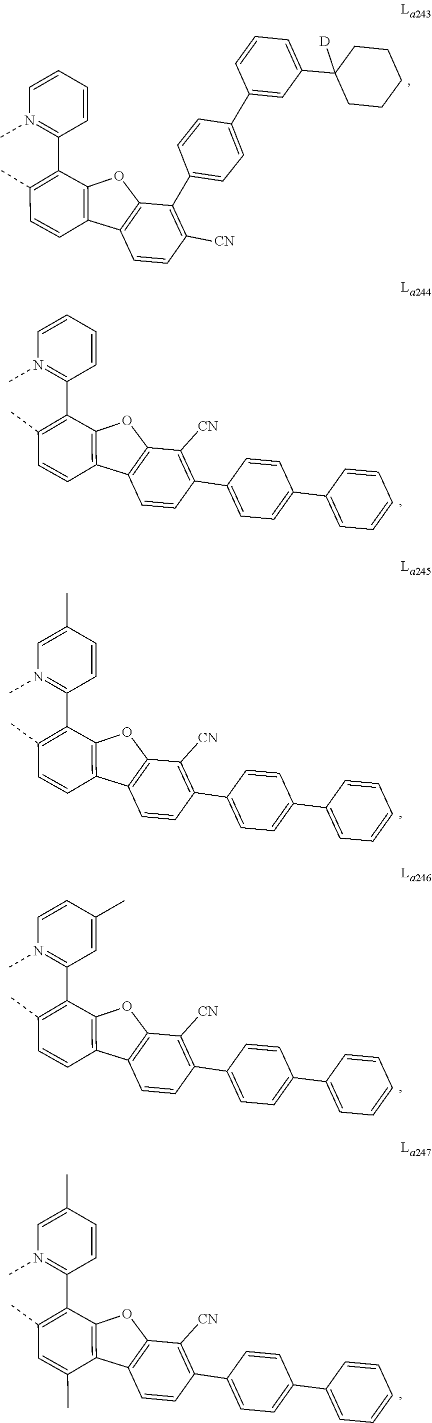

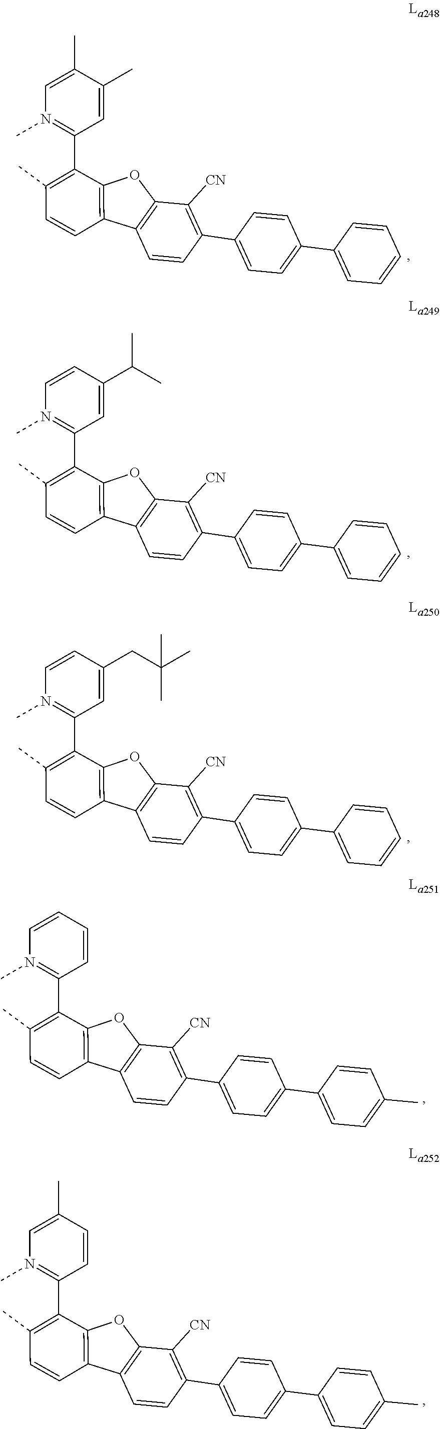

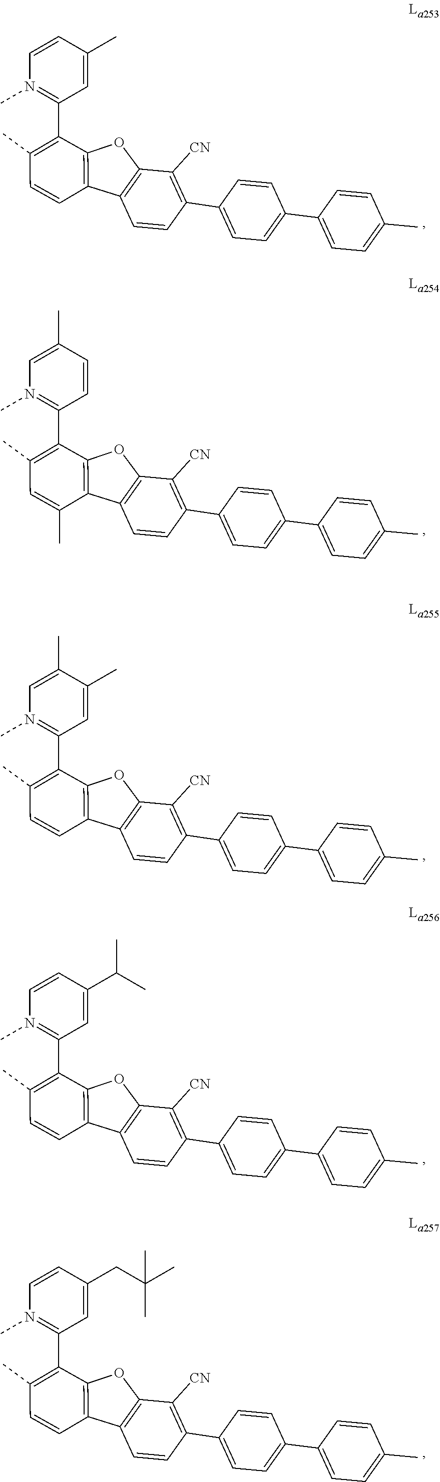

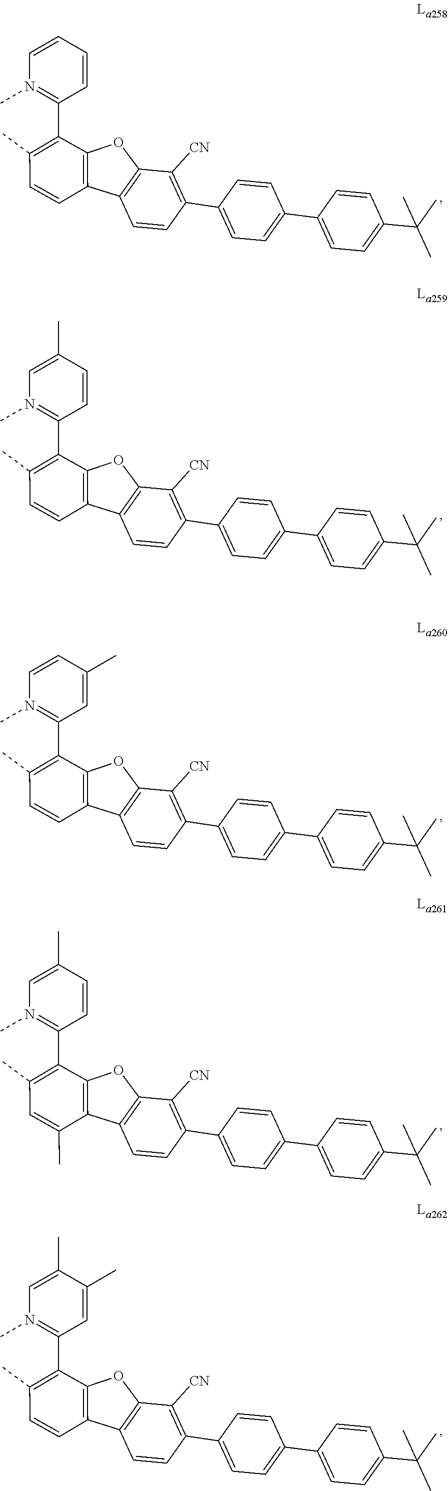

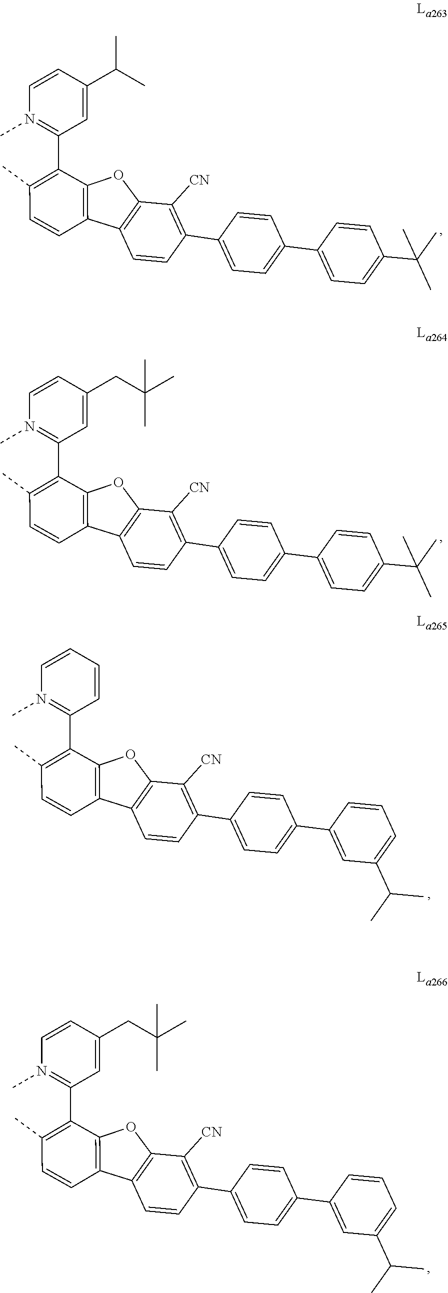

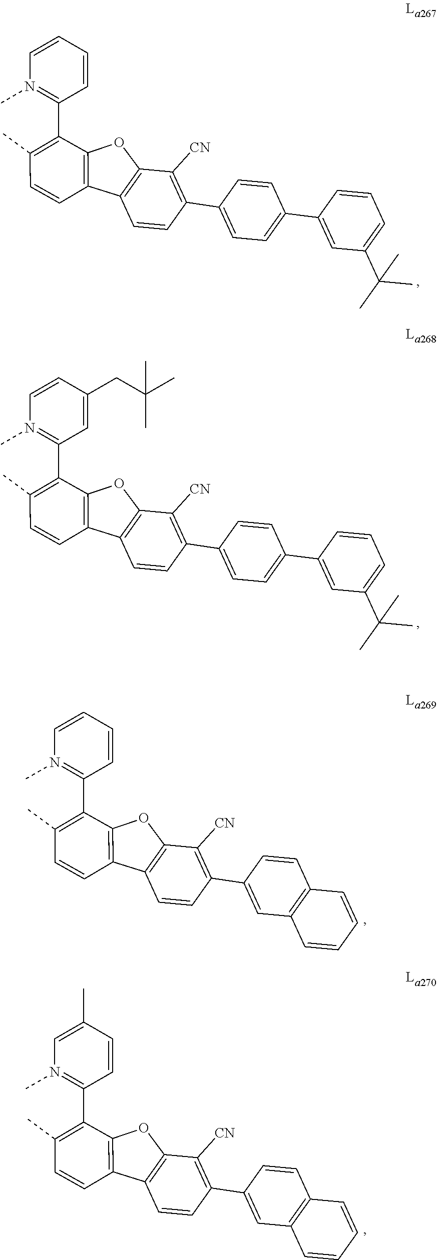

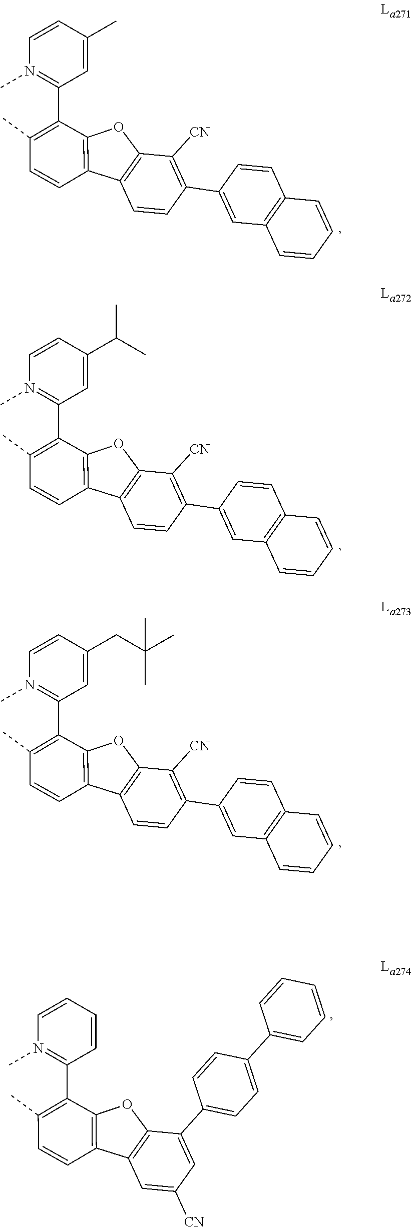

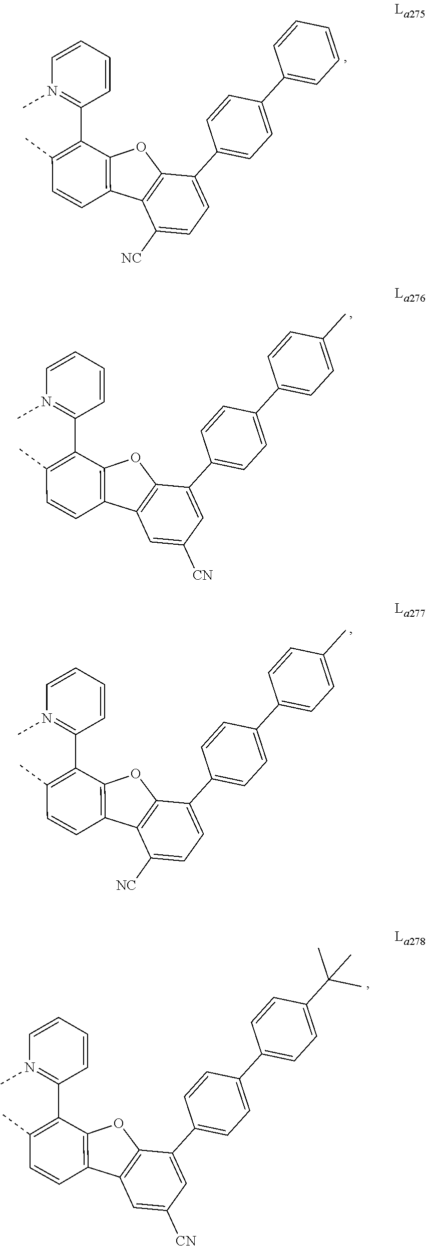

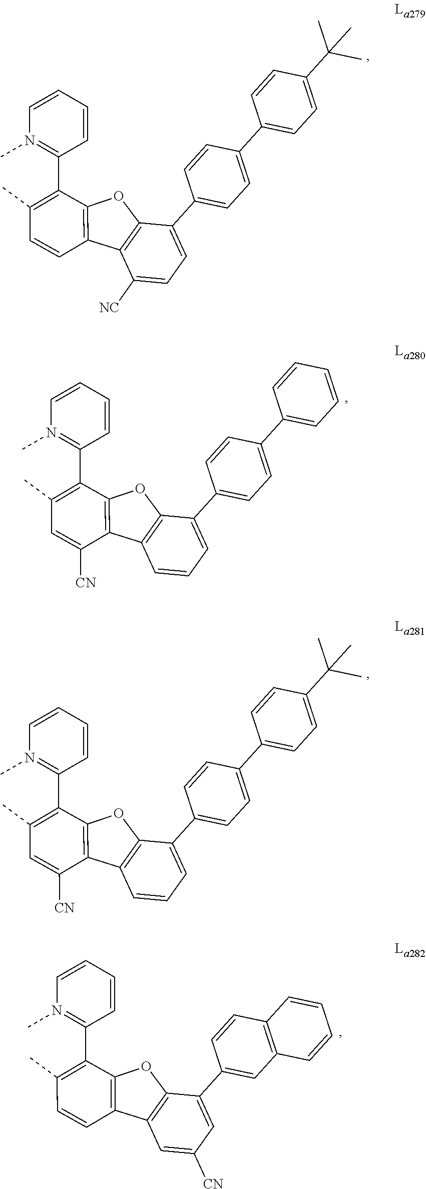

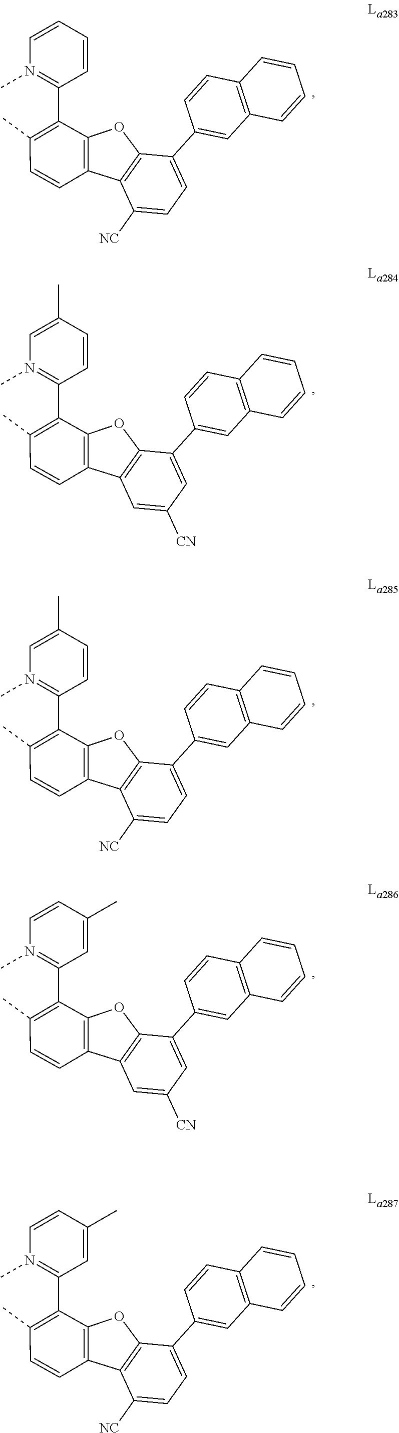

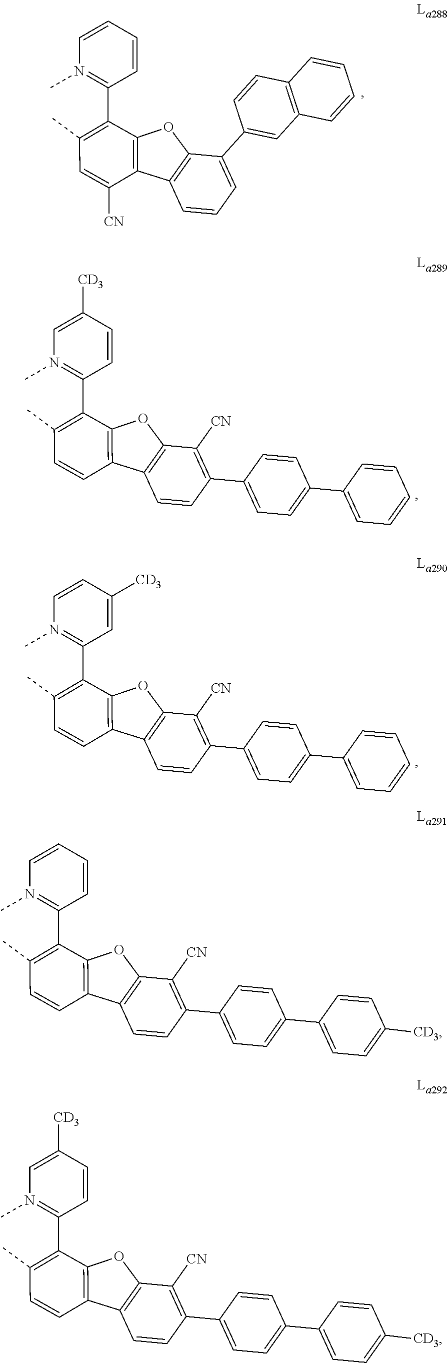

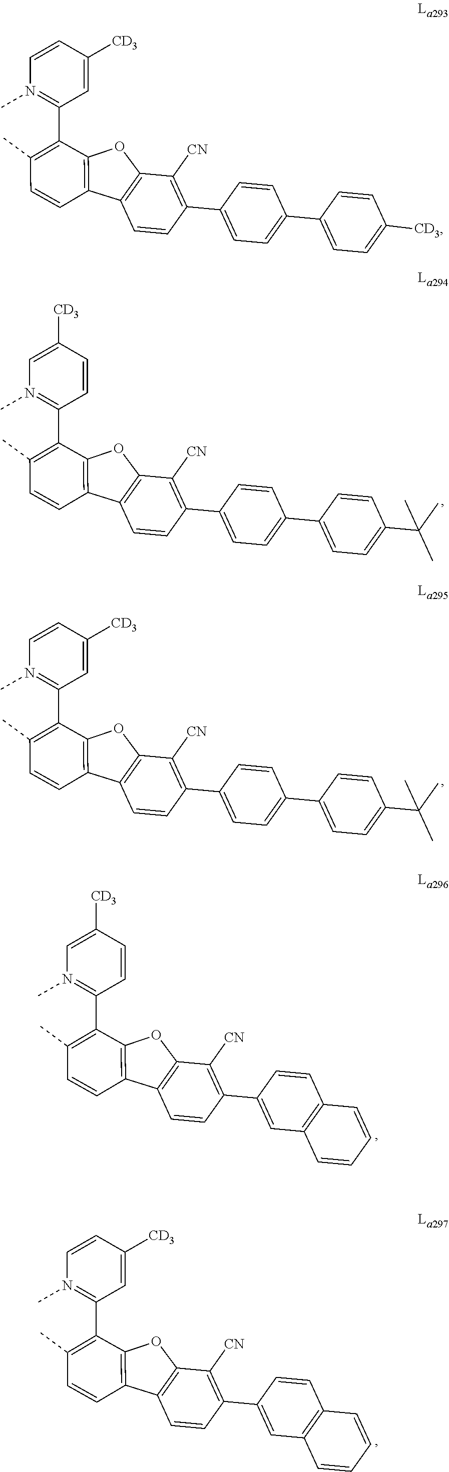

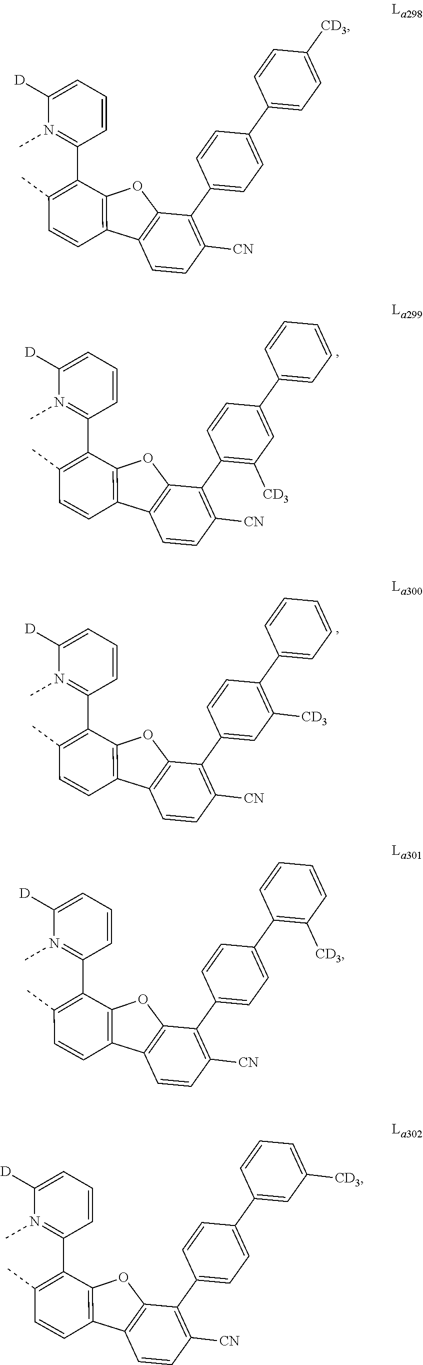

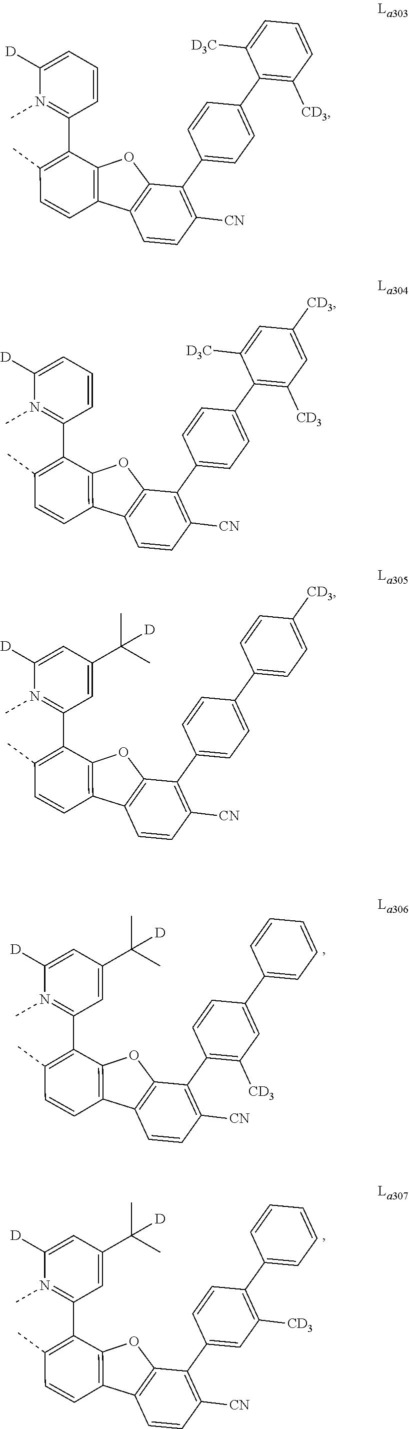

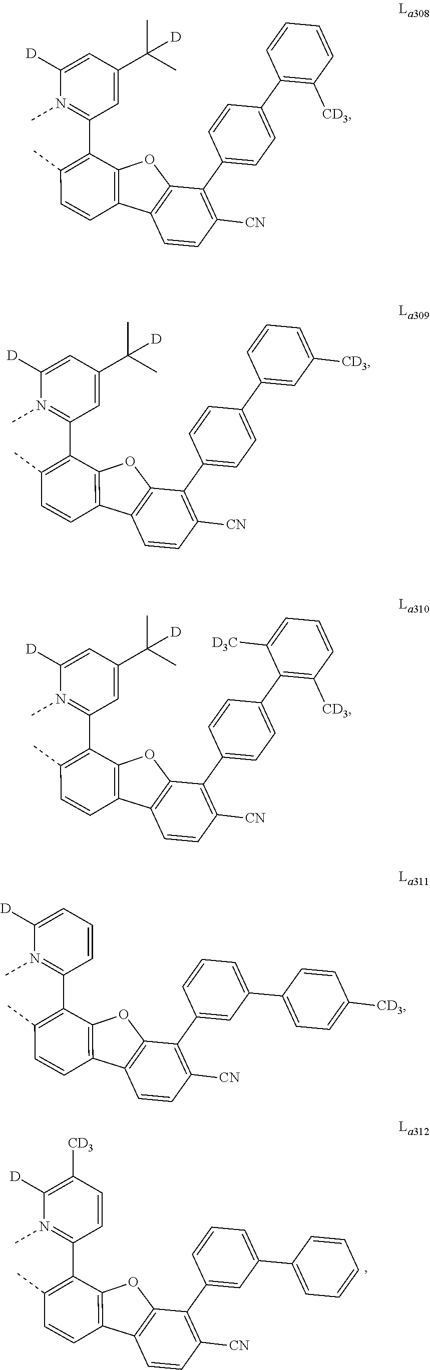

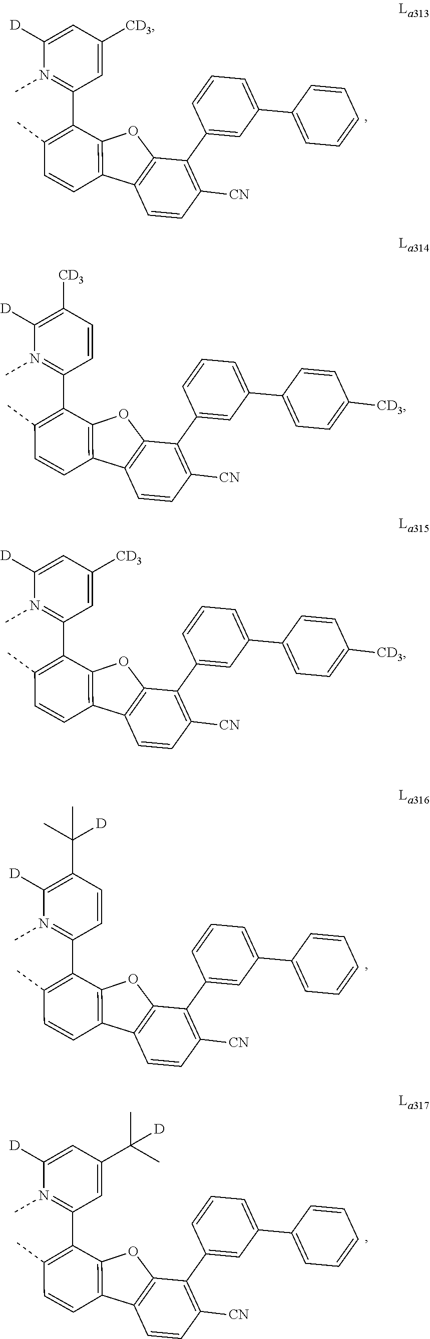

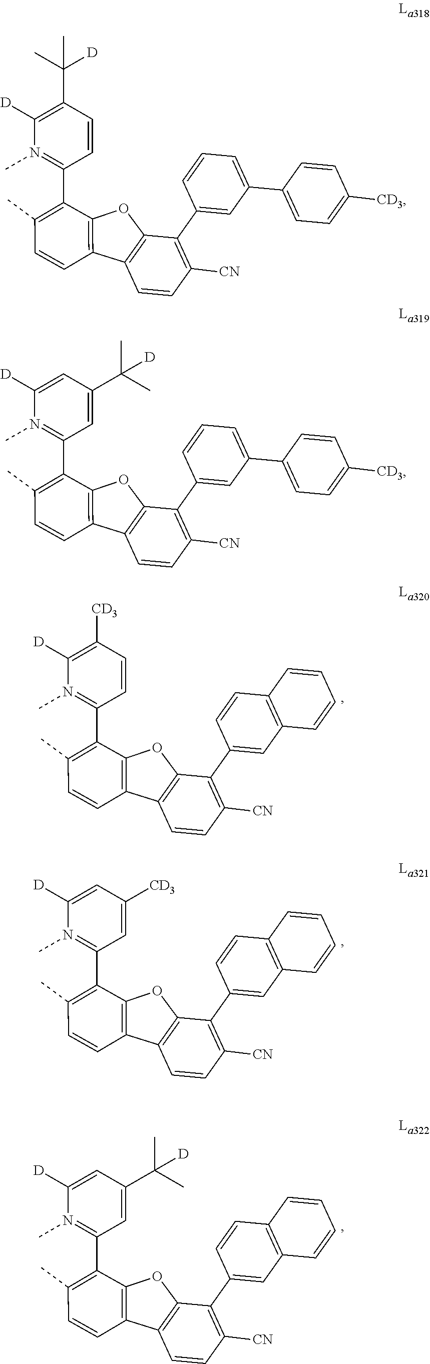

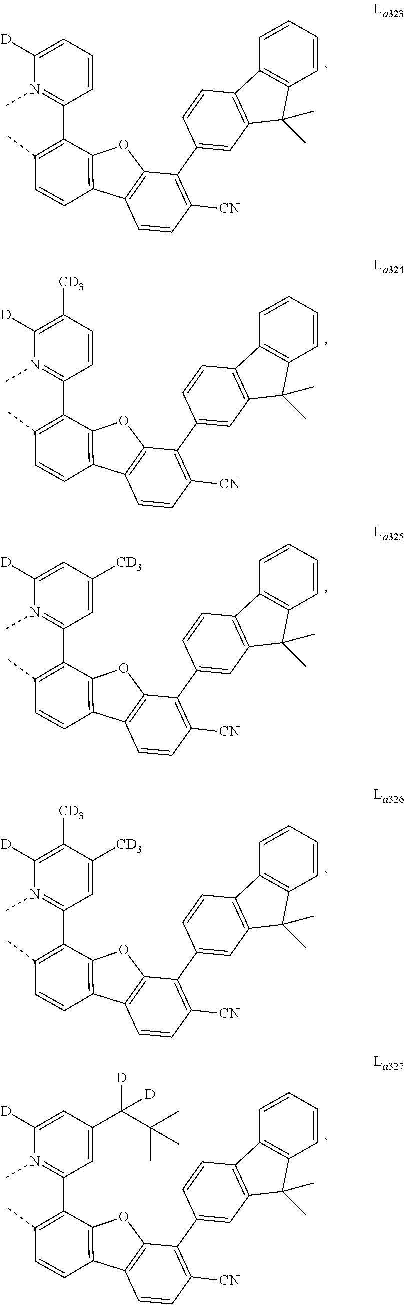

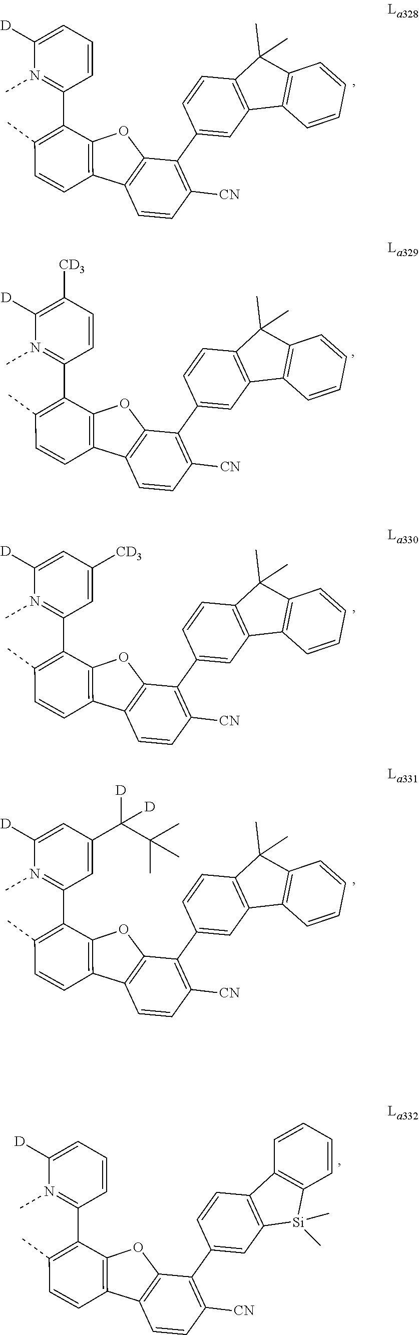

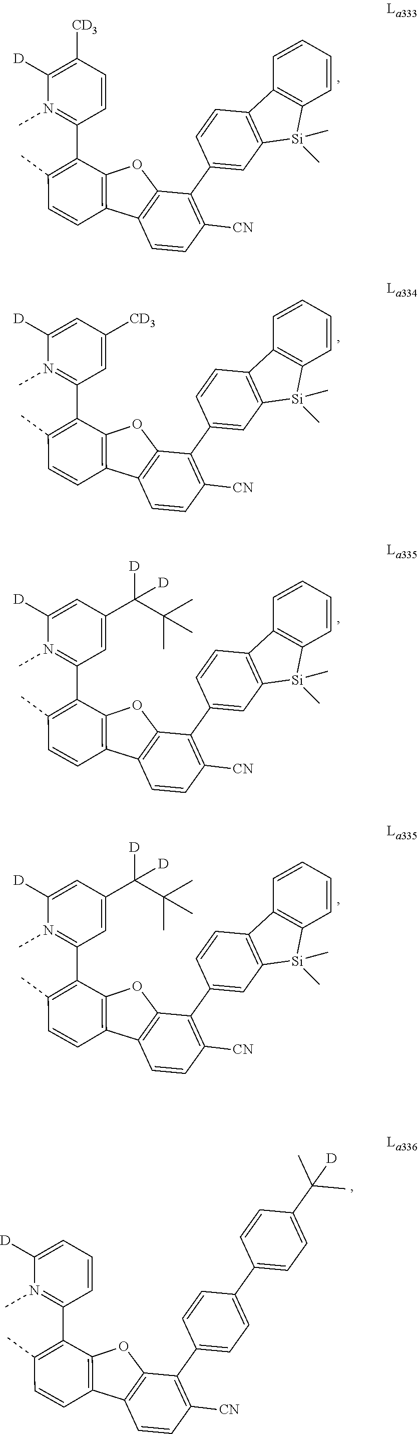

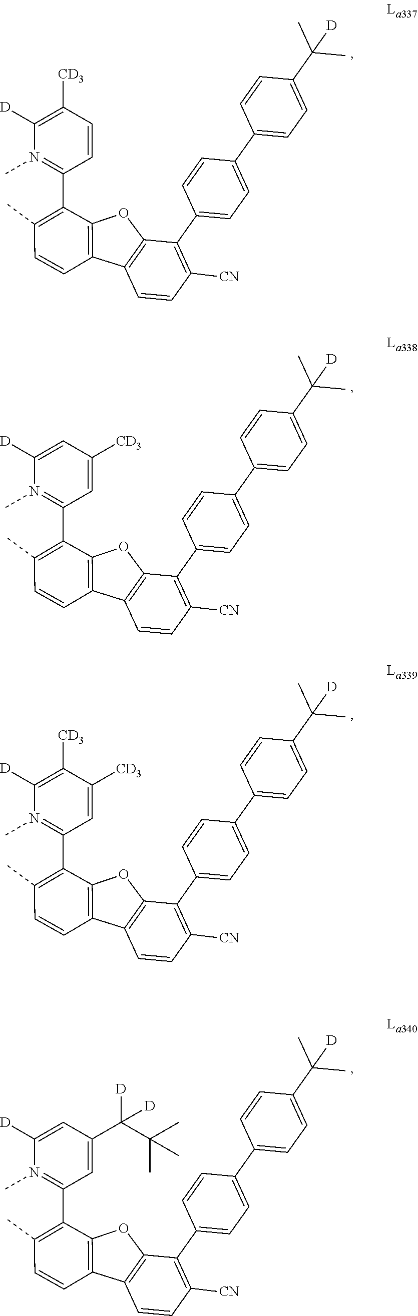

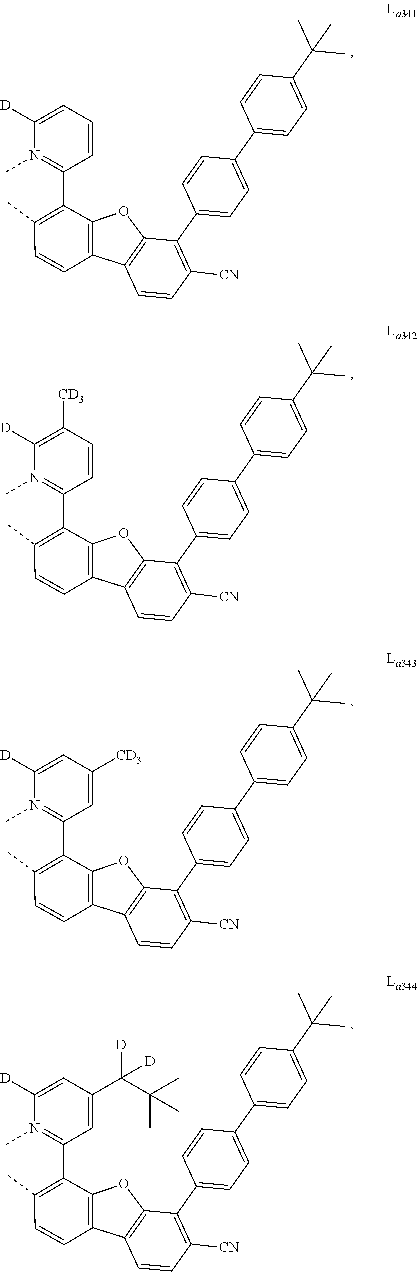

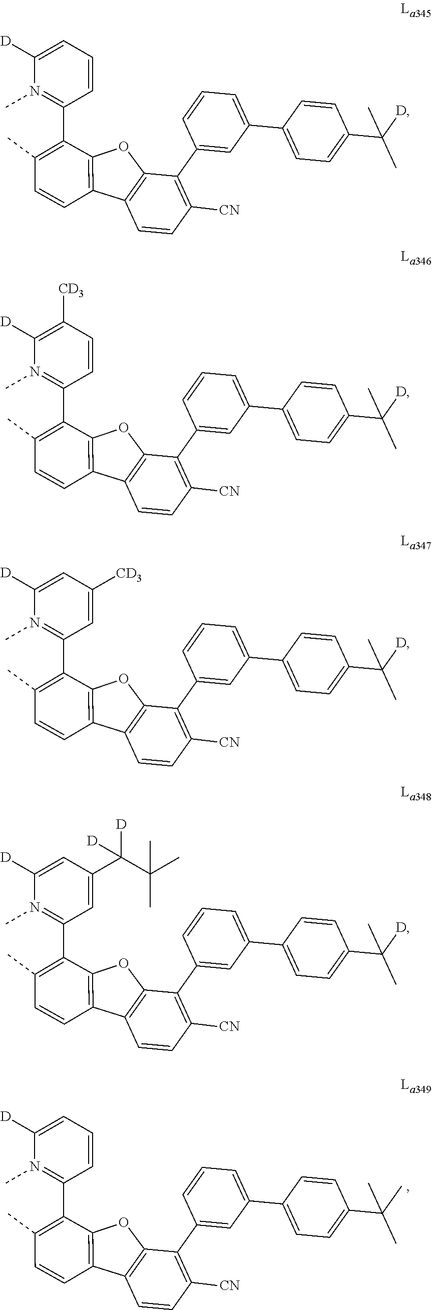

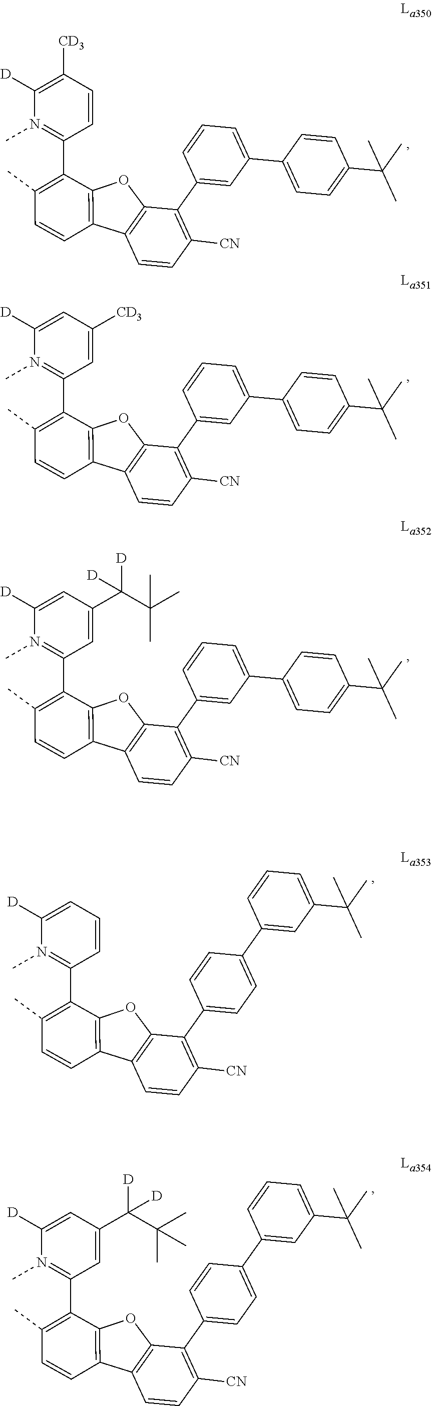

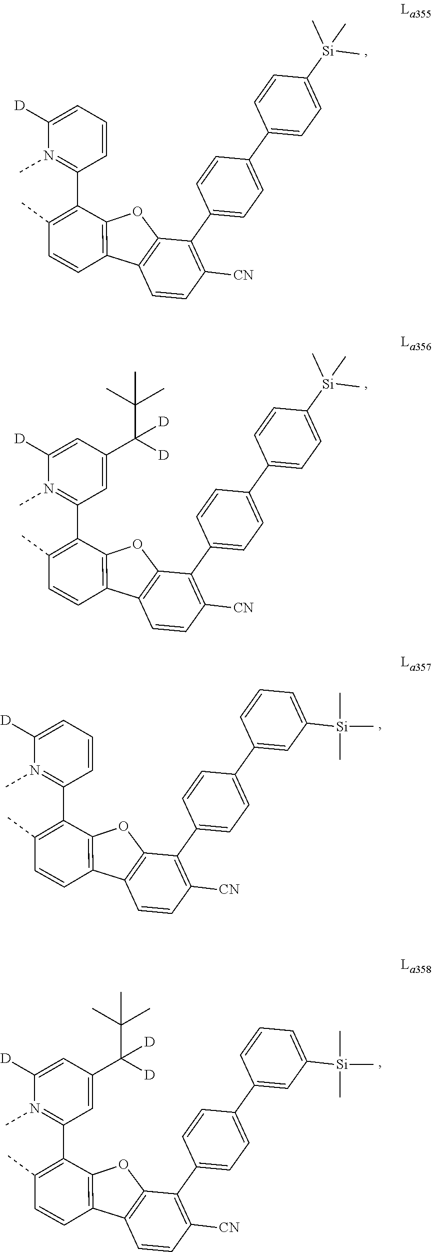

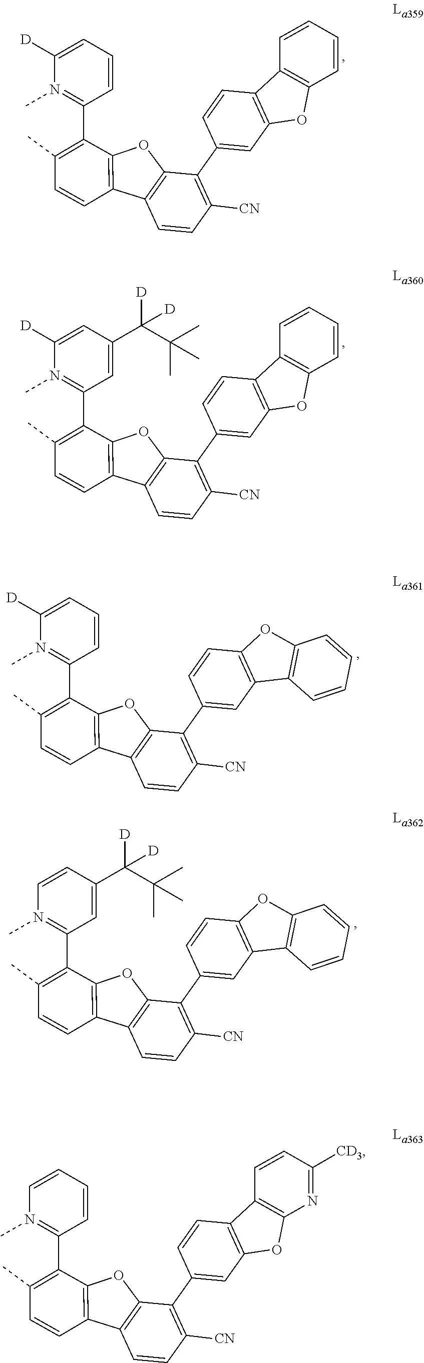

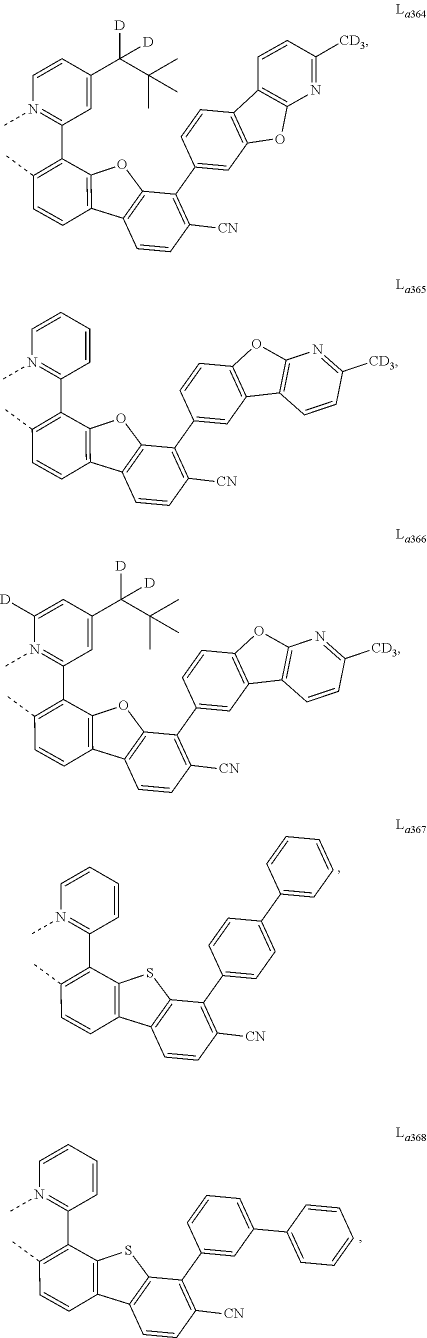

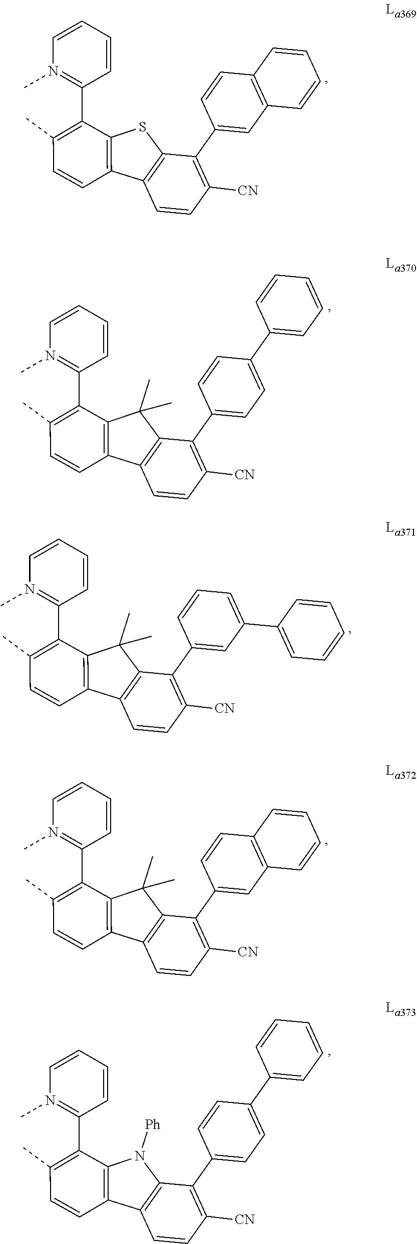

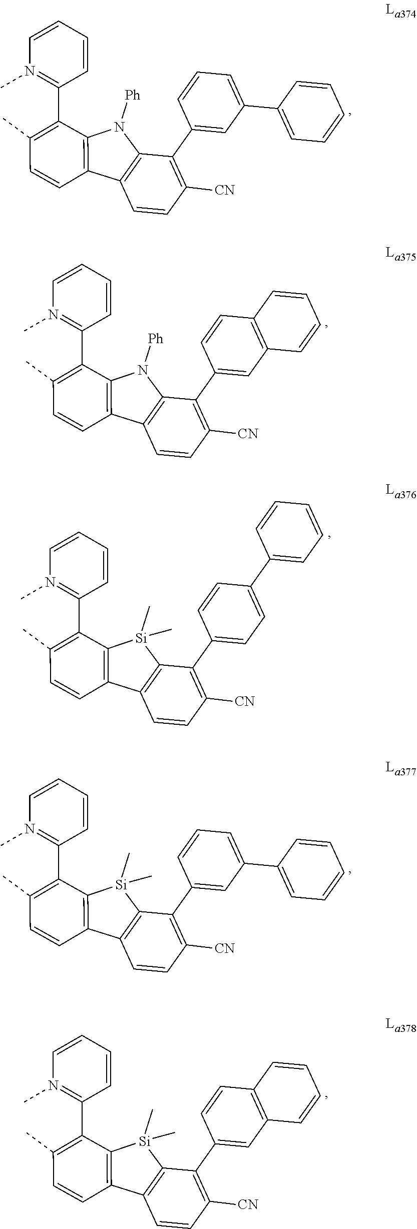

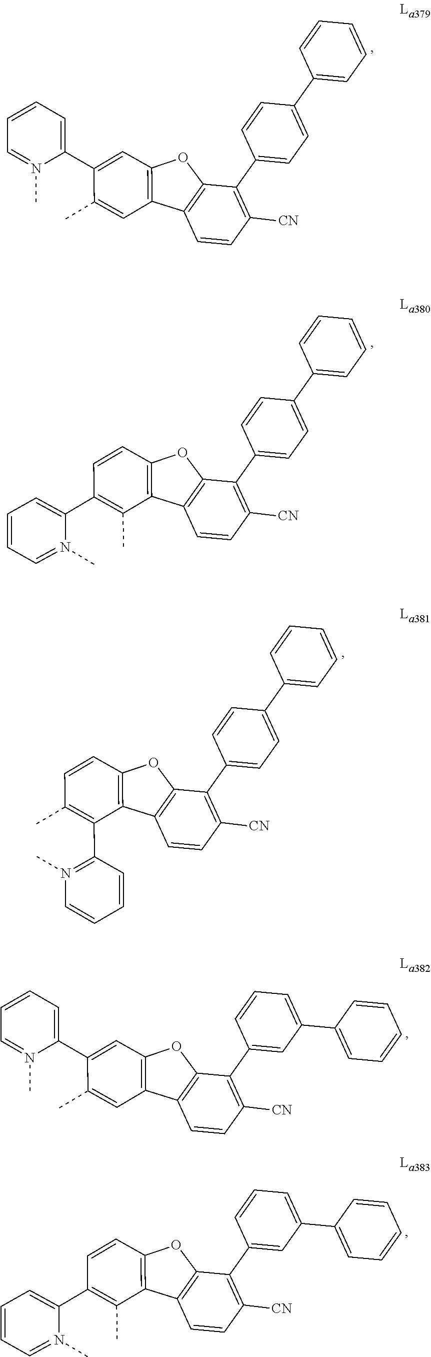

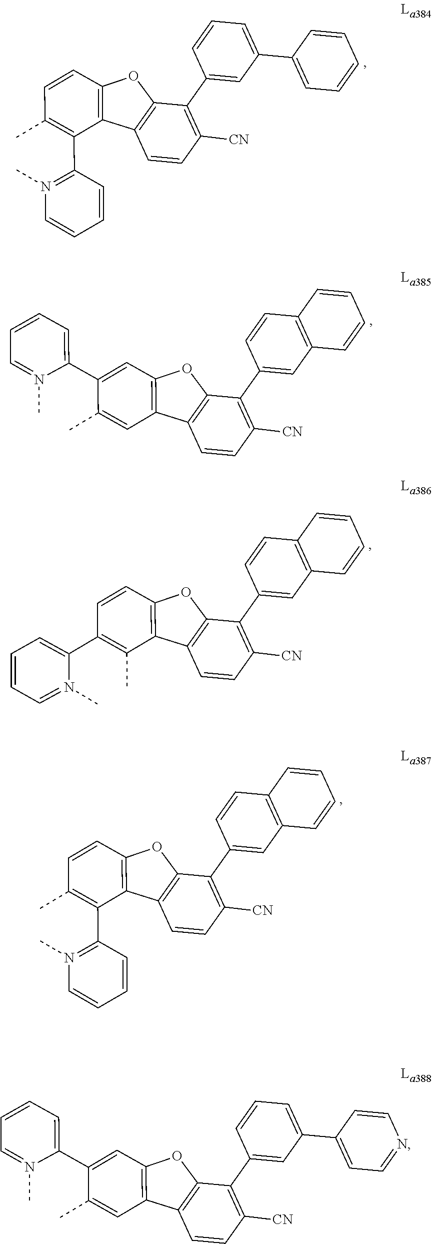

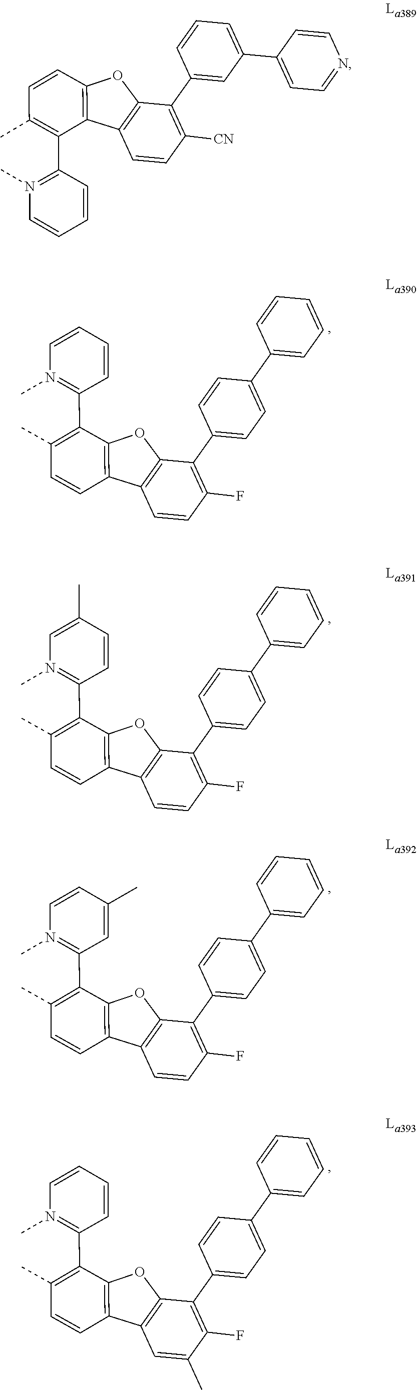

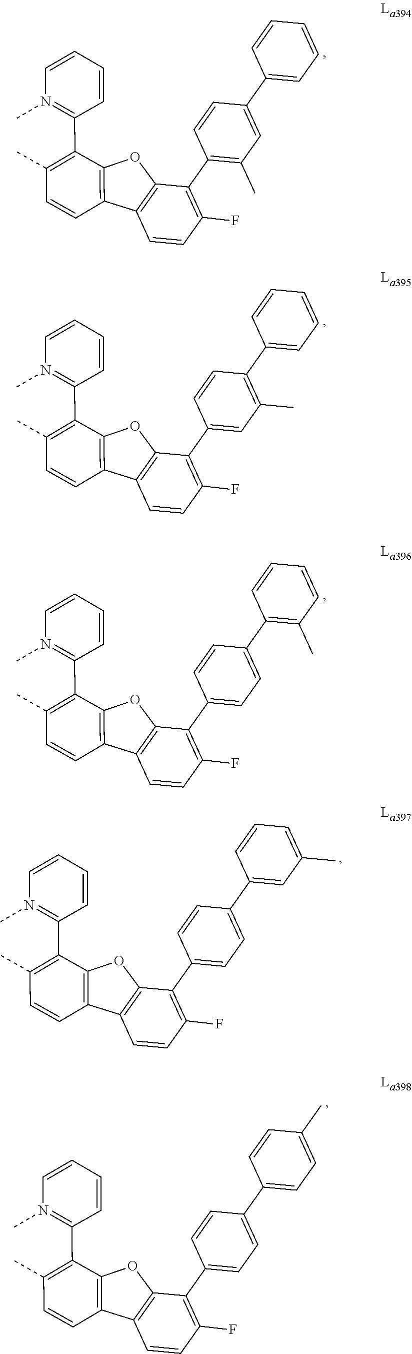

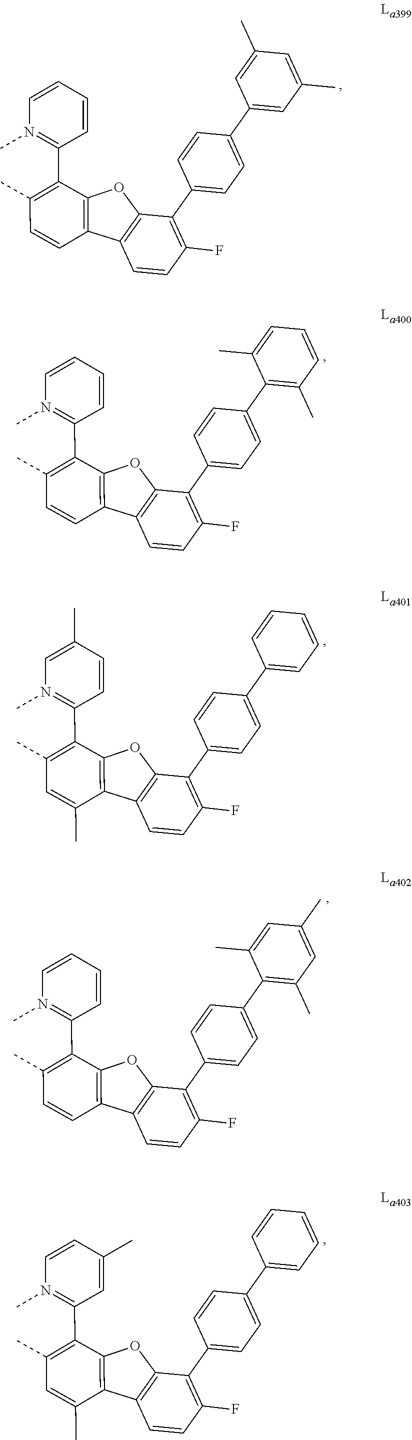

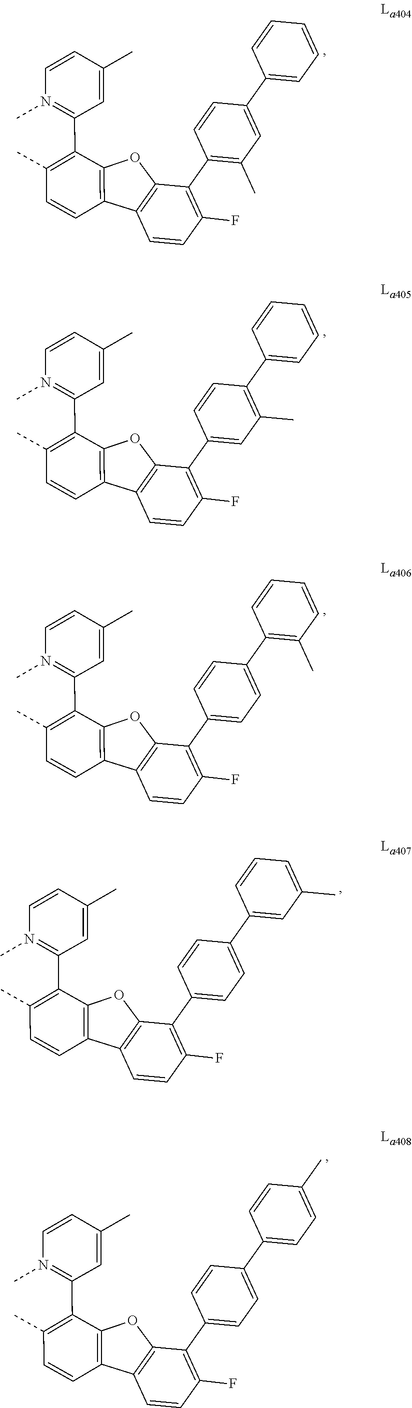

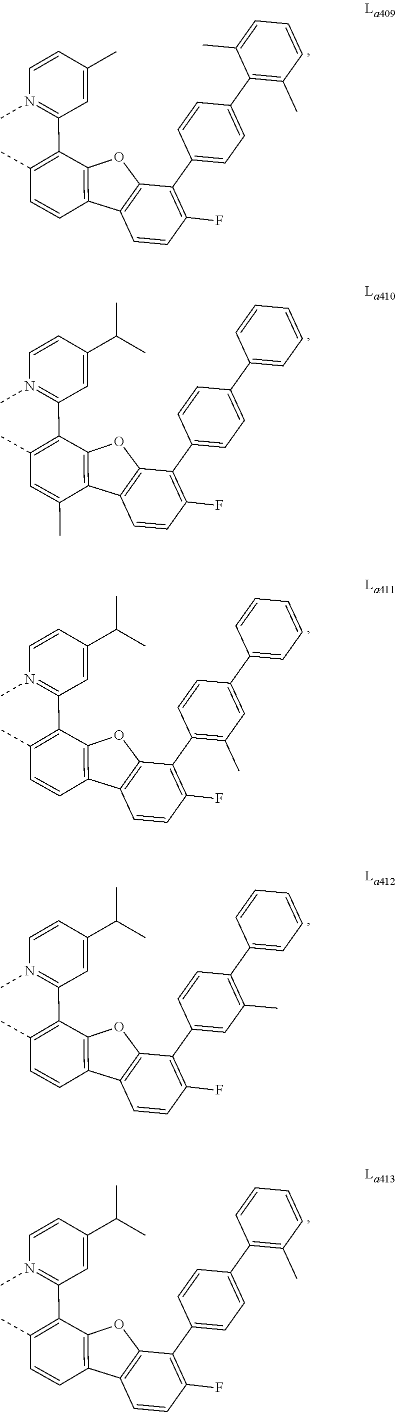

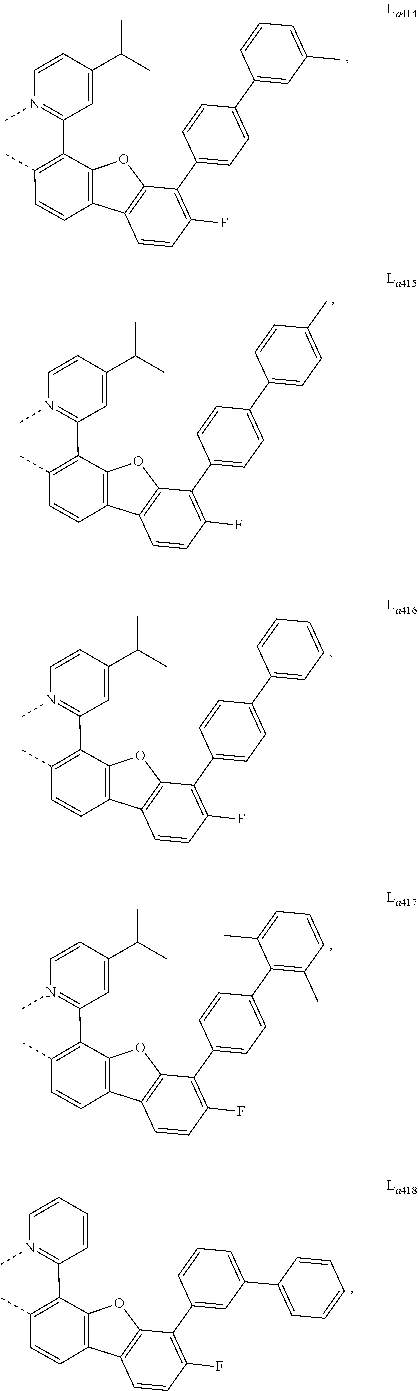

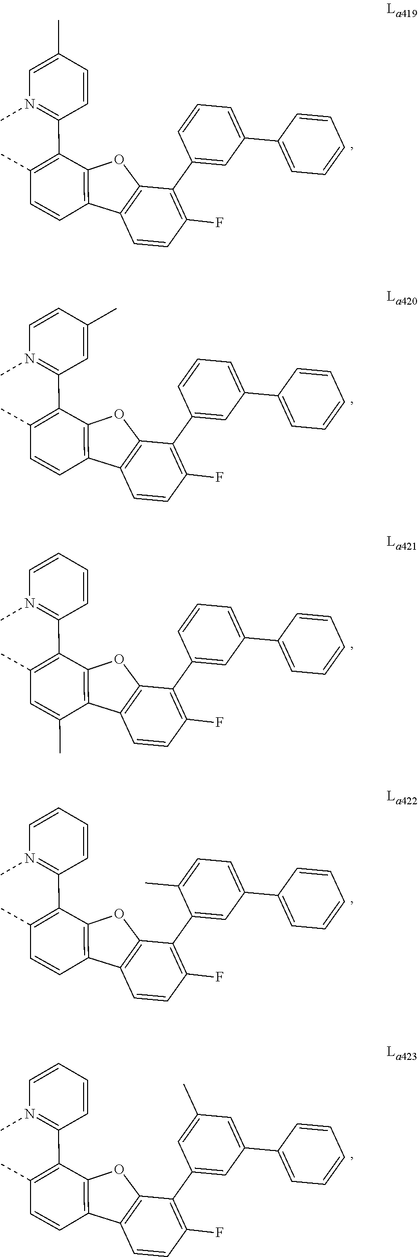

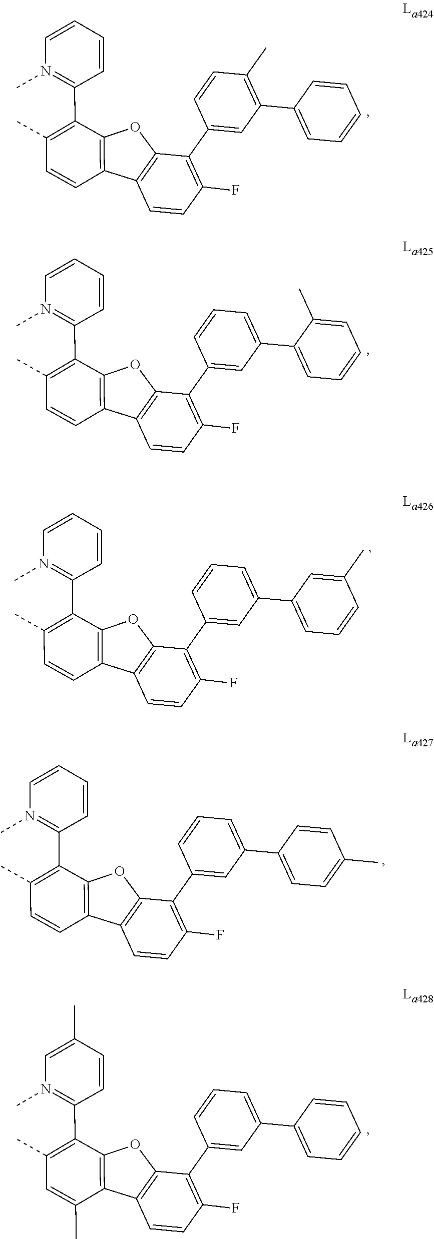

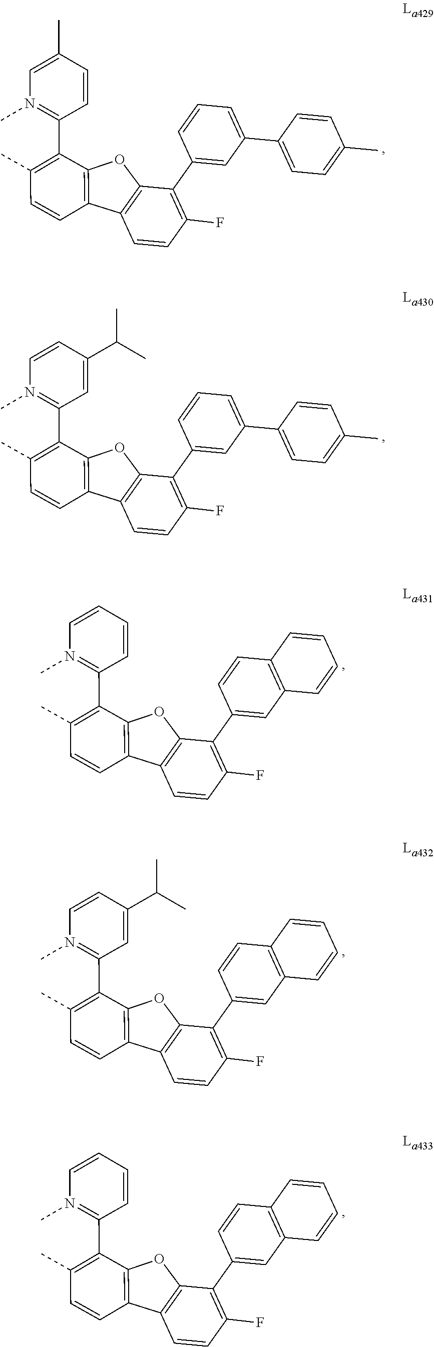

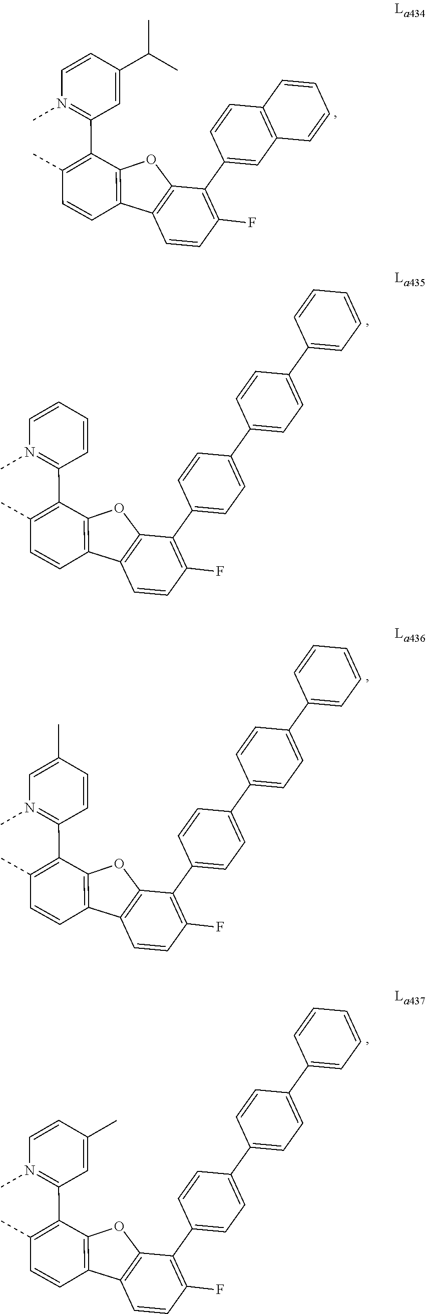

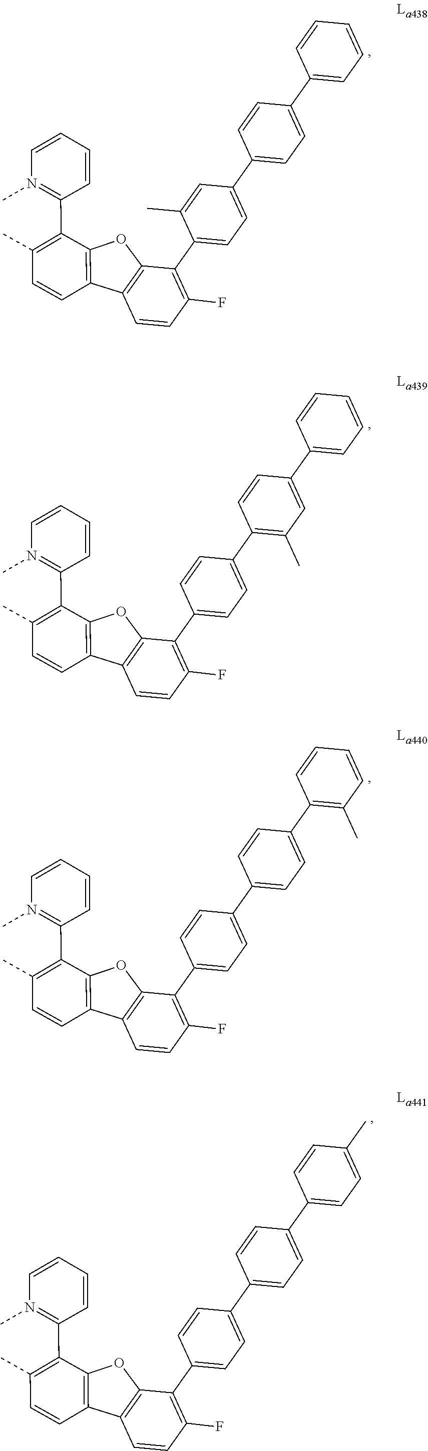

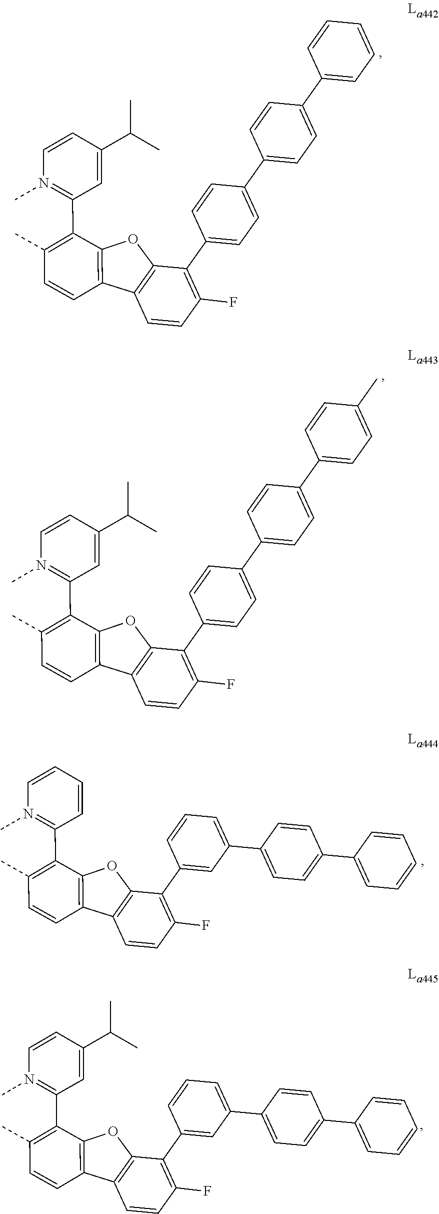

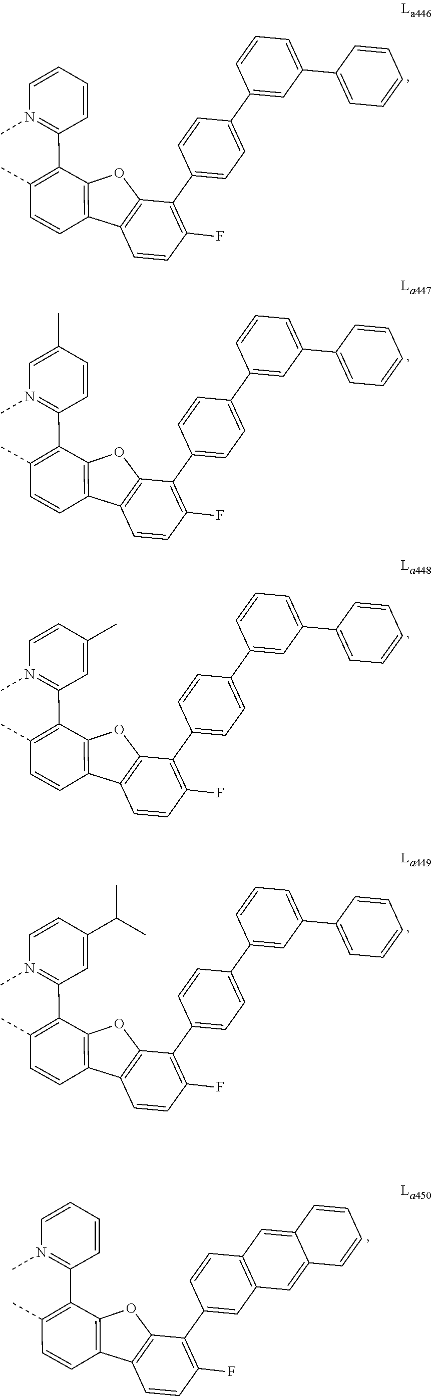

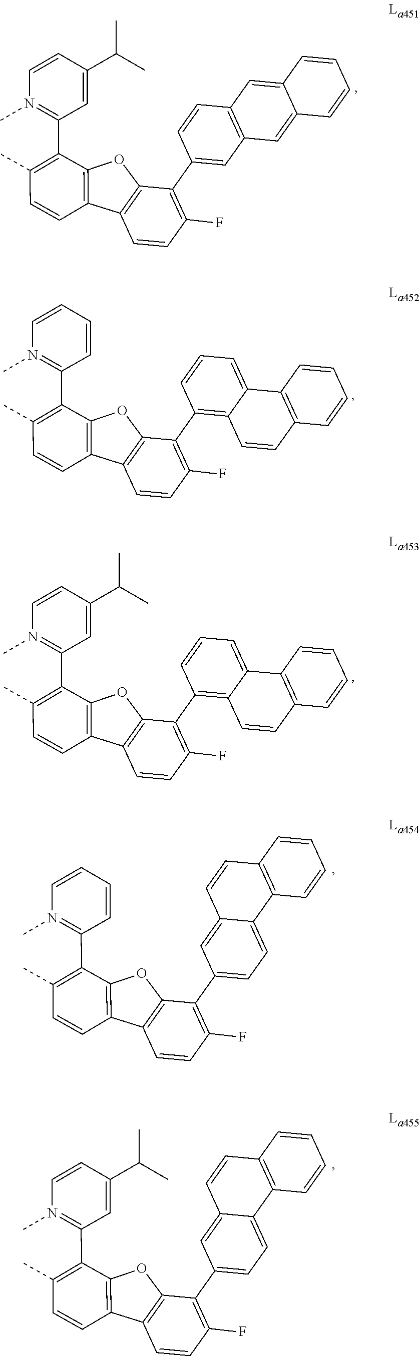

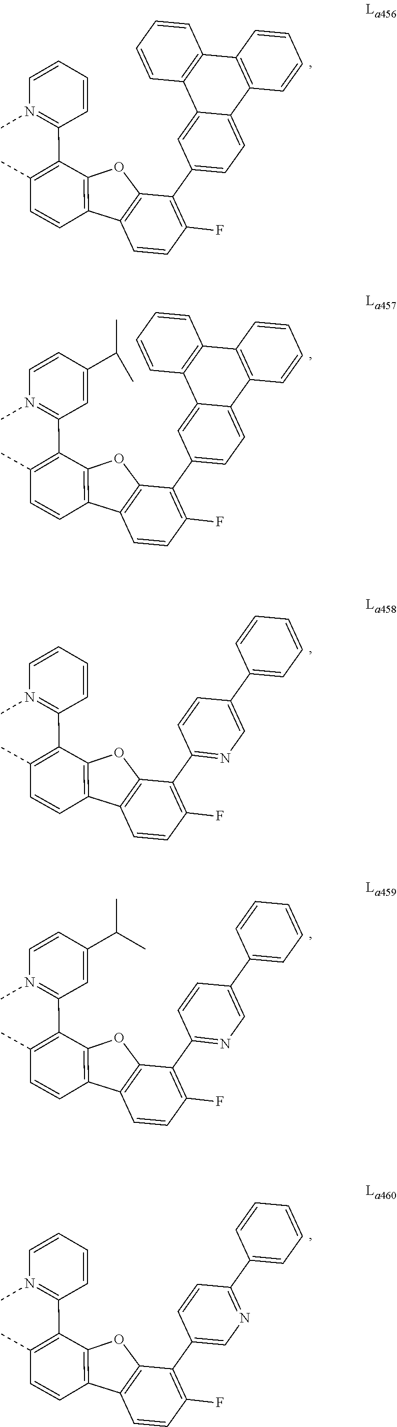

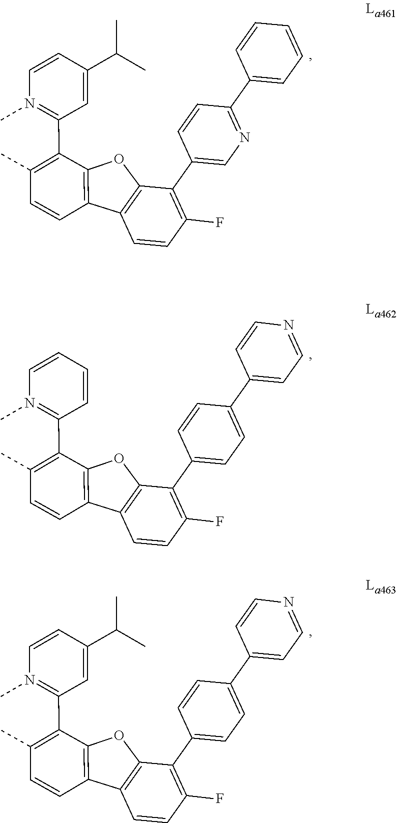

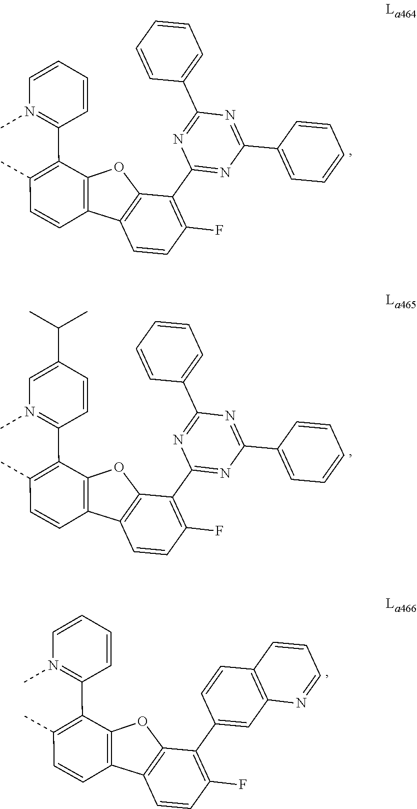

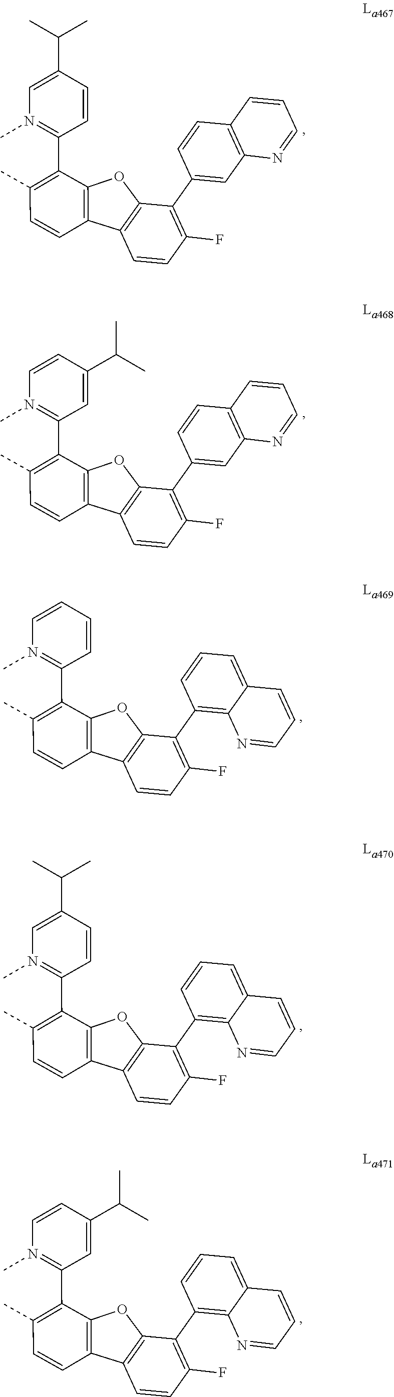

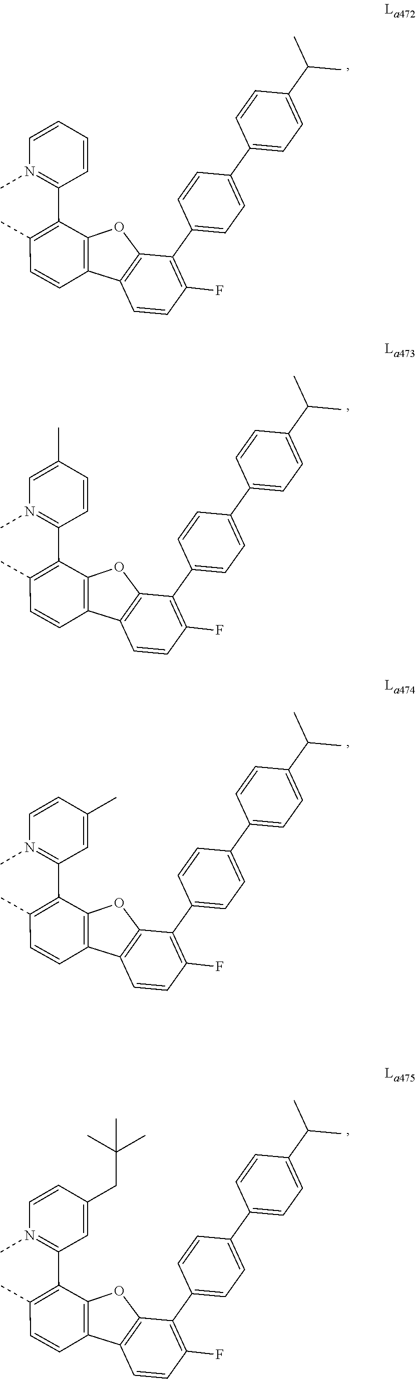

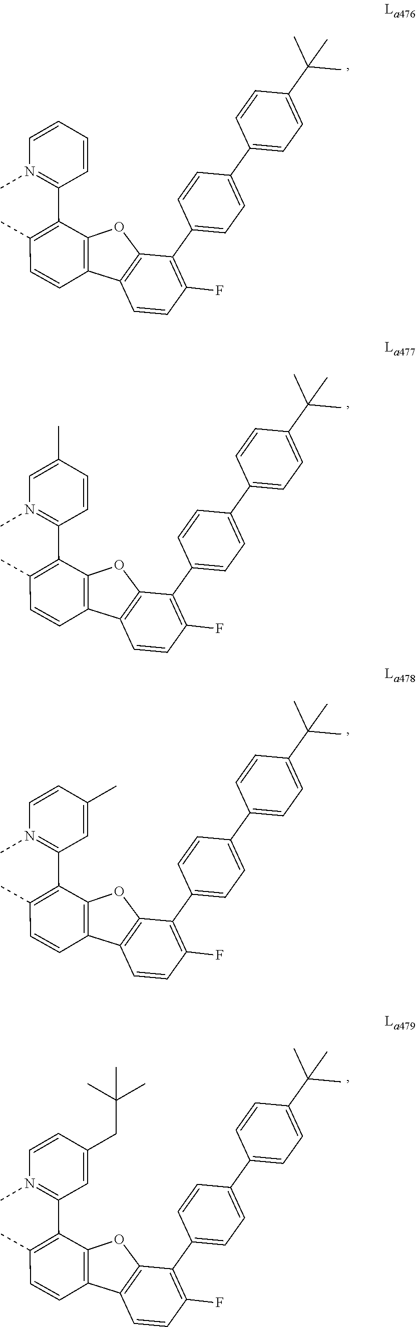

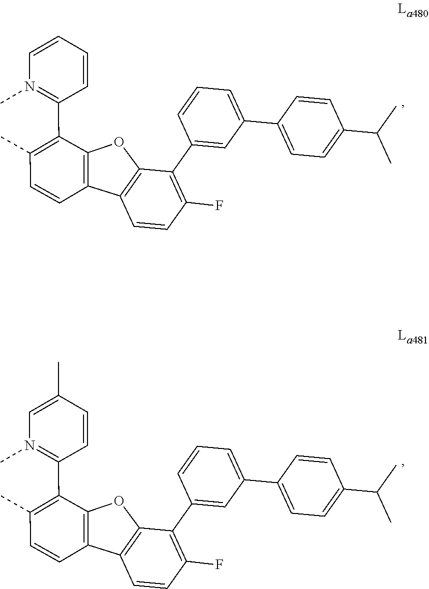

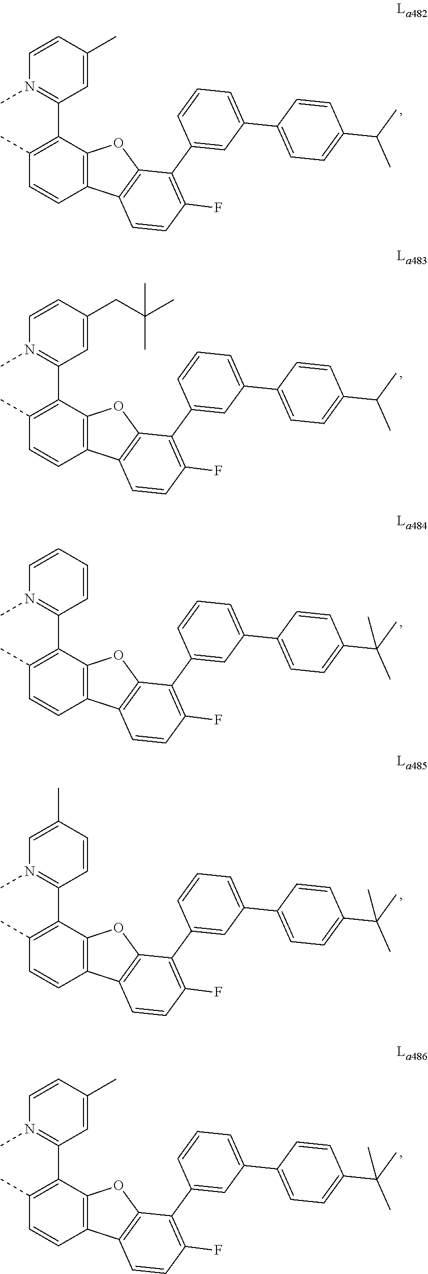

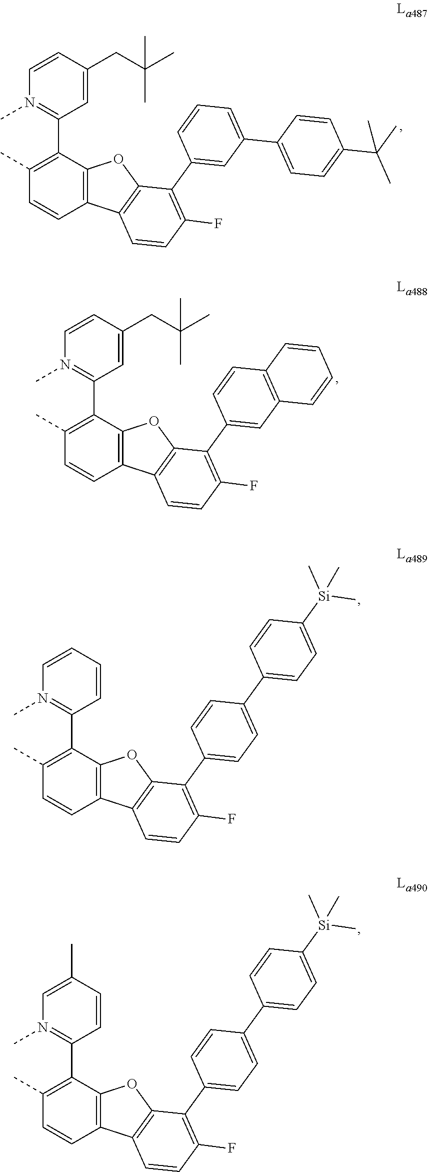

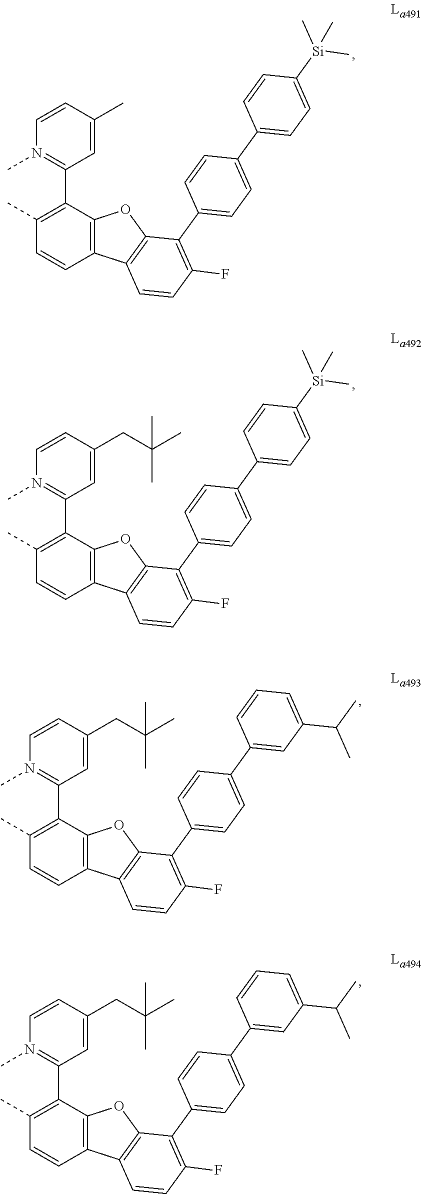

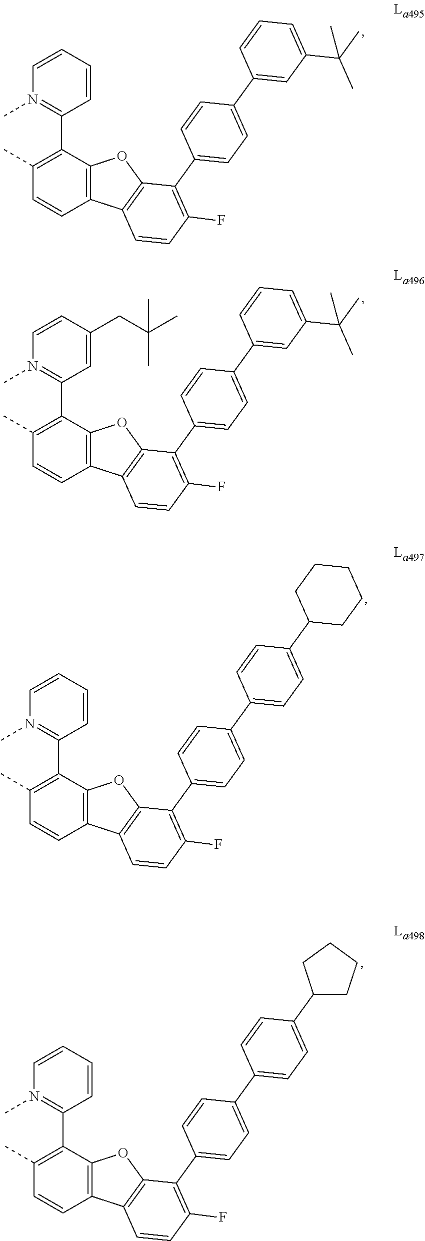

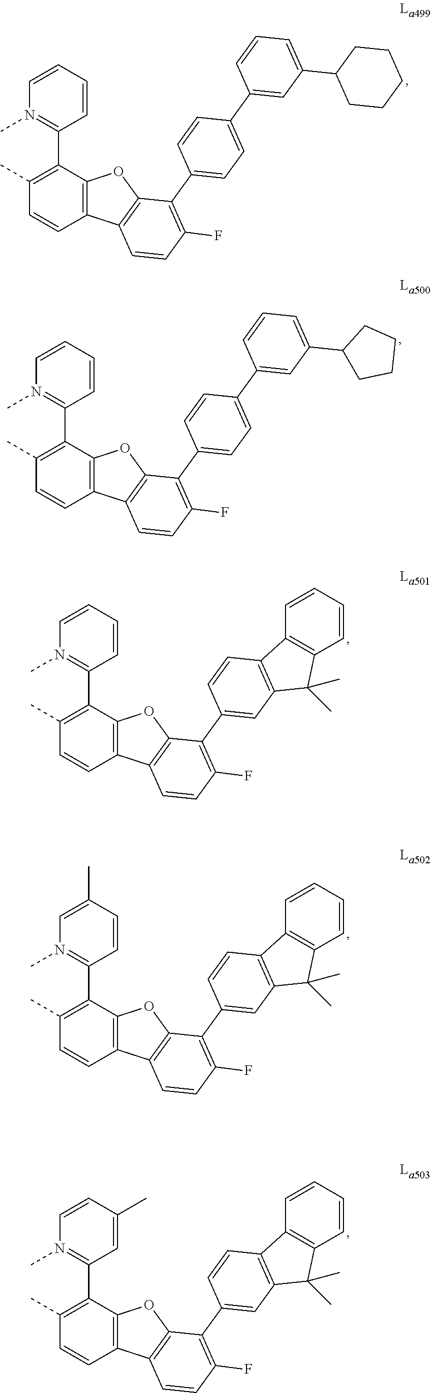

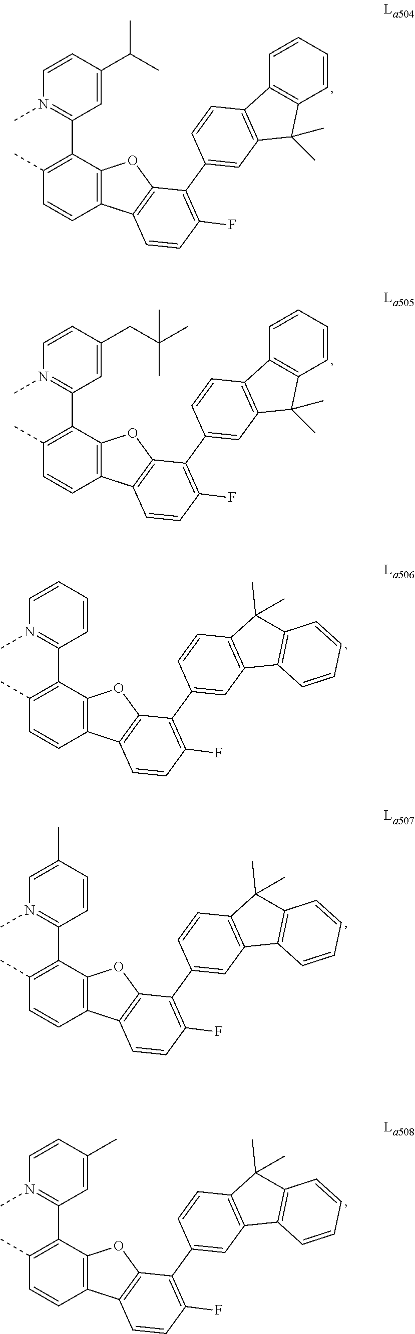

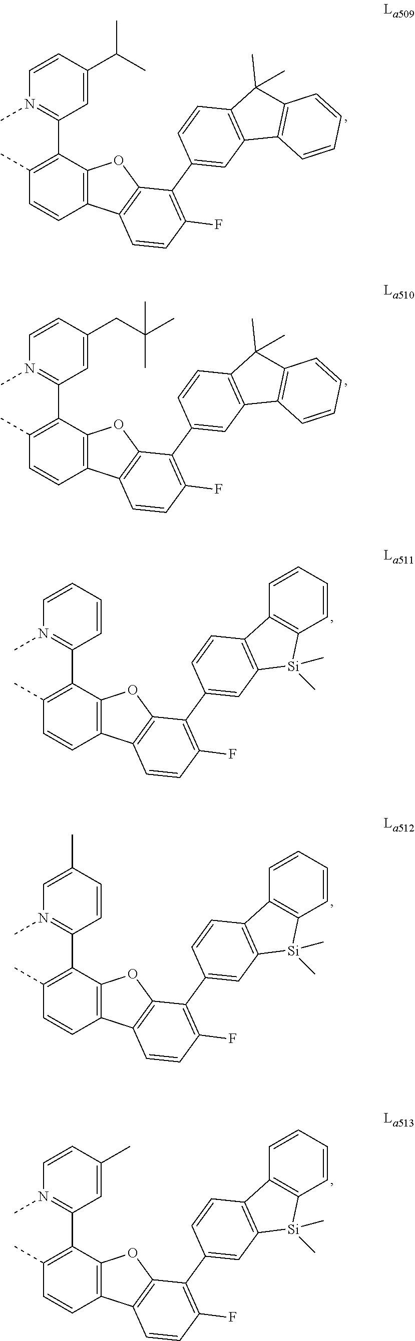

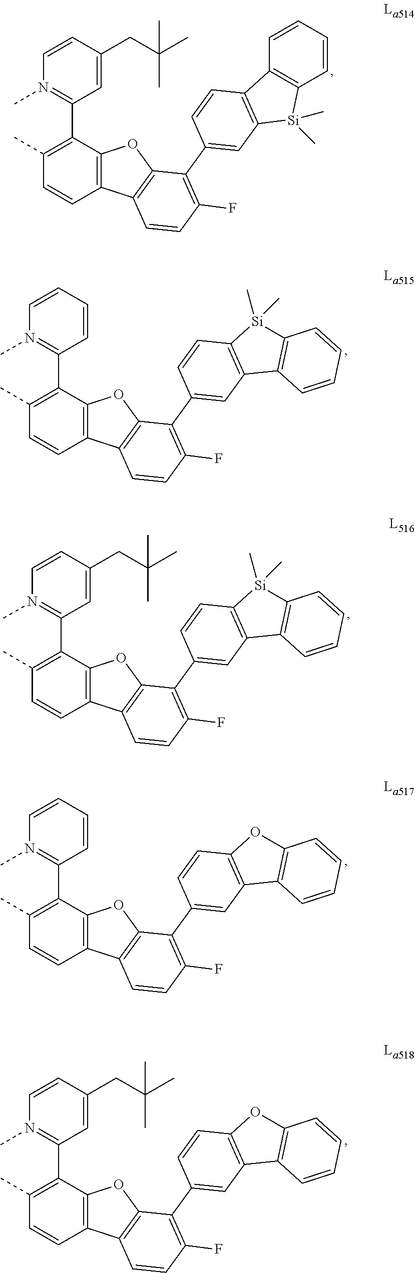

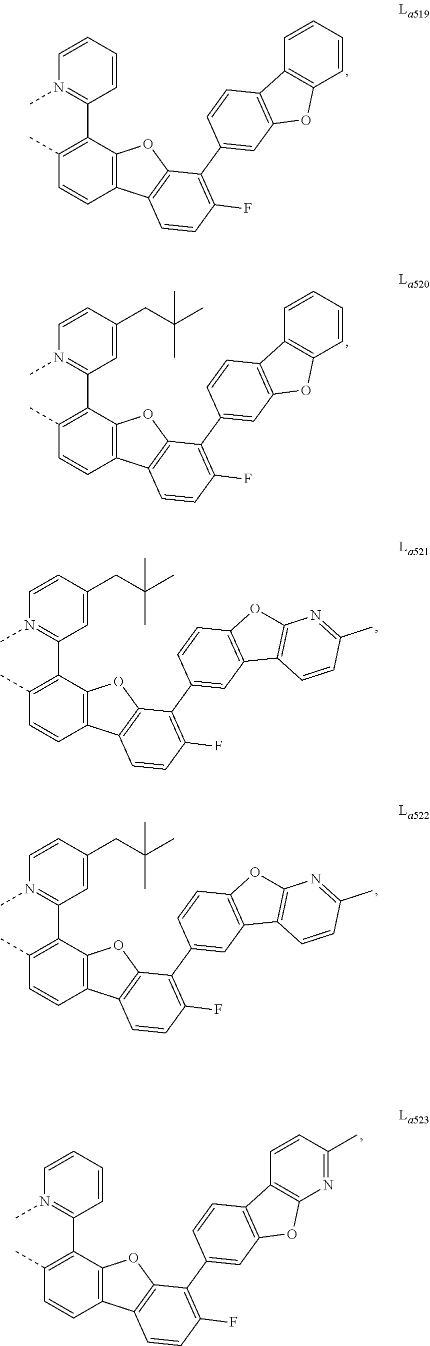

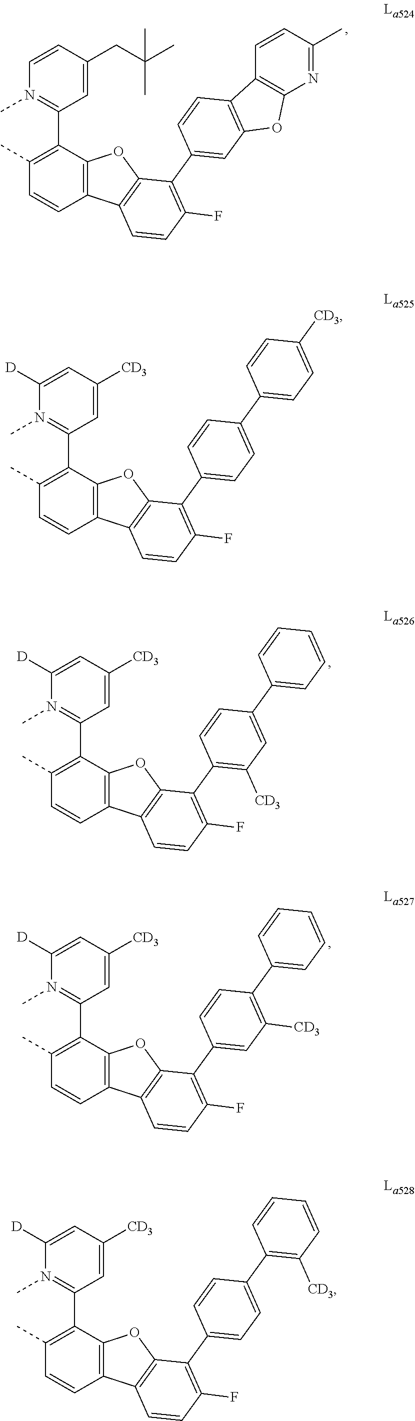

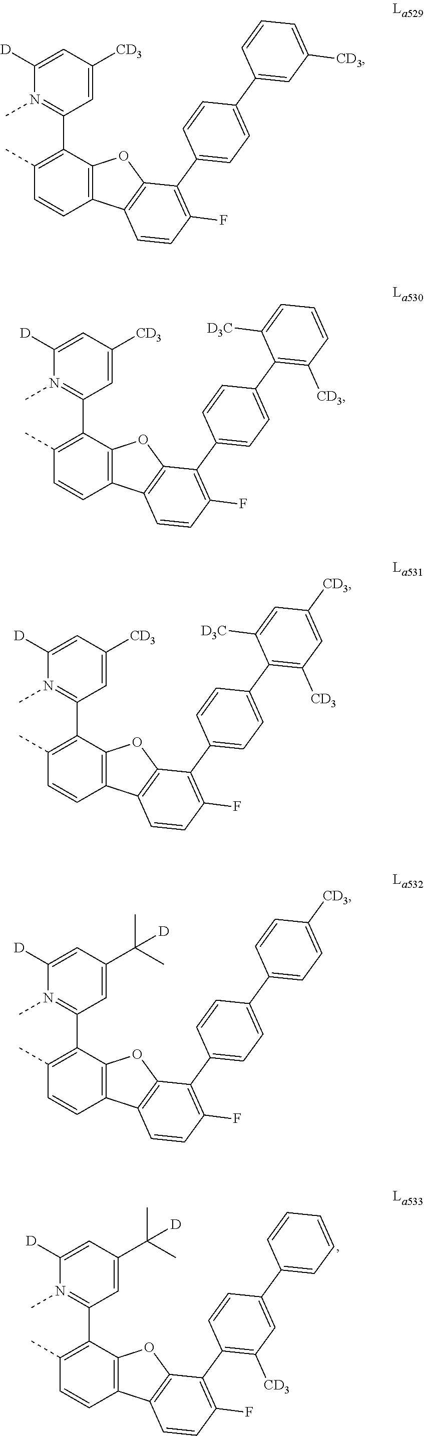

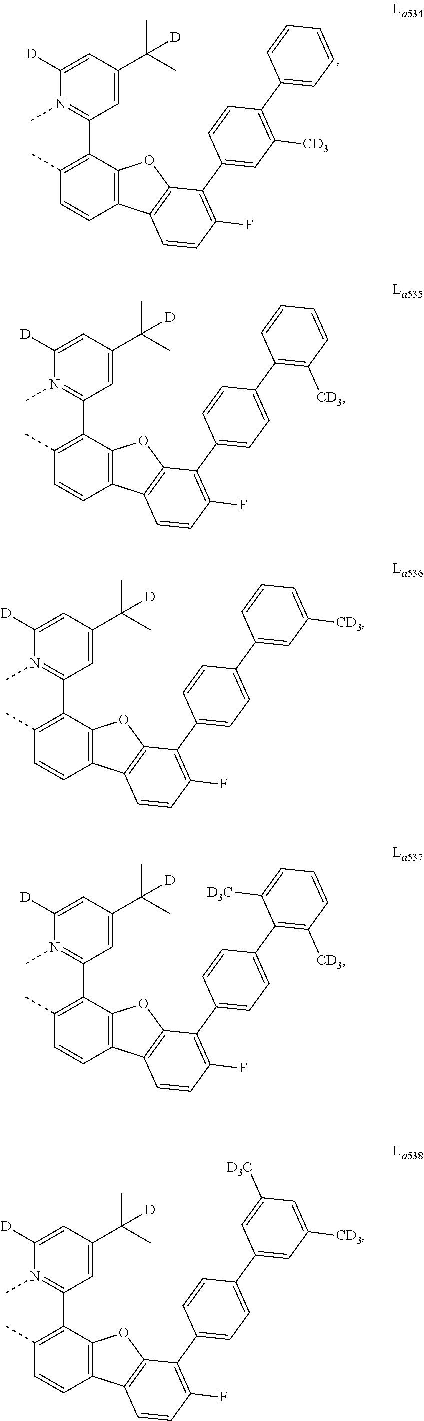

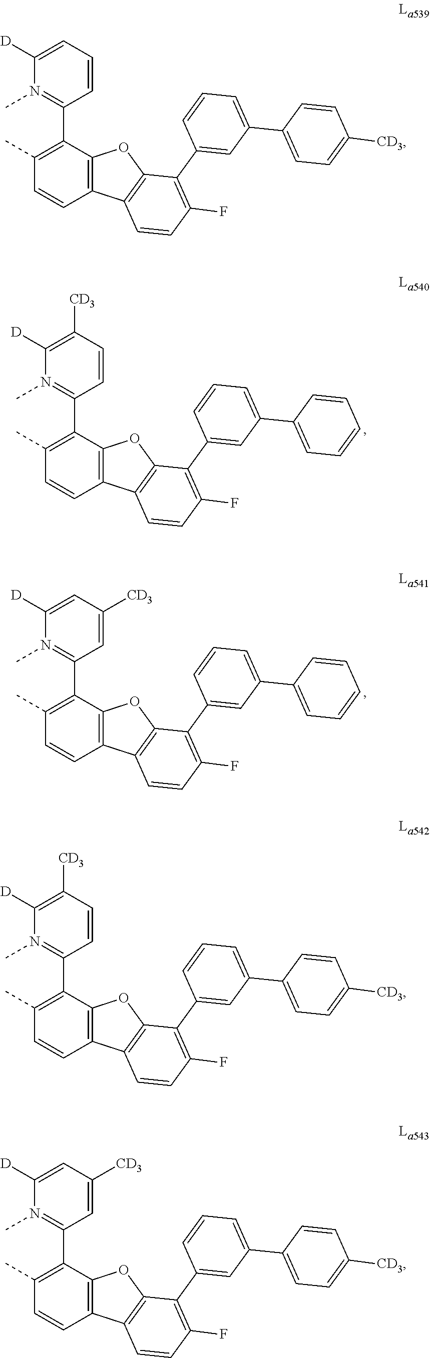

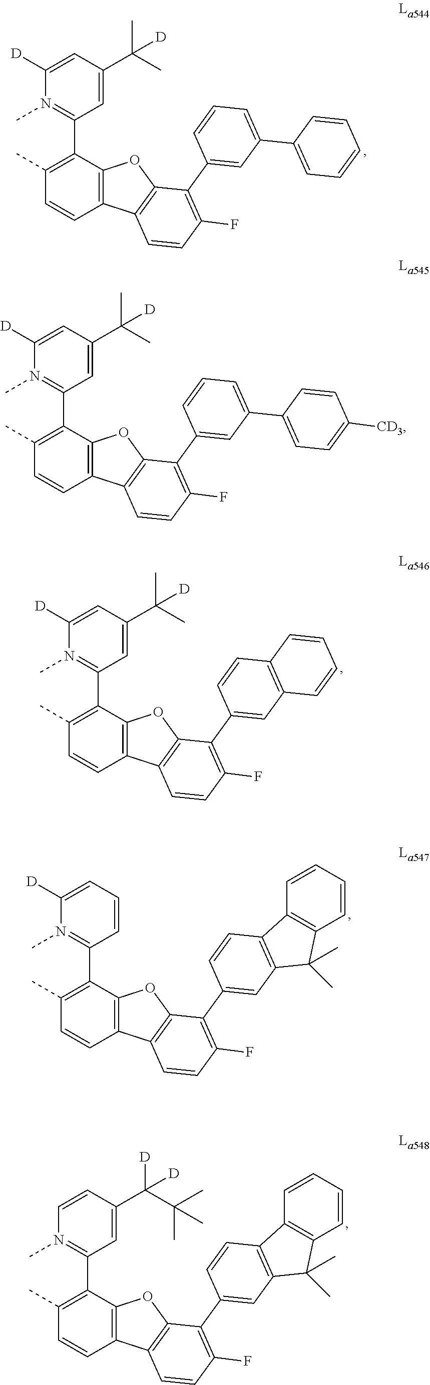

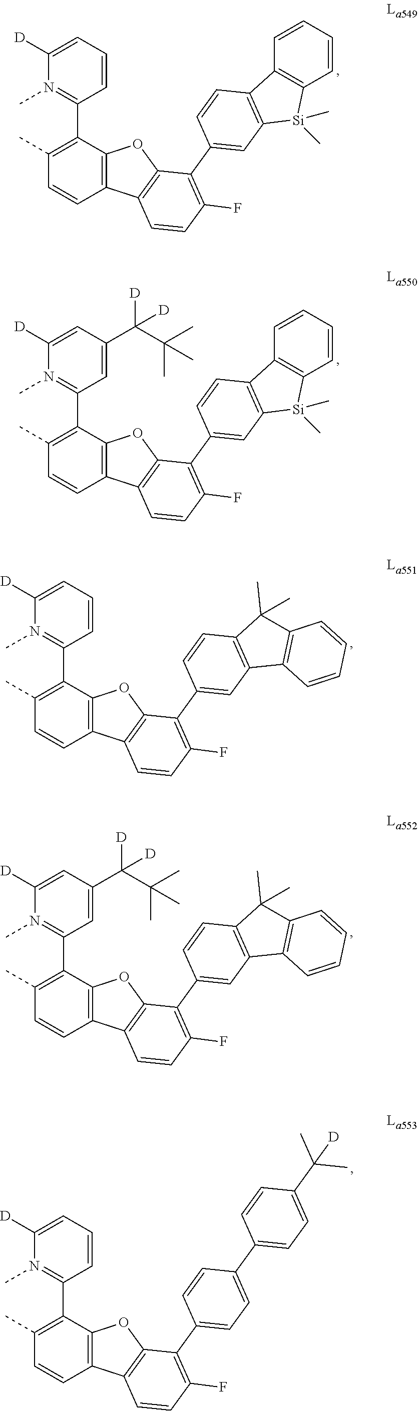

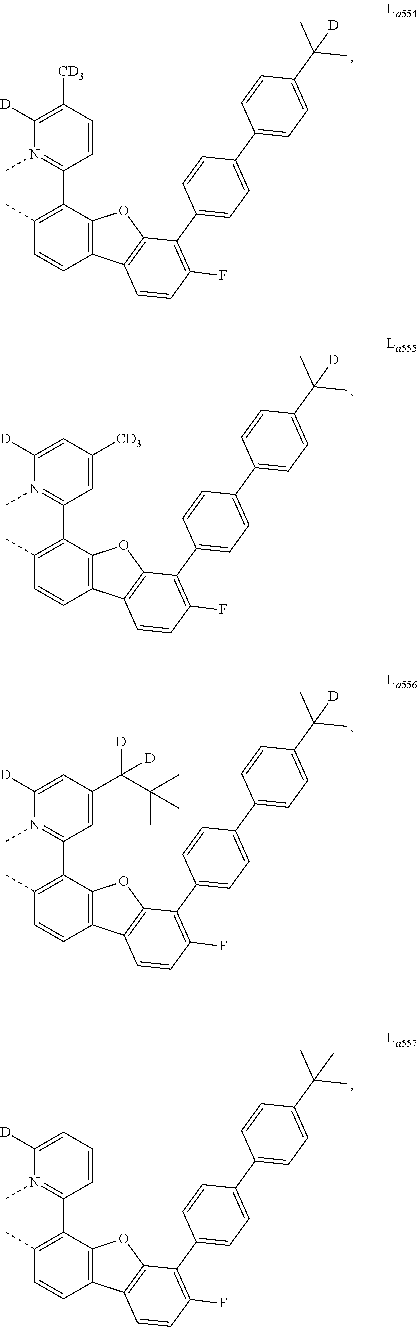

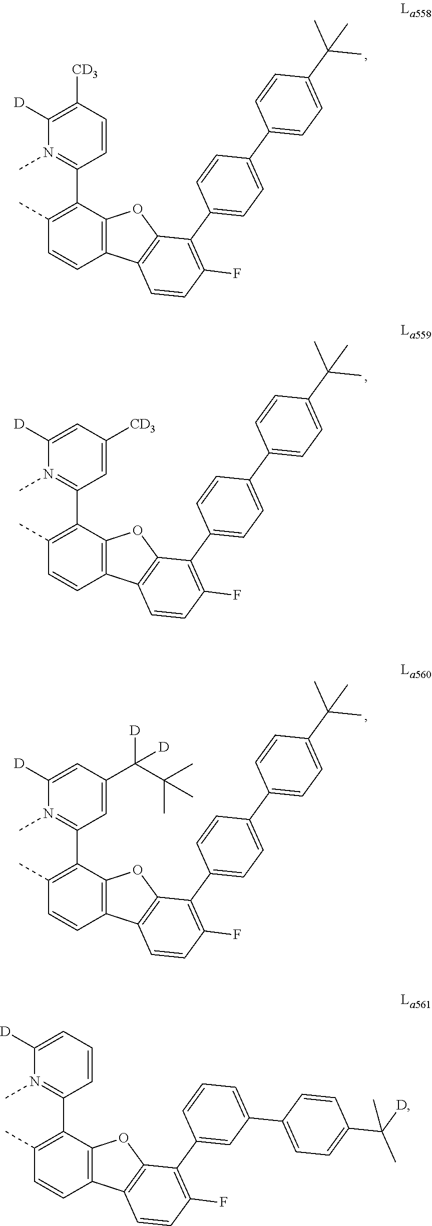

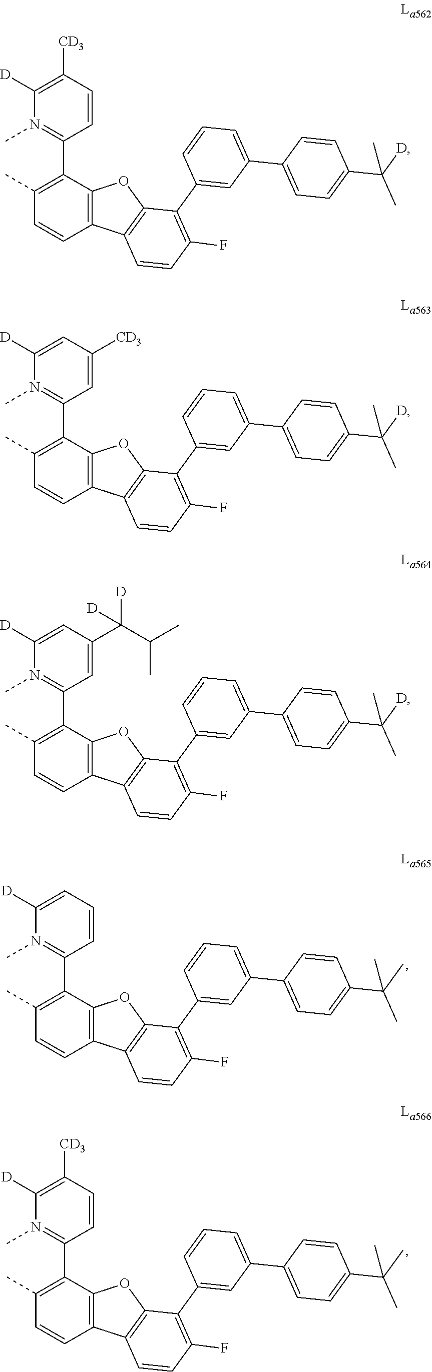

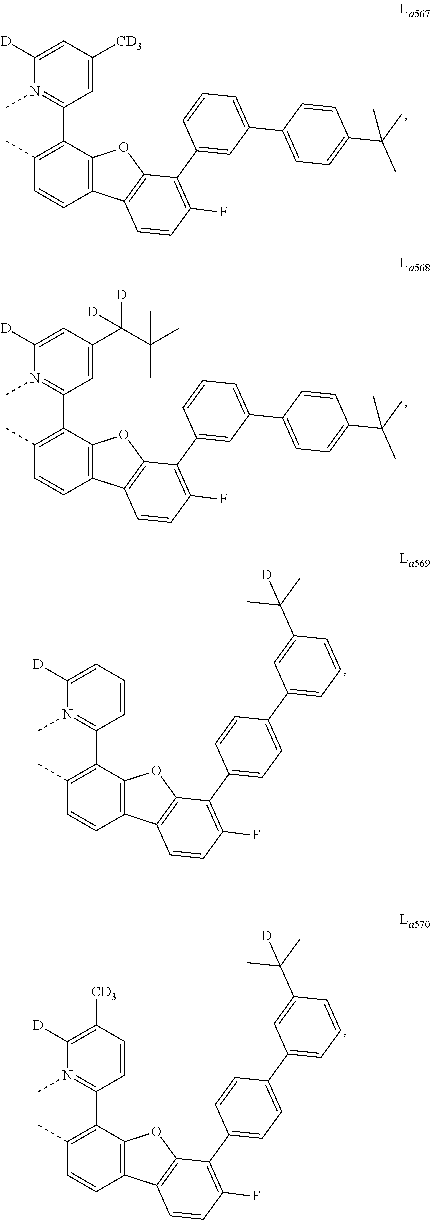

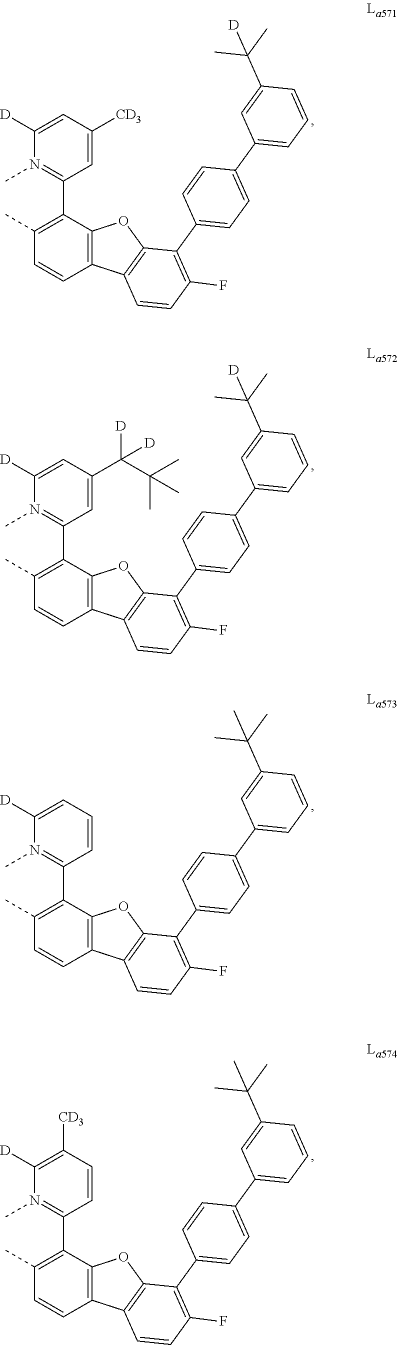

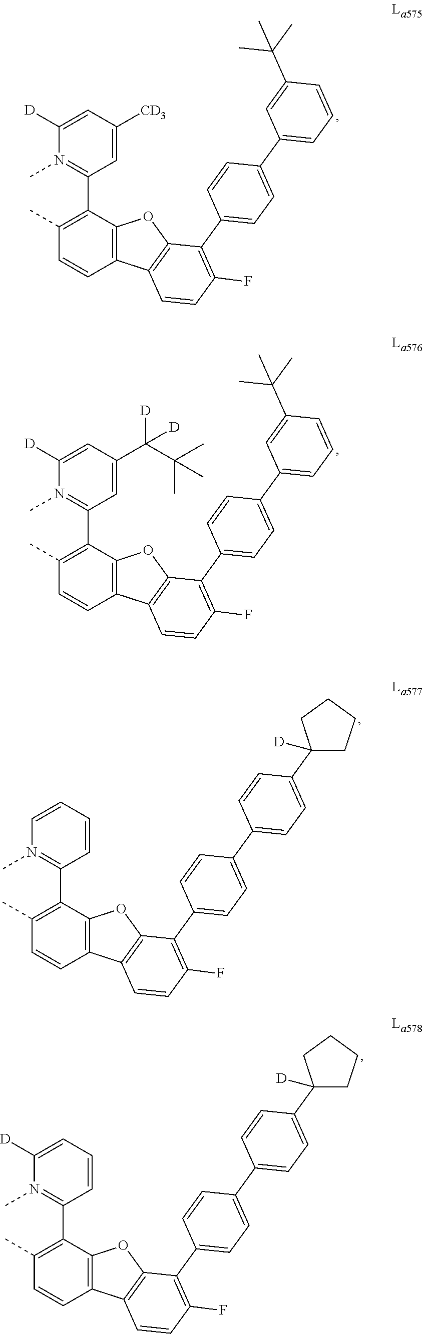

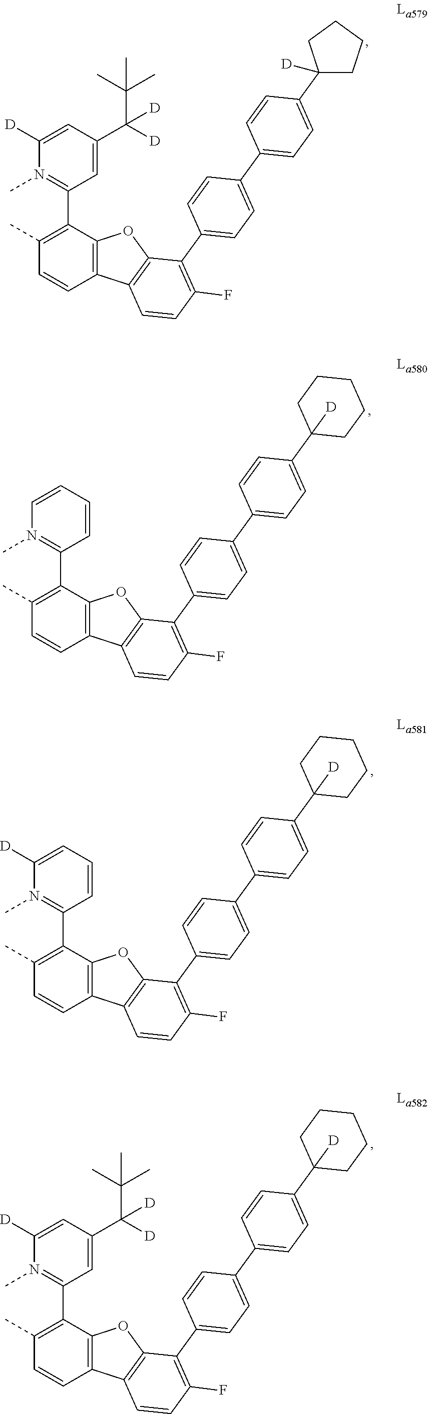

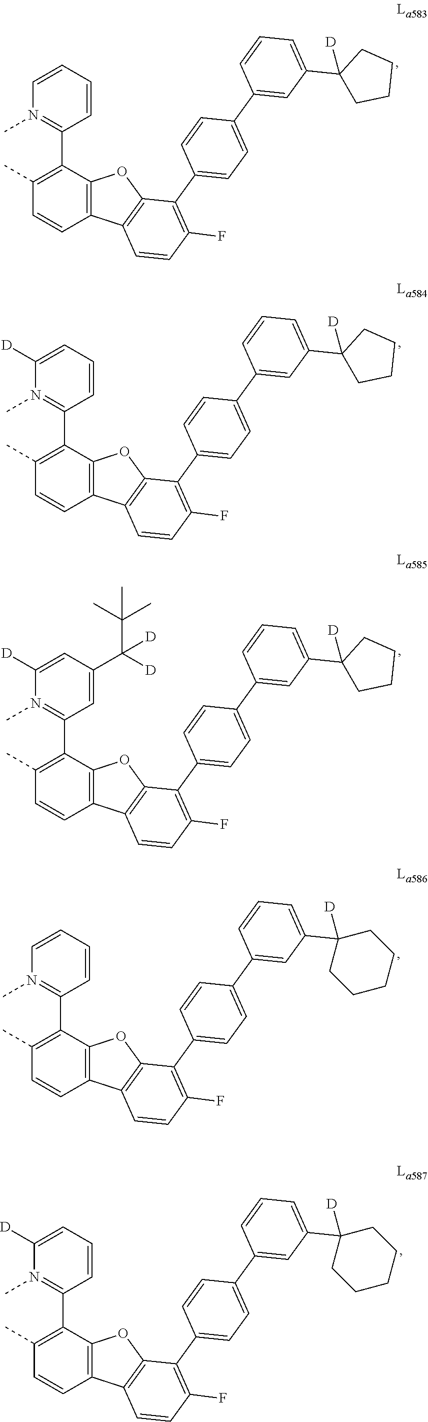

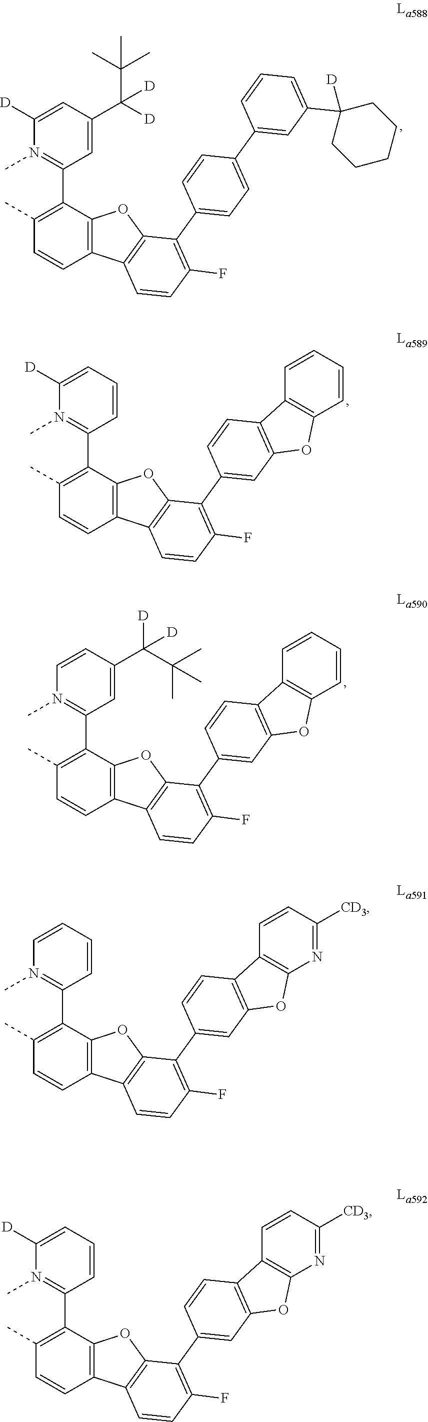

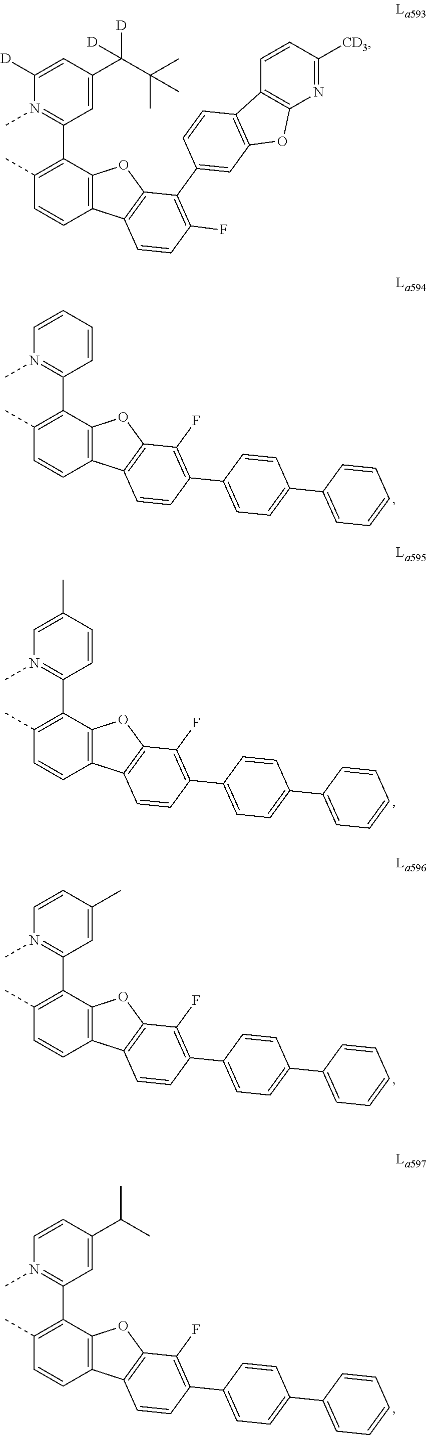

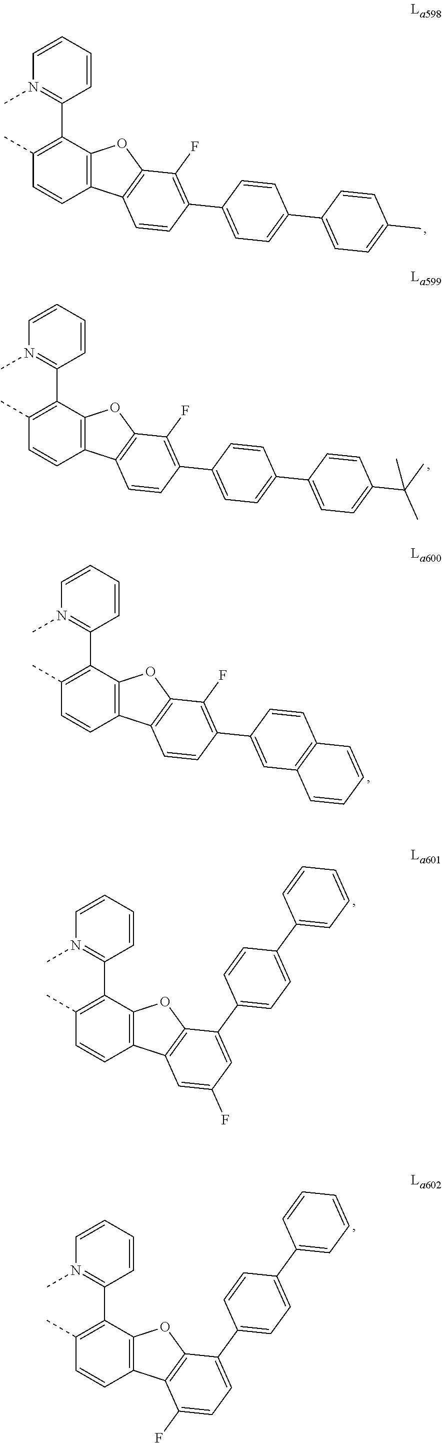

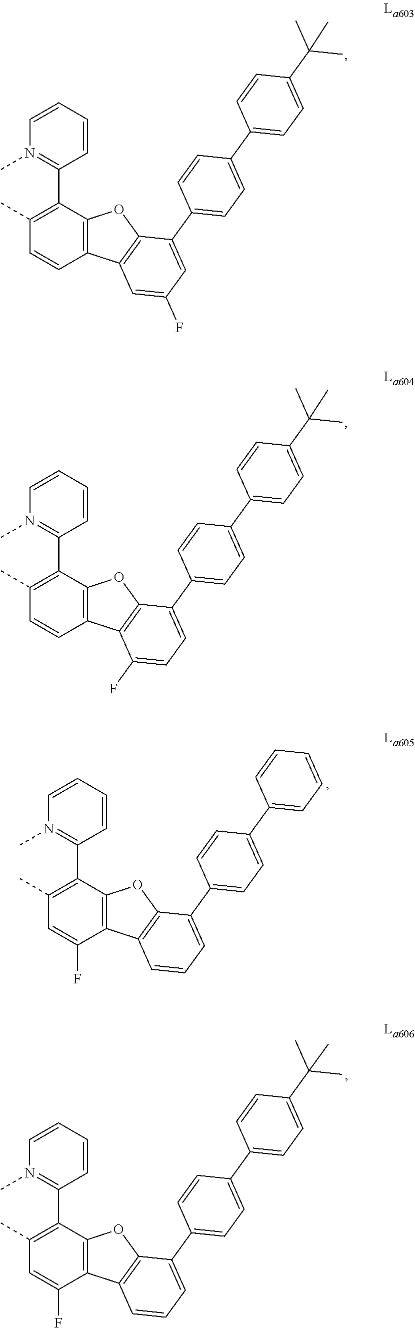

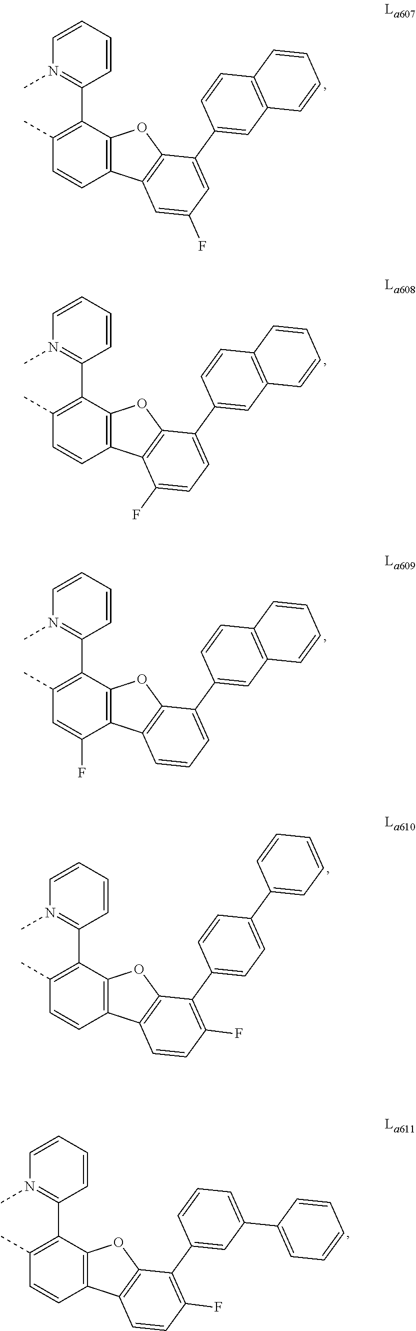

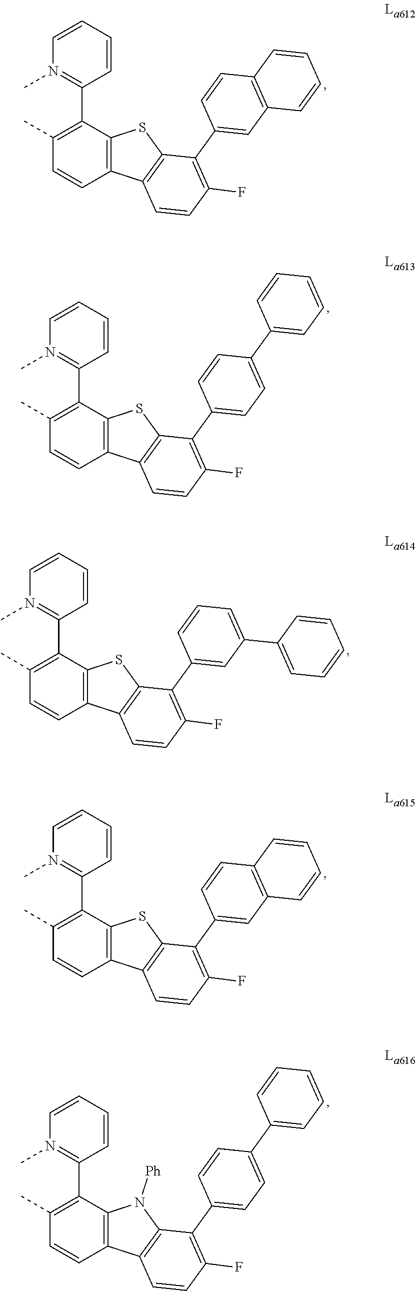

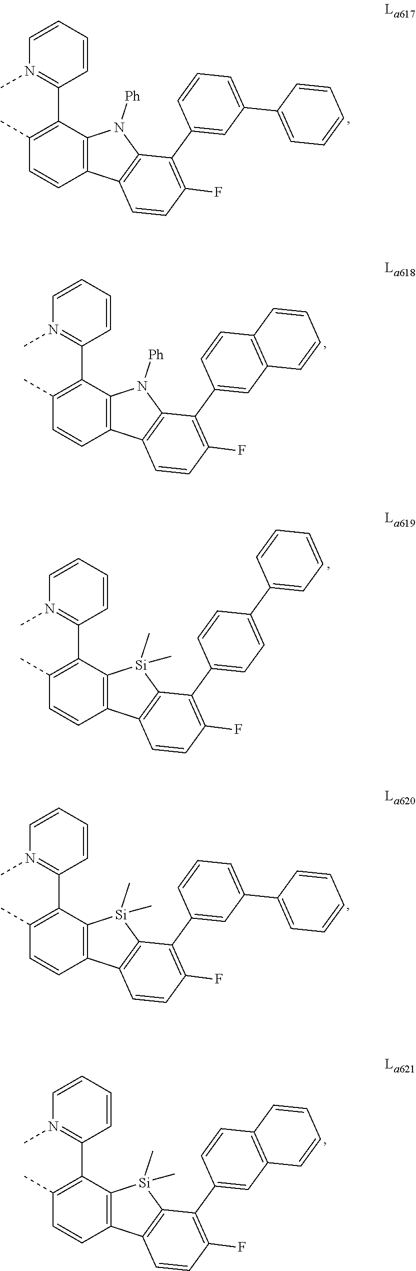

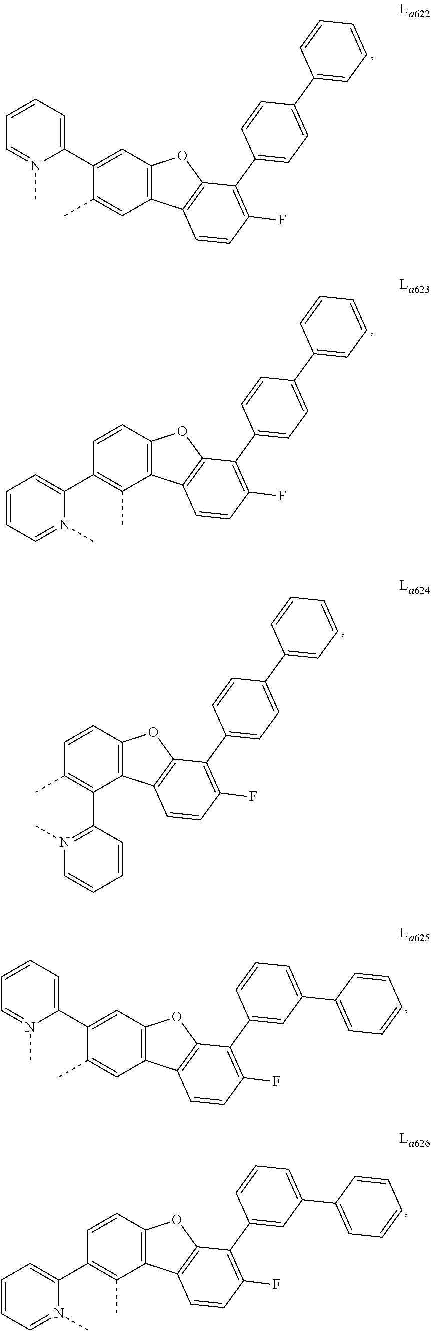

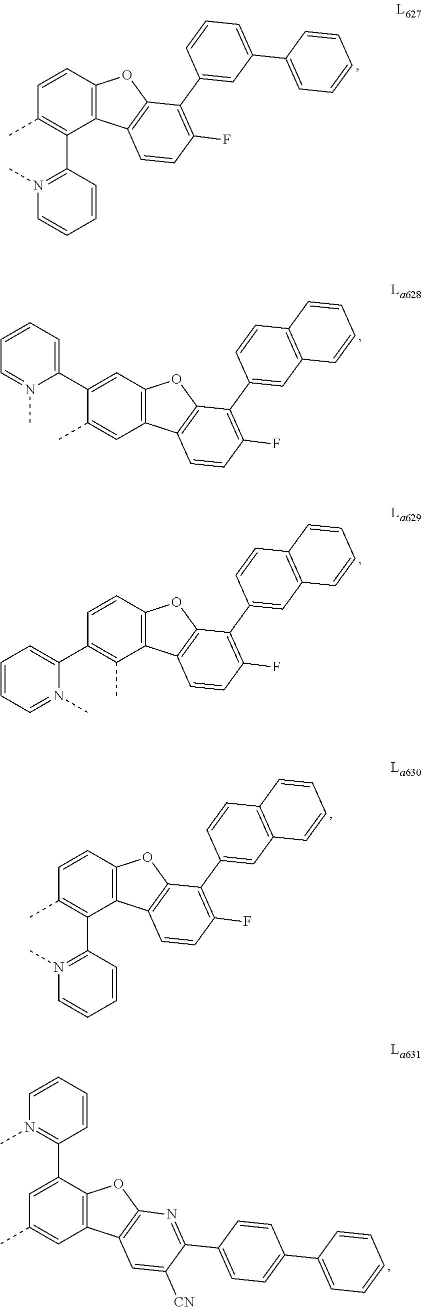

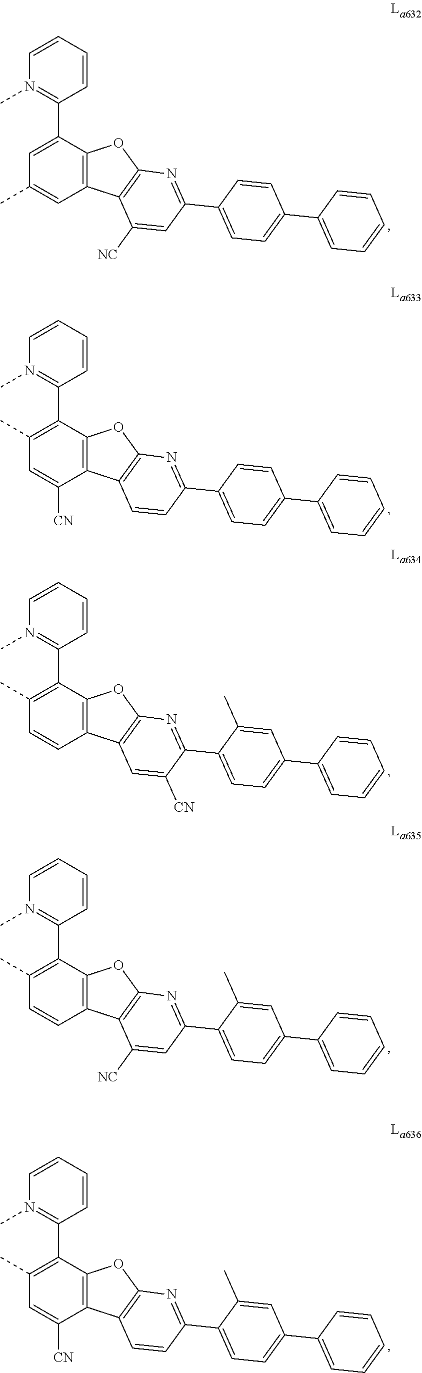

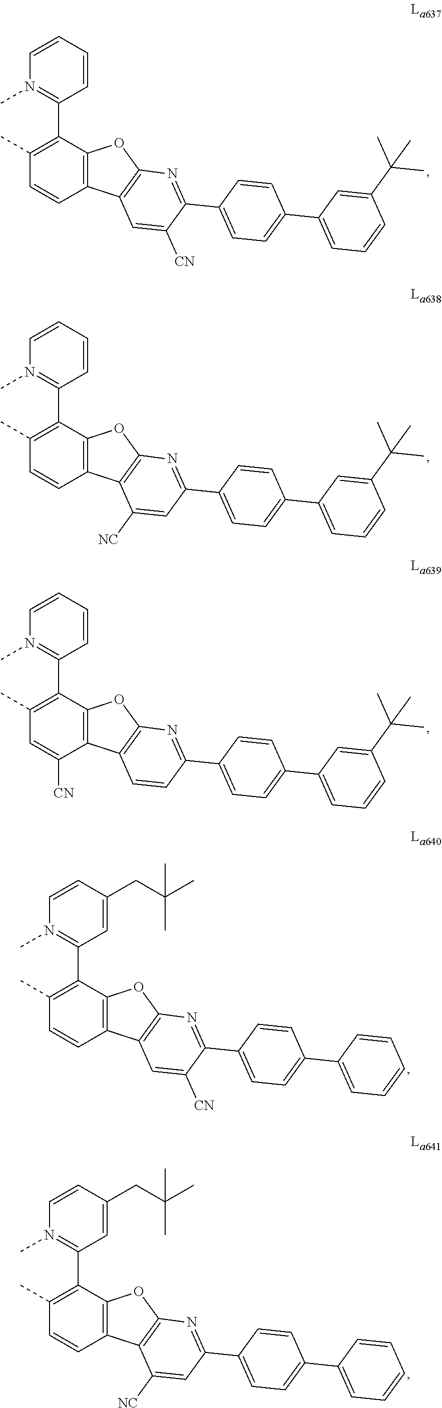

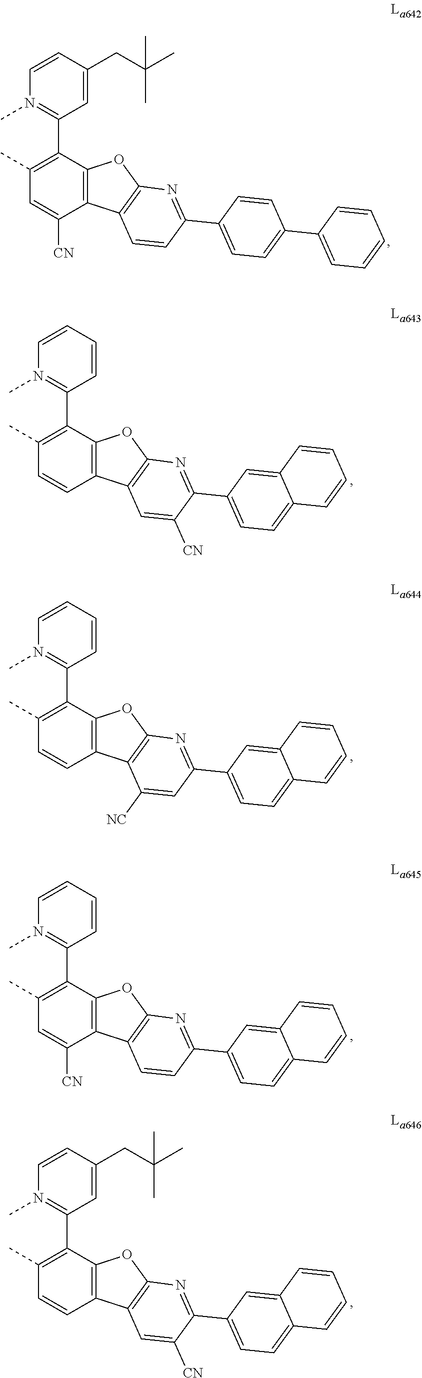

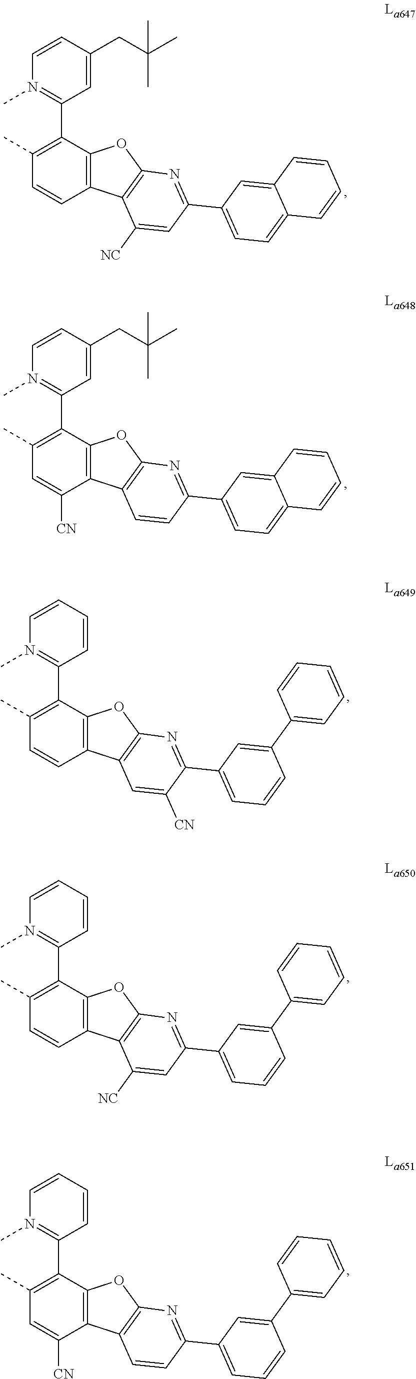

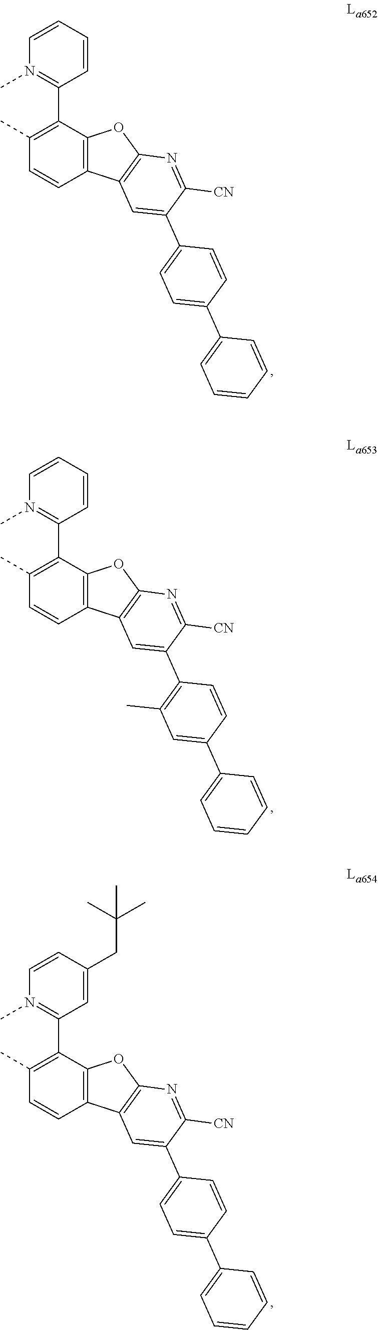

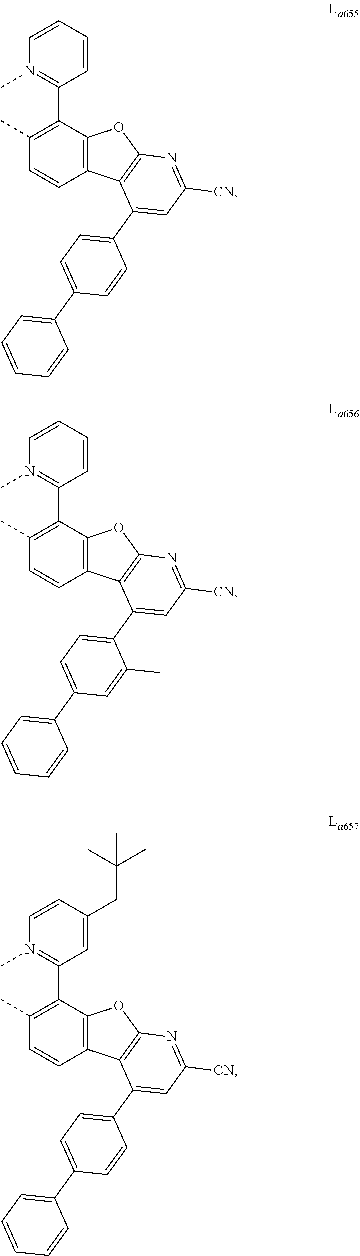

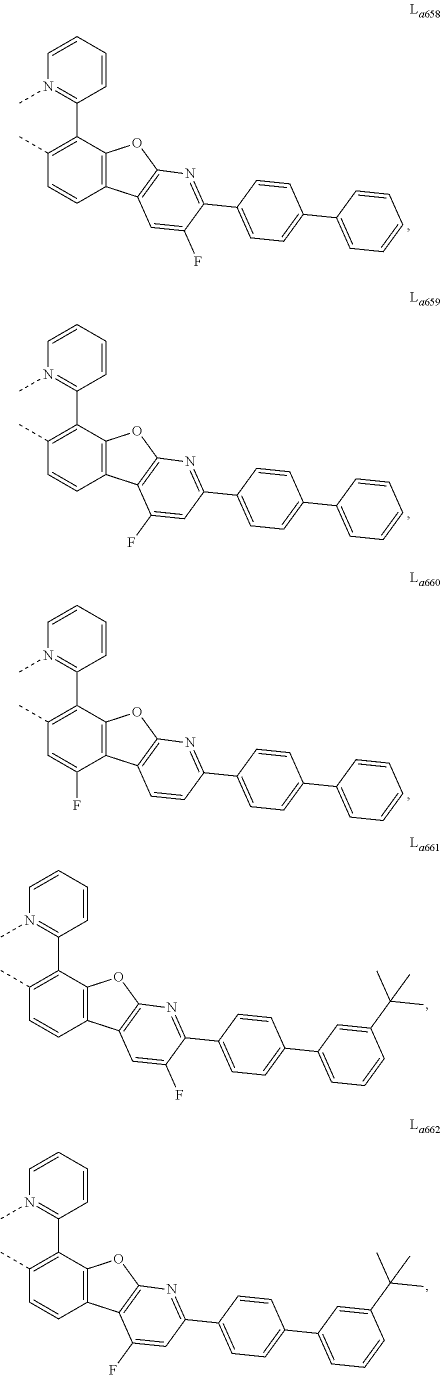

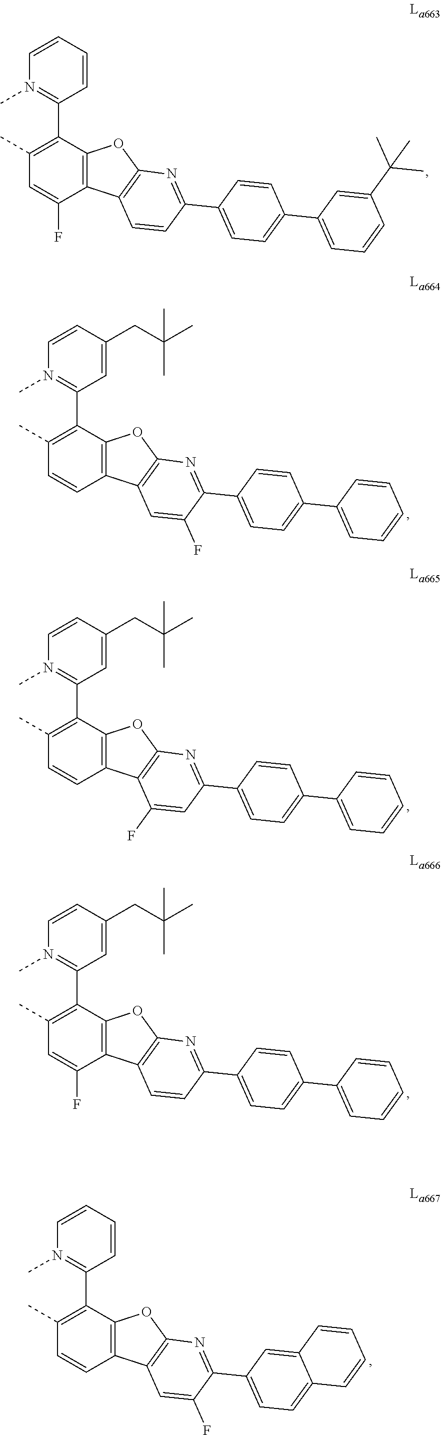

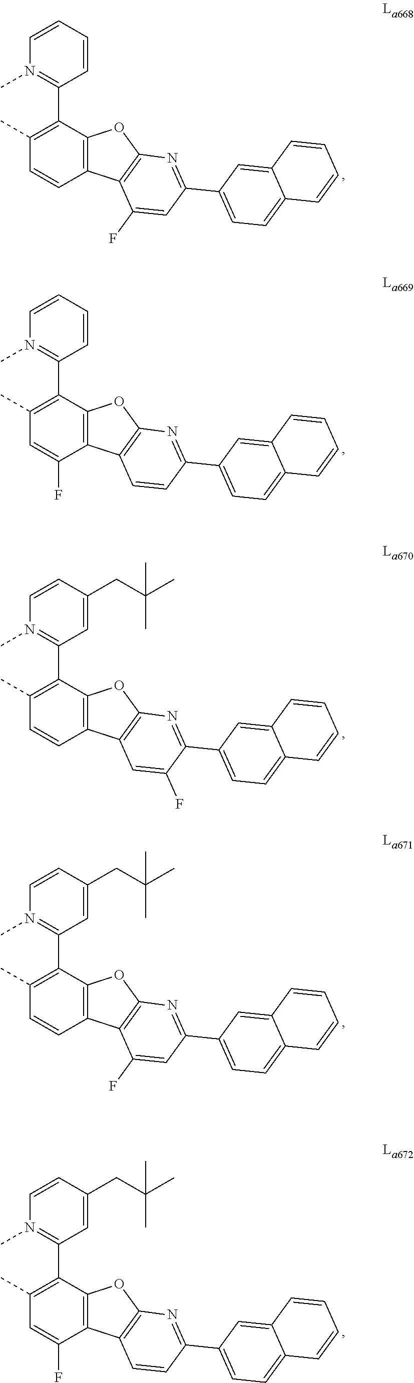

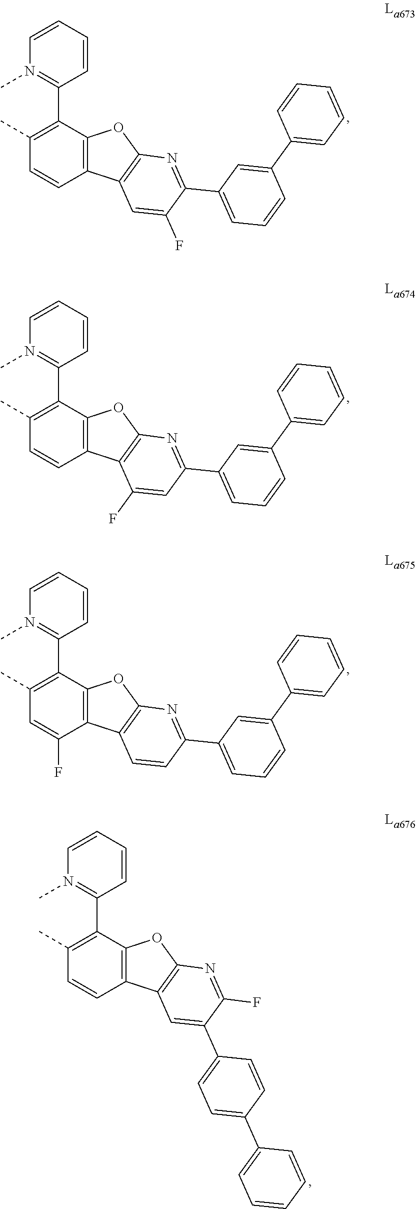

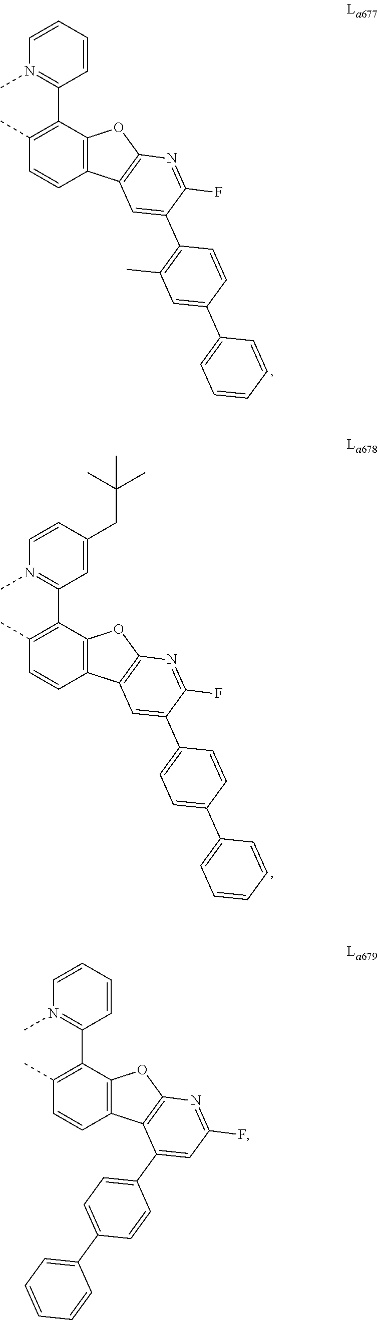

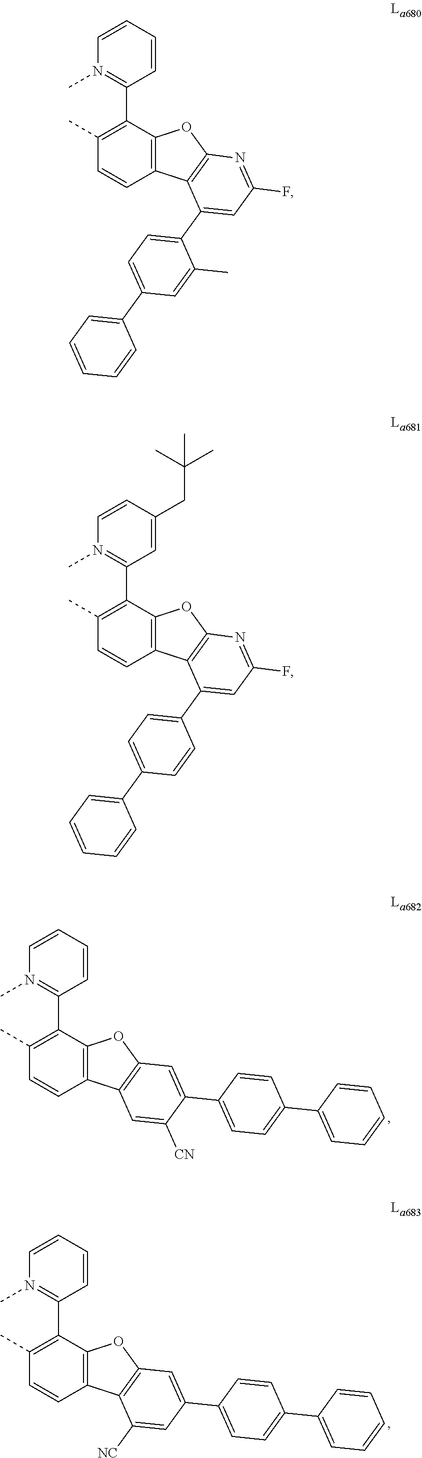

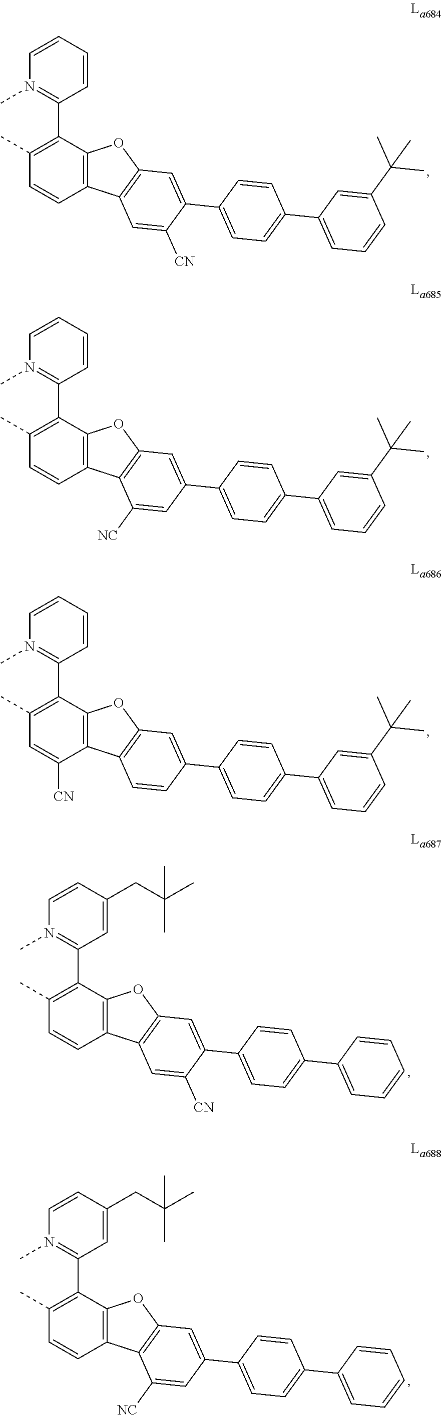

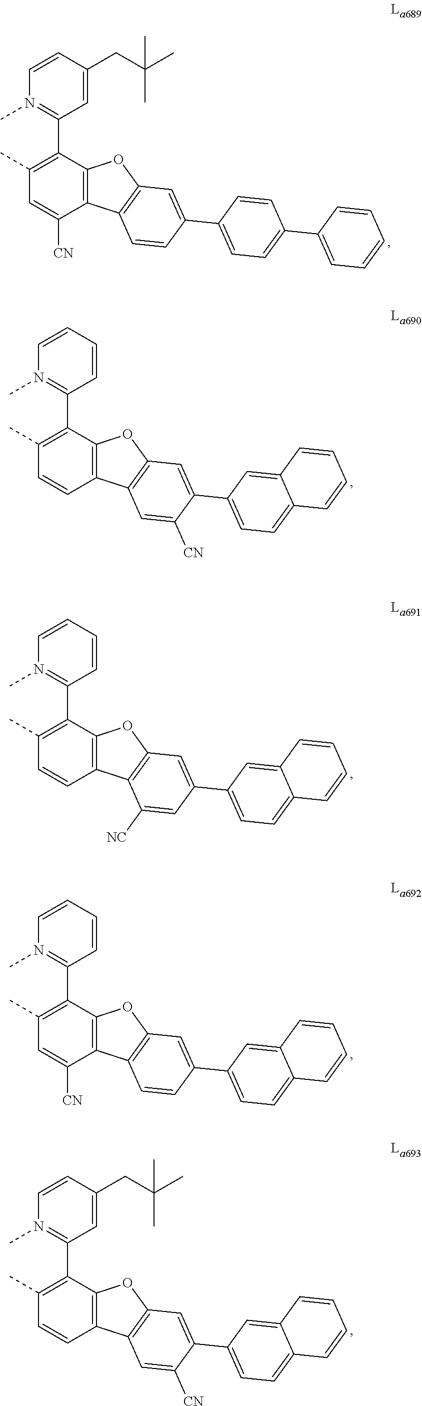

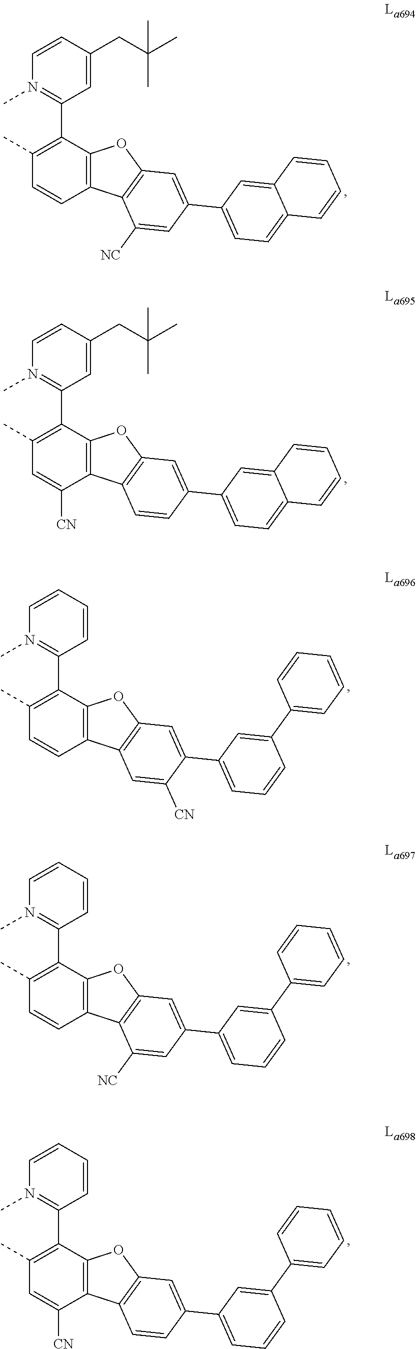

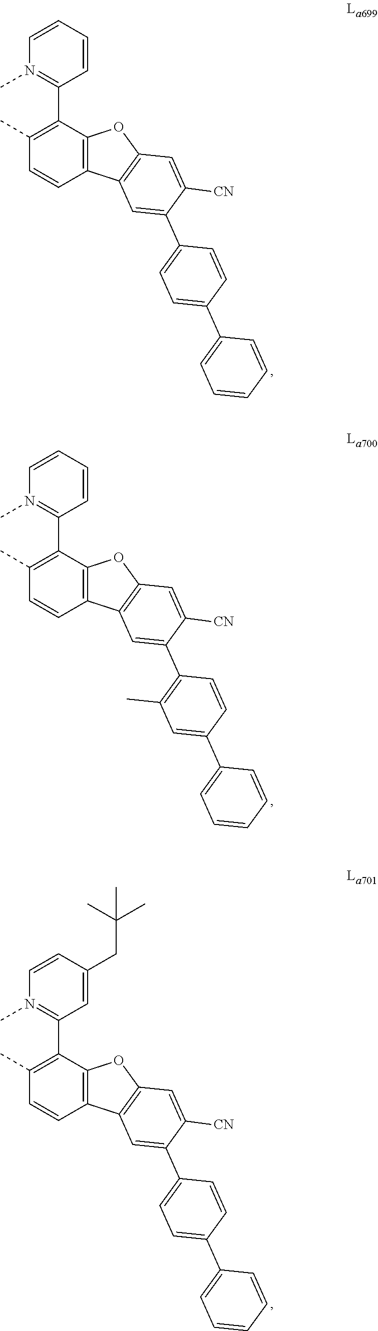

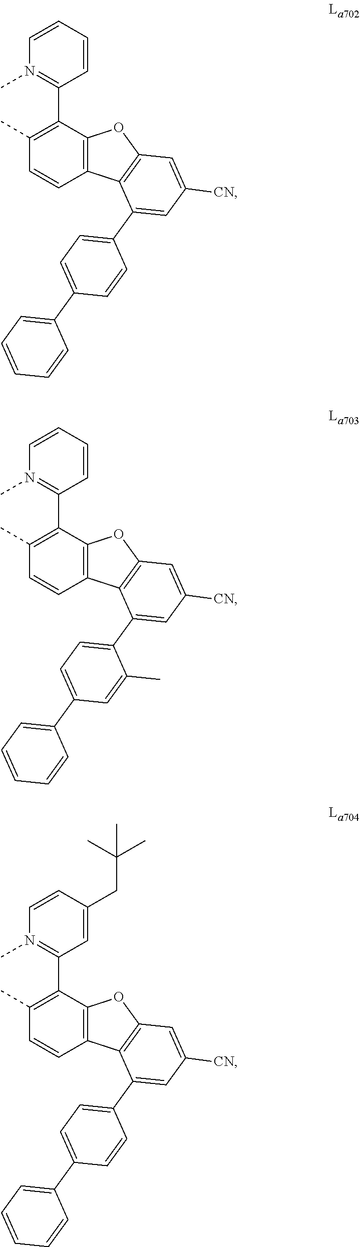

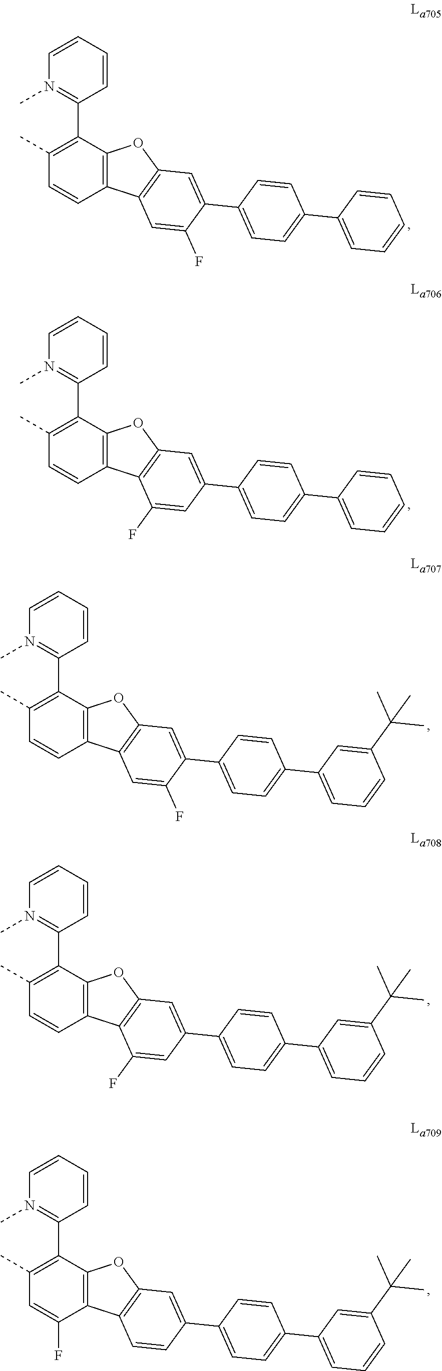

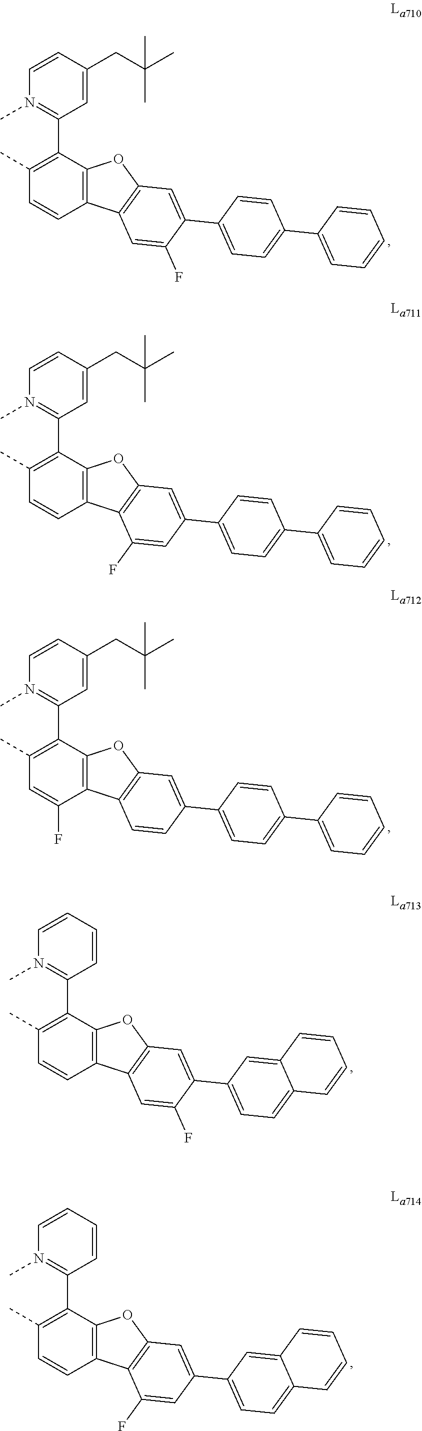

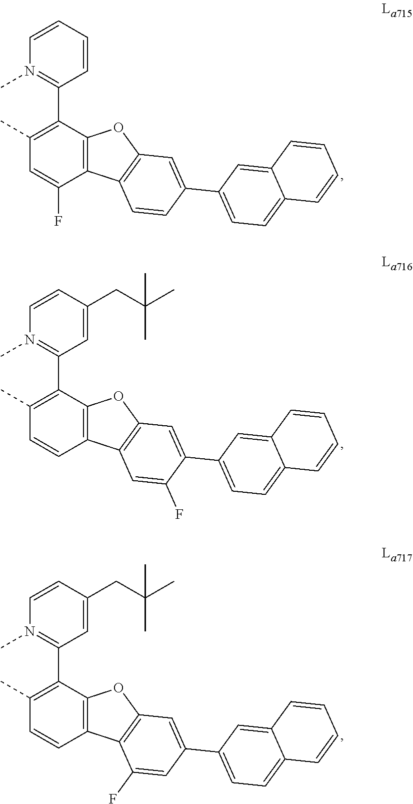

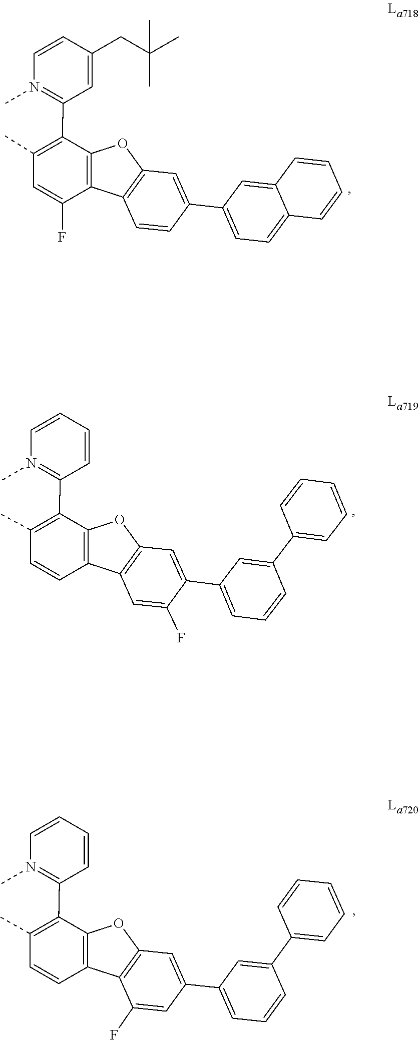

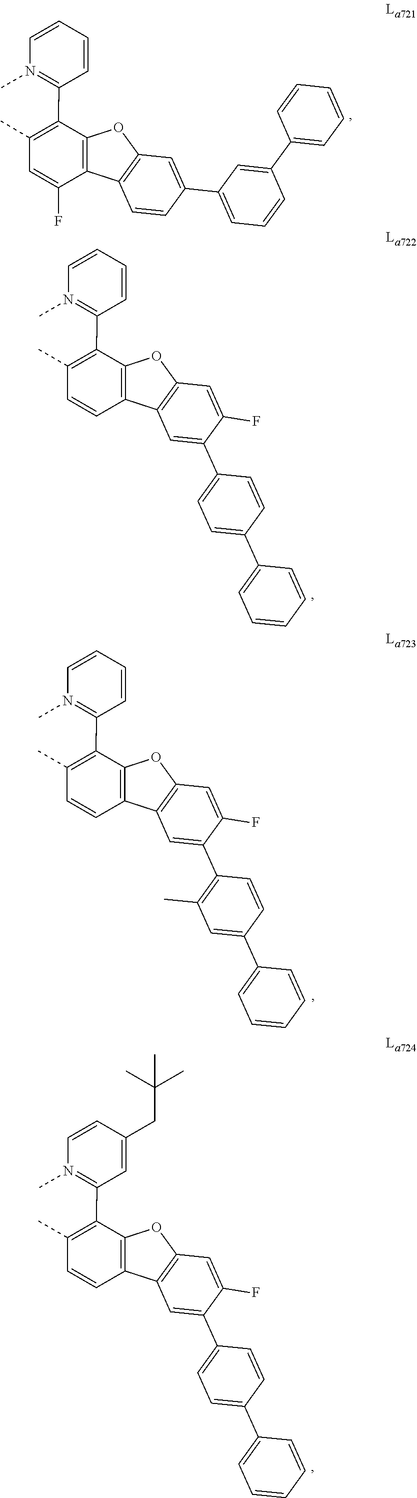

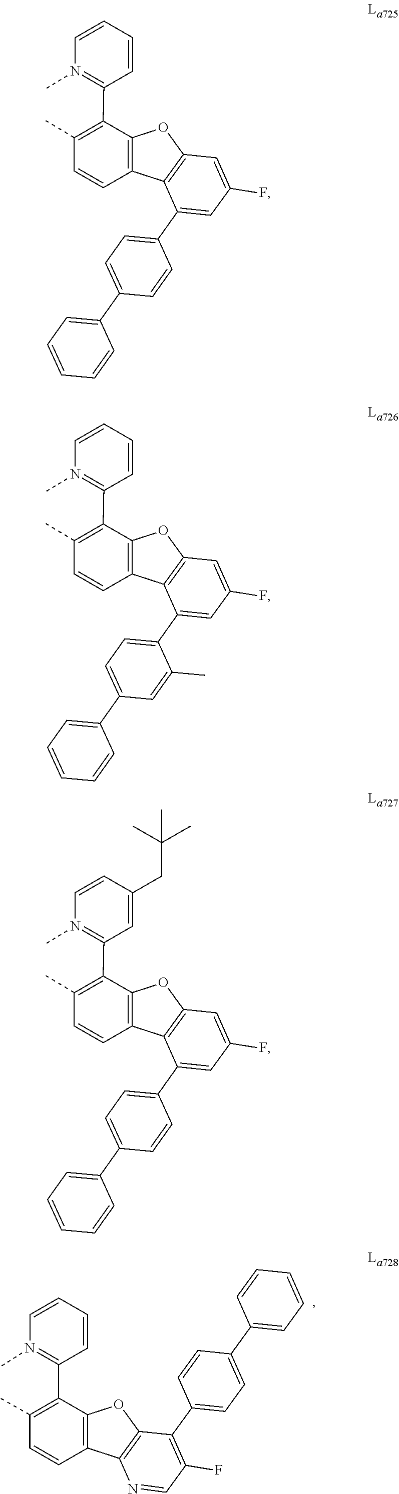

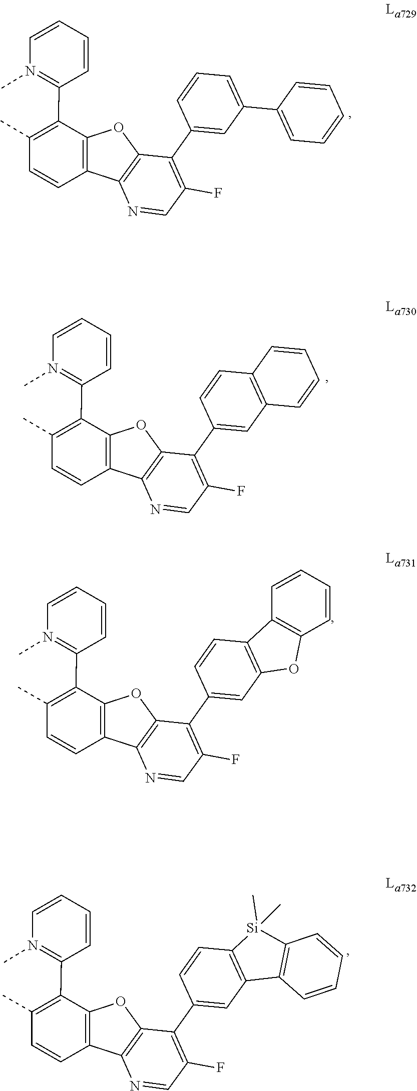

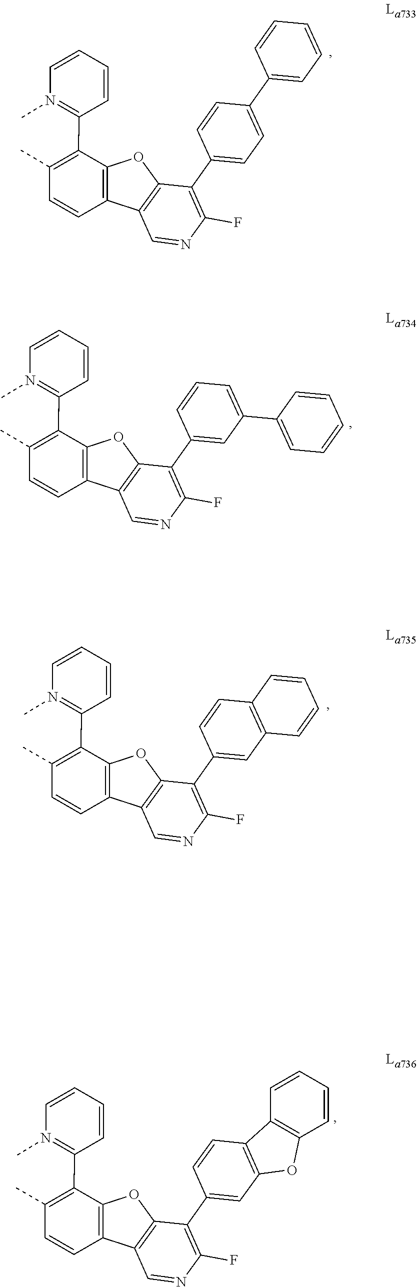

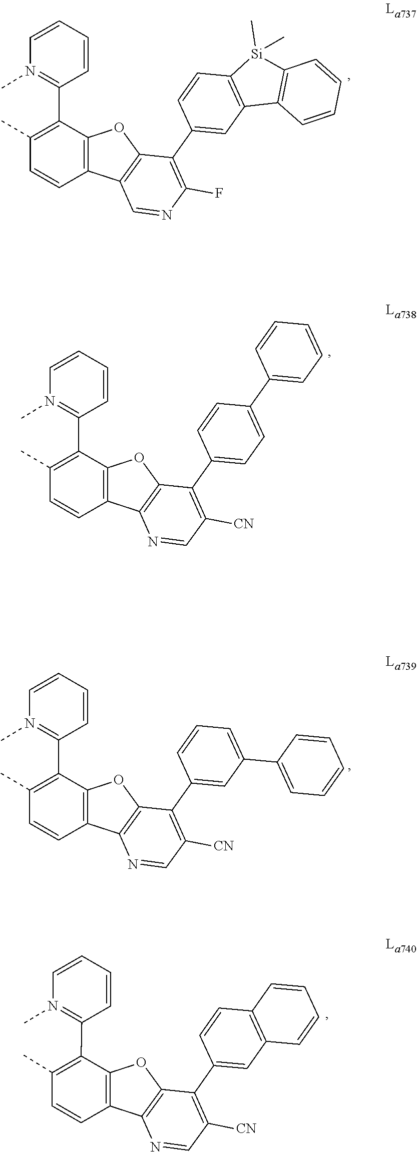

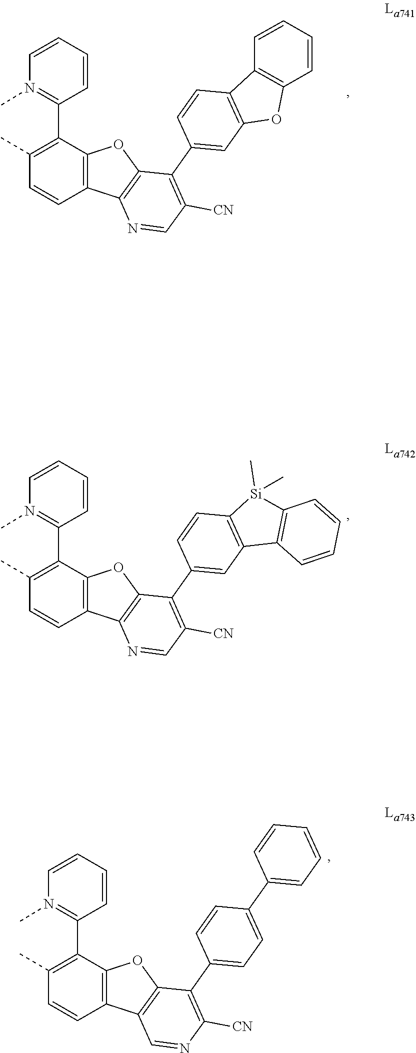

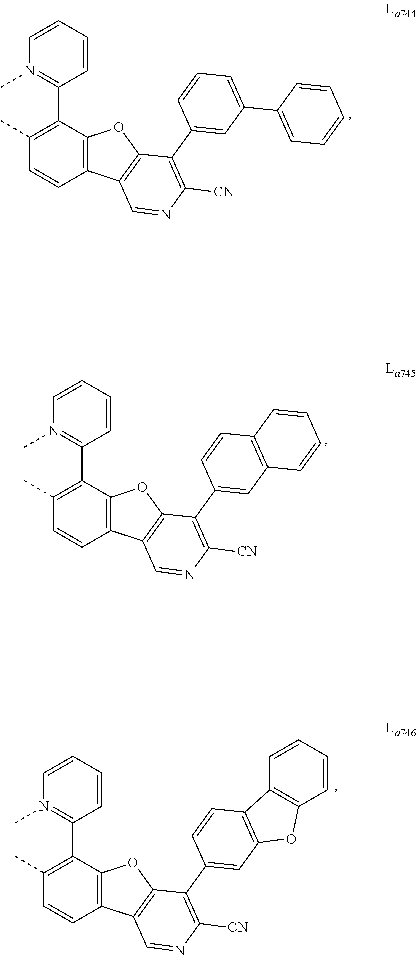

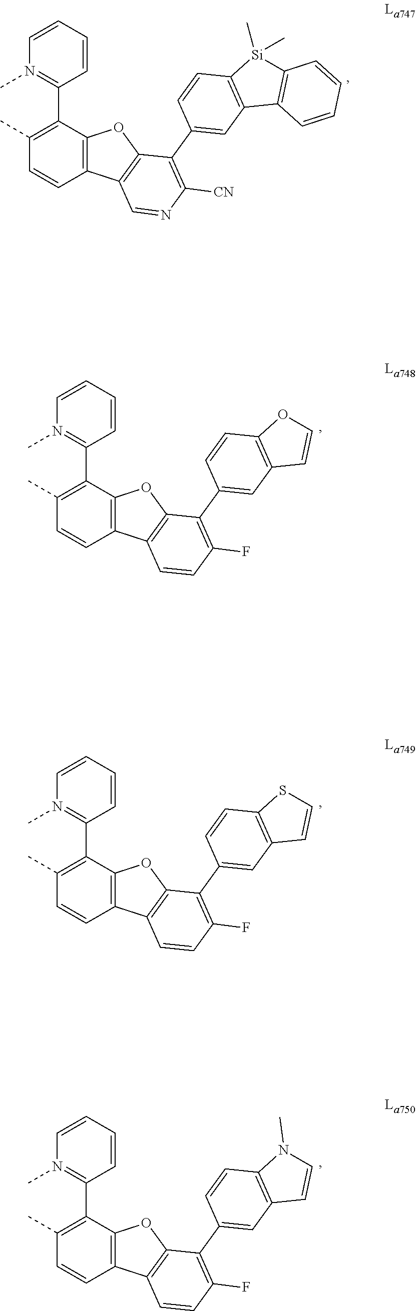

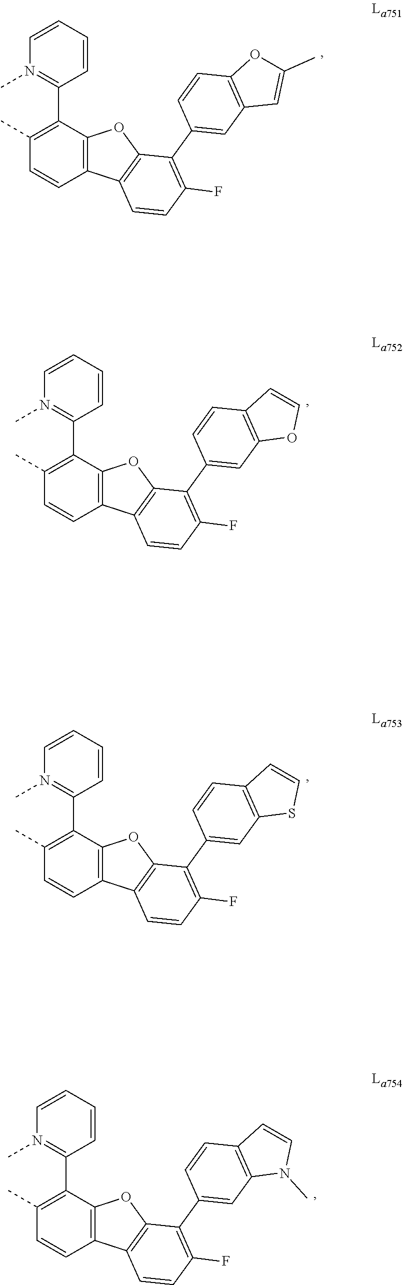

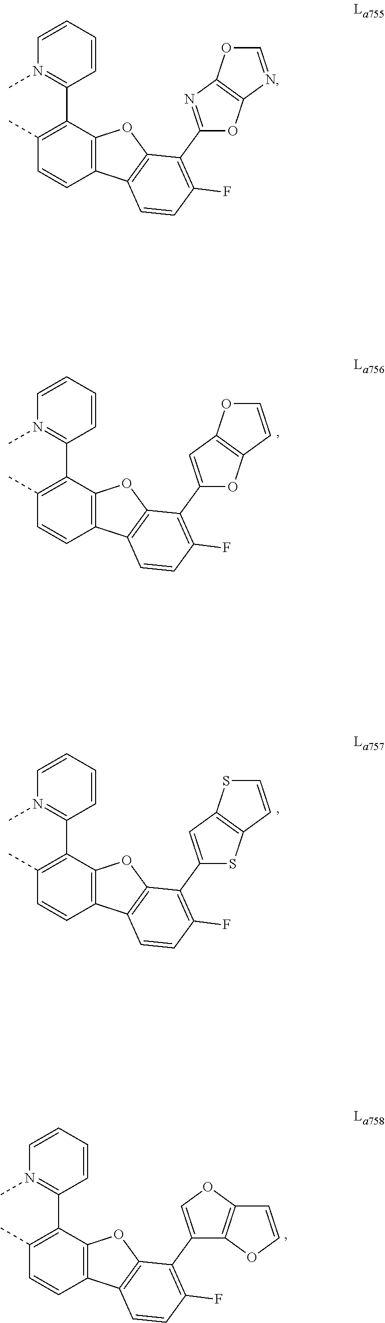

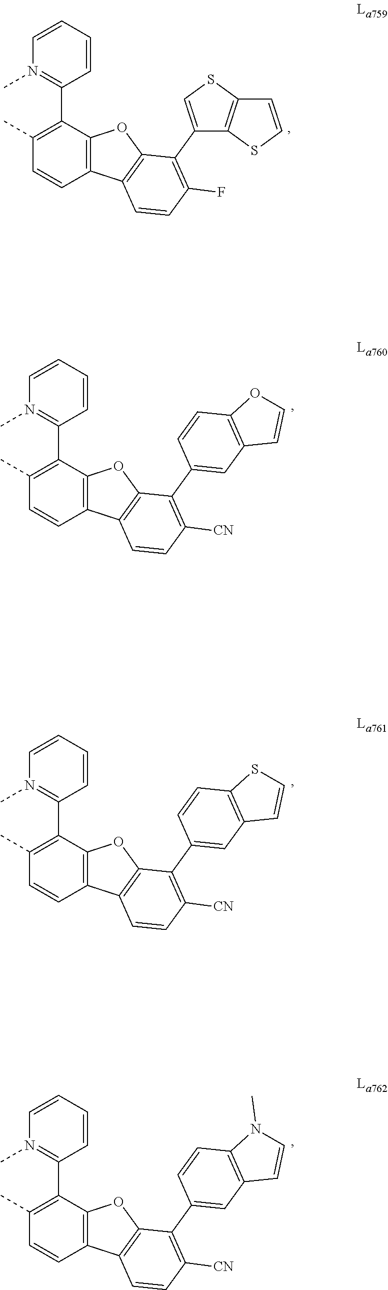

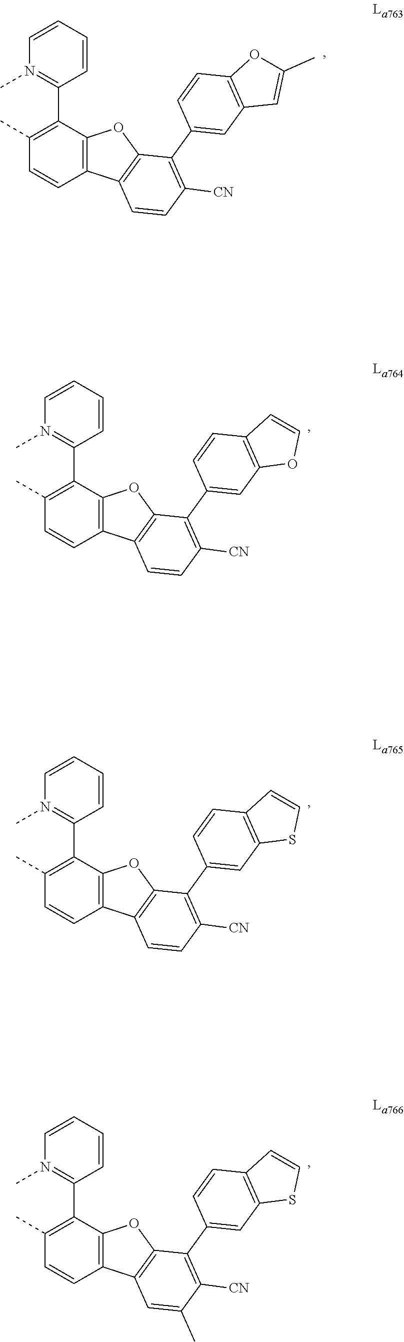

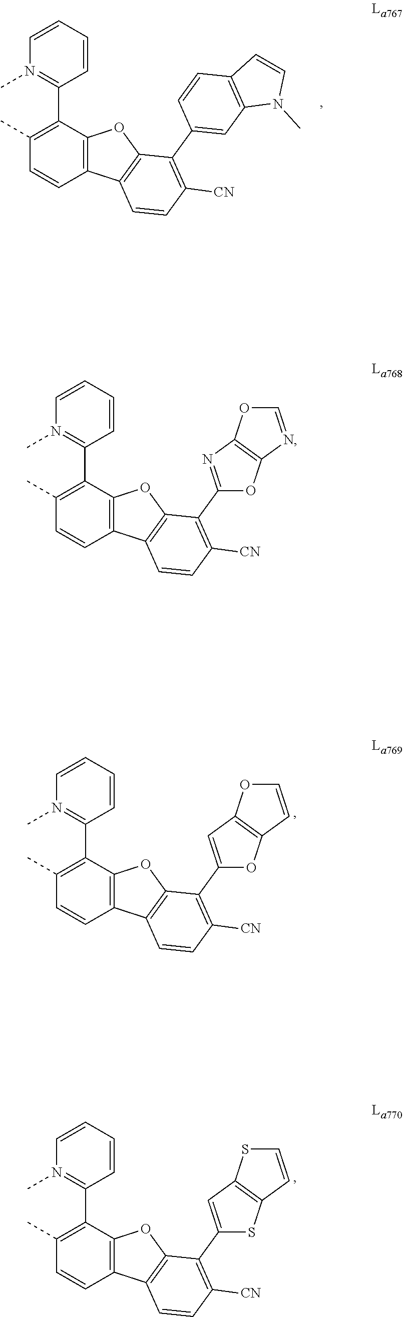

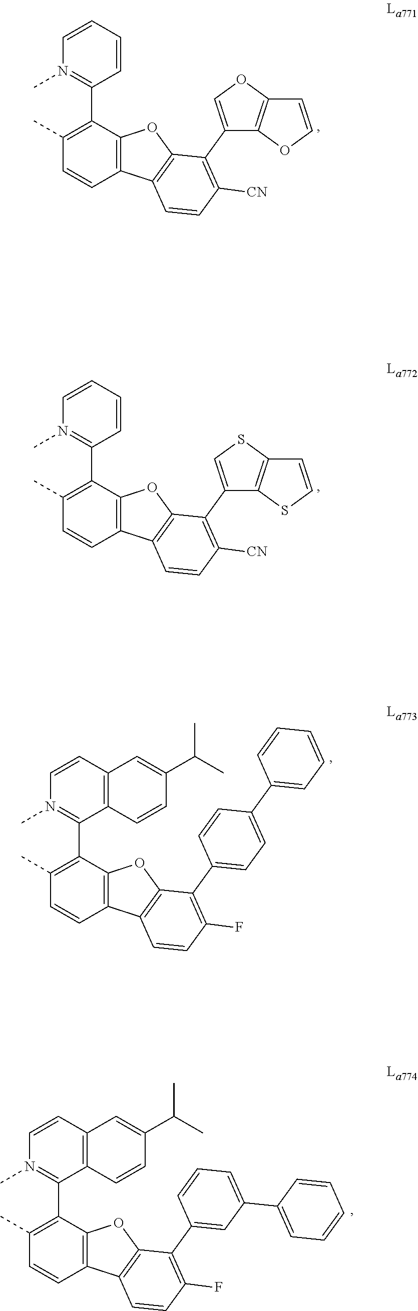

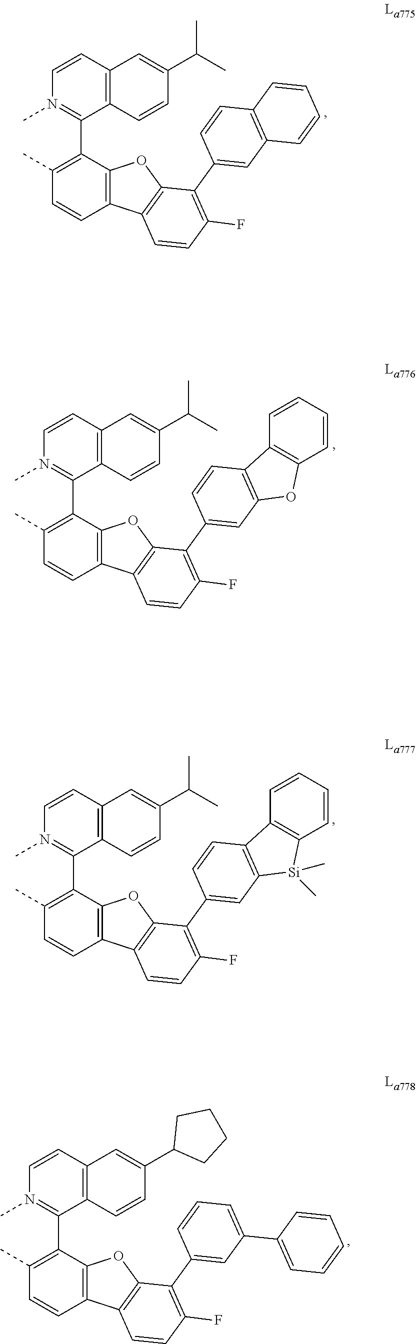

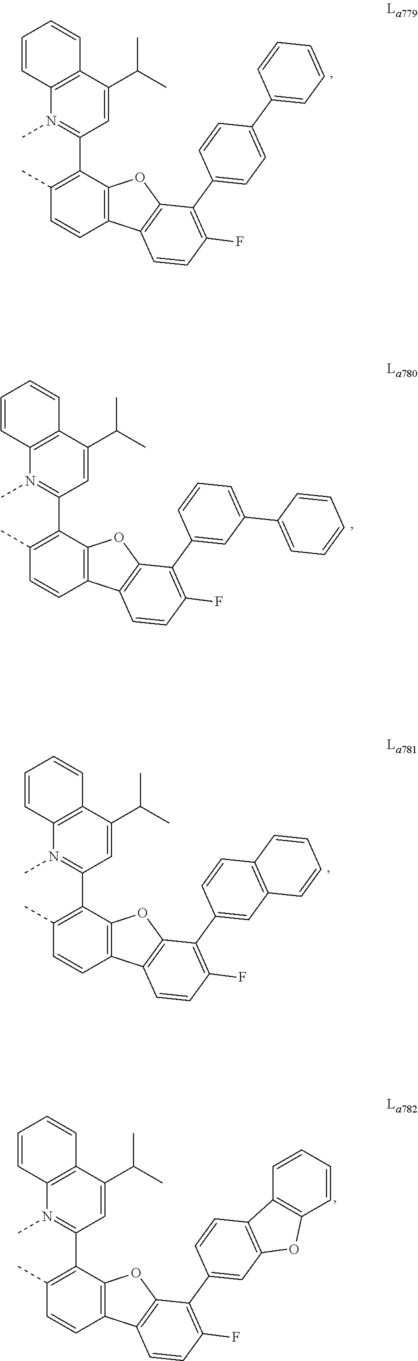

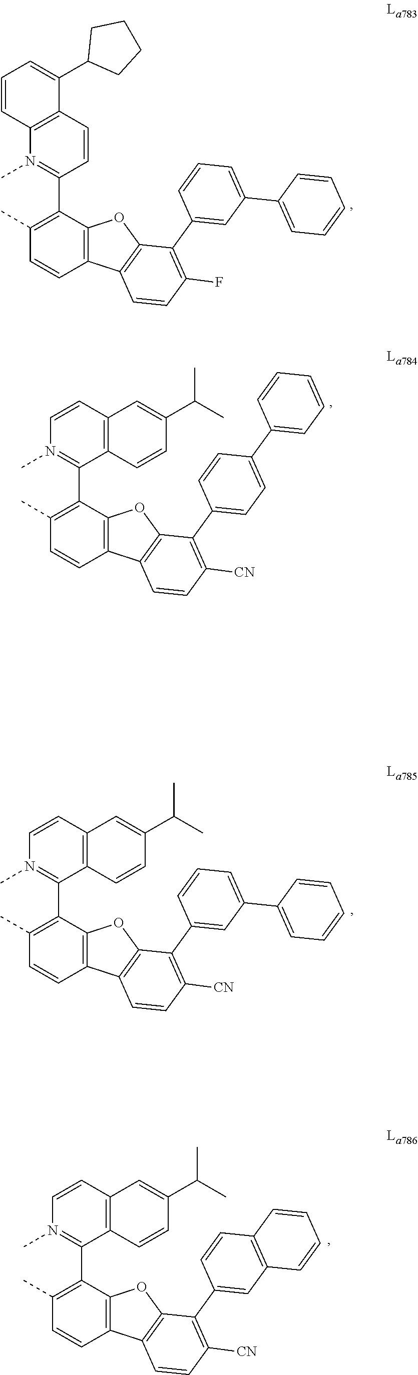

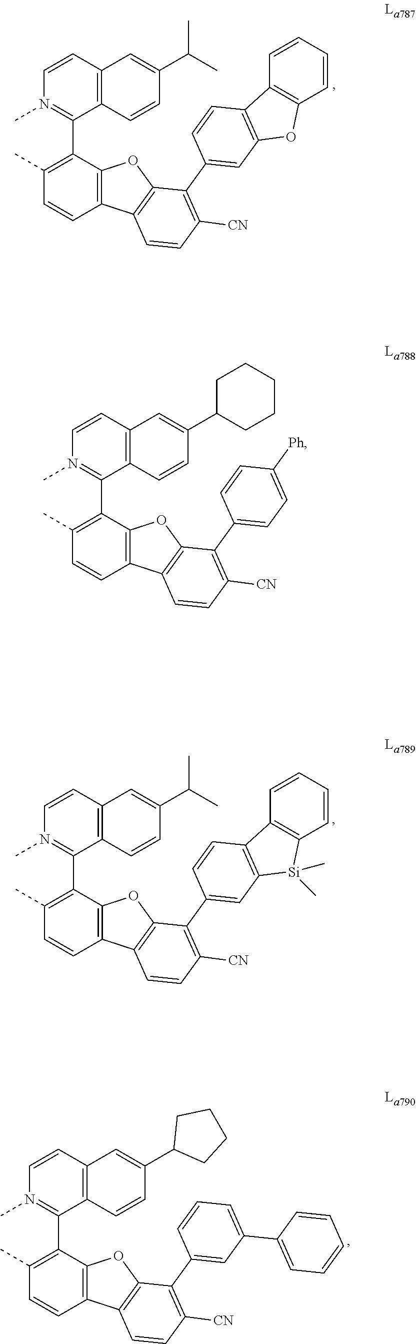

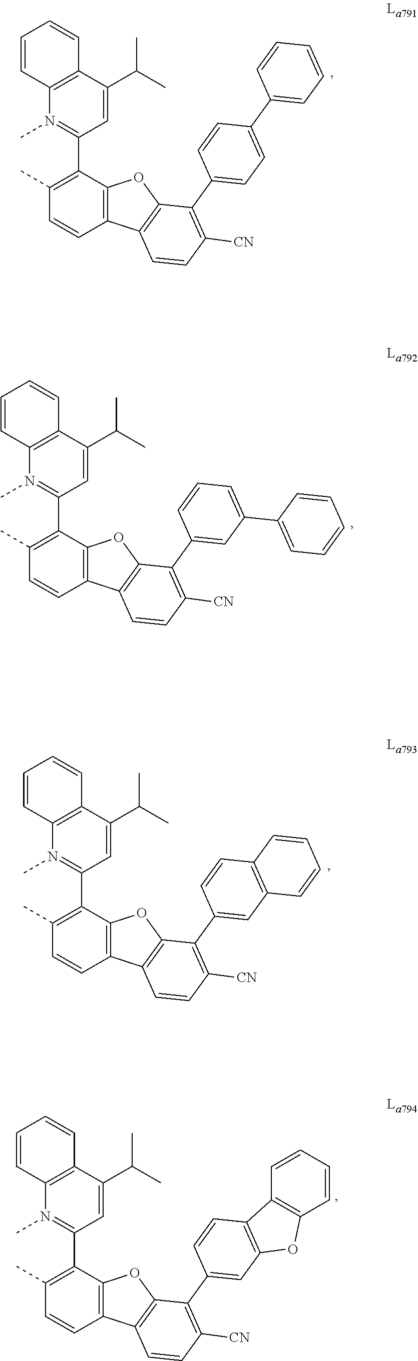

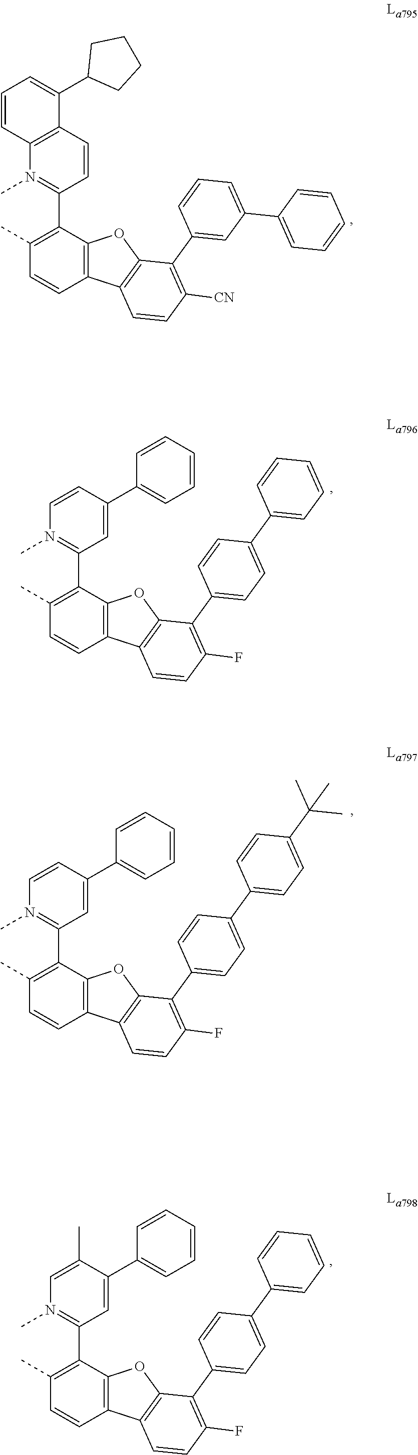

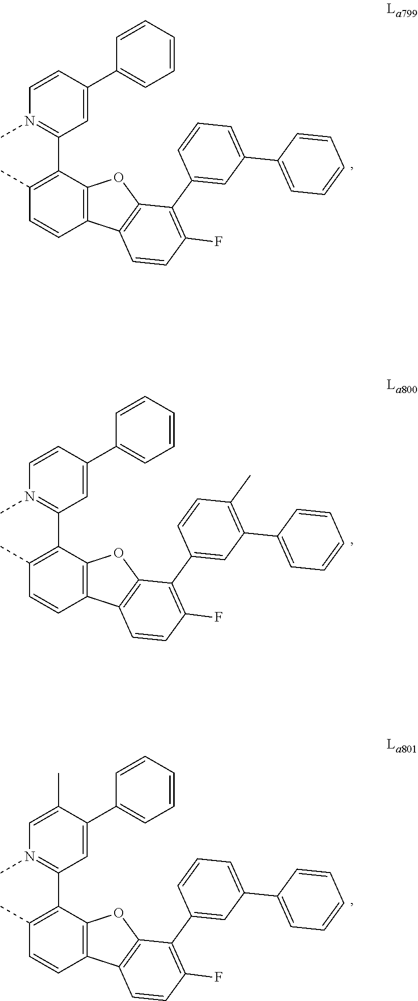

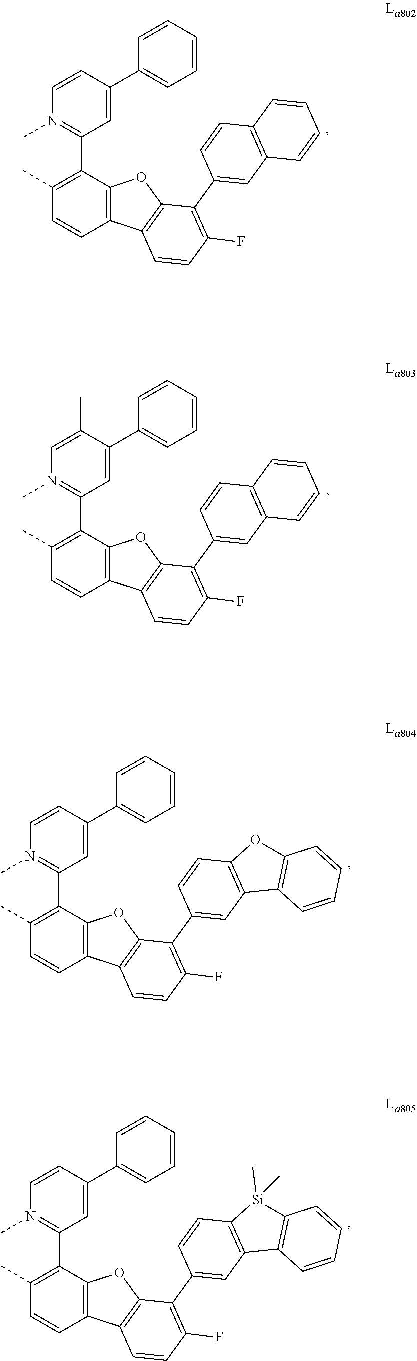

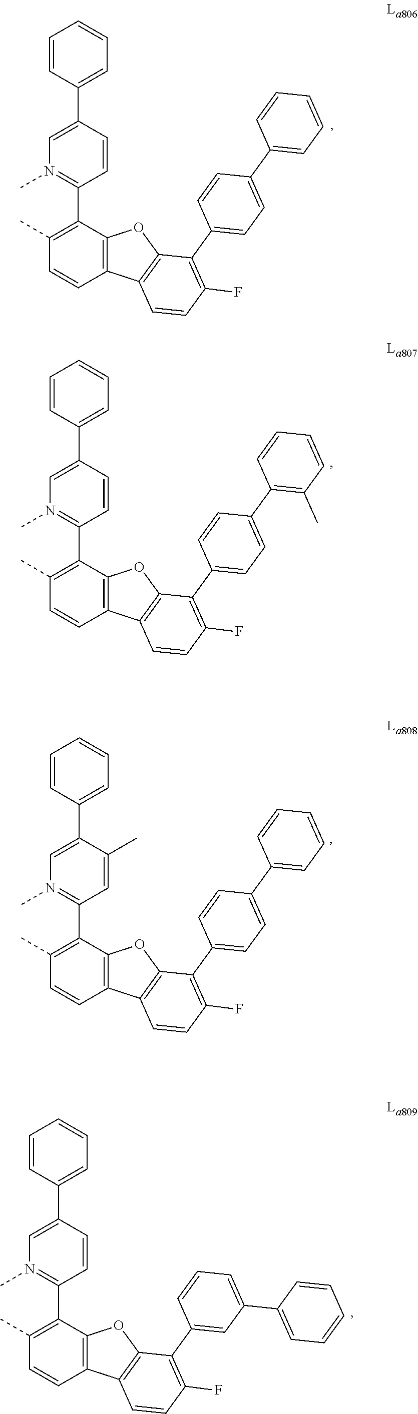

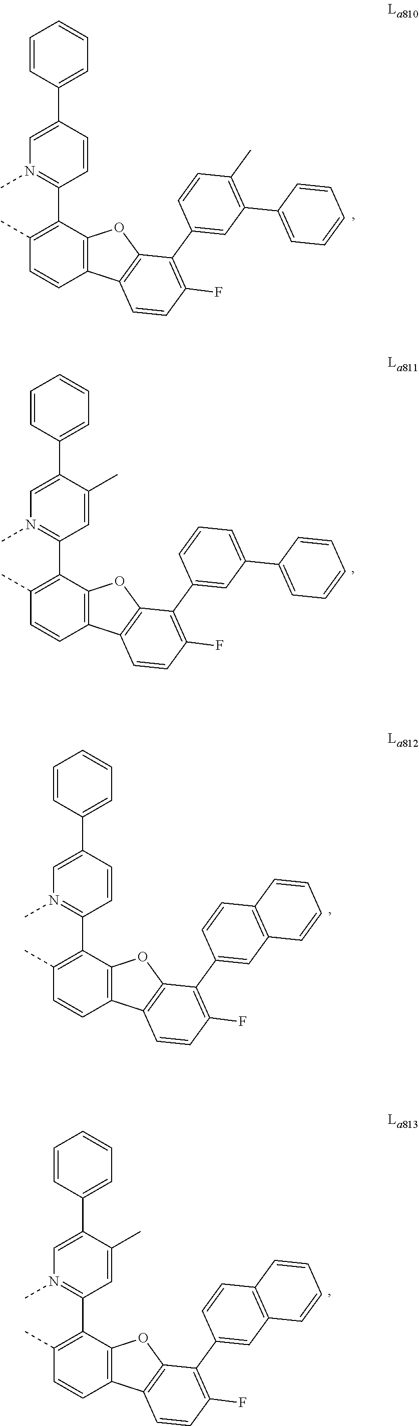

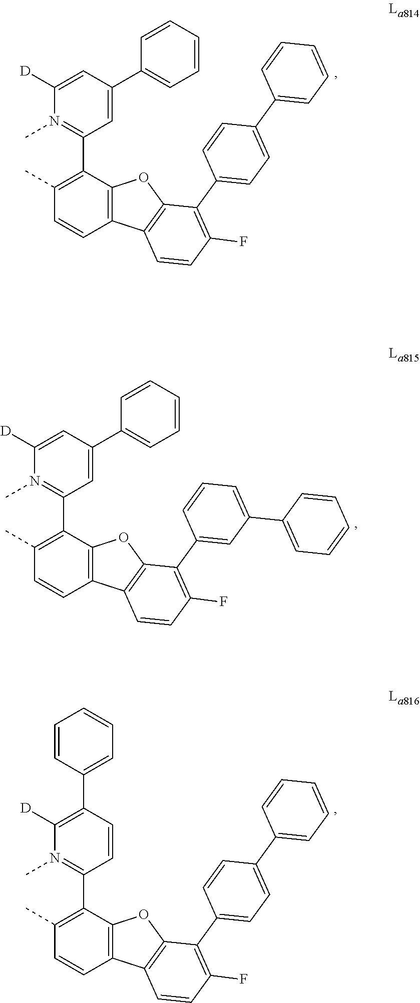

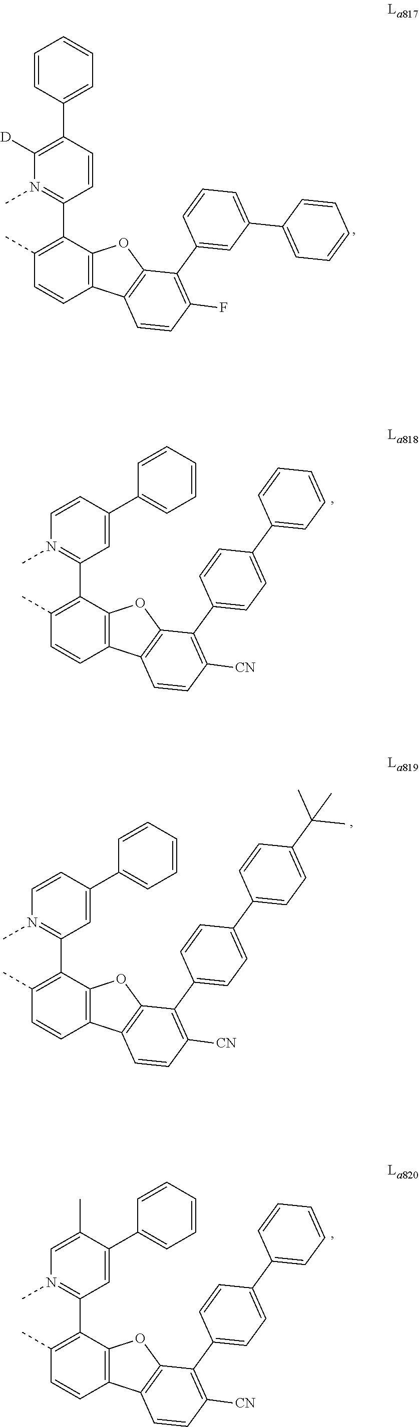

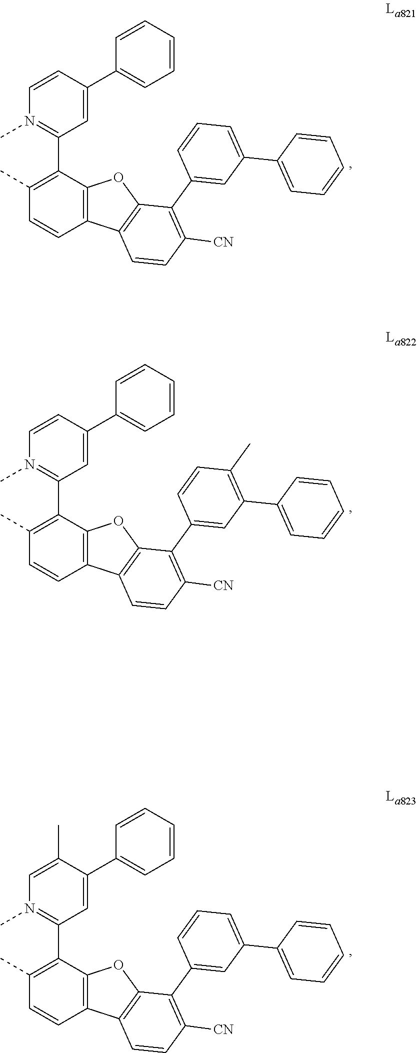

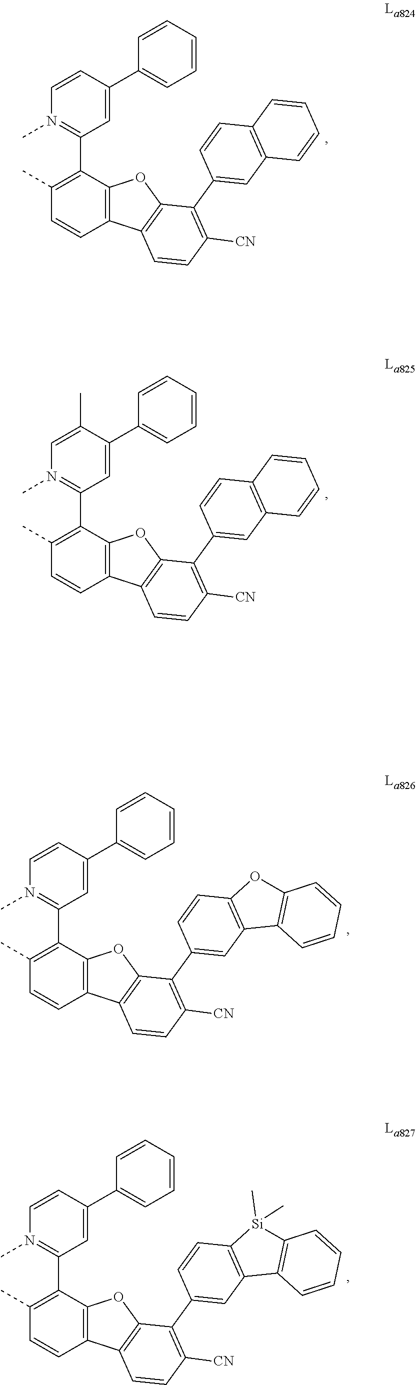

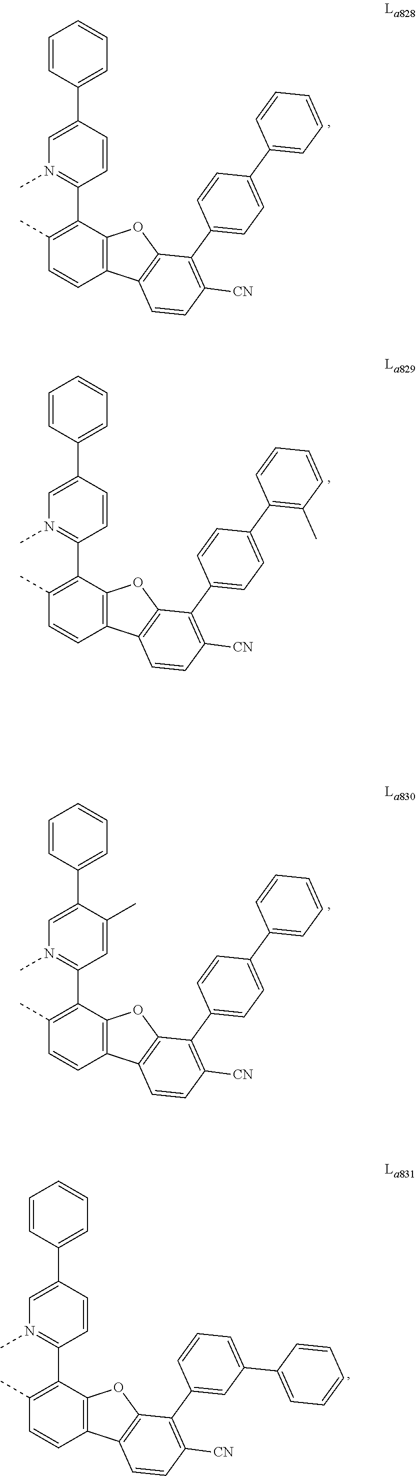

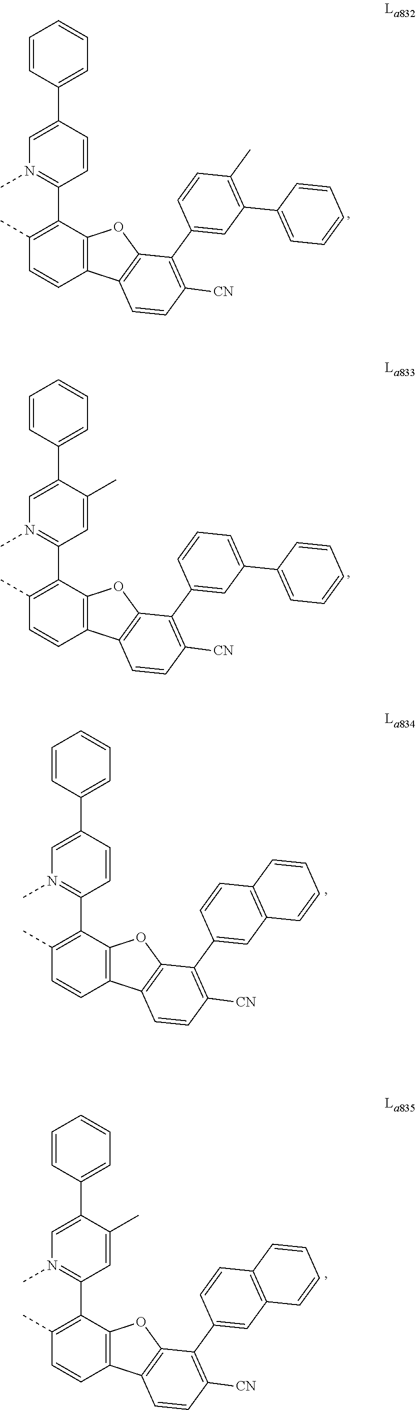

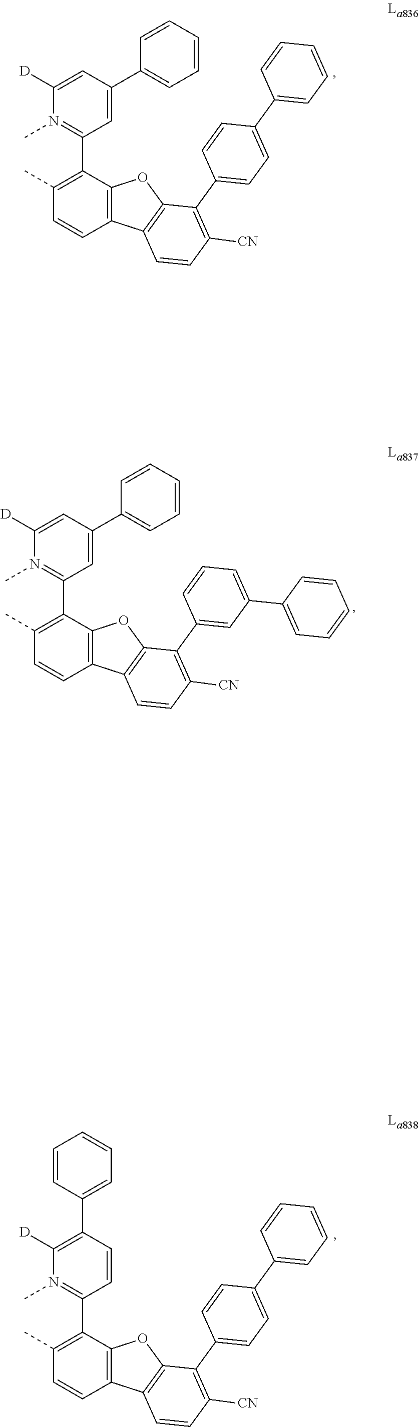

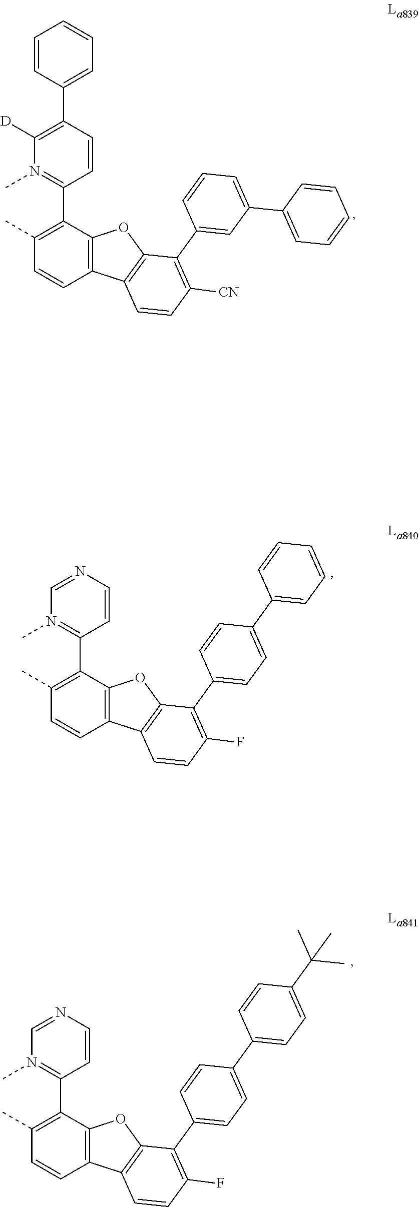

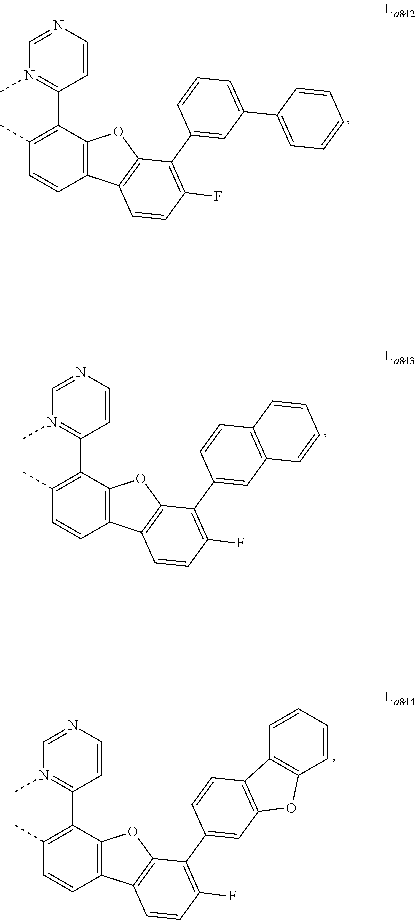

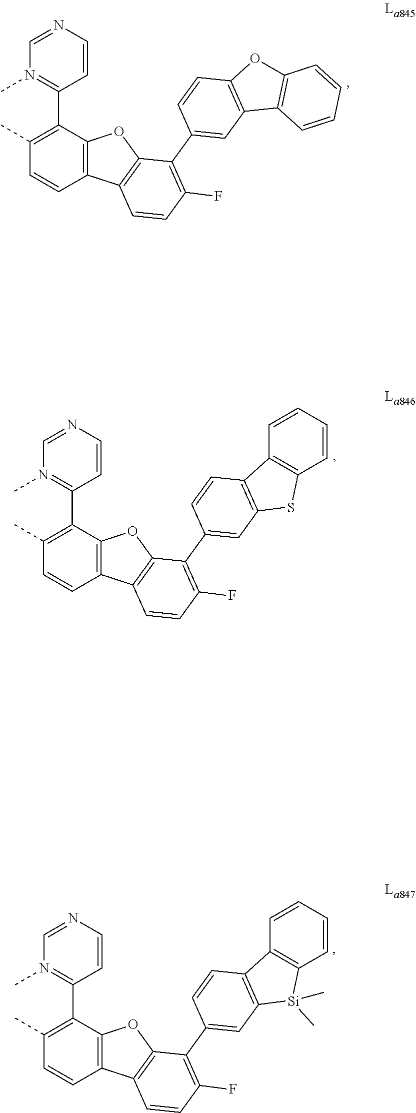

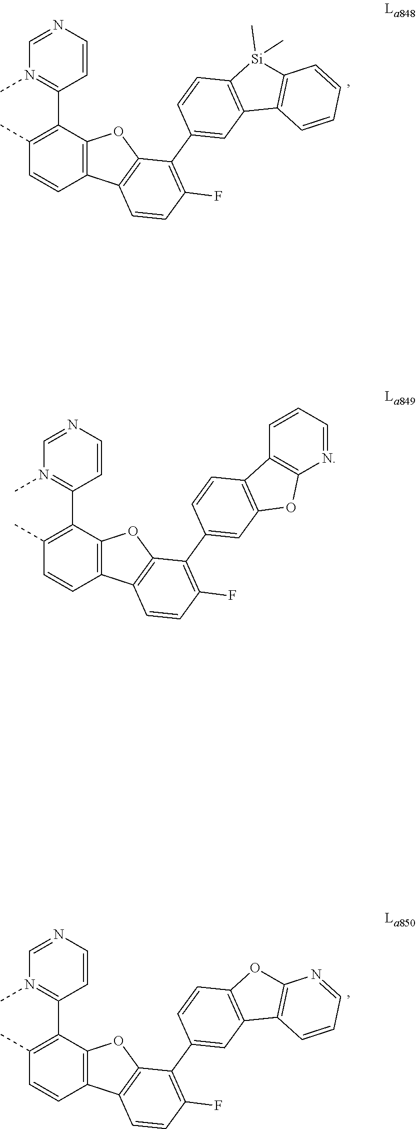

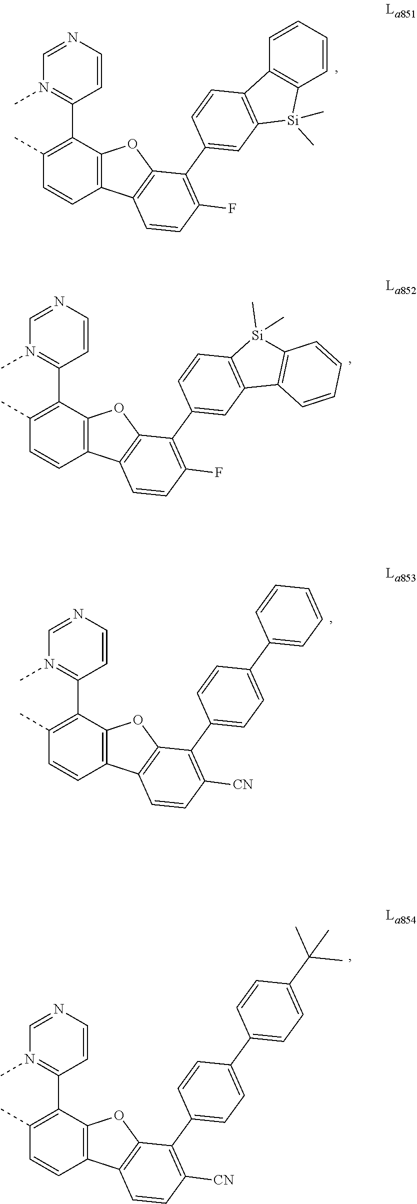

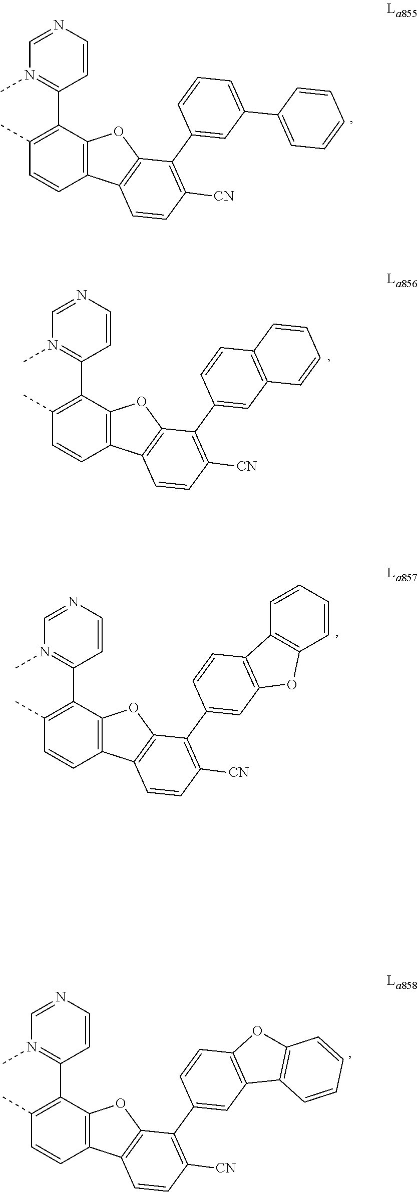

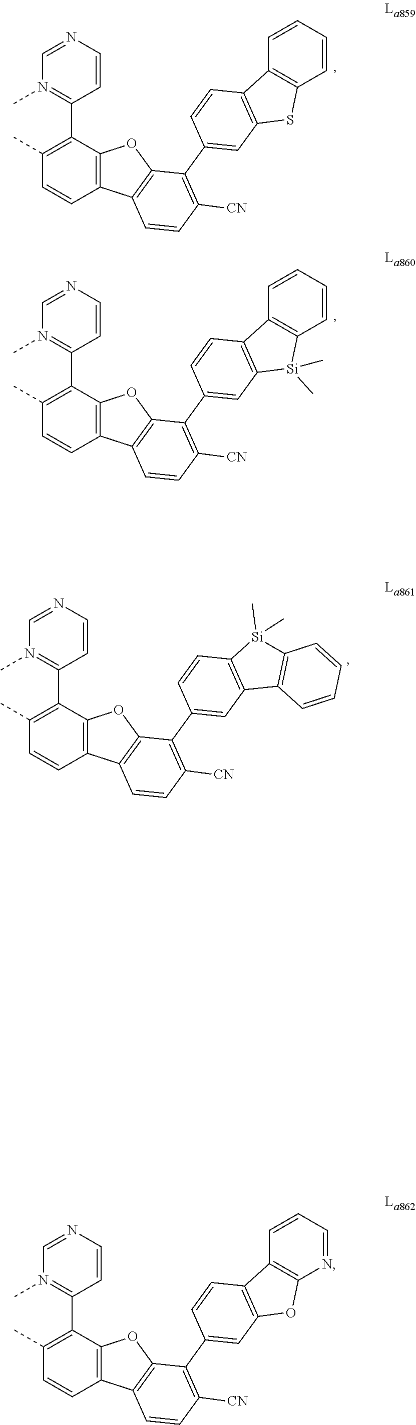

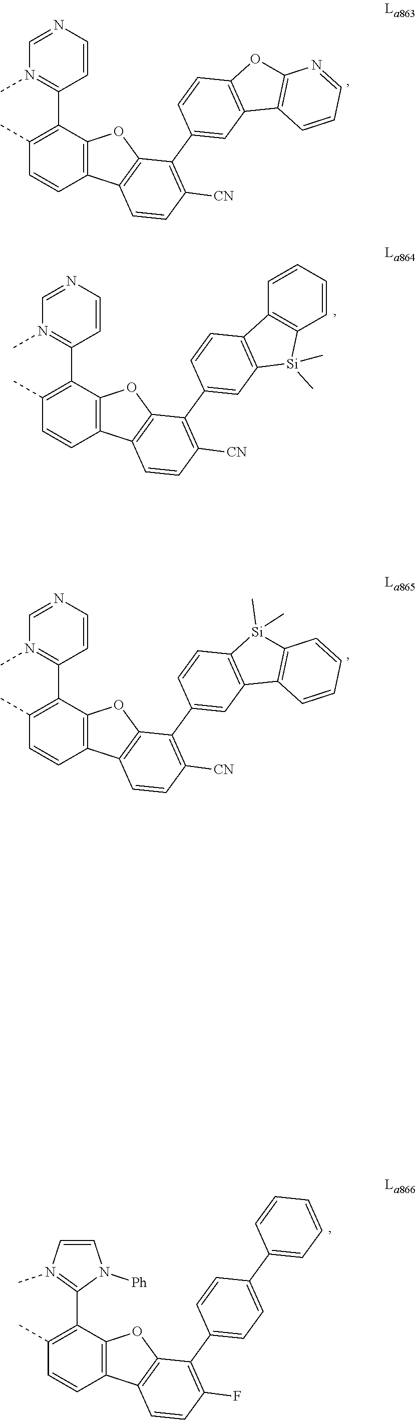

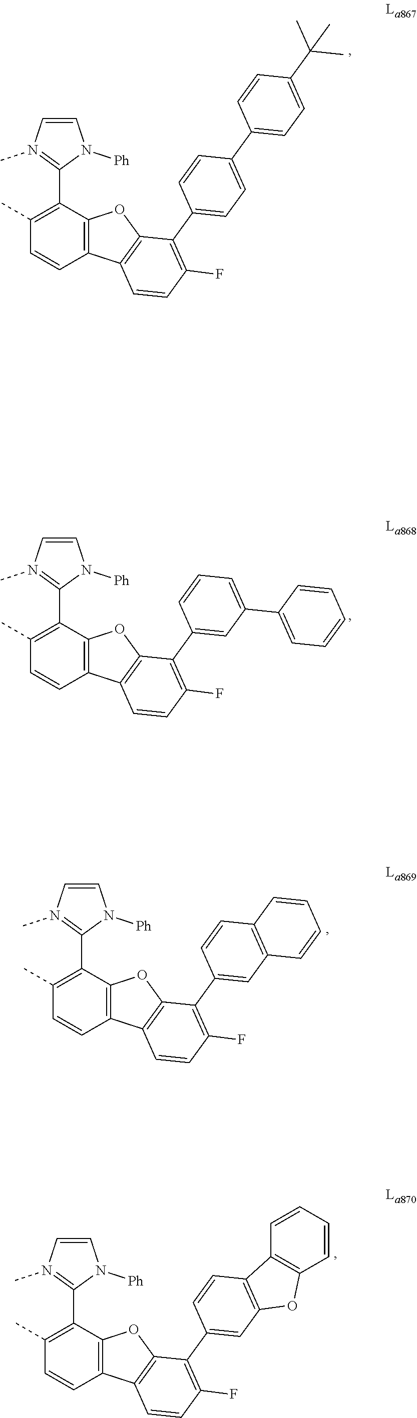

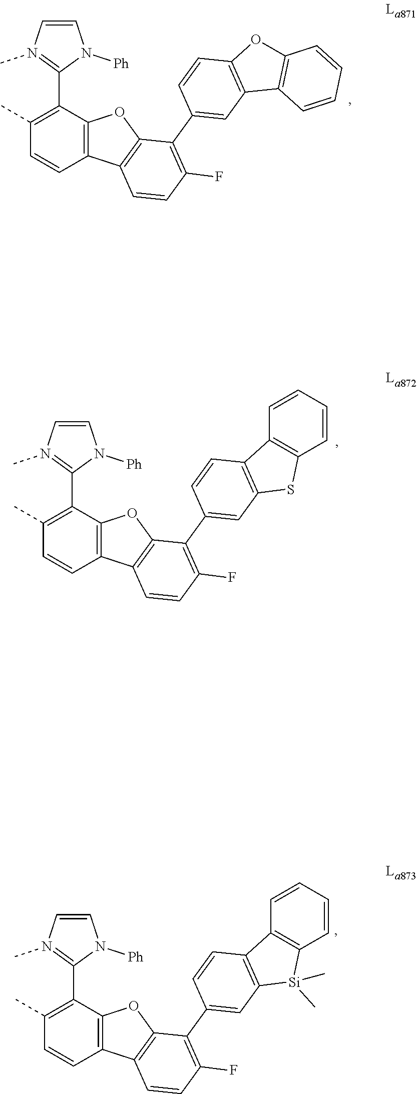

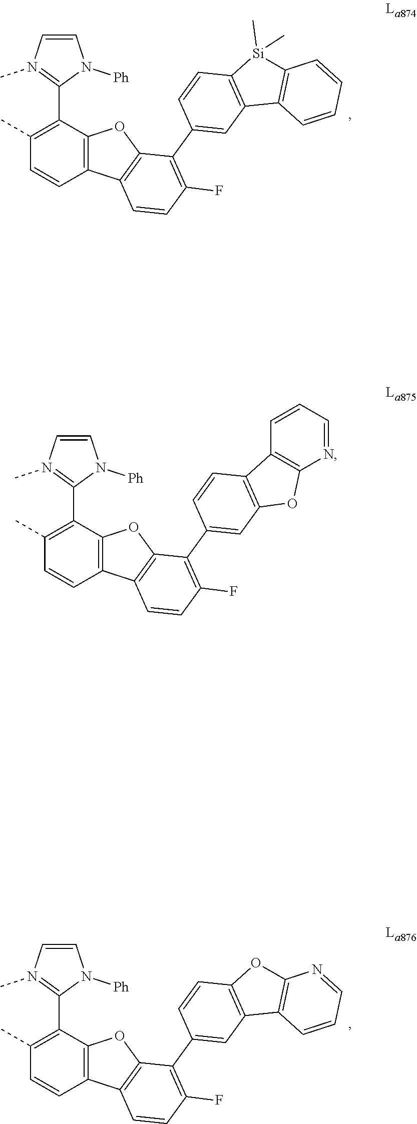

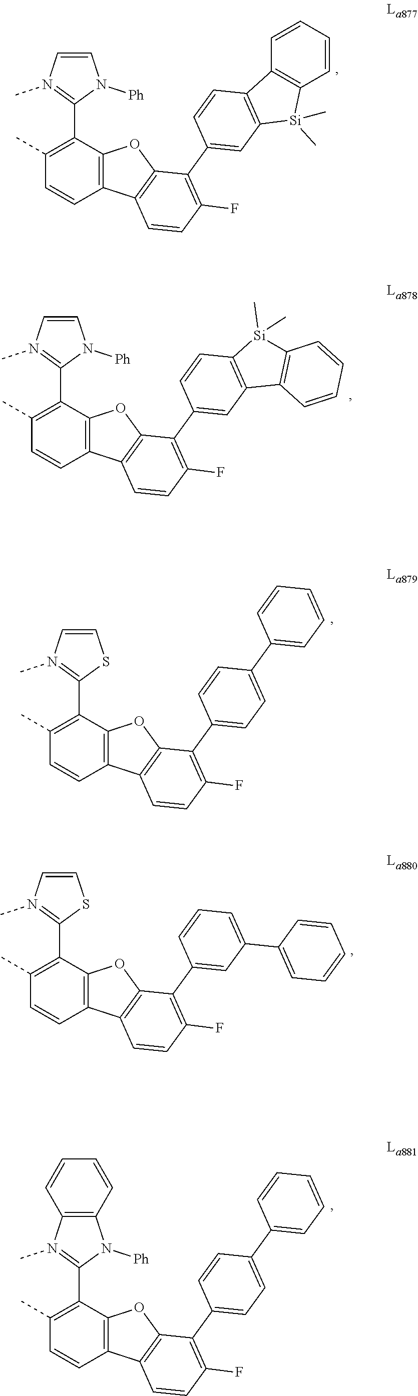

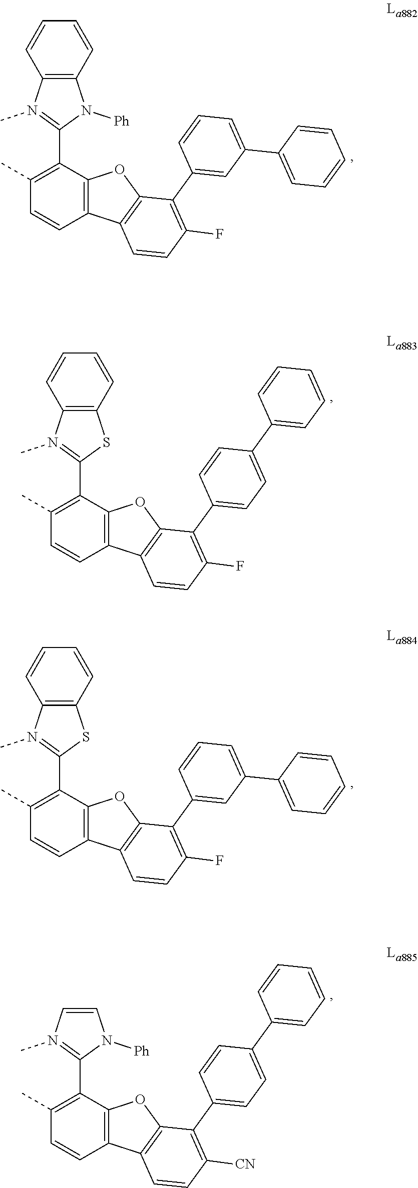

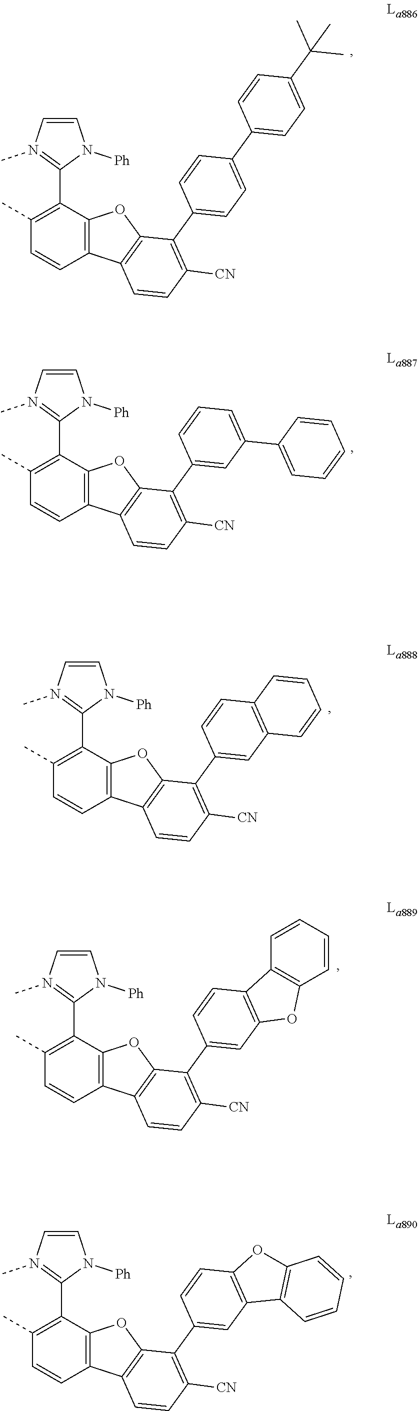

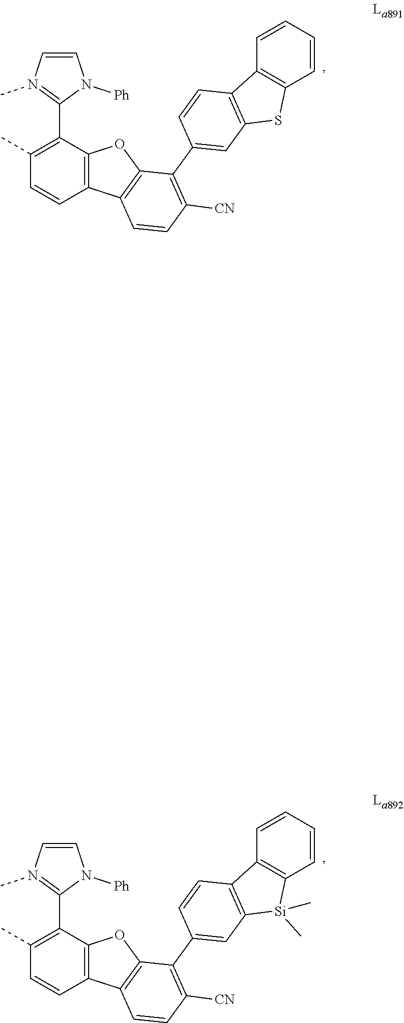

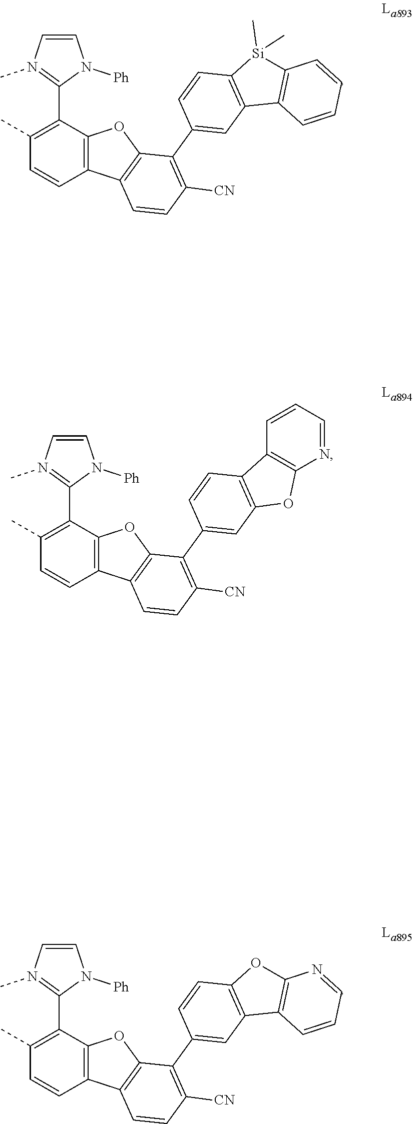

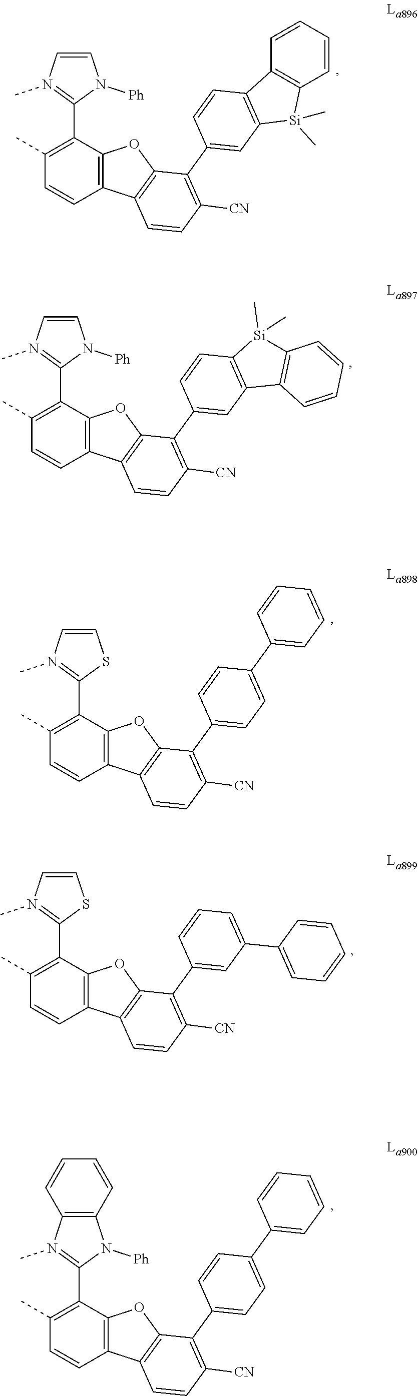

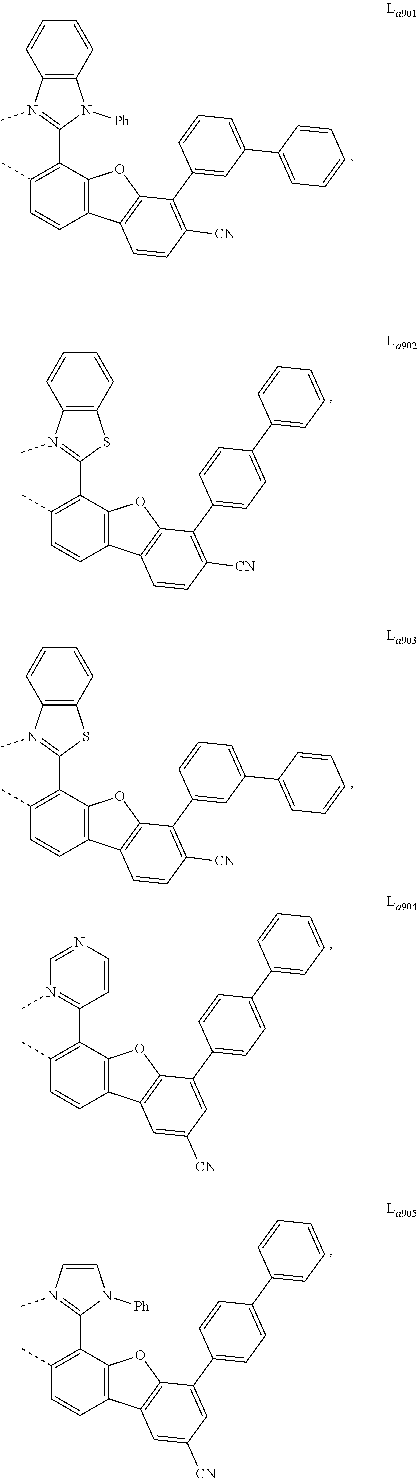

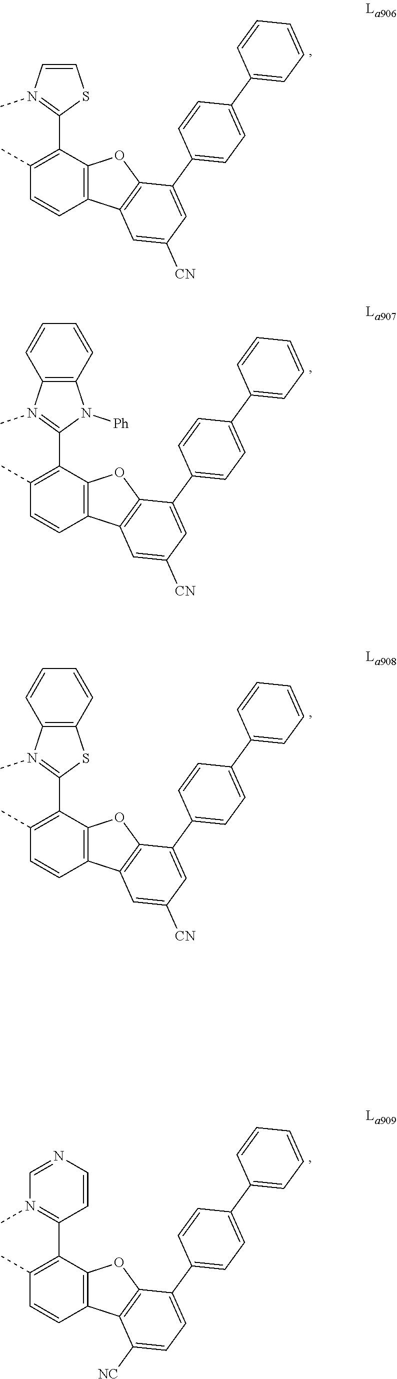

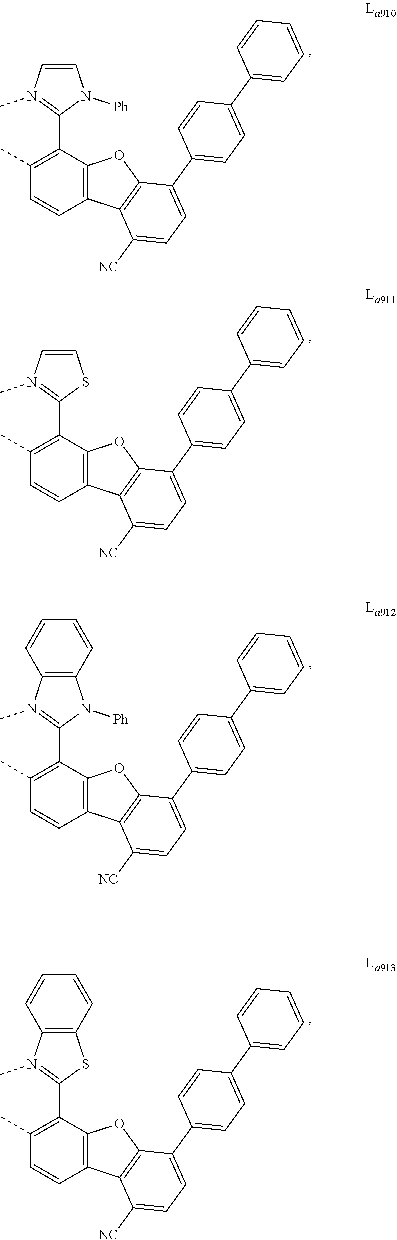

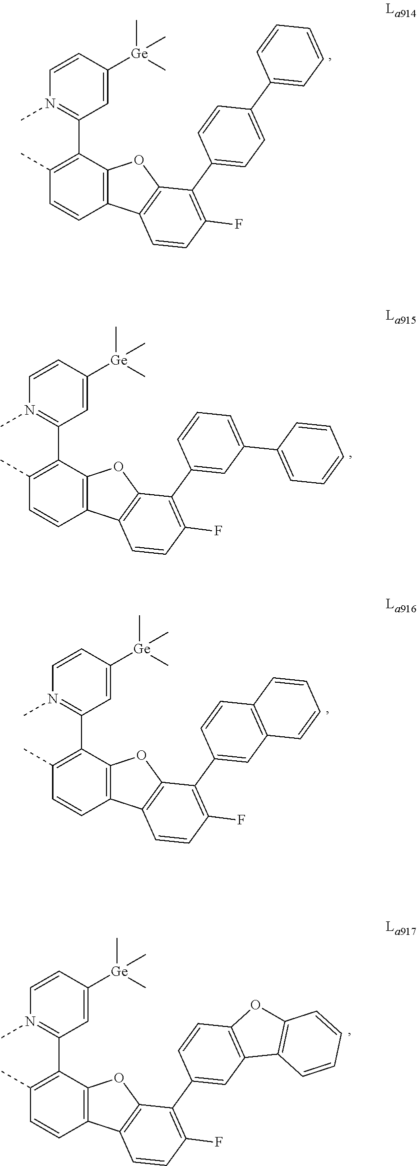

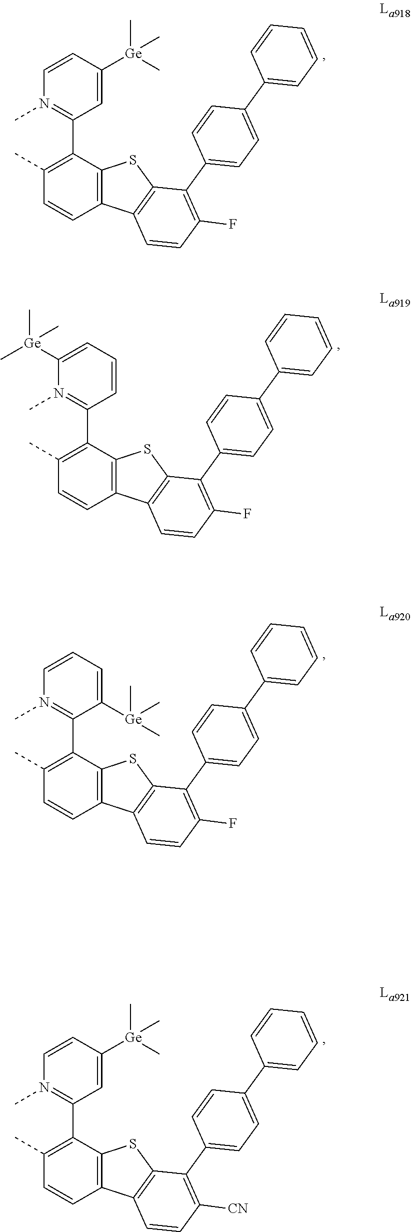

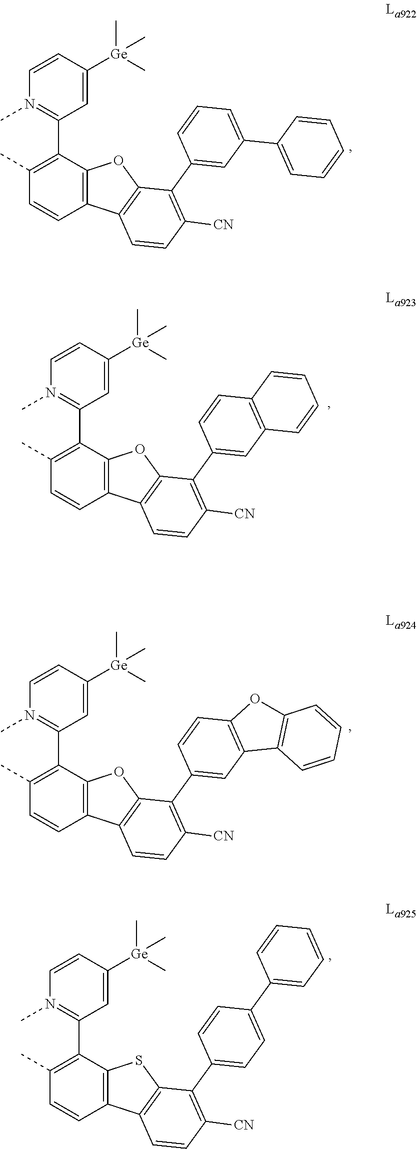

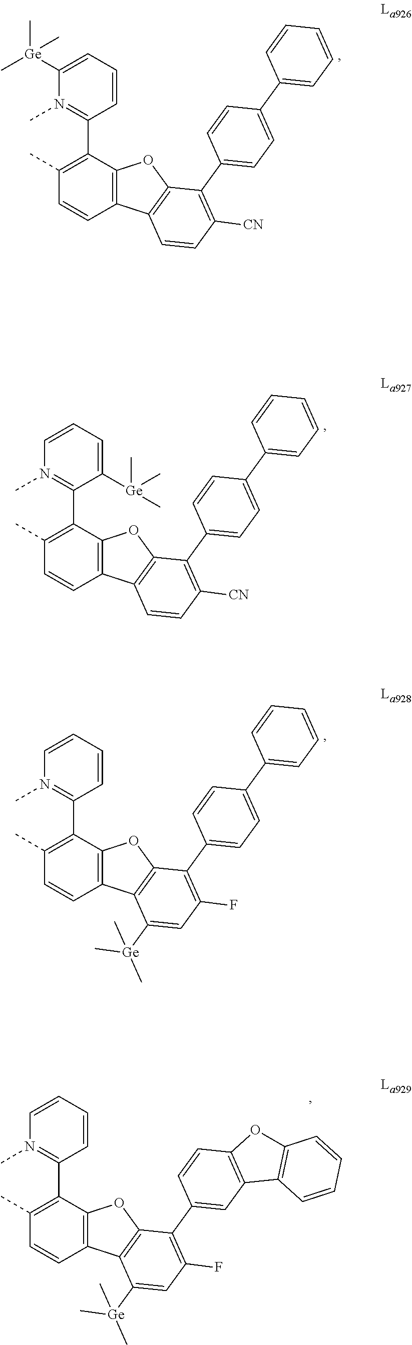

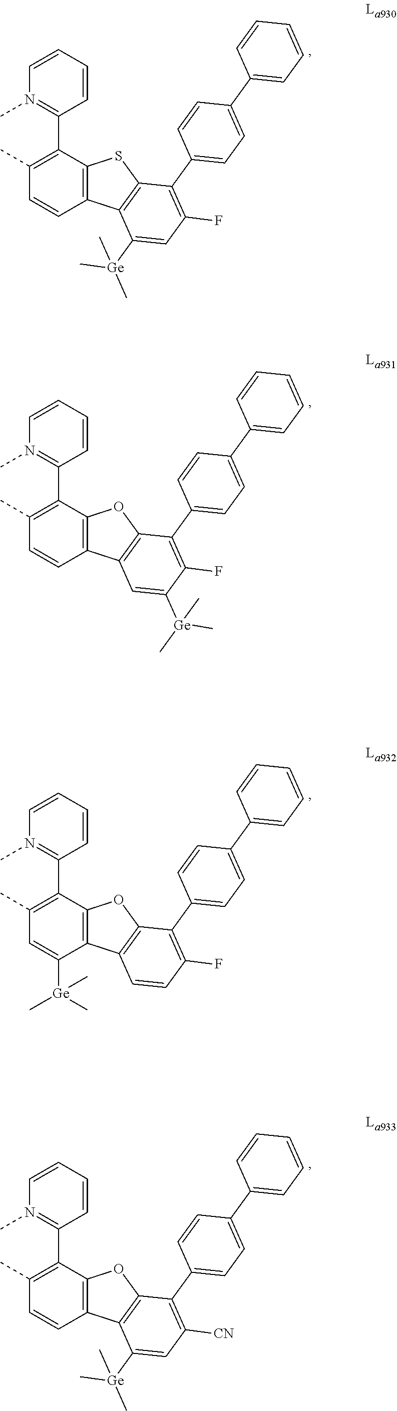

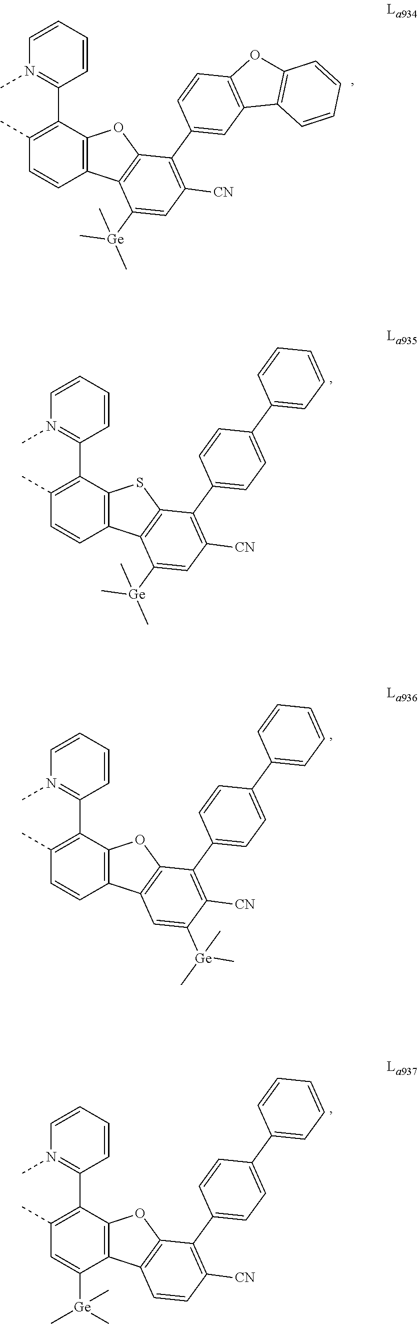

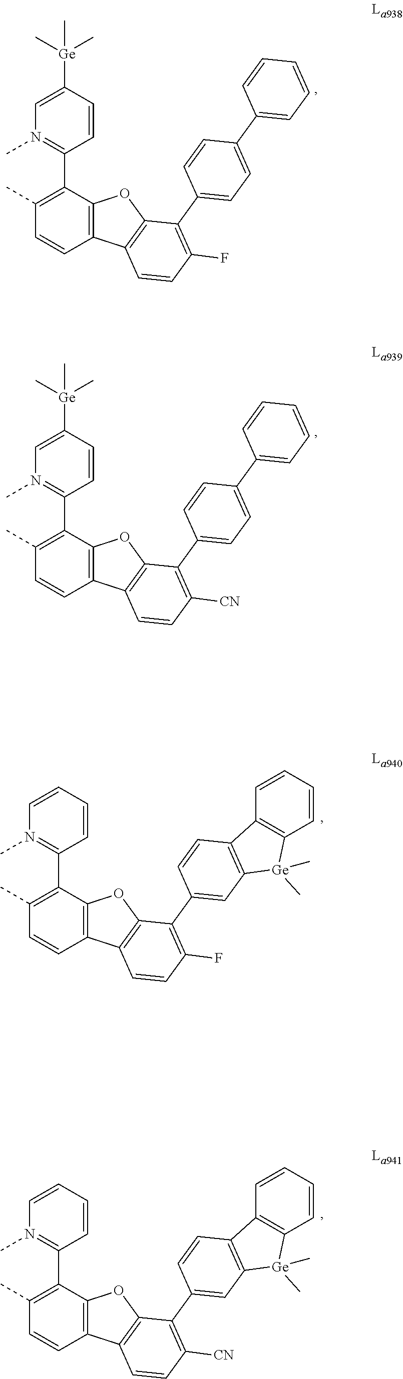

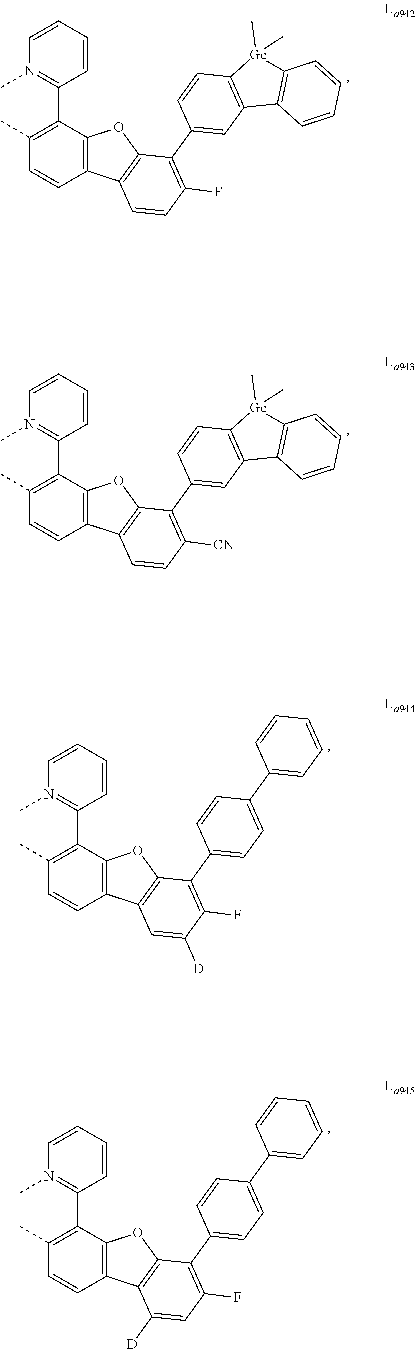

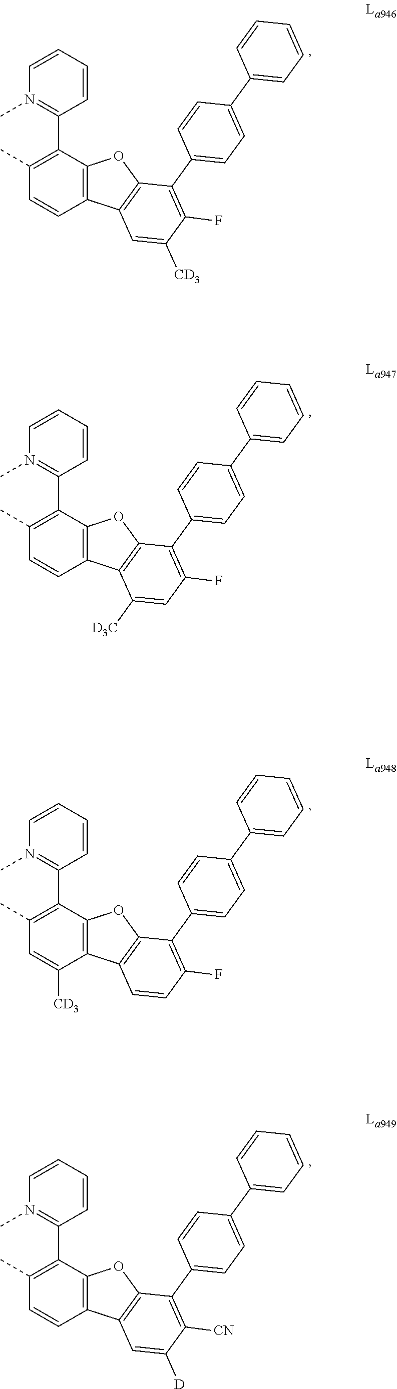

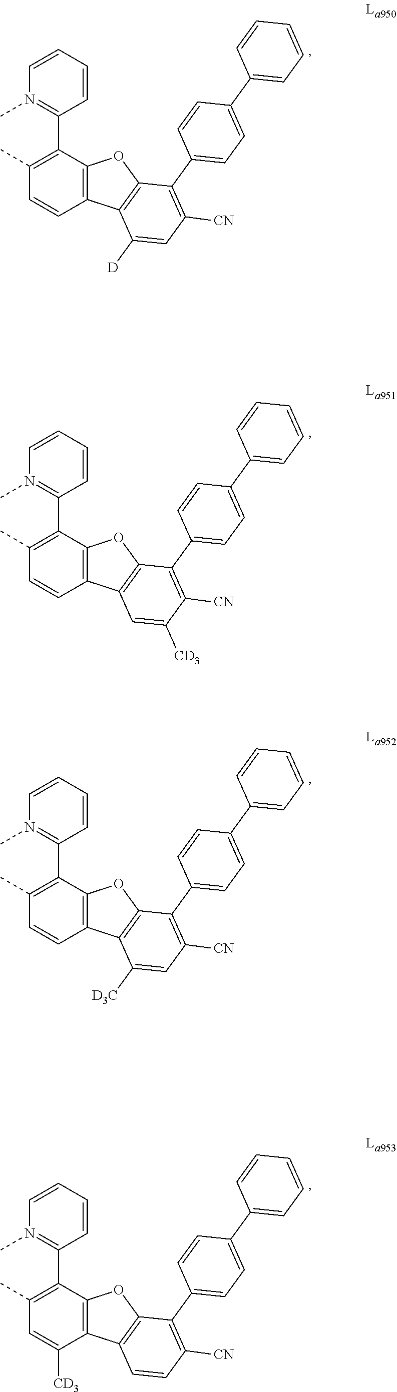

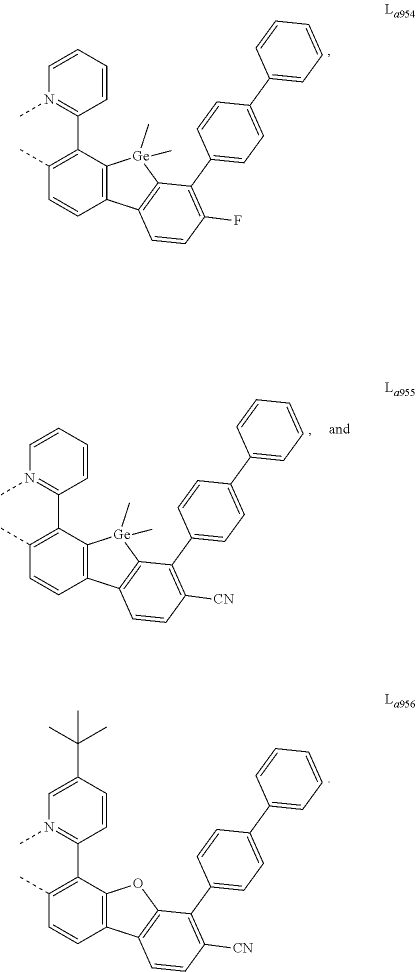

17. The metal complex according to claim 16, wherein L_{b} is, at each occurrence identically or differently, selected from the group consisting of:

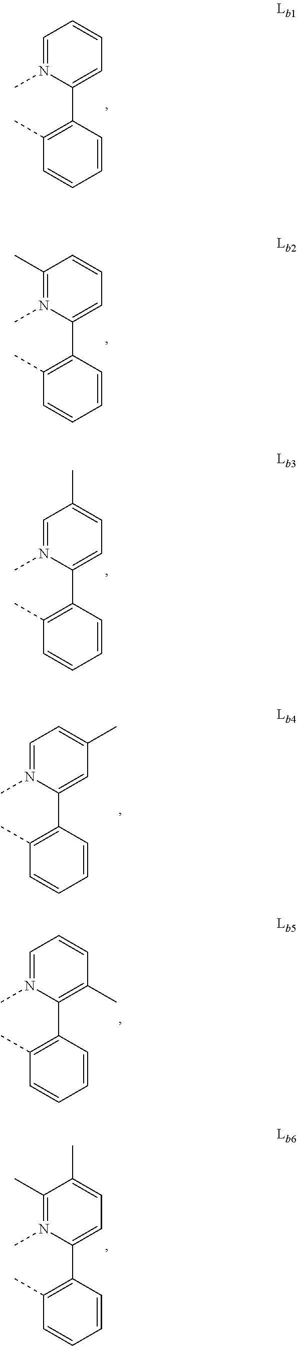

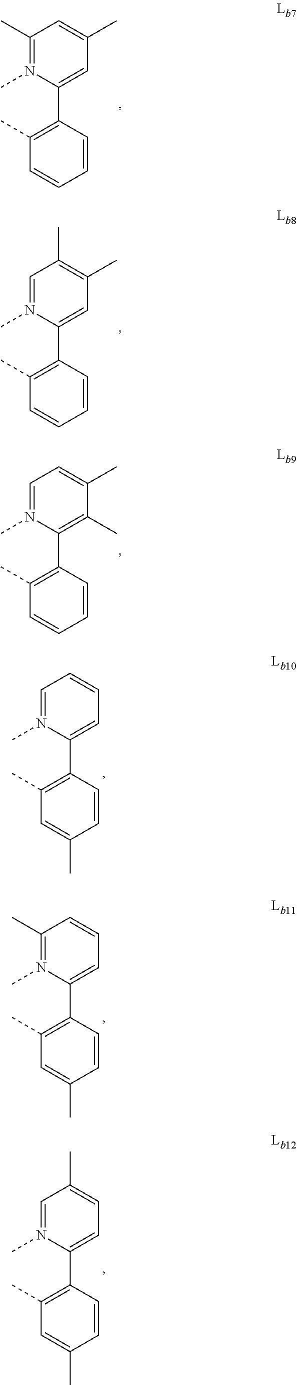

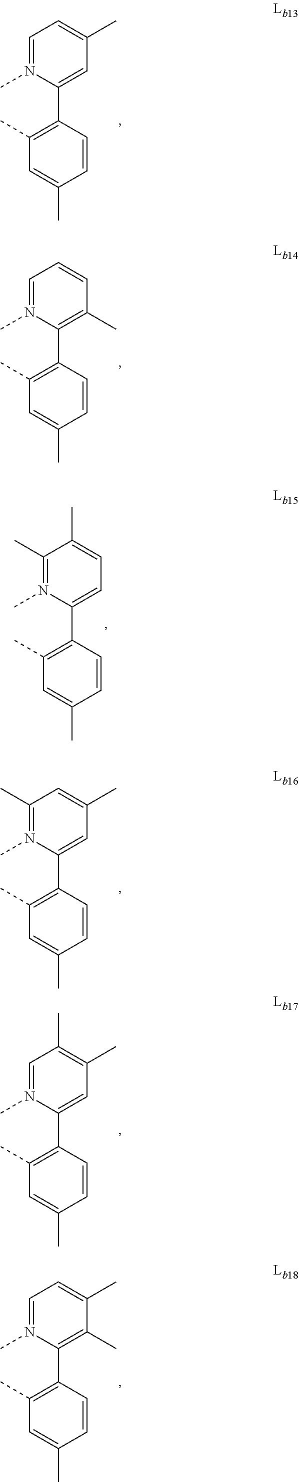

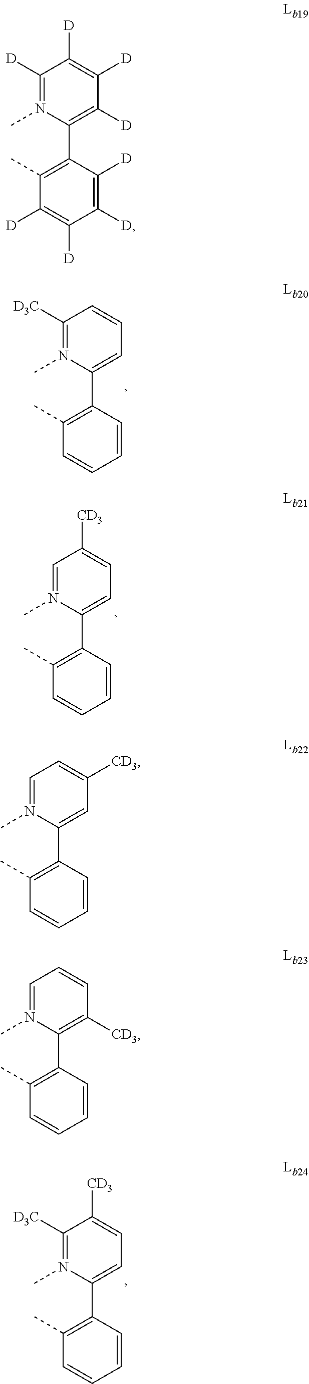

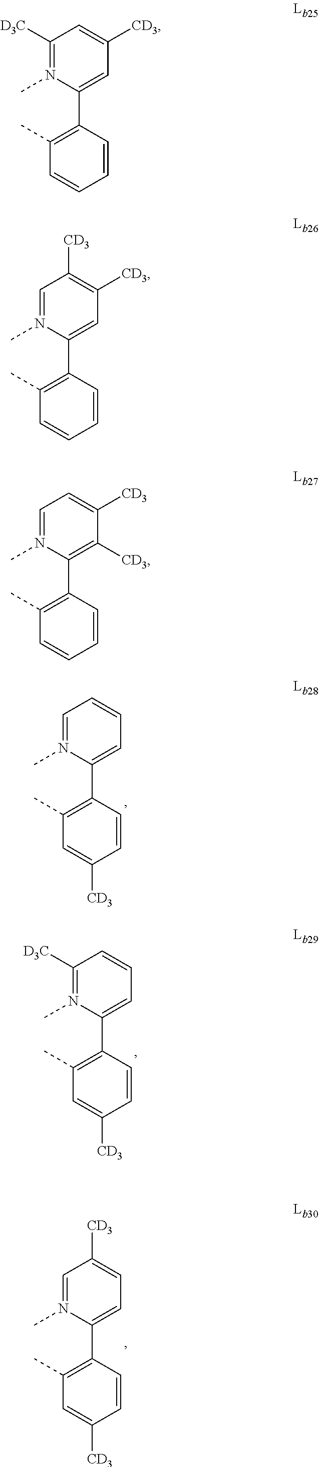

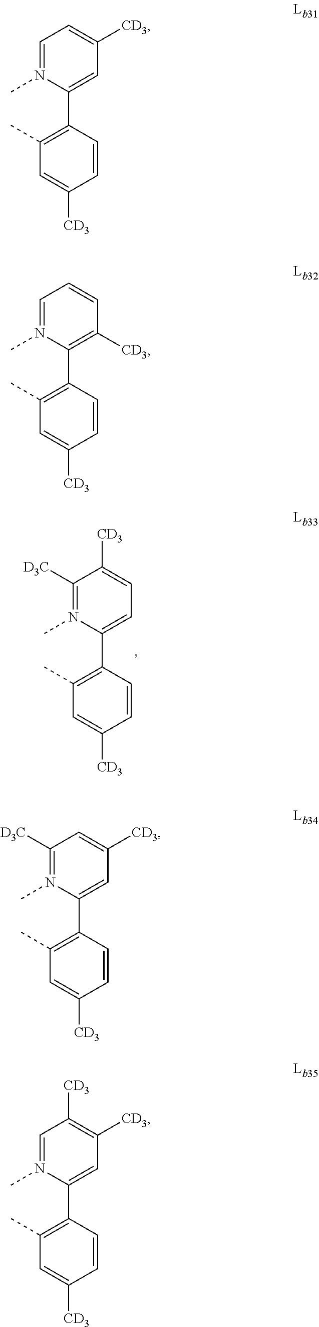

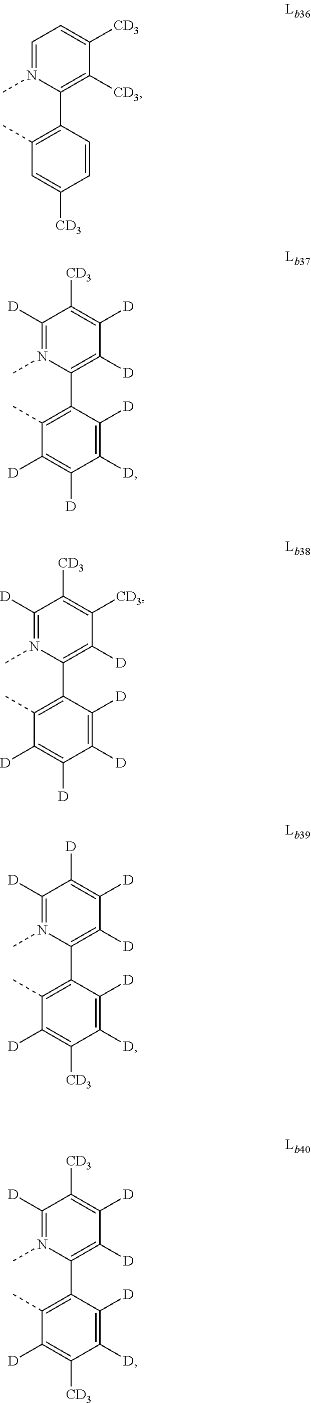

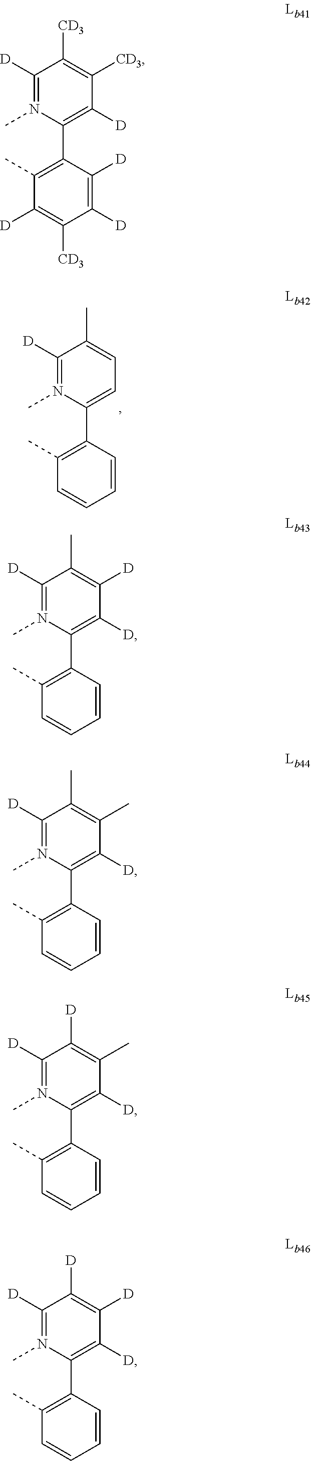

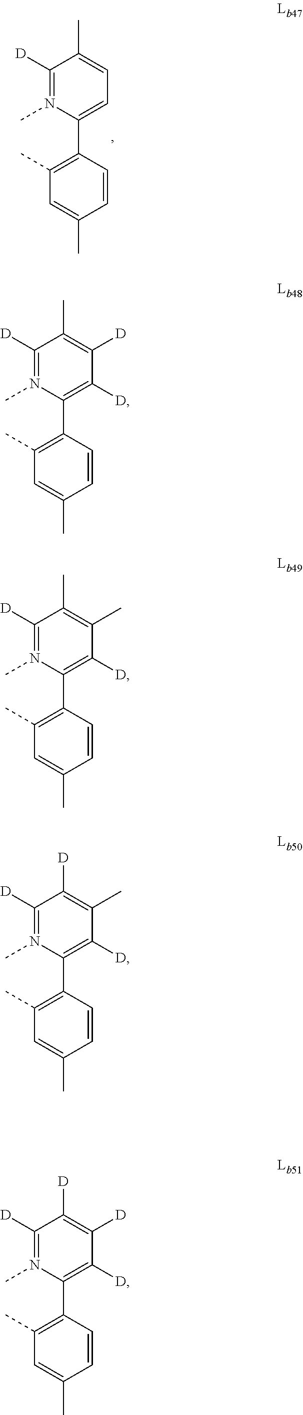

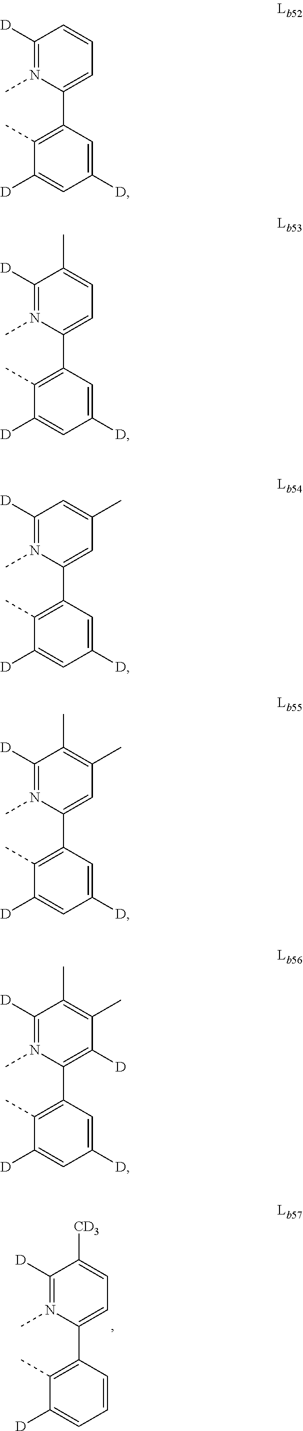

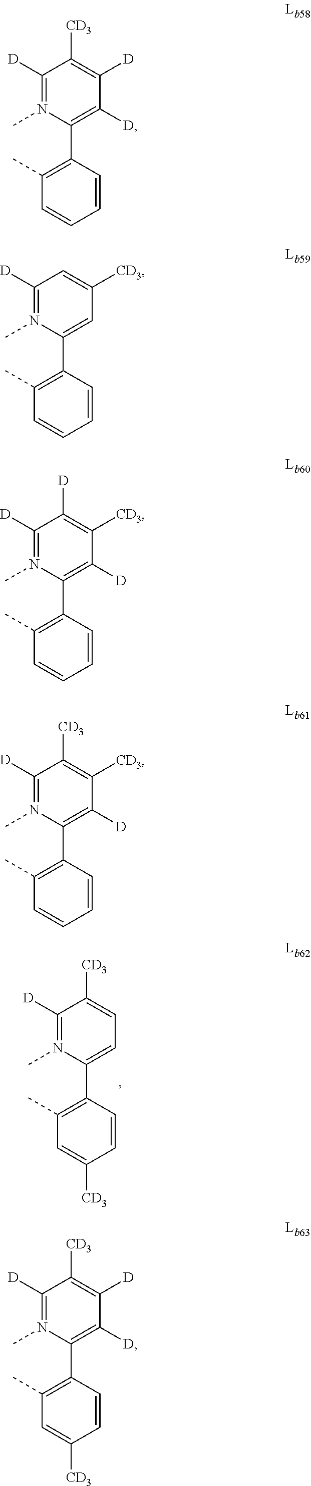

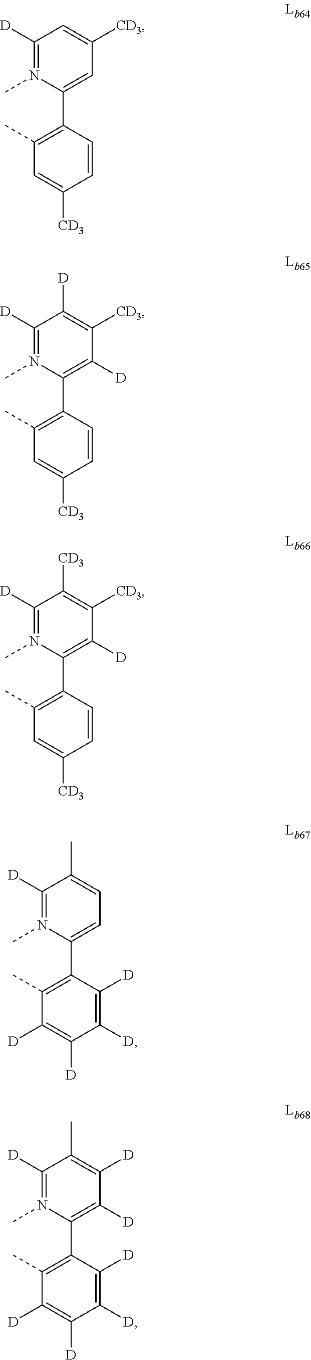

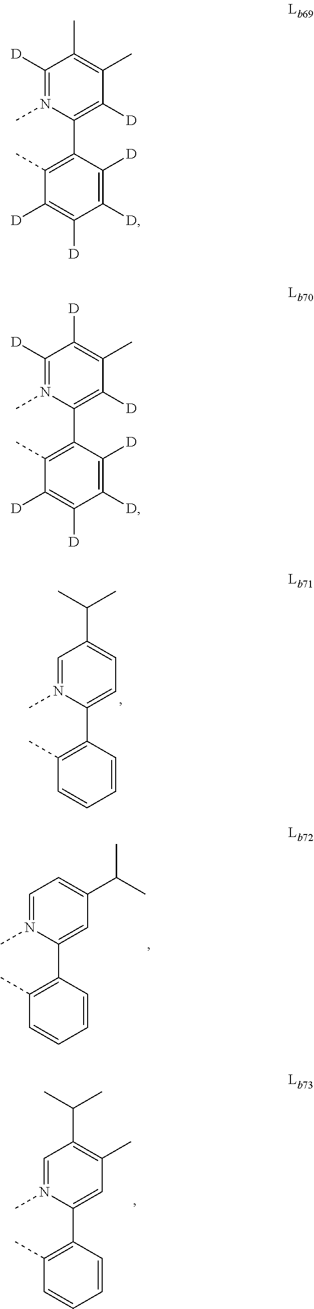

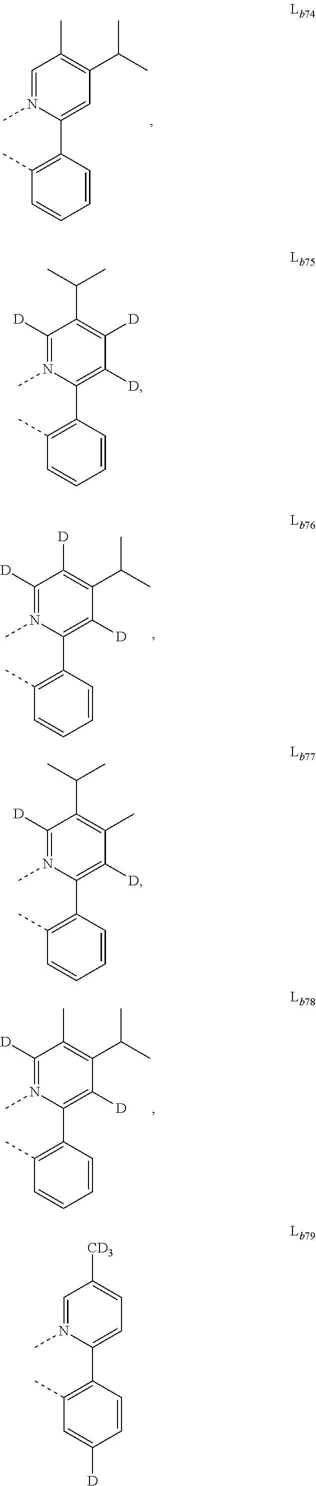

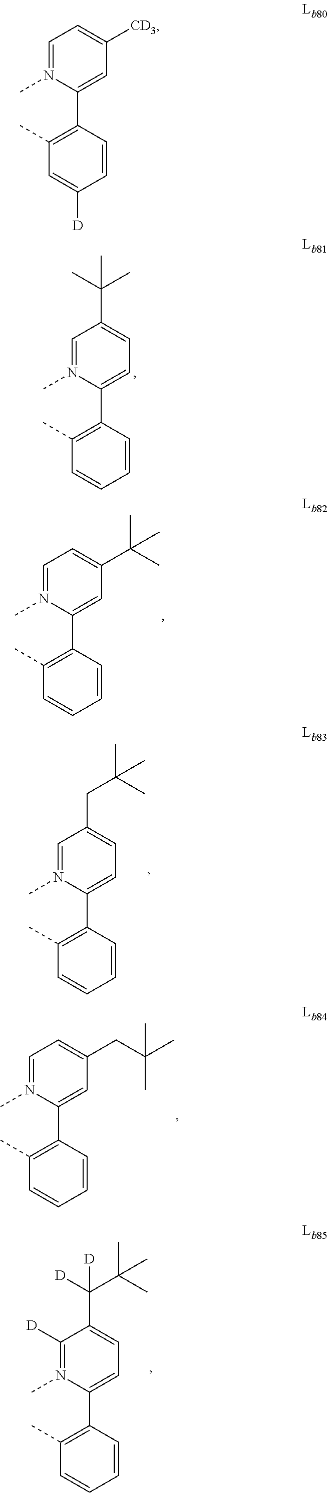

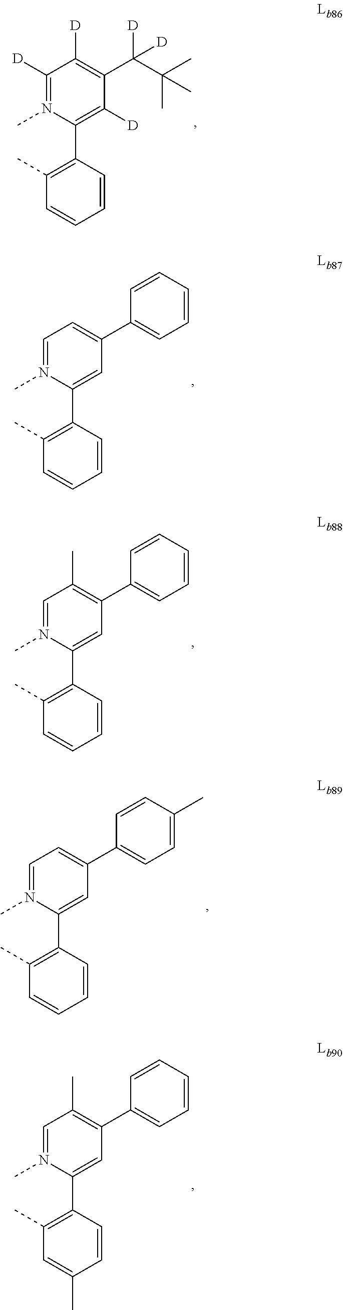

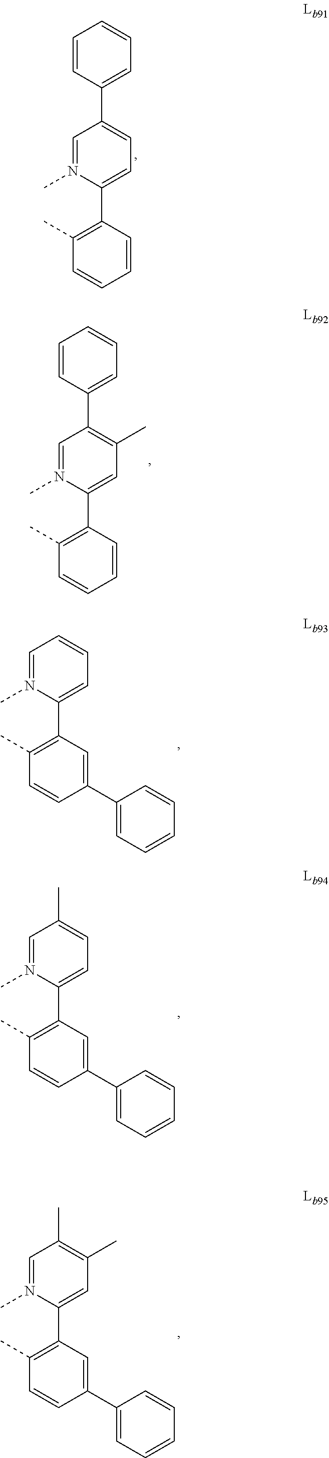

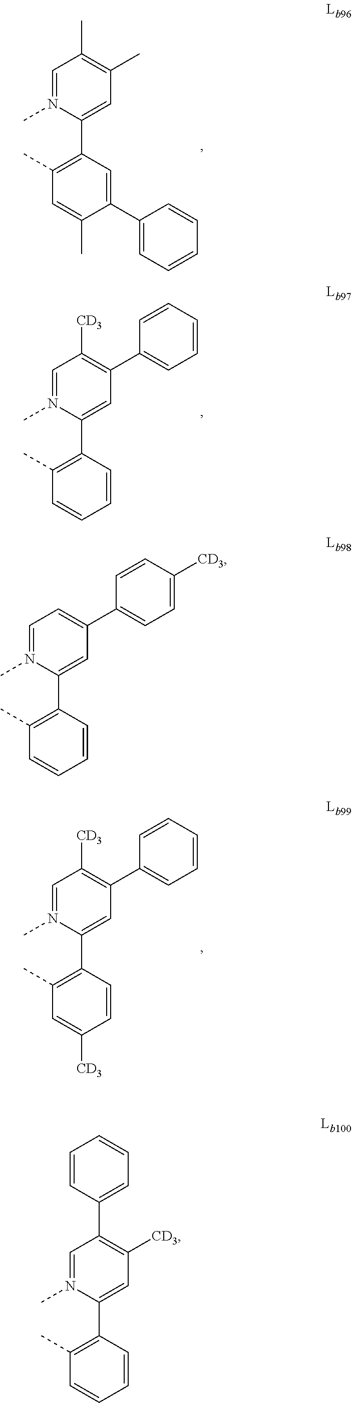

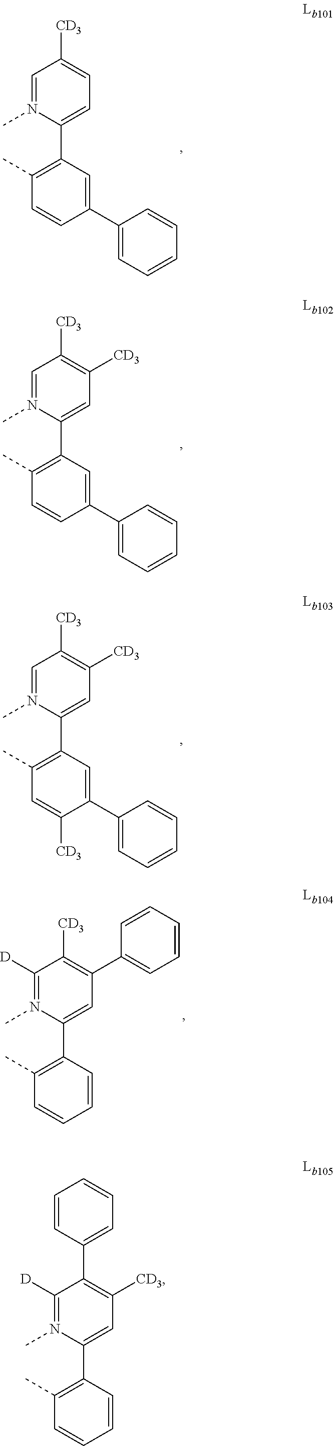

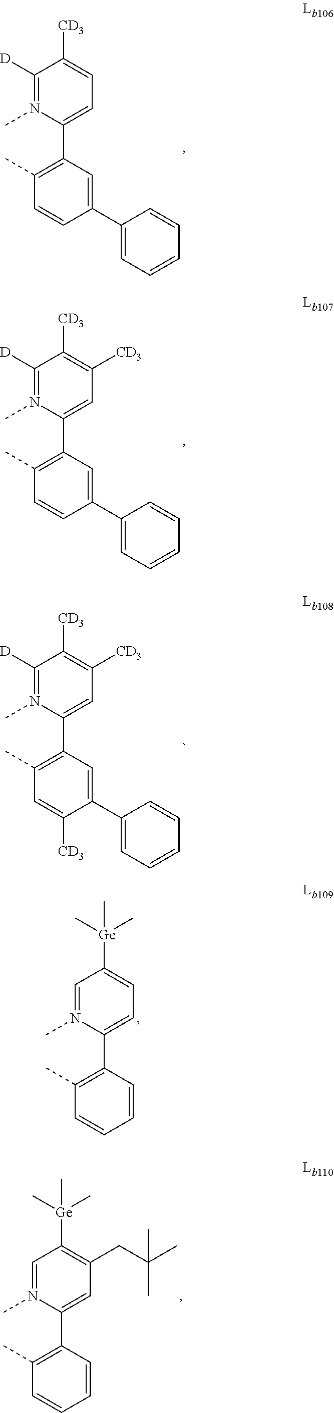

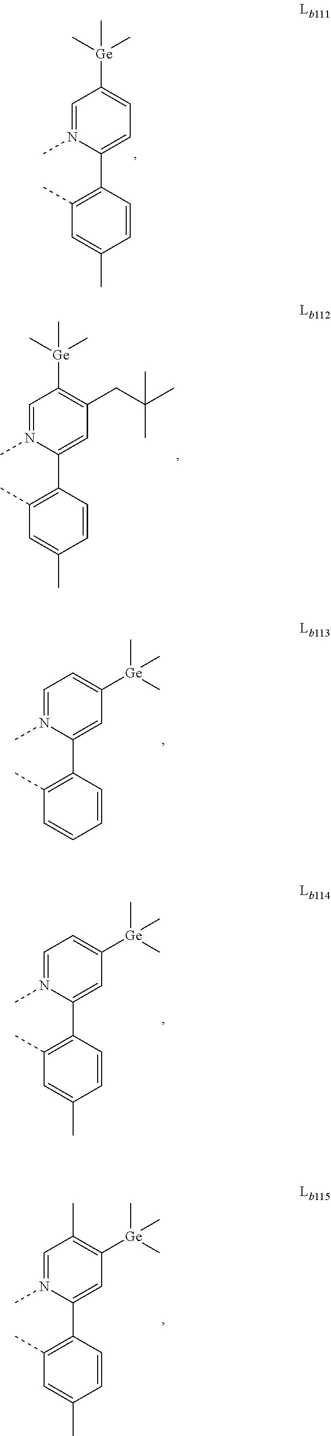

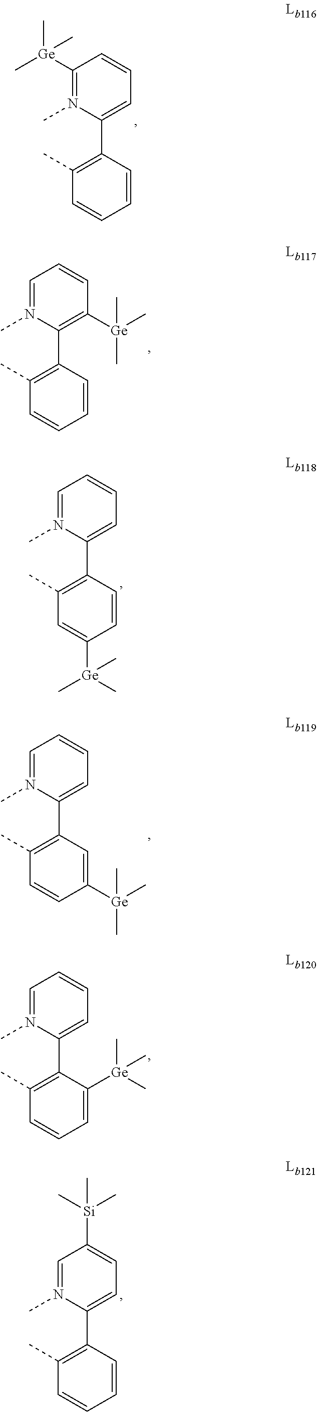

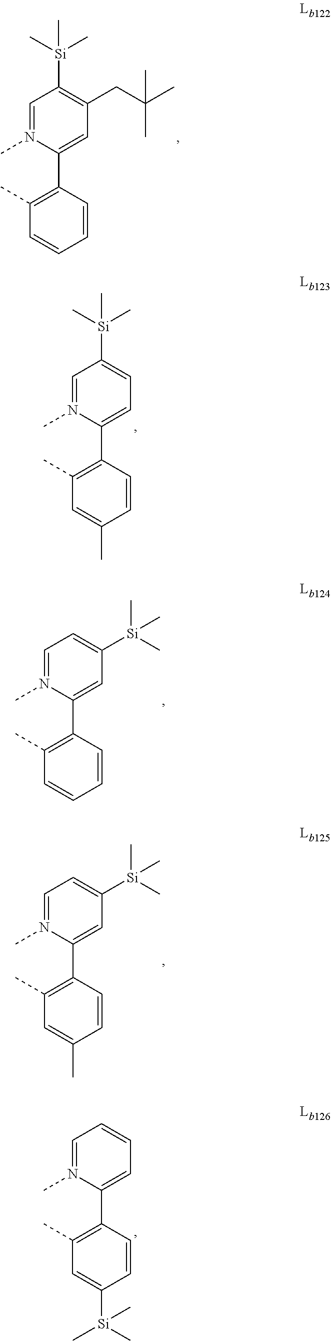

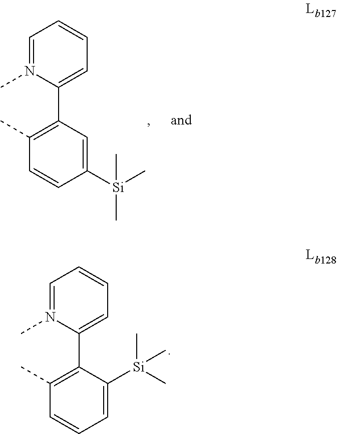

18. The metal complex according to claim 17, wherein L_{c} is, at each occurrence identically or differently, selected from the group consisting of:

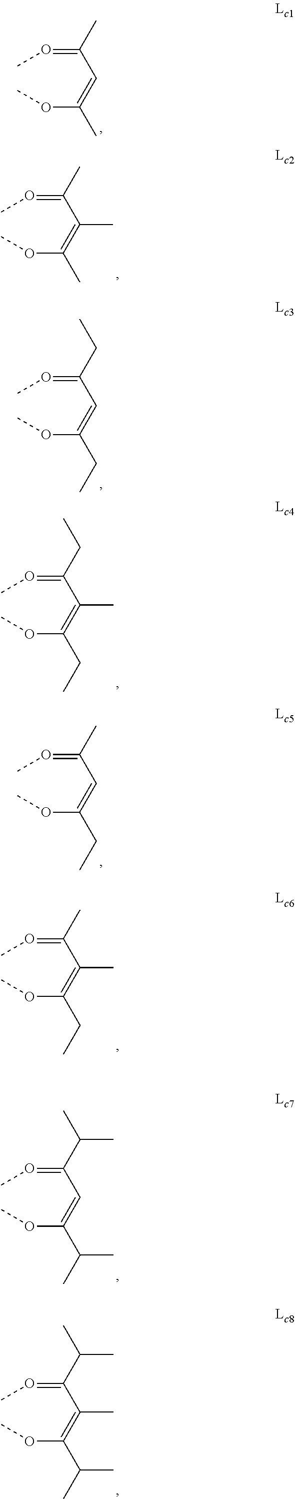

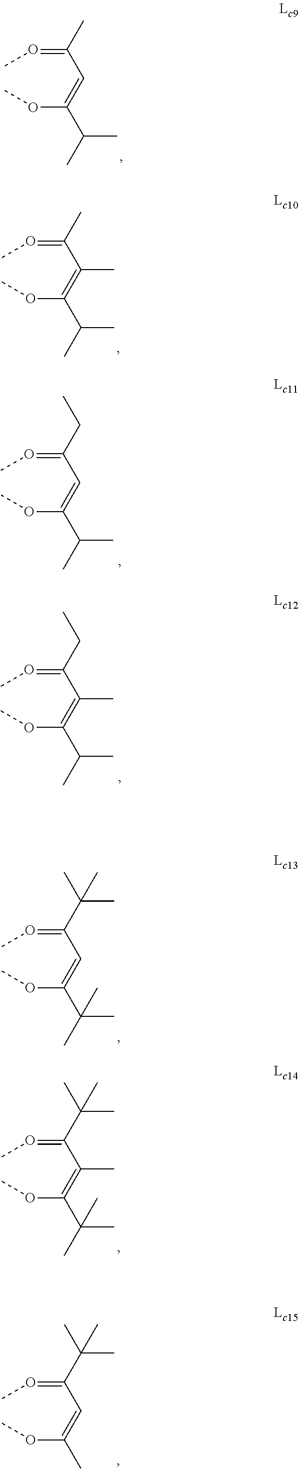

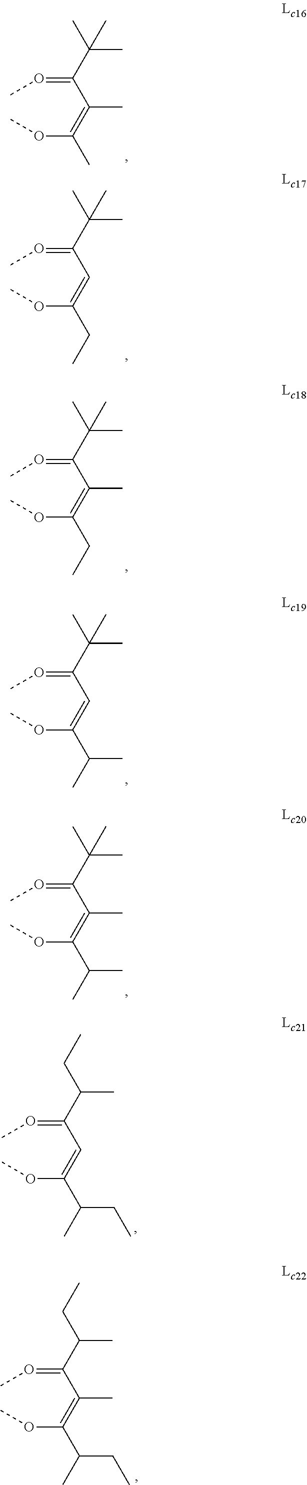

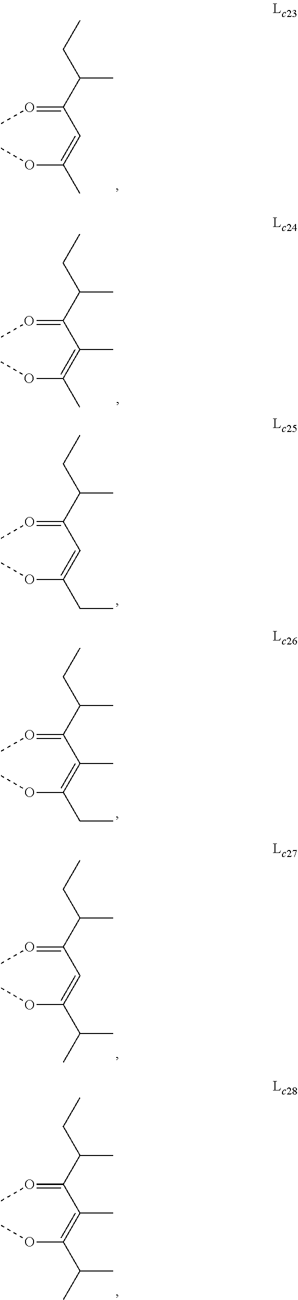

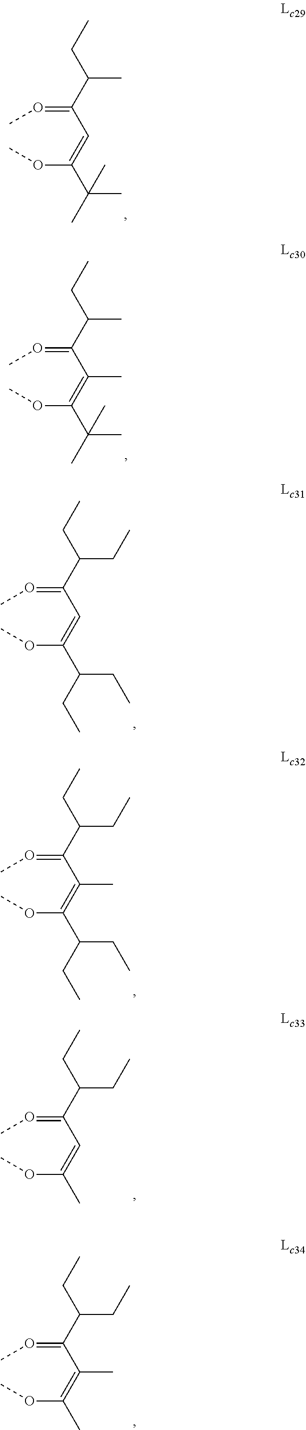

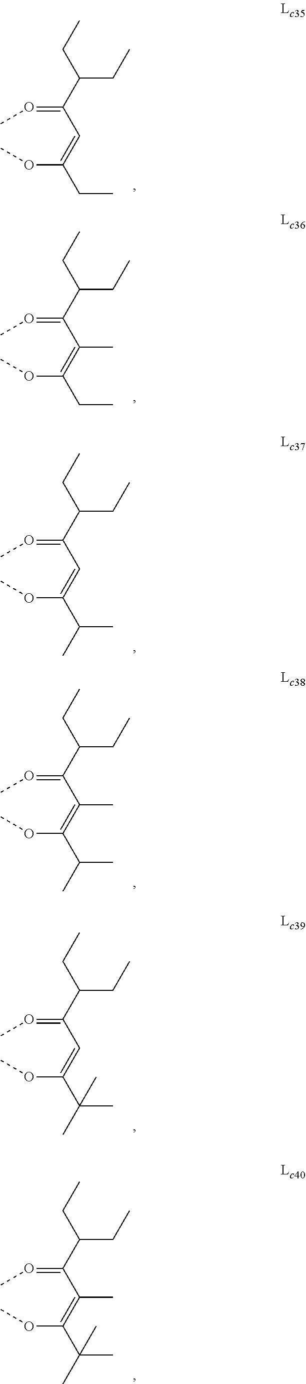

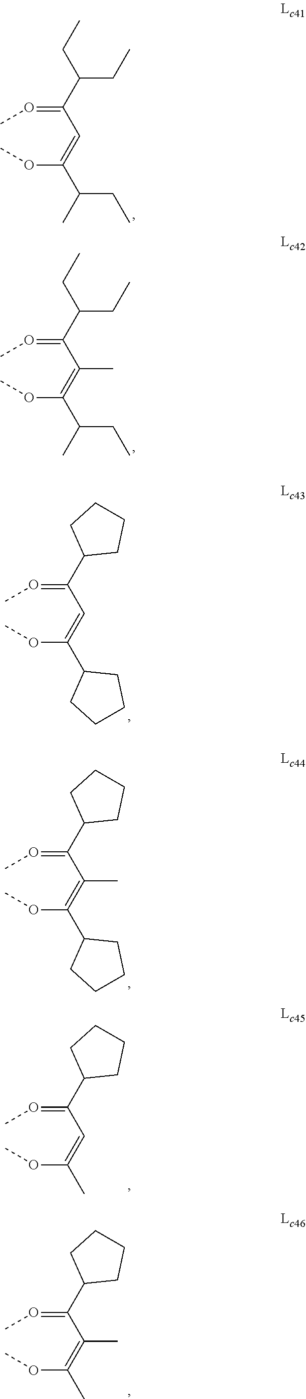

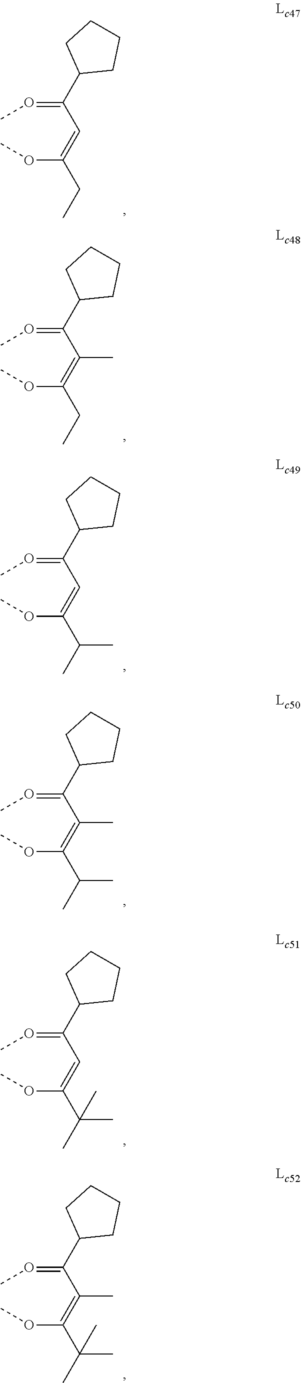

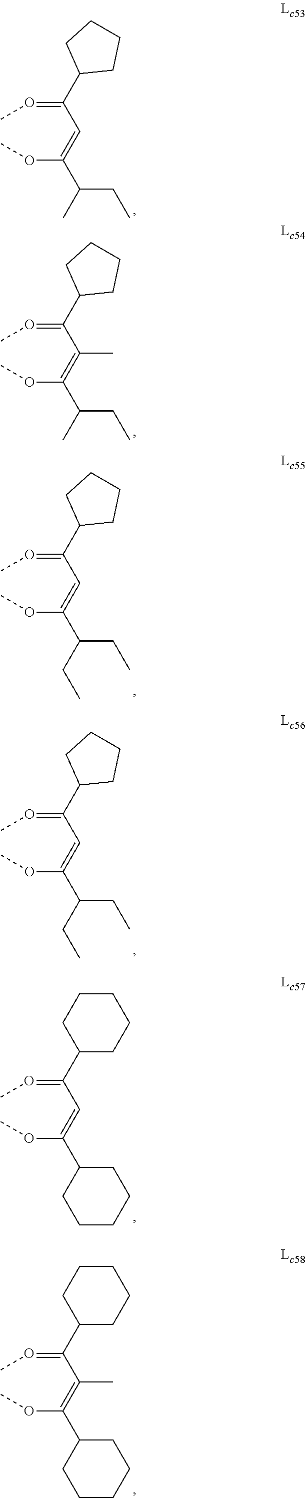

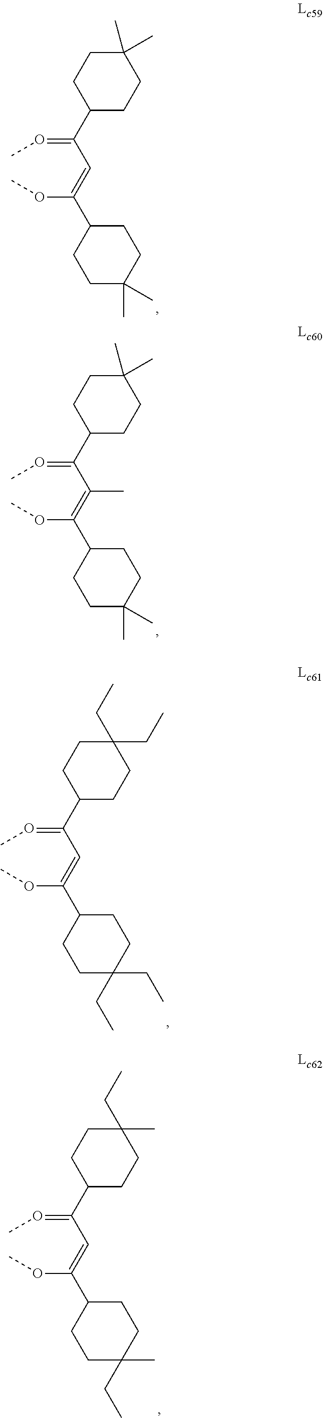

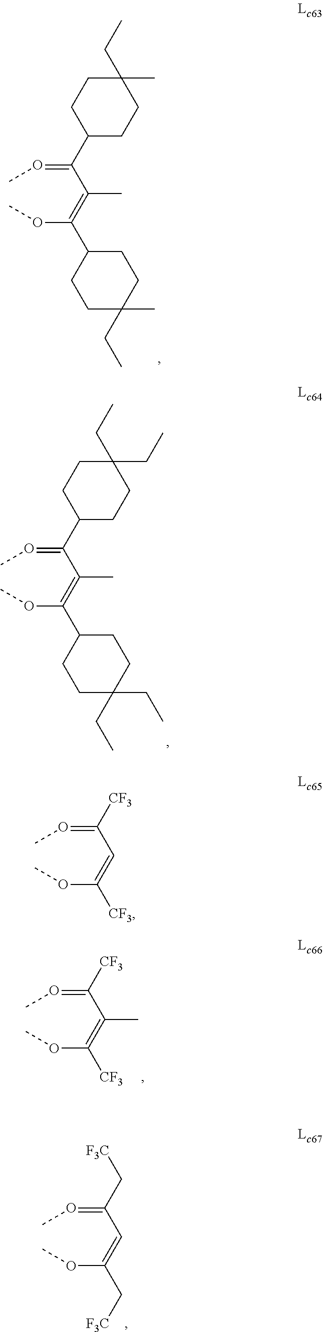

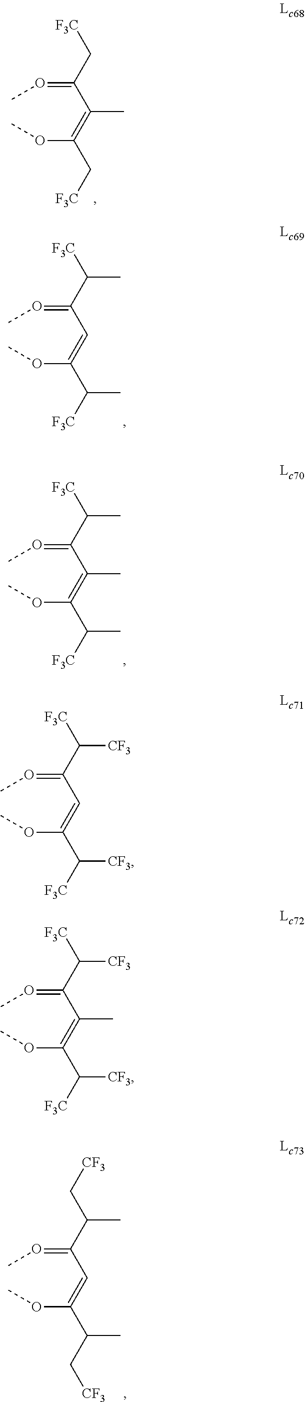

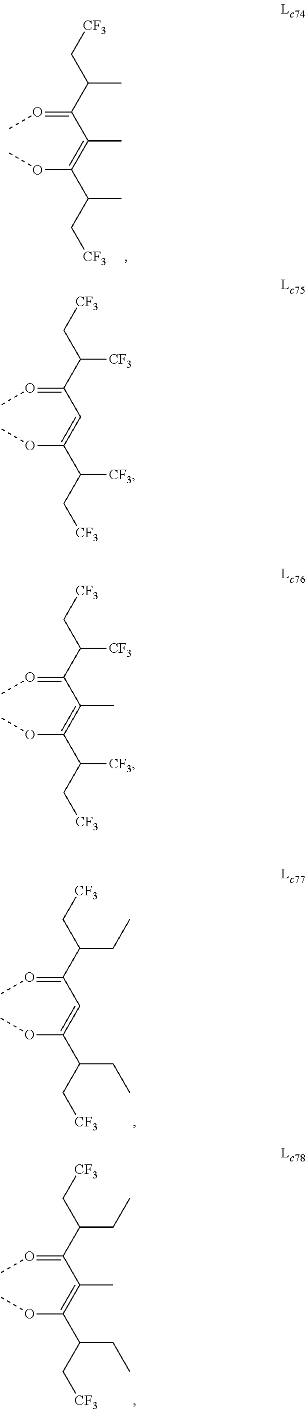

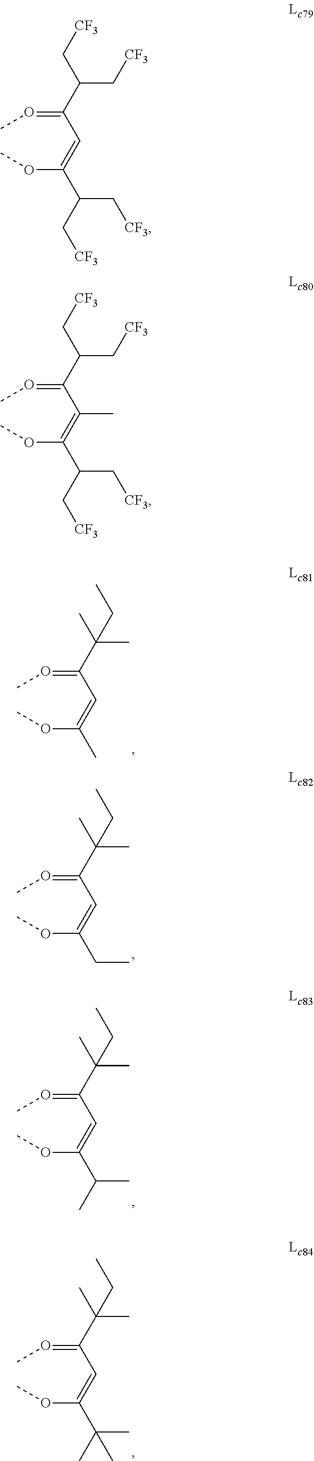

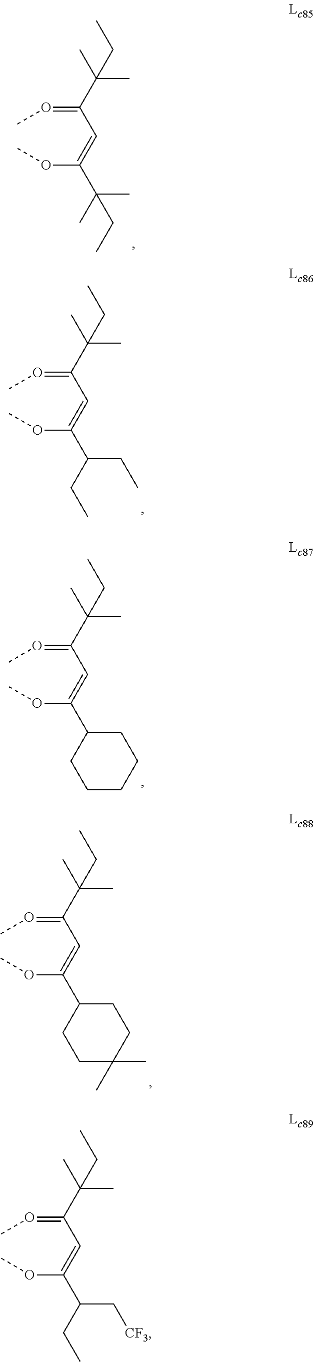

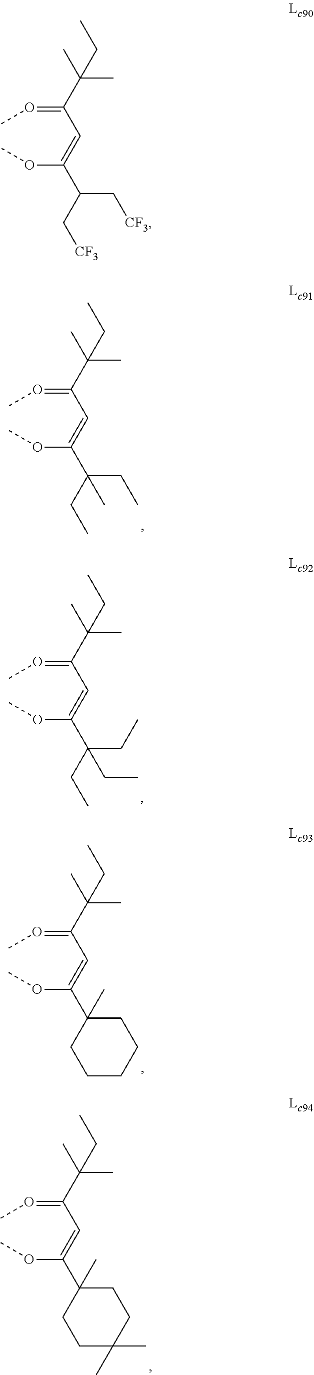

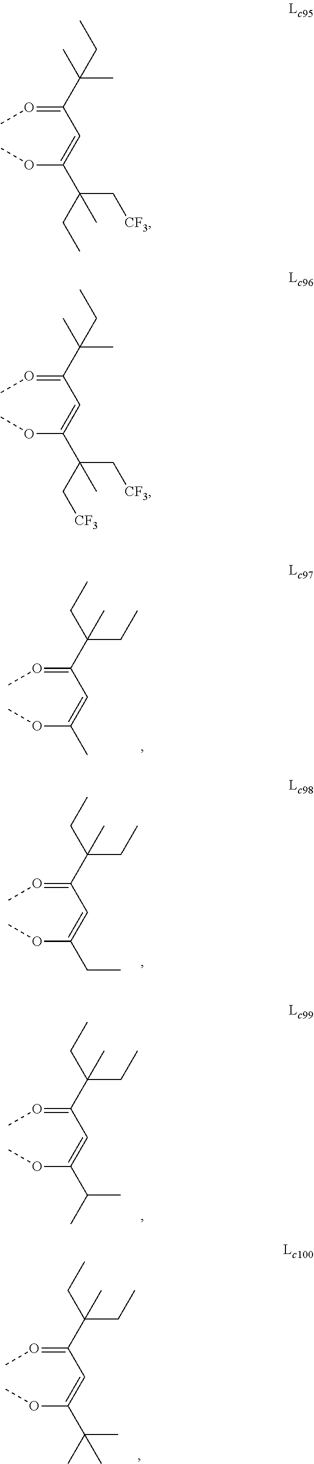

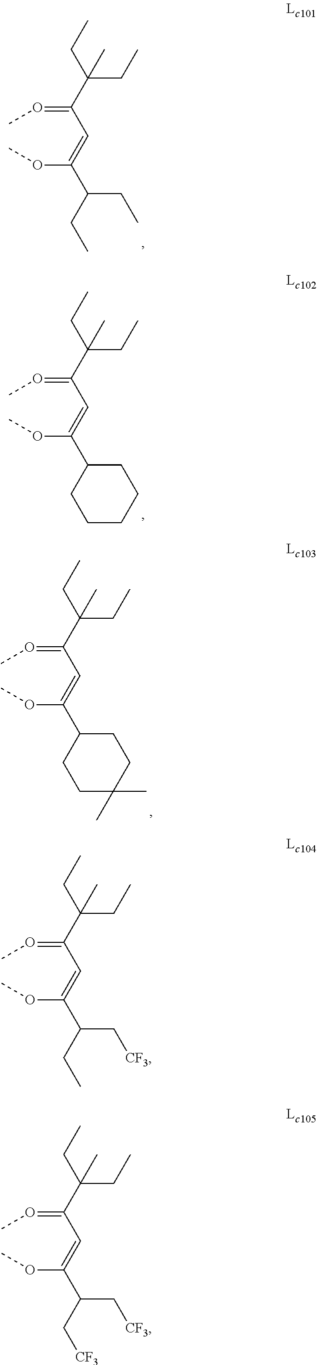

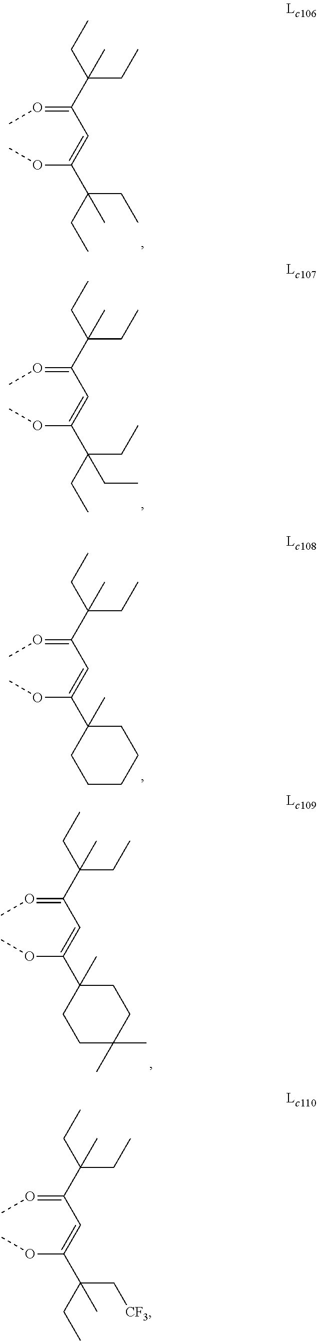

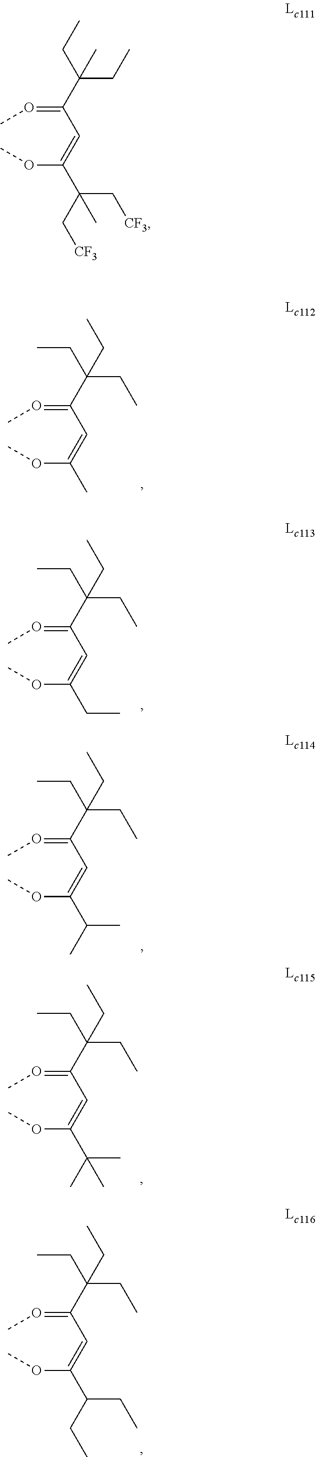

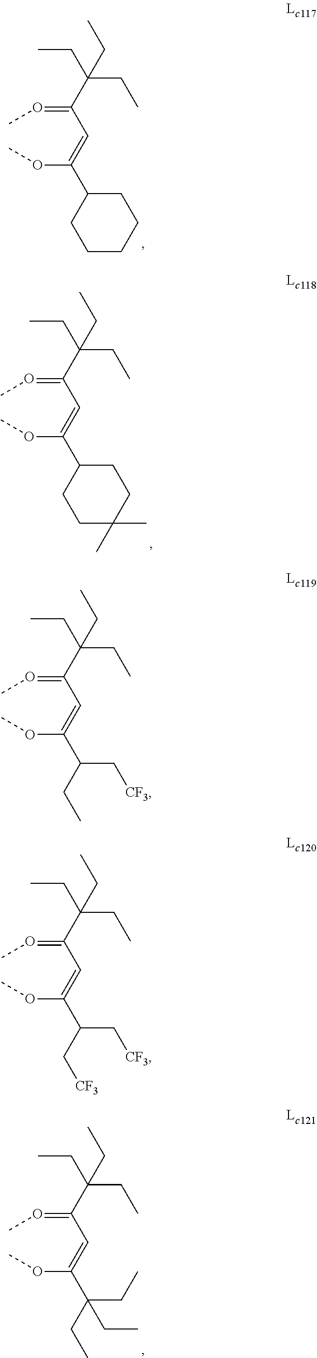

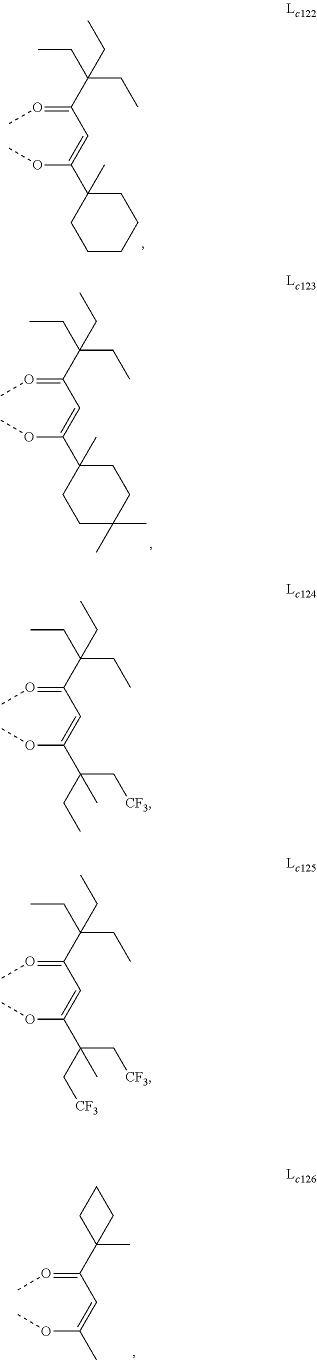

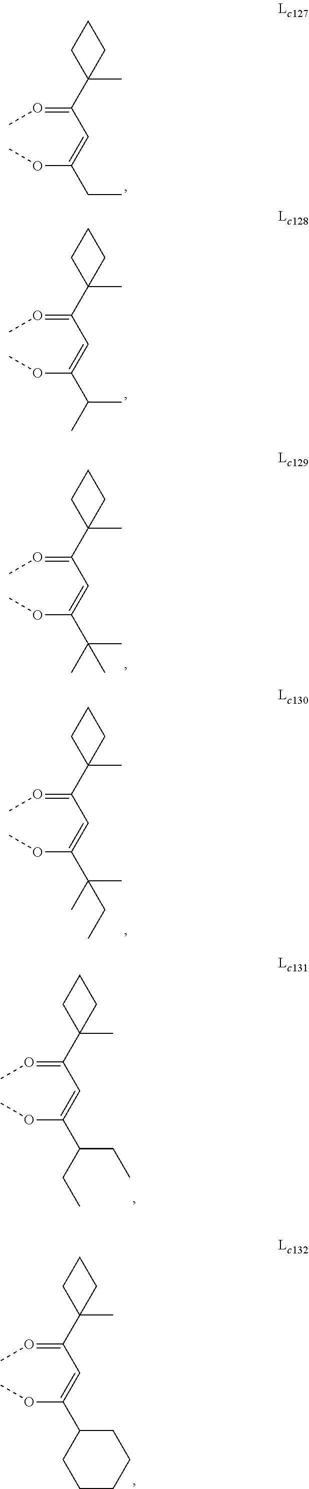

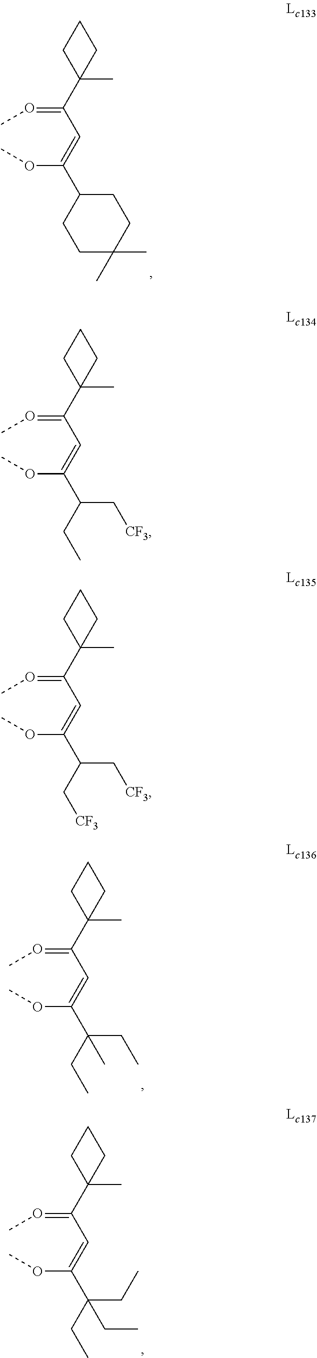

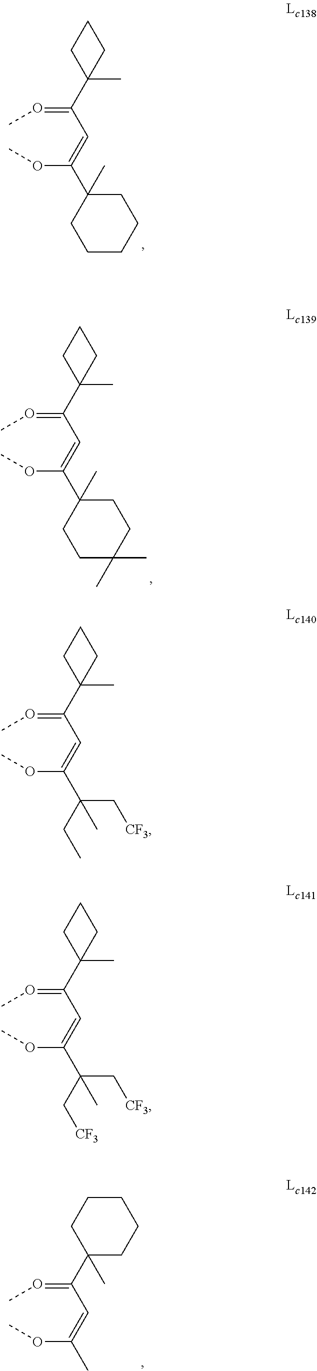

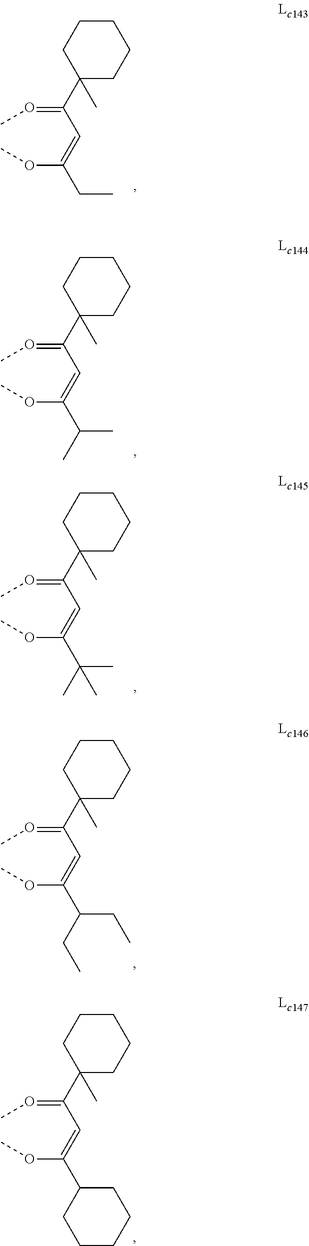

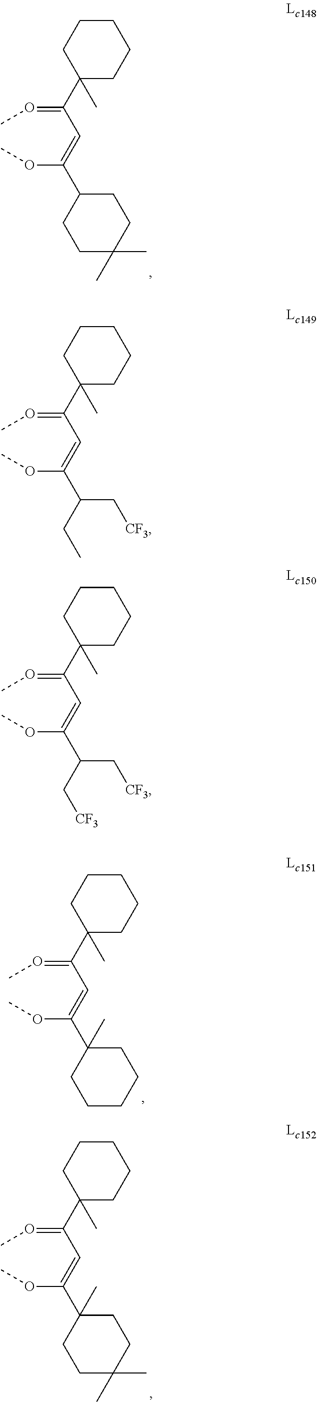

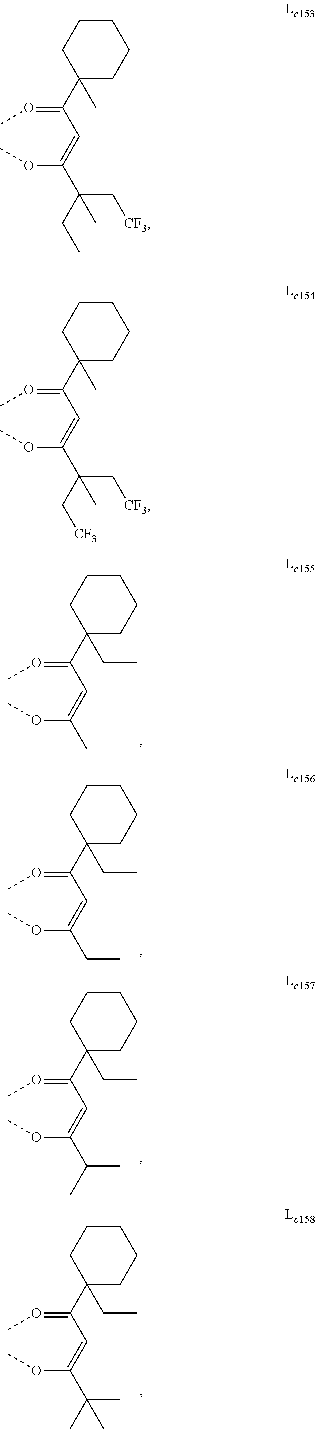

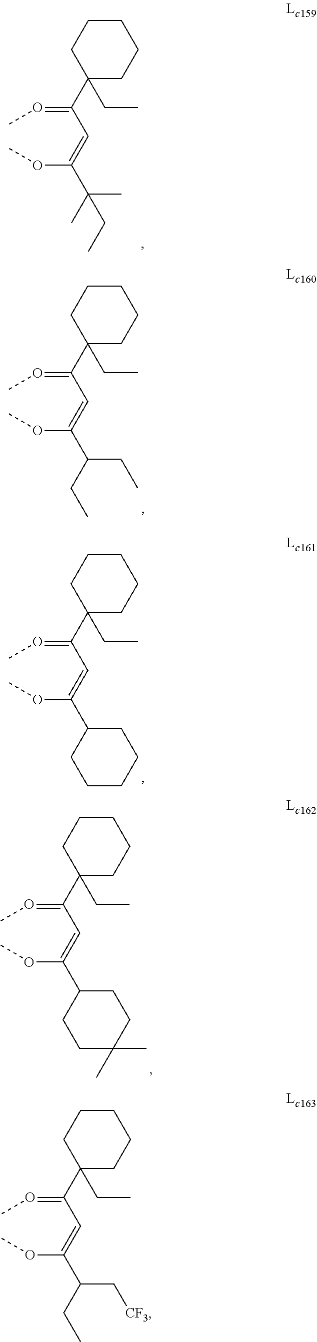

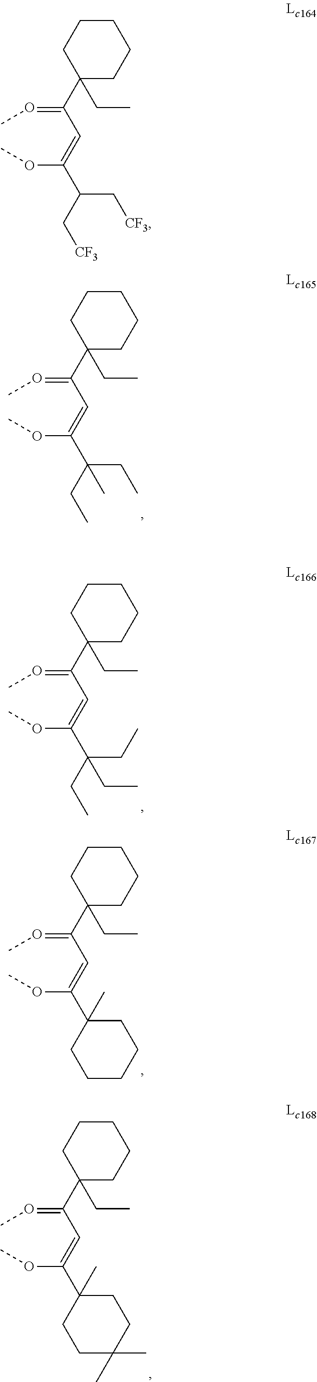

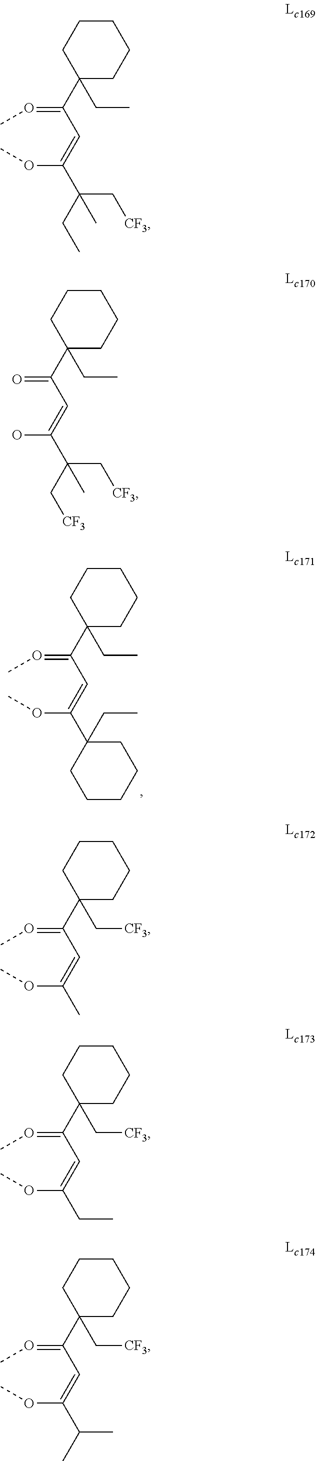

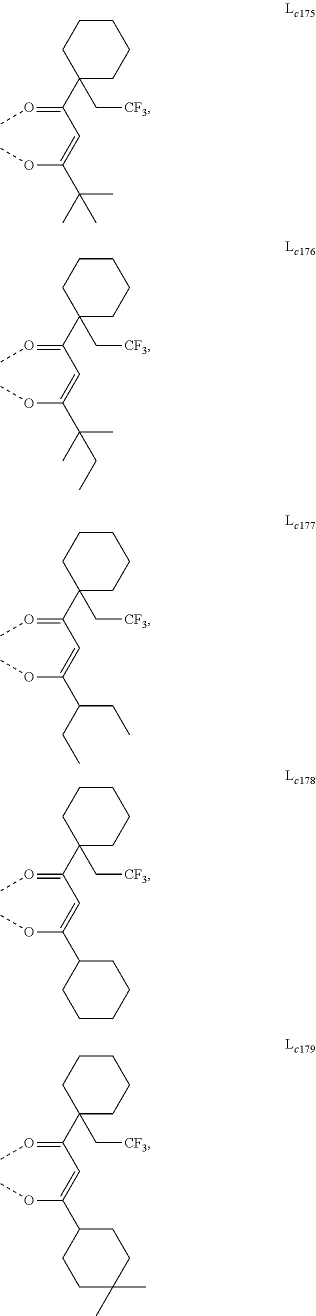

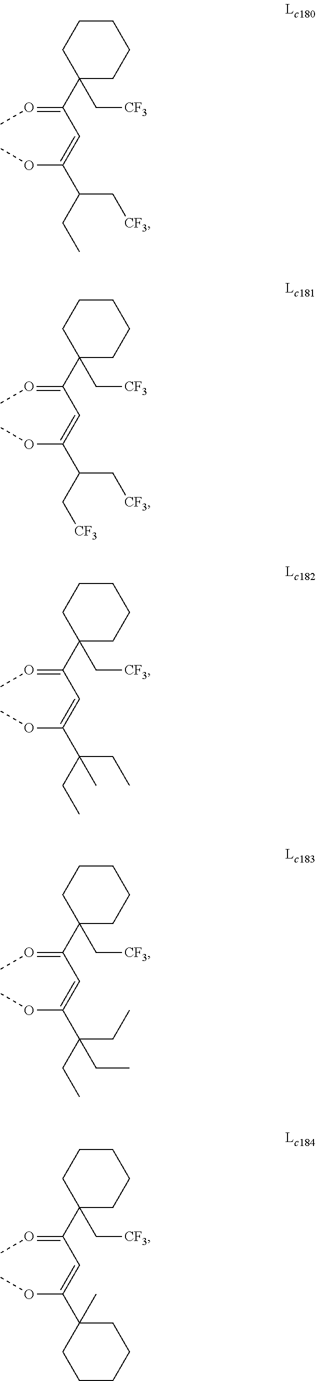

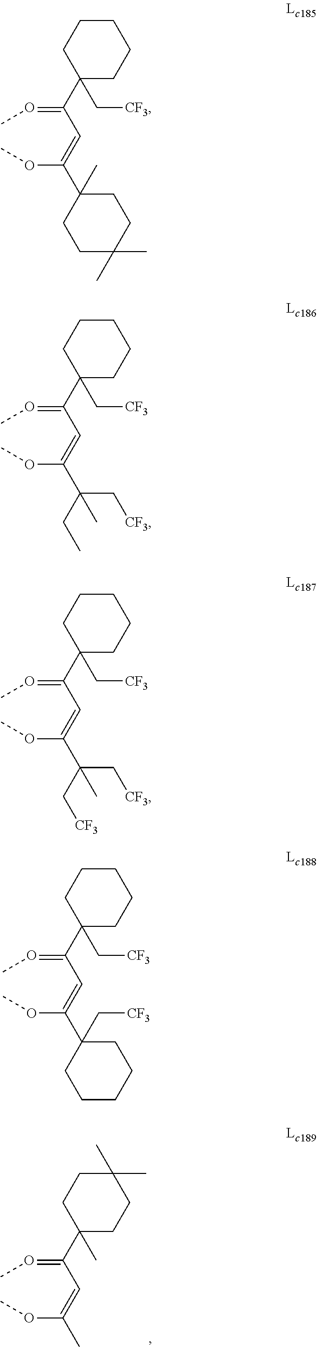

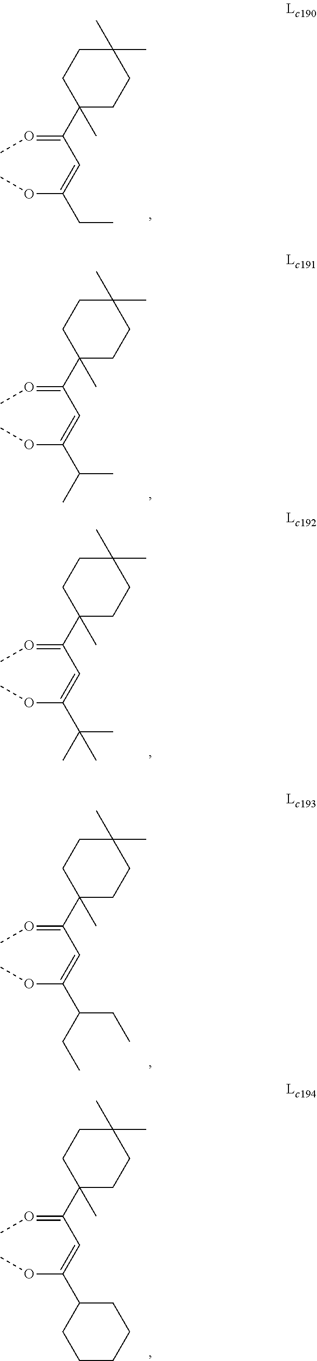

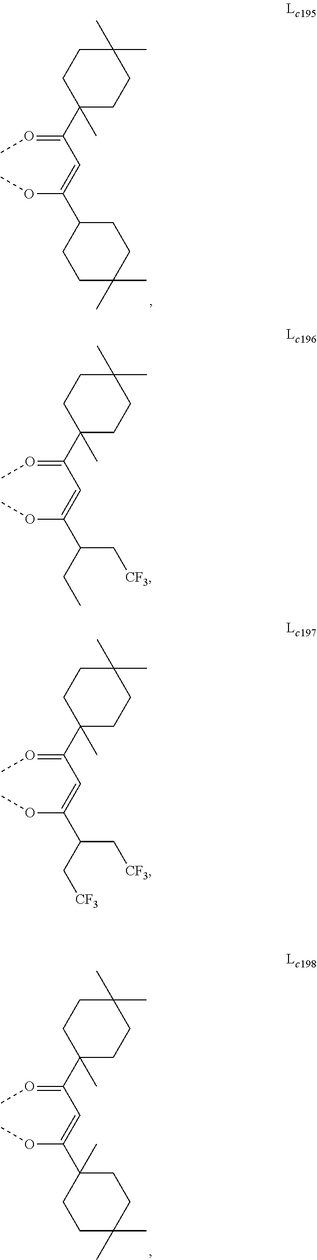

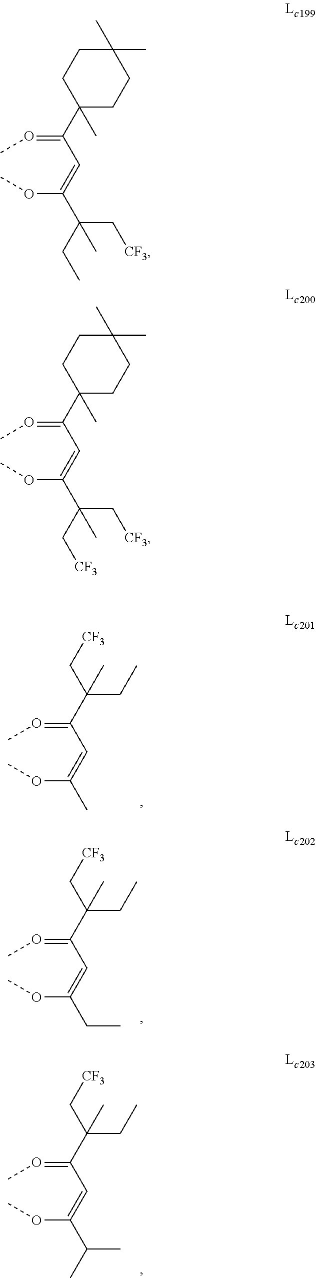

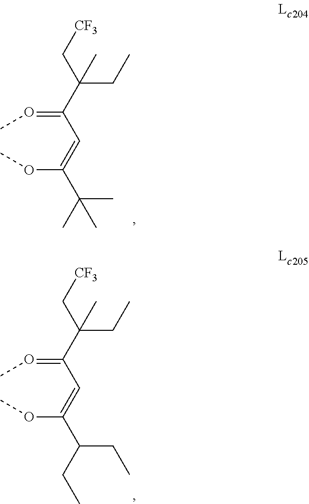

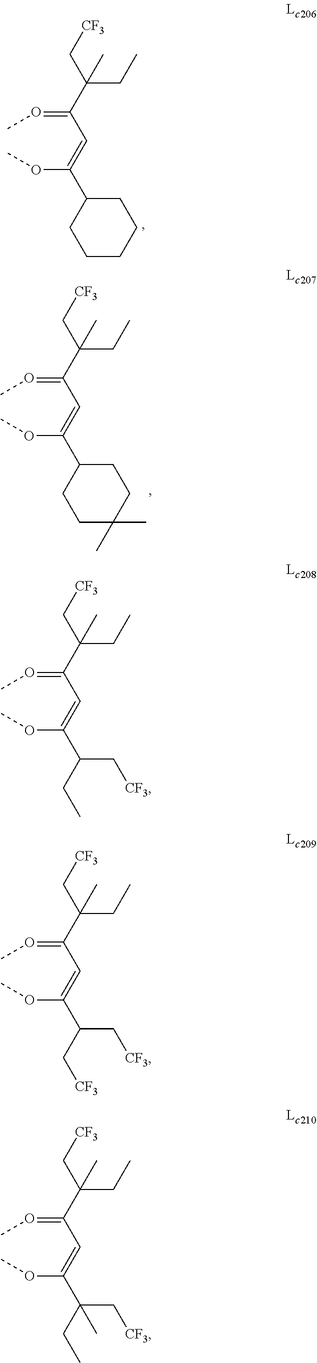

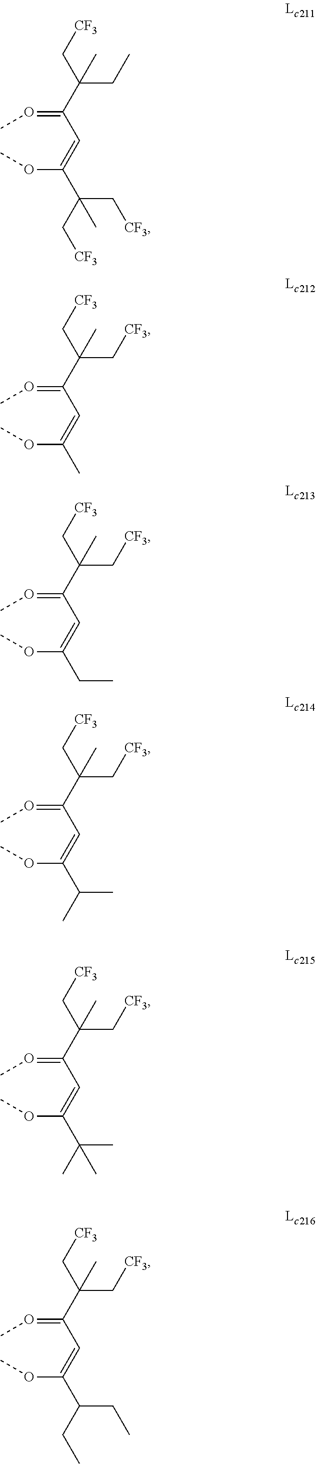

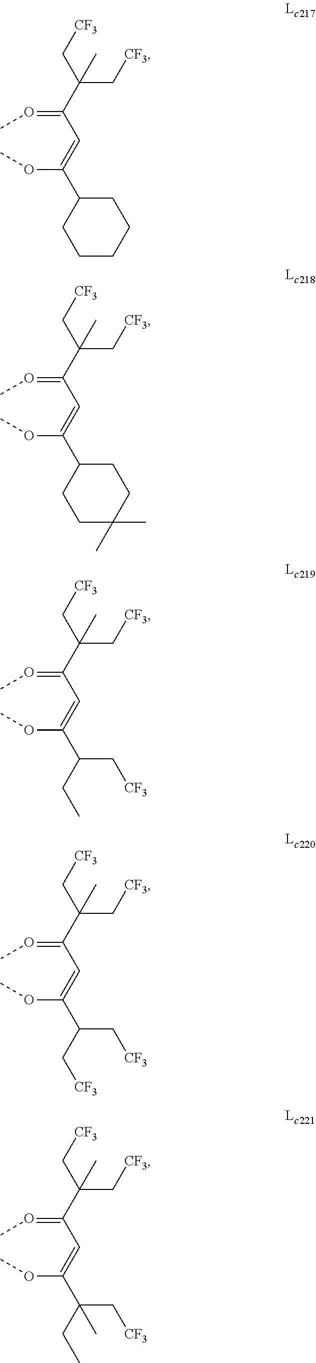

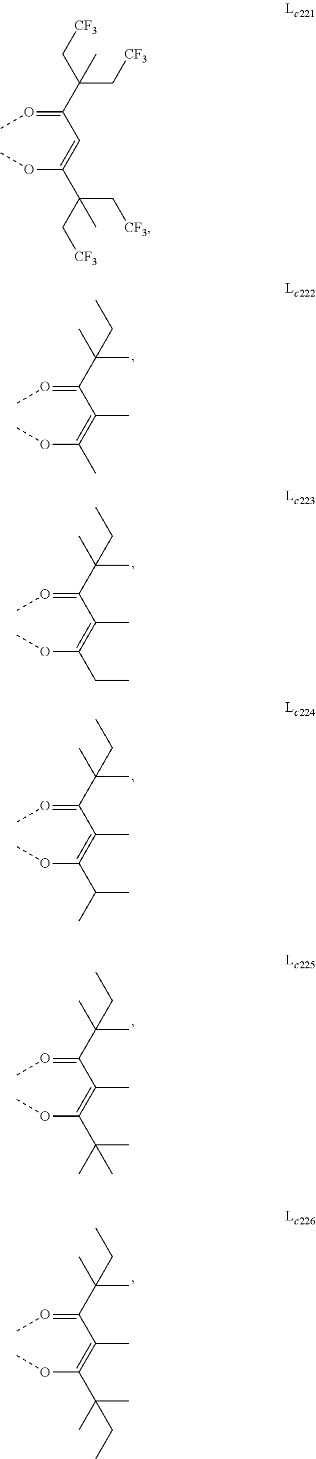

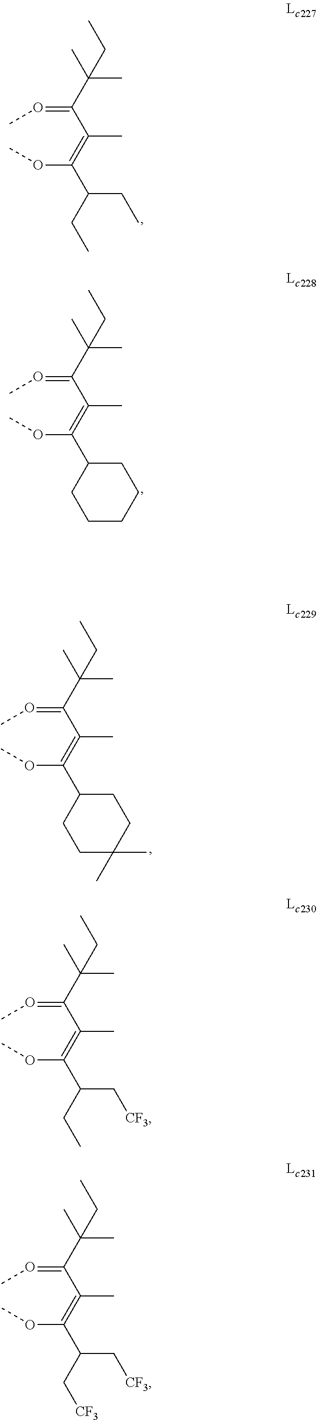

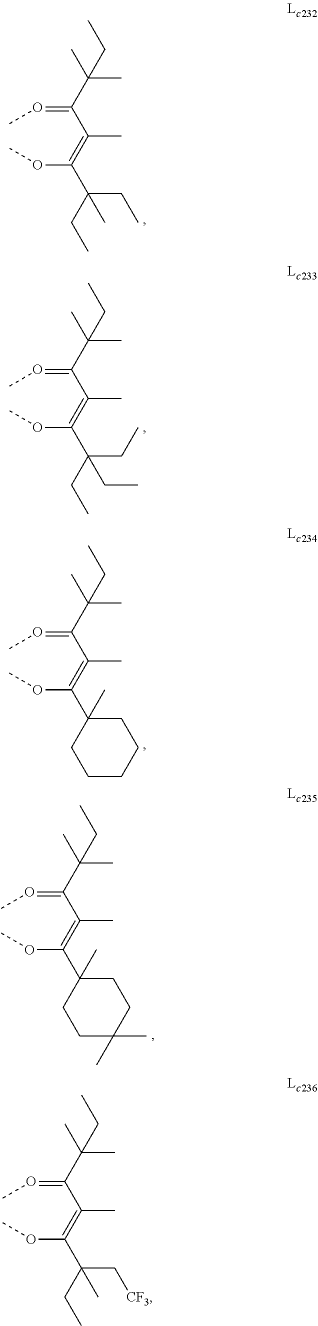

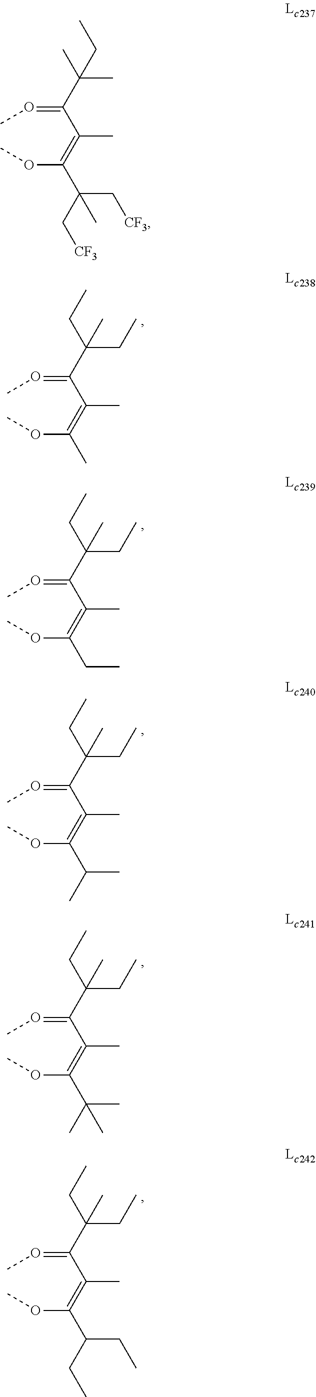

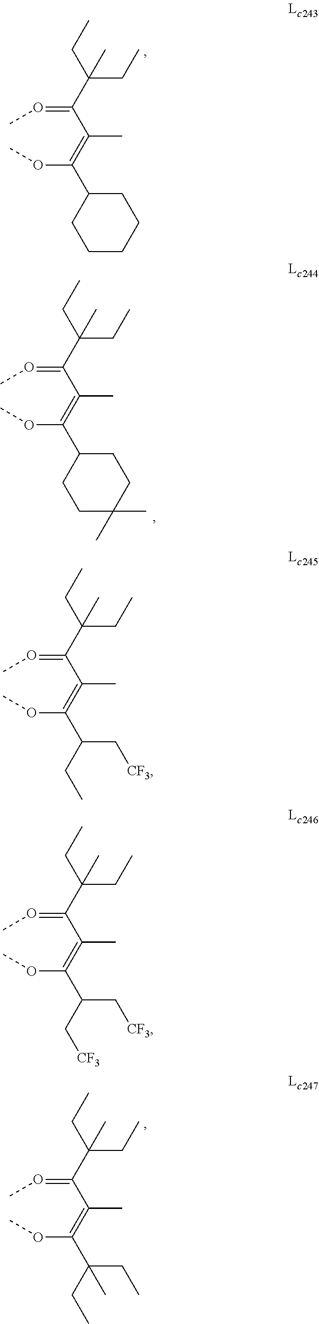

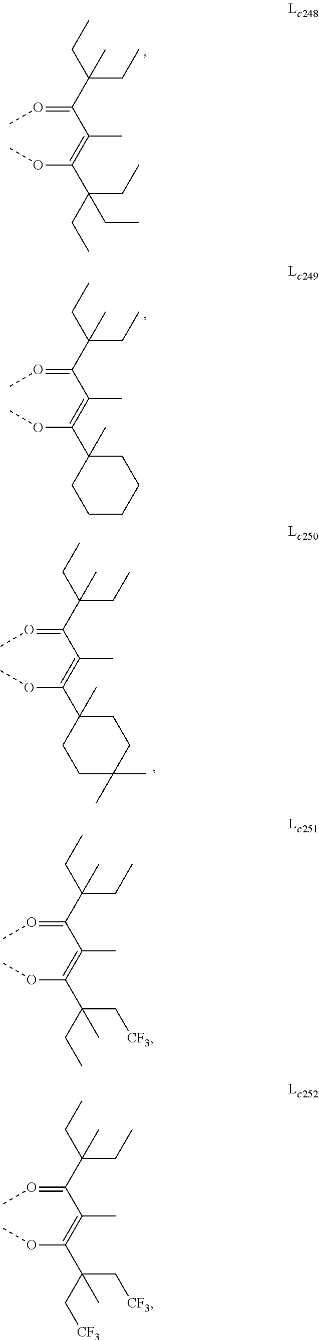

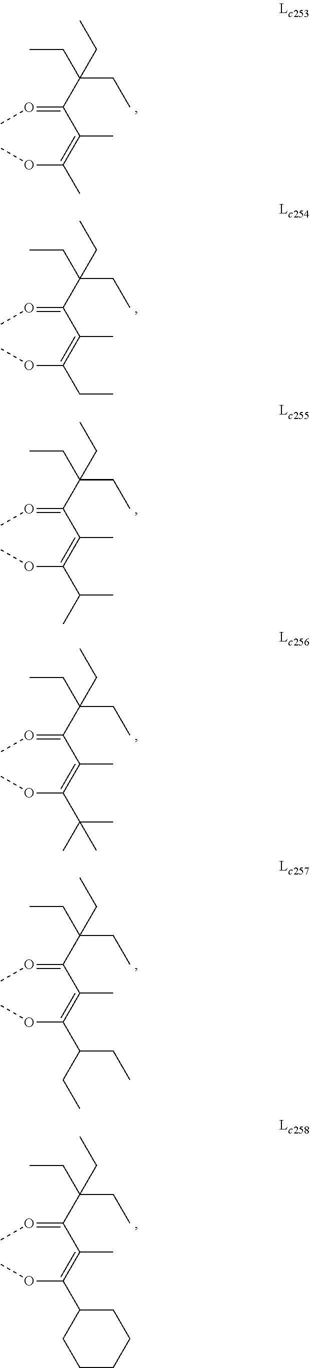

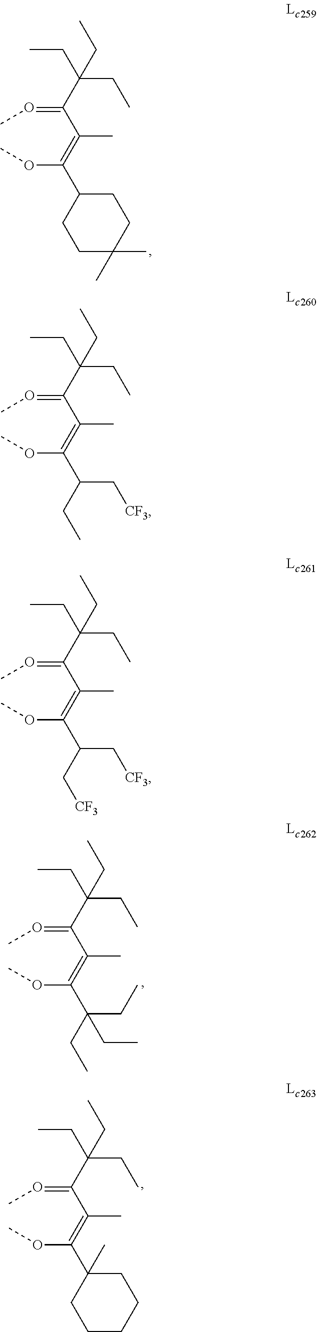

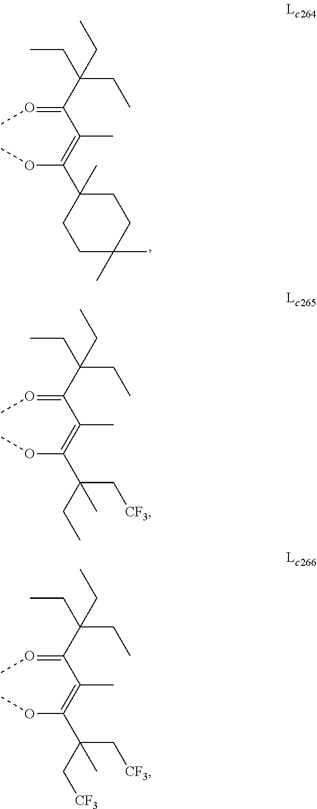

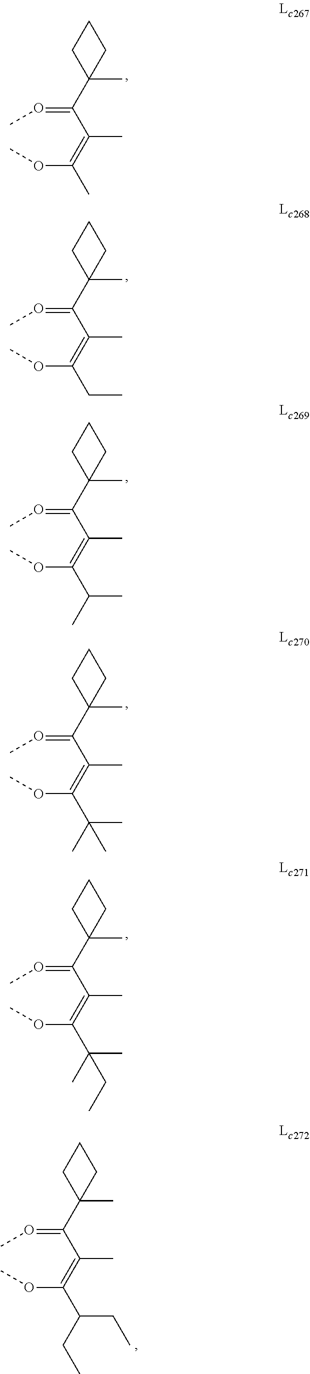

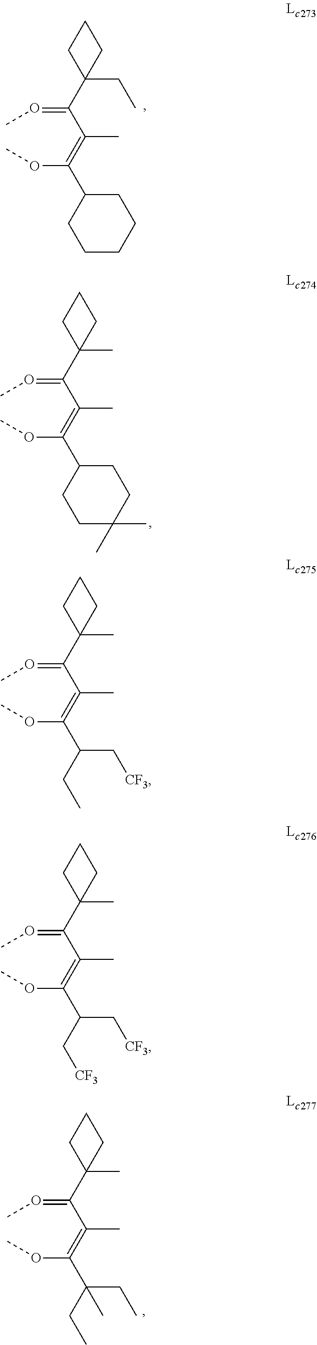

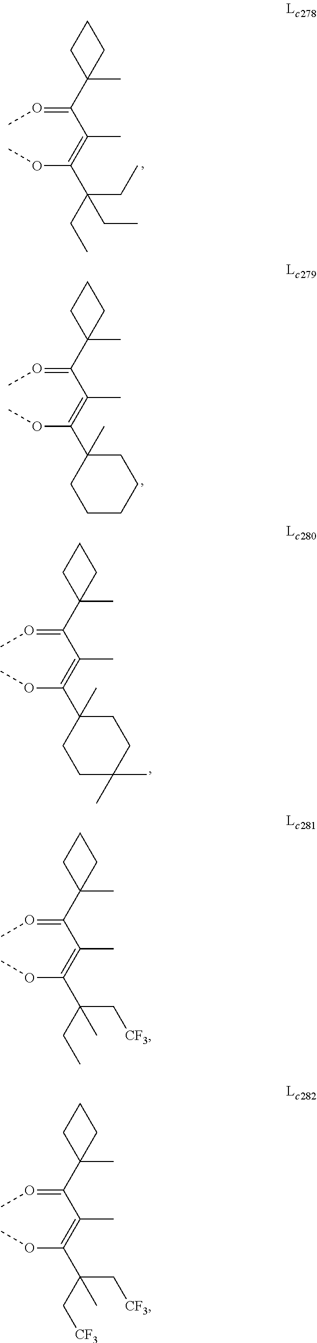

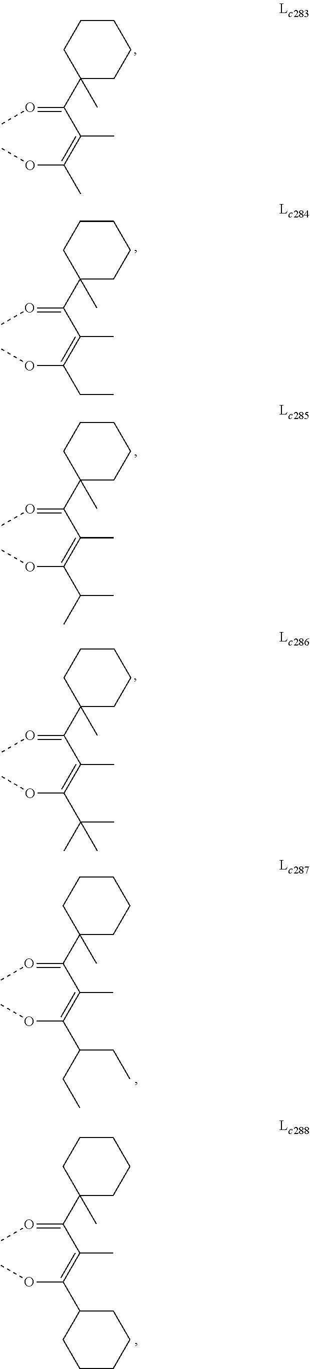

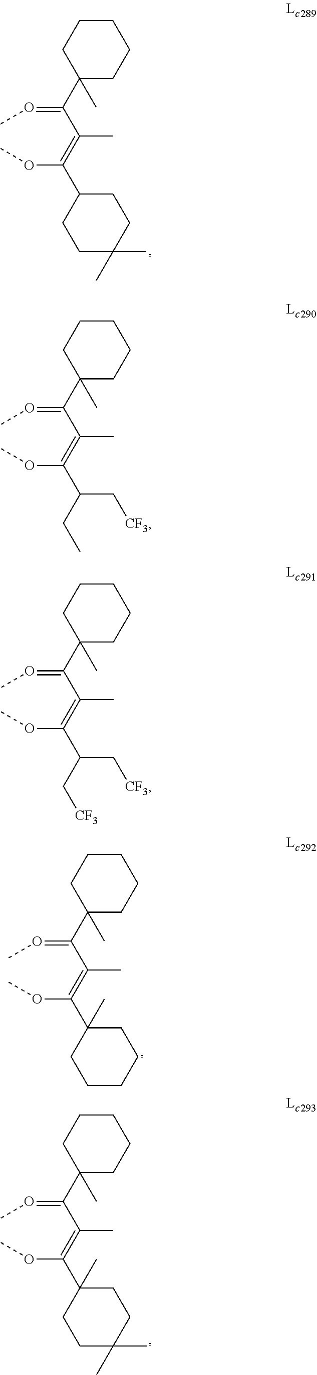

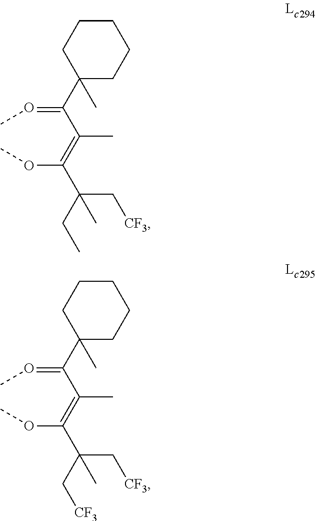

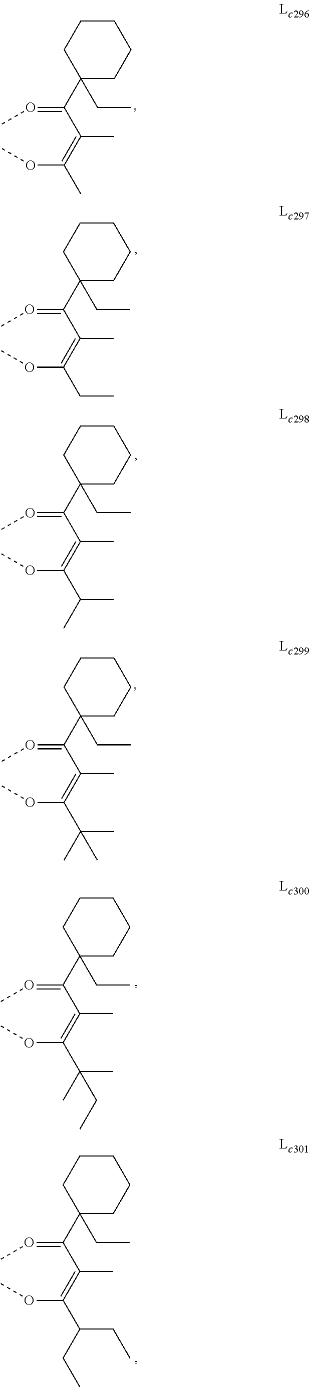

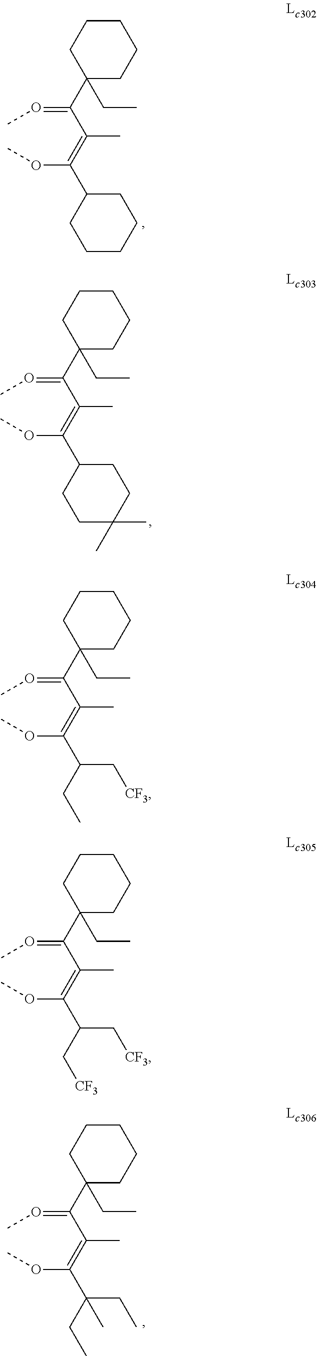

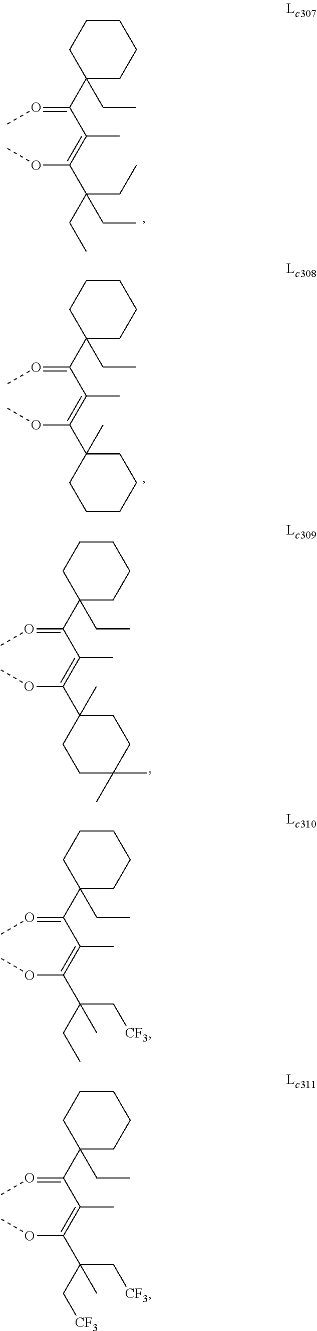

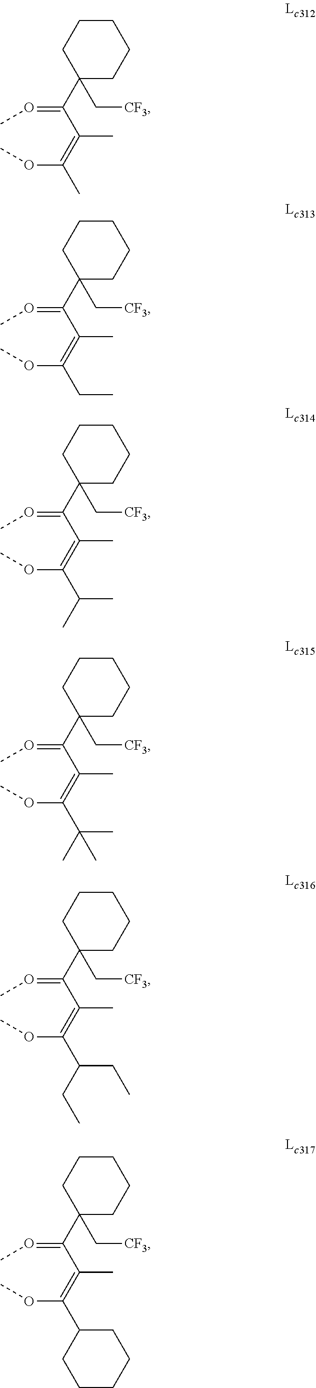

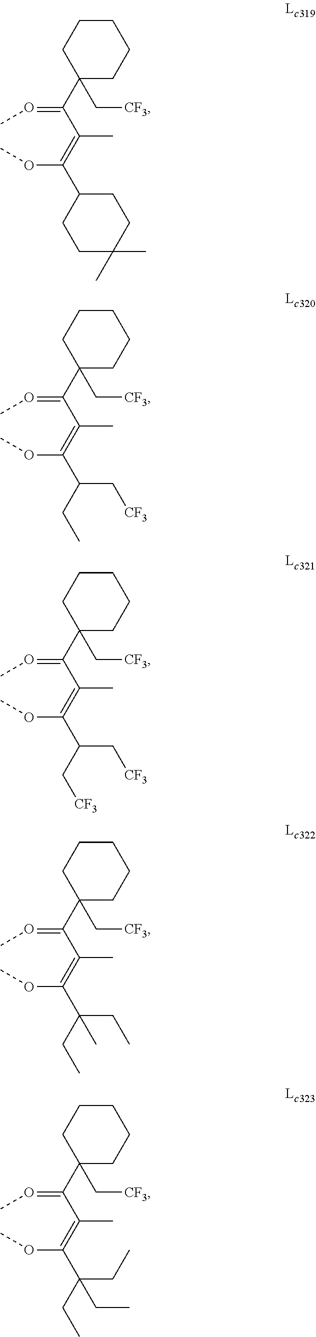

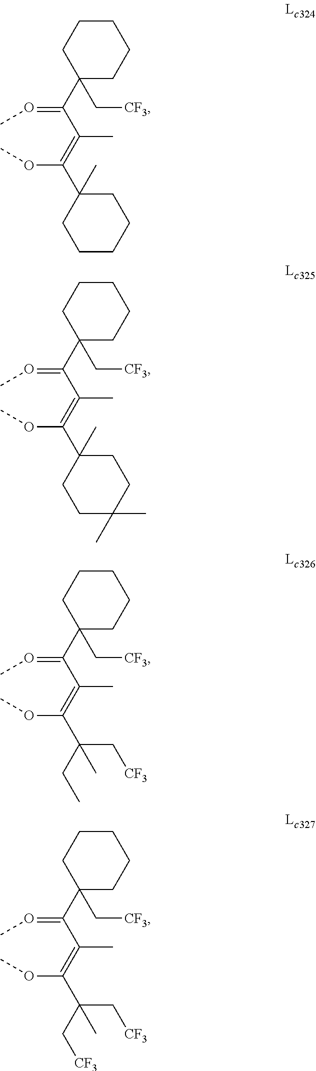

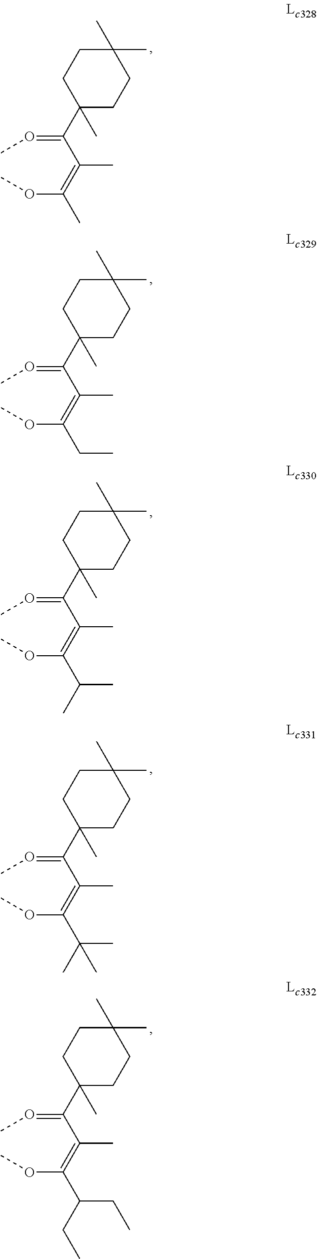

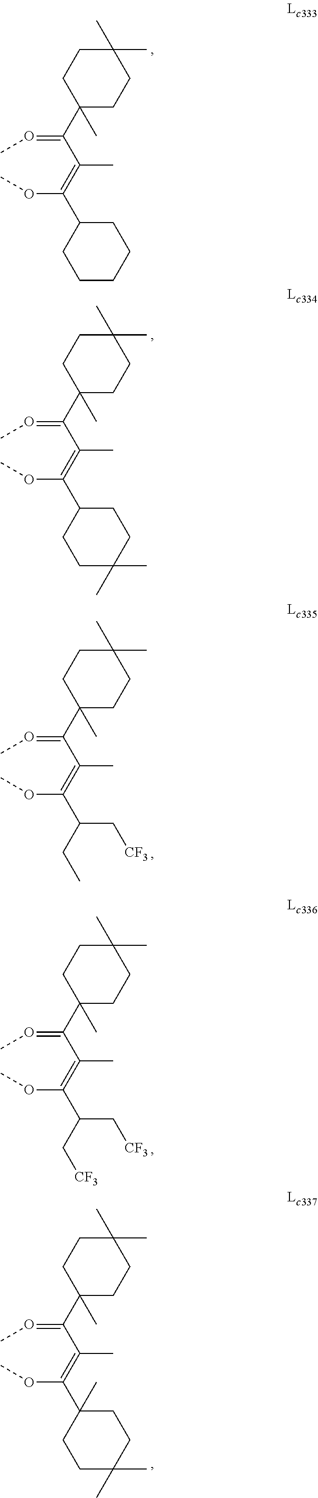

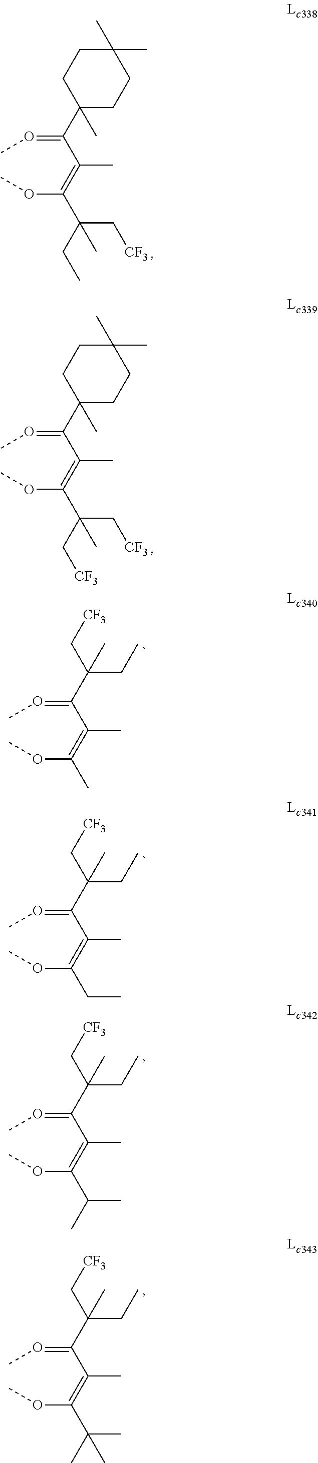

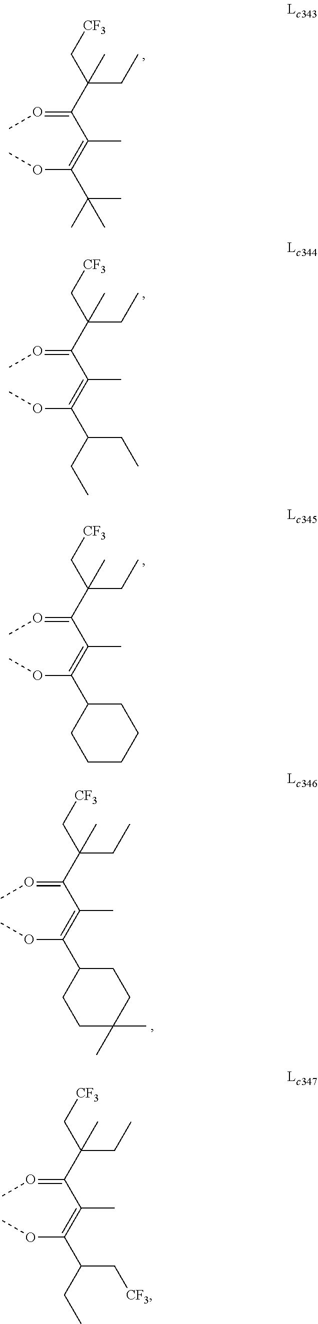

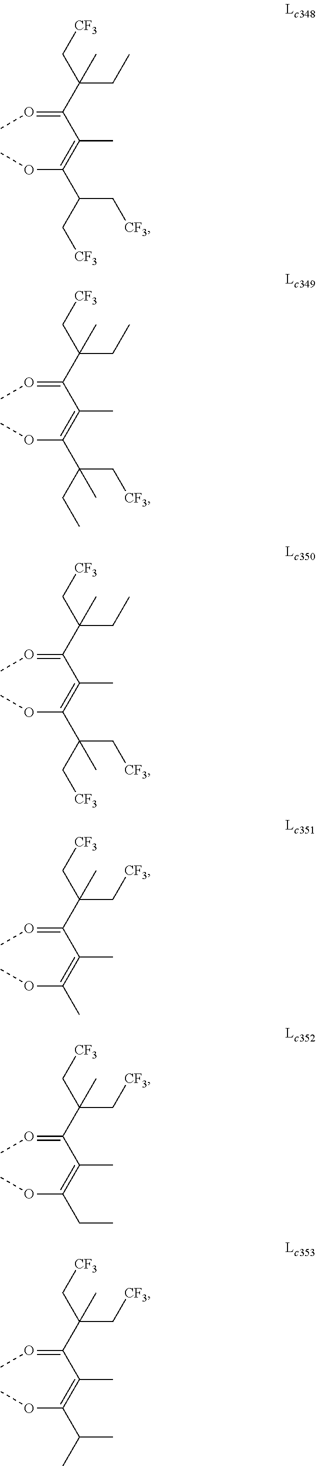

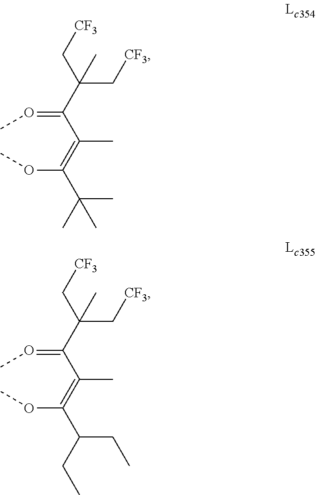

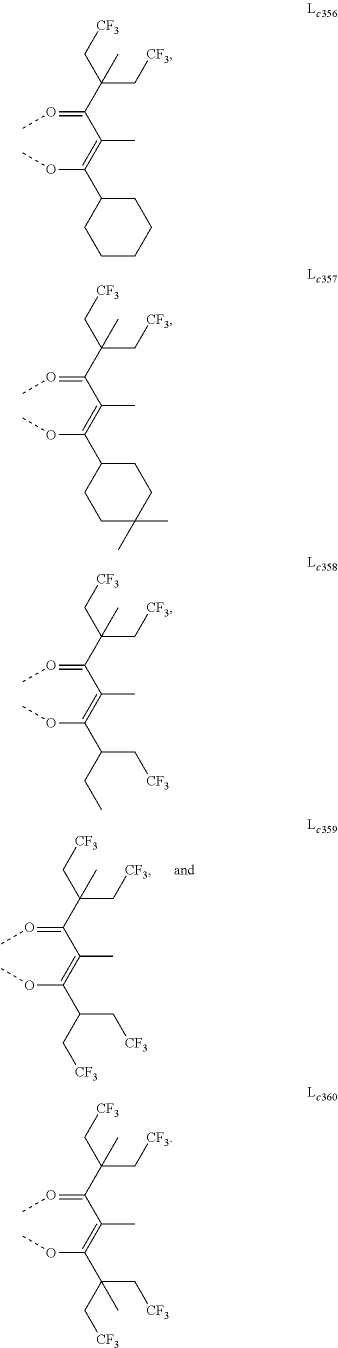

19. The metal complex according to claim 18, wherein the metal complex has a structure of Ir(Lₐ)₂(L_{b}) or Ir(Lₐ)(L_{b})₂ or Ir(Lₐ)₃, wherein Lₐ is, at each occurrence identically or differently, selected from any one or any two or any three of the group consisting of Lₐ₁ to Lₐ₉₅₆, and L_{b} is selected from any one or any two of the group consisting of L_{b1} to L_{b128}; or
the metal complex has a structure of Ir(Lₐ)₂(L_{c}) or Ir(Lₐ)(L_{c})₂, wherein Lₐ is, at each occurrence identically or differently, selected from any one or any two of the group consisting of Lₐ₁ to Lₐ₉₅₆, and L_{c} is selected from any one or any two of the group consisting of L_{c1} to L_{c360}; or
the metal complex has a structure of Ir(Lₐ)(L_{b})(L_{c}), wherein Lₐ is, at each occurrence identically or differently, selected from any one of the group consisting of Lₐ₁ to Lₐ₉₅₆, L_{b} is selected from any one of the group consisting of L_{b1} to L_{b128}, and L_{c} is selected from any one of the group consisting of L_{c1} to L_{c360};
preferably, wherein the metal complex is selected from the group consisting of Metal complex 1 to Metal complex 1217, wherein Metal complex 1 to Metal complex 1217 have a structure of IrLₐ(L_{b})₂, wherein two L_{b} are identical, wherein Lₐ and L_{b} correspond to structures in the following table, respectively:

| Metal | | |
|---|---|---|
| complex | Lₐ | L_{b} |
| 1 | Lₐ₁ | L_{b1} |
| 2 | Lₐ₇ | L_{b1} |
| 3 | Lₐ₈ | L_{b1} |
| 4 | Lₐ₉ | L_{b1} |
| 5 | Lₐ₁₀ | L_{b1} |
| 6 | Lₐ₁₁ | L_{b1} |
| 7 | Lₐ₁₂ | L_{b1} |
| 8 | Lₐ₂₀ | L_{b1} |
| 9 | Lₐ₄₀ | L_{b1} |
| 10 | Lₐ₄₃ | L_{b1} |
| 11 | Lₐ₄₉ | L_{b1} |
| 12 | Lₐ₅₀ | L_{b1} |
| 13 | Lₐ₅₁ | L_{b1} |
| 14 | Lₐ₅₂ | L_{b1} |
| 15 | Lₐ₅₃ | L_{b1} |
| 16 | Lₐ₅₄ | L_{b1} |
| 17 | Lₐ₆₁ | L_{b1} |
| 18 | Lₐ₆₉ | L_{b1} |
| 19 | Lₐ₇₄ | L_{b1} |
| 20 | Lₐ₇₇ | L_{b1} |
| 21 | Lₐ₇₈ | L_{b1} |
| 22 | Lₐ₇₉ | L_{b1} |
| 23 | Lₐ₈₃ | L_{b1} |
| 24 | Lₐ₈₅ | L_{b1} |
| 25 | Lₐ₉₁ | L_{b1} |
| 26 | Lₐ₁₀₀ | L_{b1} |
| 27 | Lₐ₁₀₃ | L_{b1} |
| 28 | Lₐ₁₀₅ | L_{b1} |
| 29 | Lₐ₁₀₉ | L_{b1} |
| 30 | Lₐ₁₁₃ | L_{b1} |
| 31 | Lₐ₁₁₇ | L_{b1} |
| 32 | Lₐ₁₂₀ | L_{b1} |
| 33 | Lₐ₁₂₃ | L_{b1} |
| 34 | Lₐ₁₂₆ | L_{b1} |
| 35 | Lₐ₁₃₃ | L_{b1} |
| 36 | Lₐ₁₃₈ | L_{b1} |
| 37 | Lₐ₁₄₃ | L_{b1} |
| 38 | Lₐ₁₄₈ | L_{b1} |
| 39 | Lₐ₁₅₁ | L_{b1} |
| 40 | Lₐ₁₅₃ | L_{b1} |
| 41 | Lₐ₁₅₅ | L_{b1} |
| 42 | Lₐ₁₅₇ | L_{b1} |
| 43 | Lₐ₁₅₉ | L_{b1} |
| 44 | Lₐ₁₆₁ | L_{b1} |
| 45 | Lₐ₁₆₃ | L_{b1} |
| 46 | Lₐ₁₆₈ | L_{b1} |
| 47 | Lₐ₁₇₃ | L_{b1} |
| 48 | Lₐ₁₇₇ | L_{b1} |
| 49 | Lₐ₁₈₁ | L_{b1} |
| 50 | Lₐ₁₈₃ | L_{b1} |
| 51 | Lₐ₁₈₅ | L_{b1} |
| 52 | Lₐ₁₈₇ | L_{b1} |
| 53 | Lₐ₁₉₀ | L_{b1} |
| 54 | Lₐ₁₉₂ | L_{b1} |
| 55 | Lₐ₁₉₄ | L_{b1} |
| 56 | Lₐ₁₉₅ | L_{b1} |
| 57 | Lₐ₁₉₆ | L_{b1} |
| 58 | Lₐ₂₀₁ | L_{b1} |
| 59 | Lₐ₂₀₂ | L_{b1} |
| 60 | Lₐ₂₀₃ | L_{b1} |
| 61 | Lₐ₂₀₄ | L_{b1} |
| 62 | Lₐ₂₁₁ | L_{b1} |
| 63 | Lₐ₂₁₆ | L_{b1} |
| 64 | Lₐ₂₂₆ | L_{b1} |
| 65 | Lₐ₂₂₇ | L_{b1} |
| 66 | Lₐ₂₄₀ | L_{b1} |
| 67 | Lₐ₂₄₁ | L_{b1} |
| 68 | Lₐ₂₄₂ | L_{b1} |
| 69 | Lₐ₂₄₃ | L_{b1} |
| 70 | Lₐ₂₄₄ | L_{b1} |
| 71 | Lₐ₂₅₈ | L_{b1} |
| 72 | Lₐ₂₆₉ | L_{b1} |
| 73 | Lₐ₂₇₄ | L_{b1} |
| 74 | Lₐ₂₇₅ | L_{b1} |
| 75 | Lₐ₃₁₁ | L_{b1} |
| 76 | Lₐ₃₁₇ | L_{b1} |
| 77 | Lₐ₃₂₃ | L_{b1} |
| 78 | Lₐ₃₂₈ | L_{b1} |
| 79 | Lₐ₃₃₂ | L_{b1} |
| 80 | Lₐ₃₄₁ | L_{b1} |
| 81 | Lₐ₃₄₅ | L_{b1} |
| 82 | Lₐ₃₄₉ | L_{b1} |
| 83 | Lₐ₃₅₃ | L_{b1} |
| 84 | Lₐ₃₅₅ | L_{b1} |
| 85 | Lₐ₃₅₇ | L_{b1} |
| 86 | Lₐ₃₅₉ | L_{b1} |
| 87 | Lₐ₃₆₁ | L_{b1} |
| 88 | Lₐ₃₆₃ | L_{b1} |
| 89 | Lₐ₃₆₅ | L_{b1} |
| 90 | Lₐ₃₆₇ | L_{b1} |
| 91 | Lₐ₃₆₈ | L_{b1} |
| 92 | Lₐ₃₆₉ | L_{b1} |
| 93 | Lₐ₃₉₀ | L_{b1} |
| 94 | Lₐ₃₉₉ | L_{b1} |
| 95 | Lₐ₄₀₀ | L_{b1} |
| 96 | Lₐ₄₀₂ | L_{b1} |
| 97 | Lₐ₄₁₈ | L_{b1} |
| 98 | Lₐ₄₂₂ | L_{b1} |
| 99 | Lₐ₄₂₇ | L_{b1} |
| 100 | Lₐ₄₃₁ | L_{b1} |
| 101 | Lₐ₄₃₃ | L_{b1} |
| 102 | Lₐ₄₃₅ | L_{b1} |
| 103 | Lₐ₄₄₆ | L_{b1} |
| 104 | Lₐ₄₅₀ | L_{b1} |
| 105 | Lₐ₄₅₄ | L_{b1} |
| 106 | Lₐ₄₅₆ | L_{b1} |
| 107 | Lₐ₄₆₂ | L_{b1} |
| 108 | Lₐ₄₆₇ | L_{b1} |
| 109 | Lₐ₄₇₂ | L_{b1} |
| 110 | Lₐ₄₇₆ | L_{b1} |
| 111 | Lₐ₄₈₀ | L_{b1} |
| 112 | Lₐ₄₈₄ | L_{b1} |
| 113 | Lₐ₄₈₉ | L_{b1} |
| 114 | Lₐ₄₉₃ | L_{b1} |
| 115 | Lₐ₄₉₅ | L_{b1} |
| 116 | Lₐ₄₉₇ | L_{b1} |
| 117 | Lₐ₄₉₈ | L_{b1} |
| 118 | Lₐ₄₉₉ | L_{b1} |
| 119 | Lₐ₅₀₀ | L_{b1} |
| 120 | Lₐ₅₀₁ | L_{b1} |
| 121 | Lₐ₅₁₁ | L_{b1} |
| 122 | Lₐ₅₁₅ | L_{b1} |
| 123 | Lₐ₅₁₇ | L_{b1} |
| 124 | Lₐ₅₁₉ | L_{b1} |
| 125 | Lₐ₅₂₁ | L_{b1} |
| 126 | Lₐ₅₂₃ | L_{b1} |
| 127 | Lₐ₅₄₄ | L_{b1} |
| 128 | Lₐ₅₄₈ | L_{b1} |
| 129 | Lₐ₅₅₀ | L_{b1} |
| 130 | Lₐ₅₅₂ | L_{b1} |
| 131 | Lₐ₅₅₆ | L_{b1} |
| 132 | Lₐ₅₆₀ | L_{b1} |
| 133 | Lₐ₅₆₄ | L_{b1} |
| 134 | Lₐ₅₆₈ | L_{b1} |
| 135 | Lₐ₅₇₆ | L_{b1} |
| 136 | Lₐ₅₇₇ | L_{b1} |
| 137 | Lₐ₅₈₀ | L_{b1} |
| 138 | Lₐ₅₈₃ | L_{b1} |
| 139 | Lₐ₅₈₆ | L_{b1} |
| 140 | Lₐ₅₉₀ | L_{b1} |
| 141 | Lₐ₅₉₁ | L_{b1} |
| 142 | Lₐ₅₉₄ | L_{b1} |
| 143 | Lₐ₆₀₁ | L_{b1} |
| 144 | Lₐ₆₀₂ | L_{b1} |
| 145 | Lₐ₆₀₅ | L_{b1} |
| 146 | Lₐ₆₁₀ | L_{b1} |
| 147 | Lₐ₆₁₁ | L_{b1} |
| 148 | Lₐ₆₁₂ | L_{b1} |
| 149 | Lₐ₆₂₂ | L_{b1} |
| 150 | Lₐ₆₂₆ | L_{b1} |
| 151 | Lₐ₁ | L_{b3} |
| 152 | Lₐ₇ | L_{b3} |
| 153 | Lₐ₈ | L_{b3} |
| 154 | Lₐ₉ | L_{b3} |
| 155 | Lₐ₁₀ | L_{b3} |
| 156 | Lₐ₁₁ | L_{b3} |
| 157 | Lₐ₁₂ | L_{b3} |
| 158 | Lₐ₂₀ | L_{b3} |
| 159 | Lₐ₄₀ | L_{b3} |
| 160 | Lₐ₄₃ | L_{b3} |
| 161 | Lₐ₄₉ | L_{b3} |
| 162 | Lₐ₅₀ | L_{b3} |
| 163 | Lₐ₅₁ | L_{b3} |
| 164 | Lₐ₅₂ | L_{b3} |
| 165 | Lₐ₅₃ | L_{b3} |
| 166 | Lₐ₅₄ | L_{b3} |
| 167 | Lₐ₆₁ | L_{b3} |
| 168 | Lₐ₆₉ | L_{b3} |
| 169 | Lₐ₇₄ | L_{b3} |
| 170 | Lₐ₇₇ | L_{b3} |
| 171 | Lₐ₇₈ | L_{b3} |
| 172 | Lₐ₇₉ | L_{b3} |
| 173 | Lₐ₈₃ | L_{b3} |
| 174 | Lₐ₈₅ | L_{b3} |
| 175 | Lₐ₉₁ | L_{b3} |
| 176 | Lₐ₁₀₀ | L_{b3} |
| 177 | Lₐ₁₀₃ | L_{b3} |
| 178 | Lₐ₁₀₅ | L_{b3} |
| 179 | Lₐ₁₀₉ | L_{b3} |
| 180 | Lₐ₁₁₃ | L_{b3} |
| 181 | Lₐ₁₁₇ | L_{b3} |
| 182 | Lₐ₁₂₀ | L_{b3} |
| 183 | Lₐ₁₂₃ | L_{b3} |
| 184 | Lₐ₁₂₆ | L_{b3} |
| 185 | Lₐ₁₃₃ | L_{b3} |
| 186 | Lₐ₁₃₈ | L_{b3} |
| 187 | Lₐ₁₄₃ | L_{b3} |
| 188 | Lₐ₁₄₈ | L_{b3} |
| 189 | Lₐ₁₅₁ | L_{b3} |
| 190 | Lₐ₁₅₃ | L_{b3} |
| 191 | Lₐ₁₅₅ | L_{b3} |
| 192 | Lₐ₁₅₇ | L_{b3} |
| 193 | Lₐ₁₅₉ | L_{b3} |
| 194 | Lₐ₁₆₁ | L_{b3} |
| 195 | Lₐ₁₆₃ | L_{b3} |
| 196 | Lₐ₁₆₈ | L_{b3} |
| 197 | Lₐ₁₇₃ | L_{b3} |
| 198 | Lₐ₁₇₇ | L_{b3} |
| 199 | Lₐ₁₈₁ | L_{b3} |
| 200 | Lₐ₁₈₃ | L_{b3} |
| 201 | Lₐ₁₈₅ | L_{b3} |
| 202 | Lₐ₁₈₇ | L_{b3} |
| 203 | Lₐ₁₉₀ | L_{b3} |
| 204 | Lₐ₁₉₂ | L_{b3} |
| 205 | Lₐ₁₉₄ | L_{b3} |
| 206 | Lₐ₁₉₅ | L_{b3} |
| 207 | Lₐ₁₉₆ | L_{b3} |
| 208 | Lₐ₂₀₁ | L_{b3} |
| 209 | Lₐ₂₀₂ | L_{b3} |
| 210 | Lₐ₂₀₃ | L_{b3} |
| 211 | Lₐ₂₀₄ | L_{b3} |
| 212 | Lₐ₂₁₁ | L_{b3} |
| 213 | Lₐ₂₁₆ | L_{b3} |
| 214 | Lₐ₂₂₆ | L_{b3} |
| 215 | Lₐ₂₂₇ | L_{b3} |
| 216 | Lₐ₂₄₀ | L_{b3} |
| 217 | Lₐ₂₄₁ | L_{b3} |
| 218 | Lₐ₂₄₂ | L_{b3} |
| 219 | Lₐ₂₄₃ | L_{b3} |
| 220 | Lₐ₂₄₄ | L_{b3} |
| 221 | Lₐ₂₅₈ | L_{b3} |
| 222 | Lₐ₂₆₉ | L_{b3} |
| 223 | Lₐ₂₇₄ | L_{b3} |
| 224 | Lₐ₂₇₅ | L_{b3} |
| 225 | Lₐ₃₁₁ | L_{b3} |
| 226 | Lₐ₃₁₇ | L_{b3} |
| 227 | Lₐ₃₂₃ | L_{b3} |
| 228 | Lₐ₃₂₈ | L_{b3} |
| 229 | Lₐ₃₃₂ | L_{b3} |
| 230 | Lₐ₃₄₁ | L_{b3} |
| 231 | Lₐ₃₄₅ | L_{b3} |
| 232 | Lₐ₃₄₉ | L_{b3} |
| 233 | Lₐ₃₅₃ | L_{b3} |
| 234 | Lₐ₃₅₅ | L_{b3} |
| 235 | Lₐ₃₅₇ | L_{b3} |
| 236 | Lₐ₃₅₉ | L_{b3} |
| 237 | Lₐ₃₆₁ | L_{b3} |
| 238 | Lₐ₃₆₃ | L_{b3} |
| 239 | Lₐ₃₆₅ | L_{b3} |
| 240 | Lₐ₃₆₇ | L_{b3} |
| 241 | Lₐ₃₆₈ | L_{b3} |
| 242 | Lₐ₃₆₉ | L_{b3} |
| 243 | Lₐ₃₉₀ | L_{b3} |
| 244 | Lₐ₃₉₉ | L_{b3} |
| 245 | Lₐ₄₀₀ | L_{b3} |
| 246 | Lₐ₄₀₂ | L_{b3} |
| 247 | Lₐ₄₁₈ | L_{b3} |
| 248 | Lₐ₄₂₂ | L_{b3} |
| 249 | Lₐ₄₂₇ | L_{b3} |
| 250 | Lₐ₄₃₁ | L_{b3} |
| 251 | Lₐ₄₃₃ | L_{b3} |
| 252 | Lₐ₄₃₅ | L_{b3} |
| 253 | Lₐ₄₄₆ | L_{b3} |
| 254 | Lₐ₄₅₀ | L_{b3} |
| 255 | Lₐ₄₅₄ | L_{b3} |
| 256 | Lₐ₄₅₆ | L_{b3} |
| 257 | Lₐ₄₆₂ | L_{b3} |
| 258 | Lₐ₄₆₇ | L_{b3} |
| 259 | Lₐ₄₇₂ | L_{b3} |
| 260 | Lₐ₄₇₆ | L_{b3} |
| 261 | Lₐ₄₈₀ | L_{b3} |
| 262 | Lₐ₄₈₄ | L_{b3} |
| 263 | Lₐ₄₈₉ | L_{b3} |
| 264 | Lₐ₄₉₃ | L_{b3} |
| 265 | Lₐ₄₉₅ | L_{b3} |
| 266 | Lₐ₄₉₇ | L_{b3} |
| 267 | Lₐ₄₉₈ | L_{b3} |
| 268 | Lₐ₄₉₉ | L_{b3} |
| 269 | Lₐ₅₀₀ | L_{b3} |
| 270 | Lₐ₅₀₁ | L_{b3} |
| 271 | Lₐ₅₁₁ | L_{b3} |
| 272 | Lₐ₅₁₅ | L_{b3} |
| 273 | Lₐ₅₁₇ | L_{b3} |
| 274 | Lₐ₅₁₉ | L_{b3} |
| 275 | Lₐ₅₂₁ | L_{b3} |
| 276 | Lₐ₅₂₃ | L_{b3} |
| 277 | Lₐ₅₄₄ | L_{b3} |
| 278 | Lₐ₅₄₈ | L_{b3} |
| 279 | Lₐ₅₅₀ | L_{b3} |
| 280 | Lₐ₅₅₂ | L_{b3} |
| 281 | Lₐ₅₅₆ | L_{b3} |
| 282 | Lₐ₅₆₀ | L_{b3} |
| 283 | Lₐ₅₆₄ | L_{b3} |
| 284 | Lₐ₅₆₈ | L_{b3} |
| 285 | Lₐ₅₇₆ | L_{b3} |
| 286 | Lₐ₅₇₇ | L_{b3} |
| 287 | Lₐ₅₈₀ | L_{b3} |
| 288 | Lₐ₅₈₃ | L_{b3} |
| 289 | Lₐ₅₈₆ | L_{b3} |
| 290 | Lₐ₅₉₀ | L_{b3} |
| 291 | Lₐ₅₉₁ | L_{b3} |
| 292 | Lₐ₅₉₄ | L_{b3} |
| 293 | Lₐ₆₀₁ | L_{b3} |
| 294 | Lₐ₆₀₂ | L_{b3} |
| 295 | Lₐ₆₀₅ | L_{b3} |
| 296 | Lₐ₆₁₀ | L_{b3} |
| 297 | Lₐ₆₁₁ | L_{b3} |
| 298 | Lₐ₆₁₂ | L_{b3} |
| 299 | Lₐ₆₂₂ | L_{b3} |
| 300 | Lₐ₆₂₆ | L_{b3} |
| 301 | Lₐ₁ | L_{b12} |
| 302 | Lₐ₇ | L_{b12} |
| 303 | Lₐ₈ | L_{b12} |
| 304 | Lₐ₉ | L_{b12} |
| 305 | Lₐ₁₀ | L_{b12} |
| 306 | Lₐ₁₁ | L_{b12} |
| 307 | Lₐ₁₂ | L_{b12} |
| 308 | Lₐ₂₀ | L_{b12} |
| 309 | Lₐ₄₀ | L_{b12} |
| 310 | Lₐ₄₃ | L_{b12} |
| 311 | Lₐ₄₉ | L_{b12} |
| 312 | Lₐ₅₀ | L_{b12} |
| 313 | Lₐ₅₁ | L_{b12} |
| 314 | Lₐ₅₂ | L_{b12} |
| 315 | Lₐ₅₃ | L_{b12} |
| 316 | Lₐ₅₄ | L_{b12} |
| 317 | Lₐ₆₁ | L_{b12} |
| 318 | Lₐ₆₉ | L_{b12} |
| 319 | Lₐ₇₄ | L_{b12} |
| 320 | Lₐ₇₇ | L_{b12} |
| 321 | Lₐ₇₈ | L_{b12} |
| 322 | Lₐ₇₉ | L_{b12} |
| 323 | Lₐ₈₃ | L_{b12} |
| 324 | Lₐ₈₅ | L_{b12} |
| 325 | Lₐ₉₁ | L_{b12} |
| 326 | Lₐ₁₀₀ | L_{b12} |
| 327 | Lₐ₁₀₃ | L_{b12} |
| 328 | Lₐ₁₀₅ | L_{b12} |
| 329 | Lₐ₁₀₉ | L_{b12} |
| 330 | Lₐ₁₁₃ | L_{b12} |
| 331 | Lₐ₁₁₇ | L_{b12} |
| 332 | Lₐ₁₂₀ | L_{b12} |
| 333 | Lₐ₁₂₃ | L_{b12} |
| 334 | Lₐ₁₂₆ | L_{b12} |
| 335 | Lₐ₁₃₃ | L_{b12} |
| 336 | Lₐ₁₃₈ | L_{b12} |
| 337 | Lₐ₁₄₃ | L_{b12} |
| 338 | Lₐ₁₄₈ | L_{b12} |
| 339 | Lₐ₁₅₁ | L_{b12} |
| 340 | Lₐ₁₅₃ | L_{b12} |
| 341 | Lₐ₁₅₅ | L_{b12} |
| 342 | Lₐ₁₅₇ | L_{b12} |
| 343 | Lₐ₁₅₉ | L_{b12} |
| 344 | Lₐ₁₆₁ | L_{b12} |
| 345 | Lₐ₁₆₃ | L_{b12} |
| 346 | Lₐ₁₆₈ | L_{b12} |
| 347 | Lₐ₁₇₃ | L_{b12} |
| 348 | Lₐ₁₇₇ | L_{b12} |
| 349 | Lₐ₁₈₁ | L_{b12} |
| 350 | Lₐ₁₈₃ | L_{b12} |
| 351 | Lₐ₁₈₅ | L_{b12} |
| 352 | Lₐ₁₈₇ | L_{b12} |
| 353 | Lₐ₁₉₀ | L_{b12} |
| 354 | Lₐ₁₉₂ | L_{b12} |
| 355 | Lₐ₁₉₄ | L_{b12} |
| 356 | Lₐ₁₉₅ | L_{b12} |
| 357 | Lₐ₁₉₆ | L_{b12} |
| 358 | Lₐ₂₀₁ | L_{b12} |
| 359 | Lₐ₂₀₂ | L_{b12} |
| 360 | Lₐ₂₀₃ | L_{b12} |
| 361 | Lₐ₂₀₄ | L_{b12} |
| 362 | Lₐ₂₁₁ | L_{b12} |
| 363 | Lₐ₂₁₆ | L_{b12} |
| 364 | Lₐ₂₂₆ | L_{b12} |
| 365 | Lₐ₂₂₇ | L_{b12} |
| 366 | Lₐ₂₄₀ | L_{b12} |
| 367 | Lₐ₂₄₁ | L_{b12} |
| 368 | Lₐ₂₄₂ | L_{b12} |
| 369 | Lₐ₂₄₃ | L_{b12} |
| 370 | Lₐ₂₄₄ | L_{b12} |
| 371 | Lₐ₂₅₈ | L_{b12} |
| 372 | Lₐ₂₆₉ | L_{b12} |
| 373 | Lₐ₂₇₄ | L_{b12} |
| 374 | Lₐ₂₇₅ | L_{b12} |
| 375 | Lₐ₃₁₁ | L_{b12} |
| 376 | Lₐ₃₁₇ | L_{b12} |
| 377 | Lₐ₃₂₃ | L_{b12} |
| 378 | Lₐ₃₂₈ | L_{b12} |
| 379 | Lₐ₃₃₂ | L_{b12} |
| 380 | Lₐ₃₄₁ | L_{b12} |
| 381 | Lₐ₃₄₅ | L_{b12} |
| 382 | Lₐ₃₄₉ | L_{b12} |
| 383 | Lₐ₃₅₃ | L_{b12} |
| 384 | Lₐ₃₅₅ | L_{b12} |
| 385 | Lₐ₃₅₇ | L_{b12} |
| 386 | Lₐ₃₅₉ | L_{b12} |
| 387 | Lₐ₃₆₁ | L_{b12} |
| 388 | Lₐ₃₆₃ | L_{b12} |
| 389 | Lₐ₃₆₅ | L_{b12} |
| 390 | Lₐ₃₆₇ | L_{b12} |
| 391 | Lₐ₃₆₈ | L_{b12} |
| 392 | Lₐ₃₆₉ | L_{b12} |
| 393 | Lₐ₃₉₀ | L_{b12} |
| 394 | Lₐ₃₉₉ | L_{b12} |
| 395 | Lₐ₄₀₀ | L_{b12} |
| 396 | Lₐ₄₀₂ | L_{b12} |
| 397 | Lₐ₄₁₈ | L_{b12} |
| 398 | Lₐ₄₂₂ | L_{b12} |
| 399 | Lₐ₄₂₇ | L_{b12} |
| 400 | Lₐ₄₃₁ | L_{b12} |
| 401 | Lₐ₄₃₃ | L_{b12} |
| 402 | Lₐ₄₃₅ | L_{b12} |
| 403 | Lₐ₄₄₆ | L_{b12} |
| 404 | Lₐ₄₅₀ | L_{b12} |
| 405 | Lₐ₄₅₄ | L_{b12} |
| 406 | Lₐ₄₅₆ | L_{b12} |
| 407 | Lₐ₄₆₂ | L_{b12} |
| 408 | Lₐ₄₆₇ | L_{b12} |
| 409 | Lₐ₄₇₂ | L_{b12} |
| 410 | Lₐ₄₇₆ | L_{b12} |
| 411 | Lₐ₄₈₀ | L_{b12} |
| 412 | Lₐ₄₈₄ | L_{b12} |
| 413 | Lₐ₄₈₉ | L_{b12} |
| 414 | Lₐ₄₉₃ | L_{b12} |
| 415 | Lₐ₄₉₅ | L_{b12} |
| 416 | Lₐ₄₉₇ | L_{b12} |
| 417 | Lₐ₄₉₈ | L_{b12} |
| 418 | Lₐ₄₉₉ | L_{b12} |
| 419 | Lₐ₅₀₀ | L_{b12} |
| 420 | Lₐ₅₀₁ | L_{b12} |
| 421 | Lₐ₅₁₁ | L_{b12} |
| 422 | Lₐ₅₁₅ | L_{b12} |
| 423 | Lₐ₅₁₇ | L_{b12} |
| 424 | Lₐ₅₁₉ | L_{b12} |
| 425 | Lₐ₅₂₁ | L_{b12} |
| 426 | Lₐ₅₂₃ | L_{b12} |
| 427 | Lₐ₅₄₄ | L_{b12} |
| 428 | Lₐ₅₄₈ | L_{b12} |
| 429 | Lₐ₅₅₀ | L_{b12} |
| 430 | Lₐ₅₅₂ | L_{b12} |
| 431 | Lₐ₅₅₆ | L_{b12} |
| 432 | Lₐ₅₆₀ | L_{b12} |
| 433 | Lₐ₅₆₄ | L_{b12} |
| 434 | Lₐ₅₆₈ | L_{b12} |
| 435 | Lₐ₅₇₆ | L_{b12} |
| 436 | Lₐ₅₇₇ | L_{b12} |
| 437 | Lₐ₅₈₀ | L_{b12} |
| 438 | Lₐ₅₈₃ | L_{b12} |
| 439 | Lₐ₅₈₆ | L_{b12} |
| 440 | Lₐ₅₉₀ | L_{b12} |
| 441 | Lₐ₅₉₁ | L_{b12} |
| 442 | Lₐ₅₉₄ | L_{b12} |
| 443 | Lₐ₆₀₁ | L_{b12} |
| 444 | Lₐ₆₀₂ | L_{b12} |
| 445 | Lₐ₆₀₅ | L_{b12} |
| 446 | Lₐ₆₁₀ | L_{b12} |
| 447 | Lₐ₆₁₁ | L_{b12} |
| 448 | Lₐ₆₁₂ | L_{b12} |
| 449 | Lₐ₆₂₂ | L_{b12} |
| 450 | Lₐ₆₂₆ | L_{b12} |
| 451 | Lₐ₁ | L_{b79} |
| 452 | Lₐ₇ | L_{b79} |
| 453 | Lₐ₈ | L_{b79} |
| 454 | Lₐ₉ | L_{b79} |
| 455 | Lₐ₁₀ | L_{b79} |
| 456 | Lₐ₁₁ | L_{b79} |
| 457 | Lₐ₁₂ | L_{b79} |
| 458 | Lₐ₂₀ | L_{b79} |
| 459 | Lₐ₄₀ | L_{b79} |
| 460 | Lₐ₄₃ | L_{b79} |
| 461 | Lₐ₄₉ | L_{b79} |
| 462 | Lₐ₅₀ | L_{b79} |
| 463 | Lₐ₅₁ | L_{b79} |
| 464 | Lₐ₅₂ | L_{b79} |
| 465 | Lₐ₅₃ | L_{b79} |
| 466 | Lₐ₅₄ | L_{b79} |
| 467 | Lₐ₆₁ | L_{b79} |
| 468 | Lₐ₆₉ | L_{b79} |
| 469 | Lₐ₇₄ | L_{b79} |
| 470 | Lₐ₇₇ | L_{b79} |
| 471 | Lₐ₇₈ | L_{b79} |
| 472 | Lₐ₇₉ | L_{b79} |
| 473 | Lₐ₈₃ | L_{b79} |
| 474 | Lₐ₈₅ | L_{b79} |
| 475 | Lₐ₉₁ | L_{b79} |
| 476 | Lₐ₁₀₀ | L_{b79} |
| 477 | Lₐ₁₀₃ | L_{b79} |
| 478 | Lₐ₁₀₅ | L_{b79} |
| 479 | Lₐ₁₀₉ | L_{b79} |
| 480 | Lₐ₁₁₃ | L_{b79} |
| 481 | Lₐ₁₁₇ | L_{b79} |
| 482 | Lₐ₁₂₀ | L_{b79} |
| 483 | Lₐ₁₂₃ | L_{b79} |
| 484 | Lₐ₁₂₆ | L_{b79} |
| 485 | Lₐ₁₃₃ | L_{b79} |
| 486 | Lₐ₁₃₈ | L_{b79} |
| 487 | Lₐ₁₄₃ | L_{b79} |
| 488 | Lₐ₁₄₈ | L_{b79} |
| 489 | Lₐ₁₅₁ | L_{b79} |
| 490 | Lₐ₁₅₃ | L_{b79} |
| 491 | Lₐ₁₅₅ | L_{b79} |
| 492 | Lₐ₁₅₇ | L_{b79} |
| 493 | Lₐ₁₅₉ | L_{b79} |
| 494 | Lₐ₁₆₁ | L_{b79} |
| 495 | Lₐ₁₆₃ | L_{b79} |
| 496 | Lₐ₁₆₈ | L_{b79} |
| 497 | Lₐ₁₇₃ | L_{b79} |
| 498 | Lₐ₁₇₇ | L_{b79} |
| 499 | Lₐ₁₈₁ | L_{b79} |
| 500 | Lₐ₁₈₃ | L_{b79} |
| 501 | Lₐ₁₈₅ | L_{b79} |
| 502 | Lₐ₁₈₇ | L_{b79} |
| 503 | Lₐ₁₉₀ | L_{b79} |
| 504 | Lₐ₁₉₂ | L_{b79} |
| 505 | Lₐ₁₉₄ | L_{b79} |
| 506 | Lₐ₁₉₅ | L_{b79} |
| 507 | Lₐ₁₉₆ | L_{b79} |
| 508 | Lₐ₂₀₁ | L_{b79} |
| 509 | Lₐ₂₀₂ | L_{b79} |
| 510 | Lₐ₂₀₃ | L_{b79} |
| 511 | Lₐ₂₀₄ | L_{b79} |
| 512 | Lₐ₂₁₁ | L_{b79} |
| 513 | Lₐ₂₁₆ | L_{b79} |
| 514 | Lₐ₂₂₆ | L_{b79} |
| 515 | Lₐ₂₂₇ | L_{b79} |
| 516 | Lₐ₂₄₀ | L_{b79} |
| 517 | Lₐ₂₄₁ | L_{b79} |
| 518 | Lₐ₂₄₂ | L_{b79} |
| 519 | Lₐ₂₄₃ | L_{b79} |
| 520 | Lₐ₂₄₄ | L_{b79} |
| 521 | Lₐ₂₅₈ | L_{b79} |
| 522 | Lₐ₂₆₉ | L_{b79} |
| 523 | Lₐ₂₇₄ | L_{b79} |
| 524 | Lₐ₂₇₅ | L_{b79} |
| 525 | Lₐ₃₁₁ | L_{b79} |
| 526 | Lₐ₃₁₇ | L_{b79} |
| 527 | Lₐ₃₂₃ | L_{b79} |
| 528 | Lₐ₃₂₈ | L_{b79} |
| 529 | Lₐ₃₃₂ | L_{b79} |
| 530 | Lₐ₃₄₁ | L_{b79} |
| 531 | Lₐ₃₄₅ | L_{b79} |
| 532 | Lₐ₃₄₉ | L_{b79} |
| 533 | Lₐ₃₅₃ | L_{b79} |
| 534 | Lₐ₃₅₅ | L_{b79} |
| 535 | Lₐ₃₅₇ | L_{b79} |
| 536 | Lₐ₃₅₉ | L_{b79} |
| 537 | Lₐ₃₆₁ | L_{b79} |
| 538 | Lₐ₃₆₃ | L_{b79} |
| 539 | Lₐ₃₆₅ | L_{b79} |
| 540 | Lₐ₃₆₇ | L_{b79} |
| 541 | Lₐ₃₆₈ | L_{b79} |
| 542 | Lₐ₃₆₉ | L_{b79} |
| 543 | Lₐ₃₉₀ | L_{b79} |
| 544 | Lₐ₃₉₉ | L_{b79} |
| 545 | Lₐ₄₀₀ | L_{b79} |
| 546 | Lₐ₄₀₂ | L_{b79} |
| 547 | Lₐ₄₁₈ | L_{b79} |
| 548 | Lₐ₄₂₂ | L_{b79} |
| 549 | Lₐ₄₂₇ | L_{b79} |
| 550 | Lₐ₄₃₁ | L_{b79} |
| 551 | Lₐ₄₃₃ | L_{b79} |
| 552 | Lₐ₄₃₅ | L_{b79} |
| 553 | Lₐ₄₄₆ | L_{b79} |
| 554 | Lₐ₄₅₀ | L_{b79} |
| 555 | Lₐ₄₅₄ | L_{b79} |
| 556 | Lₐ₄₅₆ | L_{b79} |
| 557 | Lₐ₄₆₂ | L_{b79} |
| 558 | Lₐ₄₆₇ | L_{b79} |
| 559 | Lₐ₄₇₂ | L_{b79} |
| 560 | Lₐ₄₇₆ | L_{b79} |
| 561 | Lₐ₄₈₀ | L_{b79} |
| 562 | Lₐ₄₈₄ | L_{b79} |
| 563 | Lₐ₄₈₉ | L_{b79} |
| 564 | Lₐ₄₉₃ | L_{b79} |
| 565 | Lₐ₄₉₅ | L_{b79} |
| 566 | Lₐ₄₉₇ | L_{b79} |
| 567 | Lₐ₄₉₈ | L_{b79} |
| 568 | Lₐ₄₉₉ | L_{b79} |
| 569 | Lₐ₅₀₀ | L_{b79} |
| 570 | Lₐ₅₀₁ | L_{b79} |
| 571 | Lₐ₅₁₁ | L_{b79} |
| 572 | Lₐ₅₁₅ | L_{b79} |
| 573 | Lₐ₅₁₇ | L_{b79} |
| 574 | Lₐ₅₁₉ | L_{b79} |
| 575 | Lₐ₅₂₁ | L_{b79} |
| 576 | Lₐ₅₂₃ | L_{b79} |
| 577 | Lₐ₅₄₄ | L_{b79} |
| 578 | Lₐ₅₄₈ | L_{b79} |
| 579 | Lₐ₅₅₀ | L_{b79} |
| 580 | Lₐ₅₅₂ | L_{b79} |
| 581 | Lₐ₅₅₆ | L_{b79} |
| 582 | Lₐ₅₆₀ | L_{b79} |
| 583 | Lₐ₅₆₄ | L_{b79} |
| 584 | Lₐ₅₆₈ | L_{b79} |
| 585 | Lₐ₅₇₆ | L_{b79} |
| 586 | Lₐ₅₇₇ | L_{b79} |
| 587 | Lₐ₅₈₀ | L_{b79} |
| 588 | Lₐ₅₈₃ | L_{b79} |
| 589 | Lₐ₅₈₆ | L_{b79} |
| 590 | Lₐ₅₉₀ | L_{b79} |
| 591 | Lₐ₅₉₁ | L_{b79} |
| 592 | Lₐ₅₉₄ | L_{b79} |
| 593 | Lₐ₆₀₁ | L_{b79} |
| 594 | Lₐ₆₀₂ | L_{b79} |
| 595 | Lₐ₆₀₅ | L_{b79} |
| 596 | Lₐ₆₁₀ | L_{b79} |
| 597 | Lₐ₆₁₁ | L_{b79} |
| 598 | Lₐ₆₁₂ | L_{b79} |
| 599 | Lₐ₆₂₂ | L_{b79} |
| 600 | Lₐ₆₂₆ | L_{b79} |
| 601 | Lₐ₁ | L_{b81} |
| 602 | Lₐ₇ | L_{b81} |
| 603 | Lₐ₈ | L_{b81} |
| 604 | Lₐ₉ | L_{b81} |
| 605 | Lₐ₁₀ | L_{b81} |
| 606 | Lₐ₁₁ | L_{b81} |
| 607 | Lₐ₁₂ | L_{b81} |
| 608 | Lₐ₂₀ | L_{b81} |
| 609 | Lₐ₄₀ | L_{b81} |
| 610 | Lₐ₄₃ | L_{b81} |
| 611 | Lₐ₄₉ | L_{b81} |
| 612 | Lₐ₅₀ | L_{b81} |
| 613 | Lₐ₅₁ | L_{b81} |
| 614 | Lₐ₅₂ | L_{b81} |
| 615 | Lₐ₅₃ | L_{b81} |
| 616 | Lₐ₅₄ | L_{b81} |
| 617 | Lₐ₆₁ | L_{b81} |
| 618 | Lₐ₆₉ | L_{b81} |
| 619 | Lₐ₇₄ | L_{b81} |
| 620 | Lₐ₇₇ | L_{b81} |
| 621 | Lₐ₇₈ | L_{b81} |
| 622 | Lₐ₇₉ | L_{b81} |
| 623 | Lₐ₈₃ | L_{b81} |
| 624 | Lₐ₈₅ | L_{b81} |
| 625 | Lₐ₉₁ | L_{b81} |
| 626 | Lₐ₁₀₀ | L_{b81} |
| 627 | Lₐ₁₀₃ | L_{b81} |
| 628 | Lₐ₁₀₅ | L_{b81} |
| 629 | Lₐ₁₀₉ | L_{b81} |
| 630 | Lₐ₁₁₃ | L_{b81} |
| 631 | Lₐ₁₁₇ | L_{b81} |
| 632 | Lₐ₁₂₀ | L_{b81} |
| 633 | Lₐ₁₂₃ | L_{b81} |
| 634 | Lₐ₁₂₆ | L_{b81} |
| 635 | Lₐ₁₃₃ | L_{b81} |
| 636 | Lₐ₁₃₈ | L_{b81} |
| 637 | Lₐ₁₄₃ | L_{b81} |
| 638 | Lₐ₁₄₈ | L_{b81} |
| 639 | Lₐ₁₅₁ | L_{b81} |
| 640 | Lₐ₁₅₃ | L_{b81} |
| 641 | Lₐ₁₅₅ | L_{b81} |
| 642 | Lₐ₁₅₇ | L_{b81} |
| 643 | Lₐ₁₅₉ | L_{b81} |
| 644 | Lₐ₁₆₁ | L_{b81} |
| 645 | Lₐ₁₆₃ | L_{b81} |
| 646 | Lₐ₁₆₈ | L_{b81} |
| 647 | Lₐ₁₇₃ | L_{b81} |
| 648 | Lₐ₁₇₇ | L_{b81} |
| 649 | Lₐ₁₈₁ | L_{b81} |
| 650 | Lₐ₁₈₃ | L_{b81} |
| 651 | Lₐ₁₈₅ | L_{b81} |
| 652 | Lₐ₁₈₇ | L_{b81} |
| 653 | Lₐ₁₉₀ | L_{b81} |
| 654 | Lₐ₁₉₂ | L_{b81} |
| 655 | Lₐ₁₉₄ | L_{b81} |
| 656 | Lₐ₁₉₅ | L_{b81} |
| 657 | Lₐ₁₉₆ | L_{b81} |
| 658 | Lₐ₂₀₁ | L_{b81} |
| 659 | Lₐ₂₀₂ | L_{b81} |
| 660 | Lₐ₂₀₃ | L_{b81} |
| 661 | Lₐ₂₀₄ | L_{b81} |
| 662 | Lₐ₂₁₁ | L_{b81} |
| 663 | Lₐ₂₁₆ | L_{b81} |
| 664 | Lₐ₂₂₆ | L_{b81} |
| 666 | Lₐ₂₄₀ | L_{b81} |
| 667 | Lₐ₂₄₁ | L_{b81} |
| 668 | Lₐ₂₄₂ | L_{b81} |
| 669 | Lₐ₂₄₃ | L_{b81} |
| 670 | Lₐ₂₄₄ | L_{b81} |
| 671 | Lₐ₂₅₈ | L_{b81} |
| 672 | Lₐ₂₆₉ | L_{b81} |
| 673 | Lₐ₂₇₄ | L_{b81} |
| 674 | Lₐ₂₇₅ | L_{b81} |
| 675 | Lₐ₃₁₁ | L_{b81} |
| 676 | Lₐ₃₁₇ | L_{b81} |
| 677 | Lₐ₃₂₃ | L_{b81} |
| 678 | Lₐ₃₂₈ | L_{b81} |
| 679 | Lₐ₃₃₂ | L_{b81} |
| 680 | Lₐ₃₄₁ | L_{b81} |
| 681 | Lₐ₃₄₅ | L_{b81} |
| 682 | Lₐ₃₄₉ | L_{b81} |
| 683 | Lₐ₃₅₃ | L_{b81} |
| 684 | Lₐ₃₅₅ | L_{b81} |
| 685 | Lₐ₃₅₇ | L_{b81} |
| 686 | Lₐ₃₅₉ | L_{b81} |
| 687 | Lₐ₃₆₁ | L_{b81} |
| 688 | Lₐ₃₆₃ | L_{b81} |
| 689 | Lₐ₃₆₅ | L_{b81} |
| 690 | Lₐ₃₆₇ | L_{b81} |
| 691 | Lₐ₃₆₈ | L_{b81} |
| 692 | Lₐ₃₆₉ | L_{b81} |
| 693 | Lₐ₃₉₀ | L_{b81} |
| 694 | Lₐ₃₉₉ | L_{b81} |
| 695 | Lₐ₄₀₀ | L_{b81} |
| 696 | Lₐ₄₀₂ | L_{b81} |
| 697 | Lₐ₄₁₈ | L_{b81} |
| 698 | Lₐ₄₂₂ | L_{b81} |
| 699 | Lₐ₄₂₇ | L_{b81} |
| 700 | Lₐ₄₃₁ | L_{b81} |
| 701 | Lₐ₄₃₃ | L_{b81} |
| 702 | Lₐ₄₃₅ | L_{b81} |
| 703 | Lₐ₄₄₆ | L_{b81} |
| 704 | Lₐ₄₅₀ | L_{b81} |
| 705 | Lₐ₄₅₄ | L_{b81} |
| 706 | Lₐ₄₅₆ | L_{b81} |
| 707 | Lₐ₄₆₂ | L_{b81} |
| 708 | Lₐ₄₆₇ | L_{b81} |
| 709 | Lₐ₄₇₂ | L_{b81} |
| 710 | Lₐ₄₇₆ | L_{b81} |
| 711 | Lₐ₄₈₀ | L_{b81} |
| 712 | Lₐ₄₈₄ | L_{b81} |
| 713 | Lₐ₄₈₉ | L_{b81} |
| 714 | Lₐ₄₉₃ | L_{b81} |
| 715 | Lₐ₄₉₅ | L_{b81} |
| 716 | Lₐ₄₉₇ | L_{b81} |
| 717 | Lₐ₄₉₈ | L_{b81} |
| 718 | Lₐ₄₉₉ | L_{b81} |
| 719 | Lₐ₅₀₀ | L_{b81} |
| 720 | Lₐ₅₀₁ | L_{b81} |
| 721 | Lₐ₅₁₁ | L_{b81} |
| 722 | Lₐ₅₁₅ | L_{b81} |
| 723 | Lₐ₅₁₇ | L_{b81} |
| 724 | Lₐ₅₁₉ | L_{b81} |
| 725 | Lₐ₅₂₁ | L_{b81} |
| 726 | Lₐ₅₂₃ | L_{b81} |
| 727 | Lₐ₅₄₄ | L_{b81} |
| 728 | Lₐ₅₄₈ | L_{b81} |
| 729 | Lₐ₅₅₀ | L_{b81} |
| 730 | Lₐ₅₅₂ | L_{b81} |
| 731 | Lₐ₅₅₆ | L_{b81} |
| 732 | Lₐ₅₆₀ | L_{b81} |
| 733 | Lₐ₅₆₄ | L_{b81} |
| 734 | Lₐ₅₆₈ | L_{b81} |
| 735 | Lₐ₅₇₆ | L_{b81} |
| 736 | Lₐ₅₇₇ | L_{b81} |
| 737 | Lₐ₅₈₀ | L_{b81} |
| 738 | Lₐ₅₈₃ | L_{b81} |
| 739 | Lₐ₅₈₆ | L_{b81} |
| 740 | Lₐ₅₉₀ | L_{b81} |
| 741 | Lₐ₅₉₁ | L_{b81} |
| 742 | Lₐ₅₉₄ | L_{b81} |
| 743 | Lₐ₆₀₁ | L_{b81} |
| 744 | Lₐ₆₀₂ | L_{b81} |
| 745 | Lₐ₆₀₅ | L_{b81} |
| 746 | Lₐ₆₁₀ | L_{b81} |
| 747 | Lₐ₆₁₁ | L_{b81} |
| 748 | Lₐ₆₁₂ | L_{b81} |
| 749 | Lₐ₆₂₂ | L_{b81} |
| 750 | Lₐ₆₂₆ | L_{b81} |
| 751 | Lₐ₁ | L_{b83} |
| 752 | Lₐ₇ | L_{b83} |
| 753 | Lₐ₈ | L_{b83} |
| 754 | Lₐ₉ | L_{b83} |
| 755 | Lₐ₁₀ | L_{b83} |
| 756 | Lₐ₁₁ | L_{b83} |
| 757 | Lₐ₁₂ | L_{b83} |
| 758 | Lₐ₂₀ | L_{b83} |
| 759 | Lₐ₄₀ | L_{b83} |
| 760 | Lₐ₄₃ | L_{b83} |
| 761 | Lₐ₄₉ | L_{b83} |
| 762 | Lₐ₅₀ | L_{b83} |
| 763 | Lₐ₅₁ | L_{b83} |
| 764 | Lₐ₅₂ | L_{b83} |
| 765 | Lₐ₅₃ | L_{b83} |
| 766 | Lₐ₅₄ | L_{b83} |
| 767 | Lₐ₆₁ | L_{b83} |
| 768 | Lₐ₆₉ | L_{b83} |
| 769 | Lₐ₇₄ | L_{b83} |
| 770 | Lₐ₇₇ | L_{b83} |
| 771 | Lₐ₇₈ | L_{b83} |
| 772 | Lₐ₇₉ | L_{b83} |
| 773 | Lₐ₈₃ | L_{b83} |
| 774 | Lₐ₈₅ | L_{b83} |
| 775 | Lₐ₉₁ | L_{b83} |
| 776 | Lₐ₁₀₀ | L_{b83} |
| 777 | Lₐ₁₀₃ | L_{b83} |
| 778 | Lₐ₁₀₅ | L_{b83} |
| 779 | Lₐ₁₀₉ | L_{b83} |
| 780 | Lₐ₁₁₃ | L_{b83} |
| 781 | Lₐ₁₁₇ | L_{b83} |
| 782 | Lₐ₁₂₀ | L_{b83} |
| 783 | Lₐ₁₂₃ | L_{b83} |
| 784 | Lₐ₁₂₆ | L_{b83} |
| 785 | Lₐ₁₃₃ | L_{b83} |
| 786 | Lₐ₁₃₈ | L_{b83} |
| 787 | Lₐ₁₄₃ | L_{b83} |
| 788 | Lₐ₁₄₈ | L_{b83} |
| 789 | Lₐ₁₅₁ | L_{b83} |
| 790 | Lₐ₁₅₃ | L_{b83} |
| 791 | Lₐ₁₅₅ | L_{b83} |
| 792 | Lₐ₁₅₇ | L_{b83} |
| 793 | Lₐ₁₅₉ | L_{b83} |
| 794 | Lₐ₁₆₁ | L_{b83} |
| 795 | Lₐ₁₆₃ | L_{b83} |
| 796 | Lₐ₁₆₈ | L_{b83} |
| 797 | Lₐ₁₇₃ | L_{b83} |
| 798 | Lₐ₁₆₉ | L_{b83} |
| 799 | Lₐ₁₈₁ | L_{b83} |
| 800 | Lₐ₁₈₃ | L_{b83} |
| 801 | Lₐ₁₈₅ | L_{b83} |
| 802 | Lₐ₁₈₇ | L_{b83} |
| 803 | Lₐ₁₉₀ | L_{b83} |
| 804 | Lₐ₁₉₂ | L_{b83} |
| 805 | Lₐ₁₉₄ | L_{b83} |
| 806 | Lₐ₁₉₅ | L_{b83} |
| 807 | Lₐ₁₉₆ | L_{b83} |
| 808 | Lₐ₂₀₁ | L_{b83} |
| 809 | Lₐ₂₀₂ | L_{b83} |
| 810 | Lₐ₂₀₃ | L_{b83} |
| 811 | Lₐ₂₀₄ | L_{b83} |
| 812 | Lₐ₂₁₁ | L_{b83} |
| 813 | Lₐ₂₁₆ | L_{b83} |
| 814 | Lₐ₂₂₆ | L_{b83} |
| 815 | Lₐ₂₂₇ | L_{b83} |
| 816 | Lₐ₂₄₀ | L_{b83} |
| 817 | Lₐ₂₄₁ | L_{b83} |
| 818 | Lₐ₂₄₂ | L_{b83} |
| 819 | Lₐ₂₄₃ | L_{b83} |
| 820 | Lₐ₂₄₄ | L_{b83} |
| 821 | Lₐ₂₅₈ | L_{b83} |
| 822 | Lₐ₂₆₉ | L_{b83} |
| 823 | Lₐ₂₇₄ | L_{b83} |
| 824 | Lₐ₂₇₅ | L_{b83} |
| 825 | Lₐ₃₁₁ | L_{b83} |
| 826 | Lₐ₃₁₇ | L_{b83} |
| 827 | Lₐ₃₂₃ | L_{b83} |
| 828 | Lₐ₃₂₈ | L_{b83} |
| 829 | Lₐ₃₃₂ | L_{b83} |
| 830 | Lₐ₃₄₁ | L_{b83} |
| 831 | Lₐ₃₄₅ | L_{b83} |
| 832 | Lₐ₃₄₉ | L_{b83} |
| 833 | Lₐ₃₅₃ | L_{b83} |
| 834 | Lₐ₃₅₅ | L_{b83} |
| 835 | Lₐ₃₅₇ | L_{b83} |
| 836 | Lₐ₃₅₉ | L_{b83} |
| 837 | Lₐ₃₆₁ | L_{b83} |
| 838 | Lₐ₃₆₃ | L_{b83} |
| 839 | Lₐ₃₆₅ | L_{b83} |
| 840 | Lₐ₃₆₇ | L_{b83} |
| 841 | Lₐ₃₆₈ | L_{b83} |
| 842 | Lₐ₃₆₉ | L_{b83} |
| 843 | Lₐ₃₉₀ | L_{b83} |
| 844 | Lₐ₃₉₉ | L_{b83} |
| 845 | Lₐ₄₀₀ | L_{b83} |
| 846 | Lₐ₄₀₂ | L_{b83} |
| 847 | Lₐ₄₁₈ | L_{b83} |
| 848 | Lₐ₄₂₂ | L_{b83} |
| 849 | Lₐ₄₂₇ | L_{b83} |
| 850 | Lₐ₄₃₁ | L_{b83} |
| 851 | Lₐ₄₃₃ | L_{b83} |
| 852 | Lₐ₄₃₅ | L_{b83} |
| 853 | Lₐ₄₄₆ | L_{b83} |
| 854 | Lₐ₄₅₀ | L_{b83} |
| 855 | Lₐ₄₅₄ | L_{b83} |
| 856 | Lₐ₄₅₆ | L_{b83} |
| 857 | Lₐ₄₆₂ | L_{b83} |
| 858 | Lₐ₄₆₇ | L_{b83} |
| 859 | Lₐ₄₇₂ | L_{b83} |
| 860 | Lₐ₄₇₆ | L_{b83} |
| 861 | Lₐ₄₈₀ | L_{b83} |
| 862 | Lₐ₄₈₄ | L_{b83} |
| 863 | Lₐ₄₈₉ | L_{b83} |
| 864 | Lₐ₄₉₃ | L_{b83} |
| 865 | Lₐ₄₉₅ | L_{b83} |
| 866 | Lₐ₄₉₇ | L_{b83} |
| 867 | Lₐ₄₉₈ | L_{b83} |
| 868 | Lₐ₄₉₉ | L_{b83} |
| 869 | Lₐ₅₀₀ | L_{b83} |
| 870 | Lₐ₅₀₁ | L_{b83} |
| 871 | Lₐ₅₁₁ | L_{b83} |
| 872 | Lₐ₅₁₅ | L_{b83} |
| 873 | Lₐ₅₁₇ | L_{b83} |
| 874 | Lₐ₅₁₉ | L_{b83} |
| 875 | Lₐ₅₂₁ | L_{b83} |
| 876 | Lₐ₅₂₃ | L_{b83} |
| 877 | Lₐ₅₄₄ | L_{b83} |
| 878 | Lₐ₅₄₈ | L_{b83} |
| 879 | Lₐ₅₅₀ | L_{b83} |
| 880 | Lₐ₅₅₂ | L_{b83} |
| 881 | Lₐ₅₅₆ | L_{b83} |
| 882 | Lₐ₅₆₀ | L_{b83} |
| 883 | Lₐ₅₆₄ | L_{b83} |
| 884 | Lₐ₅₆₈ | L_{b83} |
| 885 | Lₐ₅₇₆ | L_{b83} |
| 886 | Lₐ₅₇₇ | L_{b83} |
| 887 | Lₐ₅₈₀ | L_{b83} |
| 888 | Lₐ₅₈₃ | L_{b83} |
| 889 | Lₐ₅₈₆ | L_{b83} |
| 890 | Lₐ₅₉₀ | L_{b83} |
| 891 | Lₐ₅₉₁ | L_{b83} |
| 892 | Lₐ₅₉₄ | L_{b83} |
| 893 | Lₐ₆₀₁ | L_{b83} |
| 894 | Lₐ₆₀₂ | L_{b83} |
| 895 | Lₐ₆₀₅ | L_{b83} |
| 896 | Lₐ₆₁₀ | L_{b83} |
| 897 | Lₐ₆₁₁ | L_{b83} |
| 898 | Lₐ₆₁₂ | L_{b83} |
| 899 | Lₐ₆₂₂ | L_{b83} |
| 900 | Lₐ₆₂₆ | L_{b83} |
| 901 | Lₐ₆₃₁ | L_{b81} |
| 902 | Lₐ₆₃₂ | L_{b81} |
| 903 | Lₐ₆₃₃ | L_{b81} |
| 904 | Lₐ₆₄₀ | L_{b81} |
| 905 | Lₐ₆₄₁ | L_{b81} |
| 906 | Lₐ₆₄₂ | L_{b81} |
| 907 | Lₐ₆₅₂ | L_{b81} |
| 908 | Lₐ₆₅₅ | L_{b81} |
| 909 | Lₐ₆₅₈ | L_{b81} |
| 910 | Lₐ₆₅₉ | L_{b81} |
| 911 | Lₐ₆₆₀ | L_{b81} |
| 912 | Lₐ₆₆₆ | L_{b81} |
| 913 | Lₐ₆₇₆ | L_{b81} |
| 914 | Lₐ₆₇₈ | L_{b81} |
| 915 | Lₐ₆₇₉ | L_{b81} |
| 916 | Lₐ₆₈₁ | L_{b81} |
| 917 | Lₐ₁ | L_{b88} |
| 918 | Lₐ₇ | L_{b88} |
| 919 | Lₐ₈ | L_{b88} |
| 920 | Lₐ₉ | L_{b88} |
| 921 | Lₐ₁₀ | L_{b88} |
| 922 | Lₐ₁₁ | L_{b88} |
| 923 | Lₐ₁₂ | L_{b88} |
| 924 | Lₐ₂₀ | L_{b88} |
| 925 | Lₐ₄₀ | L_{b88} |
| 926 | Lₐ₄₃ | L_{b88} |
| 927 | Lₐ₄₉ | L_{b88} |
| 928 | Lₐ₅₀ | L_{b88} |
| 929 | Lₐ₅₁ | L_{b88} |
| 930 | Lₐ₅₂ | L_{b88} |
| 931 | Lₐ₅₃ | L_{b88} |
| 932 | Lₐ₅₄ | L_{b88} |
| 933 | Lₐ₆₁ | L_{b88} |
| 934 | Lₐ₆₉ | L_{b88} |
| 935 | Lₐ₇₄ | L_{b88} |
| 936 | Lₐ₇₇ | L_{b88} |
| 937 | Lₐ₇₈ | L_{b88} |
| 938 | Lₐ₇₉ | L_{b88} |
| 939 | Lₐ₈₃ | L_{b88} |
| 940 | Lₐ₈₅ | L_{b88} |
| 941 | Lₐ₉₁ | L_{b88} |
| 942 | Lₐ₁₀₀ | L_{b88} |
| 943 | Lₐ₁₀₃ | L_{b88} |
| 944 | Lₐ₁₀₅ | L_{b88} |
| 945 | Lₐ₁₀₉ | L_{b88} |
| 946 | Lₐ₁₁₃ | L_{b88} |
| 947 | Lₐ₁₁₇ | L_{b88} |
| 948 | Lₐ₁₂₀ | L_{b88} |
| 949 | Lₐ₁₂₃ | L_{b88} |
| 950 | Lₐ₁₂₆ | L_{b88} |
| 951 | Lₐ₁₃₃ | L_{b88} |
| 952 | Lₐ₁₃₈ | L_{b88} |
| 953 | Lₐ₁₄₃ | L_{b88} |
| 954 | Lₐ₁₄₈ | L_{b88} |
| 955 | Lₐ₁₅₁ | L_{b88} |
| 956 | Lₐ₁₅₃ | L_{b88} |
| 957 | Lₐ₁₅₅ | L_{b88} |
| 958 | Lₐ₁₅₇ | L_{b88} |
| 959 | Lₐ₁₅₉ | L_{b88} |
| 960 | Lₐ₁₆₁ | L_{b88} |
| 961 | Lₐ₁₆₃ | L_{b88} |
| 962 | Lₐ₁₆₈ | L_{b88} |
| 963 | Lₐ₁₇₃ | L_{b88} |
| 964 | Lₐ₁₇₇ | L_{b88} |
| 965 | Lₐ₁₈₁ | L_{b88} |
| 966 | Lₐ₁₈₃ | L_{b88} |
| 967 | Lₐ₁₈₅ | L_{b88} |
| 968 | Lₐ₁₈₇ | L_{b88} |
| 969 | Lₐ₁₉₀ | L_{b88} |
| 970 | Lₐ₁₉₂ | L_{b88} |
| 971 | Lₐ₁₉₄ | L_{b88} |
| 972 | Lₐ₁₉₅ | L_{b88} |
| 973 | Lₐ₁₉₆ | L_{b88} |
| 974 | Lₐ₂₀₁ | L_{b88} |
| 975 | Lₐ₂₀₂ | L_{b88} |
| 976 | Lₐ₂₀₃ | L_{b88} |
| 977 | Lₐ₂₀₄ | L_{b88} |
| 978 | Lₐ₂₁₁ | L_{b88} |
| 979 | Lₐ₂₁₆ | L_{b88} |
| 980 | Lₐ₂₂₆ | L_{b88} |
| 981 | Lₐ₂₂₇ | L_{b88} |
| 982 | Lₐ₂₄₀ | L_{b88} |
| 983 | Lₐ₂₄₁ | L_{b88} |
| 984 | Lₐ₂₄₂ | L_{b88} |
| 985 | Lₐ₂₄₃ | L_{b88} |
| 986 | Lₐ₂₄₄ | L_{b88} |
| 987 | Lₐ₂₅₈ | L_{b88} |
| 988 | Lₐ₂₆₉ | L_{b88} |
| 989 | Lₐ₂₇₄ | L_{b88} |
| 990 | Lₐ₂₇₅ | L_{b88} |
| 991 | Lₐ₃₁₁ | L_{b88} |
| 992 | Lₐ₃₁₇ | L_{b88} |
| 993 | Lₐ₃₂₃ | L_{b88} |
| 994 | Lₐ₃₂₈ | L_{b88} |
| 995 | Lₐ₃₃₂ | L_{b88} |
| 996 | Lₐ₃₄₁ | L_{b88} |
| 997 | Lₐ₃₄₅ | L_{b88} |
| 998 | Lₐ₃₄₉ | L_{b88} |
| 999 | Lₐ₃₅₃ | L_{b88} |
| 1000 | Lₐ₃₅₅ | L_{b88} |
| 1001 | Lₐ₃₅₇ | L_{b88} |
| 1002 | Lₐ₃₅₉ | L_{b88} |
| 1003 | Lₐ₃₆₁ | L_{b88} |
| 1004 | Lₐ₃₆₃ | L_{b88} |
| 1005 | Lₐ₃₆₅ | L_{b88} |
| 1006 | Lₐ₃₆₇ | L_{b88} |
| 1007 | Lₐ₃₆₈ | L_{b88} |
| 1008 | Lₐ₃₆₉ | L_{b88} |
| 1009 | Lₐ₃₉₀ | L_{b88} |
| 1010 | Lₐ₃₉₉ | L_{b88} |
| 1011 | Lₐ₄₀₀ | L_{b88} |
| 1012 | Lₐ₄₀₂ | L_{b88} |
| 1013 | Lₐ₄₁₈ | L_{b88} |
| 1014 | Lₐ₄₂₂ | L_{b88} |
| 1015 | Lₐ₄₂₇ | L_{b88} |
| 1016 | Lₐ₄₃₁ | L_{b88} |
| 1017 | Lₐ₄₃₃ | L_{b88} |
| 1018 | Lₐ₄₃₅ | L_{b88} |
| 1019 | Lₐ₄₄₆ | L_{b88} |
| 1020 | Lₐ₄₅₀ | L_{b88} |
| 1021 | Lₐ₄₅₄ | L_{b88} |
| 1022 | Lₐ₄₅₆ | L_{b88} |
| 1023 | Lₐ₄₆₂ | L_{b88} |
| 1024 | Lₐ₄₆₇ | L_{b88} |
| 1025 | Lₐ₄₇₂ | L_{b88} |
| 1026 | Lₐ₄₇₆ | L_{b88} |
| 1027 | Lₐ₄₈₀ | L_{b88} |
| 1028 | Lₐ₄₈₄ | L_{b88} |
| 1029 | Lₐ₄₈₉ | L_{b88} |
| 1030 | Lₐ₄₉₃ | L_{b88} |
| 1031 | Lₐ₄₉₅ | L_{b88} |
| 1032 | Lₐ₄₉₇ | L_{b88} |
| 1033 | Lₐ₄₉₈ | L_{b88} |
| 1034 | Lₐ₄₉₉ | L_{b88} |
| 1035 | Lₐ₅₀₀ | L_{b88} |
| 1036 | Lₐ₅₀₁ | L_{b88} |
| 1037 | Lₐ₅₁₁ | L_{b88} |
| 1038 | Lₐ₅₁₅ | L_{b88} |
| 1039 | Lₐ₅₁₇ | L_{b88} |
| 1040 | Lₐ₅₁₉ | L_{b88} |
| 1041 | Lₐ₅₂₁ | L_{b88} |
| 1042 | Lₐ₅₂₃ | L_{b88} |
| 1043 | Lₐ₅₄₄ | L_{b88} |
| 1044 | Lₐ₅₄₈ | L_{b88} |
| 1045 | Lₐ₅₅₀ | L_{b88} |
| 1046 | Lₐ₅₅₂ | L_{b88} |
| 1047 | Lₐ₅₅₆ | L_{b88} |
| 1048 | Lₐ₅₆₀ | L_{b88} |
| 1049 | Lₐ₅₆₄ | L_{b88} |
| 1050 | Lₐ₅₆₈ | L_{b88} |
| 1051 | Lₐ₅₇₆ | L_{b88} |
| 1052 | Lₐ₅₇₇ | L_{b88} |
| 1053 | Lₐ₅₈₀ | L_{b88} |
| 1054 | Lₐ₅₈₃ | L_{b88} |
| 1055 | Lₐ₅₈₆ | L_{b88} |
| 1056 | Lₐ₅₉₀ | L_{b88} |
| 1057 | Lₐ₅₉₁ | L_{b88} |
| 1058 | Lₐ₅₉₄ | L_{b88} |
| 1059 | Lₐ₆₀₁ | L_{b88} |
| 1060 | Lₐ₆₀₂ | L_{b88} |
| 1061 | Lₐ₆₀₅ | L_{b88} |
| 1062 | Lₐ₆₁₀ | L_{b88} |
| 1063 | Lₐ₆₁₁ | L_{b88} |
| 1064 | Lₐ₆₁₂ | L_{b88} |
| 1065 | Lₐ₆₂₂ | L_{b88} |
| 1066 | Lₐ₆₂₆ | L_{b88} |
| 1067 | Lₐ₁ | L_{b94} |
| 1068 | Lₐ₇ | L_{b94} |
| 1069 | Lₐ₈ | L_{b94} |
| 1070 | Lₐ₉ | L_{b94} |
| 1071 | Lₐ₁₀ | L_{b94} |
| 1072 | Lₐ₁₁ | L_{b94} |
| 1073 | Lₐ₁₂ | L_{b94} |
| 1074 | Lₐ₂₀ | L_{b94} |
| 1075 | Lₐ₄₀ | L_{b94} |
| 1076 | Lₐ₄₃ | L_{b94} |
| 1077 | Lₐ₄₉ | L_{b94} |
| 1078 | Lₐ₅₀ | L_{b94} |
| 1079 | Lₐ₅₁ | L_{b94} |
| 1080 | Lₐ₅₂ | L_{b94} |
| 1081 | Lₐ₅₃ | L_{b94} |
| 1082 | Lₐ₅₄ | L_{b94} |
| 1083 | Lₐ₆₁ | L_{b94} |
| 1084 | Lₐ₆₉ | L_{b94} |
| 1085 | Lₐ₇₄ | L_{b94} |
| 1086 | Lₐ₇₇ | L_{b94} |
| 1087 | Lₐ₇₈ | L_{b94} |
| 1088 | Lₐ₇₉ | L_{b94} |
| 1089 | Lₐ₈₃ | L_{b94} |
| 1090 | Lₐ₈₅ | L_{b94} |
| 1091 | Lₐ₉₁ | L_{b94} |
| 1092 | Lₐ₁₀₀ | L_{b94} |
| 1093 | Lₐ₁₀₃ | L_{b94} |
| 1094 | Lₐ₁₀₅ | L_{b94} |
| 1095 | Lₐ₁₀₉ | L_{b94} |
| 1096 | Lₐ₁₁₃ | L_{b94} |
| 1097 | Lₐ₁₁₇ | L_{b94} |
| 1098 | Lₐ₁₂₀ | L_{b94} |
| 1099 | Lₐ₁₂₃ | L_{b94} |
| 1100 | Lₐ₁₂₆ | L_{b94} |
| 1101 | Lₐ₁₃₃ | L_{b94} |
| 1102 | Lₐ₁₃₈ | L_{b94} |
| 1103 | Lₐ₁₄₃ | L_{b94} |
| 1104 | Lₐ₁₄₈ | L_{b94} |
| 1105 | Lₐ₁₅₁ | L_{b94} |
| 1106 | Lₐ₁₅₃ | L_{b94} |
| 1107 | Lₐ₁₅₅ | L_{b94} |
| 1108 | Lₐ₁₅₇ | L_{b94} |
| 1109 | Lₐ₁₅₉ | L_{b94} |
| 1110 | Lₐ₁₆₁ | L_{b94} |
| 1111 | Lₐ₁₆₃ | L_{b94} |
| 1112 | Lₐ₁₆₈ | L_{b94} |
| 1113 | Lₐ₁₇₃ | L_{b94} |
| 1114 | Lₐ₁₇₇ | L_{b94} |
| 1115 | Lₐ₁₈₁ | L_{b94} |
| 1116 | Lₐ₁₈₃ | L_{b94} |
| 1117 | Lₐ₁₈₅ | L_{b94} |
| 1118 | Lₐ₁₈₇ | L_{b94} |
| 1119 | Lₐ₁₉₀ | L_{b94} |
| 1120 | Lₐ₁₉₂ | L_{b94} |
| 1121 | Lₐ₁₉₄ | L_{b94} |
| 1122 | Lₐ₁₉₅ | L_{b94} |
| 1123 | Lₐ₁₉₆ | L_{b94} |
| 1124 | Lₐ₂₀₁ | L_{b94} |
| 1125 | Lₐ₂₀₂ | L_{b94} |
| 1126 | Lₐ₂₀₃ | L_{b94} |
| 1127 | Lₐ₂₀₄ | L_{b94} |
| 1128 | Lₐ₂₁₁ | L_{b94} |
| 1129 | Lₐ₂₁₆ | L_{b94} |
| 1130 | Lₐ₂₂₆ | L_{b94} |
| 1131 | Lₐ₂₂₇ | L_{b94} |
| 1132 | Lₐ₂₄₀ | L_{b94} |
| 1133 | Lₐ₂₄₁ | L_{b94} |
| 1134 | Lₐ₂₄₂ | L_{b94} |
| 1135 | Lₐ₂₄₃ | L_{b94} |
| 1136 | Lₐ₂₄₄ | L_{b94} |
| 1137 | Lₐ₂₅₈ | L_{b94} |
| 1138 | Lₐ₂₆₉ | L_{b94} |
| 1139 | Lₐ₂₇₄ | L_{b94} |
| 1140 | Lₐ₂₇₅ | L_{b94} |
| 1141 | Lₐ₃₁₁ | L_{b94} |
| 1142 | Lₐ₃₁₇ | L_{b94} |
| 1143 | Lₐ₃₂₃ | L_{b94} |
| 1144 | Lₐ₃₂₈ | L_{b94} |
| 1145 | Lₐ₃₃₂ | L_{b94} |
| 1146 | Lₐ₃₄₁ | L_{b94} |
| 1147 | Lₐ₃₄₅ | L_{b94} |
| 1148 | Lₐ₃₄₉ | L_{b94} |
| 1149 | Lₐ₃₅₃ | L_{b94} |
| 1150 | Lₐ₃₅₅ | L_{b94} |
| 1151 | Lₐ₃₅₇ | L_{b94} |
| 1152 | Lₐ₃₅₉ | L_{b94} |
| 1153 | Lₐ₃₆₁ | L_{b94} |
| 1154 | Lₐ₃₆₃ | L_{b94} |
| 1155 | Lₐ₃₆₅ | L_{b94} |
| 1156 | Lₐ₃₆₇ | L_{b94} |
| 1157 | Lₐ₃₆₈ | L_{b94} |
| 1158 | Lₐ₃₆₉ | L_{b94} |
| 1159 | Lₐ₃₉₀ | L_{b94} |
| 1160 | Lₐ₃₉₉ | L_{b94} |
| 1161 | Lₐ₄₀₀ | L_{b94} |
| 1162 | Lₐ₄₀₂ | L_{b94} |
| 1163 | Lₐ₄₁₈ | L_{b94} |
| 1164 | Lₐ₄₂₂ | L_{b94} |
| 1165 | Lₐ₄₂₇ | L_{b94} |
| 1166 | Lₐ₄₃₁ | L_{b94} |
| 1167 | Lₐ₄₃₃ | L_{b94} |
| 1168 | Lₐ₄₃₅ | L_{b94} |
| 1169 | Lₐ₄₄₆ | L_{b94} |
| 1170 | Lₐ₄₅₀ | L_{b94} |
| 1171 | Lₐ₄₅₄ | L_{b94} |
| 1172 | Lₐ₄₅₆ | L_{b94} |
| 1173 | Lₐ₄₆₂ | L_{b94} |
| 1174 | Lₐ₄₆₇ | L_{b94} |
| 1175 | Lₐ₄₇₂ | L_{b94} |
| 1176 | Lₐ₄₇₆ | L_{b94} |
| 1177 | Lₐ₄₈₀ | L_{b94} |
| 1178 | Lₐ₄₈₄ | L_{b94} |
| 1179 | Lₐ₄₈₉ | L_{b94} |
| 1180 | Lₐ₄₉₃ | L_{b94} |
| 1181 | Lₐ₄₉₅ | L_{b94} |
| 1182 | Lₐ₄₉₇ | L_{b94} |
| 1183 | Lₐ₄₉₈ | L_{b94} |
| 1184 | Lₐ₄₉₉ | L_{b94} |
| 1185 | Lₐ₅₀₀ | L_{b94} |
| 1186 | Lₐ₅₀₁ | L_{b94} |
| 1187 | Lₐ₅₁₁ | L_{b94} |
| 1188 | Lₐ₅₁₅ | L_{b94} |
| 1189 | Lₐ₅₁₇ | L_{b94} |
| 1190 | Lₐ₅₁₉ | L_{b94} |
| 1191 | Lₐ₅₂₁ | L_{b94} |
| 1192 | Lₐ₅₂₃ | L_{b94} |
| 1193 | Lₐ₅₄₄ | L_{b94} |
| 1194 | Lₐ₅₄₈ | L_{b94} |
| 1195 | Lₐ₅₅₀ | L_{b94} |
| 1196 | Lₐ₅₅₂ | L_{b94} |
| 1197 | Lₐ₅₅₆ | L_{b94} |
| 1198 | Lₐ₅₆₀ | L_{b94} |
| 1199 | Lₐ₅₆₄ | L_{b94} |
| 1200 | Lₐ₅₆₈ | L_{b94} |
| 1201 | Lₐ₅₇₆ | L_{b94} |
| 1202 | Lₐ₅₇₇ | L_{b94} |
| 1203 | Lₐ₅₈₀ | L_{b94} |
| 1204 | Lₐ₅₈₃ | L_{b94} |
| 1205 | Lₐ₅₈₆ | L_{b94} |
| 1206 | Lₐ₅₉₀ | L_{b94} |
| 1207 | Lₐ₅₉₁ | L_{b94} |
| 1208 | Lₐ₅₉₄ | L_{b94} |
| 1209 | Lₐ₆₀₁ | L_{b94} |
| 1210 | Lₐ₆₀₂ | L_{b94} |
| 1211 | Lₐ₆₀₅ | L_{b94} |
| 1212 | Lₐ₆₁₀ | L_{b94} |
| 1213 | Lₐ₆₁₁ | L_{b94} |
| 1214 | Lₐ₆₁₂ | L_{b94} |
| 1215 | Lₐ₆₂₂ | L_{b94} |
| 1216 | Lₐ₆₂₆ | L_{b94} |
| 1217 | Lₐ₉₅₆ | L_{b81} |

20. An electroluminescent device, comprising:
an anode,
a cathode, and
an organic layer disposed between the anode and the cathode, wherein the organic layer comprises the metal complex according to claim 1.

21. The electroluminescent device according to claim 20, wherein the organic layer comprising the metal complex is an emissive layer.

22. The electroluminescent device according to claim 21, wherein the electroluminescent device emits green light or white light.

23. The electroluminescent device according to claim 21, wherein the emissive layer comprises a first host compound;
preferably, the emissive layer further comprises a second host compound;
more preferably, the first host compound and/or the second host compound comprise at least one chemical group selected from the group consisting of benzene, pyridine, pyrimidine, triazine, carbazole, azacarbazole, indolocarbazole, dibenzothiophene, azadibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

24. The electroluminescent device according to claim 23, wherein the first host compound has a structure represented by Formula 4: 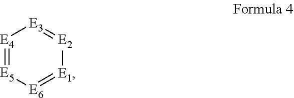
wherein
E₁ to E₆ are, at each occurrence identically or differently, selected from C, CRₑ or N, at least two of E₁ to E₆ are N, and at least one of E₁ to E₆ is C and is attached to Formula A: 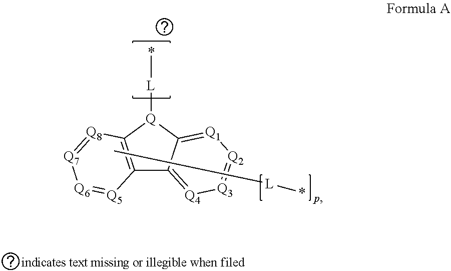
wherein,
Q is, at each occurrence identically or differently, selected from the group consisting of O, S, Se, N, NR″, CR″R″, SiR″R″, GeR″R″, and R″C═CR″; when two R″ are present, the two R″ can be the same or different;
p is 0 or 1; r is 0 or 1;
when Q is selected from N, p is 0, and r is 1;
when Q is selected from the group consisting of O, S, Se, NR″, CR″R″, SiR″R″, GeR″R″, and R″C═CR″, p is 1, and r is 0;
L is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or combinations thereof;
Q₁ to Q₈ are, at each occurrence identically or differently, selected from C, CR_{q} or N;
Rₑ, R″, and R_{q} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a substituted or unsubstituted alkylgermanyl having 3 to 20 carbon atoms, a substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,
“*” represents a position where Formula A is attached to Formula 4;
adjacent substituents Rₑ, R″, R_{q} can be optionally joined to form a ring.

25. The electroluminescent device according to claim 24, wherein E₁ to E₆ are, at each occurrence identically or differently, selected from C, CRₑ or N, and three of E₁ to E₆ are N, at least one of E₁ to E₆ are is CRₑ, and Rₑ is, at each occurrence identically or differently, selected from the group consisting of: substituted or unsubstituted aryl having 6 to 30 carbon atoms, substituted or unsubstituted heteroaryl having 3 to 30 carbon atoms, and combinations thereof; and/or
Q is, at each occurrence identically or differently, selected from O, S, N or NR″; and/or
at least one or at least two of Q₁ to Q₈ is(are) selected from CR_{q}, and the R_{q} is selected from substituted or unsubstituted aryl having 6 to 30 carbon atoms, substituted or unsubstituted heteroaryl having 5 to 30 carbon atoms or combinations thereof, and/or
L is, at each occurrence identically or differently, selected from a single bond, substituted or unsubstituted arylene having 6 to 20 carbon atoms, substituted or unsubstituted heteroarylene having 3 to 20 carbon atoms or combinations thereof.

26. The electroluminescent device according to claim 24, wherein the first host compound is selected from the group consisting of

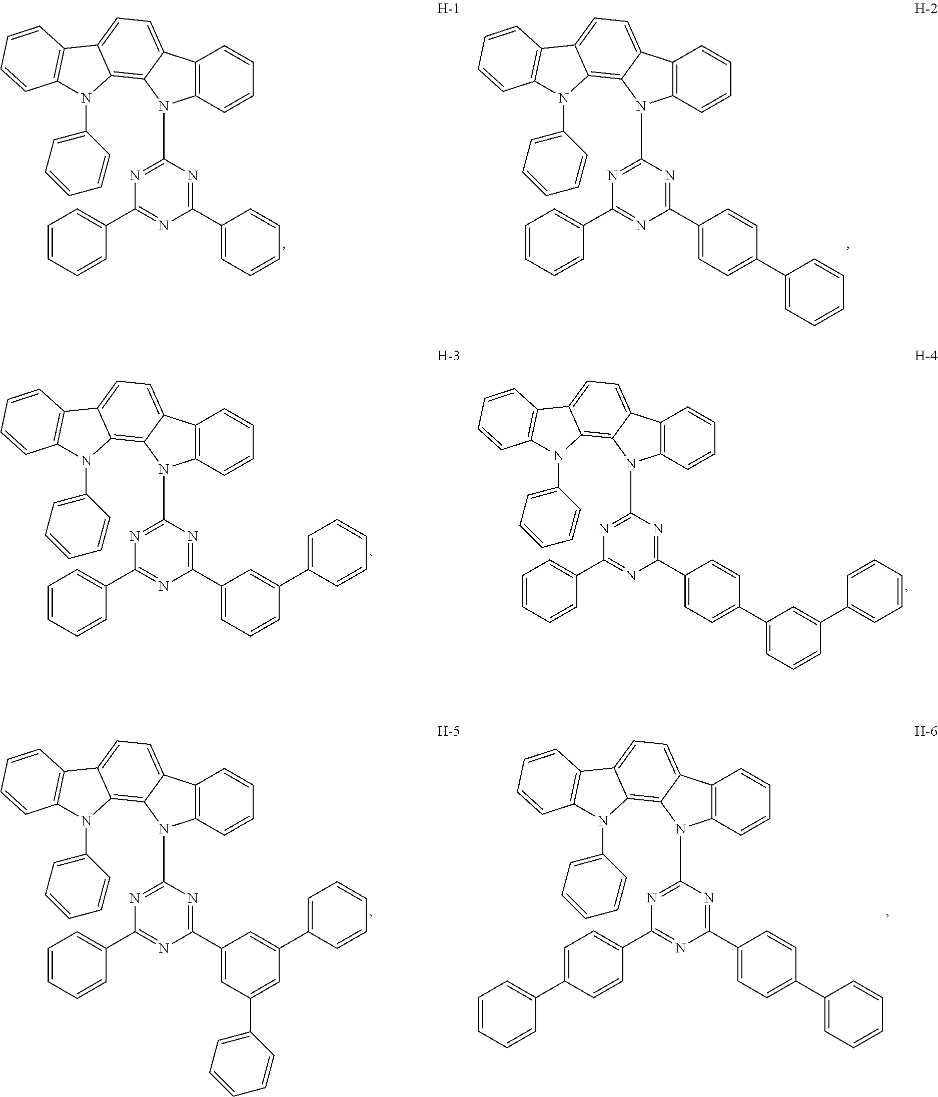

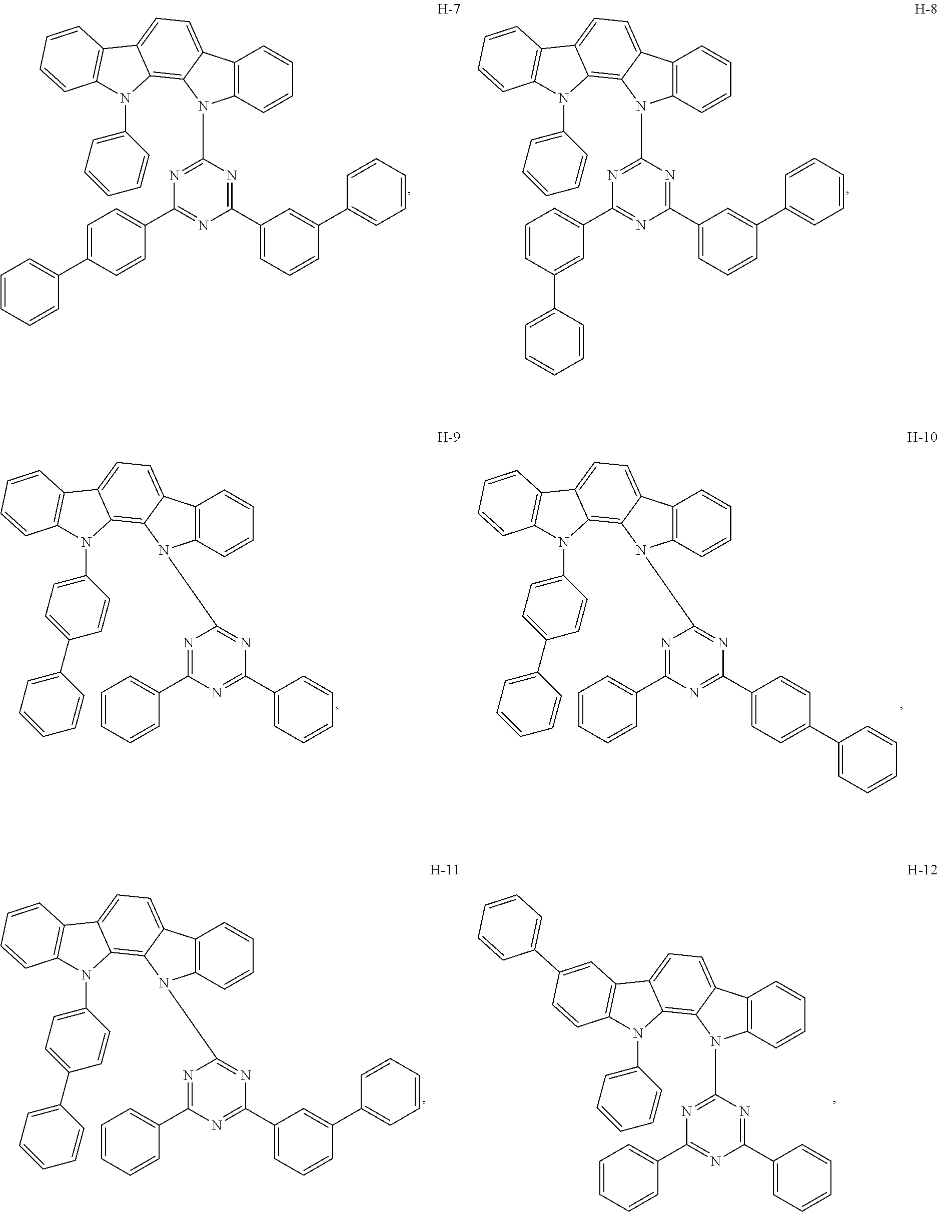

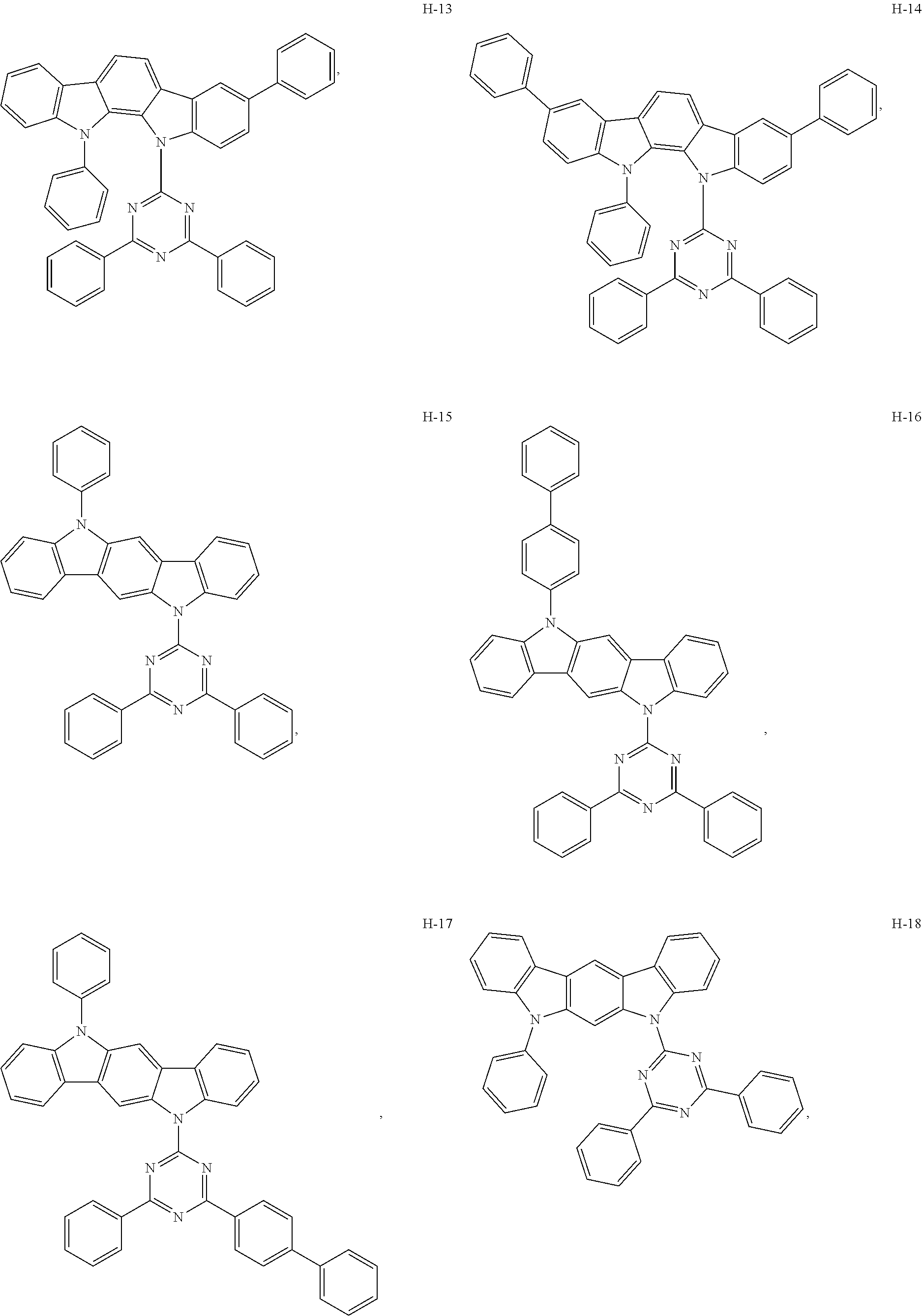

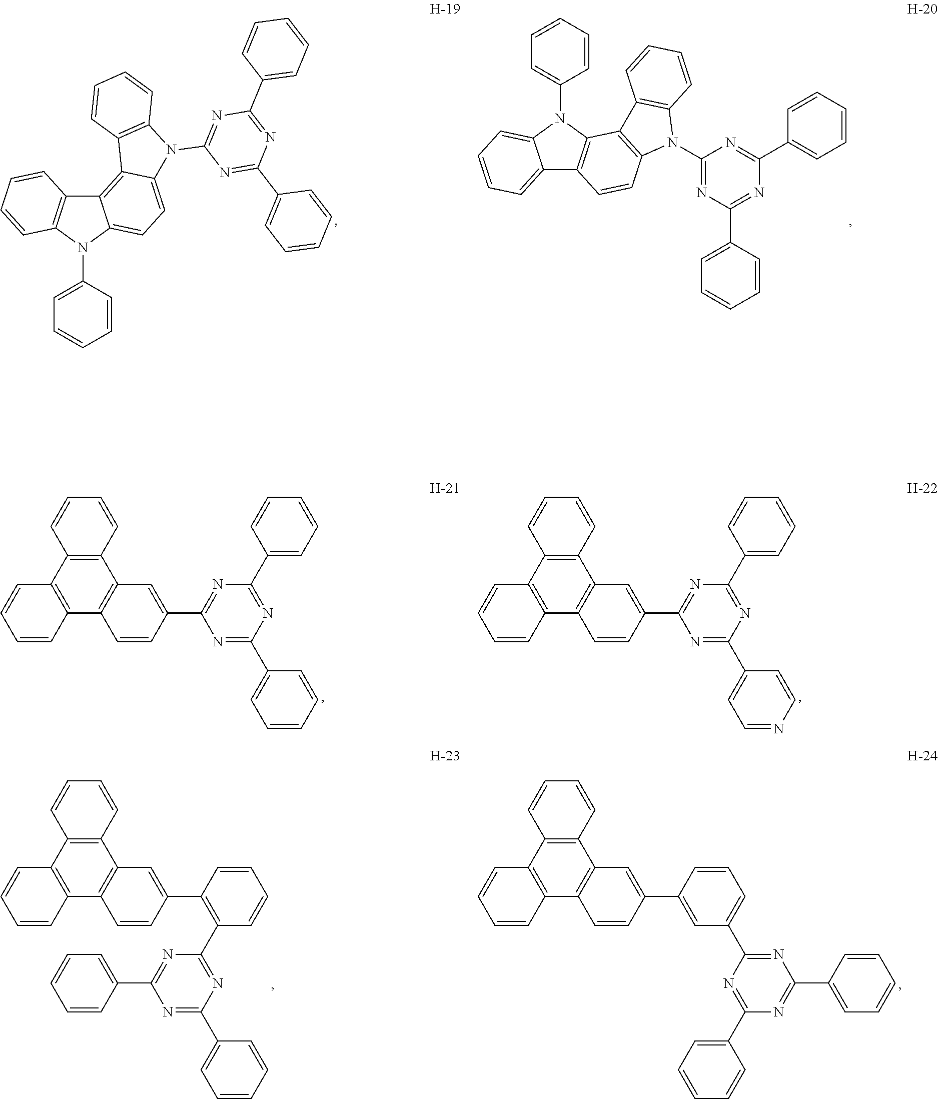 [SMILES: c1ccc(-c2nc(-c3ccccc3)nc(-n3c4ccccc4c4c5c6ccccc6n(-c6ccccc6)c5ccc43)n2)cc1 ; c1ccc(-c2nc(-c3ccccc3)nc(-n3c4ccccc4c4c3ccc3c5ccccc5n(-c5ccccc5)c34)n2)cc1 ; c1ccc(-c2nc(-c3ccccc3)nc(-c3ccc4c5ccccc5c5ccccc5c4c3)n2)cc1 ; c1ccc(-c2nc(-c3ccncc3)nc(-c3ccc4c5ccccc5c5ccccc5c4c3)n2)cc1 ; c1ccc(-c2nc(-c3ccccc3)nc(-c3ccccc3-c3ccc4c5ccccc5c5ccccc5c4c3)n2)cc1 ; c1ccc(-c2nc(-c3ccccc3)nc(-c3cccc(-c4ccc5c6ccccc6c6ccccc6c5c4)c3)n2)cc1]

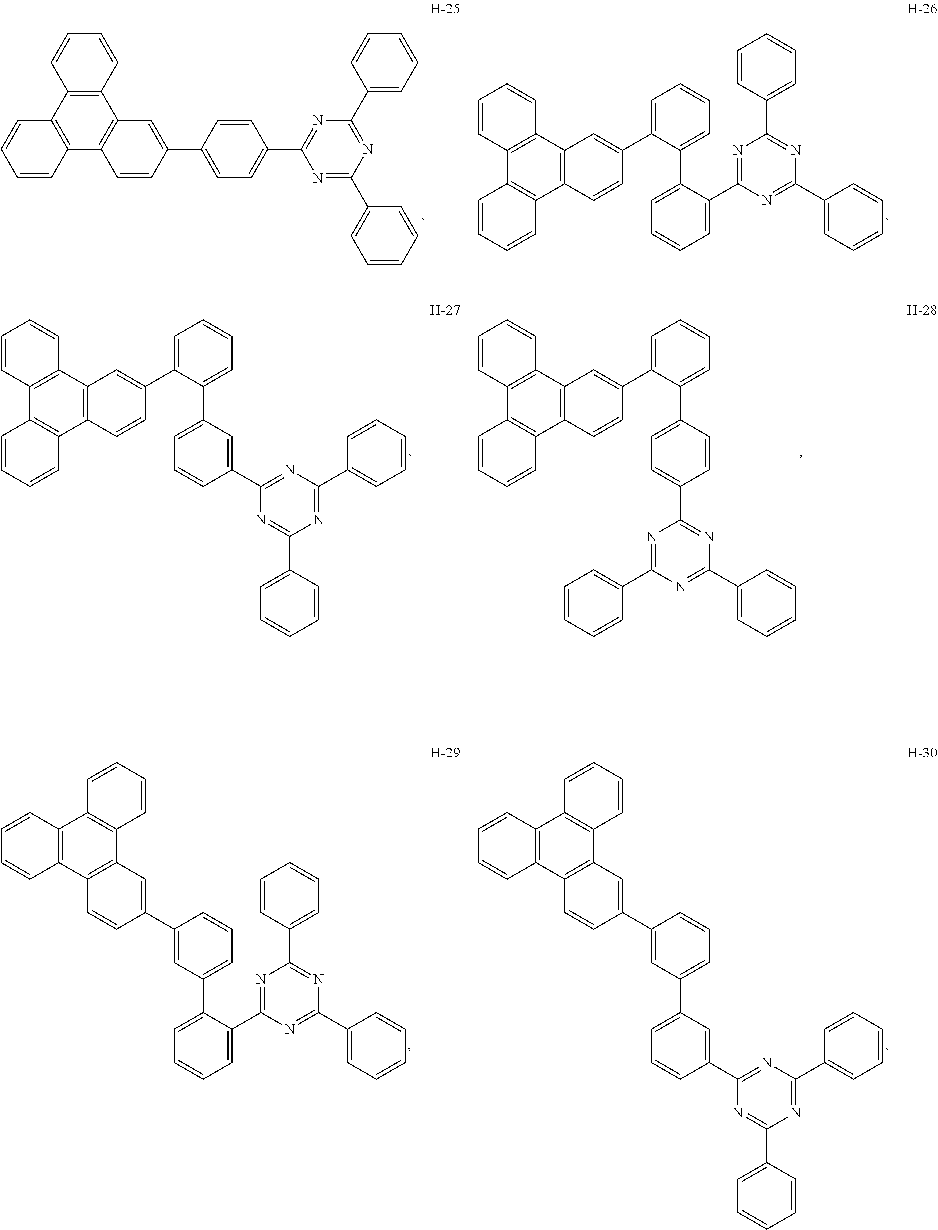 [SMILES: c1ccc(-c2nc(-c3ccccc3)nc(-c3ccc(-c4ccc5c6ccccc6c6ccccc6c5c4)cc3)n2)cc1 ; c1ccc(-c2nc(-c3ccccc3)nc(-c3ccccc3-c3ccccc3-c3ccc4c5ccccc5c5ccccc5c4c3)n2)cc1 ; c1ccc(-c2nc(-c3ccccc3)nc(-c3cccc(-c4ccccc4-c4ccc5c6ccccc6c6ccccc6c5c4)c3)n2)cc1 ; c1ccc(-c2nc(-c3ccccc3)nc(-c3ccc(-c4ccccc4-c4ccc5c6ccccc6c6ccccc6c5c4)cc3)n2)cc1 ; c1ccc(-c2nc(-c3ccccc3)nc(-c3ccccc3-c3cccc(-c4ccc5c6ccccc6c6ccccc6c5c4)c3)n2)cc1 ; c1ccc(-c2nc(-c3ccccc3)nc(-c3cccc(-c4cccc(-c5ccc6c7ccccc7c7ccccc7c6c5)c4)c3)n2)cc1]

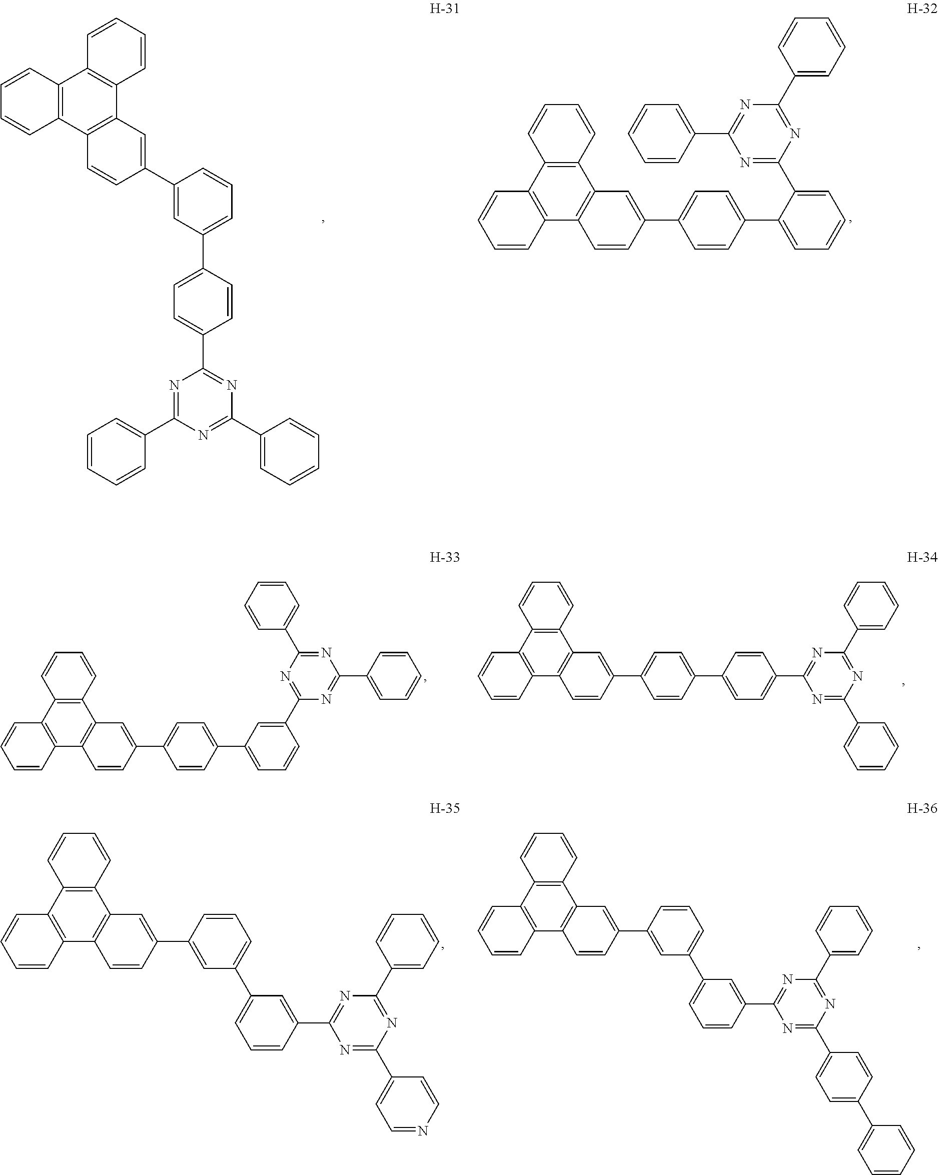

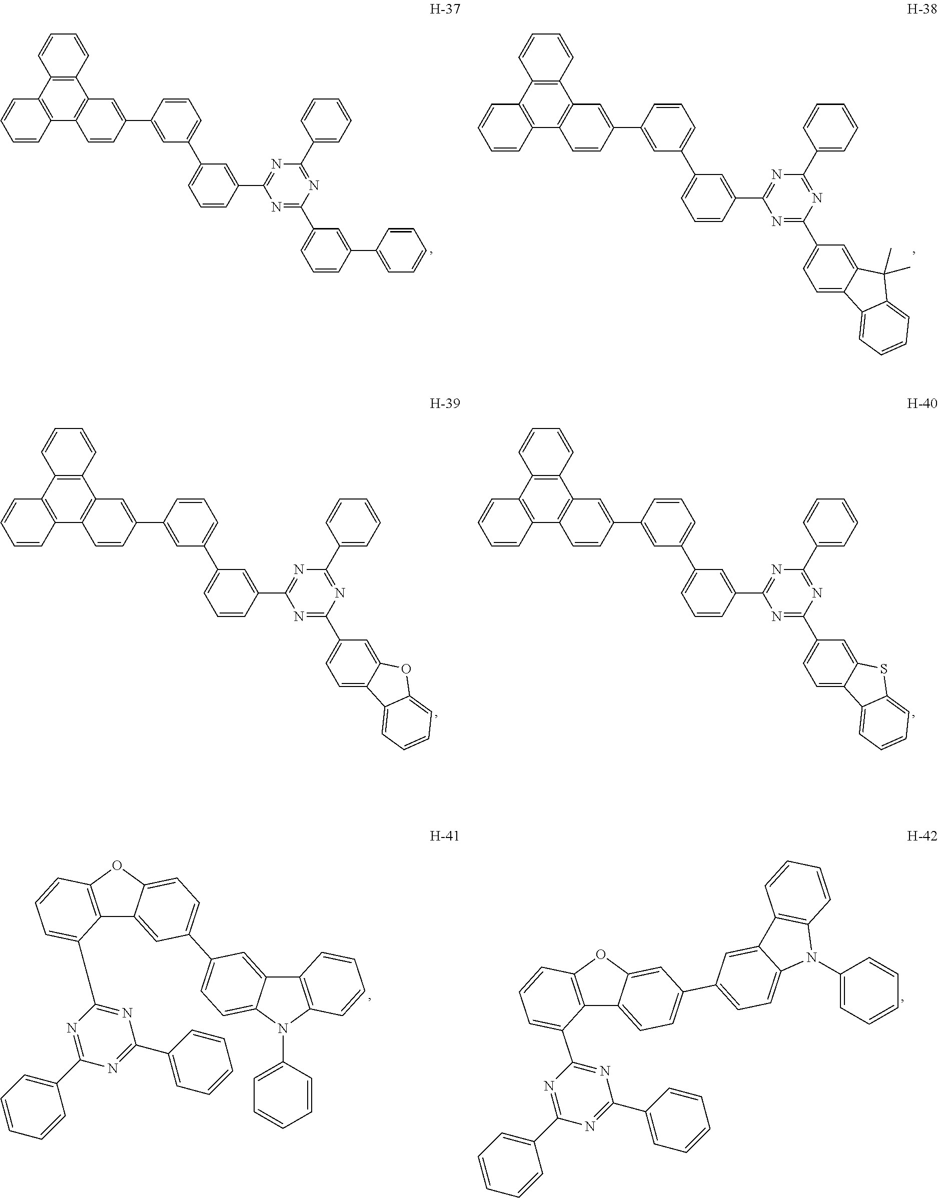

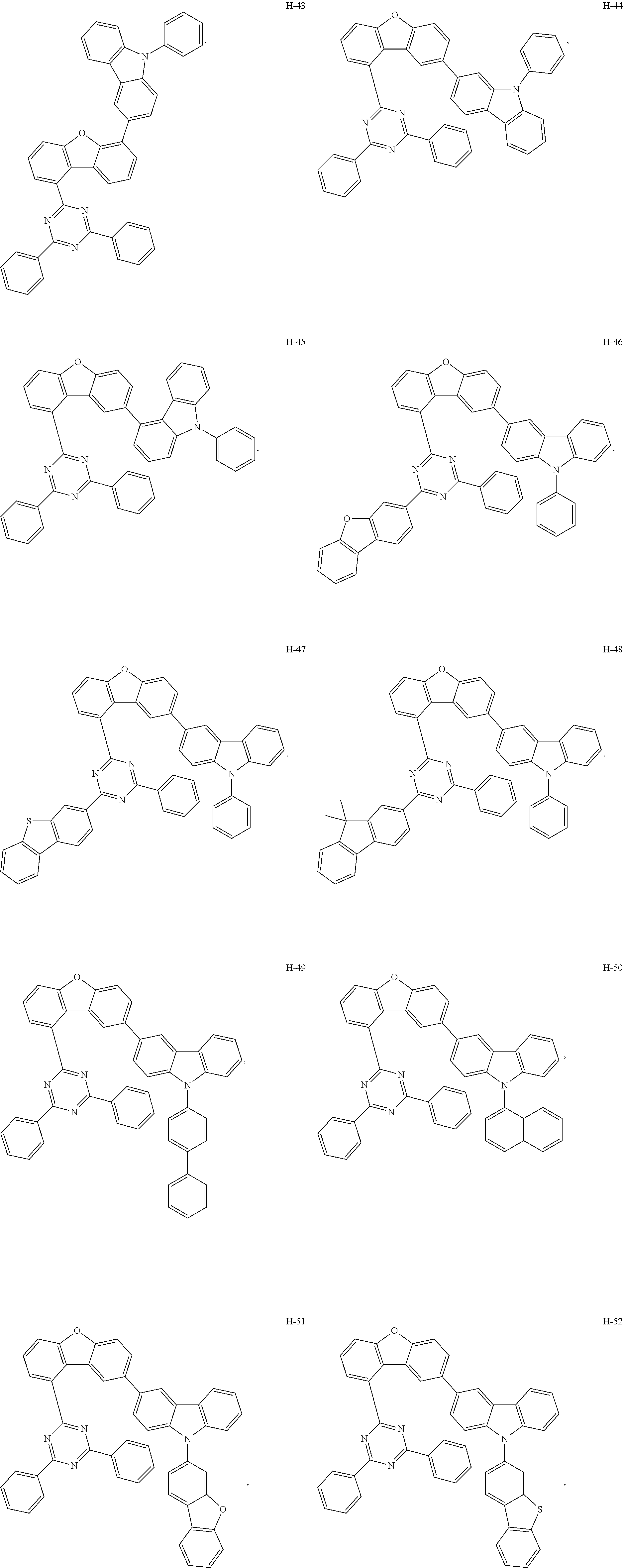

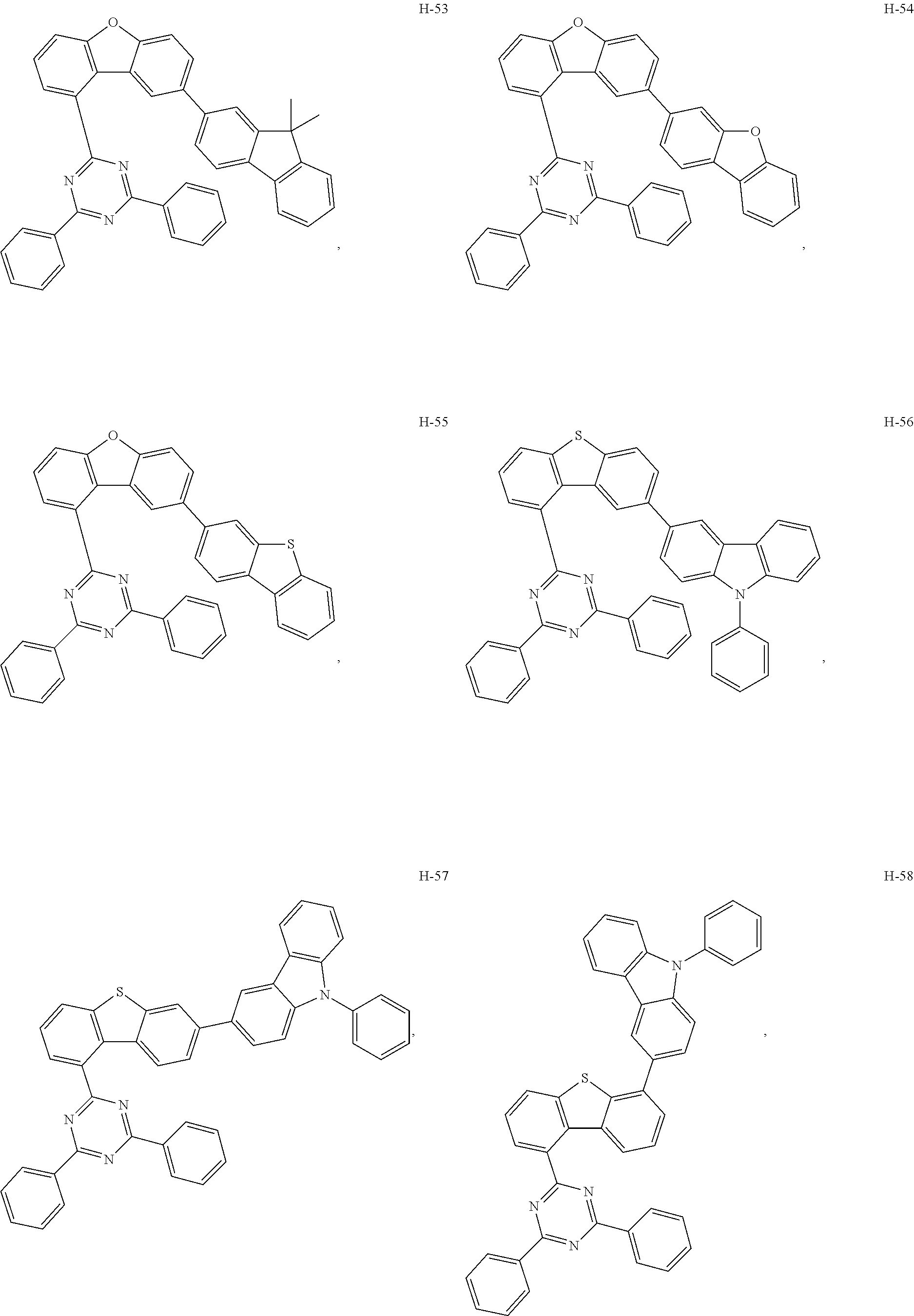

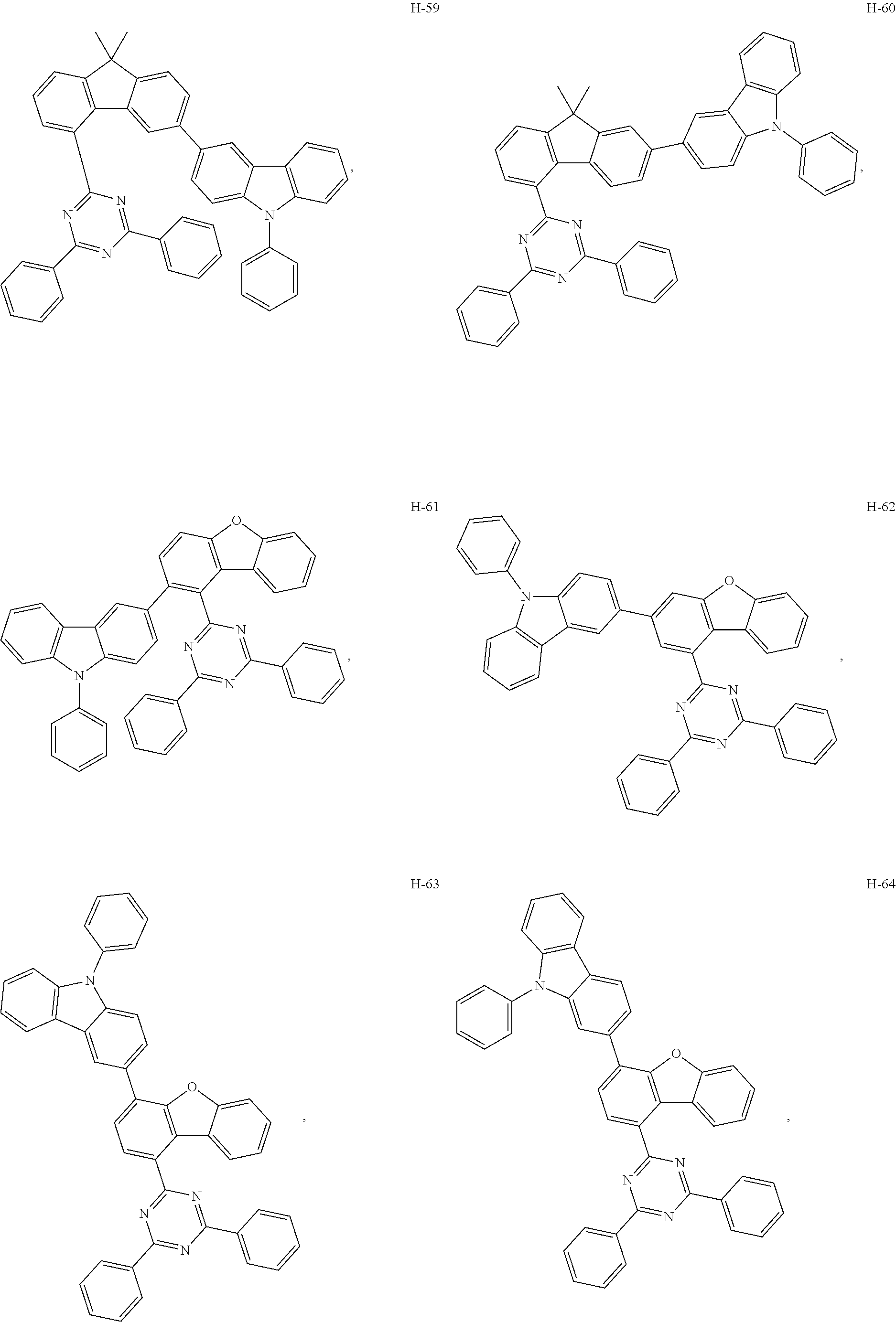

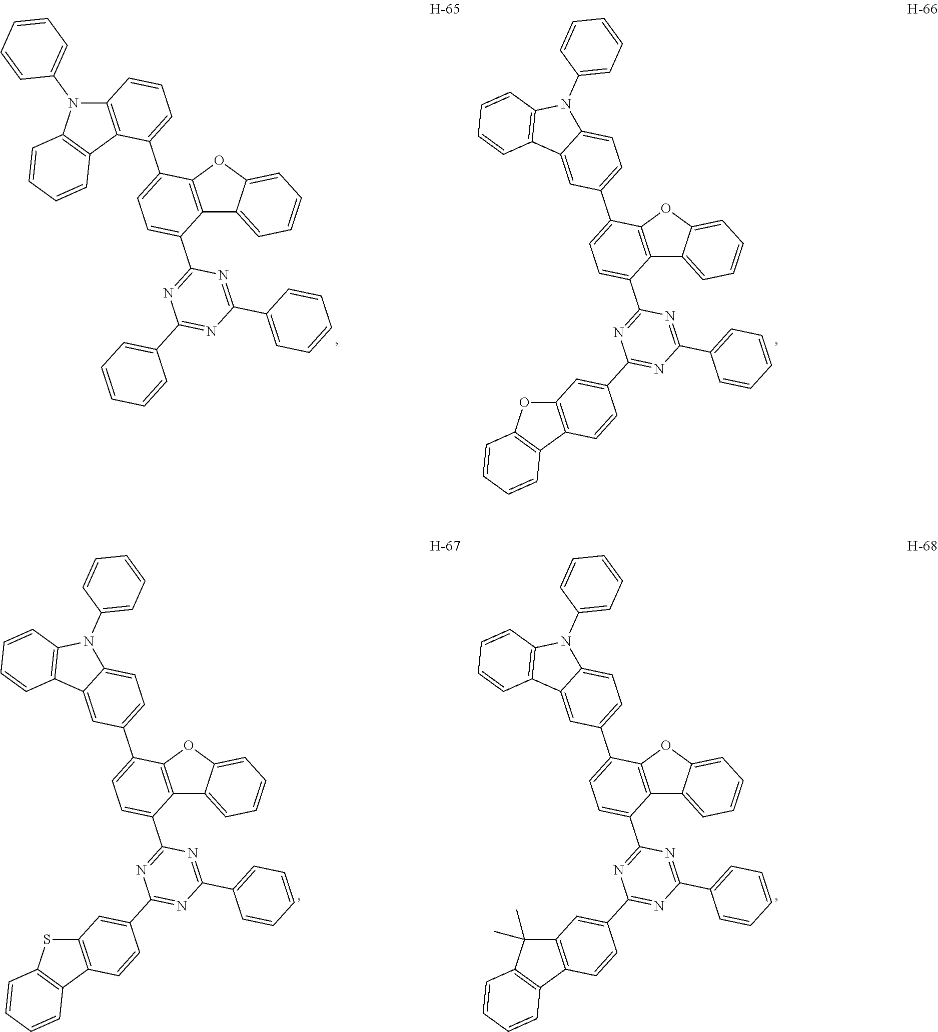 [SMILES: c1ccc(-c2nc(-c3ccccc3)nc(-c3ccc(-c4cccc5c4c4ccccc4n5-c4ccccc4)c4oc5ccccc5c34)n2)cc1 ; c1ccc(-c2nc(-c3ccc4c(c3)oc3ccccc34)nc(-c3ccc(-c4ccc5c(c4)c4ccccc4n5-c4ccccc4)c4oc5ccccc5c34)n2)cc1 ; c1ccc(-c2nc(-c3ccc4c(c3)sc3ccccc34)nc(-c3ccc(-c4ccc5c(c4)c4ccccc4n5-c4ccccc4)c4oc5ccccc5c34)n2)cc1 ; CC1(C)c2ccccc2-c2ccc(-c3nc(-c4ccccc4)nc(-c4ccc(-c5ccc6c(c5)c5ccccc5n6-c5ccccc5)c5oc6ccccc6c45)n3)cc21]

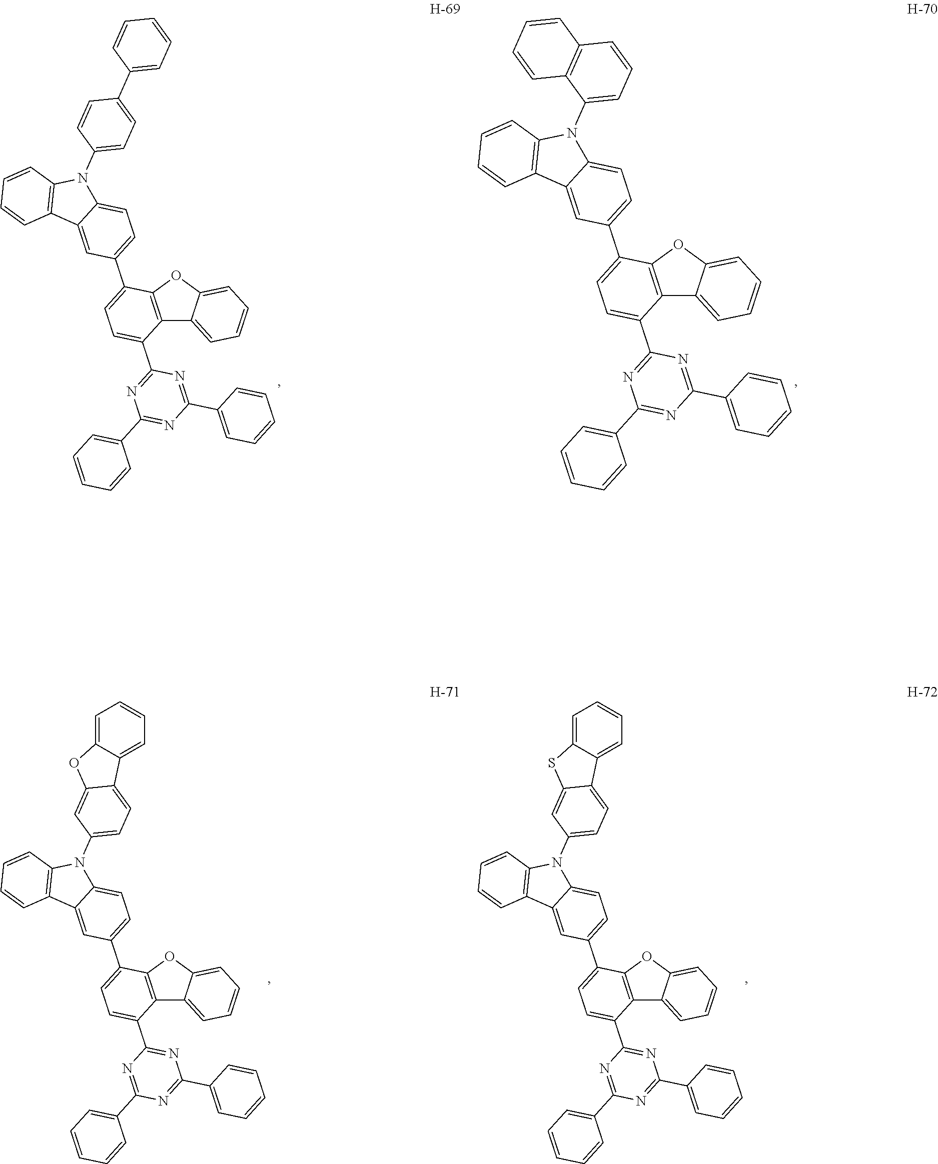 [SMILES: c1ccc(-c2ccc(-n3c4ccccc4c4cc(-c5ccc(-c6nc(-c7ccccc7)nc(-c7ccccc7)n6)c6c5oc5ccccc56)ccc43)cc2)cc1 ; c1ccc(-c2nc(-c3ccccc3)nc(-c3ccc(-c4ccc5c(c4)c4ccccc4n5-c4cccc5ccccc45)c4oc5ccccc5c34)n2)cc1 ; c1ccc(-c2nc(-c3ccccc3)nc(-c3ccc(-c4ccc5c(c4)c4ccccc4n5-c4ccc5c(c4)oc4ccccc45)c4oc5ccccc5c34)n2)cc1 ; c1ccc(-c2nc(-c3ccccc3)nc(-c3ccc(-c4ccc5c(c4)c4ccccc4n5-c4ccc5c(c4)sc4ccccc45)c4oc5ccccc5c34)n2)cc1]

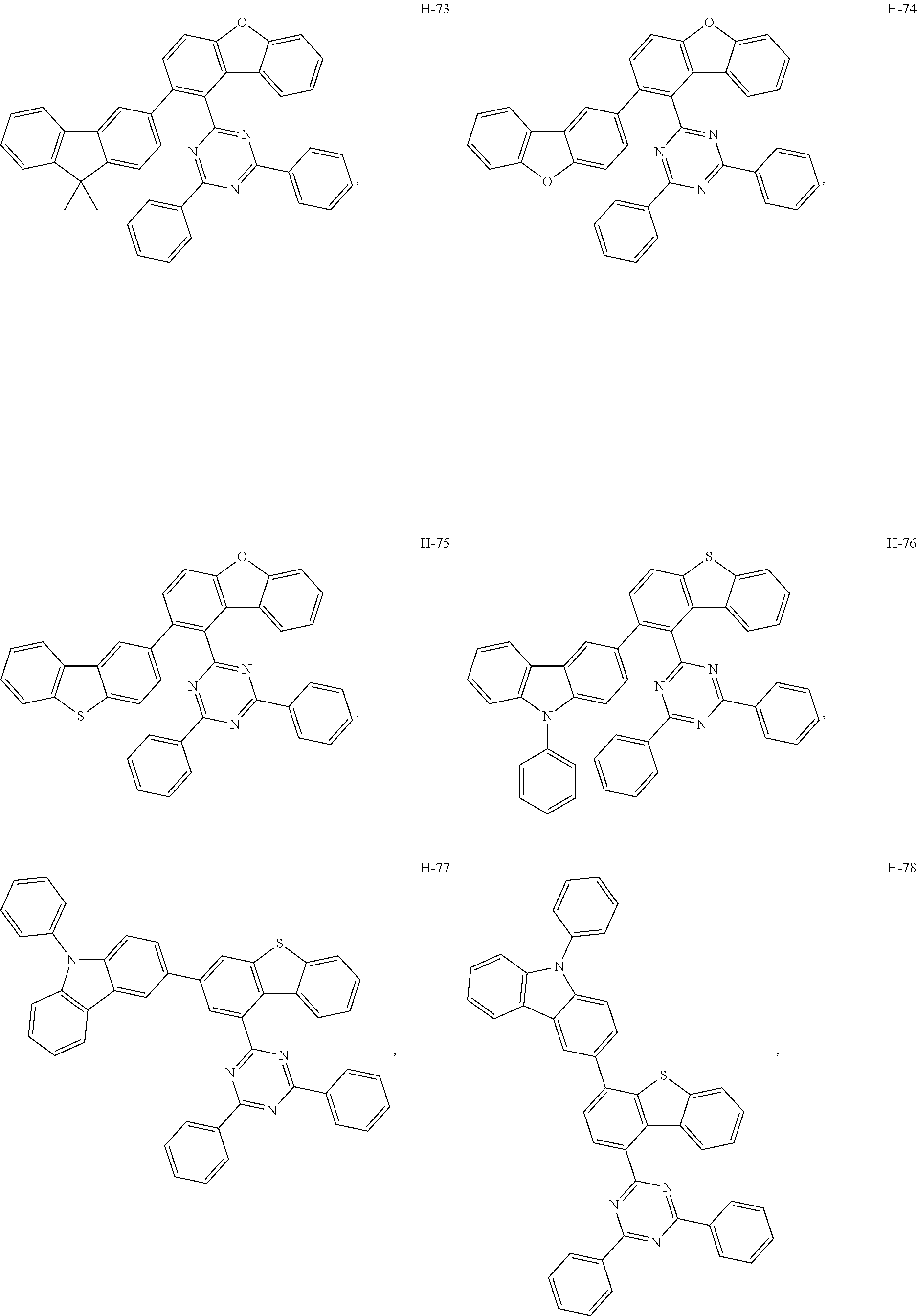

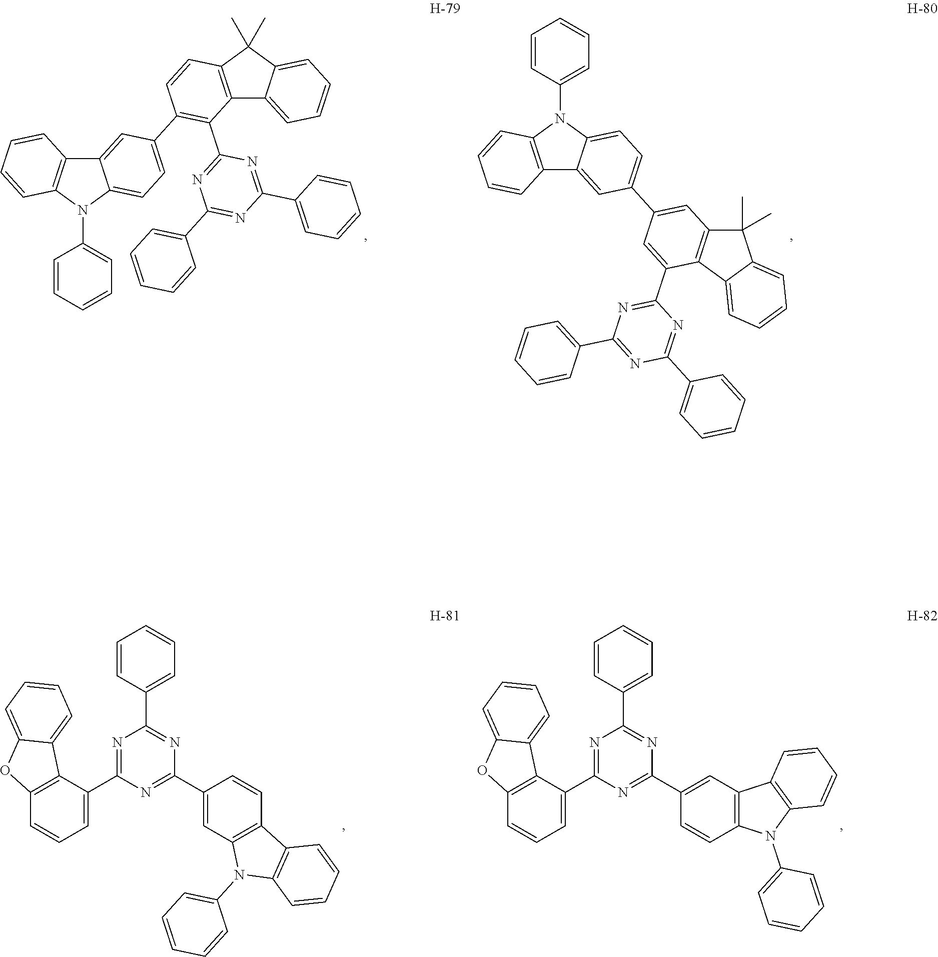 [SMILES: CC1(C)c2ccccc2-c2c1ccc(-c1ccc3c(c1)c1ccccc1n3-c1ccccc1)c2-c1nc(-c2ccccc2)nc(-c2ccccc2)n1 ; CC1(C)c2ccccc2-c2c(-c3nc(-c4ccccc4)nc(-c4ccccc4)n3)cc(-c3ccc4c(c3)c3ccccc3n4-c3ccccc3)cc21 ; c1ccc(-c2nc(-c3ccc4c5ccccc5n(-c5ccccc5)c4c3)nc(-c3cccc4oc5ccccc5c34)n2)cc1 ; c1ccc(-c2nc(-c3ccc4c(c3)c3ccccc3n4-c3ccccc3)nc(-c3cccc4oc5ccccc5c34)n2)cc1]

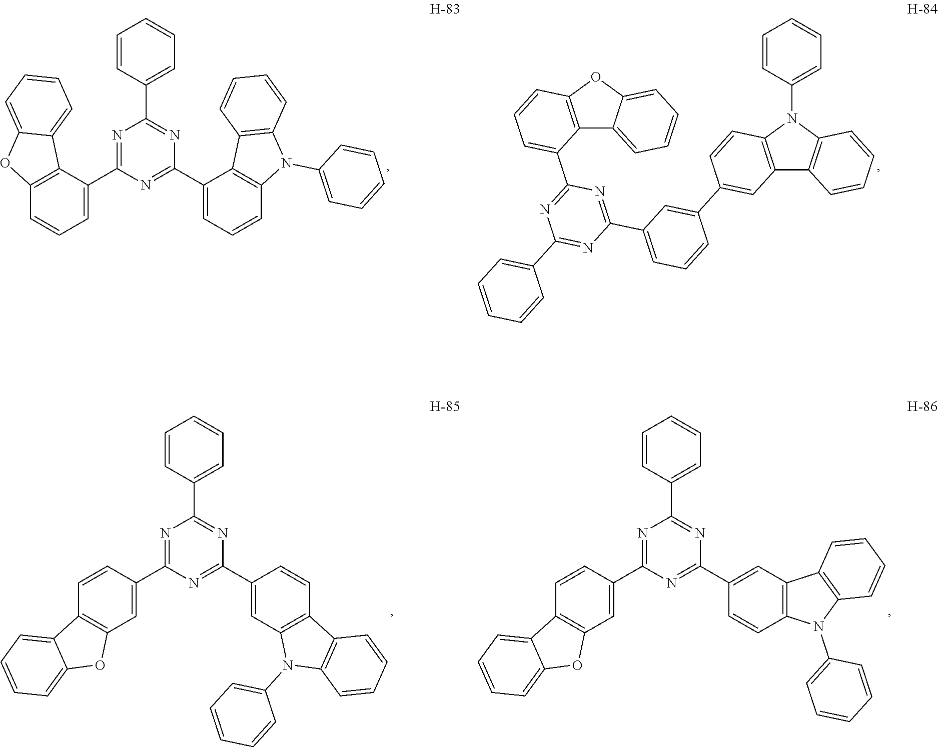 [SMILES: c1ccc(-c2nc(-c3cccc4oc5ccccc5c34)nc(-c3cccc4c3c3ccccc3n4-c3ccccc3)n2)cc1 ; c1ccc(-c2nc(-c3cccc(-c4ccc5c(c4)c4ccccc4n5-c4ccccc4)c3)nc(-c3cccc4oc5ccccc5c34)n2)cc1 ; c1ccc(-c2nc(-c3ccc4c(c3)oc3ccccc34)nc(-c3ccc4c5ccccc5n(-c5ccccc5)c4c3)n2)cc1 ; c1ccc(-c2nc(-c3ccc4c(c3)oc3ccccc34)nc(-c3ccc4c(c3)c3ccccc3n4-c3ccccc3)n2)cc1]

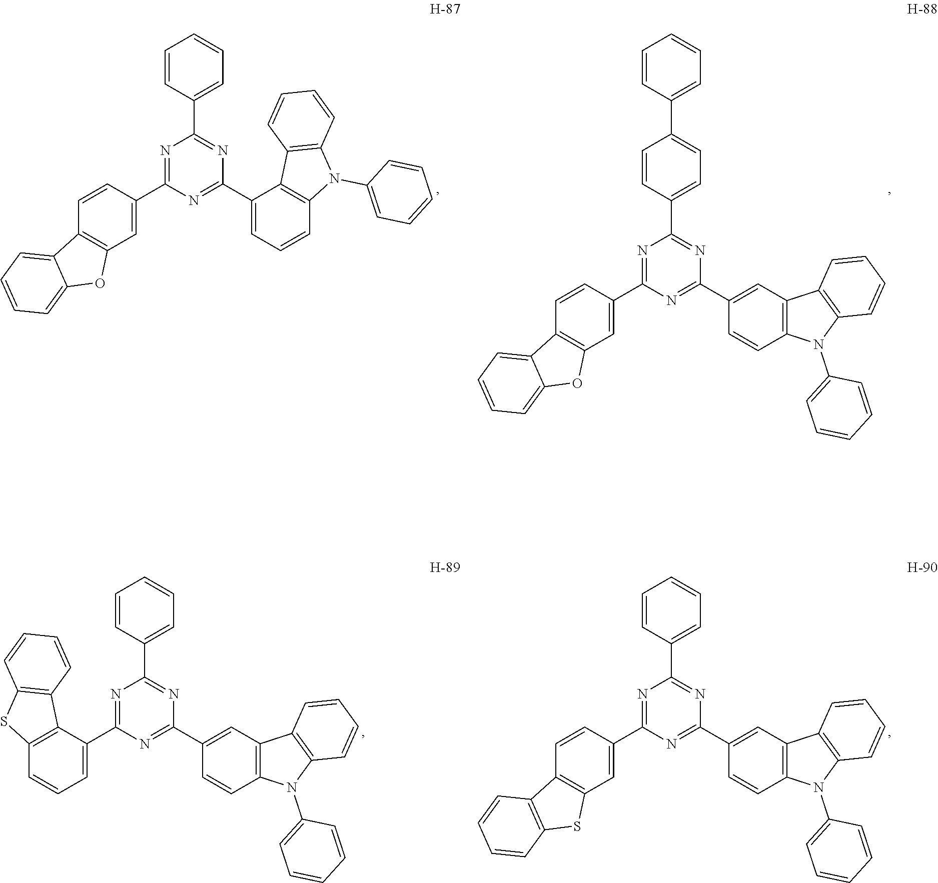 [SMILES: c1ccc(-c2nc(-c3ccc4c(c3)oc3ccccc34)nc(-c3cccc4c3c3ccccc3n4-c3ccccc3)n2)cc1 ; c1ccc(-c2ccc(-c3nc(-c4ccc5c(c4)oc4ccccc45)nc(-c4ccc5c(c4)c4ccccc4n5-c4ccccc4)n3)cc2)cc1 ; c1ccc(-c2nc(-c3ccc4c(c3)c3ccccc3n4-c3ccccc3)nc(-c3cccc4sc5ccccc5c34)n2)cc1 ; c1ccc(-c2nc(-c3ccc4c(c3)sc3ccccc34)nc(-c3ccc4c(c3)c3ccccc3n4-c3ccccc3)n2)cc1]

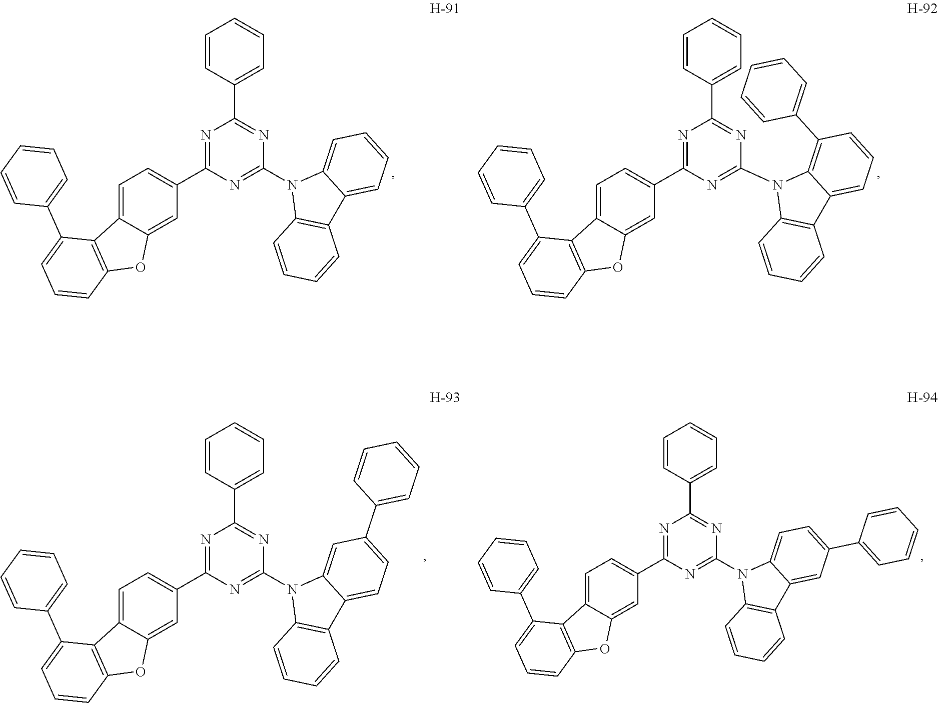 [SMILES: c1ccc(-c2nc(-c3ccc4c(c3)oc3cccc(-c5ccccc5)c34)nc(-n3c4ccccc4c4ccccc43)n2)cc1 ; c1ccc(-c2nc(-c3ccc4c(c3)oc3cccc(-c5ccccc5)c34)nc(-n3c4ccccc4c4cccc(-c5ccccc5)c43)n2)cc1 ; c1ccc(-c2ccc3c4ccccc4n(-c4nc(-c5ccccc5)nc(-c5ccc6c(c5)oc5cccc(-c7ccccc7)c56)n4)c3c2)cc1 ; c1ccc(-c2ccc3c(c2)c2ccccc2n3-c2nc(-c3ccccc3)nc(-c3ccc4c(c3)oc3cccc(-c5ccccc5)c34)n2)cc1]

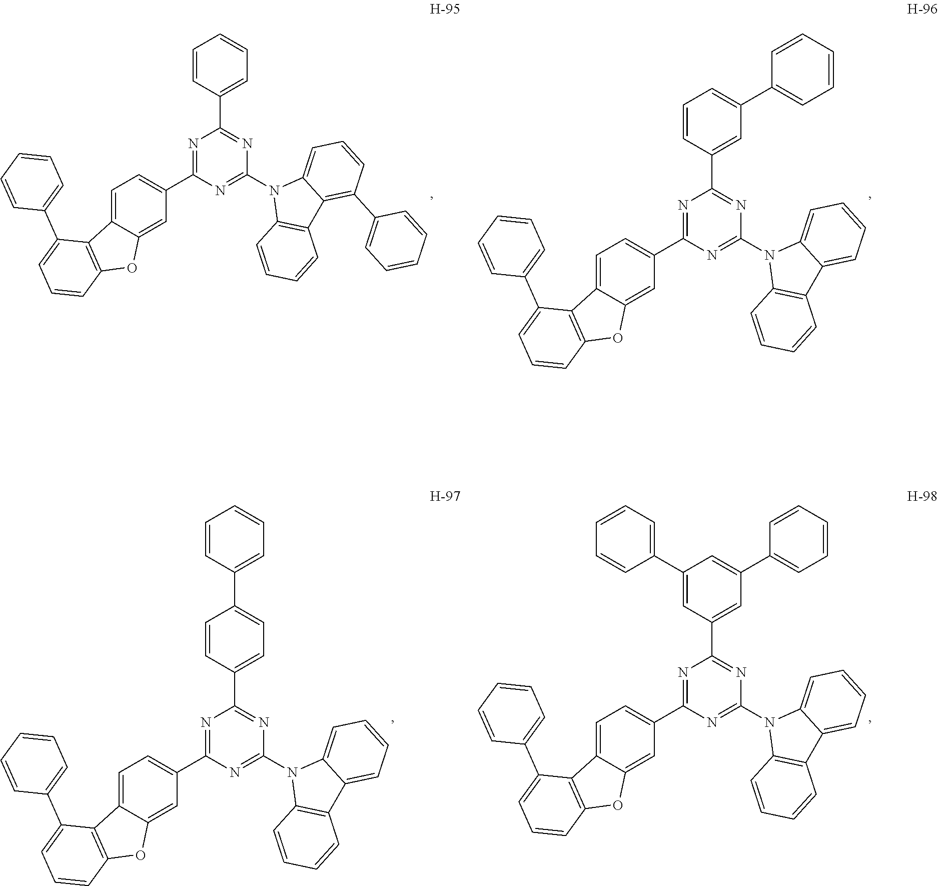 [SMILES: c1ccc(-c2nc(-c3ccc4c(c3)oc3cccc(-c5ccccc5)c34)nc(-n3c4ccccc4c4c(-c5ccccc5)cccc43)n2)cc1 ; c1ccc(-c2cccc(-c3nc(-c4ccc5c(c4)oc4cccc(-c6ccccc6)c45)nc(-n4c5ccccc5c5ccccc54)n3)c2)cc1 ; c1ccc(-c2ccc(-c3nc(-c4ccc5c(c4)oc4cccc(-c6ccccc6)c45)nc(-n4c5ccccc5c5ccccc54)n3)cc2)cc1 ; c1ccc(-c2cc(-c3ccccc3)cc(-c3nc(-c4ccc5c(c4)oc4cccc(-c6ccccc6)c45)nc(-n4c5ccccc5c5ccccc54)n3)c2)cc1]

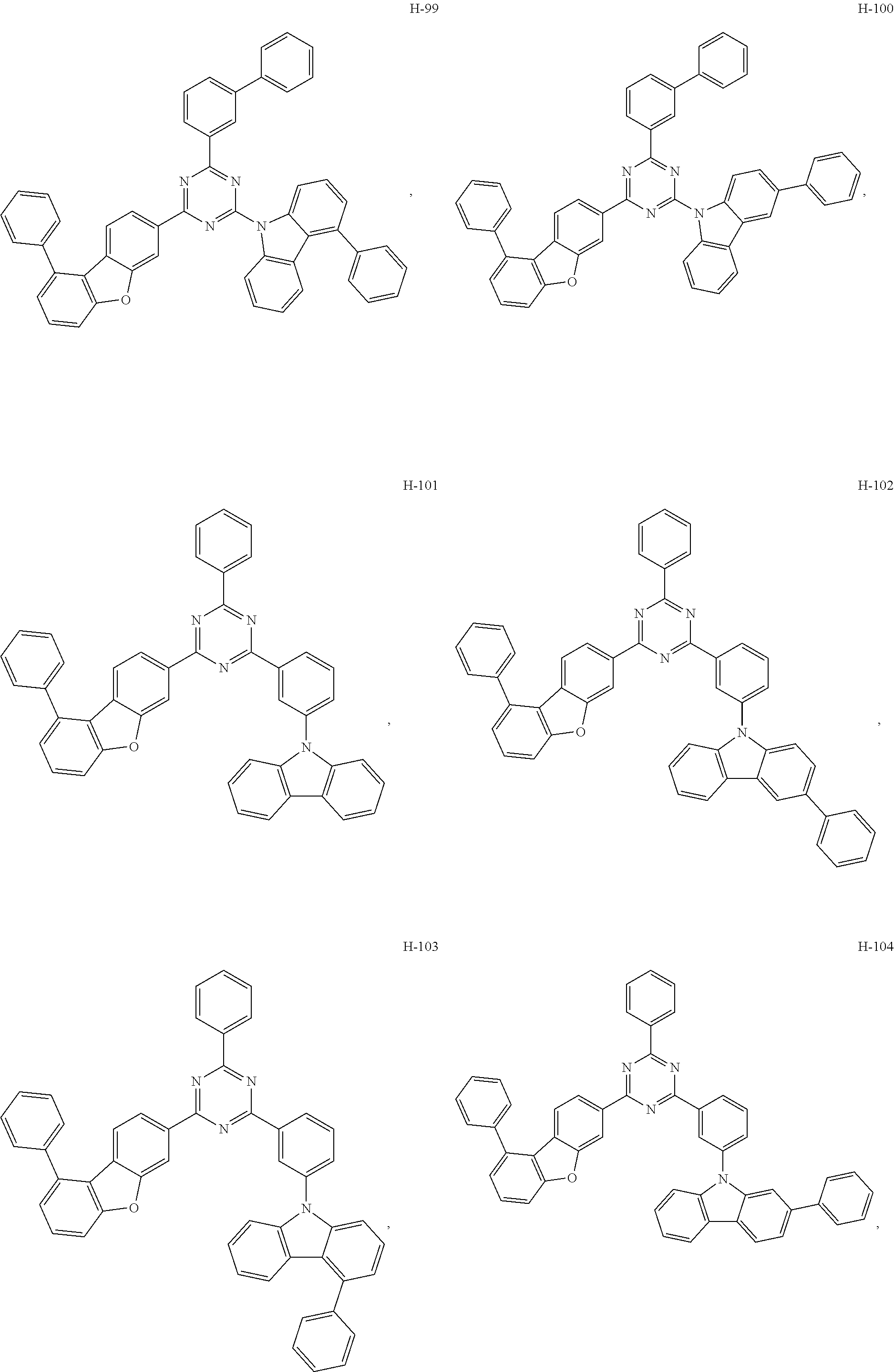

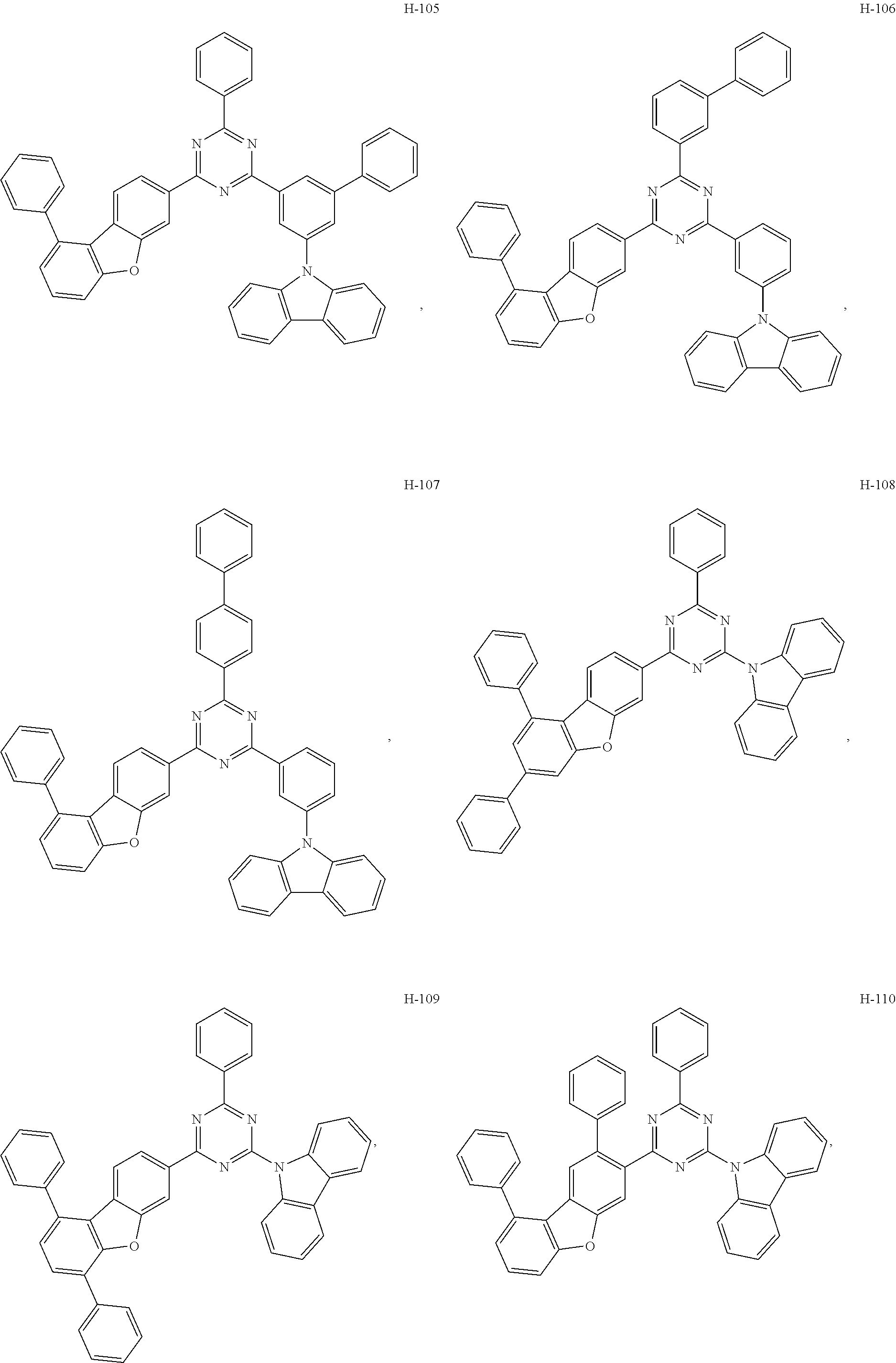

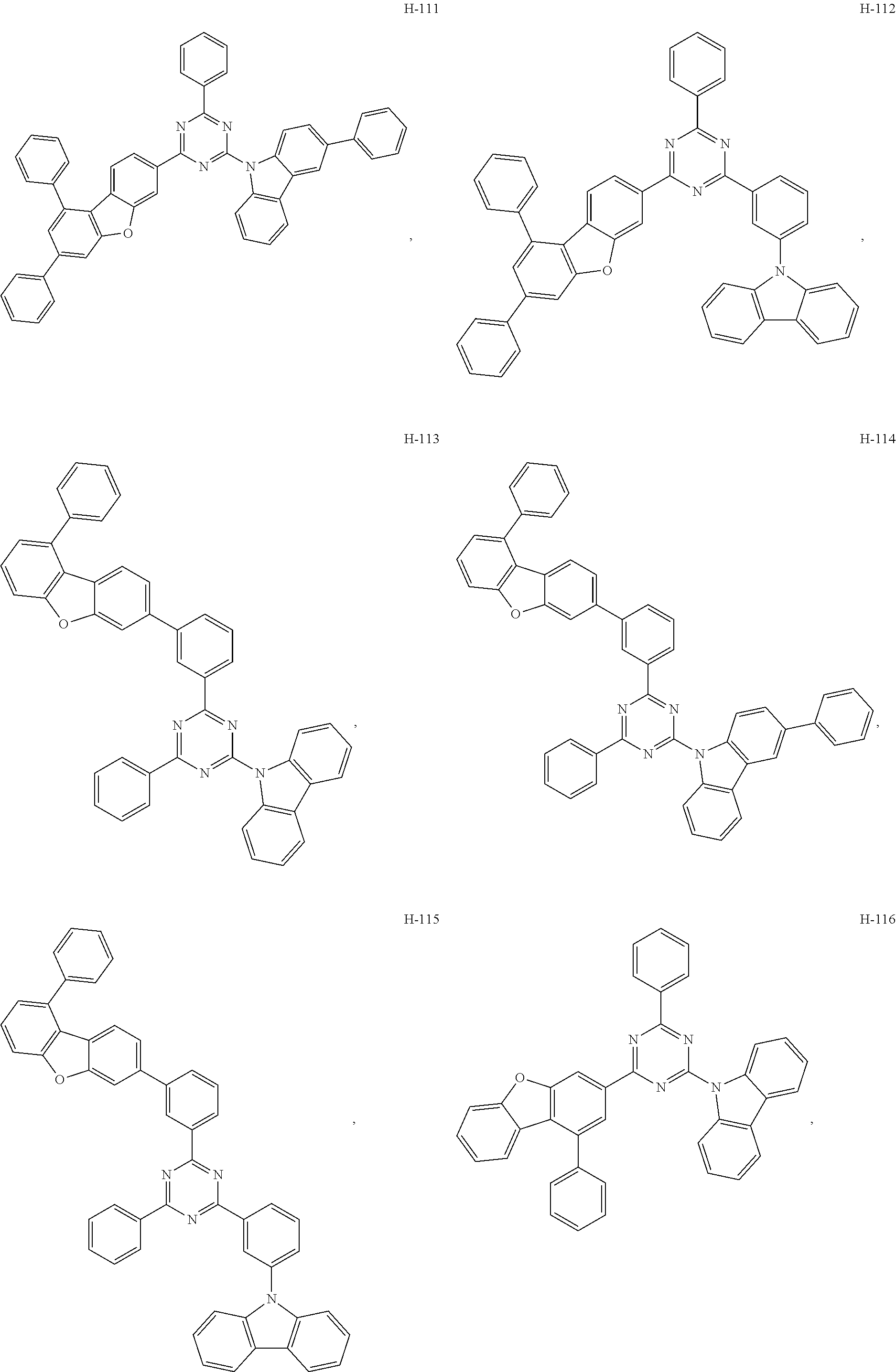

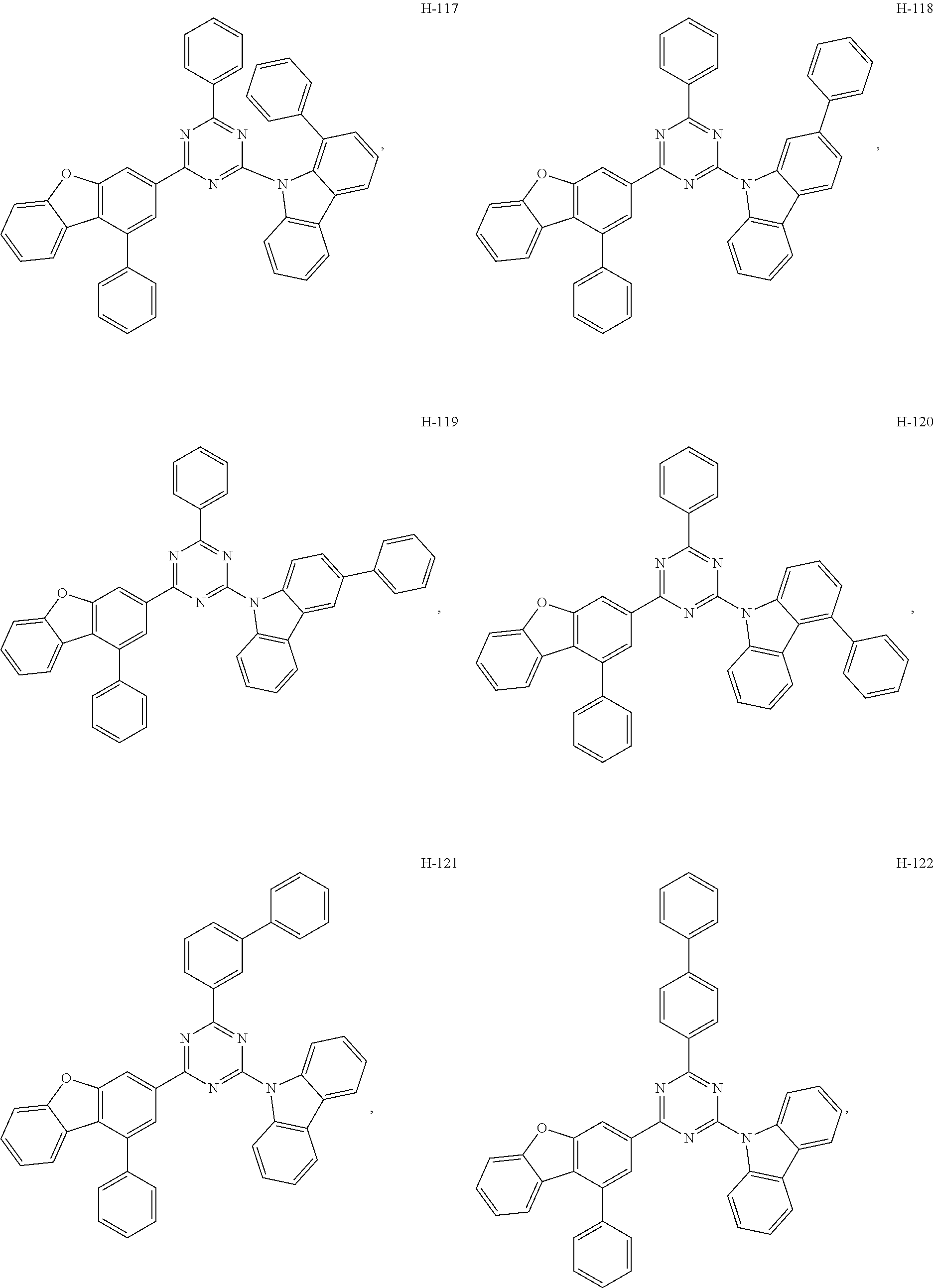

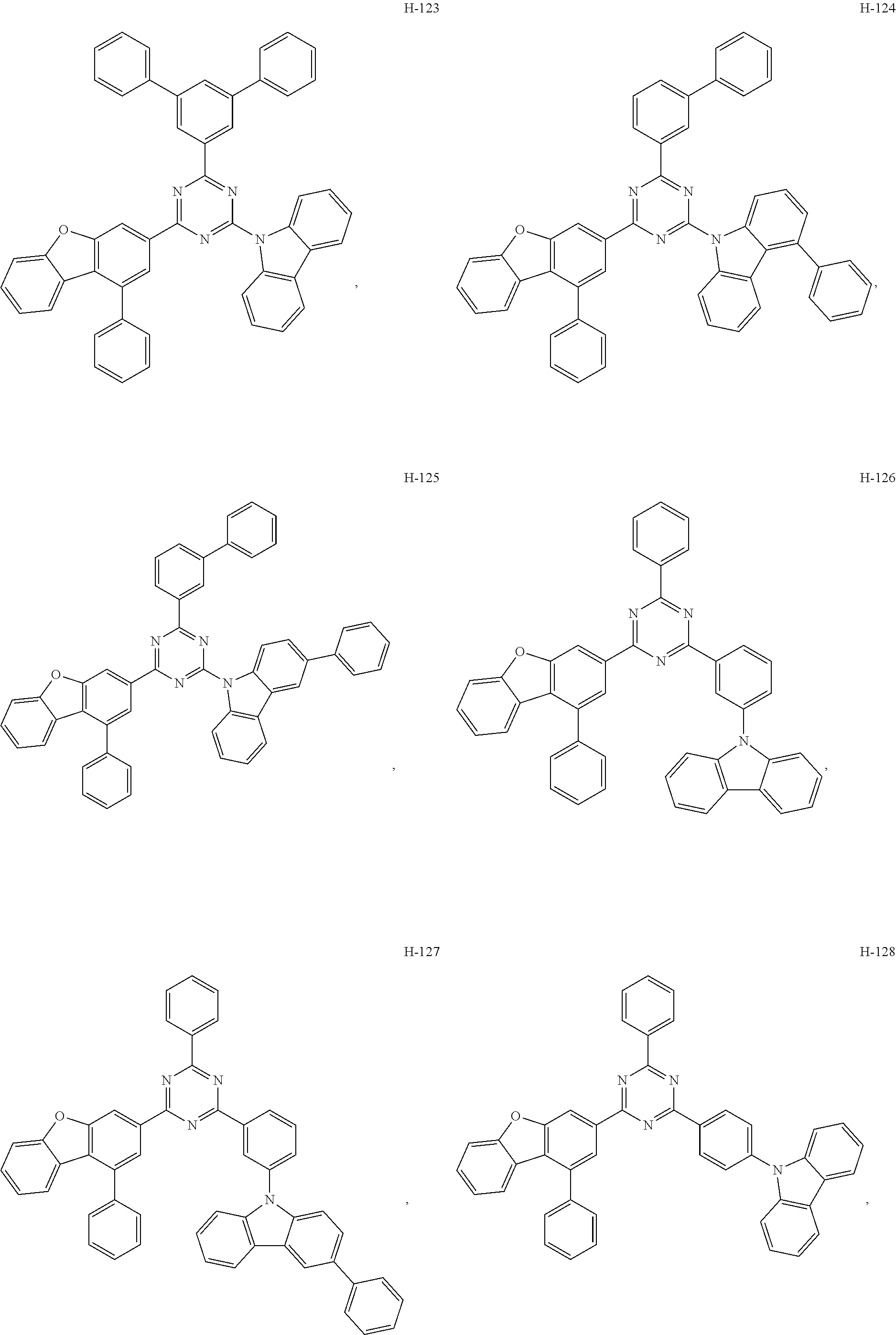

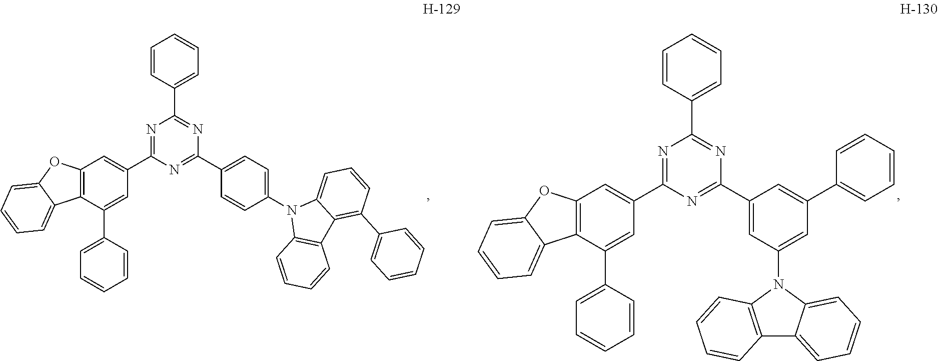 [SMILES: c1ccc(-c2nc(-c3ccc(-n4c5ccccc5c5c(-c6ccccc6)cccc54)cc3)nc(-c3cc(-c4ccccc4)c4c(c3)oc3ccccc34)n2)cc1 ; c1ccc(-c2cc(-c3nc(-c4ccccc4)nc(-c4cc(-c5ccccc5)c5c(c4)oc4ccccc45)n3)cc(-n3c4ccccc4c4ccccc43)c2)cc1]

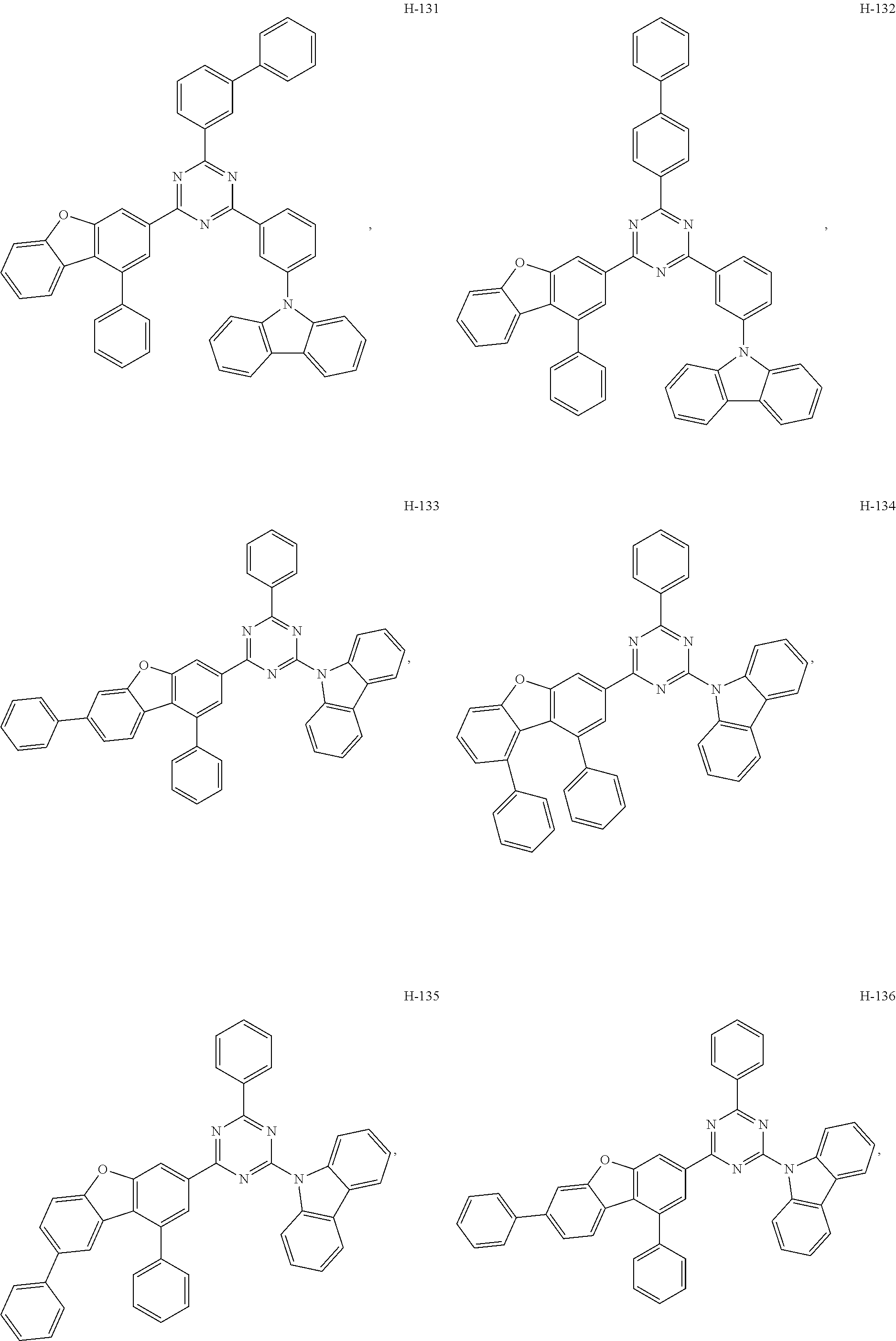

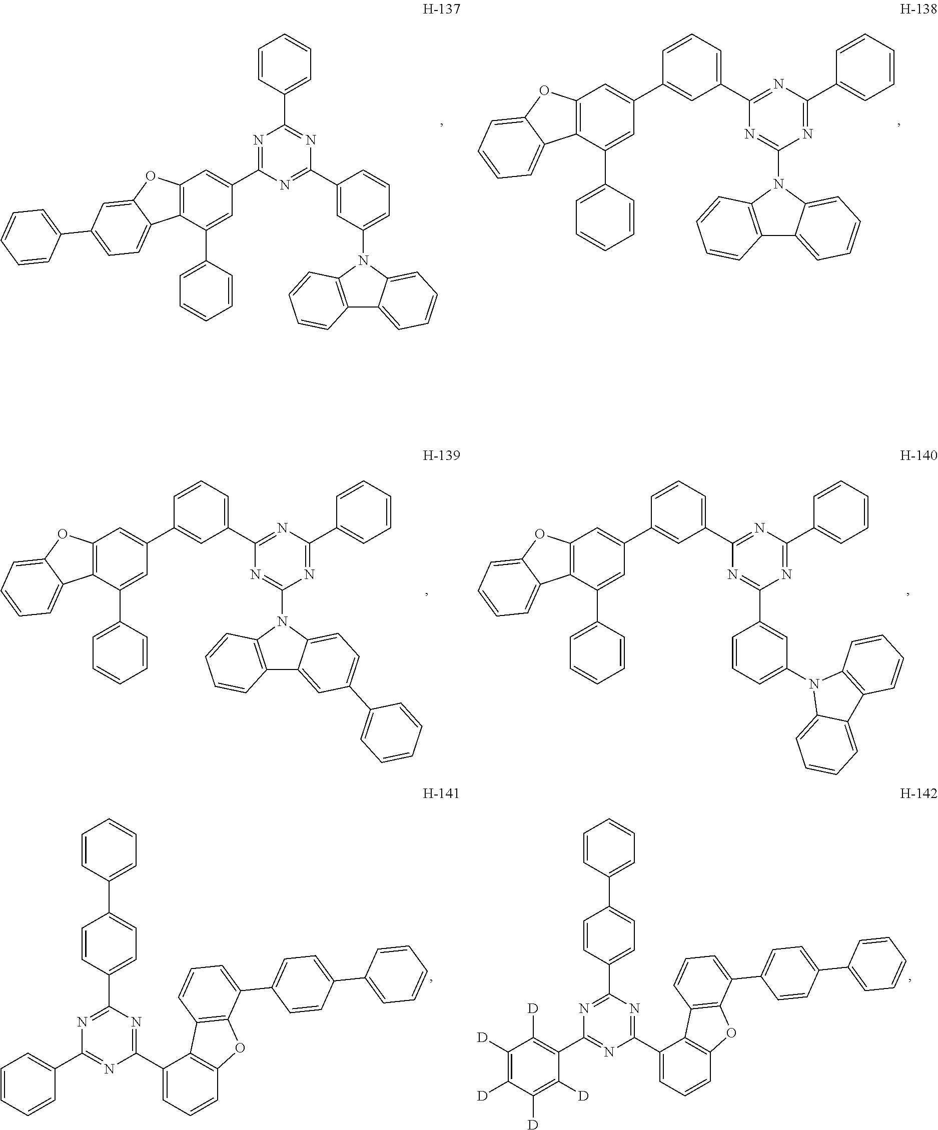

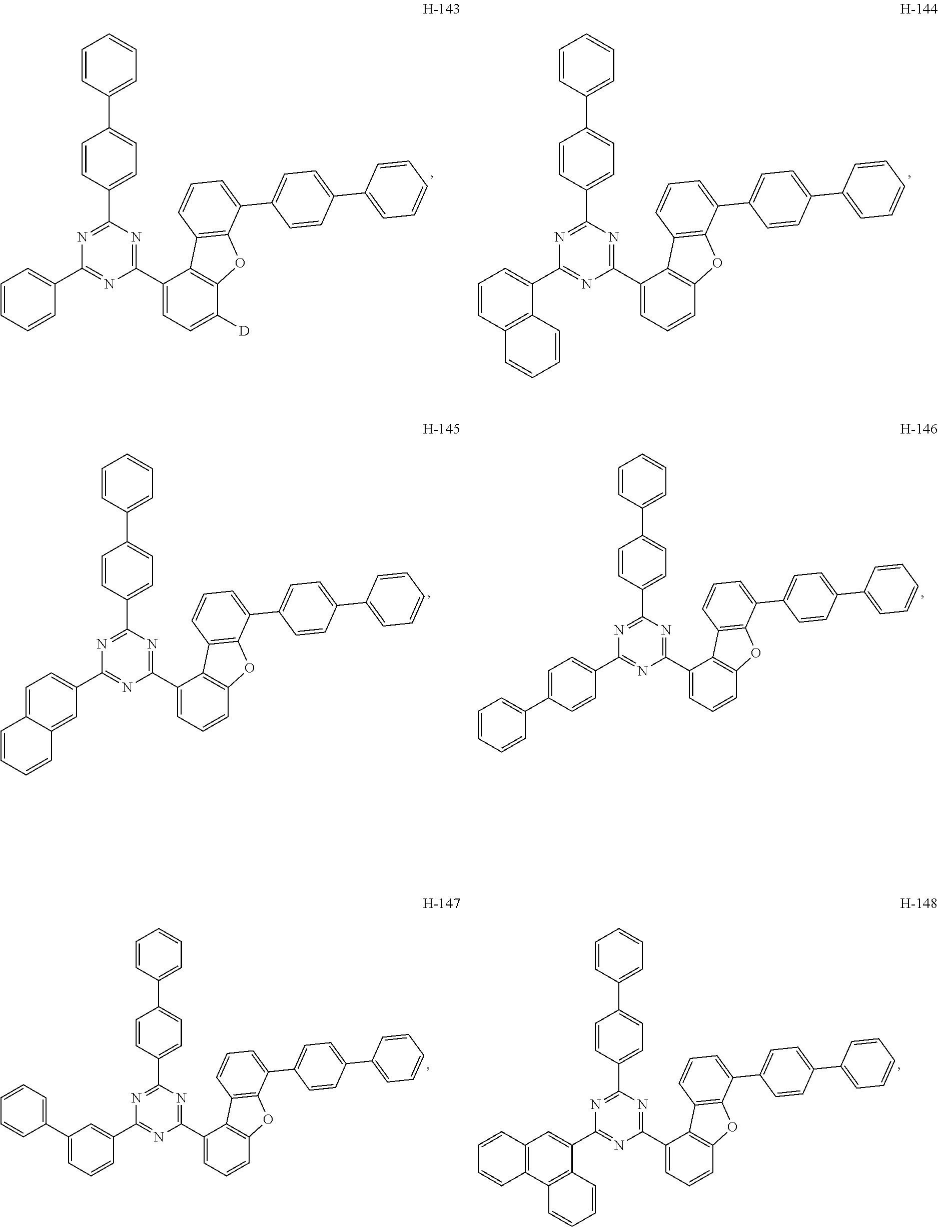

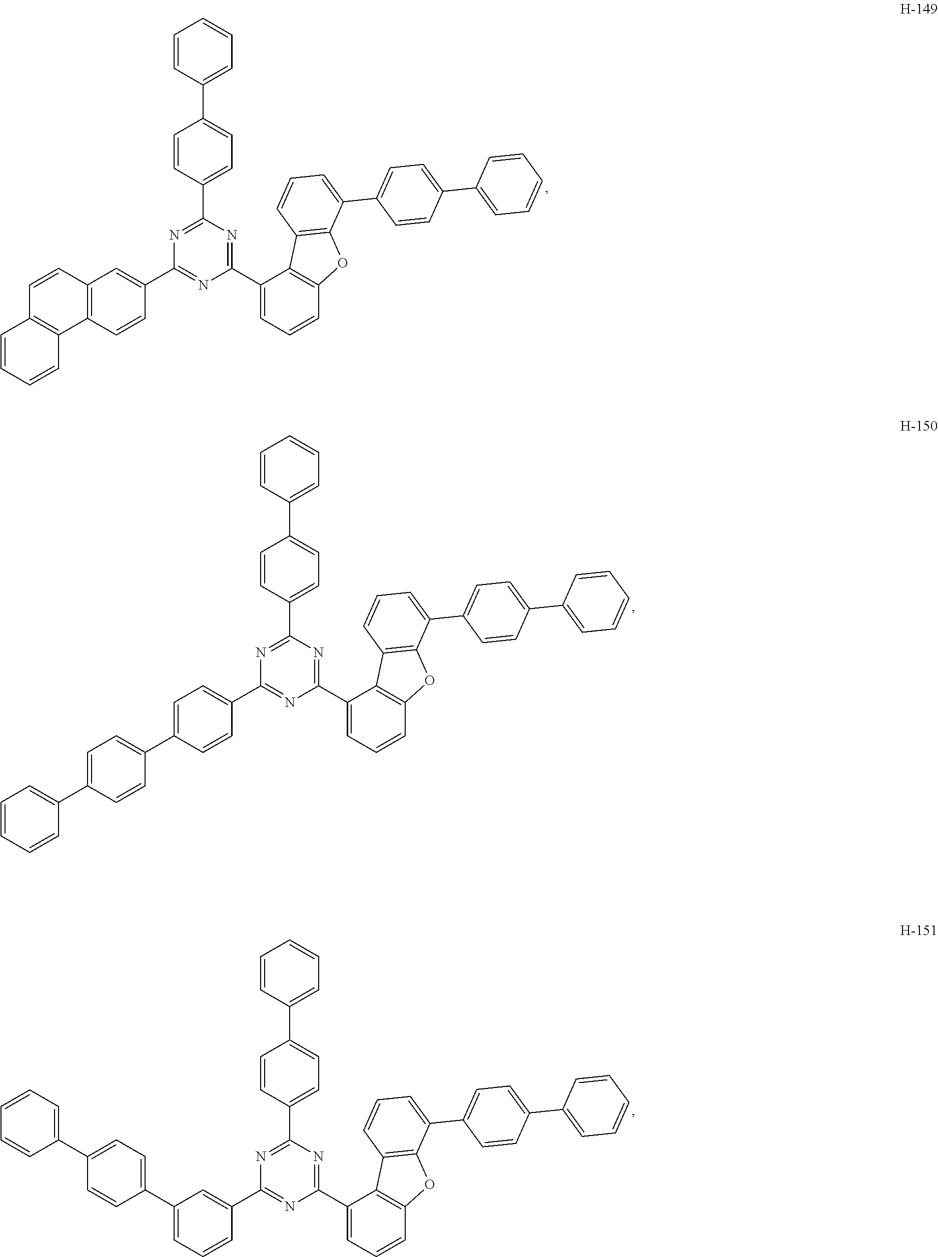 [SMILES: c1ccc(-c2ccc(-c3nc(-c4ccc5c(ccc6ccccc65)c4)nc(-c4cccc5oc6c(-c7ccc(-c8ccccc8)cc7)cccc6c45)n3)cc2)cc1 ; c1ccc(-c2ccc(-c3ccc(-c4nc(-c5ccc(-c6ccccc6)cc5)nc(-c5cccc6oc7c(-c8ccc(-c9ccccc9)cc8)cccc7c56)n4)cc3)cc2)cc1 ; c1ccc(-c2ccc(-c3cccc(-c4nc(-c5ccc(-c6ccccc6)cc5)nc(-c5cccc6oc7c(-c8ccc(-c9ccccc9)cc8)cccc7c56)n4)c3)cc2)cc1]

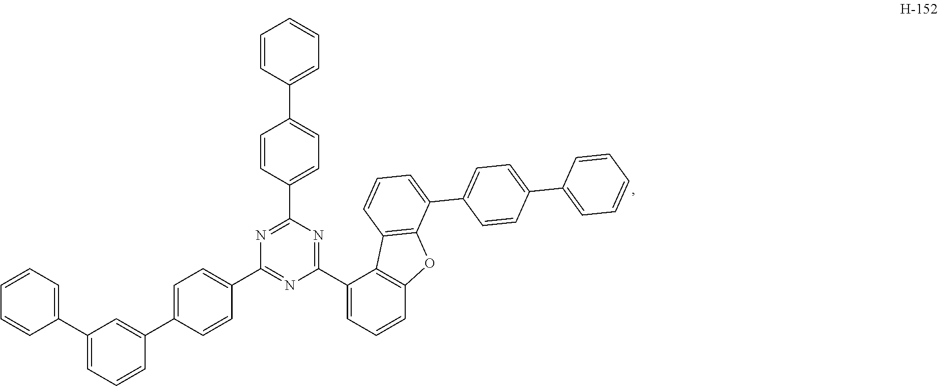 [SMILES: c1ccc(-c2ccc(-c3nc(-c4ccc(-c5cccc(-c6ccccc6)c5)cc4)nc(-c4cccc5oc6c(-c7ccc(-c8ccccc8)cc7)cccc6c45)n3)cc2)cc1]

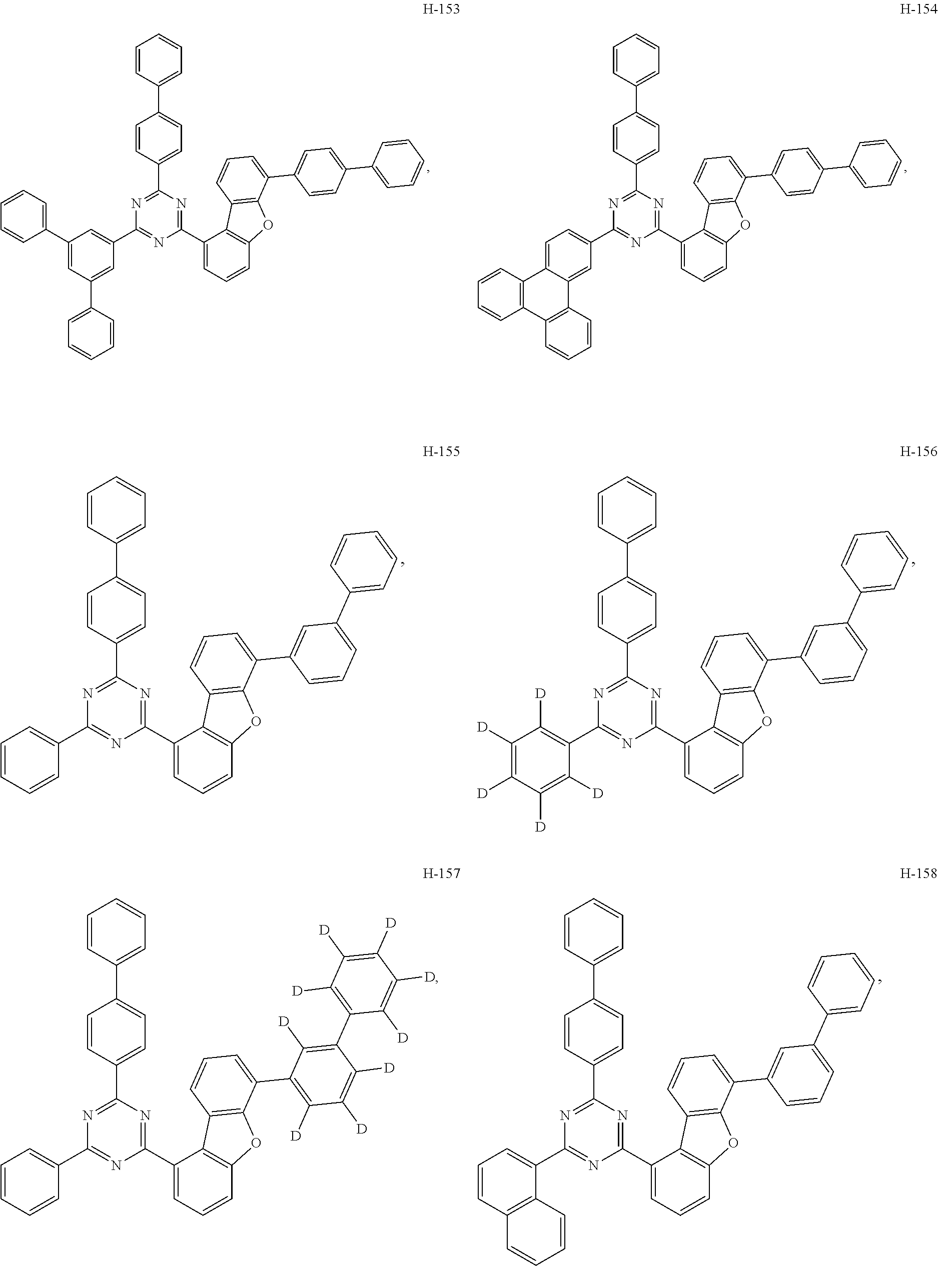

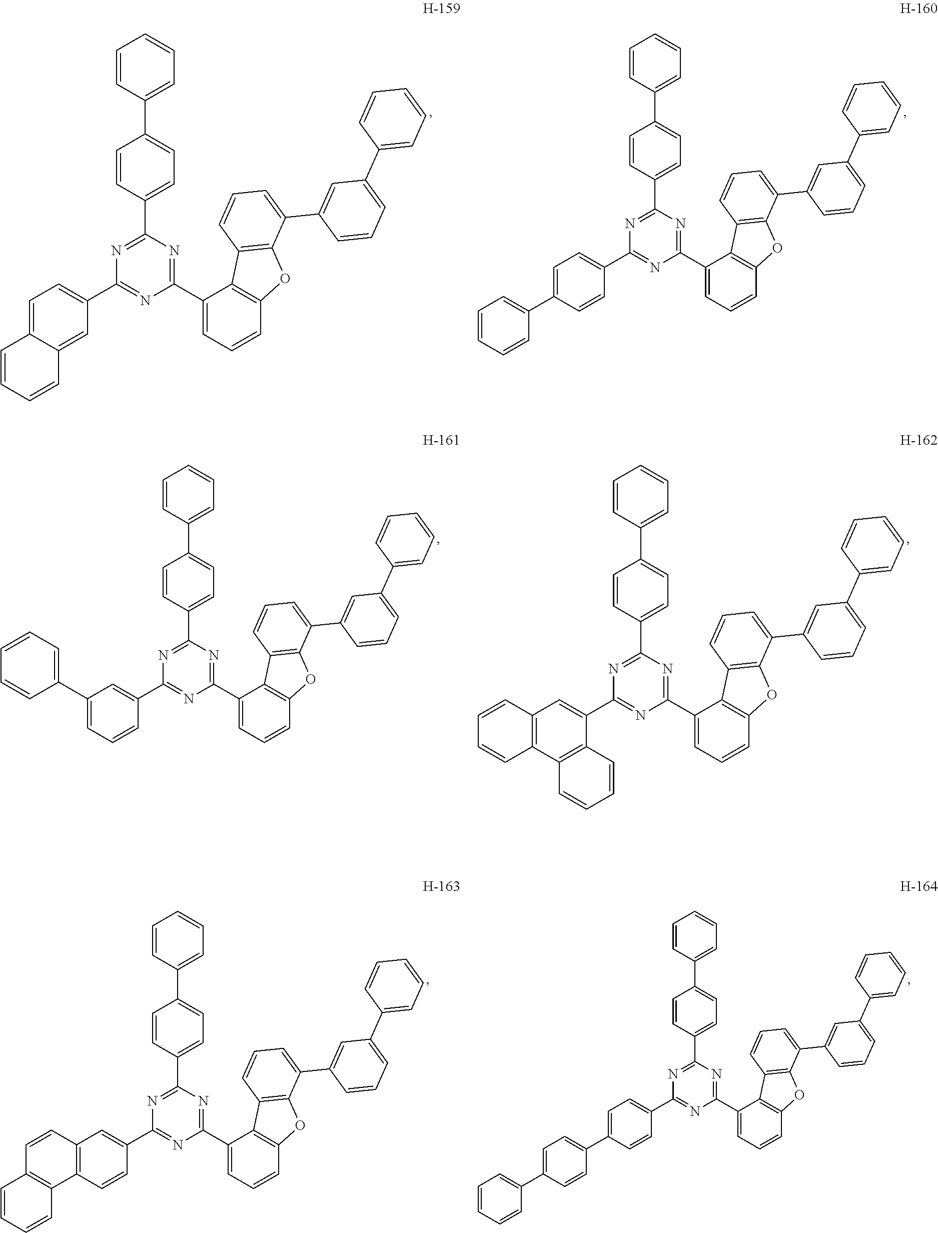

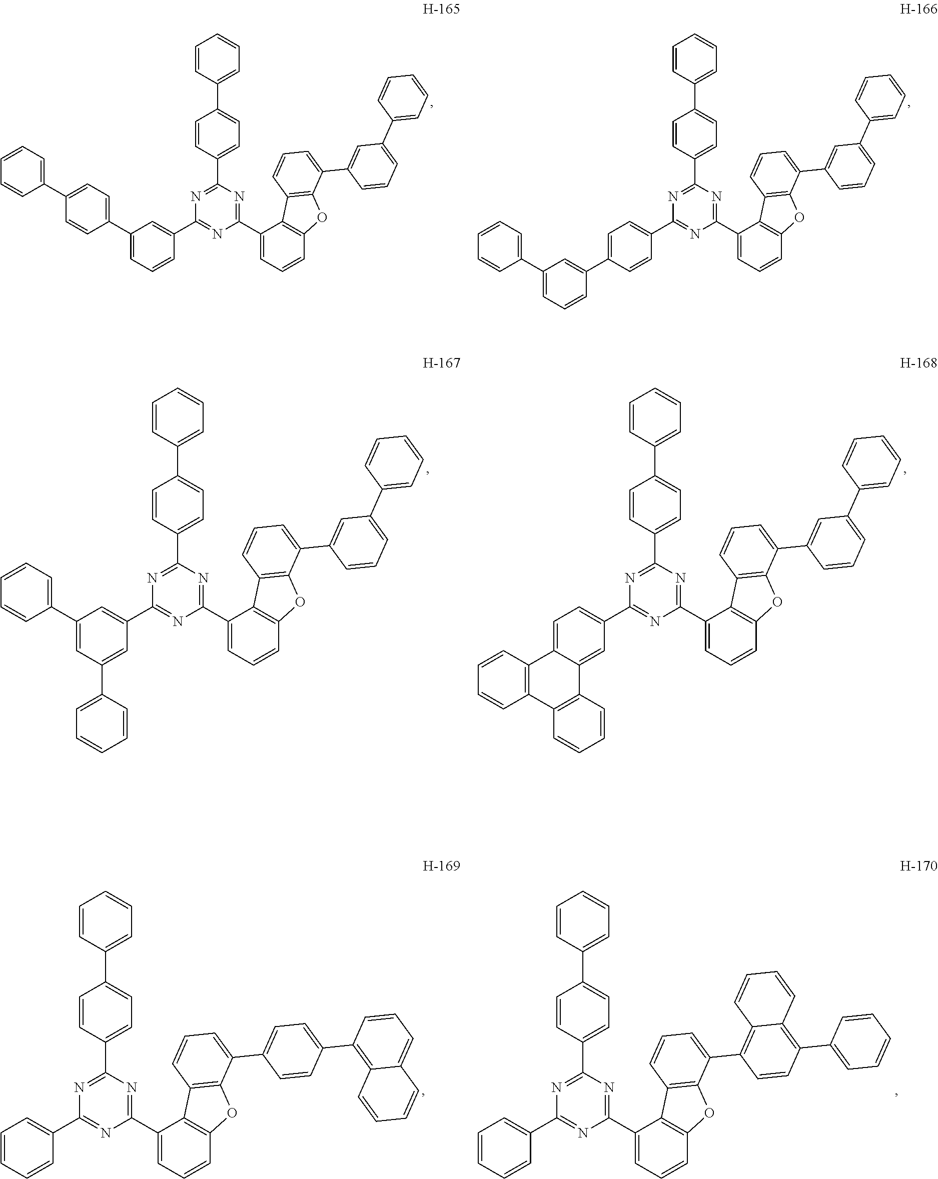

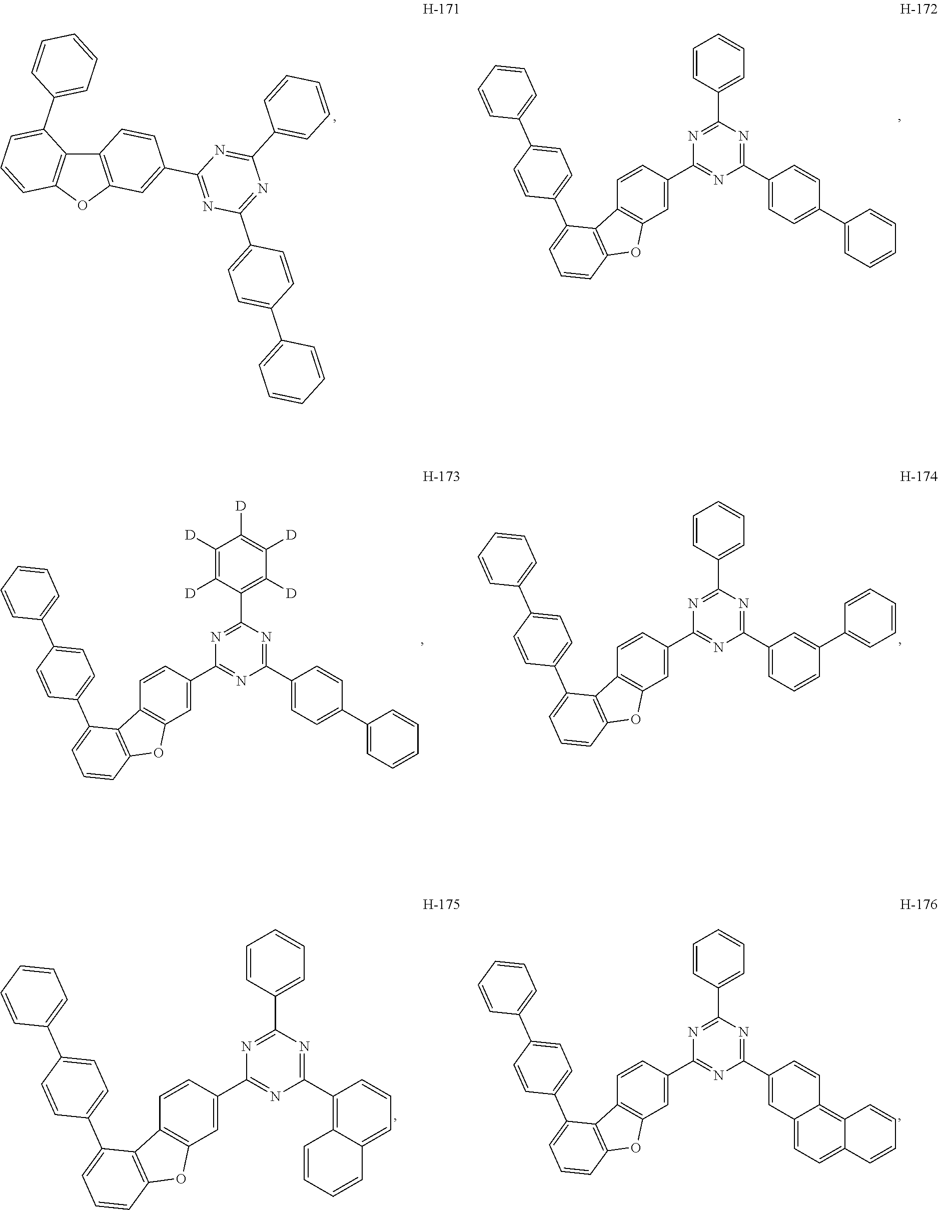

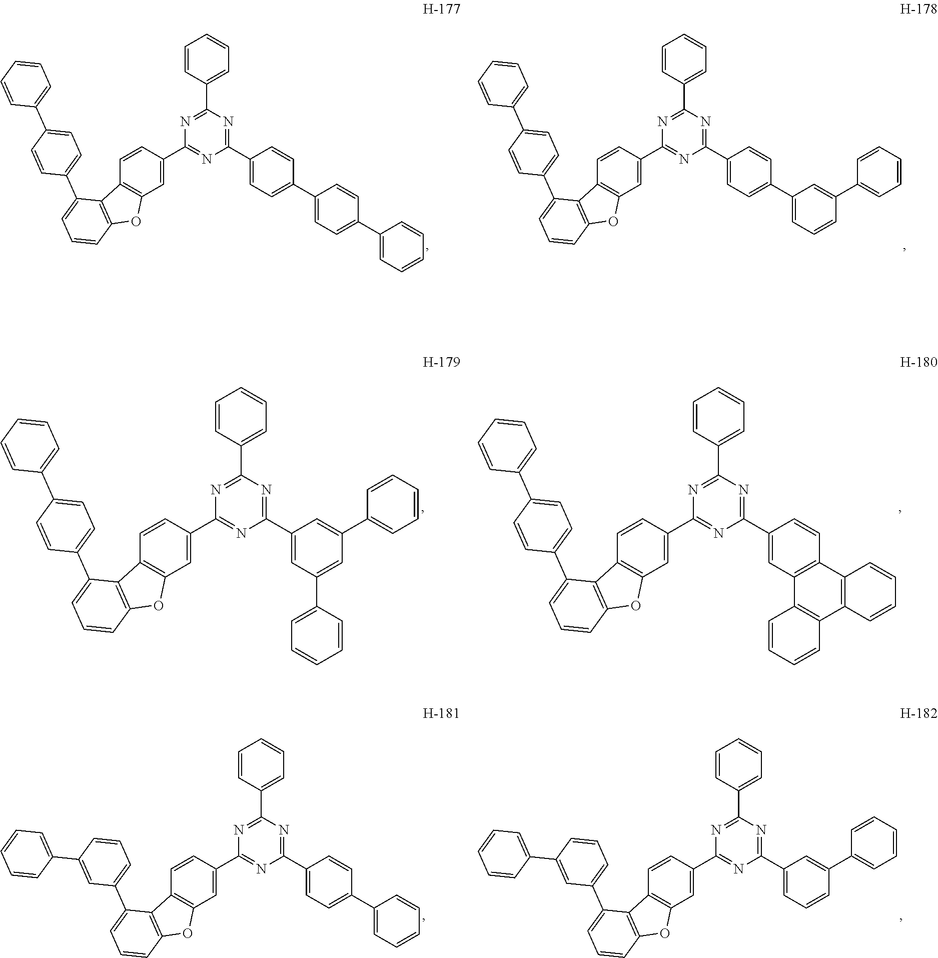

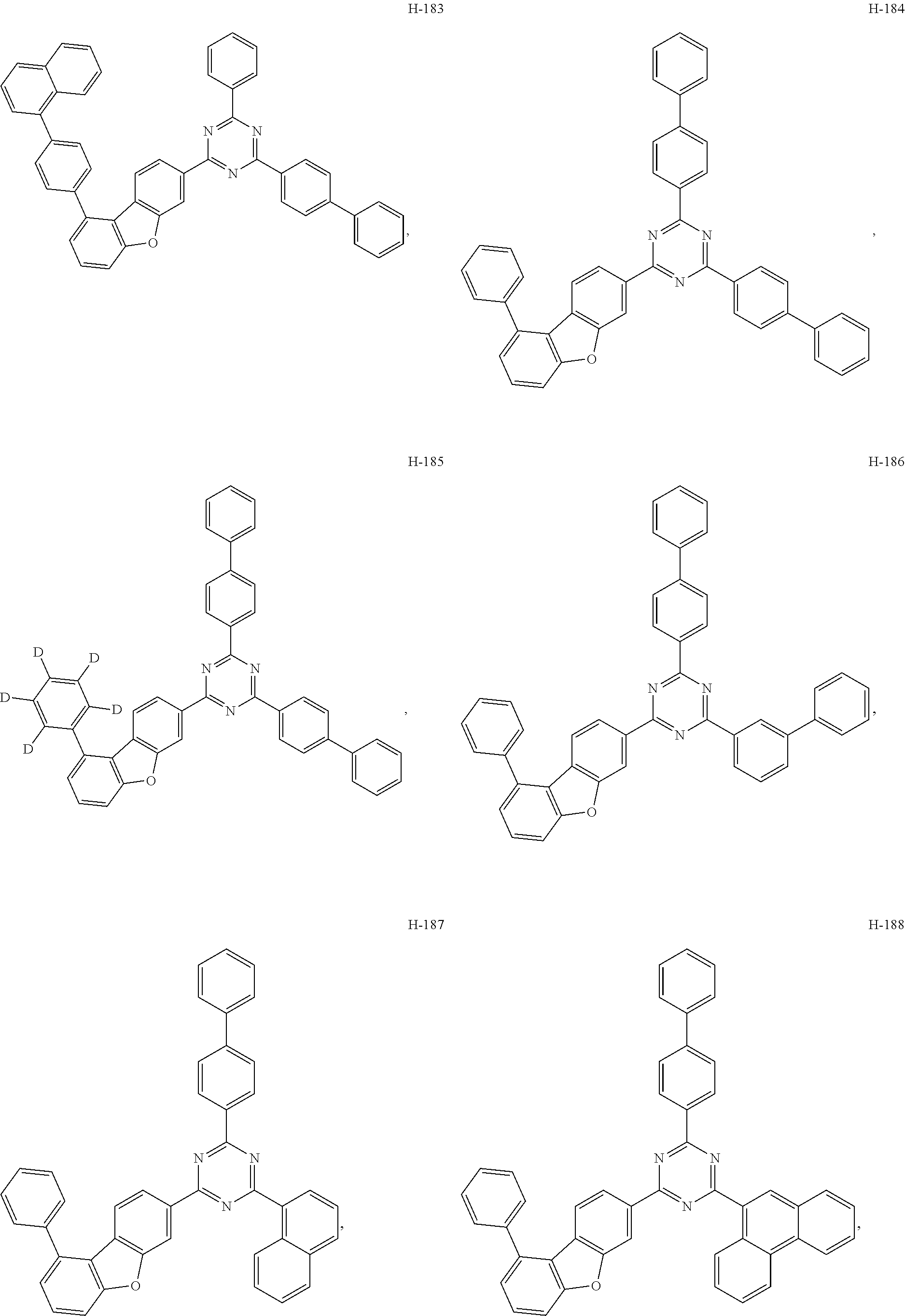

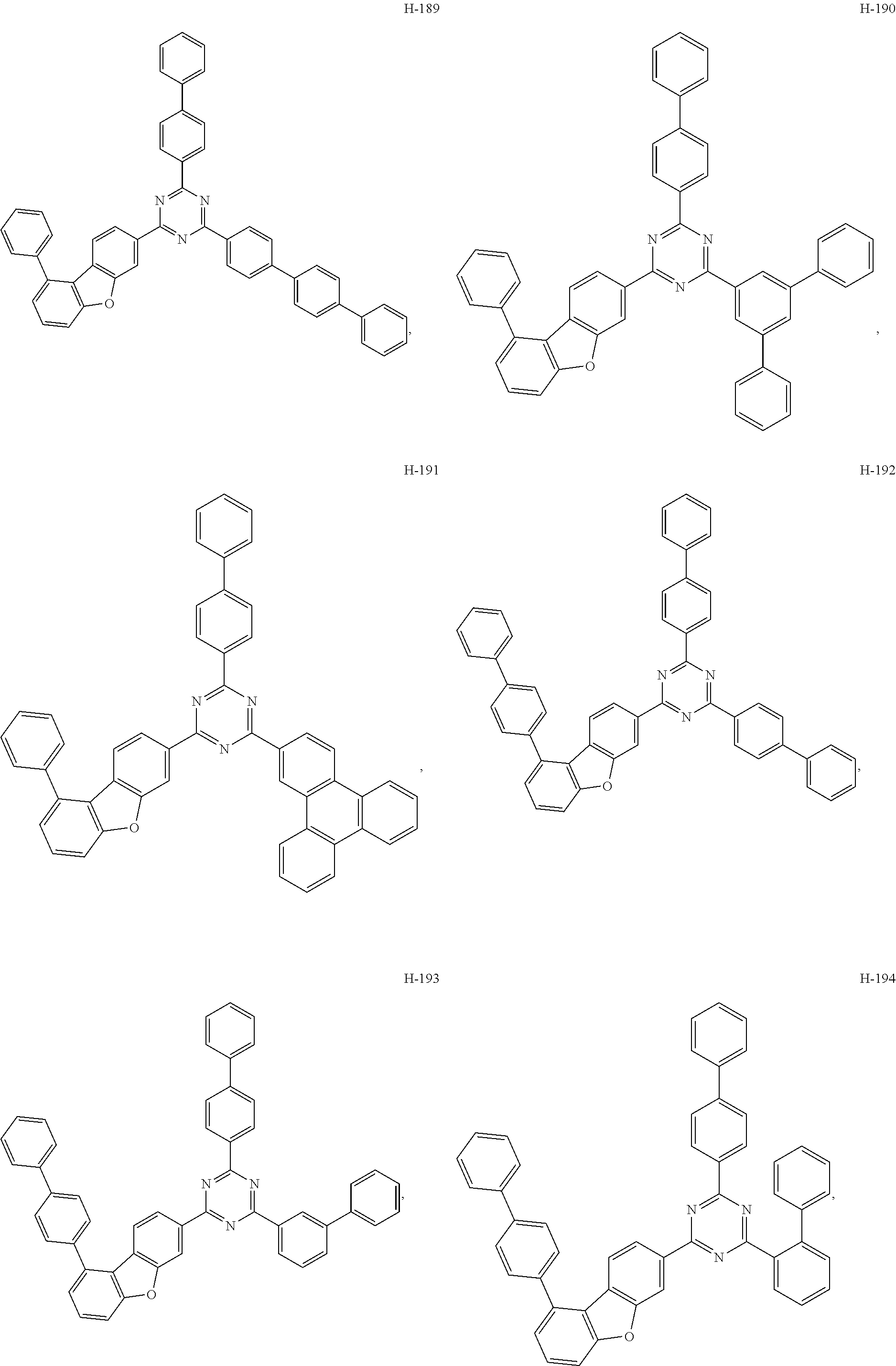

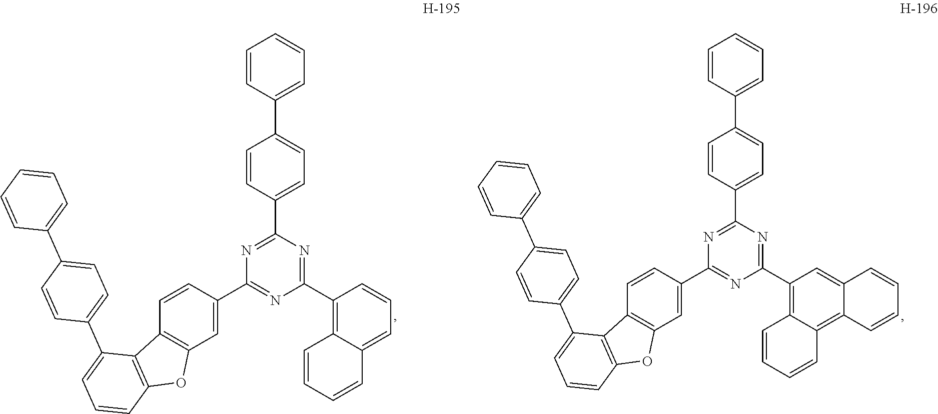 [SMILES: c1ccc(-c2ccc(-c3nc(-c4ccc5c(c4)oc4cccc(-c6ccc(-c7ccccc7)cc6)c45)nc(-c4cccc5ccccc45)n3)cc2)cc1 ; c1ccc(-c2ccc(-c3nc(-c4ccc5c(c4)oc4cccc(-c6ccc(-c7ccccc7)cc6)c45)nc(-c4cc5ccccc5c5ccccc45)n3)cc2)cc1]

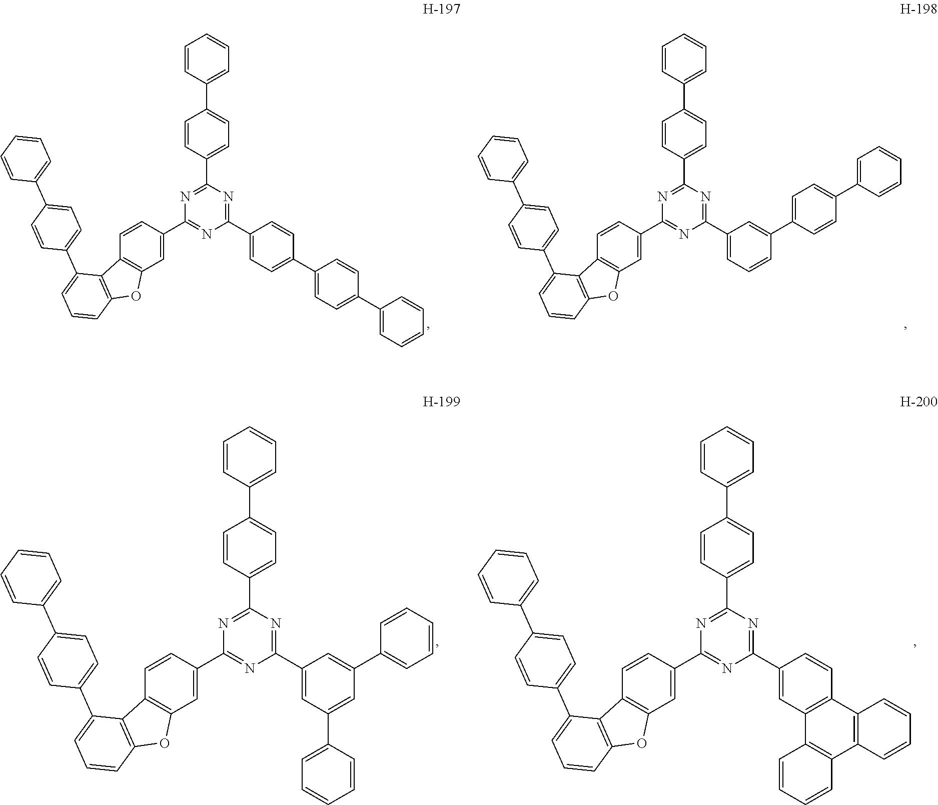 [SMILES: c1ccc(-c2ccc(-c3ccc(-c4nc(-c5ccc(-c6ccccc6)cc5)nc(-c5ccc6c(c5)oc5cccc(-c7ccc(-c8ccccc8)cc7)c56)n4)cc3)cc2)cc1 ; c1ccc(-c2ccc(-c3cccc(-c4nc(-c5ccc(-c6ccccc6)cc5)nc(-c5ccc6c(c5)oc5cccc(-c7ccc(-c8ccccc8)cc7)c56)n4)c3)cc2)cc1 ; c1ccc(-c2ccc(-c3nc(-c4cc(-c5ccccc5)cc(-c5ccccc5)c4)nc(-c4ccc5c(c4)oc4cccc(-c6ccc(-c7ccccc7)cc6)c45)n3)cc2)cc1 ; c1ccc(-c2ccc(-c3nc(-c4ccc5c(c4)oc4cccc(-c6ccc(-c7ccccc7)cc6)c45)nc(-c4ccc5c6ccccc6c6ccccc6c5c4)n3)cc2)cc1]

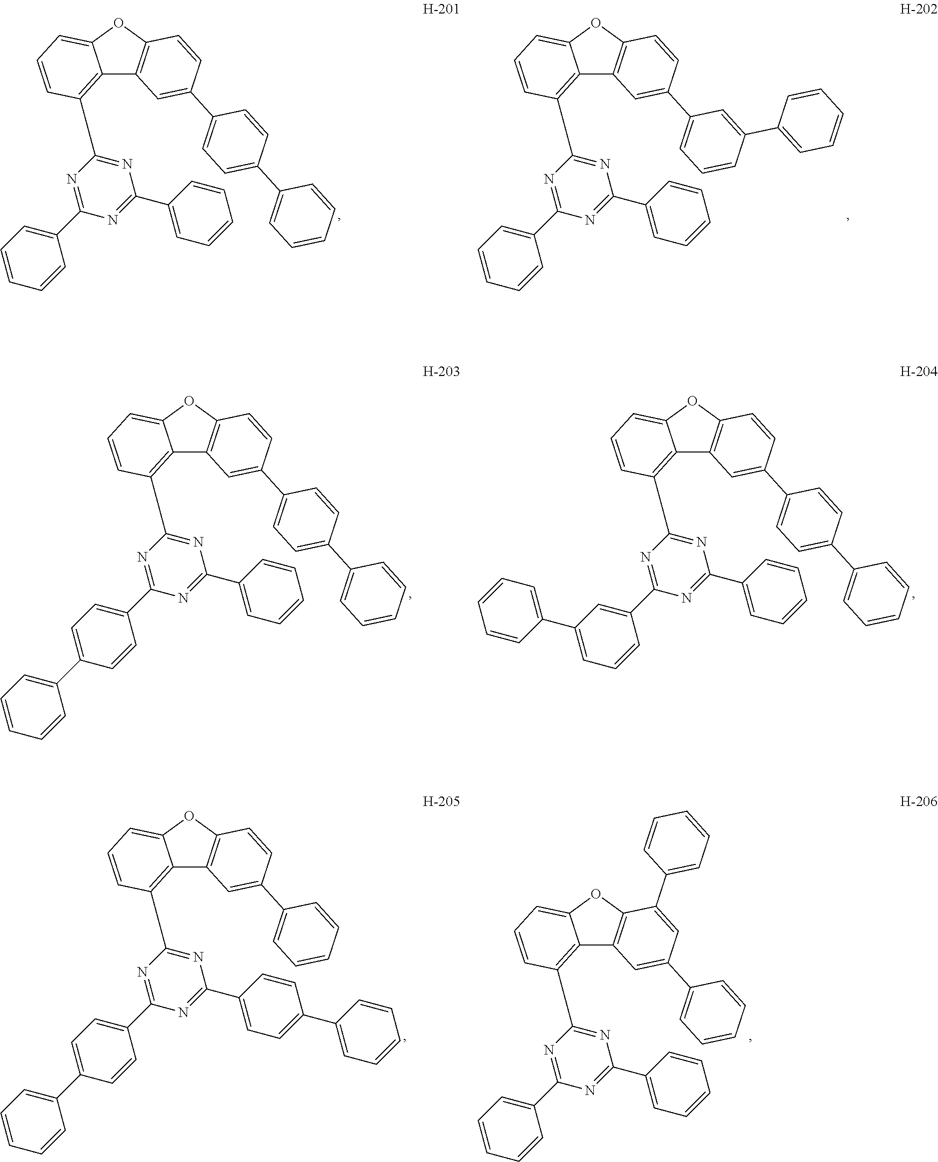 [SMILES: c1ccc(-c2ccc(-c3ccc4oc5cccc(-c6nc(-c7ccccc7)nc(-c7ccccc7)n6)c5c4c3)cc2)cc1 ; c1ccc(-c2cccc(-c3ccc4oc5cccc(-c6nc(-c7ccccc7)nc(-c7ccccc7)n6)c5c4c3)c2)cc1 ; c1ccc(-c2ccc(-c3ccc4oc5cccc(-c6nc(-c7ccccc7)nc(-c7ccc(-c8ccccc8)cc7)n6)c5c4c3)cc2)cc1 ; c1ccc(-c2ccc(-c3ccc4oc5cccc(-c6nc(-c7ccccc7)nc(-c7cccc(-c8ccccc8)c7)n6)c5c4c3)cc2)cc1 ; c1ccc(-c2ccc(-c3nc(-c4ccc(-c5ccccc5)cc4)nc(-c4cccc5oc6ccc(-c7ccccc7)cc6c45)n3)cc2)cc1 ; c1ccc(-c2cc(-c3ccccc3)c3oc4cccc(-c5nc(-c6ccccc6)nc(-c6ccccc6)n5)c4c3c2)cc1]

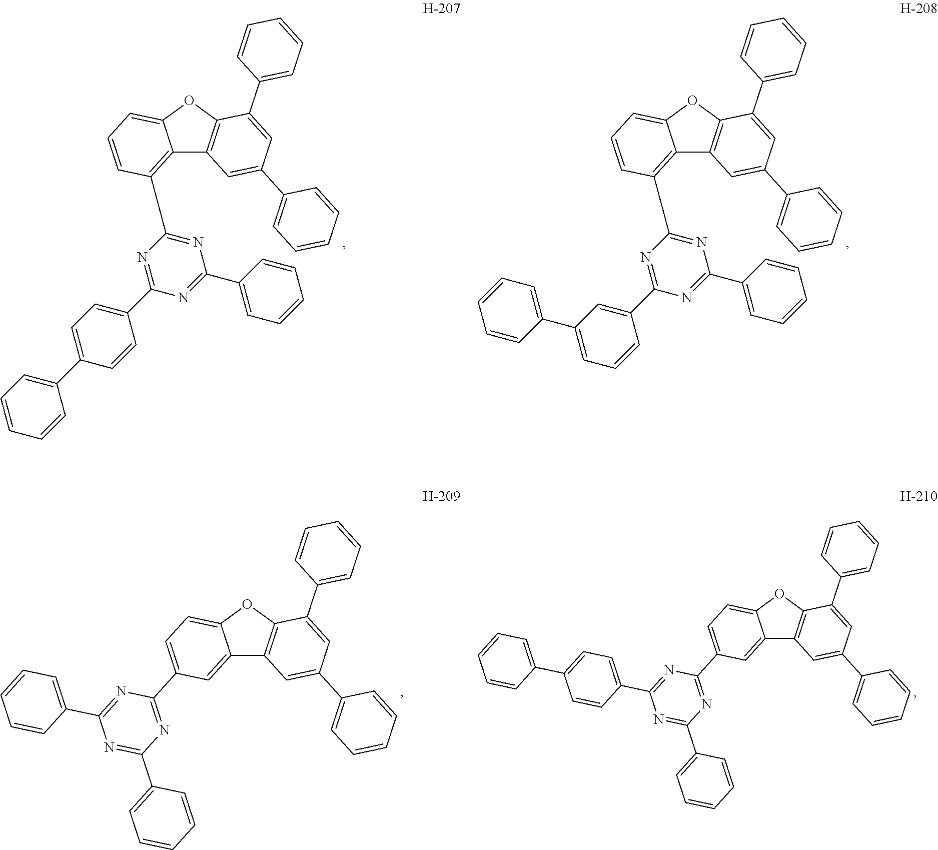 [SMILES: c1ccc(-c2ccc(-c3nc(-c4ccccc4)nc(-c4cccc5oc6c(-c7ccccc7)cc(-c7ccccc7)cc6c45)n3)cc2)cc1 ; c1ccc(-c2cccc(-c3nc(-c4ccccc4)nc(-c4cccc5oc6c(-c7ccccc7)cc(-c7ccccc7)cc6c45)n3)c2)cc1 ; c1ccc(-c2cc(-c3ccccc3)c3oc4ccc(-c5nc(-c6ccccc6)nc(-c6ccccc6)n5)cc4c3c2)cc1 ; c1ccc(-c2ccc(-c3nc(-c4ccccc4)nc(-c4ccc5oc6c(-c7ccccc7)cc(-c7ccccc7)cc6c5c4)n3)cc2)cc1]

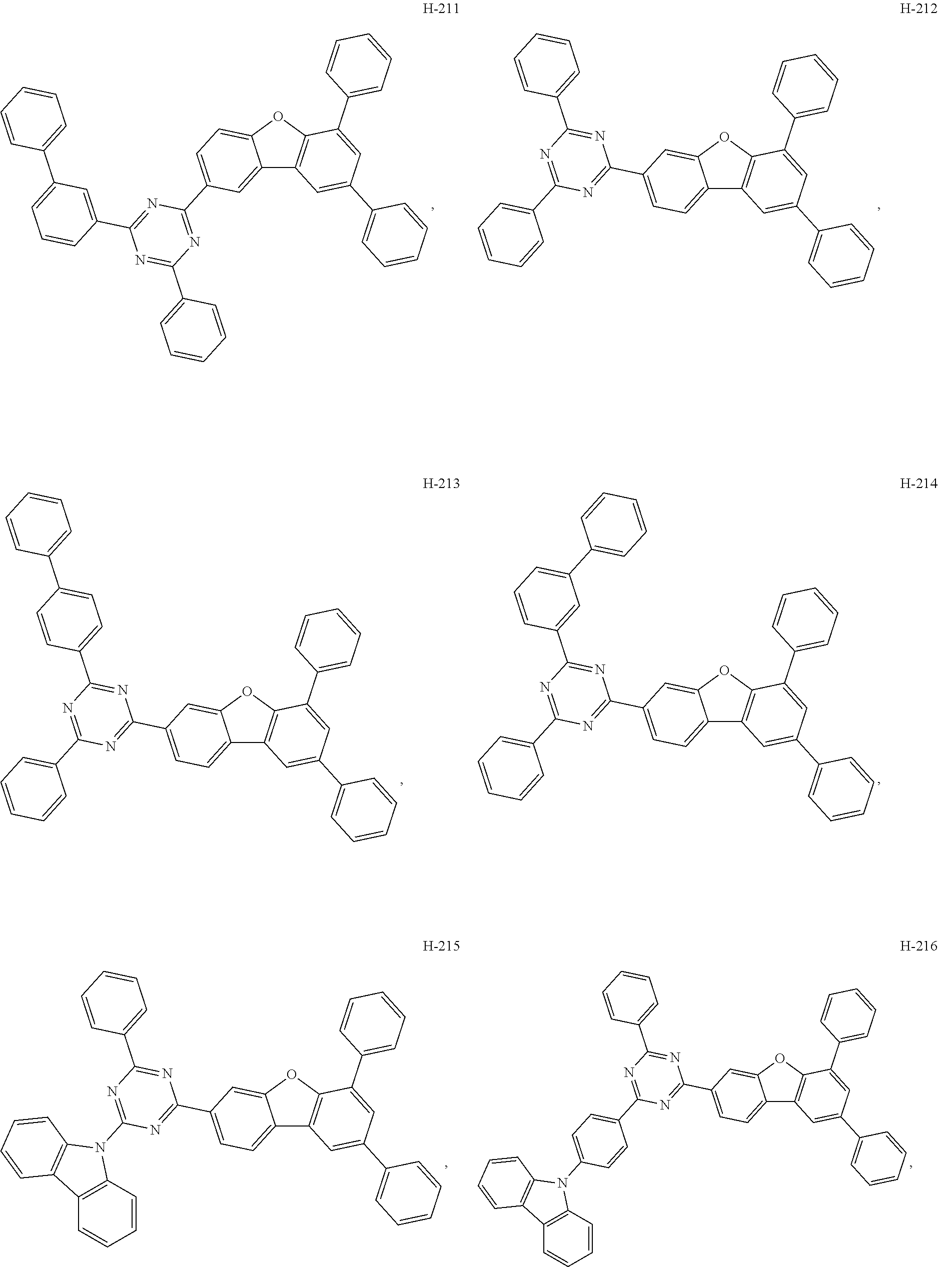

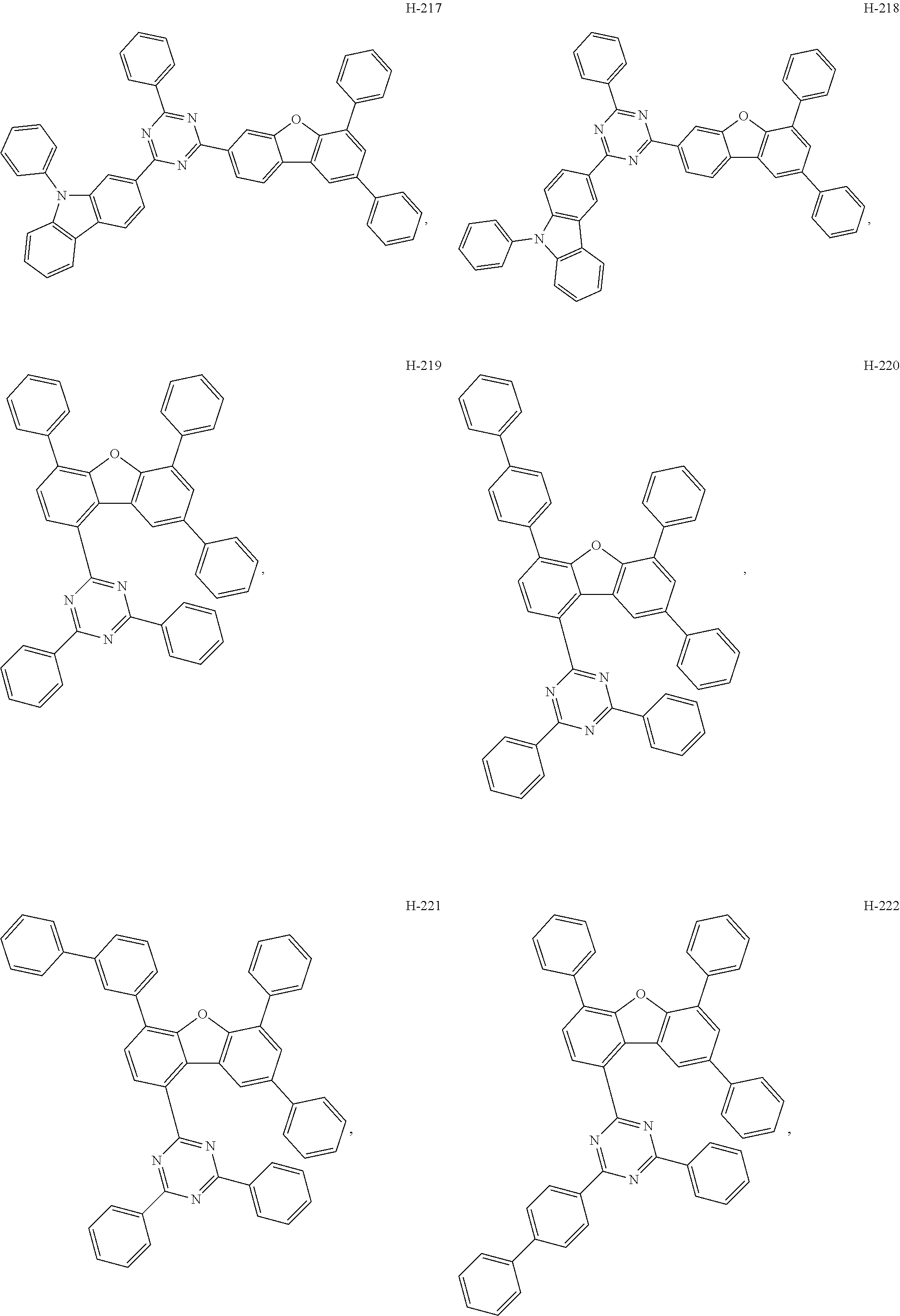

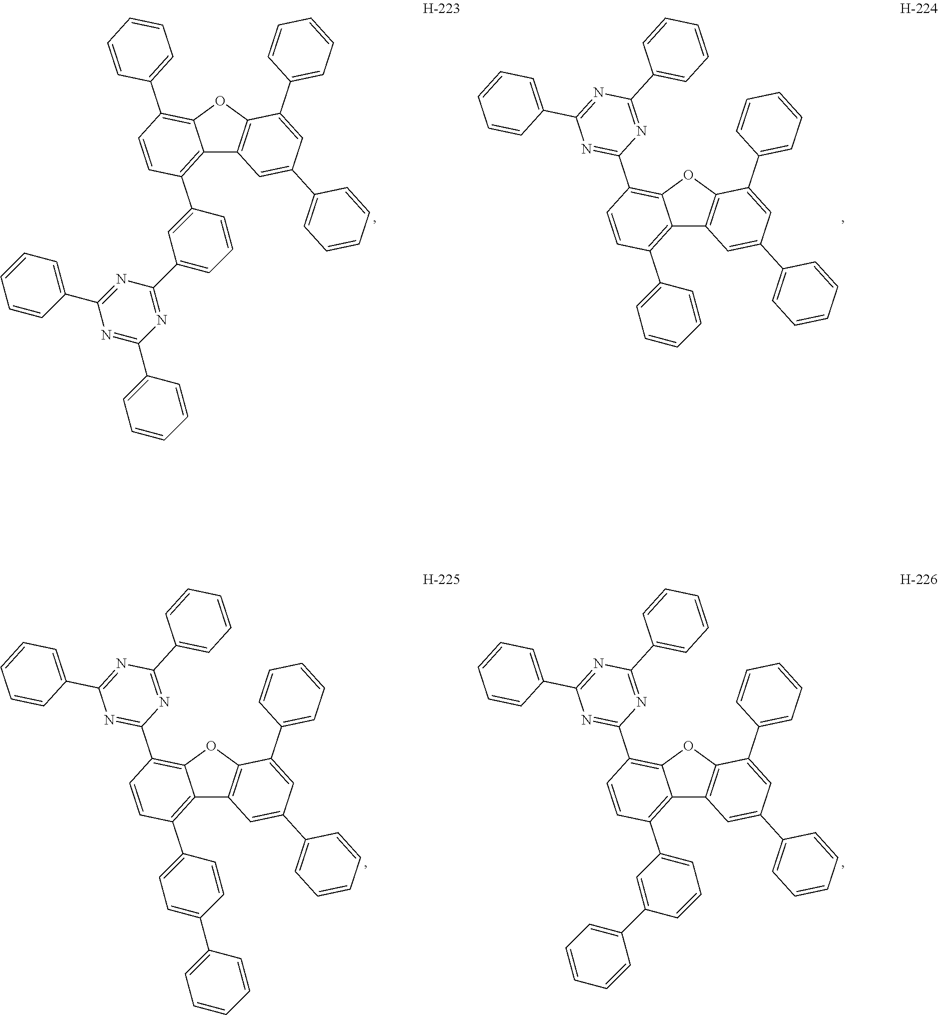 [SMILES: c1ccc(-c2cc(-c3ccccc3)c3oc4c(-c5ccccc5)ccc(-c5cccc(-c6nc(-c7ccccc7)nc(-c7ccccc7)n6)c5)c4c3c2)cc1 ; c1ccc(-c2cc(-c3ccccc3)c3oc4c(-c5nc(-c6ccccc6)nc(-c6ccccc6)n5)ccc(-c5ccccc5)c4c3c2)cc1 ; c1ccc(-c2ccc(-c3ccc(-c4nc(-c5ccccc5)nc(-c5ccccc5)n4)c4oc5c(-c6ccccc6)cc(-c6ccccc6)cc5c34)cc2)cc1 ; c1ccc(-c2cccc(-c3ccc(-c4nc(-c5ccccc5)nc(-c5ccccc5)n4)c4oc5c(-c6ccccc6)cc(-c6ccccc6)cc5c34)c2)cc1]

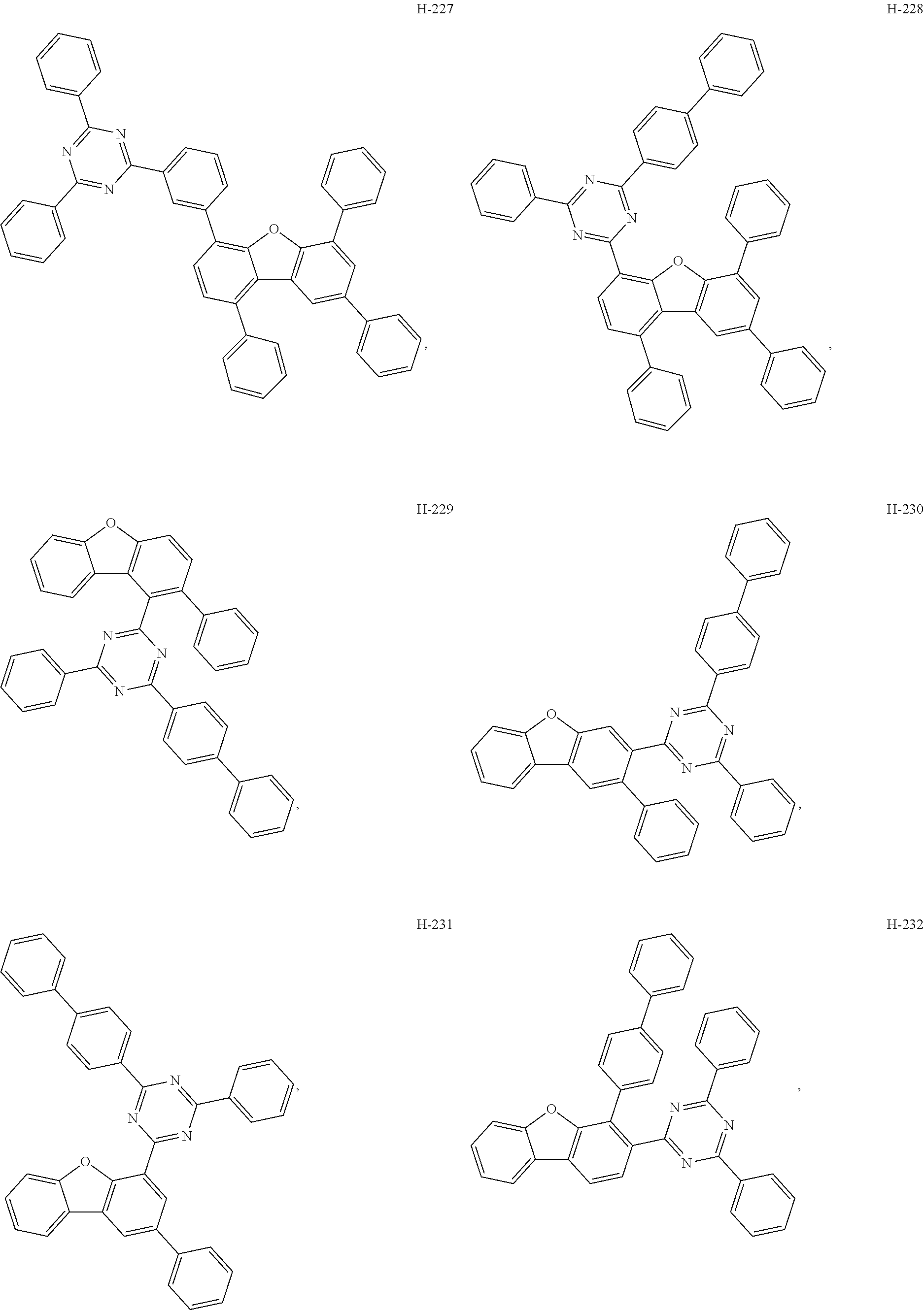

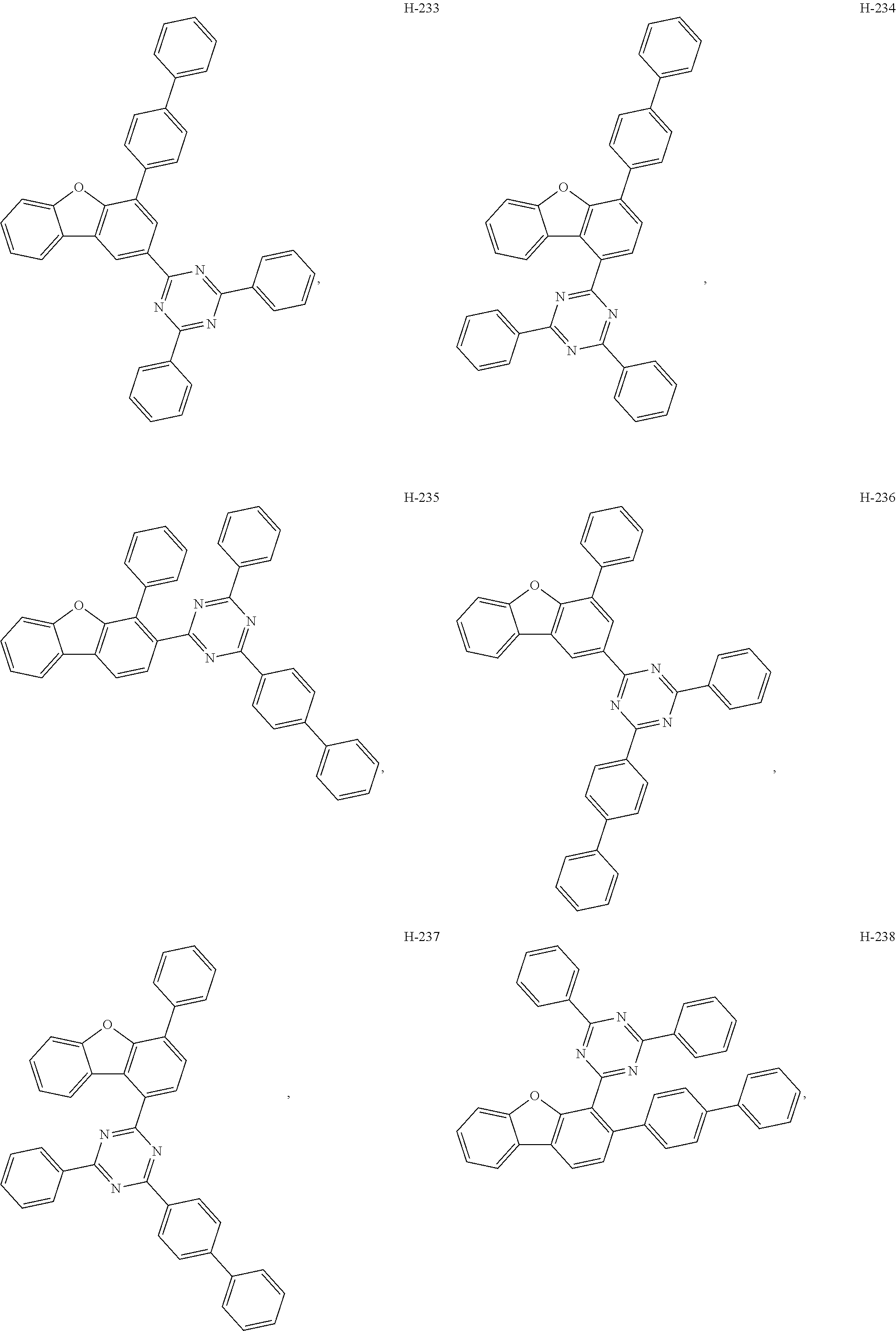

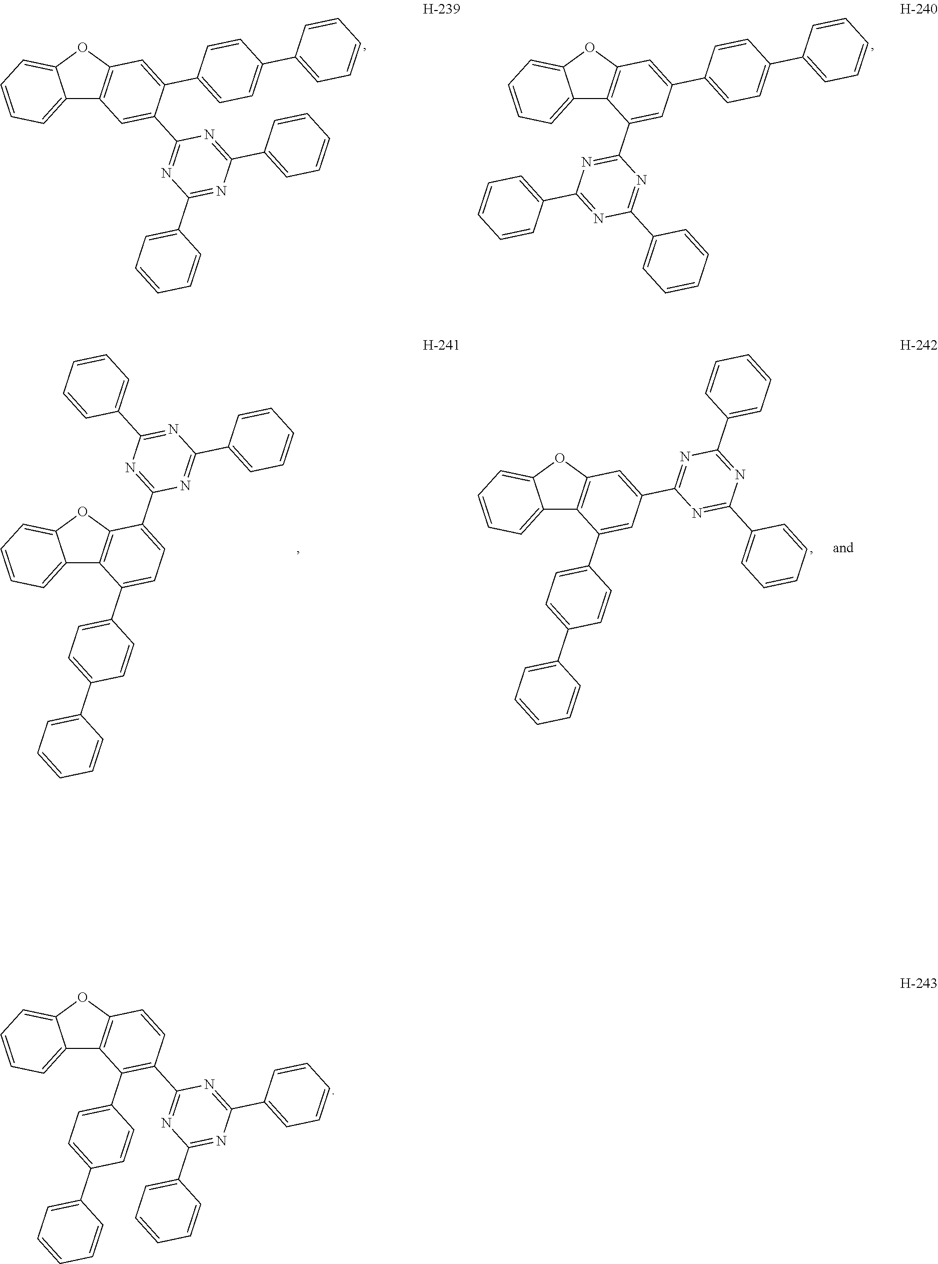 [SMILES: c1ccc(-c2ccc(-c3cc4oc5ccccc5c4cc3-c3nc(-c4ccccc4)nc(-c4ccccc4)n3)cc2)cc1 ; c1ccc(-c2ccc(-c3cc(-c4nc(-c5ccccc5)nc(-c5ccccc5)n4)c4c(c3)oc3ccccc34)cc2)cc1 ; c1ccc(-c2ccc(-c3ccc(-c4nc(-c5ccccc5)nc(-c5ccccc5)n4)c4oc5ccccc5c34)cc2)cc1 ; c1ccc(-c2ccc(-c3cc(-c4nc(-c5ccccc5)nc(-c5ccccc5)n4)cc4oc5ccccc5c34)cc2)cc1 ; c1ccc(-c2ccc(-c3c(-c4nc(-c5ccccc5)nc(-c5ccccc5)n4)ccc4oc5ccccc5c34)cc2)cc1]

27. The electroluminescent device according to claim 23, wherein the second host compound has a structure represented by Formula 5: 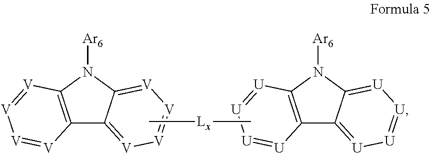
wherein,
Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or combinations thereof,
V is, at each occurrence identically or differently, selected from C, CRᵥ or N, and at least one of V is C and is attached to Lₓ;
U is, at each occurrence identically or differently, selected from C, CRᵤ or N, and at least one of U is C and is attached to Lₓ;
Rᵥ and Rᵤ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a substituted or unsubstituted alkylgermanyl having 3 to 20 carbon atoms, a substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,
Ar₆ is, at each occurrence identically or differently, selected from substituted or unsubstituted aryl having 6 to 30 carbon atoms, substituted or unsubstituted heteroaryl having 3 to 30 carbon atoms or combinations thereof,
adjacent substituents Rᵥ and Rᵤ can be optionally joined to form a ring;
preferably, the second host compound has a structure represented by one of Formula 5-a to Formula 5-j:

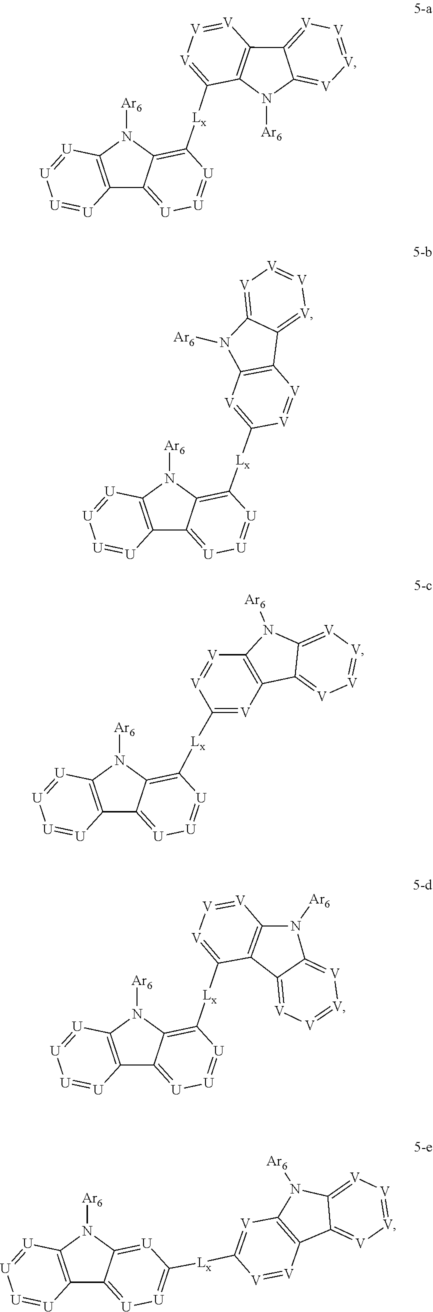

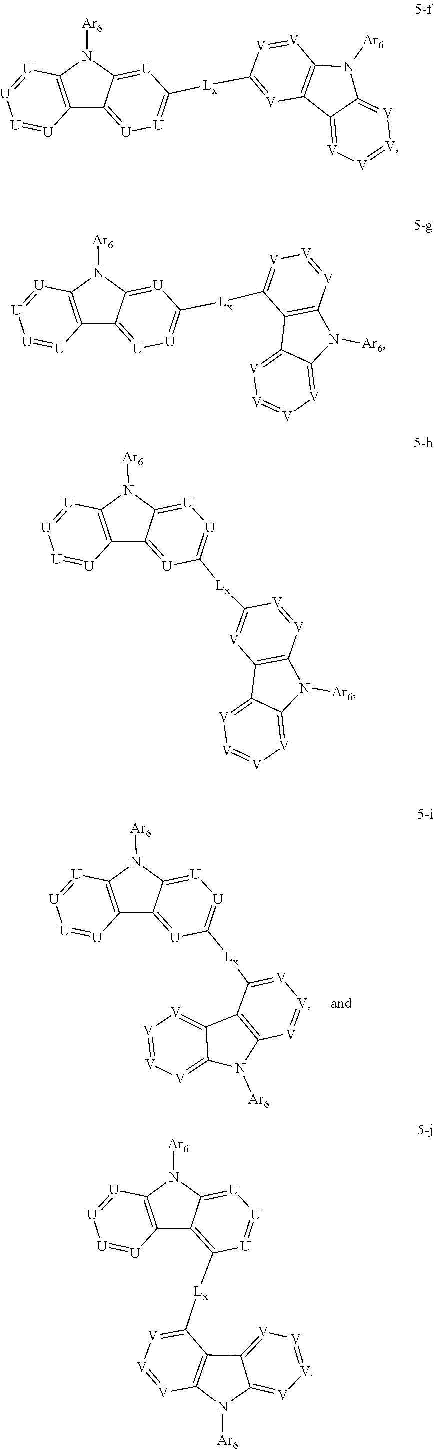

28. The electroluminescent device according to claim 27, wherein the second host compound is selected from the group consisting of:

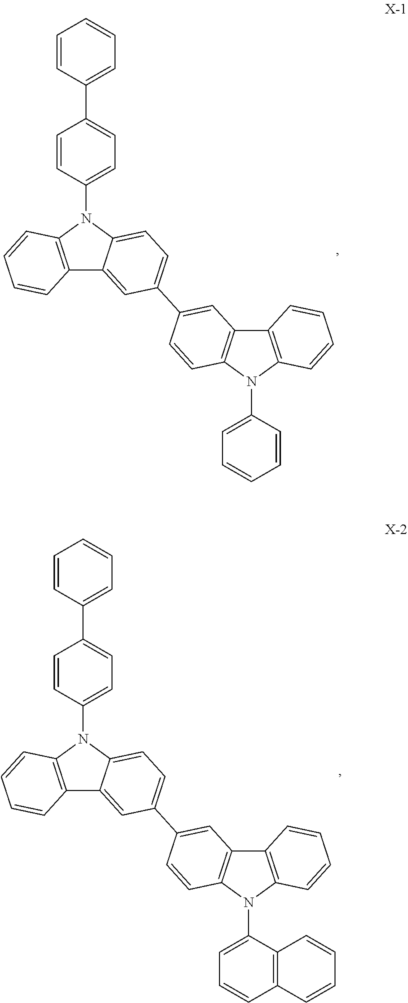 [SMILES: c1ccc(-c2ccc(-n3c4ccccc4c4cc(-c5ccc6c(c5)c5ccccc5n6-c5ccccc5)ccc43)cc2)cc1 ; c1ccc(-c2ccc(-n3c4ccccc4c4cc(-c5ccc6c(c5)c5ccccc5n6-c5cccc6ccccc56)ccc43)cc2)cc1]

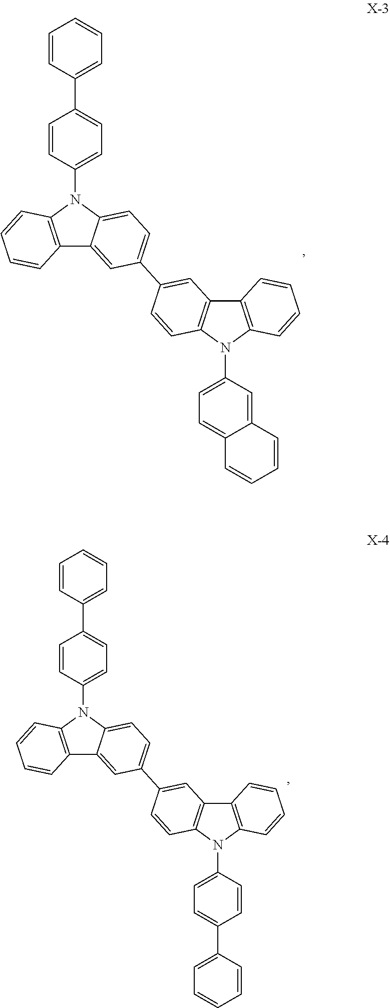 [SMILES: c1ccc(-c2ccc(-n3c4ccccc4c4cc(-c5ccc6c(c5)c5ccccc5n6-c5ccc6ccccc6c5)ccc43)cc2)cc1 ; c1ccc(-c2ccc(-n3c4ccccc4c4cc(-c5ccc6c(c5)c5ccccc5n6-c5ccc(-c6ccccc6)cc5)ccc43)cc2)cc1]

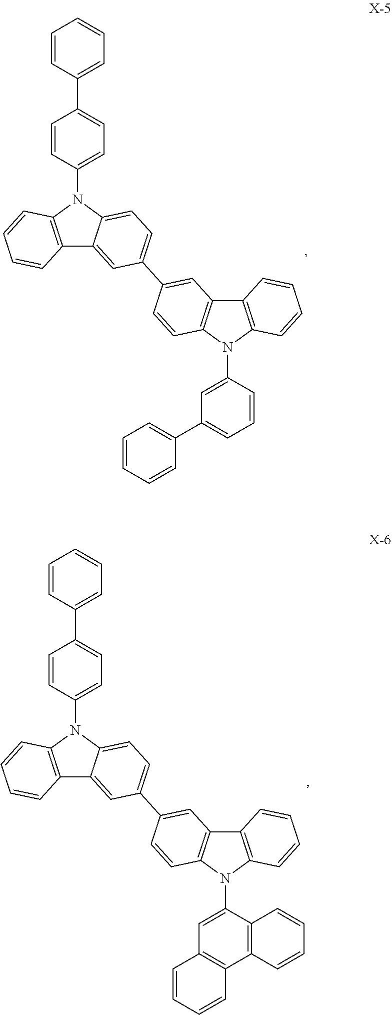 [SMILES: c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5cc6ccccc6c6ccccc56)ccc43)cc2)cc1]

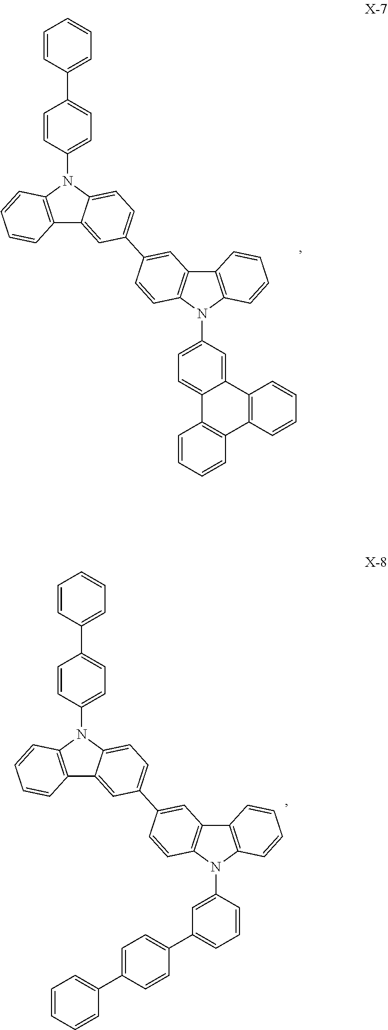 [SMILES: c1ccc(-c2ccc(-n3c4ccccc4c4cc(-c5ccc6c(c5)c5ccccc5n6-c5ccc6c7ccccc7c7ccccc7c6c5)ccc43)cc2)cc1 ; c1ccc(-c2ccc(-c3cccc(-n4c5ccccc5c5cc(-c6ccc7c(c6)c6ccccc6n7-c6ccc(-c7ccccc7)cc6)ccc54)c3)cc2)cc1]

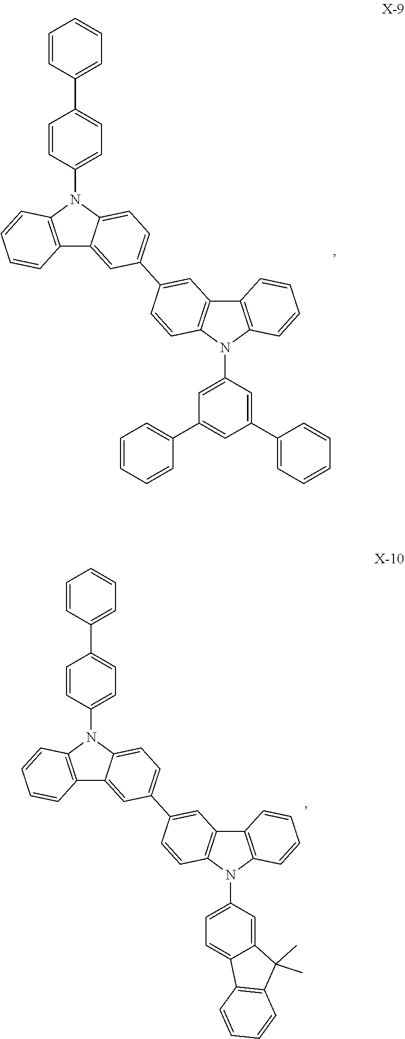 [SMILES: c1ccc(-c2ccc(-n3c4ccccc4c4cc(-c5ccc6c(c5)c5ccccc5n6-c5cc(-c6ccccc6)cc(-c6ccccc6)c5)ccc43)cc2)cc1 ; CC1(C)c2ccccc2-c2ccc(-n3c4ccccc4c4cc(-c5ccc6c(c5)c5ccccc5n6-c5ccc(-c6ccccc6)cc5)ccc43)cc21]

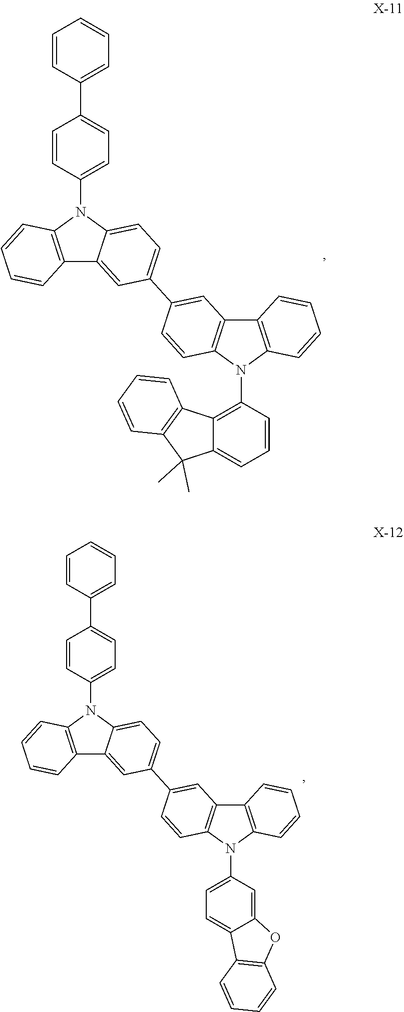 [SMILES: CC1(C)c2ccccc2-c2c(-n3c4ccccc4c4cc(-c5ccc6c(c5)c5ccccc5n6-c5ccc(-c6ccccc6)cc5)ccc43)cccc21 ; c1ccc(-c2ccc(-n3c4ccccc4c4cc(-c5ccc6c(c5)c5ccccc5n6-c5ccc6c(c5)oc5ccccc56)ccc43)cc2)cc1]

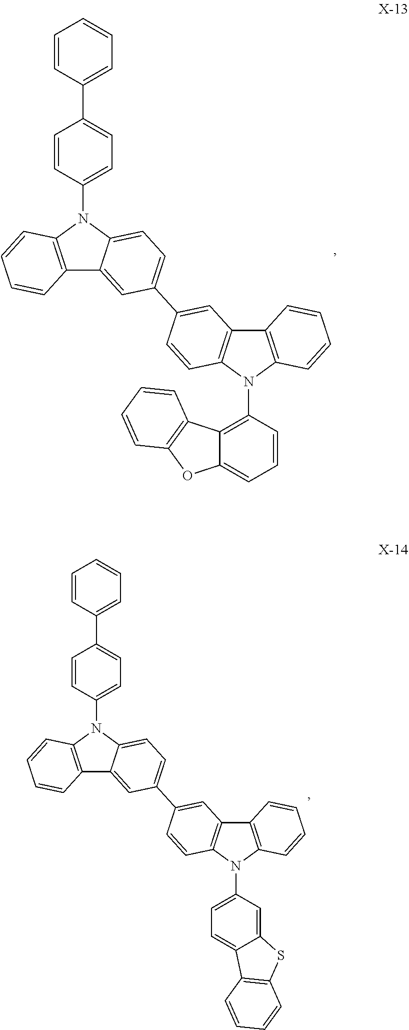 [SMILES: c1ccc(-c2ccc(-n3c4ccccc4c4cc(-c5ccc6c(c5)c5ccccc5n6-c5cccc6oc7ccccc7c56)ccc43)cc2)cc1 ; c1ccc(-c2ccc(-n3c4ccccc4c4cc(-c5ccc6c(c5)c5ccccc5n6-c5ccc6c(c5)sc5ccccc56)ccc43)cc2)cc1]

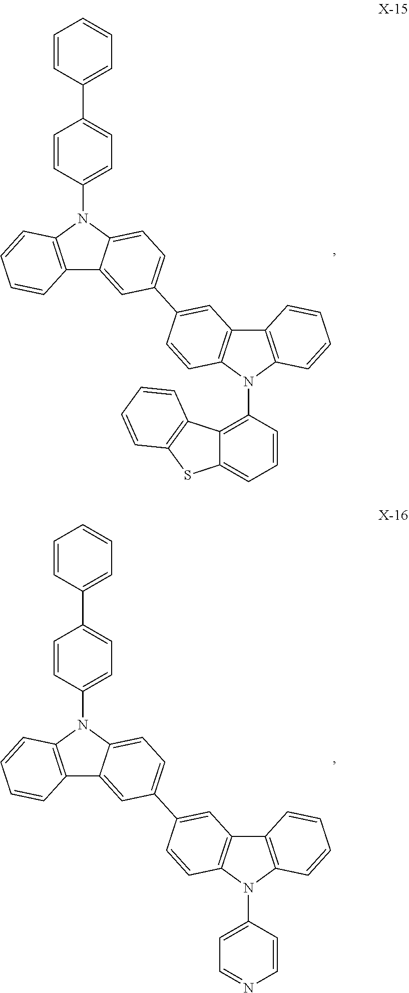 [SMILES: c1ccc(-c2ccc(-n3c4ccccc4c4cc(-c5ccc6c(c5)c5ccccc5n6-c5cccc6sc7ccccc7c56)ccc43)cc2)cc1 ; c1ccc(-c2ccc(-n3c4ccccc4c4cc(-c5ccc6c(c5)c5ccccc5n6-c5ccncc5)ccc43)cc2)cc1]

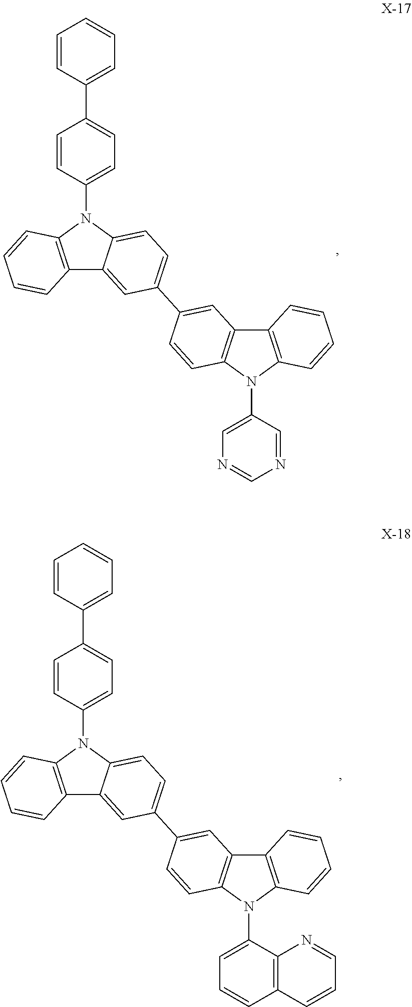 [SMILES: c1ccc(-c2ccc(-n3c4ccccc4c4cc(-c5ccc6c(c5)c5ccccc5n6-c5cncnc5)ccc43)cc2)cc1 ; c1ccc(-c2ccc(-n3c4ccccc4c4cc(-c5ccc6c(c5)c5ccccc5n6-c5cccc6cccnc56)ccc43)cc2)cc1]

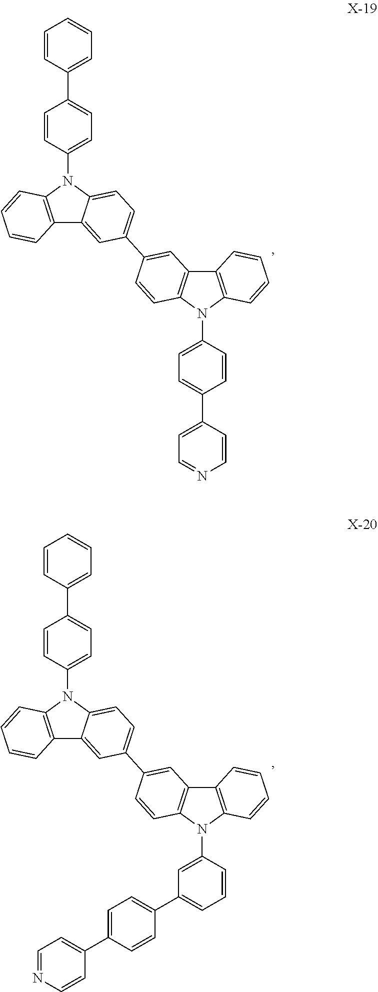 [SMILES: c1ccc(-c2ccc(-n3c4ccccc4c4cc(-c5ccc6c(c5)c5ccccc5n6-c5ccc(-c6ccncc6)cc5)ccc43)cc2)cc1 ; c1ccc(-c2ccc(-n3c4ccccc4c4cc(-c5ccc6c(c5)c5ccccc5n6-c5cccc(-c6ccc(-c7ccncc7)cc6)c5)ccc43)cc2)cc1]

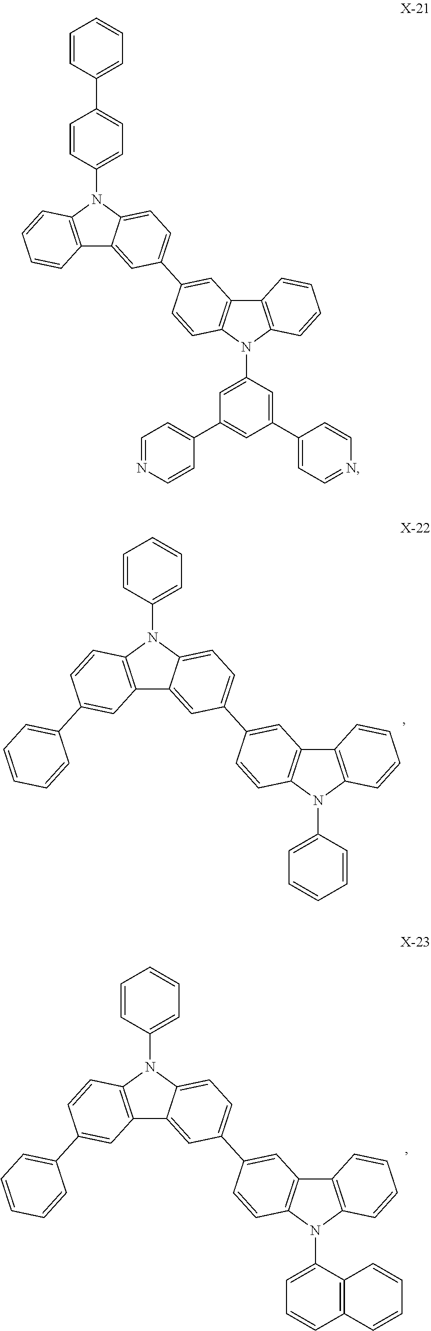 [SMILES: c1ccc(-c2ccc(-n3c4ccccc4c4cc(-c5ccc6c(c5)c5ccccc5n6-c5cc(-c6ccncc6)cc(-c6ccncc6)c5)ccc43)cc2)cc1 ; c1ccc(-c2ccc3c(c2)c2cc(-c4ccc5c(c4)c4ccccc4n5-c4ccccc4)ccc2n3-c2ccccc2)cc1 ; c1ccc(-c2ccc3c(c2)c2cc(-c4ccc5c(c4)c4ccccc4n5-c4cccc5ccccc45)ccc2n3-c2ccccc2)cc1]

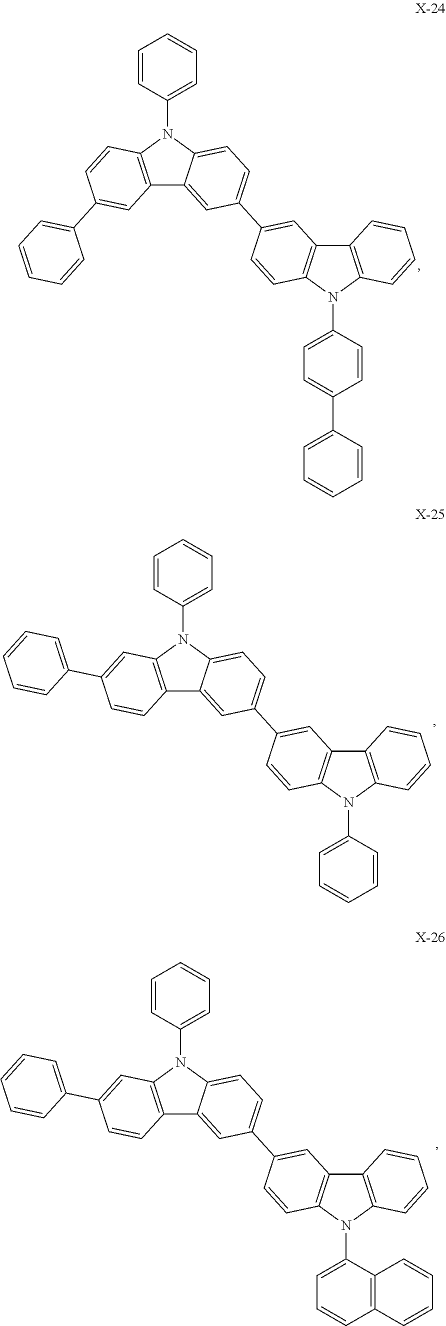 [SMILES: c1ccc(-c2ccc(-n3c4ccccc4c4cc(-c5ccc6c(c5)c5cc(-c7ccccc7)ccc5n6-c5ccccc5)ccc43)cc2)cc1 ; c1ccc(-c2ccc3c4cc(-c5ccc6c(c5)c5ccccc5n6-c5ccccc5)ccc4n(-c4ccccc4)c3c2)cc1 ; c1ccc(-c2ccc3c4cc(-c5ccc6c(c5)c5ccccc5n6-c5cccc6ccccc56)ccc4n(-c4ccccc4)c3c2)cc1]

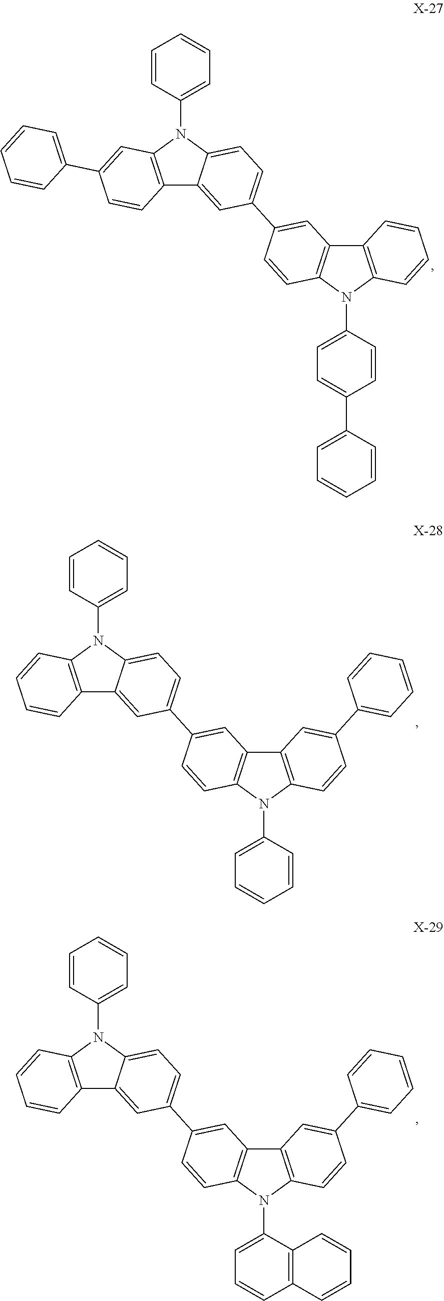 [SMILES: c1ccc(-c2ccc(-n3c4ccccc4c4cc(-c5ccc6c(c5)c5ccc(-c7ccccc7)cc5n6-c5ccccc5)ccc43)cc2)cc1 ; c1ccc(-c2ccc3c(c2)c2cc(-c4ccc5c(c4)c4ccccc4n5-c4ccccc4)ccc2n3-c2ccccc2)cc1 ; c1ccc(-c2ccc3c(c2)c2cc(-c4ccc5c(c4)c4ccccc4n5-c4ccccc4)ccc2n3-c2cccc3ccccc23)cc1]

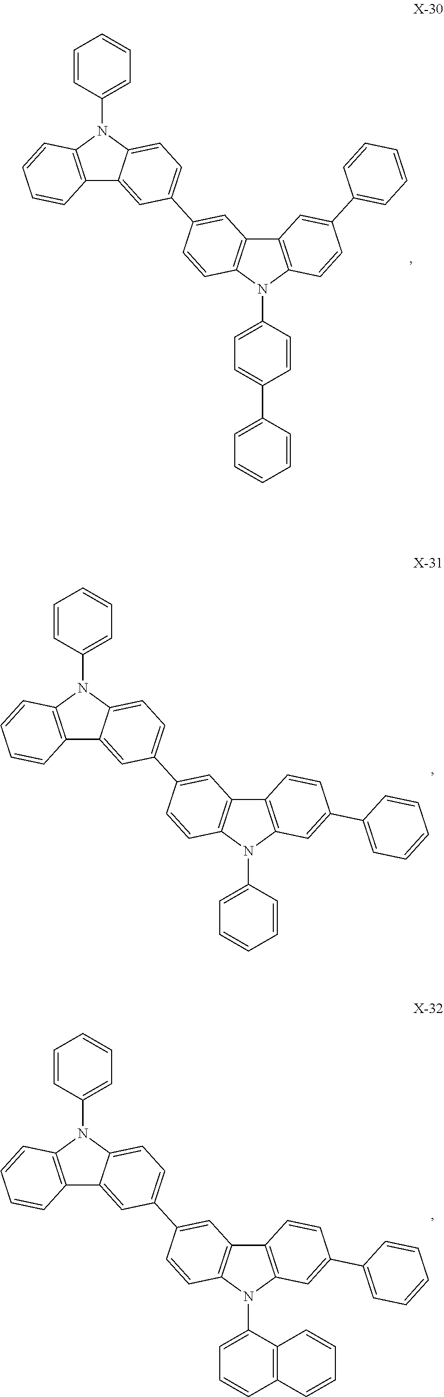 [SMILES: c1ccc(-c2ccc(-n3c4ccc(-c5ccccc5)cc4c4cc(-c5ccc6c(c5)c5ccccc5n6-c5ccccc5)ccc43)cc2)cc1 ; c1ccc(-c2ccc3c4cc(-c5ccc6c(c5)c5ccccc5n6-c5ccccc5)ccc4n(-c4ccccc4)c3c2)cc1 ; c1ccc(-c2ccc3c4cc(-c5ccc6c(c5)c5ccccc5n6-c5ccccc5)ccc4n(-c4cccc5ccccc45)c3c2)cc1]

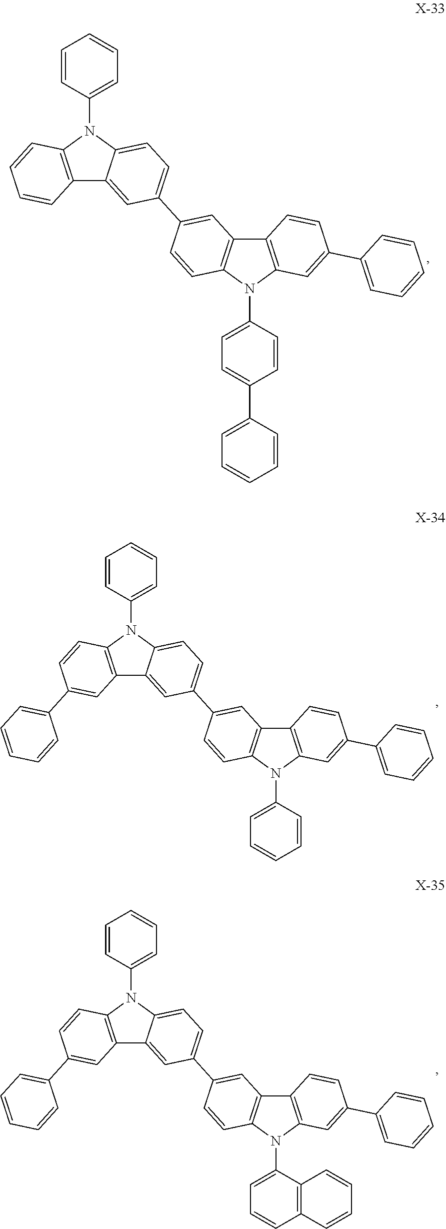 [SMILES: c1ccc(-c2ccc(-n3c4ccc(-c5ccc6c(c5)c5ccccc5n6-c5ccccc5)cc4c4ccc(-c5ccccc5)cc43)cc2)cc1 ; c1ccc(-c2ccc3c(c2)c2cc(-c4ccc5c(c4)c4ccc(-c6ccccc6)cc4n5-c4ccccc4)ccc2n3-c2ccccc2)cc1 ; c1ccc(-c2ccc3c(c2)c2cc(-c4ccc5c(c4)c4ccc(-c6ccccc6)cc4n5-c4cccc5ccccc45)ccc2n3-c2ccccc2)cc1]

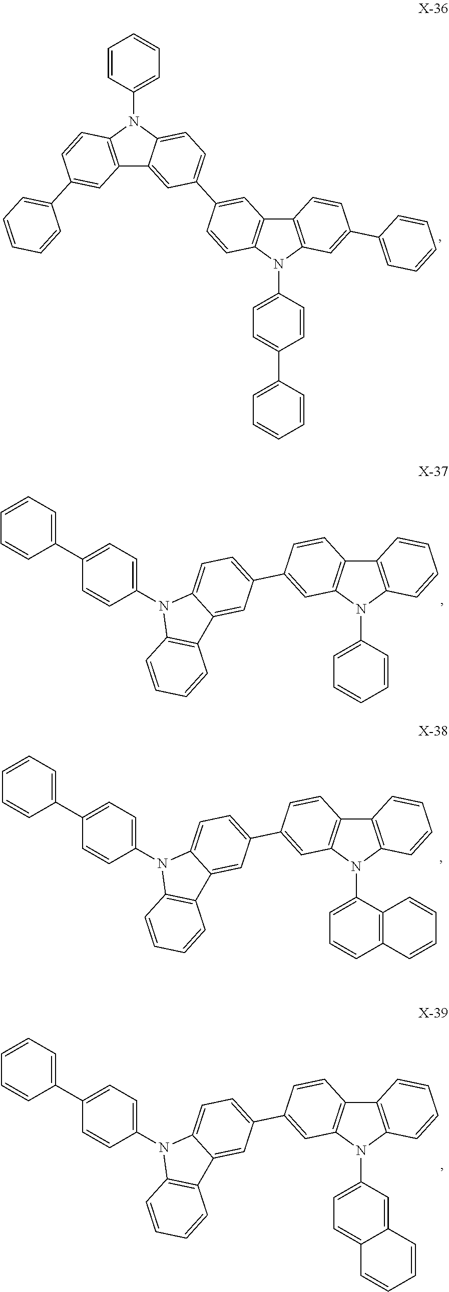 [SMILES: c1ccc(-c2ccc(-n3c4ccc(-c5ccc6c(c5)c5cc(-c7ccccc7)ccc5n6-c5ccccc5)cc4c4ccc(-c5ccccc5)cc43)cc2)cc1 ; c1ccc(-c2ccc(-n3c4ccccc4c4cc(-c5ccc6c7ccccc7n(-c7ccccc7)c6c5)ccc43)cc2)cc1 ; c1ccc(-c2ccc(-n3c4ccccc4c4cc(-c5ccc6c7ccccc7n(-c7cccc8ccccc78)c6c5)ccc43)cc2)cc1 ; c1ccc(-c2ccc(-n3c4ccccc4c4cc(-c5ccc6c7ccccc7n(-c7ccc8ccccc8c7)c6c5)ccc43)cc2)cc1]

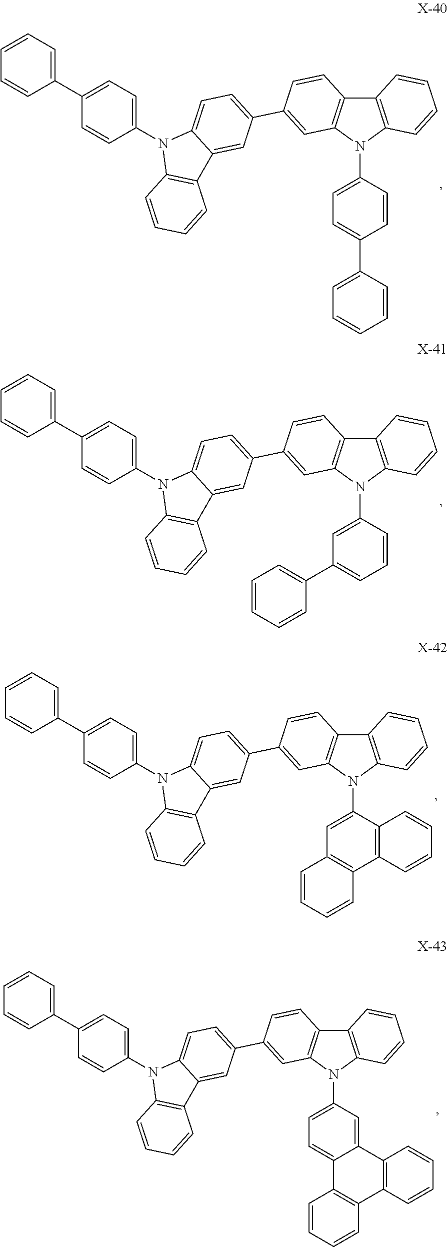 [SMILES: c1ccc(-c2ccc(-n3c4ccccc4c4cc(-c5ccc6c7ccccc7n(-c7ccc(-c8ccccc8)cc7)c6c5)ccc43)cc2)cc1 ; c1ccc(-c2ccc(-n3c4ccccc4c4cc(-c5ccc6c7ccccc7n(-c7cccc(-c8ccccc8)c7)c6c5)ccc43)cc2)cc1 ; c1ccc(-c2ccc(-n3c4ccccc4c4cc(-c5ccc6c7ccccc7n(-c7cc8ccccc8c8ccccc78)c6c5)ccc43)cc2)cc1 ; c1ccc(-c2ccc(-n3c4ccccc4c4cc(-c5ccc6c7ccccc7n(-c7ccc8c9ccccc9c9ccccc9c8c7)c6c5)ccc43)cc2)cc1]

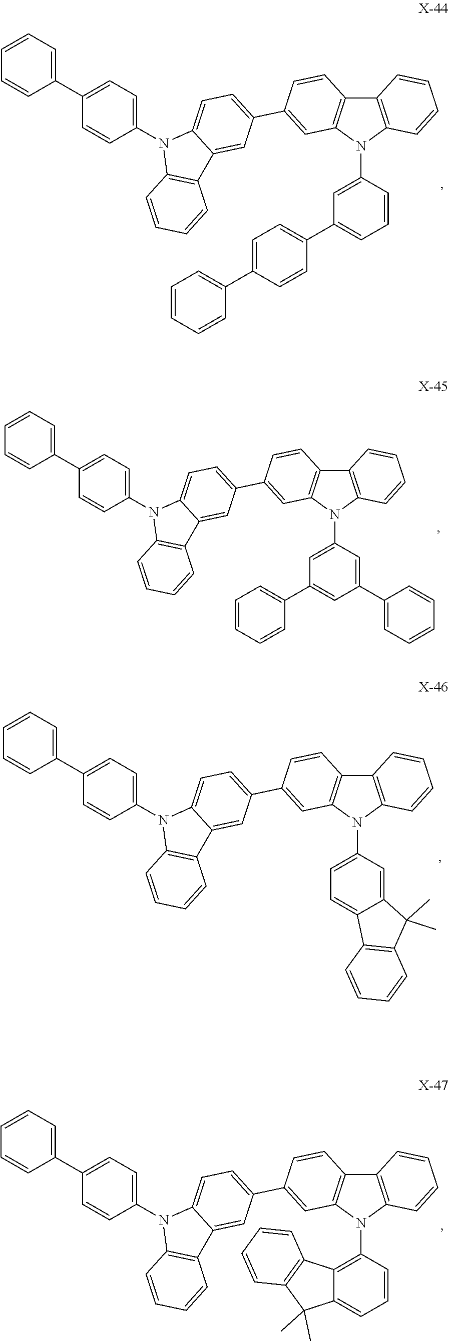 [SMILES: c1ccc(-c2ccc(-c3cccc(-n4c5ccccc5c5ccc(-c6ccc7c(c6)c6ccccc6n7-c6ccc(-c7ccccc7)cc6)cc54)c3)cc2)cc1 ; c1ccc(-c2ccc(-n3c4ccccc4c4cc(-c5ccc6c7ccccc7n(-c7cc(-c8ccccc8)cc(-c8ccccc8)c7)c6c5)ccc43)cc2)cc1 ; CC1(C)c2ccccc2-c2ccc(-n3c4ccccc4c4ccc(-c5ccc6c(c5)c5ccccc5n6-c5ccc(-c6ccccc6)cc5)cc43)cc21 ; CC1(C)c2ccccc2-c2c(-n3c4ccccc4c4ccc(-c5ccc6c(c5)c5ccccc5n6-c5ccc(-c6ccccc6)cc5)cc43)cccc21]

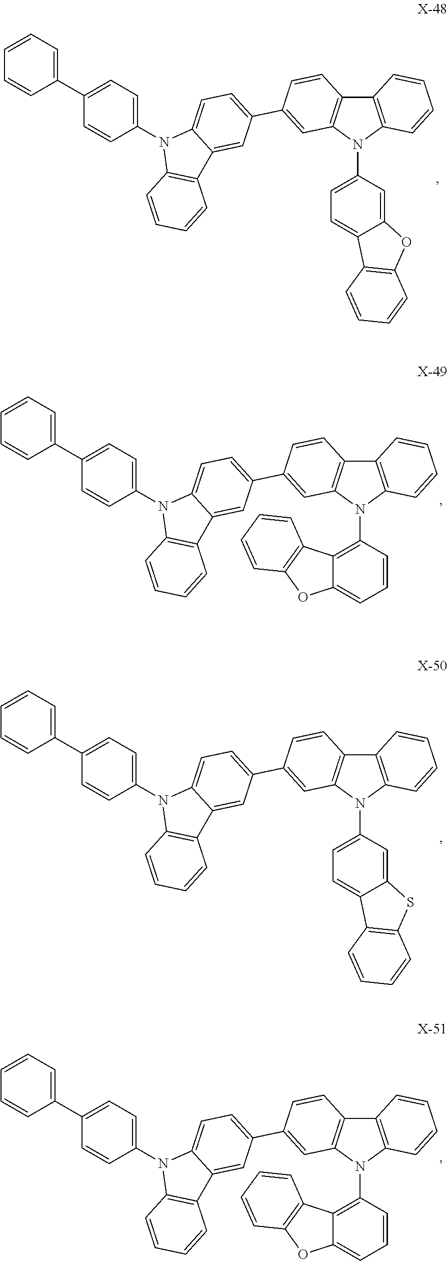 [SMILES: c1ccc(-c2ccc(-n3c4ccccc4c4cc(-c5ccc6c7ccccc7n(-c7ccc8c(c7)oc7ccccc78)c6c5)ccc43)cc2)cc1 ; c1ccc(-c2ccc(-n3c4ccccc4c4cc(-c5ccc6c7ccccc7n(-c7cccc8oc9ccccc9c78)c6c5)ccc43)cc2)cc1 ; c1ccc(-c2ccc(-n3c4ccccc4c4cc(-c5ccc6c7ccccc7n(-c7ccc8c(c7)sc7ccccc78)c6c5)ccc43)cc2)cc1 ; c1ccc(-c2ccc(-n3c4ccccc4c4cc(-c5ccc6c7ccccc7n(-c7cccc8oc9ccccc9c78)c6c5)ccc43)cc2)cc1]

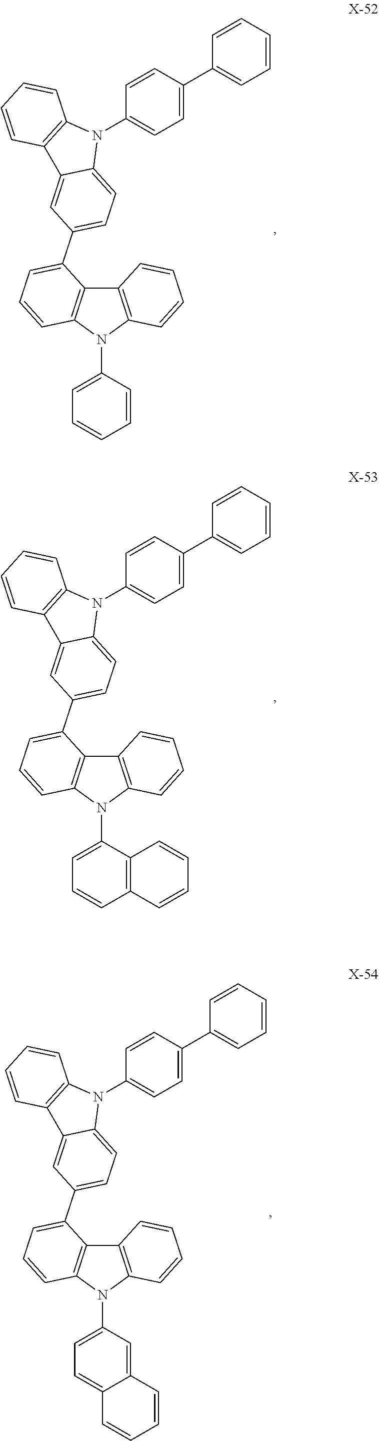 [SMILES: c1ccc(-c2ccc(-n3c4ccccc4c4cc(-c5cccc6c5c5ccccc5n6-c5ccccc5)ccc43)cc2)cc1 ; c1ccc(-c2ccc(-n3c4ccccc4c4cc(-c5cccc6c5c5ccccc5n6-c5cccc6ccccc56)ccc43)cc2)cc1 ; c1ccc(-c2ccc(-n3c4ccccc4c4cc(-c5cccc6c5c5ccccc5n6-c5ccc6ccccc6c5)ccc43)cc2)cc1]

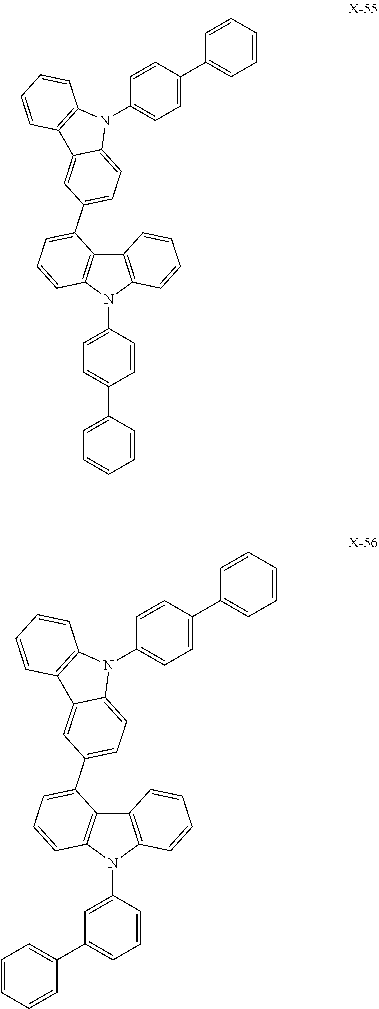 [SMILES: c1ccc(-c2ccc(-n3c4ccccc4c4cc(-c5cccc6c5c5ccccc5n6-c5ccc(-c6ccccc6)cc5)ccc43)cc2)cc1 ; c1ccc(-c2ccc(-n3c4ccccc4c4cc(-c5cccc6c5c5ccccc5n6-c5cccc(-c6ccccc6)c5)ccc43)cc2)cc1]

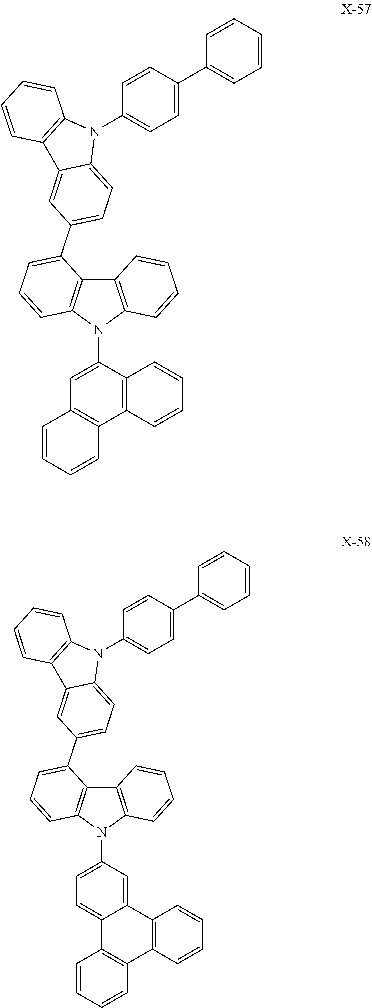 [SMILES: c1ccc(-c2ccc(-n3c4ccccc4c4cc(-c5cccc6c5c5ccccc5n6-c5cc6ccccc6c6ccccc56)ccc43)cc2)cc1 ; c1ccc(-c2ccc(-n3c4ccccc4c4cc(-c5cccc6c5c5ccccc5n6-c5ccc6c7ccccc7c7ccccc7c6c5)ccc43)cc2)cc1]

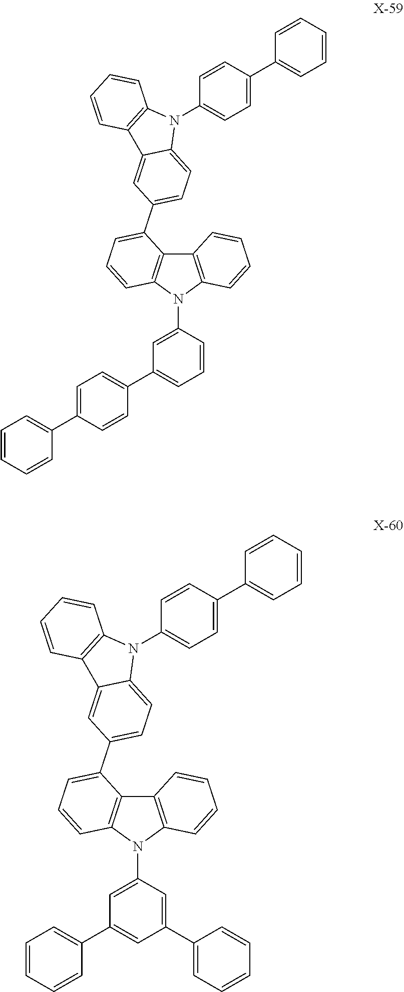 [SMILES: c1ccc(-c2ccc(-c3cccc(-n4c5ccccc5c5c(-c6ccc7c(c6)c6ccccc6n7-c6ccc(-c7ccccc7)cc6)cccc54)c3)cc2)cc1 ; c1ccc(-c2ccc(-n3c4ccccc4c4cc(-c5cccc6c5c5ccccc5n6-c5cc(-c6ccccc6)cc(-c6ccccc6)c5)ccc43)cc2)cc1]

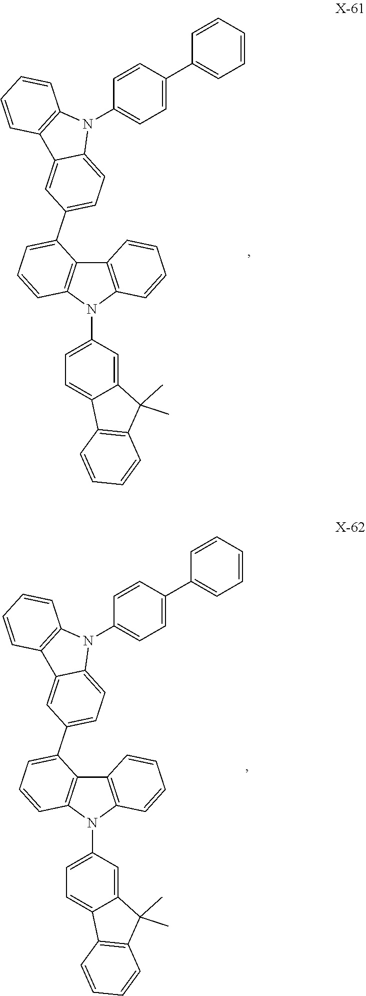 [SMILES: CC1(C)c2ccccc2-c2ccc(-n3c4ccccc4c4c(-c5ccc6c(c5)c5ccccc5n6-c5ccc(-c6ccccc6)cc5)cccc43)cc21 ; CC1(C)c2ccccc2-c2ccc(-n3c4ccccc4c4c(-c5ccc6c(c5)c5ccccc5n6-c5ccc(-c6ccccc6)cc5)cccc43)cc21]

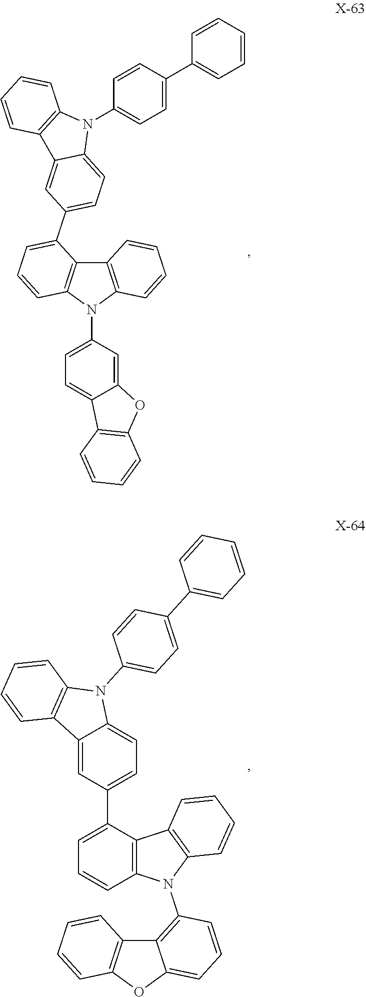 [SMILES: c1ccc(-c2ccc(-n3c4ccccc4c4cc(-c5cccc6c5c5ccccc5n6-c5ccc6c(c5)oc5ccccc56)ccc43)cc2)cc1 ; c1ccc(-c2ccc(-n3c4ccccc4c4cc(-c5cccc6c5c5ccccc5n6-c5cccc6oc7ccccc7c56)ccc43)cc2)cc1]

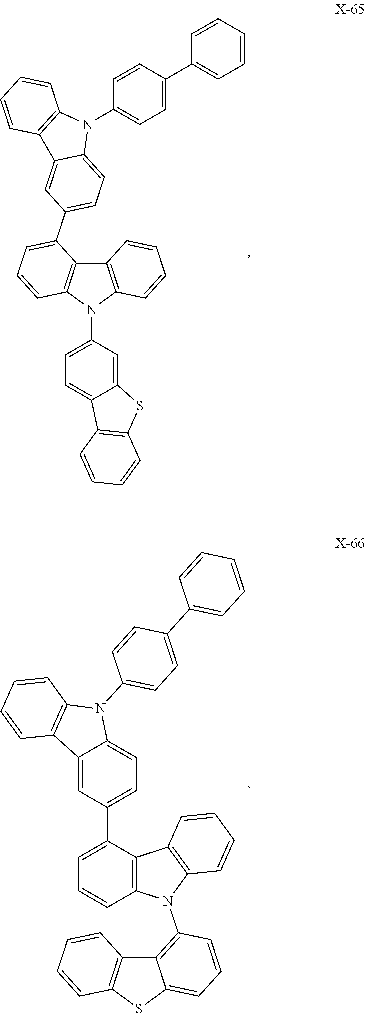 [SMILES: c1ccc(-c2ccc(-n3c4ccccc4c4cc(-c5cccc6c5c5ccccc5n6-c5ccc6c(c5)sc5ccccc56)ccc43)cc2)cc1 ; c1ccc(-c2ccc(-n3c4ccccc4c4cc(-c5cccc6c5c5ccccc5n6-c5cccc6sc7ccccc7c56)ccc43)cc2)cc1]

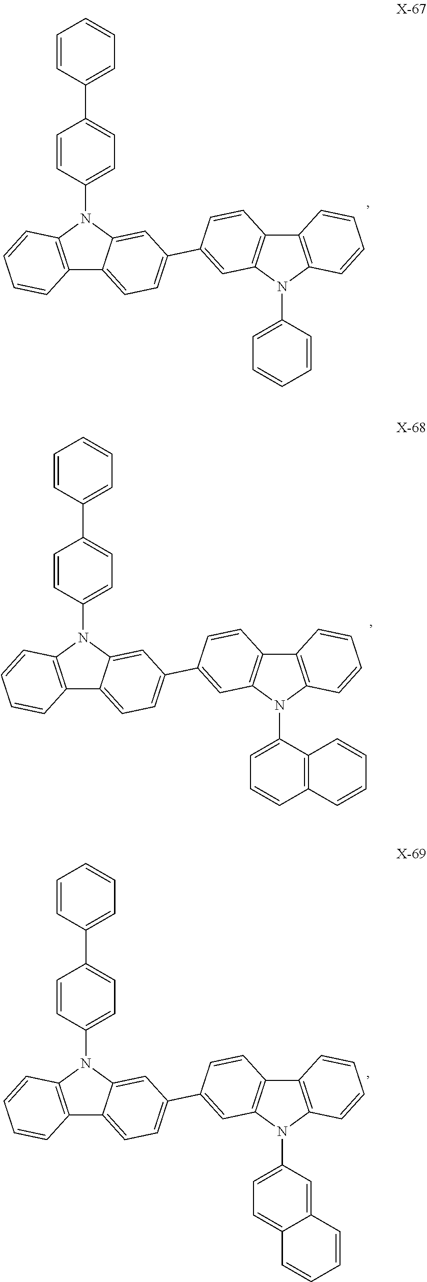 [SMILES: c1ccc(-c2ccc(-n3c4ccccc4c4ccc(-c5ccc6c7ccccc7n(-c7ccccc7)c6c5)cc43)cc2)cc1 ; c1ccc(-c2ccc(-n3c4ccccc4c4ccc(-c5ccc6c7ccccc7n(-c7cccc8ccccc78)c6c5)cc43)cc2)cc1 ; c1ccc(-c2ccc(-n3c4ccccc4c4ccc(-c5ccc6c7ccccc7n(-c7ccc8ccccc8c7)c6c5)cc43)cc2)cc1]

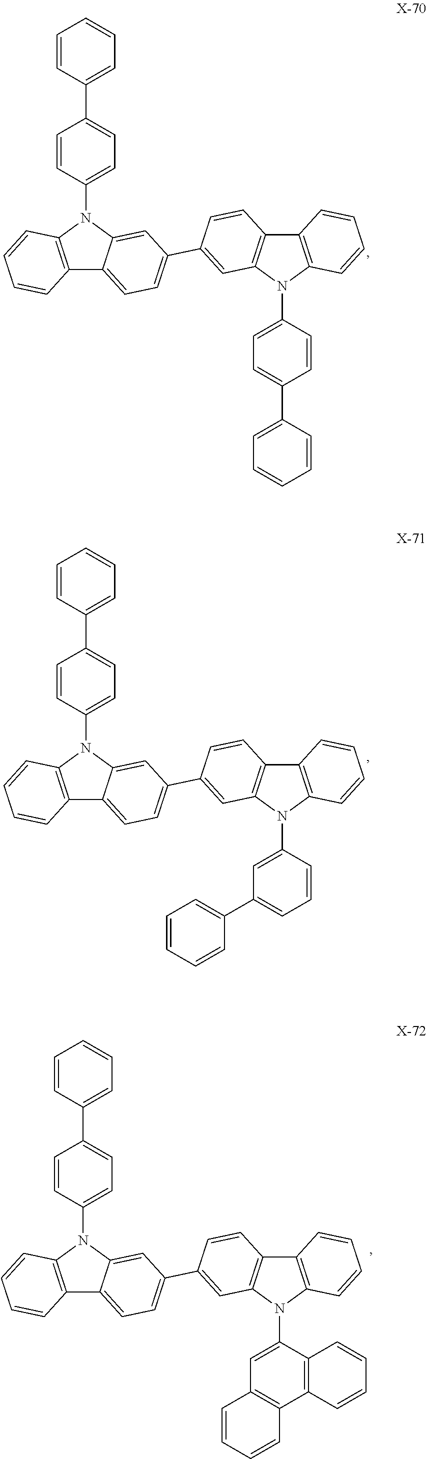 [SMILES: c1ccc(-c2ccc(-n3c4ccccc4c4ccc(-c5ccc6c7ccccc7n(-c7ccc(-c8ccccc8)cc7)c6c5)cc43)cc2)cc1 ; c1ccc(-c2ccc(-n3c4ccccc4c4ccc(-c5ccc6c7ccccc7n(-c7cccc(-c8ccccc8)c7)c6c5)cc43)cc2)cc1 ; c1ccc(-c2ccc(-n3c4ccccc4c4ccc(-c5ccc6c7ccccc7n(-c7cc8ccccc8c8ccccc78)c6c5)cc43)cc2)cc1]

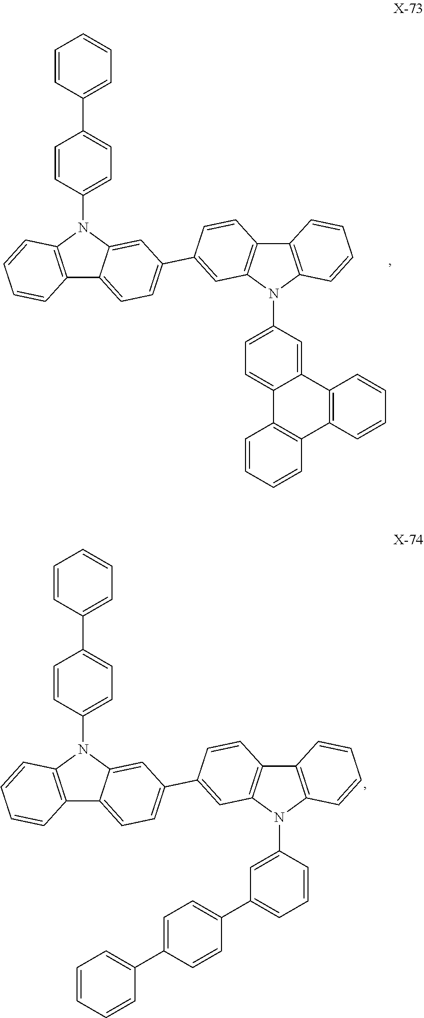 [SMILES: c1ccc(-c2ccc(-n3c4ccccc4c4ccc(-c5ccc6c7ccccc7n(-c7ccc8c9ccccc9c9ccccc9c8c7)c6c5)cc43)cc2)cc1 ; c1ccc(-c2ccc(-c3cccc(-n4c5ccccc5c5ccc(-c6ccc7c8ccccc8n(-c8ccc(-c9ccccc9)cc8)c7c6)cc54)c3)cc2)cc1]

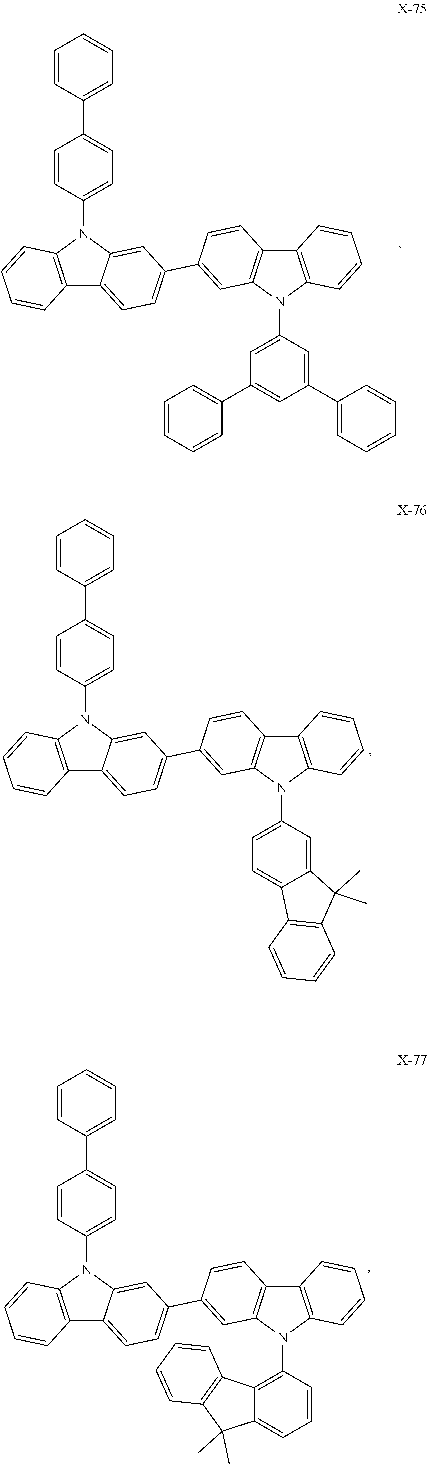 [SMILES: c1ccc(-c2ccc(-n3c4ccccc4c4ccc(-c5ccc6c7ccccc7n(-c7cc(-c8ccccc8)cc(-c8ccccc8)c7)c6c5)cc43)cc2)cc1 ; CC1(C)c2ccccc2-c2ccc(-n3c4ccccc4c4ccc(-c5ccc6c7ccccc7n(-c7ccc(-c8ccccc8)cc7)c6c5)cc43)cc21 ; CC1(C)c2ccccc2-c2c(-n3c4ccccc4c4ccc(-c5ccc6c7ccccc7n(-c7ccc(-c8ccccc8)cc7)c6c5)cc43)cccc21]

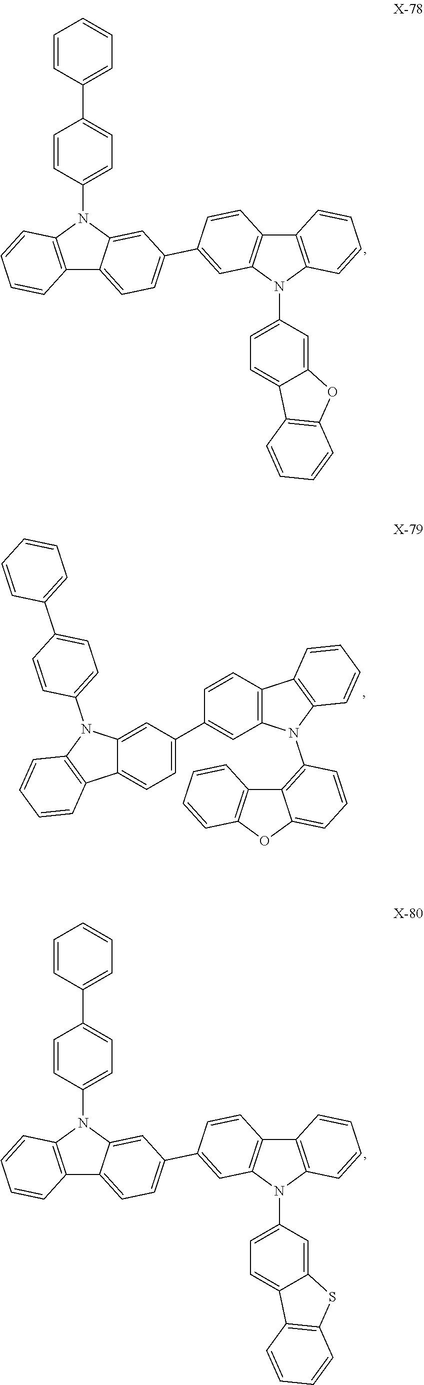 [SMILES: c1ccc(-c2ccc(-n3c4ccccc4c4ccc(-c5ccc6c7ccccc7n(-c7ccc8c(c7)oc7ccccc78)c6c5)cc43)cc2)cc1 ; c1ccc(-c2ccc(-n3c4ccccc4c4ccc(-c5ccc6c7ccccc7n(-c7cccc8oc9ccccc9c78)c6c5)cc43)cc2)cc1 ; c1ccc(-c2ccc(-n3c4ccccc4c4ccc(-c5ccc6c7ccccc7n(-c7ccc8c(c7)sc7ccccc78)c6c5)cc43)cc2)cc1]

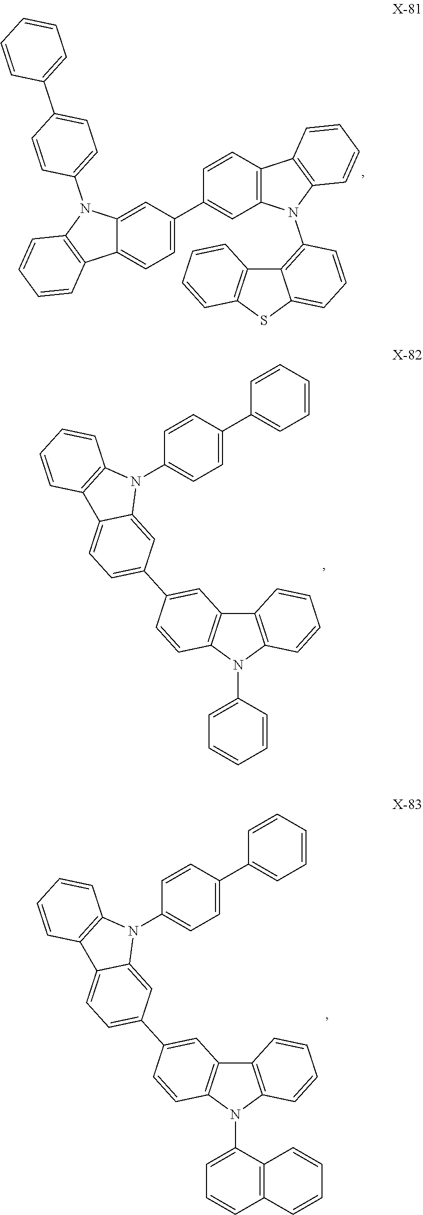 [SMILES: c1ccc(-c2ccc(-n3c4ccccc4c4ccc(-c5ccc6c7ccccc7n(-c7cccc8sc9ccccc9c78)c6c5)cc43)cc2)cc1 ; c1ccc(-c2ccc(-n3c4ccccc4c4ccc(-c5ccc6c(c5)c5ccccc5n6-c5ccccc5)cc43)cc2)cc1 ; c1ccc(-c2ccc(-n3c4ccccc4c4ccc(-c5ccc6c(c5)c5ccccc5n6-c5cccc6ccccc56)cc43)cc2)cc1]

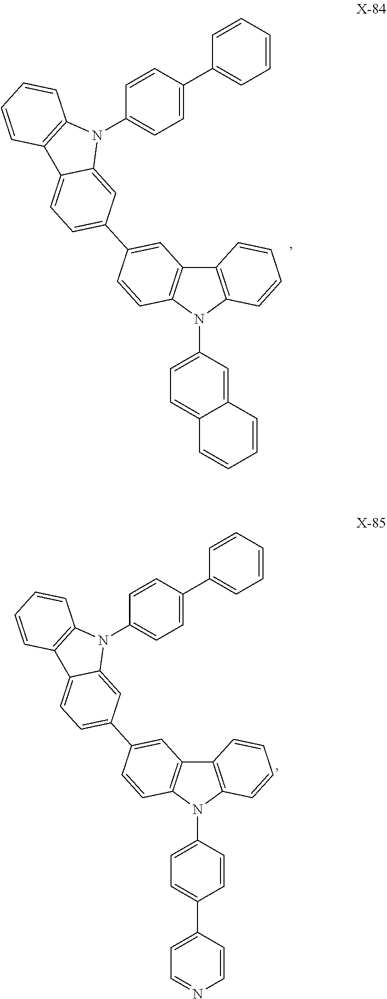 [SMILES: c1ccc(-c2ccc(-n3c4ccccc4c4ccc(-c5ccc6c(c5)c5ccccc5n6-c5ccc6ccccc6c5)cc43)cc2)cc1 ; c1ccc(-c2ccc(-n3c4ccccc4c4ccc(-c5ccc6c(c5)c5ccccc5n6-c5ccc(-c6ccncc6)cc5)cc43)cc2)cc1]

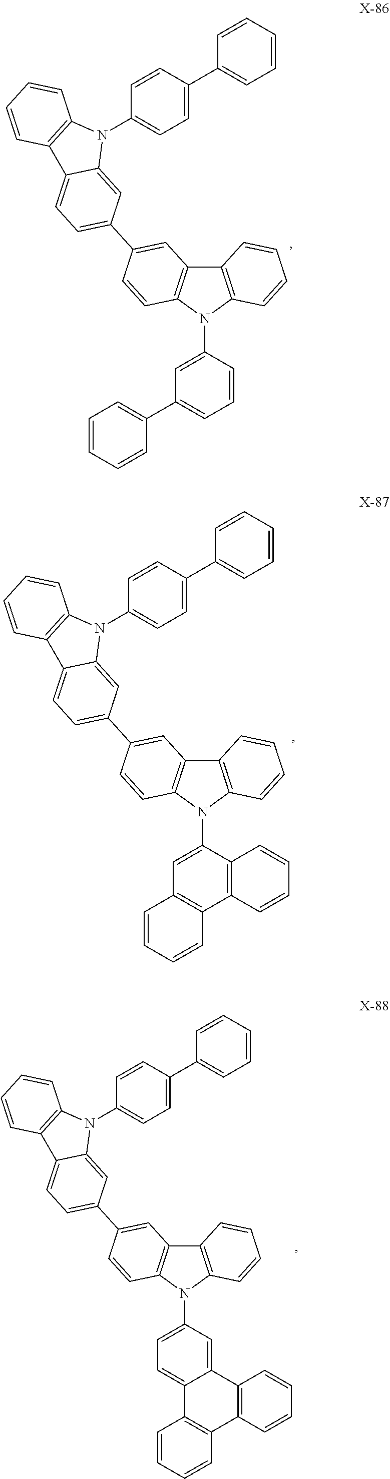 [SMILES: c1ccc(-c2ccc(-n3c4ccccc4c4ccc(-c5ccc6c(c5)c5ccccc5n6-c5cccc(-c6ccccc6)c5)cc43)cc2)cc1 ; c1ccc(-c2ccc(-n3c4ccccc4c4ccc(-c5ccc6c(c5)c5ccccc5n6-c5cc6ccccc6c6ccccc56)cc43)cc2)cc1 ; c1ccc(-c2ccc(-n3c4ccccc4c4ccc(-c5ccc6c(c5)c5ccccc5n6-c5ccc6c7ccccc7c7ccccc7c6c5)cc43)cc2)cc1]

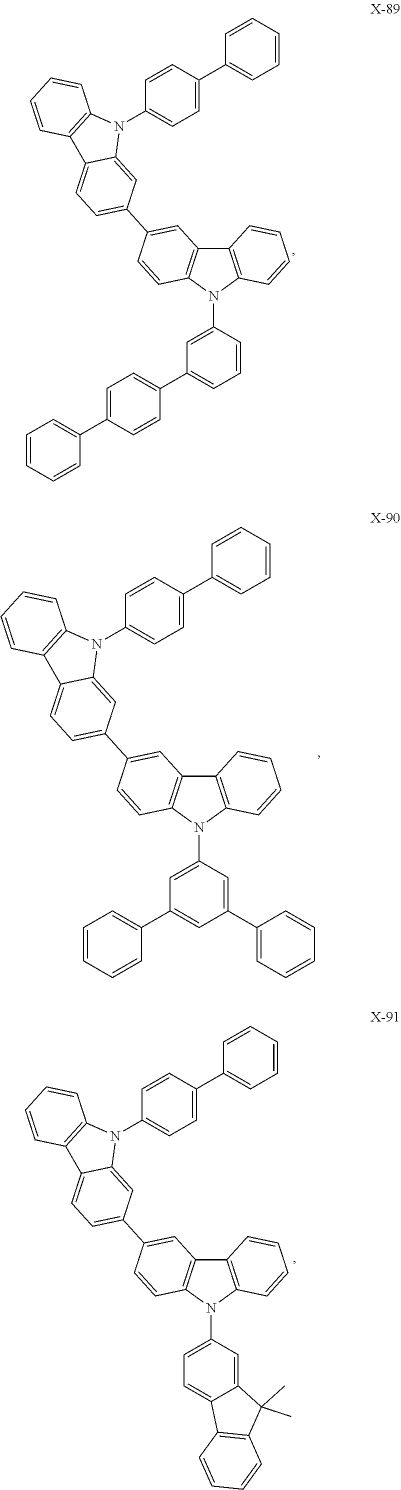 [SMILES: c1ccc(-c2ccc(-c3cccc(-n4c5ccccc5c5cc(-c6ccc7c8ccccc8n(-c8ccc(-c9ccccc9)cc8)c7c6)ccc54)c3)cc2)cc1 ; c1ccc(-c2ccc(-n3c4ccccc4c4ccc(-c5ccc6c(c5)c5ccccc5n6-c5cc(-c6ccccc6)cc(-c6ccccc6)c5)cc43)cc2)cc1 ; CC1(C)c2ccccc2-c2ccc(-n3c4ccccc4c4cc(-c5ccc6c7ccccc7n(-c7ccc(-c8ccccc8)cc7)c6c5)ccc43)cc21]

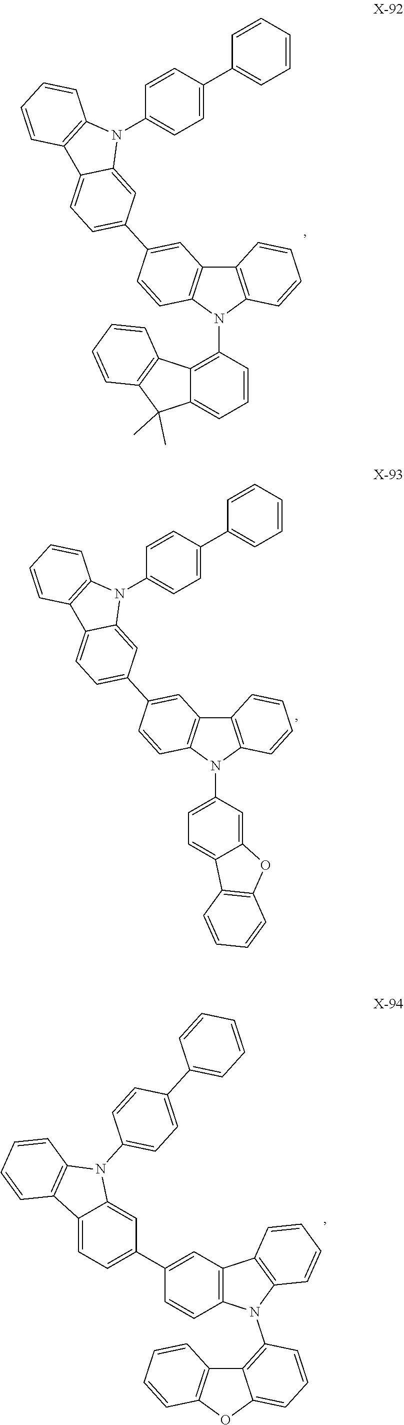 [SMILES: CC1(C)c2ccccc2-c2c(-n3c4ccccc4c4cc(-c5ccc6c7ccccc7n(-c7ccc(-c8ccccc8)cc7)c6c5)ccc43)cccc21 ; c1ccc(-c2ccc(-n3c4ccccc4c4ccc(-c5ccc6c(c5)c5ccccc5n6-c5ccc6c(c5)oc5ccccc56)cc43)cc2)cc1 ; c1ccc(-c2ccc(-n3c4ccccc4c4ccc(-c5ccc6c(c5)c5ccccc5n6-c5cccc6oc7ccccc7c56)cc43)cc2)cc1]

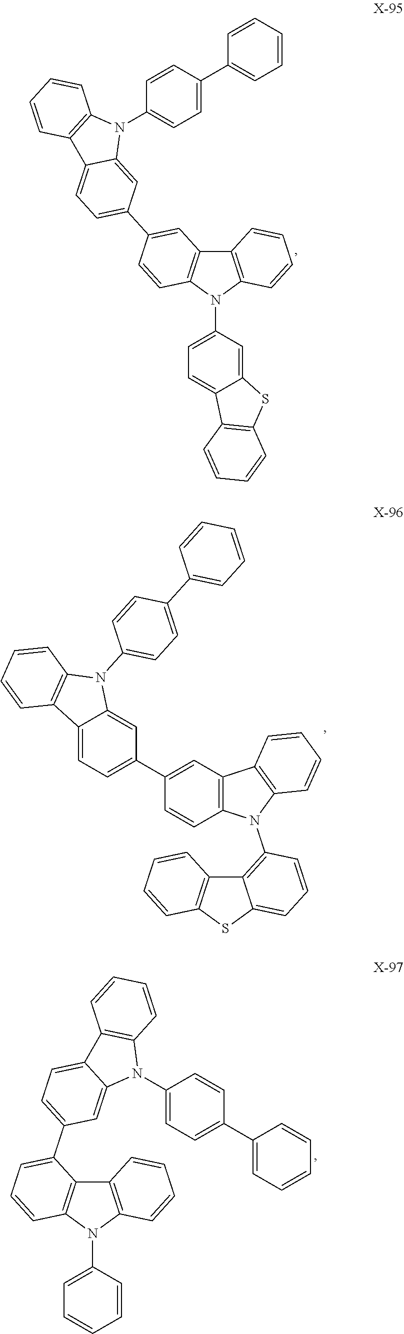

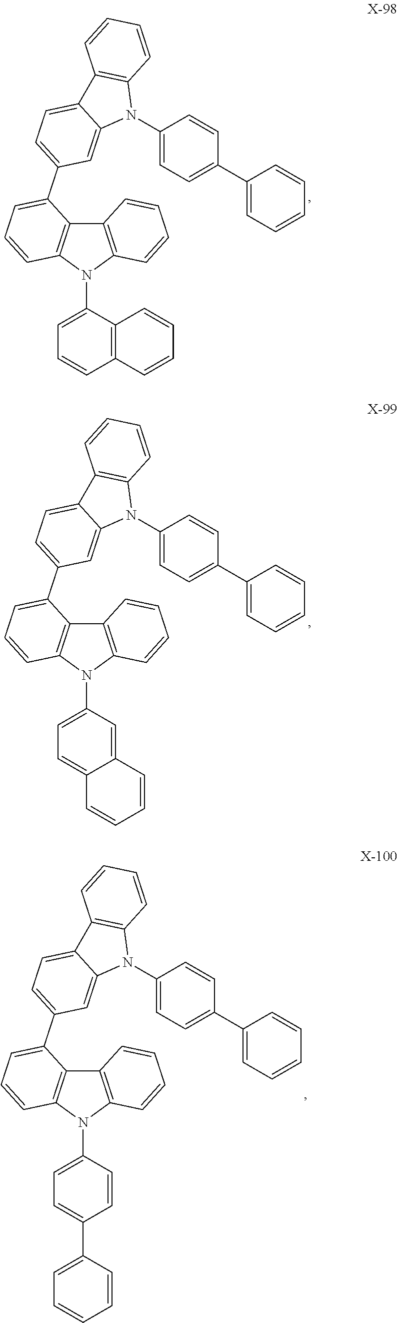

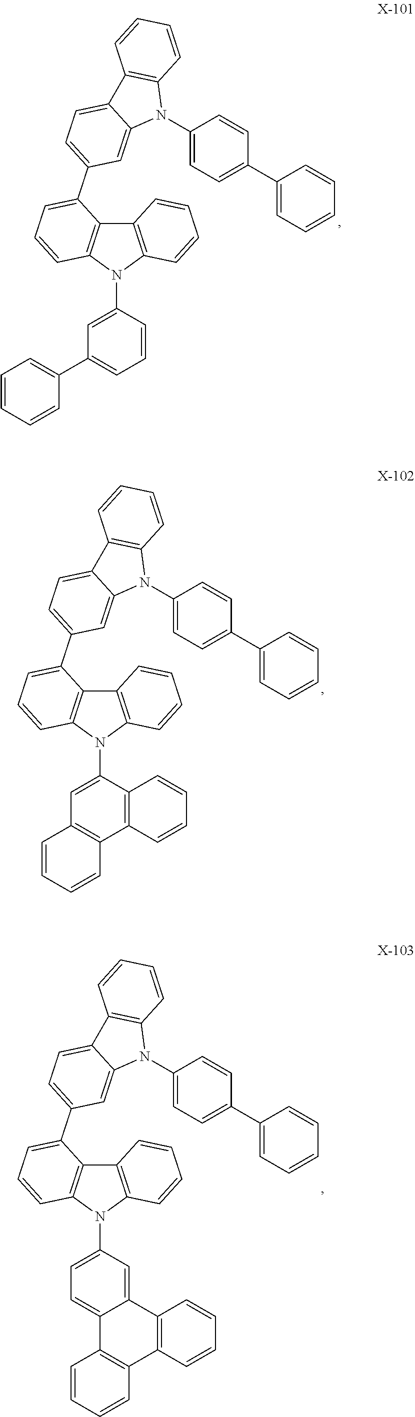 [SMILES: c1ccc(-c2ccc(-n3c4ccccc4c4ccc(-c5cccc6c5c5ccccc5n6-c5cccc(-c6ccccc6)c5)cc43)cc2)cc1 ; c1ccc(-c2ccc(-n3c4ccccc4c4ccc(-c5cccc6c5c5ccccc5n6-c5cc6ccccc6c6ccccc56)cc43)cc2)cc1 ; c1ccc(-c2ccc(-n3c4ccccc4c4ccc(-c5cccc6c5c5ccccc5n6-c5ccc6c7ccccc7c7ccccc7c6c5)cc43)cc2)cc1]

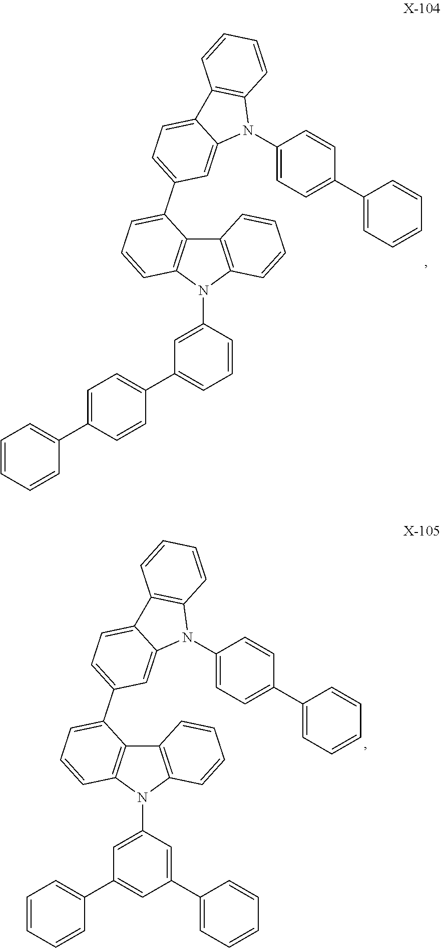 [SMILES: c1ccc(-c2ccc(-c3cccc(-n4c5ccccc5c5c(-c6ccc7c8ccccc8n(-c8ccc(-c9ccccc9)cc8)c7c6)cccc54)c3)cc2)cc1 ; c1ccc(-c2ccc(-n3c4ccccc4c4ccc(-c5cccc6c5c5ccccc5n6-c5cc(-c6ccccc6)cc(-c6ccccc6)c5)cc43)cc2)cc1]

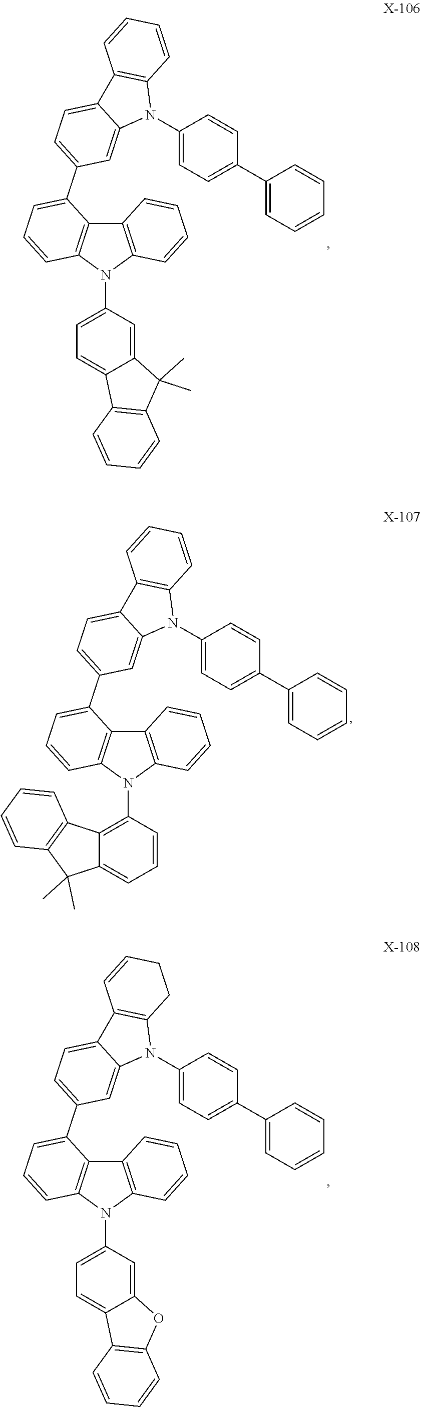 [SMILES: CC1(C)c2ccccc2-c2ccc(-n3c4ccccc4c4c(-c5ccc6c7ccccc7n(-c7ccc(-c8ccccc8)cc7)c6c5)cccc43)cc21 ; CC1(C)c2ccccc2-c2c(-n3c4ccccc4c4c(-c5ccc6c7ccccc7n(-c7ccc(-c8ccccc8)cc7)c6c5)cccc43)cccc21 ; C1=Cc2c(n(-c3ccc(-c4ccccc4)cc3)c3cc(-c4cccc5c4c4ccccc4n5-c4ccc5c(c4)oc4ccccc45)ccc23)CC1]

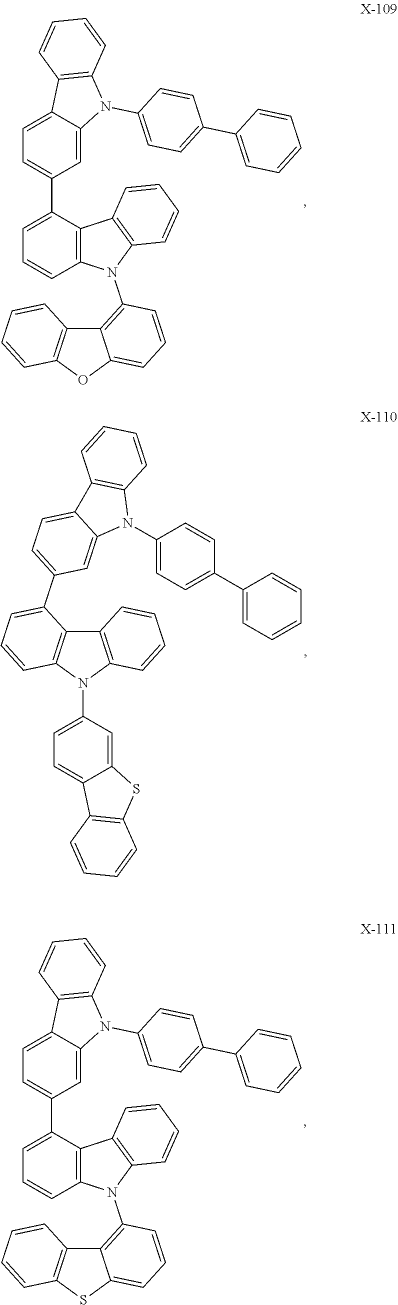 [SMILES: c1ccc(-c2ccc(-n3c4ccccc4c4ccc(-c5cccc6c5c5ccccc5n6-c5cccc6oc7ccccc7c56)cc43)cc2)cc1 ; c1ccc(-c2ccc(-n3c4ccccc4c4ccc(-c5cccc6c5c5ccccc5n6-c5ccc6c(c5)sc5ccccc56)cc43)cc2)cc1 ; c1ccc(-c2ccc(-n3c4ccccc4c4ccc(-c5cccc6c5c5ccccc5n6-c5cccc6sc7ccccc7c56)cc43)cc2)cc1]

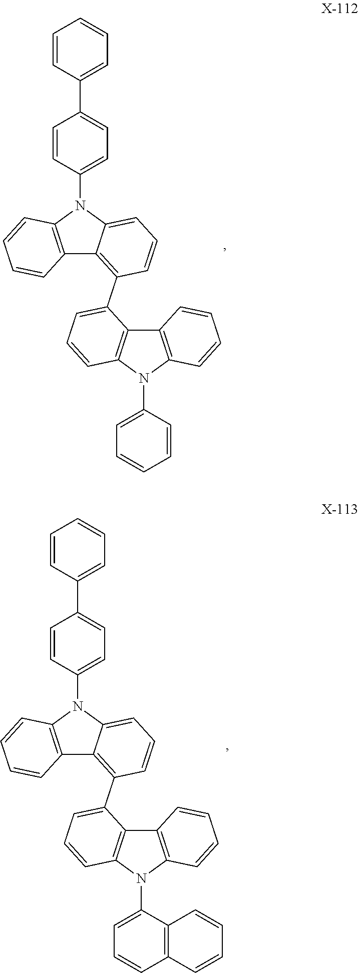 [SMILES: c1ccc(-c2ccc(-n3c4ccccc4c4c(-c5cccc6c5c5ccccc5n6-c5ccccc5)cccc43)cc2)cc1 ; c1ccc(-c2ccc(-n3c4ccccc4c4c(-c5cccc6c5c5ccccc5n6-c5cccc6ccccc56)cccc43)cc2)cc1]

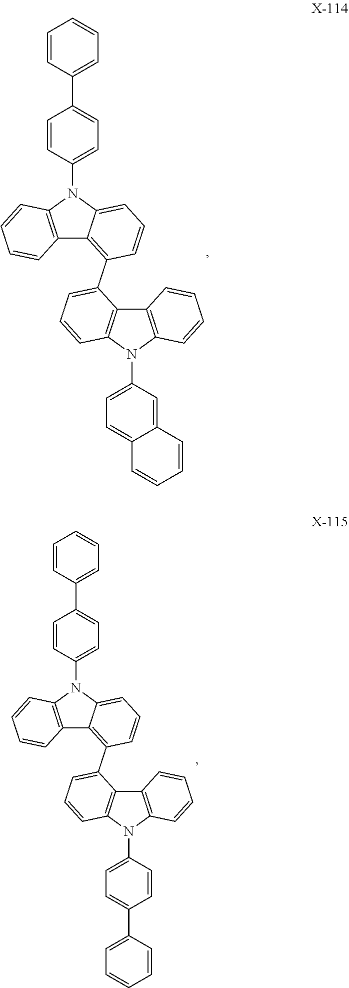 [SMILES: c1ccc(-c2ccc(-n3c4ccccc4c4c(-c5cccc6c5c5ccccc5n6-c5ccc6ccccc6c5)cccc43)cc2)cc1 ; c1ccc(-c2ccc(-n3c4ccccc4c4c(-c5cccc6c5c5ccccc5n6-c5ccc(-c6ccccc6)cc5)cccc43)cc2)cc1]

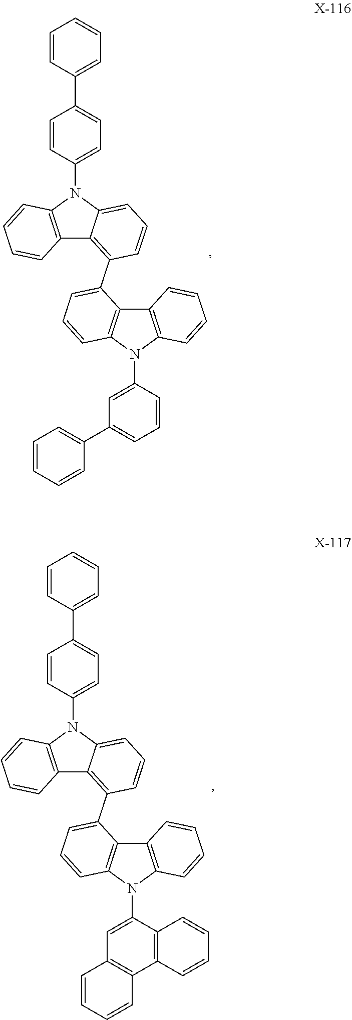 [SMILES: c1ccc(-c2ccc(-n3c4ccccc4c4c(-c5cccc6c5c5ccccc5n6-c5cccc(-c6ccccc6)c5)cccc43)cc2)cc1 ; c1ccc(-c2ccc(-n3c4ccccc4c4c(-c5cccc6c5c5ccccc5n6-c5cc6ccccc6c6ccccc56)cccc43)cc2)cc1]

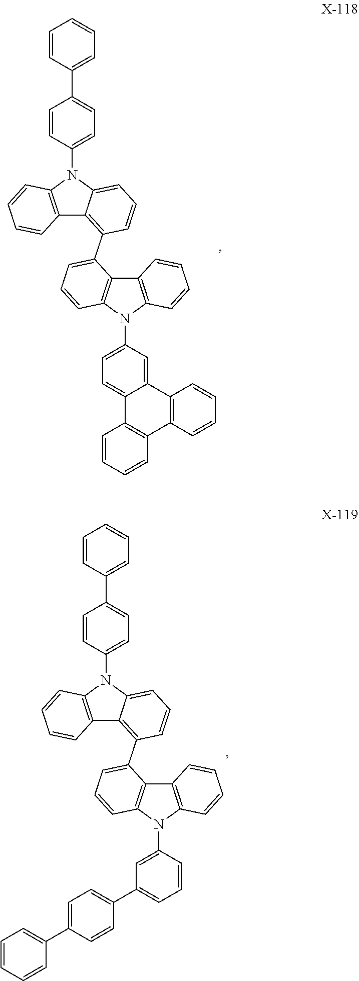 [SMILES: c1ccc(-c2ccc(-n3c4ccccc4c4c(-c5cccc6c5c5ccccc5n6-c5ccc6c7ccccc7c7ccccc7c6c5)cccc43)cc2)cc1 ; c1ccc(-c2ccc(-c3cccc(-n4c5ccccc5c5c(-c6cccc7c6c6ccccc6n7-c6ccc(-c7ccccc7)cc6)cccc54)c3)cc2)cc1]

29. The electroluminescent device according to claim 23, wherein the metal complex is doped in the first host compound and the second host compound, and the weight of the metal complex accounts for 1% to 30% of the total weight of the emissive layer;
preferably, the weight of the metal complex accounts for 3% to 13% of the total weight of the emissive layer.

30. A compound composition, comprising the metal complex according to claim 1.
